(19) United States
(12) Patent Application Publication
(10) Pub. No.: US 2024/0107885 A1
(43) Pub. Date: Mar. 28, 2024

(54) LIGHT EMITTING DEVICE AND FUSED POLYCYCLIC COMPOUND FOR THE LIGHT EMITTING DEVICE

(71) Applicant: Samsung Display Co., Ltd., Yongin-si (KR)

(72) Inventors: MUN-KI SIM, Yongin-si (KR); CHANSEOK OH, Yongin-si (KR); SUN YOUNG PAK, Yongin-si (KR); JUNHA PARK, Yongin-si (KR); Kyoung SUNWOO, Yongin-si (KR)

(21) Appl. No.: 18/195,856

(22) Filed: May 10, 2023

(30) Foreign Application Priority Data
Aug. 16, 2022 (KR) 10-2022-0102269

(51) Int. Cl. H01L 51/00; C09K 11/02; C09K 11/06

(52) U.S. Cl. CPC H10K 85/658; C09K 11/02; C09K 11/06; H10K 85/346; H10K 85/40; H10K 85/633; H10K 85/654; C07B 2200/05

(57) ABSTRACT

A light emitting device includes a first electrode, a second electrode facing the first electrode, and an emission layer between the first electrode and the second electrode, where the emission layer includes a first compound represented by Formula 1:

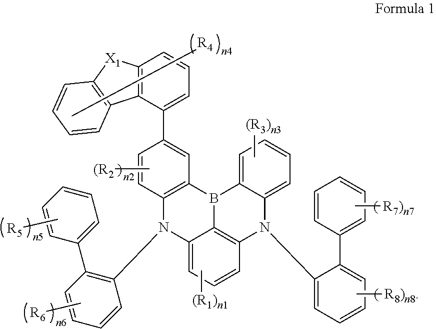

### CROSS-REFERENCE TO RELATED APPLICATION

This application claims priority to and the benefit of Korean Patent Application No. 10-2022-0102269, filed on Aug. 16, 2022, in the Korean Intellectual Property Office, the entire content of which is hereby incorporated by reference.

### BACKGROUND

### 1. Field

One or more embodiments of the present disclosure relate to a light emitting device and a fused polycyclic compound utilized in the light emitting device.

### 2. Description of the Related Art

Recently, the development of an organic electroluminescence display apparatus as an image display apparatus is being actively conducted. Unlike liquid crystal display apparatuses and/or the like, the organic electroluminescence display apparatus is a self-luminescent display apparatus in which holes and electrons injected from a first electrode and a second electrode of the organic electroluminescence display apparatus recombine in an emission layer, and thus a luminescent material including an organic compound in the emission layer may emit light to implement display (e.g., of an image).

In the application of an organic electroluminescence device to a display apparatus, there is a demand for an organic electroluminescence device having a low driving voltage, high luminous efficiency, and a long service life, and the development on materials, for an organic electroluminescence device, capable of stably attaining such characteristics is being continuously required and desired.

In recent years, in order to improve the luminous efficiency of the organic electroluminescence device, technologies pertaining to phosphorescence emission utilizing triplet state energy or fluorescence utilizing triplet-triplet annihilation (TTA) in which singlet excitons are generated by collision of triplet excitons are being developed, and thermally activated delayed fluorescence (TADF) materials utilizing delayed fluorescence phenomenon are also being intensively investigated and developed.

### SUMMARY

One or more aspects of embodiments of the present disclosure are directed toward a light emitting device in which luminous efficiency and a device service life are improved.

One or more aspects of embodiments of the present disclosure are directed toward a fused polycyclic compound capable of improving luminous efficiency and a device service life of a light emitting device.

Additional aspects will be set forth in part in the description which follows and, in part, will be apparent from the description, or may be learned by practice of the presented embodiments.

one or more embodiments of the present disclosure provide a light emitting device including a first electrode, a second electrode facing the first electrode, and an emission layer between the first electrode and the second electrode, wherein the emission layer may include a first compound represented by Formula 1:

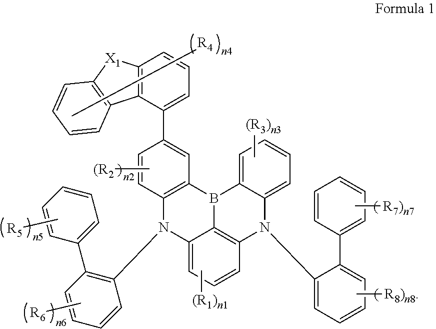

In Formula 1, X₁ may be NRₐ, CR_{b}R_{c}, O, or S, and R₁ to R₈ may each independently be hydrogen, deuterium, a halogen, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and

Rₐ to R_{c} may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring, n1 and n2 may each independently be an integer of 0 to 3, n3, n6, and n8 may each independently be an integer of 0 to 4, n4 is an integer of 0 to 7, and n5 and n7 may each independently be an integer of 0 to 5.

In one or more embodiments, the first compound represented by Formula 1 may be represented by any one selected from among Formula 2-1 to Formula 2-5:

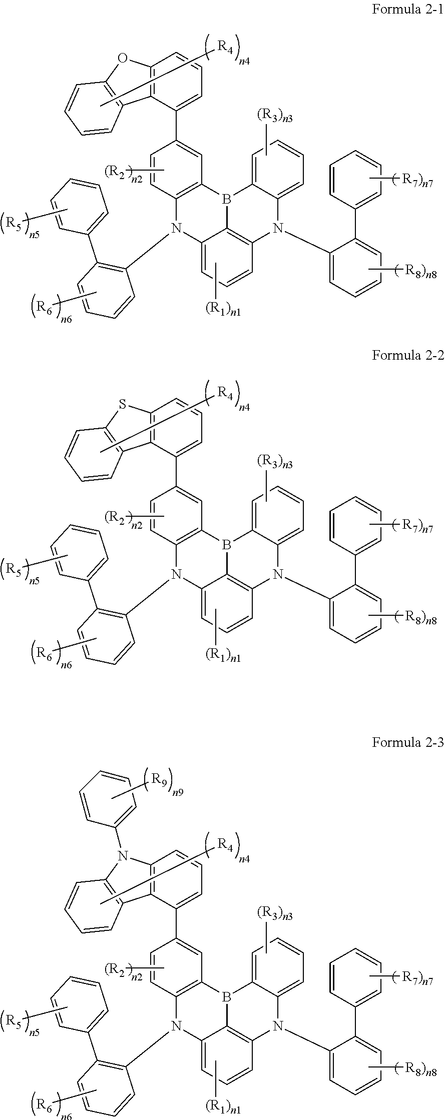

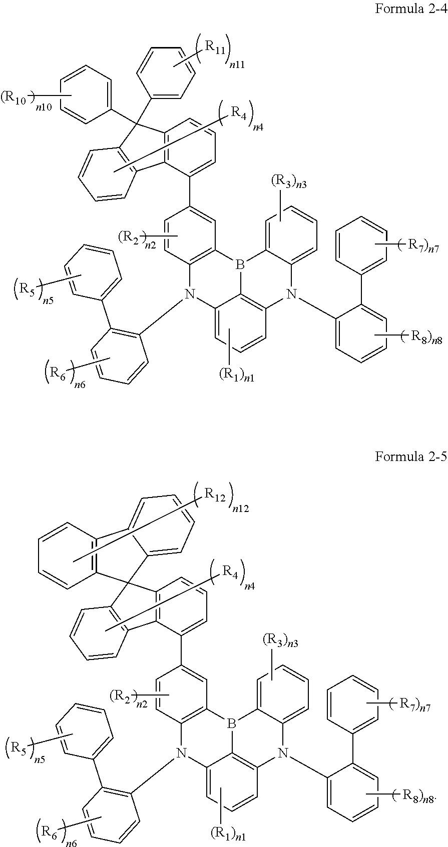

In Formula 2-1 to Formula 2-5, R₉ to R₁₂ may each independently be hydrogen, deuterium, a halogen, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, n9 to n11 may each independently be an integer of 0 to 5, and n12 is an integer of 0 to 8.

In Formula 2-1 to Formula 2-5, R₁ to R₈ and n1 to n8 may each be the same as defined in Formula 1.

In one or more embodiments, the first compound represented by Formula 1 may be represented by Formula 3-1 or Formula 3-2:

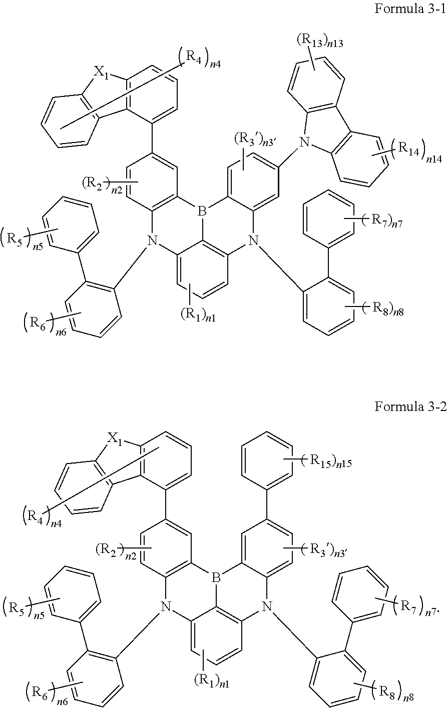

In Formula 3-1 and Formula 3-2, R₃′ may be hydrogen, deuterium, a halogen, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, R₁₃ to R₁₅ may each independently be hydrogen, deuterium, a halogen, a cyano group, a substituted or unsubstituted amine group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring, n3′ is an integer of 0 to 3, n13 and n14 may each independently be an integer of 0 to 4, and n15 is an integer of 0 to 5.

In Formula 3-1 and Formula 3-2, X₁, R₁, R₂, R₄ to R₈, n1, n2, and n4 to n8 may each be the same as defined in Formula 1.

In one or more embodiments, the first compound represented by Formula 1 may be represented by Formula 4:

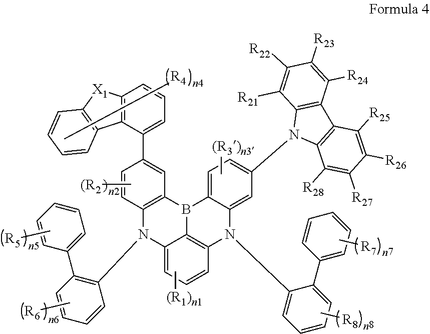

In Formula 4, R₃′ is hydrogen, deuterium, a halogen, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, R₂₁ to R₂₈ may each independently be hydrogen, deuterium, a halogen, a cyano group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring, at least one pair among adjacent pairs of R₂₁ to R₂₈ may be positions at which a substituent represented by Formula 4-A is fused, and n3′ is an integer of 0 to 3.

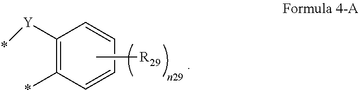

In Formula 4-A, Y is NR₃₀, O, or S, —* is a position which is fused to any adjacent one pair among R₂₁ to R₂₈ in Formula 4, R₂₉ and R₃₀ may each independently be hydrogen, deuterium, a halogen, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and n29 is an integer of 0 to 4.

In Formula 4, X₁, R₁, R₂, R₄ to R₈, n1, n2, and n4 to n8 may each be the same as defined in Formula 1.

In one or more embodiments, the first compound represented by Formula 1 may be represented by Formula 5:

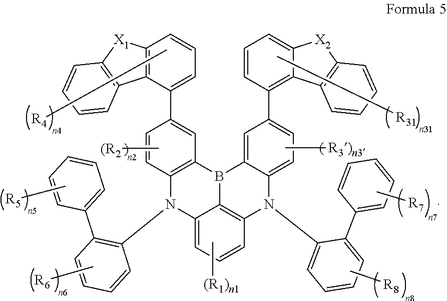

In Formula 5, X₂ is NR_{d}, CRₑR_{f}, O, or S, and R₃′ and R₃₁ may each independently be hydrogen, deuterium, a halogen, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and

R_{d} to R_{f} may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring, n3′ is an integer of 0 to 3, and n31 is an integer of 0 to 7.

In Formula 5 above, X₁, R₁, R₂, R₄ to R₈, n1, n2, and n4 to n8 may each be the same as defined in Formula 1.

In one or more embodiments, the first compound represented by Formula 5 may be represented by any one selected from among Formula 6-1 to Formula 6-5:

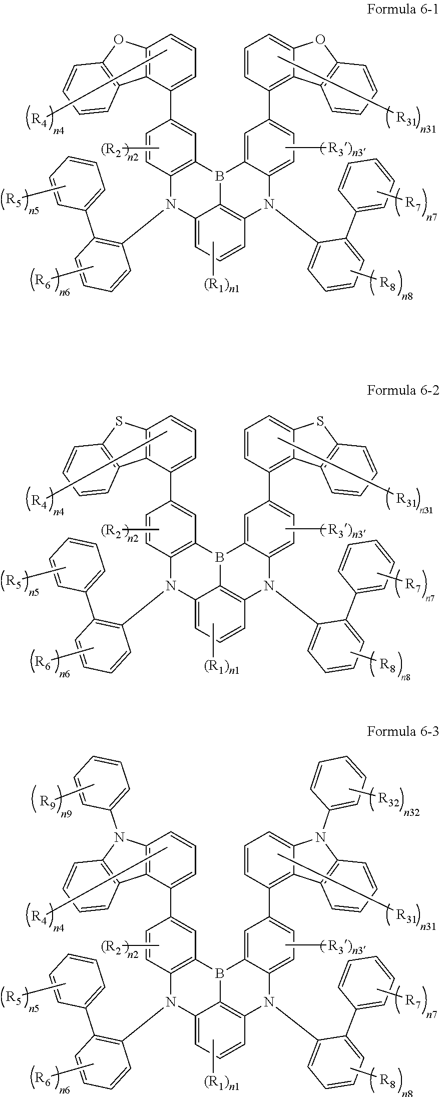

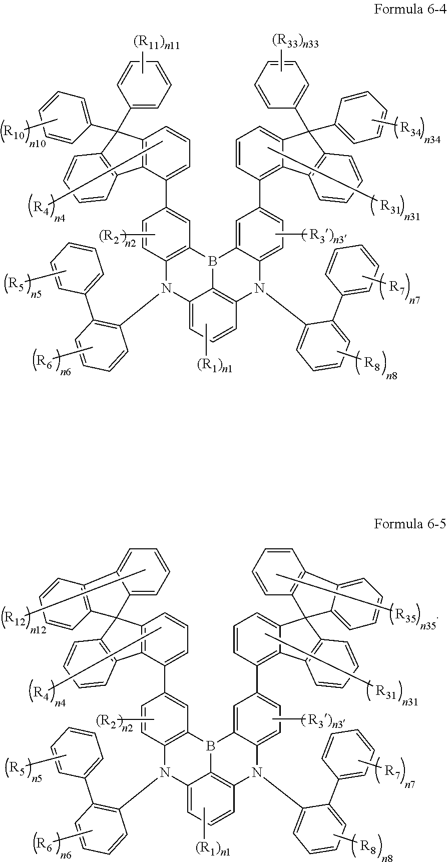

In Formula 6-1 to Formula 6-5, R₉ to R₁₂ and R₃₂ to R₃₅ may each independently be hydrogen, deuterium, a halogen, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, n9 to n11 and n32 to n34 may each independently be an integer of 0 to 5, and n12 and n35 may each independently be an integer of 0 to 8.

In Formula 6-1 to Formula 6-5, R₁, R₂, R₃′, R₄ to R₈, R₃₁, n1, n2, n3′, n4 to n8, and n31 may each be the same as defined in Formula 1 and Formula 5.

In one or more embodiments, the first compound represented by Formula 1 may be represented by Formula 7:

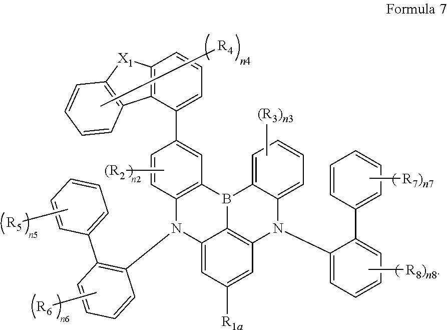

In Formula 7, R₁ₐ may be a substituted or unsubstituted alkyl group having 1 to 10 carbon atoms, or may be represented by any one selected from among Formula A-1 to Formula A-3:

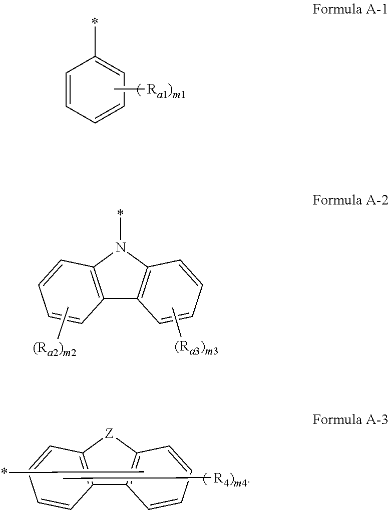

In Formula A-1 to Formula A-3, Z is NRₐ₅, O, or S, Rai to Rₐ₅ may each independently be hydrogen, deuterium, a halogen, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, m1 is an integer of 0 to 5, m2 and m3 may each independently be an integer of 0 to 4, and m4 is an integer of 0 to 7.

In Formula 7, X₁, R₂ to R₈, and n2 to n8 may each be the same as defined in Formula 1.

In one or more embodiments, the first compound represented by Formula 1 may be represented by Formula 8-1 or Formula 8-2:

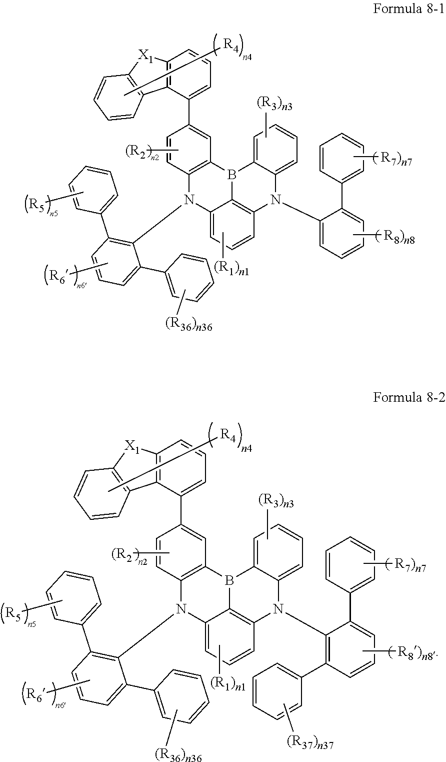

In Formula 8-1 and Formula 8-2 above, R₆′, R₈′, R₃₆, and R₃₇ may each independently be hydrogen, deuterium, a halogen, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, n6′ and n8′ may each independently be an integer of 0 to 3, and n36 and n37 may each independently be an integer of 0 to 5.

In Formula 8-1 and Formula 8-2, X₁, R₁ to R₅, R₇, R₈, n1 to n5, n7, and n8 may each be the same as defined in Formula 1.

In one or more embodiments, the emission layer may further include at least one of a second compound represented by Formula HT-1 or a third compound represented by Formula ET-1:

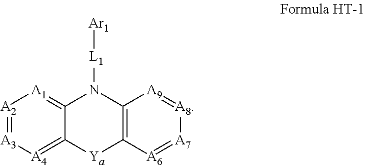

In Formula HT-1, A₁ to A₄, and A₆ to A₉ may each independently be N or CR₄₁, L₁ is a direct linkage, a substituted or unsubstituted arylene group having 6 to 30 ring-forming carbon atoms, or a substituted or unsubstituted heteroarylene group having 2 to 30 ring-forming carbon atoms, Yₐ is a direct linkage, CR₄₂R₄₃, or SiR₄₄R₄₅, Ar₁ is a substituted or unsubstituted aryl group having 6 to 30 ring-forming carbon atoms, or a substituted or unsubstituted heteroaryl group having 2 to 30 ring-forming carbon atoms, R₄₁ to R₄₅ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring.

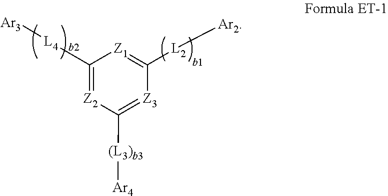

In Formula ET-1, at least one selected among Z₁ to Z₃ may be N, the rest may be CR₄₆, R₄₆ may be hydrogen, deuterium, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, b1 to b3 may each independently be an integer of 0 to 10, L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms, and Ar₂ to Ar₄ may each independently be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In one or more embodiments, the emission layer may further include a fourth compound represented by Formula D-1:

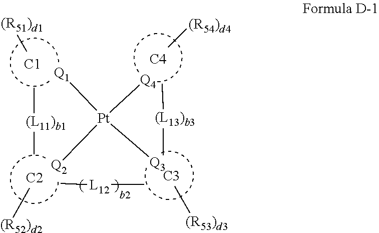

In Formula D-1, Q₁ to Q₄ may each independently be C or N, C1 to C4 may each independently be a substituted or unsubstituted hydrocarbon ring having 5 to 30 ring-forming carbon atoms, or a substituted or unsubstituted heterocycle having 2 to 30 ring-forming carbon atoms, L₁₁ to L₁₃ may each independently be a direct linkage,

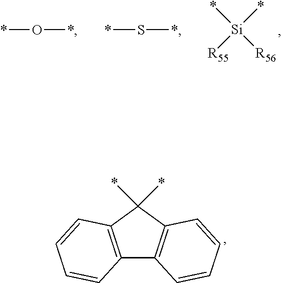

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, b1 to b3 may each independently be 0 or 1, R₅₁ to R₅₆ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and/or may be bonded to an adjacent group to form a ring, and d1 to d4 may each independently be an integer of 0 to 4.

In one or more embodiments of the present disclosure, a fused polycyclic compound may be represented by Formula 1.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure. Above and/or other aspects of the present disclosure should become apparent and appreciated from the following description of embodiments taken in conjunction with the accompanying drawings. In the drawings:

FIG. 1 is a plan view of a display apparatus according to one or more embodiments of the present disclosure;

FIG. 2 is a cross-sectional view of a display apparatus according to one or more embodiments of the present disclosure;

FIG. 3 is a cross-sectional view schematically illustrating a light emitting device according to one or more embodiments of the present disclosure;

FIG. 4 is a cross-sectional view schematically illustrating a light emitting device according to one or more embodiments of the present disclosure;

FIG. 5 is a cross-sectional view schematically illustrating a light emitting device according to one or more embodiments of the present disclosure;

FIG. 6 is a cross-sectional view schematically illustrating a light emitting device according to one or more embodiments of the present disclosure;

FIGS. 7 and 8 are cross-sectional views of display apparatuses according to one or more embodiments of the present disclosure;

FIG. 9 is a cross-sectional view illustrating a display apparatus according to one or more embodiments of the present disclosure; and

FIG. 10 is a cross-sectional view illustrating a display apparatus according to one or more embodiments of the present disclosure.

### DETAILED DESCRIPTION

The present disclosure may be modified in one or more suitable manners and have many forms, and thus specific embodiments will be exemplified in the drawings and described in more detail in the detailed description of the present disclosure. It should be understood, however, that it is not intended to limit the present disclosure to the particular forms disclosed, but rather, is intended to cover all modifications, equivalents, and alternatives falling within the spirit and scope of the present disclosure.

When explaining each of drawings, like reference numbers are utilized for referring to like elements. In the accompanying drawings, the dimensions of each structure are exaggeratingly illustrated for clarity of the present disclosure. It will be understood that, although the terms “first,” “second,” etc., may be utilized herein to describe one or more suitable elements, these elements should not be limited by these terms. These terms are only utilized to distinguish one element from another. For example, a first element could be termed a second element, and, similarly, a second element could be termed a first element, without departing from the scope of example embodiments of the present disclosure. The terms of a singular form may include plural forms unless the context clearly indicates otherwise.

In the present disclosure, it will be understood that the terms “comprise(s),” “include(s),” “have/has” and/or the like specify the presence of features, numbers, steps, operations, elements, parts, or combinations thereof disclosed in the specification, but do not exclude the possibility of presence or addition of one or more other features, numbers, steps, operations, elements, parts, or combinations thereof.

In the present disclosure, when a layer, a film, a region, or a plate is referred to as being “above” or “on an upper portion of” another layer, film, region, or plate, it can be not only “directly on” the layer, film, region, or plate, but intervening layers, films, regions, or plates may also be present. On the contrary to this, when a layer, a film, a region, or a plate is referred to as being “in a lower portion of” another layer, film, region, or plate, it can be not only directly under the layer, film, region, or plate, but intervening layers, films, regions, or plates may also be present. In some embodiments, it will be understood that when a part is referred to as being “on” another part, it can be disposed above the other part, or disposed under the other part as well. As used herein, the terms “and”, “or”, and “and/or” may include any and all combinations of one or more of the associated listed items. Expressions such as “at least one of,” “one of,” and “selected from,” when preceding a list of elements, modify the entire list of elements and do not modify the individual elements of the list. For example, “at least one of a, b, or c”, “at least one selected from a, b, and c”, “at least one selected from among a to c”, etc., may indicate only a, only b, only c, both (e.g., simultaneously) a and b, both (e.g., simultaneously) a and c, both (e.g., simultaneously) b and c, all of a, b, and c, or variations thereof. The “/” utilized herein may be interpreted as “and” or as “or” depending on the situation.

In the present disclosure, the term “substituted or unsubstituted” may refer to substituted or unsubstituted with at least one substituent selected from the group consisting of deuterium, a halogen, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In some embodiments, each of the substituents exemplified above may be substituted or unsubstituted. For example, a biphenyl group may be interpreted as an aryl group or a phenyl group substituted with a phenyl group.

In the present disclosure, the phrase “bonded to an adjacent group to form a ring” may refer to that one is bonded to an adjacent group to form a substituted or unsubstituted hydrocarbon ring, or a substituted or unsubstituted heterocycle. The hydrocarbon ring may include an aliphatic hydrocarbon ring and/or an aromatic hydrocarbon ring. The heterocycle may include an aliphatic heterocycle and/or an aromatic heterocycle. The hydrocarbon ring and the heterocycle may be monocyclic or polycyclic. In some embodiments, the rings formed by being bonded to each other may be connected to another ring to form a spiro structure.

In the present disclosure, the term “adjacent group” may refer to a substituent substituted for an atom which is directly linked to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. In some embodiments, two methyl groups in 4,5-dimethylphenanthrene may be interpreted as “adjacent groups” to each other.

In the present disclosure, examples of a halogen may include fluorine, chlorine, bromine, or iodine.

In the present disclosure, an alkyl group may be a linear, branched, or cyclic type or kind. The number of carbons in the alkyl group may be 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-heneicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments of the present disclosure are not limited thereto.

In the present disclosure, an alkenyl group may refer to a hydrocarbon group including at least one carbon-carbon double bond in the middle or terminal of an alkyl group having 2 or more carbon atoms. The alkenyl group may be linear or branched. The number of carbon atoms in the alkenyl group is not specifically limited, but may be 2 to 30, 2 to 20, or 2 to 10. Examples of the alkenyl group may include a vinyl group, a 1-butenyl group, a 1-pentenyl group, a 1,3-butadienyl aryl group, a styrenyl group, a styryl vinyl group, etc., but embodiments of the present disclosure are not limited thereto.

In the present disclosure, an alkynyl group may refer to a hydrocarbon group including at least one carbon-carbon triple bond in the middle or terminal of an alkyl group having 2 or more carbon atoms. The alkynyl group may be linear or branched. Although the number of carbon atoms in the alkynyl group is not specifically limited, it may be 2 to 30, 2 to 20, or 2 to 10. Examples of the alkynyl group may include an ethynyl group, a propynyl group, etc., without limitation.

In the present disclosure, a hydrocarbon ring group may refer to any functional group or substituent derived from an aliphatic hydrocarbon ring. The hydrocarbon ring group may be a saturated hydrocarbon ring group having 5 to 20 ring-forming carbon atoms.

In the present disclosure, an aryl group may refer to any functional group or substituent derived from an aromatic hydrocarbon ring. The aryl group may be a monocyclic aryl group or a polycyclic aryl group. The number of ring-forming carbon atoms in the aryl group may be 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments of the present disclosure are not limited thereto.

In the present disclosure, a fluorenyl group may be substituted, and two substituents may be bonded to each other to form a spiro structure. Examples of the substituted fluorenyl group may be as follows. However, embodiments of the present disclosure are not limited thereto.

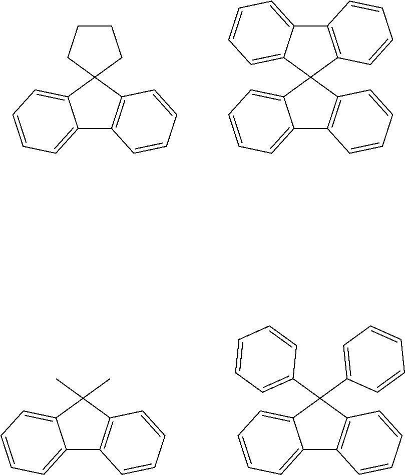

The heterocyclic group as utilized herein may refer to any functional group or substituent derived from a ring containing at least one of B, O, N, P, Si, or Se, as a heteroatom. The heterocyclic group may include an aliphatic heterocyclic group and an aromatic heterocyclic group. The aromatic heterocyclic group may be a heteroaryl group. The aliphatic heterocycle and the aromatic heterocycle may be monocyclic or polycyclic.

In the present disclosure, a heterocyclic group may contain at least one of B, O, N, P, Si or S, as a heteroatom. When the heterocyclic group contains two or more heteroatoms, the two or more heteroatoms may be the same or different. The heterocyclic group may be a monocyclic heterocyclic group or a polycyclic heterocyclic group and has the concept including a heteroaryl group. The number of ring-forming carbon atoms in the heterocyclic group may be 2 to 30, 2 to 20, or 2 to 10.

In the present disclosure, an aliphatic heterocyclic group may include at least one of B, O, N, P, Si, or S, as a heteroatom. The number of ring-forming carbon atoms in the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments of the present disclosure are not limited thereto.

In the present disclosure, a heteroaryl group may include at least one of B, O, N, P, Si, or S, as a heteroatom. When the heteroaryl group contains two or more heteroatoms, the two or more heteroatoms may be the same as or different from each other. The heteroaryl group may be a monocyclic heterocyclic group or a polycyclic heterocyclic group. The number of ring-forming carbon atoms in the heteroaryl group may be 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments of the present disclosure are not limited thereto.

In the present disclosure, the above description of the aryl group may be applied to an arylene group except that the arylene group is a divalent group. The above description of the heteroaryl group may be applied to a heteroarylene group except that the heteroarylene group is a divalent group.

In the present disclosure, a silyl group may include an alkylsilyl group and/or an arylsilyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments of the present disclosure are not limited thereto.

In the present disclosure, the number of ring-forming carbon atoms in a carbonyl group is not specifically limited, but may be 1 to 40, 1 to 30, or 1 to 20. For example, the carbonyl group may have the following structures, but embodiments of the present disclosure are not limited thereto.

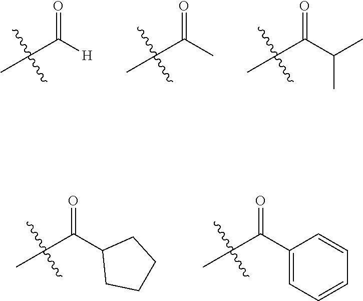

In the present disclosure, the number of carbon atoms in a sulfinyl group or a sulfonyl group is not particularly limited, but may be 1 to 30. The sulfinyl group may include an alkyl sulfinyl group and/or an aryl sulfinyl group. The sulfonyl group may include an alkyl sulfonyl group and/or an aryl sulfonyl group.

In the present disclosure, a thio group may include an alkylthio group and/or an arylthio group. The thio group may refer to that a sulfur atom is bonded to the alkyl group or the aryl group as defined above. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but embodiments of the present disclosure are not limited thereto.

In the present disclosure, an oxy group may refer to that an oxygen atom is bonded to the alkyl group or the aryl group as defined above. The oxy group may include an alkoxy group and/or an aryl oxy group. The alkoxy group may be a linear chain, a branched chain, or a ring chain. The number of carbon atoms in the alkoxy group is not specifically limited, but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, etc., but embodiments of the present disclosure are not limited thereto.

The boron group as utilized herein may refer to that a boron atom is bonded to the alkyl group or the aryl group as defined above. The boron group may include an alkyl boron group and/or an aryl boron group. Examples of the boron group may include a dimethylboron group, a trimethylboron group, a t-butyldimethylboron group, a diphenylboron group, a phenylboron group, etc., but embodiments of the present disclosure are not limited thereto.

In the present disclosure, an alkenyl group may be linear or branched. The number of carbon atoms in the alkenyl group is not specifically limited, but may be 2 to 30, 2 to 20, or 2 to 10. Examples of the alkenyl group may include a vinyl group, a 1-butenyl group, a 1-pentenyl group, a 1,3-butadienyl aryl group, a styrenyl group, a styryl vinyl group, etc., but embodiments of the present disclosure are not limited thereto.

In the present disclosure, the number of carbon atoms in an amine group is not specifically limited, but may be 1 to 30. The amine group may include an alkyl amine group and/or an aryl amine group. Examples of the amine group may include a methylamine group, a dimethylamine group, a phenylamine group, a diphenylamine group, a naphthylamine group, a 9-methyl-anthracenylamine group, a triphenylamine group, etc., but embodiments of the present disclosure are not limited thereto.

In the present disclosure, the alkyl group among an alkylthio group, an alkylsulfoxy group, an alkylaryl group, an alkylamino group, an alkyl boron group, an alkyl silyl group, and an alkyl amine group may be the same as the examples of the alkyl group described above.

In the present disclosure, the aryl group among an aryloxy group, an arylthio group, an arylsulfoxy group, an arylamino group, an arylboron group, an arylsilyl group, an arylamine group may be the same as the examples of the aryl group described above.

In the present disclosure, a direct linkage may refer to a single bond.

In some embodiments, in the present disclosure,

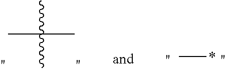

may refer to a position to be connected.

Hereinafter, embodiments of the present disclosure will be described in more detail with reference to the accompanying drawings.

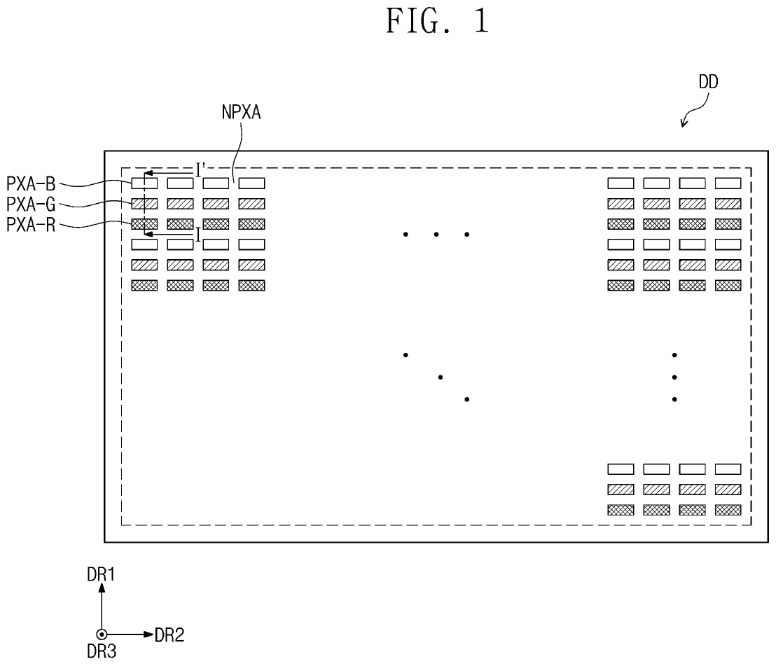

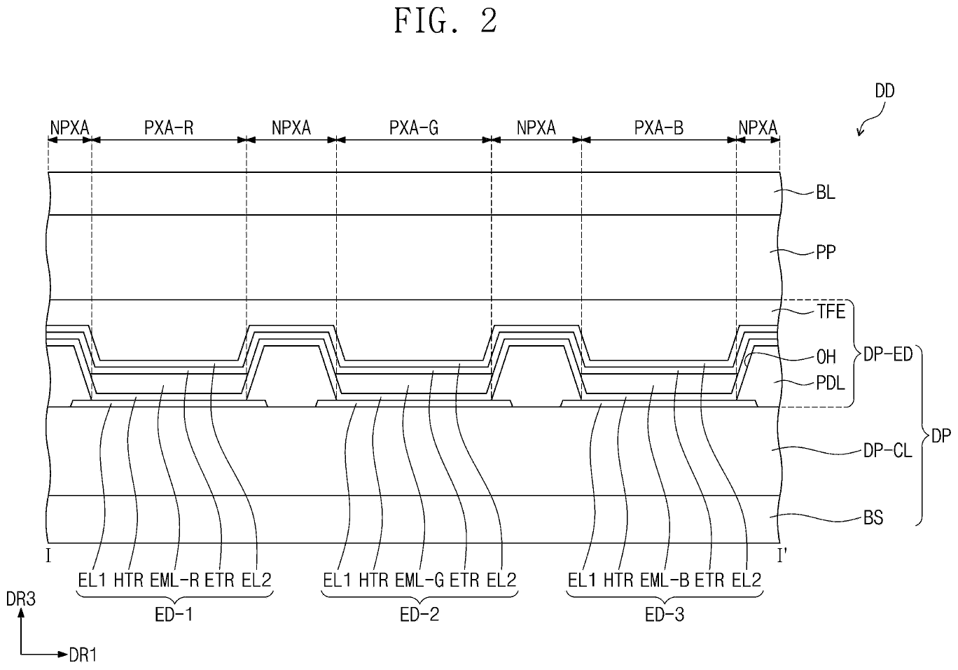

FIG. 1 is a plan view illustrating a display apparatus DD according to one or more embodiments. FIG. 2 is a cross-sectional view of the display apparatus DD according to one or more embodiments. FIG. 2 is a cross-sectional view illustrating a part taken along line I-I′ of FIG. 1.

The display apparatus DD may include a display panel DP and an optical layer PP disposed on the display panel DP. The display panel DP may include light emitting devices ED-1, ED-2, and ED-3. The display apparatus DD may include a plurality of light emitting devices ED-1, ED-2, and ED-3. The optical layer PP may be disposed on the display panel DP to control reflected light in the display panel DP due to external light. The optical layer PP may include, for example, a polarization layer or a color filter layer. In some embodiments, the optical layer PP may not be provided for the display apparatus DD.

A base substrate BL may be disposed on the optical layer PP. The base substrate BL may be a member which provides a base surface on which the optical layer PP disposed. The base substrate BL may be a glass substrate, a metal substrate, a plastic substrate, etc. However, embodiments of the present disclosure are not limited thereto, and the base substrate BL may be an inorganic layer, an organic layer, or a composite material layer. In some embodiments, the base substrate BL may not be provided.

The display apparatus DD according to one or more embodiments may further include a filling layer. The filling layer may be disposed between a display device layer DP-ED and the base substrate BL. The filling layer may be an organic material layer. The filling layer may include at least one of an acrylic-based resin, a silicone-based resin, or an epoxy-based resin.

The display panel DP may include a base layer BS, a circuit layer DP-CL provided on the base layer BS, and the display device layer DP-ED. The display device layer DP-ED may include a pixel defining film PDL, the light emitting devices ED-1, ED-2, and ED-3 disposed between portions of the pixel defining film PDL, and an encapsulation layer TFE disposed on the light emitting devices ED-1, ED-2, and ED-3.

The base layer BS may be a member which provides a base surface on which the display device layer DP-ED is disposed. The base layer BS may be a glass substrate, a metal substrate, a plastic substrate, etc. However, embodiments of the present disclosure are not limited thereto, and the base layer BS may be an inorganic layer, an organic layer, or a composite material layer.

In one or more embodiments, the circuit layer DP-CL may be disposed on the base layer BS, and the circuit layer DP-CL may include a plurality of transistors. Each of the transistors may include a control electrode, an input electrode, and an output electrode. For example, the circuit layer DP-CL may include a switching transistor and a driving transistor for driving the light emitting devices ED-1, ED-2, and ED-3 of the display device layer DP-ED.

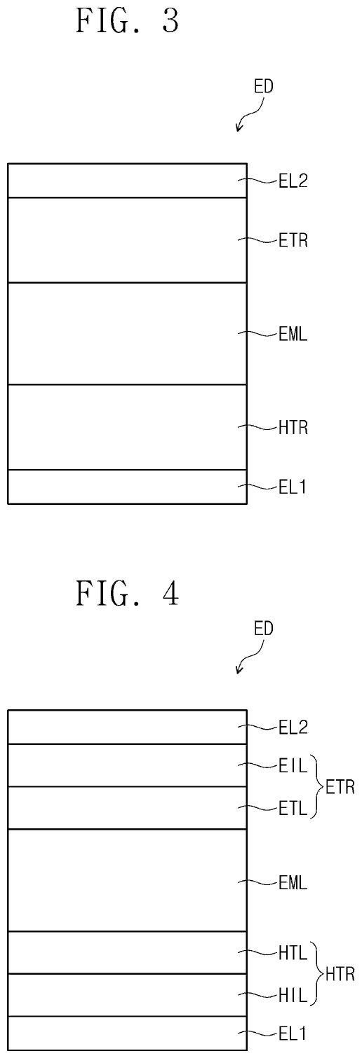

Each of the light emitting devices ED-1, ED-2, and ED-3 may have a structure of each light emitting device ED of embodiments according to FIGS. 3 to 6, which will be described later. Each of the light emitting devices ED-1, ED-2, and ED-3 may include a first electrode EL1, a hole transport region HTR, a respective or at least one selected from emission layers EML-R, EML-G, and EML-B, an electron transport region ETR, and a second electrode EL2.

FIG. 2 illustrates an embodiment in which the emission layers EML-R, EML-G, and EML-B of the light emitting devices ED-1, ED-2, and ED-3, respectively, are disposed in openings OH defined in the pixel defining film PDL, and the hole transport region HTR, the electron transport region ETR, and the second electrode EL2 are provided as a common layer throughout the entire light emitting devices ED-1, ED-2, and ED-3. However, embodiments of the present disclosure are not limited thereto, and unlike the configuration illustrated in FIG. 2, in one or more embodiments, the hole transport region HTR and the electron transport region ETR may be provided by being patterned inside the openings OH defined in the pixel defining film PDL. For example, in some embodiments, the hole transport region HTR, the respective emission layers EML-R, EML-G, and EML-B, and the electron transport region ETR of the light emitting devices ED-1, ED-2, and ED-3 may be provided by being patterned in an inkjet printing method.

The encapsulation layer TFE may cover the light emitting devices ED-1, ED-2, and ED-3. The encapsulation layer TFE may seal the display device layer DP-ED. The encapsulation layer TFE may be a thin film encapsulation layer. The encapsulation layer TFE may be formed by laminating one layer or a plurality of layers. The encapsulation layer TFE may include at least one insulation layer. The encapsulation layer TFE according to one or more embodiments may include at least one inorganic film (hereinafter, an encapsulation-inorganic film). The encapsulation layer TFE according to one or more embodiments may also include at least one organic film (hereinafter, an encapsulation-organic film) and at least one encapsulation-inorganic film.

The encapsulation-inorganic film protects the display device layer DP-ED from moisture/oxygen, and the encapsulation-organic film protects the display device layer DP-ED from foreign substances such as dust particles. The encapsulation-inorganic film may include silicon nitride, silicon oxynitride, silicon oxide, titanium oxide, aluminum oxide, and/or the like, but embodiments of the present disclosure are not particularly limited thereto. The encapsulation-organic film may include an acrylic-based compound, an epoxy-based compound, and/or the like. The encapsulation-organic film may include a photopolymerizable organic material, but embodiments of the present disclosure are not particularly limited thereto.

The encapsulation layer TFE may be disposed on the second electrode EL2 and may be disposed to fill the opening OH.

Referring to FIGS. 1 and 2, the display apparatus DD may include a non-light emitting region NPXA and light emitting regions PXA-R, PXA-G, and PXA-B. The light emitting regions PXA-R, PXA-G, and PXA-B may be regions in which light generated by the respective light emitting devices ED-1, ED-2, and ED-3 is emitted. The light emitting regions PXA-R, PXA-G, and PXA-B may be spaced apart from each other on a plane.

Each of the light emitting regions PXA-R, PXA-G, and PXA-B may be a region divided by the pixel defining film PDL. The non-light emitting areas NPXA may be areas between the adjacent light emitting areas PXA-R, PXA-G, and PXA-B, which correspond to the pixel defining film PDL. in the present disclosure, the light emitting regions PXA-R, PXA-G, and PXA-B may respectively correspond to pixels. The pixel defining film PDL may divide the light emitting devices ED-1, ED-2, and ED-3. In some embodiments, the respective emission layers EML-R, EML-G, and EML-B of the light emitting devices ED-1, ED-2, and ED-3 may be disposed in openings OH defined in the pixel defining film PDL and separated from each other.

The light emitting regions PXA-R, PXA-G, and PXA-B may be divided into a plurality of groups according to the color of light generated from the light emitting devices ED-1, ED-2, and ED-3. In the display apparatus DD illustrated in FIGS. 1 and 2, three light emitting regions PXA-R, PXA-G, and PXA-B, which emit red light, green light, and blue light, respectively, are exemplarily illustrated. For example, in some embodiments, the display apparatus DD may include a red light emitting region PXA-R, a green light emitting region PXA-G, and a blue light emitting region PXA-B that are separated from each other.

In the display apparatus DD according to one or more embodiments, the plurality of light emitting devices ED-1, ED-2, and ED-3 may be to emit light beams having wavelengths different from each other. For example, in one embodiment, the display apparatus DD may include a first light emitting device ED-1 that emits red light, a second light emitting device ED-2 that emits green light, and a third light emitting device ED-3 that emits blue light. For example, the red light emitting region PXA-R, the green light emitting region PXA-G, and the blue light emitting region PXA-B of the display apparatus DD may correspond to the first light emitting device ED-1, the second light emitting device ED-2, and the third light emitting device ED-3, respectively.

However, embodiments of the present disclosure are not limited thereto, and the first to third light emitting devices ED-1, ED-2, and ED-3 may be to emit light beams in substantially the same wavelength range or at least one light emitting device may be to emit a light beam in a wavelength range different from the others. For example, in some embodiments, the first to third light emitting devices ED-1, ED-2, and ED-3 may all emit blue light.

The light emitting regions PXA-R, PXA-G, and PXA-B in the display apparatus DD according to one or more embodiments may be arranged in a stripe form. Referring to FIG. 1, a plurality of red light emitting regions PXA-R may be arranged with each other along a second direction axis DR2, a plurality of green light emitting regions PXA-G may be arranged with each other along the second direction axis DR2, and a plurality of blue light emitting regions PXA-B may be arranged with each other along the second direction axis DR2. In some embodiments, the red light emitting region PXA-R, the green light emitting region PXA-G, and the blue light emitting region PXA-B may be alternately arranged in this order along a first directional axis DR1.

FIGS. 1 and 2 illustrate that all the light emitting regions PXA-R, PXA-G, and PXA-B have similar area, but embodiments of the present disclosure are not limited thereto. In some embodiments, the light emitting regions PXA-R, PXA-G, and PXA-B may have different areas from each other according to the wavelength range of the emitted light. The areas of the light emitting regions PXA-R, PXA-G, and PXA-B may refer to areas when viewed on a plane defined by the first directional axis DR1 and the second directional axis DR2.

In some embodiments, an arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in one or more suitable combinations according to the characteristics of display quality required in the display apparatus DD. For example, the arrangement form of the light emitting regions PXA-R, PXA-G, and PXA-B may be a pentile (PENTILE©) arrangement form (for example, an RGBG matrix, an RGBG structure, or an RGBG matrix structure) or a diamond (Diamond Pixel™) arrangement form (e.g., a display (e.g., an OLED display) containing red, blue, and green (RGB) light-emitting regions arranged in the shape of diamonds). PENTILE® is a duly registered trademark of Samsung Display Co., Ltd. Diamond Pixel™ is a trademark of Samsung Display Co., Ltd.

In some embodiments, the areas of the light emitting regions PXA-R, PXA-G, and PXA-B may be different from each other. For example, in some embodiments, the area of the green light emitting region PXA-G may be smaller than that of the blue light emitting region PXA-B, but embodiments of the present disclosure are not limited thereto.

Hereinafter, FIGS. 3 to 6 are cross-sectional views schematically illustrating light emitting devices according one or more embodiments. Each of the light emitting devices ED according to one or more embodiments may include a first electrode EL1, a hole transport region HTR, an emission layer EML, an electron transport region ETR, and a second electrode EL2 that are sequentially stacked.

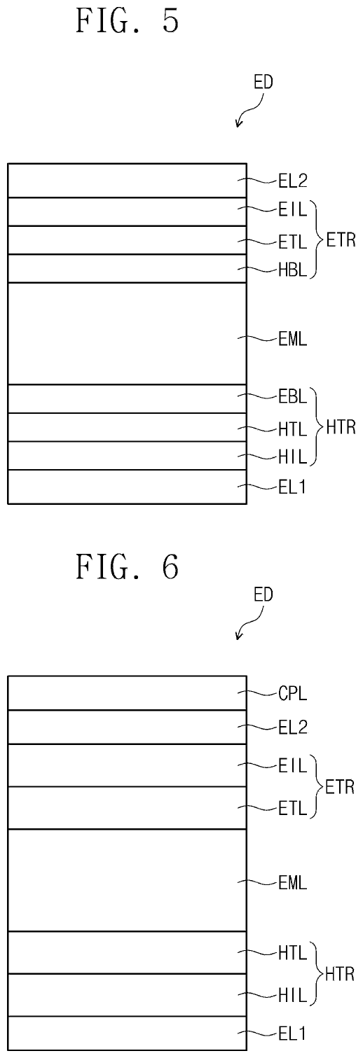

Compared with FIG. 3, FIG. 4 illustrates a cross-sectional view of a light emitting device ED according to one or more embodiments, in which a hole transport region HTR may include a hole injection layer HIL and a hole transport layer HTL, and an electron transport region ETR may include an electron injection layer EIL and an electron transport layer ETL. In some embodiments, compared with FIG. 3, FIG. 5 illustrates a cross-sectional view of a light emitting device ED, in which a hole transport region HTR may include a hole injection layer HIL, a hole transport layer HTL, and an electron blocking layer EBL, and an electron transport region ETR may include an electron injection layer EIL, an electron transport layer ETL, and a hole blocking layer HBL. Compared with FIG. 4, FIG. 6 illustrates a cross-sectional view of a light emitting device ED according to one or more embodiments including a capping layer CPL disposed on a second electrode EL2.

The first electrode EL1 has conductivity (e.g., is a conductor). The first electrode EL1 may be formed of a metal material, a metal alloy, or a conductive compound. The first electrode EL1 may be an anode or a cathode. However, embodiments of the present disclosure are not limited thereto. In some embodiments, the first electrode EL1 may be a pixel electrode. The first electrode EL1 may be a transmissive electrode, a transflective electrode, or a reflective electrode. The first electrode EL1 may include at least one selected from among silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), lithium fluoride (LiF), molybdenum (Mo), titanium (Ti), tungsten (W), indium (In), tin (Sn), and zink (Zn), a compound of two or more selected therefrom, a mixture of two or more selected therefrom, and/or an oxide thereof.

When the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). When the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound or mixture thereof (e.g., a mixture of Ag and Mg). In some embodiments, the first electrode EL1 may have a multilayer structure including a reflective film or a transflective film formed of the above-described materials, and a transparent conductive film formed of ITO, IZO, ZnO, ITZO, etc. For example, in some embodiments, the first electrode EL1 may have a three-layer structure of ITO/Ag/ITO, but embodiments of the present disclosure are not limited thereto. In some embodiments, the first electrode EL1 may include the above-described metal materials, combinations of at least two metal materials of the above-described metal materials, oxides of the above-described metal materials, and/or the like. The thickness of the first electrode EL1 may be from about 700 Å to about 10,000 Å. For example, in one or more embodiments, the thickness of the first electrode EL1 may be from about 1,000 Å to about 3,000 Å.

The hole transport region HTR may be provided on the first electrode EL1. The hole transport region HTR may include at least one of a hole injection layer HIL, a hole transport layer HTL, a buffer layer or an emission-auxiliary layer, or an electron blocking layer EBL. The thickness of the hole transport region HTR may be, for example, from about 50 Å to about 15,000 Å.

The hole transport region HTR may have a single layer formed of a single material, a single layer formed of a plurality of different materials, or a multilayer structure including a plurality of layers formed of a plurality of different materials.

For example, in one or more embodiments, the hole transport region HTR may have a single layer structure of the hole injection layer HIL or the hole transport layer HTL, or may have a single layer structure formed of a hole injection material and a hole transport material. In some embodiments, the hole transport region HTR may have a single layer structure formed of a plurality of different materials, or a structure in which a hole injection layer HIL/hole transport layer HTL, a hole injection layer HIL/hole transport layer HTL/buffer layer, a hole injection layer HIL/buffer layer, a hole transport layer HTL/buffer layer, or a hole injection layer HIL/hole transport layer HTL/electron blocking layer EBL are stacked in order (e.g., in the stated order) from the first electrode EL1, but embodiments of the present disclosure are not limited thereto.

The hole transport region HTR may be formed utilizing one or more suitable methods such as a vacuum deposition method, a spin coating method, a casting method, a Langmuir-Blodgett (LB) method, an inkjet printing method, a laser printing method, and/or a laser induced thermal imaging (LITI) method.

The hole transport region HTR may include a compound represented by Formula H-2:

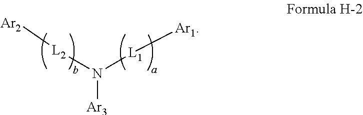

In Formula H-2, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. a and b may each independently be an integer of 0 to 10. In some embodiments, when a or b is an integer of 2 or greater, a plurality of Li(s) and L₂(s) may each independently be a substituted or unsubstituted arylene group having 6 to 30 ring-forming carbon atoms, or a substituted or unsubstituted heteroarylene group having 2 to 30 ring-forming carbon atoms.

In Formula H-2, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. In some embodiments, in Formula H-2, Ar₃ may be a substituted or unsubstituted aryl group having 6 to 30 ring-forming carbon atoms, or a substituted or unsubstituted heteroaryl group having 2 to 30 ring-forming carbon atoms.

The compound represented by Formula H-2 may be a monoamine compound. In some embodiments, the compound represented by Formula H-2 may be a diamine compound in which at least one selected from among Ar₁ to Ar₃ includes the amine group as a substituent. In some embodiments, the compound represented by Formula H-2 may be a carbazole-based compound including a substituted or unsubstituted carbazole group in at least one of Ar₁ or Ar₂, or a fluorene-based compound including a substituted or unsubstituted fluorene group in at least one of Ar₁ or Ar₂.

The compound represented by Formula H-2 may be represented by any one selected from among the compounds of Compound Group H. However, the compounds listed in Compound Group H are mere examples, and the compounds represented by Formula H-2 are not limited to those represented by Compound Group H:

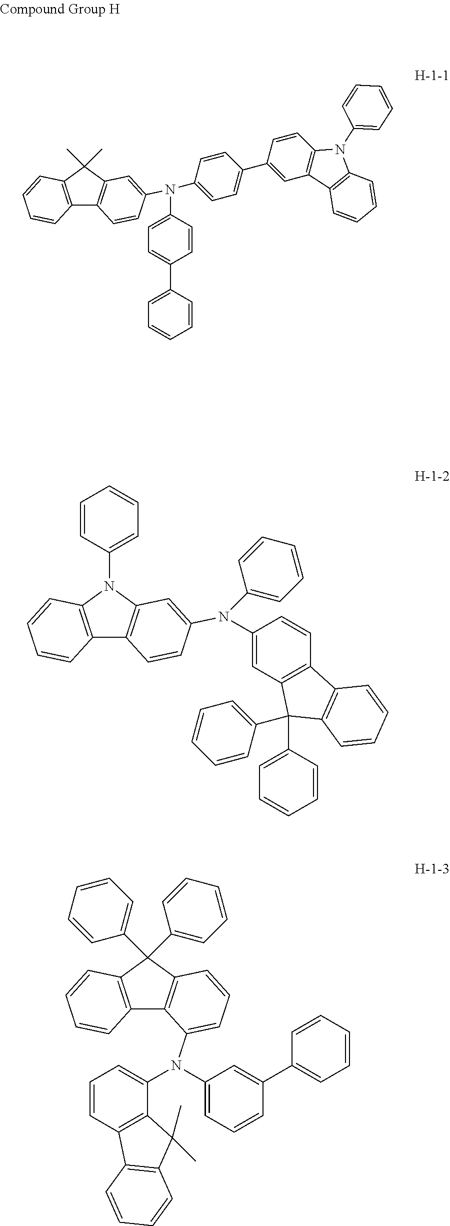 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

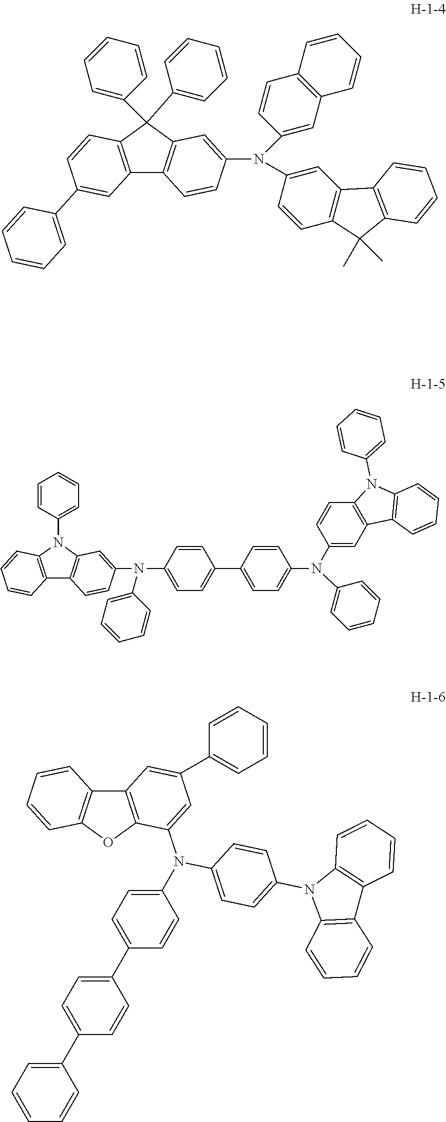 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

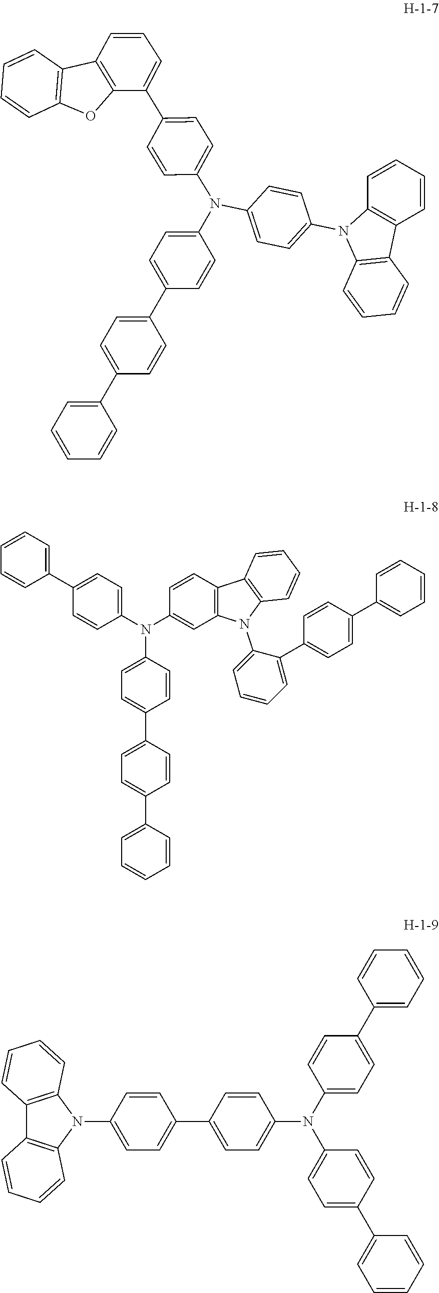 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

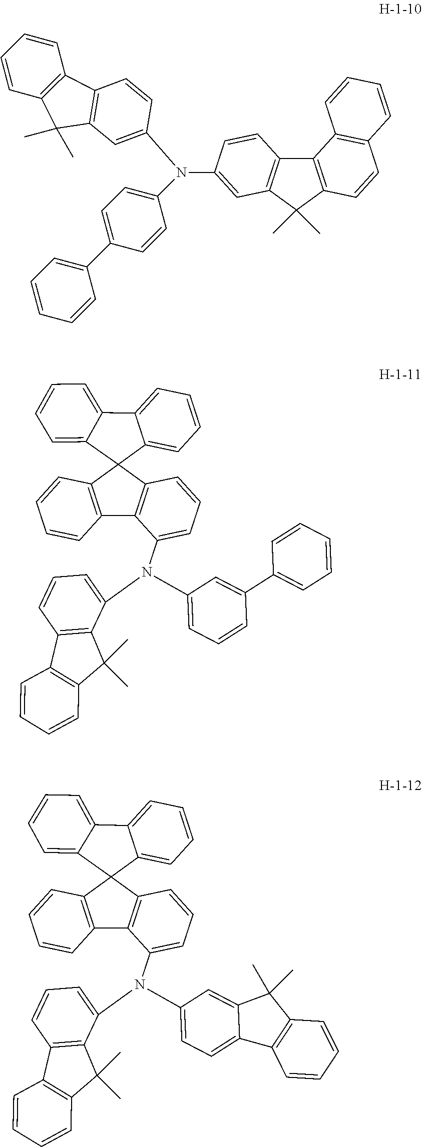 [SMILES: CC1(C)c2ccccc2-c2ccc(N(c3ccc(-c4ccccc4)cc3)c3ccc4c(c3)C(C)(C)c3ccc5ccccc5c3-4)cc21 ; CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21]

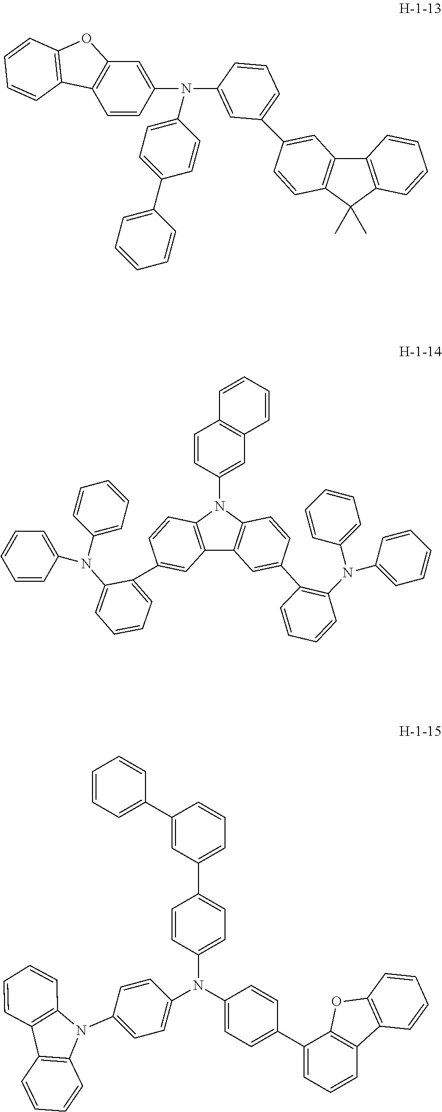 [SMILES: CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

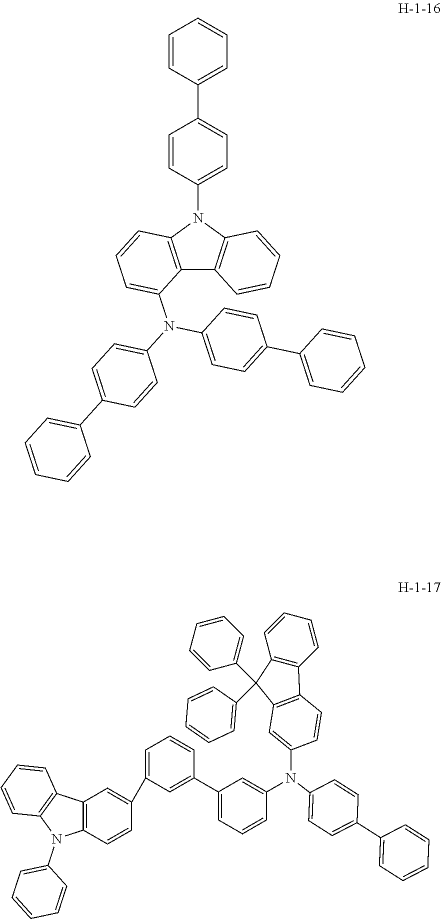 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1]

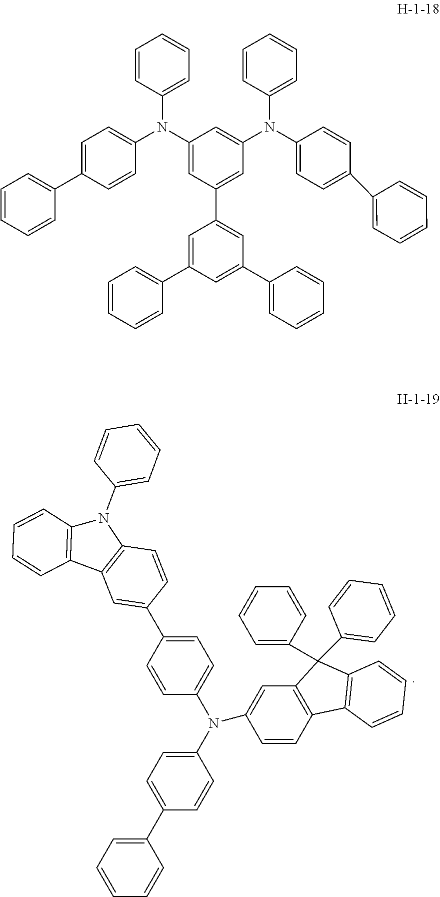 [SMILES: c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine, N¹,N¹′-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

The hole transport region HTR may include a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), etc.

In some embodiments, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region in at least one of a hole injection layer HIL, a hole transport layer HTL, or an electron blocking layer EBL.

The thickness of the hole transport region HTR may be from about 100 Å to about 10,000 Å, for example, from about 100 Å to about 5,000 Å. When the hole transport region HTR includes the hole injection layer HIL, the hole injection layer HIL may have, for example, a thickness of about 30 Å to about 1,000 Å. When the hole transport region HTR includes the hole transport layer HTL, the hole transport layer HTL may have a thickness of about 250 Å to about 1,000 Å. For example, when the hole transport region HTR includes the electron blocking layer EBL, the electron blocking layer EBL may have a thickness of about 10 Å to about 1,000 Å. When the thicknesses of the hole transport region HTR, the hole injection layer HIL, the hole transport layer HTL, and the electron blocking layer EBL satisfy the above-described ranges, satisfactory hole transport properties may be achieved without a substantial increase in driving voltage.

The hole transport region HTR may further include a charge generating material to increase conductivity in addition to the above-described materials. The charge generating material may be dispersed uniformly or non-uniformly in the hole transport region HTR. The charge generating material may be, for example, a p-dopant. The p-dopant may include at least one of a halogenated metal compound, a quinone derivative, a metal oxide, or a cyano group-containing compound, but embodiments of the present disclosure are not limited thereto. For example, in some embodiments, the p-dopant may include a metal halide compound such as CuI or RbI, a quinone derivative such as tetracyanoquinodimethane (TCNQ) or 2,3,5,6-tetrafluoro-7,7,8,8-tetracyanoquinodimethane (F4-TCNQ), a metal oxide such as tungsten oxide or molybdenum oxide, a cyano group-containing compound such as dipyrazino[2,3-f: 2′,3′-h]quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments of the present disclosure are not limited thereto.

As described above, the hole transport region HTR may further include at least one of the buffer layer or the electron blocking layer EBL in addition to the hole injection layer HIL and the hole transport layer HTL. The buffer layer may compensate for a resonance distance according to the wavelength of light emitted from the emission layer EML and may thus increase light emission efficiency. A material that may be included in the hole transport region HTR may be utilized as a material to be included in the buffer layer. The electron blocking layer EBL is a layer that serves to prevent or reduce the electron injection from the electron transport region ETR to the hole transport region HTR.

The emission layer EML may be provided on the hole transport region HTR. The emission layer EML may have a thickness of, for example, about 100 Å to about 1,000 Å, or about 100 Å to about 300 Å. The emission layer EML may have a single layer formed of a single material, a single layer formed of a plurality of different materials, or a multilayer structure having a plurality of layers formed of a plurality of different materials.

In one or more embodiments, the emission layer EML in the light emitting device ED may include a fused polycyclic compound of present disclosure. In one or more embodiments, the emission layer EML may include the fused polycyclic compound of the present disclosure as a dopant. The fused polycyclic compound of one or more embodiments of the present disclosure may be a dopant material of the emission layer EML. In some embodiments, the fused polycyclic compound of the present disclosure, which will be described later, may be referred to as a first compound.

The fused polycyclic compound of one or more embodiments may include a structure in which a plurality of aromatic rings are fused via a boron atom and a nitrogen atom. For example, the fused polycyclic compound of one or more embodiments may include a structure in which first to third aromatic rings are fused via one boron atom, a first nitrogen atom, and a second nitrogen atom. The first to third aromatic rings each may be linked to the boron atom, the first aromatic ring and the second aromatic ring may be linked via the first nitrogen atom, and the first aromatic ring and the third aromatic ring may be linked via the second nitrogen atom. in the present disclosure, the boron atom and the first and second nitrogen atoms, and the first to third aromatic rings which are fused via the boron atom and the first and second nitrogen atoms may be referred to as “fused ring core.”

The fused polycyclic compound of one or more embodiments may include a first substituent linked to a fused ring core. In one or more embodiments, the first substituent may be a substituted or unsubstituted dibenzoheterole group, a substituted or unsubstituted carbazole group, or a substituted or unsubstituted fluorenyl group. The first substituent may be linked to the second aromatic ring of the fused ring core at the fourth carbon position of the first substituent. The first substituent may be directly bonded to the second aromatic ring. The first substituent may be linked at the para-position with the first nitrogen atom of the fused ring core. For example, carbon at position 4 of the first substituent may be linked to the second aromatic ring at the para-position carbon, with respect to the first nitrogen atom, among carbon atoms constituting the second aromatic ring. The first substituent may be linked to the fused ring core at the fourth carbon position of the first substituent, and thus may have an increase in multiple resonance effects. Thus, the linking position of the first substituent and the fused ring core is specified, and accordingly the fused polycyclic compound of one or more embodiments may achieve high efficiency and a long service life when applied to the light emitting device.

The numbers of carbon atoms constituting the first substituent may be represented by Formula S1:

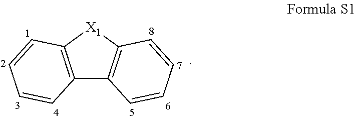

With respect to the carbon numbering of the first substituent, in the embodiment in which the first substituent is disposed such that X₁ is disposed on the top of the first substituent like Formula S1, the numbers are assigned in a counterclockwise direction starting from the carbon atom, at the ortho-position with X₁, from among the carbon atoms constituting the left benzene ring, and the carbon number at the condensation position is excluded. In some embodiments, for convenience of description, substituents linked to benzene rings at both (e.g., simultaneously) sides in Formula S1 are omitted. In some embodiments, unlike Formula S1, the first substituent may have at least one substituent in addition to hydrogen. However, embodiments of the present disclosure are not limited thereto.

In Formula S1, X₁ is NRₐ, CR_{b}R_{c}, O, or S. In Formula S1, Rₐ to R_{c} may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In Formula S1, when X₁ is NRₐ, the first substituent may be a substituted carbazole group. In Formula S1, when X₁ is CR_{b}R_{c}, the first substituent may be a substituted fluorenyl group. In Formula S1, when X₁ is 0, the first substituent may be a substituted or unsubstituted dibenzofuran group. In Formula S1, when X₁ is S, the first substituent may be a substituted or unsubstituted dibenzothiophene group.

The fused polycyclic compound of one or more embodiments may include a second substituent and a third substituent, each of which is a steric hindrance substituent in the molecular structure. The second substituent and the third substituent may be respectively linked to the first nitrogen atom and the second nitrogen atom constituting the fused ring core in the fused polycyclic compound of one or more embodiments. The second substituent and the third substituent may each independently be a substituent which includes a benzene moiety and in which a substituted or unsubstituted phenyl group is introduced into a carbon at a specific position of the benzene moiety. For example, the second substituent may be linked to the first nitrogen atom constituting the fused ring core, and include a structure in which a substituted or unsubstituted phenyl group is introduced into at least one of two ortho positions with respect to the first nitrogen atom. The third substituent may be linked to the second nitrogen atom constituting the fused ring core, and include a structure in which a substituted or unsubstituted phenyl group is introduced into at least one of two ortho positions with respect to the second nitrogen atom.

The fused polycyclic compound of one or more embodiments may be represented by Formula 1:

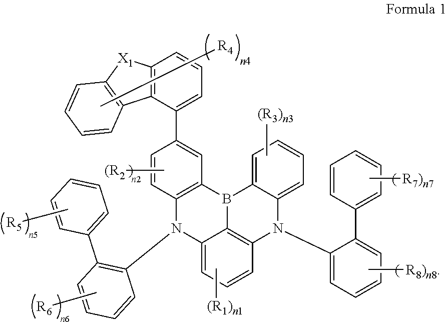

The fused polycyclic compound represented by Formula 1 of one or more embodiments may include a structure in which three aromatic rings are fused via one boron atom and two nitrogen atoms. The benzene ring, which is substituted with the substituent represented by R₁, may correspond to the aforementioned first aromatic ring, the benzene ring, which is substituted with a substituent represented by R₂, may correspond to the aforementioned second aromatic ring, and the benzene ring, which is substituted with a substituent represented by R₃, may correspond to the aforementioned third aromatic ring. In some embodiments, in Formula 1, the heterocycle containing X₁ as a ring-forming atom may correspond to the aforementioned first substituent.

In Formula 1, X₁ may be NRₐ, CR_{b}R_{c}, O, or S.

In Formula 1, R₁ to R₈ may each independently be hydrogen, deuterium, halogen, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in some embodiments, R₁ to R₈ may each independently be hydrogen, a substituted or unsubstituted t-butyl group, a substituted or unsubstituted phenyl group, a substituted or unsubstituted biphenyl group, a substituted or unsubstituted terphenyl group, a substituted or unsubstituted carbazole group, a substituted or unsubstituted dibenzofuran group, a substituted or unsubstituted dibenzothiophene group, a substituted or unsubstituted fluorenyl group, a substituted or unsubstituted benzofurocarbazole group, or a substituted or unsubstituted benzothiocarbazole group.

In Formula 1, Rₐ to R_{c} may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In some embodiments, each of Rₐ to R_{c} may be bonded to an adjacent group to form a ring. For example, in some embodiments, Rₐ to R_{c} may each independently be a substituted or unsubstituted phenyl group. In some embodiments, R_{b} and R_{c} may be bonded to each other to form a ring. In Formula 1, when X₁ is CR_{b}R_{c}, R_{b} and R_{c} may be substituted or unsubstituted phenyl groups, and R_{b} and R_{c} may be bonded to each other to form a ring and/or form a spiro structure. However, embodiments of the present disclosure are not limited thereto.

In Formula 1, n1 and n2 may each independently be an integer of 0 to 3, n3, n6, and n8 may each independently be an integer of integer of 0 to 4, and n4 is an integer of 0 to 7, and n5 and n7 may each independently be an integer of 0 to 5.

In Formula 1, when each of n1 and n2 is 0, the fused polycyclic compound of one or more embodiments may not be substituted with each of R₁ and R₂. In Formula 1, embodiments in which each of n1 and n2 is 3 and R₁(s) and R₂(s) are each hydrogen may be the same as embodiments in which each of n1 and n2 is 0 in Formula 1. When each of n1 and n2 is an integer of 2 or more, a plurality of R₁(s) and R₂(s) may each be the same or at least one selected from among the plurality of R₁(s) and R₂(s) may be different from the others.

In Formula 1, When each of n3, n6, and n8 is 0, the fused polycyclic compound of one or more embodiments may not be substituted with each of R₃, R₆, and R₈. In Formula 1, embodiments in which each of n3, n6, and n8 is 4 and R₃(s), R₆(s), and R₈(s) are each hydrogen may be the same as embodiments where each of n3, n6, and n8 is 0 in Formula 1. When each of n3, n6, and n8 is an integer of 2 or more, a plurality of R₃(s), R₆(s), and R₈(s) may each be the same or at least one selected from among the plurality of R₃(s), R₆(s), and R₈(s) may be different from the others.

In Formula 1, when n4 is 0, the fused polycyclic compound of one or more embodiments may not be substituted with R₄. In Formula 1, embodiments in which n4 is 7 and R₄(s) are all hydrogen may be the same as embodiments in which n4 is 0 in Formula 1. When n4 is an integer of 2 or more, a plurality of R₄(s) may all be the same, or at least one selected from among the plurality of R₄(s) may be different from the others.

In Formula 1, when each of n5 and n7 is 0, the fused polycyclic compound of one or more embodiments may not be substituted with each of R₅ and R₇. In Formula 1, embodiments in which each of n5 and n7 is 5 and R₅(s) and R₇(s) are each hydrogen may be the same as embodiments in which each of n5 and n7 is 0 in Formula 1. When each of n5 and n7 is an integer of 2 or more, a plurality of R₅(s) and R₇(s) may each be the same or at least one selected from among the plurality of R₅(s) and R₇(s) may be different from the others.

In one or more embodiments, the first compound represented by Formula 1 may be represented by any one selected from among Formula 2-1 to Formula 2-5:

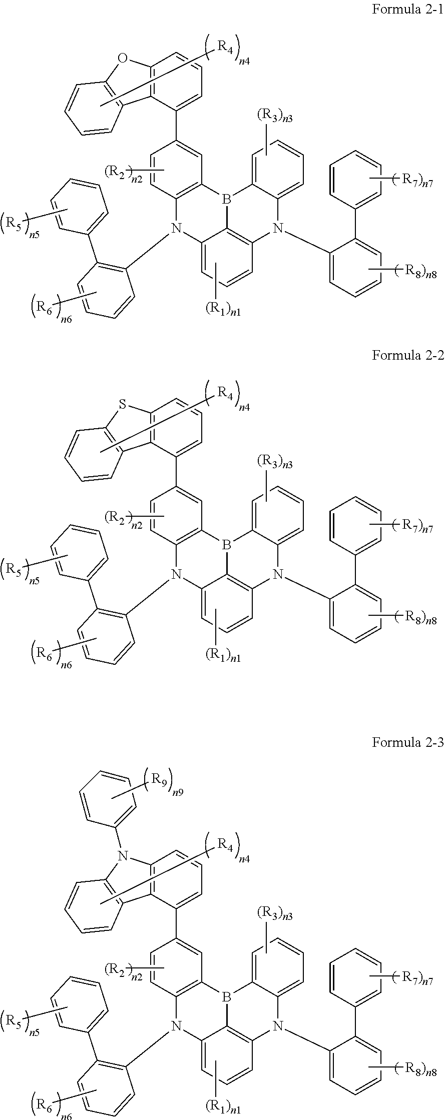

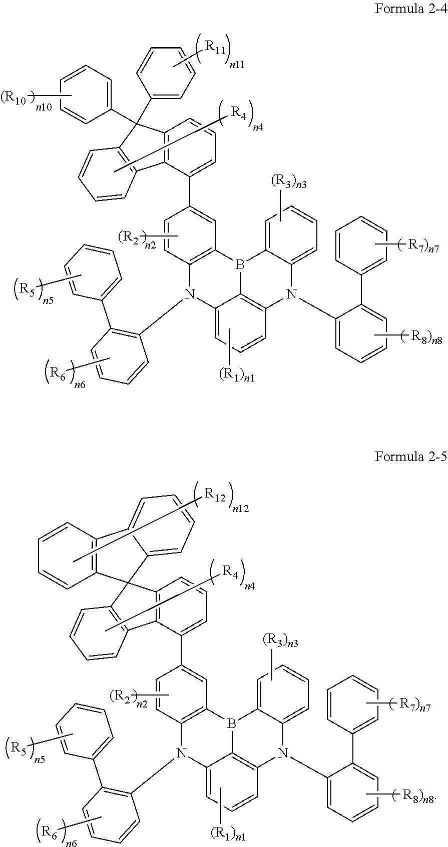

Formula 2-1 to Formula 2-5 represent embodiments in which the types (kinds) of X₁ are specified in Formula 1. For example, Formula 2-1 to Formula 2-5 represent the embodiments in which the types (kinds) of the first substituent in the fused polycyclic compound of one or more embodiments are specified. Formula 2-1 represents embodiments in which the first substituent may be a substituted or unsubstituted dibenzofuran group. Formula 2-2 represents embodiments in which the first substituent may be a substituted or unsubstituted dibenzothiophene group. Formula 2-3 represents embodiments in which the first substituent may be a substituted carbazole group. Formula 2-4 and Formula 2-5 each represent the embodiments in which the first substituent may be a substituted fluorenyl group.

In Formula 2-3 to Formula 2-5, R₉ to R₁₂ may each independently be hydrogen, deuterium, a halogen, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in some embodiments, R₉ to R₁₂ may each independently be hydrogen.

In Formula 2-3 and Formula 2-4, n9 to n11 may each independently be an integer of 0 to 5. In Formula 2-3 and Formula 2-4, when each of n9 to n11 is 0, the fused polycyclic compound of one or more embodiments may not be substituted with each of R₉ to R₁₁. In Formula 2-3 and Formula 2-4, embodiments in which each of n9 to n11 is 5 and R₉(s) to R₁₁(s) are each hydrogen may be the same as embodiments in which each of n9 to n11 is 0 in Formula 2-3 and Formula 2-4. When each of n9 to n11 is an integer of 2 or more, a plurality of R₉(s) to R₁₁(s) may each be the same or at least one selected from among the plurality of R₉(s) to R₁₁(s) may be different from the others.

In Formula 2-5, n12 is an integer of 0 to 8. In Formula 2-5, when n12 is 0, the fused polycyclic compound of one or more embodiments may not be substituted with R₁₂. In Formula 2-5, embodiments in which n12 is 8 and R₁₂(s) are all hydrogen may be the same as embodiments in which n12 is 0 in Formula 2-5. When n12 is an integer of 2 or more, a plurality of R₁₂(s) may all be the same, or at least one selected from among the plurality of R₁₂(s) may be different from the others.

In Formula 2-1 to Formula 2-5, R₁ to R₈ and n1 to n8 may each be the same as described in Formula 1.

In one or more embodiments, the first compound represented by Formula 1 may be represented by Formula 3-1 or Formula 3-2:

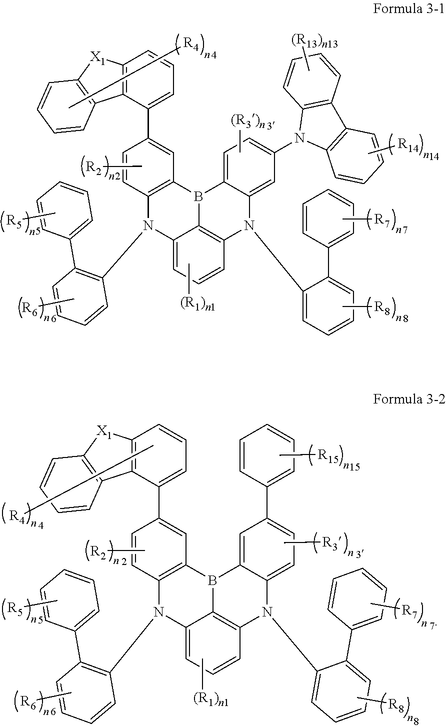

Formula 3-1 and Formula 3-2 represent embodiments in which the types (kinds) and substituted positions of R₃ are specified in Formula 1. Formula 3-1 represents embodiments in which the substituent represented by R₃ in Formula 1 is a substituted or unsubstituted carbazole group, and substituted at the para-position with the boron atom. Formula 3-2 represents embodiments in which the substituent represented by R₃ in Formula 1 is a substituted or unsubstituted phenyl group, and substituted at the para-position with the second nitrogen atom.

In Formula 3-1 and Formula 3-2, R₃′ may be hydrogen, deuterium, a halogen, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in some embodiments, R₃′ may be hydrogen.

In Formula 3-1 and Formula 3-2, R₁₃ to R₁₅ may each independently be hydrogen, deuterium, a halogen, a cyano group, a substituted or unsubstituted amine group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In some embodiments, each of R₁₃ to R₁₅ may be bonded to an adjacent group to form a ring. For example, in some embodiment, R₁₃ to R₁₅ may each independently be hydrogen, deuterium, a cyano group, a substituted or unsubstituted methyl group, a substituted or unsubstituted isopropyl group, a substituted or unsubstituted t-butyl group, a substituted or unsubstituted phenyl group, a substituted or unsubstituted aryloxy group, or a substituted or unsubstituted arylthio group.

In Formula 3-1 and Formula 3-2, n3′ is an integer of 0 to 3. In Formula 3-1 and Formula 3-2, when n3′ is 0, the fused polycyclic compound of one or more embodiments may not be substituted with R₃′. In Formula 3-1 and Formula 3-2, embodiments in which n3′ is 3 and R₃′(s) are all hydrogen may be the same as embodiments in which n3′ is 0 in Formula 3-1 and Formula 3-2. When n3′ is an integer of 2 or more, a plurality of R₃′(s) may all be the same, or at least one of the plurality of R₃′(s) may be different from the others.

In Formula 3-1, n13 and n14 may each independently be an integer of 0 to 4. In Formula 3-1, when each of n13 and n14 is 0, the fused polycyclic compound of one or more embodiments may not be substituted with each of R₁₃ and R₁₄. In Formula 3-1, embodiments in which each of n13 and n14 is 4 and R₁₃(s) and R₁₄(s) are each hydrogen may be the same as embodiments in which each of n13 and n14 is 0 in Formula 3-1. When each of n13 and n14 is an integer of 2 or more, a plurality of R₁₃(s) and R₁₄(s) may each be the same or at least one selected from among the plurality of R₁₃(s) and R₁₄(s) may be different from the others.

In Formula 3-2, n15 is an integer of 0 to 5. In Formula 3-2, when n15 is 0, the fused polycyclic compound of one or more embodiments may not be substituted with R₁₅. In Formula 3-2, embodiments in which n15 is 5 and R₁₅(s) are all hydrogen may be the same as embodiments in which n15 is 0 in Formula 3-2. When n15 is an integer of 2 or more, a plurality of R₁₅(s) may all be the same, or at least one selected from among the plurality of R₁₅(s) may be different from the others.

In Formula 3-1 to Formula 3-2, X₁, R₁, R₂, R₄ to R₈, n1, n2, and n4 to n8 may each be the same as described in Formula 1.

In one or more embodiments, the first compound represented by Formula 1 may be represented by Formula 4:

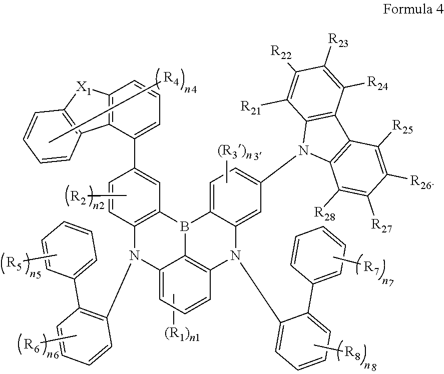

Formula 4 represents embodiments in which the type or kind and substituted position of R₃ are specified in Formula 1.

In Formula 4, R₃′ may be hydrogen, deuterium, a halogen, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in some embodiments, R₃′ may be hydrogen.

In Formula 4, n3′ is an integer of 0 to 3. In Formula 4, when n3′ is 0, the fused polycyclic compound of one or more embodiments may not be substituted with R₃′. In Formula 4, embodiments in which n3′ is 3 and R₃′(s) are all hydrogen may be the same as embodiments in which n3′ is 0 in Formula 4. When n3′ is an integer of 2 or more, a plurality of R₃′(s) may all be the same, or at least one of the plurality of R₃′(s) may be different from the others.

In Formula 4, R₂₁ to R₂₈ may each independently be hydrogen, deuterium, a halogen, a cyano group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In some embodiments, each of R₂₁ to R₂₈ may be bonded to an adjacent group to form a ring. For example, in some embodiments, R₂₁ to R₂₈ may each independently be hydrogen, deuterium, a cyano group, a substituted or unsubstituted methyl group, a substituted or unsubstituted t-butyl group, a substituted or unsubstituted phenyl group, a substituted or unsubstituted aryloxy group, or a substituted or unsubstituted arylthio group.

At least one pair selected from among adjacent pairs of R₂₁ to R₂₈ may be positions at which a substituent represented by Formula 4-A is fused. In one or more embodiments, one pair selected from among adjacent pairs of R₂₁ to R₂₈ may be positions at which a substituent represented by Formula 4-A is fused.

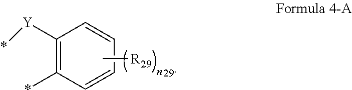

In Formula 4-A, Y may be NR₃₀, O, or S. For example, in some embodiments, Y may be O or S.

In Formula 4-A, —* may be a position at which Formula 4-A is fused to any one adjacent pair selected from among R₂₁ to R₂₈ in Formula 4.

In Formula 4-A, R₂₉ and R₃₀ may each independently be hydrogen, deuterium, a halogen, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in some embodiments, R₂₉ may be hydrogen. R₃₀ may be a substituted or unsubstituted phenyl group.

In Formula 4-A, n29 is an integer of 0 to 4. In Formula 4-A, when n29 is 0, the substituent represented by Formula 4-A may not be substituted with R₂₉. In Formula 4-A, embodiments in which n29 is 4 and R₂₉(s) are all hydrogen may be the same as embodiments in which n29 is 0 in Formula 4-A. When n29 is an integer of 2 or more, a plurality of R₂₉(s) may all be the same, or at least one selected from among the plurality of R₂₉(s) may be different from the others.

In Formula 4, X₁, R₁, R₂, R₄ to R₈, n1, n2, and n4 to n8 may each be the same as described in Formula 1.

In one or more embodiments, the first compound represented by Formula 4 may be represented by any one selected from among Formula 4-1 to Formula 4-4:

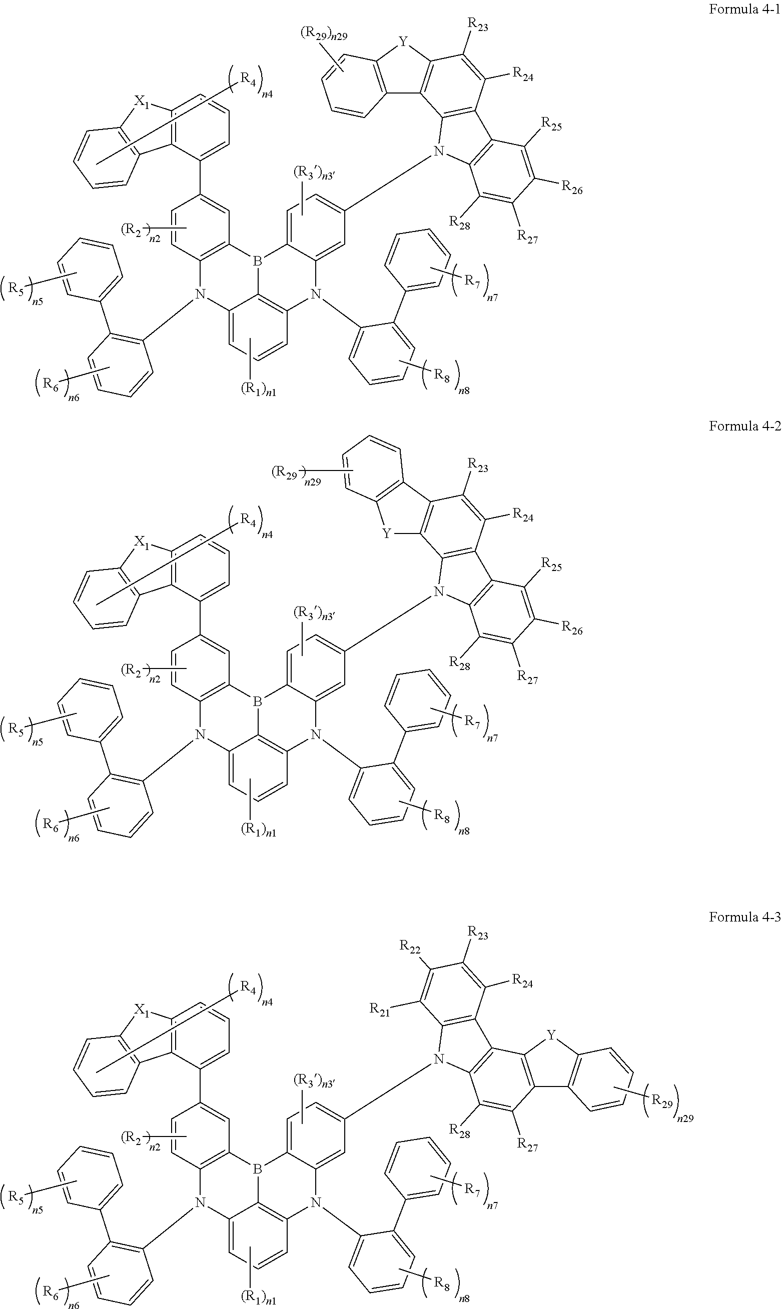

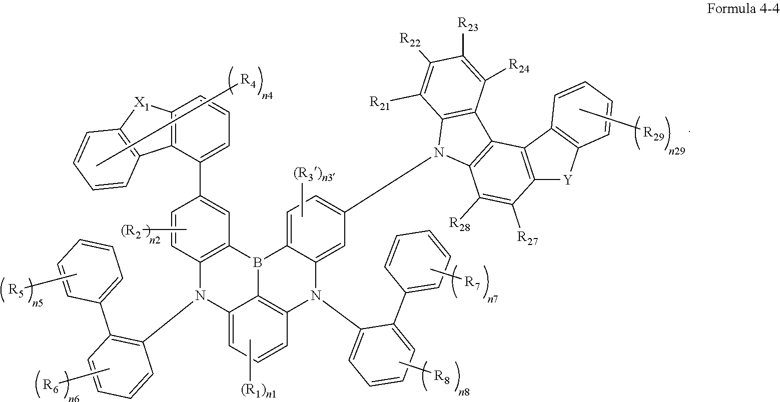

Formula 4-1 to Formula 4-4 represent that substituents represented by Formula 4-A may be fused in Formula 4.

In Formula 4-1 to Formula 4-4, X₁, R₁, R₂, R₄ to R₈, n1, n2, and n4 to n8 may each be the same as described in Formula 1. In Formula 4-1 to Formula 4-4, R₃′ and n3′ may each be the same as described in Formula 4. In Formula 4-1 to Formula 4-4, Y, R₂₉, and n29 may each be the same as described in Formula 4-A.

The fused polycyclic compound of one or more embodiments may further include a fourth substituent. In one or more embodiments, the fourth substituent may be a substituted or unsubstituted dibenzoheterole group, a substituted or unsubstituted carbazole group, or a substituted or unsubstituted fluorenyl group. The fourth substituent may be linked to the third aromatic ring of the fused ring core at the fourth carbon position of the fourth substituent. The fourth substituent may be directly bonded to the third aromatic ring. The fourth substituent may be linked at the para-position with the second nitrogen atom of the fused ring core. For example, in some embodiments, carbon at position 4 of the fourth substituent may be linked to the third aromatic ring at the para-position carbon, with respect to the second nitrogen atom, among carbon atoms constituting the third aromatic ring. The fourth substituent may be linked at the fourth carbon position to the fused ring core, and thus may have an increase in multiple resonance effects. Thus, the linking position of the fourth substituent and the fused ring core is specified, and accordingly the fused polycyclic compound of one or more embodiments may achieve high efficiency and a long service life when applied to the light emitting device.

The numbers of carbon atoms constituting the fourth substituent are represented by Formula S2:

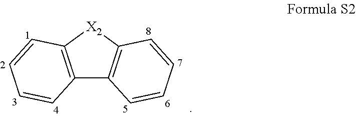

With respect to the carbon numbering of the fourth substituent, in embodiments in which the fourth substituent is disposed such that X₂ is disposed on the top of the fourth substituent like Formula S2, the numbers are assigned in a counterclockwise direction starting from the carbon atom, at the ortho-position with X₂, from among the carbon atoms constituting the left benzene ring, and the carbon number at the condensation position is excluded. In some embodiments, for convenience of description, substituents linked to benzene rings at both (e.g., simultaneously) sides in Formula S2 are omitted. In some embodiments, unlike Formula S1, the fourth substituent may have at least one substituent. However, embodiments of the present disclosure are not limited thereto.

In Formula S2, X₂ is NR_{d}, CRₑR_{f}, O, or S. In Formula S2, R_{d} to R_{f} may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In Formula S2, when X₂ is NR_{d}, the fourth substituent may be a substituted carbazole group. In Formula S2, when X₂ is CRₑR_{f}, the fourth substituent may be a substituted fluorenyl group. In Formula S2, when X₂ is 0, the fourth substituent may be a substituted or unsubstituted dibenzofuran group. In Formula S2, when X₂ is S, the fourth substituent may be a substituted or unsubstituted dibenzothiophene group.

In one or more embodiments, the first compound represented by Formula 1 may be represented by Formula 5:

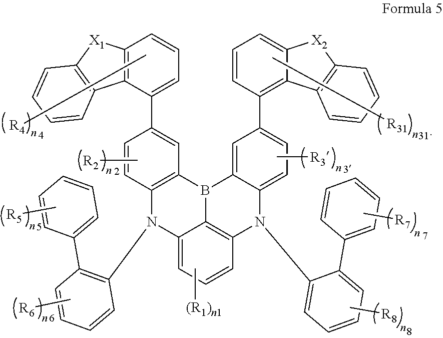

In Formula 5, the heterocycle containing X₂ as a ring-forming atom may correspond to the aforementioned fourth substituent.

In Formula 5, X₂ may be NR_{d}, CRₑR_{f}, O, or S.

In Formula 5, R₃′ and R₃₁ may each independently be hydrogen, deuterium, a halogen, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in some embodiments, R₃′ and R₃₁ may each independently be hydrogen.

In Formula 5, R_{d} to R_{f} may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In some embodiments, each of R_{d} to R_{f} may be bonded to an adjacent group to form a ring. For example, in some embodiments, R_{d} to R_{f} may each independently be a substituted or unsubstituted phenyl group. In some embodiments, Rₑ and R_{f} may be bonded to each other to form a ring. For example, in Formula 2, when X₂ is CRₑR_{f} and each of Rₑ and R_{f} is a substituted or unsubstituted phenyl group, Rₑ and R_{f} may be bonded to each other to form a spiro structure. However, embodiments of the present disclosure are not limited thereto.

In Formula 5, n3′ is an integer of 0 to 3. In Formula 5, when n3′ is 0, the fused polycyclic compound of one or more embodiments may not be substituted with R₃′. In Formula 5, embodiments in which n3′ is 3 and R₃′(s) are all hydrogen may be the same as embodiments in which n3′ is 0 in Formula 5. When n3′ is an integer of 2 or more, a plurality of R₃′(s) may all be the same, or at least one of the plurality of R₃′(s) may be different from the others.

In Formula 5, n31 is an integer of 0 to 7. In Formula 5, when n31 is 0, the fused polycyclic compound of one or more embodiments may not be substituted with R₃₁. In Formula 5, embodiments in which n31 is 7 and R₃₁(s) are all hydrogen may be the same as embodiments in which n31 is 0 in Formula 5. When n31 is an integer of 2 or more, a plurality of R₃₁(s) may all be the same, or at least one of the plurality of R₃₁(s) may be different from the others.

In Formula 5, X₁, R₁, R₂, R₄ to R₈, n1, n2, and n4 to n8 may each be the same as described in Formula 1.

In one or more embodiments, the first compound represented by Formula 5 may be represented by any one selected from among Formula 6-1 to Formula 6-5:

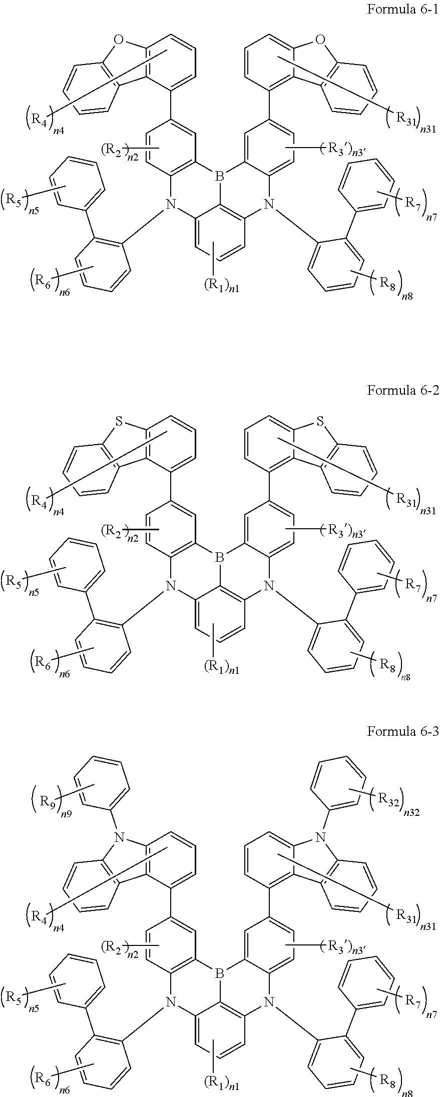

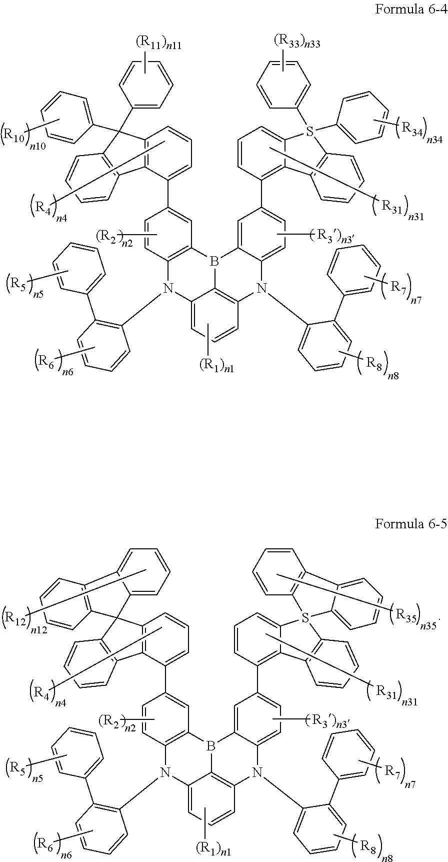

Formula 6-1 to Formula 6-5 represent embodiments in which the types (kinds) of X₂ are specified in Formula 5.

In Formula 6-3 to Formula 6-5, R₉ to R₁₂ and R₃₂ to R₃₅ may each independently be hydrogen, deuterium, a halogen, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in some embodiments, R₉ to R₁₂, and R₃₂ to R₃₅ may each independently be hydrogen.

In Formula 6-3 and Formula 6-4, n9 to n11, and n32 to n34 may each independently be an integer of 0 to 5. In Formula 6-3 and Formula 6-4, when each of n9 to n11 and n32 to n34 is 0, the fused polycyclic compound of one or more embodiments may not be substituted with each of R₉ to R₁₁, R₃₂ to R₃₄. In Formula 6-3 and Formula 6-4, embodiments in which each of n9 to n11 and n32 to n34 is 5 and R₉(s) to R₁₁(s) and R₃₂(s) to R₃₄(s) are each hydrogen may be the same as embodiments in which each of n9 to n11 and n32 to n34 is 0 in Formula 6-3 and Formula 6-4. When each of n9 to n11 and n32 to n34 is an integer of 2 or more, a plurality of R₉(s) to R₁₁(s), and R₃₂(s) to R₃₄(s) may each be the same or at least one selected from among the plurality of R₉(s) to R₁₁(s), and R₃₂(s) to R₃₄(s) may be different from the others.

In Formula 6-5, n12 and n35 may each independently be an integer of 0 to 8. In Formula 6-5, when each of n12 and n35 is 0, the fused polycyclic compound of an embodiment may not be substituted with each of R₁₂ and R₃₅. In Formula 6-5, embodiments in which each of n12 and n35 is 8 and R₁₂(s) and R₃₅(s) are each hydrogen may be the same as embodiments in which each of n12 and n35 is 0 in Formula 6-5. When each of n12 and n35 is an integer of 2 or more, a plurality of R₁₂(s) and R₃₅(s) may each be the same or at least one selected from among the plurality of R₁₂(s) and R₃₅(s) may be different from the others.

In Formula 6-1 to Formula 6-5, R₁, R₂, R₃′, R₄ to R₈, R₃₁, n1, n2, n3′, n4 to n8, and n31 may each be the same as described in Formula 1 and Formula 5.

In one or more embodiments, the first compound represented by Formula 1 may be represented by Formula 7:

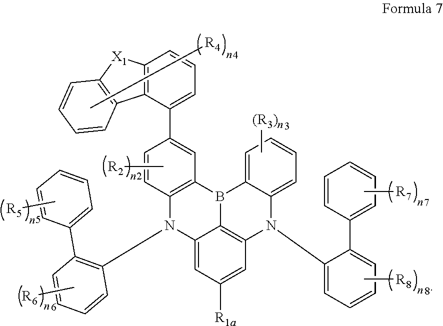

In Formula 7, R₁ₐ may be a substituted or unsubstituted alkyl group having 1 to 10 carbon atoms, or may be represented by any one selected from among Formula A-1 to Formula A-3:

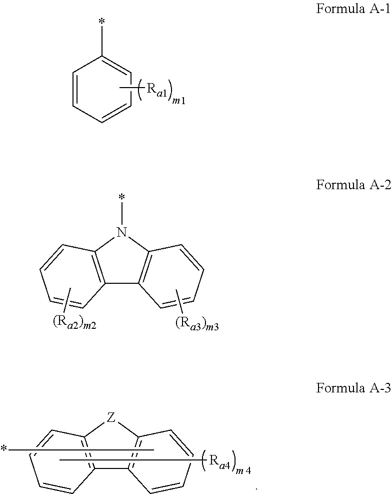

In Formula A-1 to Formula A-3, Z may be NRₐ₅, O, or S.

In Formula A-1 to Formula A-3, Rai to Rₐ₅ may each independently be hydrogen, deuterium, a halogen, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in some embodiments, Rₐ₁ to Rₐ₅ may each independently be hydrogen, deuterium, a cyano group, a substituted or unsubstituted t-butyl group, or a substituted or unsubstituted phenyl group.

In Formula A-1, m1 is an integer of 0 to 5. In Formula A-1, when m1 is 0, the substituent represented by Formula A-1 may not be substituted with Rₐ₁. In Formula A-1, embodiments in which m1 is 5 and Rₐ₁(s) are all hydrogen may be the same as embodiments in which m1 is 0 in Formula A-1. When m1 is an integer of 2 or more, a plurality of Rₐ₁(s) may all be the same, or at least one of the plurality of Rₐ₁(s) may be different from the others.

In Formula A-2, m2 and m3 may each independently be an integer of 0 to 4. In Formula A-2, when each of m2 and m3 is 0, the substituent represented by Formula A-2 may not be substituted with each of Rₐ₂ and Rₐ₃. In Formula A-2, embodiments in which each of m2 and m3 is 4 and Rₐ₂(s) and Rₐ₃(s) are each hydrogen may be the same as embodiments in which each of m2 and m3 is 0 in Formula A-2. When each of m2 and m3 is an integer of 2 or more, a plurality of Rₐ₂(s) and Rₐ₃(s) may each be the same or at least one selected from among the plurality of Rₐ₂(s) and Rₐ₃(s) may be different from the others.

In Formula A-3, m4 is an integer of 0 to 7. In Formula A-3, when m4 is 0, the substituent represented by Formula A-3 may not be substituted with Rₐ₄. In Formula A-3, embodiments in which m4 is 7 and Rₐ₄(s) are all hydrogen may be the same as embodiments in which m4 is 0 in Formula A-3. When m4 is an integer of 2 or more, a plurality of Rₐ₄(s) may be all the same or at least one selected from among the plurality of Rₐ₄(s) may be different from the others.

In Formula 7, X₁, R₂ to R₈, and n2 to n8 may each be the same as described in Formula 1.

In one or more embodiments, the first compound represented by Formula 1 may be represented by Formula 7-1:

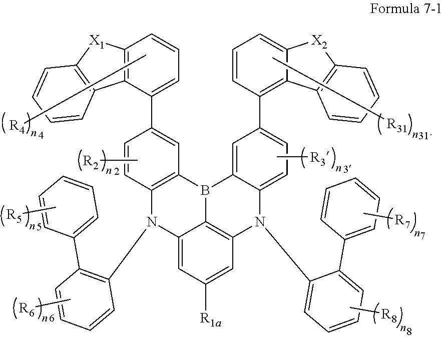

In Formula 7-1, X₁, R₂, R₄ to R₈, n2, and n4 to n8 may each be the same as described in Formula 1. In some embodiments, X₂, R₃′, R₃₁, n3′, and n31 may each be the same as described in Formula 5. R₁ₐ may be the same as described in Formula 7.

In the fused polycyclic compound of one or more embodiments, the second substituent linked to the first nitrogen atom may include a structure in which a substituted or unsubstituted phenyl group is introduced to at least one selected from among two ortho-positions with respect to the first nitrogen atom in the benzene moiety. In some embodiments, the third substituent linked to the second nitrogen atom may include a structure in which a substituted or unsubstituted phenyl group is introduced to at least one selected from among two ortho-positions with respect to the second nitrogen atom in the benzene moiety. The fused polycyclic compound of one or more embodiments having such a structure may effectively maintain a trigonal planar structure of the boron atom through the steric hindrance effect due to the second substituent and the third substituent. The boron atom may have electron deficiency characteristics by an empty p-orbital, thereby forming a bond with other nucleophiles, and thus being changed into a tetrahedral structure, which may cause deterioration of the device. According to the present disclosure, the fused polycyclic compound of one or more embodiments has the second substituent and the third substituent introduced at the fused ring core, thereby being able to effectively protect the empty p-orbital of the boron atom, and thus preventing or reducing the deterioration phenomenon due to the structural change.

In addition, the fused polycyclic compound of one or more embodiments may have an improvement in luminous efficiency and service life characteristics because the intermolecular interaction may be suppressed or reduced by the second substituent and the third substituent, thereby suppressing the formation of aggregation, excimer, and/or exciplex. The fused polycyclic compound of one or more embodiments includes the second substituent and the third substituent in which an additional substituent is introduced at a specific position, thus the intermolecular distance increases, and thereby having an effect of reducing exciton quenching such as Dexter energy transfer. The Dexter energy transfer is a phenomenon, in which a triplet exciton moves between molecules, and increasing when the intermolecular distance is short, and may become a factor that increases a quenching phenomenon due to the increase of triplet concentration. According to the present disclosure, the fused polycyclic compound of one or more embodiments has an increase in the distance between adjacent molecules due to the large steric hindrance structure to suppress or reduce the Dexter energy transfer, and thus may suppress or reduce the deterioration of service life due to the increase of triplet concentration. Therefore, when the fused polycyclic compound of one or more embodiments is applied to the emission layer EML of the light emitting device ED, the luminous efficiency may be increased, and the device service life may also be improved.

In one or more embodiments, the first compound represented by Formula 1 may be represented by Formula 8-1 or Formula 8-2:

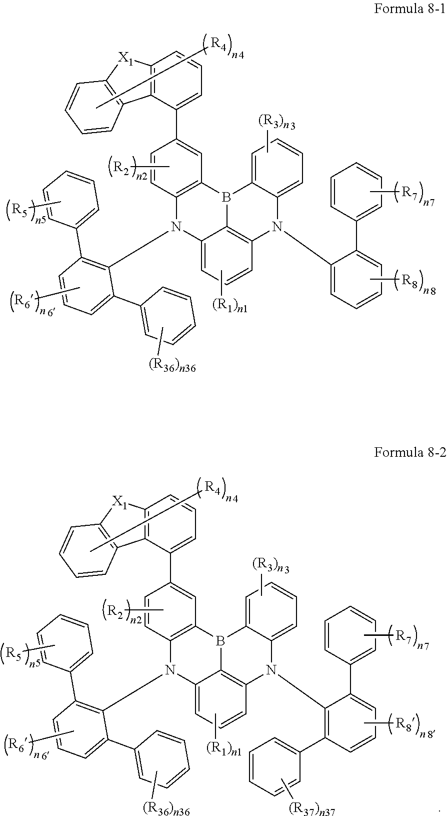

In Formula 8-1 and Formula 8-2, R₆′, R₈′, R₃₆, and R₃₇ may each independently be hydrogen, deuterium, a halogen, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in some embodiments, R₆′, R₈′, R₃₆, and R₃₇ may each independently be hydrogen, a substituted or unsubstituted t-butyl, or a substituted or unsubstituted phenyl group.

In Formula 8-1 and Formula 8-2, n6′ and n8′ may each independently be an integer of 0 to 3. In Formula 8-1 and Formula 8-2, when each of n6′ and n8′ is 0, the fused polycyclic compound of one or more embodiments may not be substituted with each of R₆′ and R₈′. In Formula 8-1 and Formula 8-2, embodiments in which each of n6′ and n8′ is 3 and R₆′(s) and R₈′(s) are each hydrogen may be the same as embodiments in which each of n6′ and n8′ is 0 in Formula 8-1 and Formula 8-2. When each of n6′ and n8′ is an integer of 2 or more, a plurality of R₆′(s) and R₈′(s) may each be the same or at least one selected from among the plurality of R₆′(s) and R₈′(s) may be different from the others.

In Formula 8-1 and Formula 8-2, n36 and n37 may each independently be an integer of 0 to 5. In Formula 8-1 and Formula 8-2, when each of n36 and n37 is 0, the fused polycyclic compound of one or more embodiments may not be substituted with each of R₃₆ and R₃₇. In Formula 8-1 and Formula 8-2, embodiments in which each of n36 and n37 is 5 and R₃₆(s) and R₃₇(s) are each hydrogen may be the same as embodiments in which each of n36 and n37 is 0 in Formula 8-1 and Formula 8-2. When each of n36 and n37 is an integer of 2 or more, a plurality of R₃₆(s) and R₃₇(s) may each be the same or at least one selected from among the plurality of R₃₆(s) and R₃₇(s) may be different from the others.

In Formula 8-1 to Formula 8-2, X₁, R₁ to R₅, R₇, R₈, n1 to n5, n7, and n8 may each be the same as described in Formula 1.

In one or more embodiments, the first compound represented by Formula 1 may be represented by Formula 9-1 or Formula 9-2:

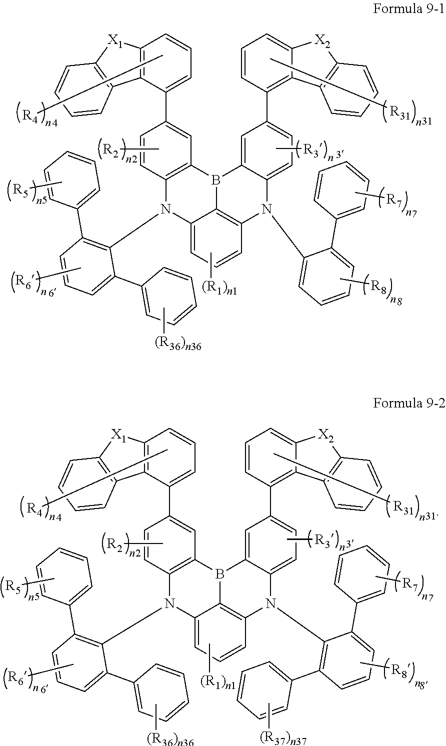

In Formula 9-1 to Formula 9-2, X₁, R₁, R₂, R₄, R₅, R₇, R₈, n1, n2, n4, n5, n7, and n8 may each be the same as described in Formula 1. Meanwhile, X₂, R₃′, R₃₁, n3′, and n31 may each be the same as described in Formula 5. R₆′, R₈′, R₃₆, R₃₇, n6′, n8′, n36, and n37 may each be the same as described in Formula 8-1 and Formula 8-2.

The fused polycyclic compound of one or more embodiments may be any one selected from among the compounds represented by Compound Group 1. The light emitting device ED of one or more embodiments may include at least one fused polycyclic compound selected from among the compounds represented by Compound Group 1 in the emission layer EML.

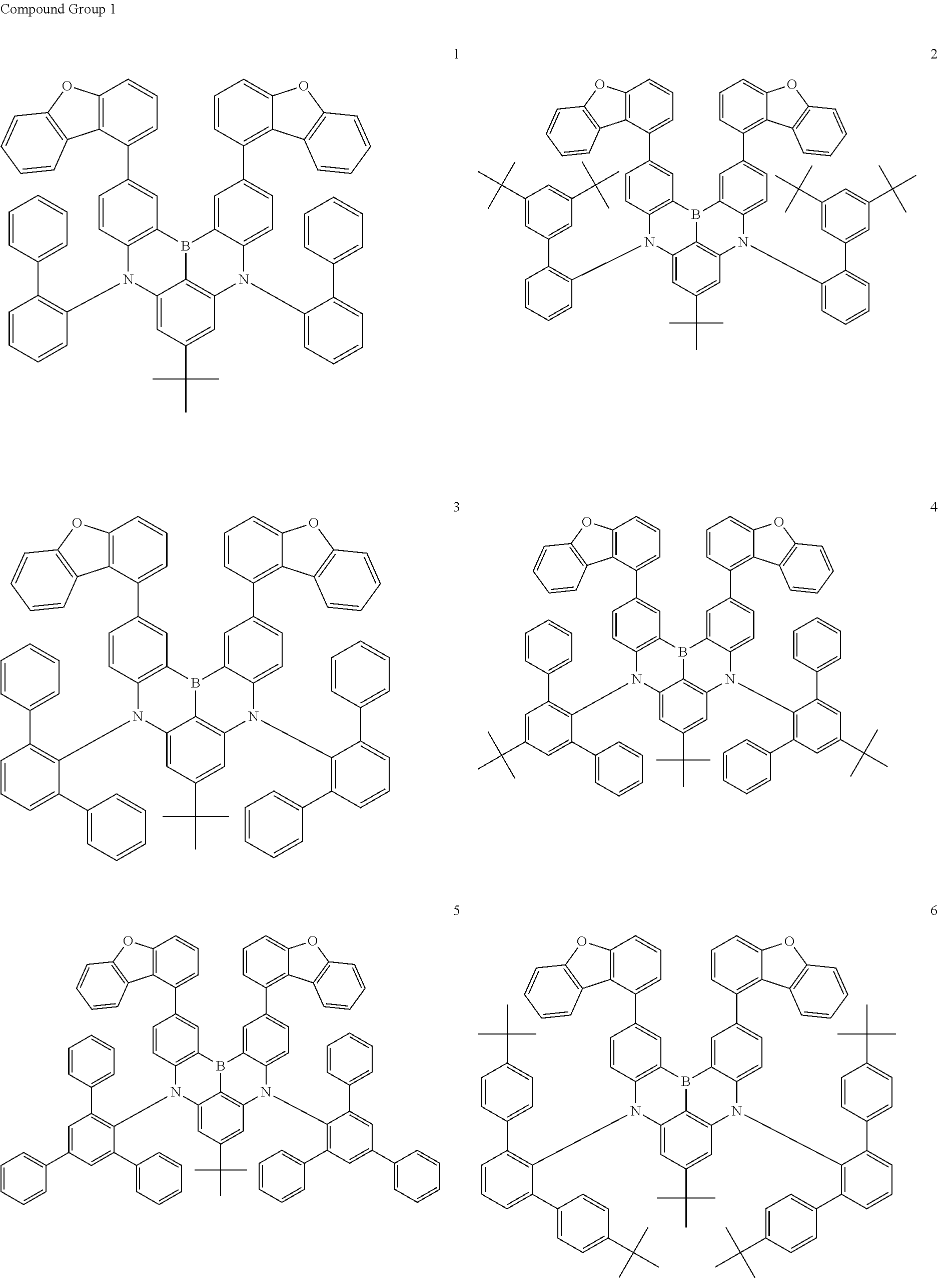

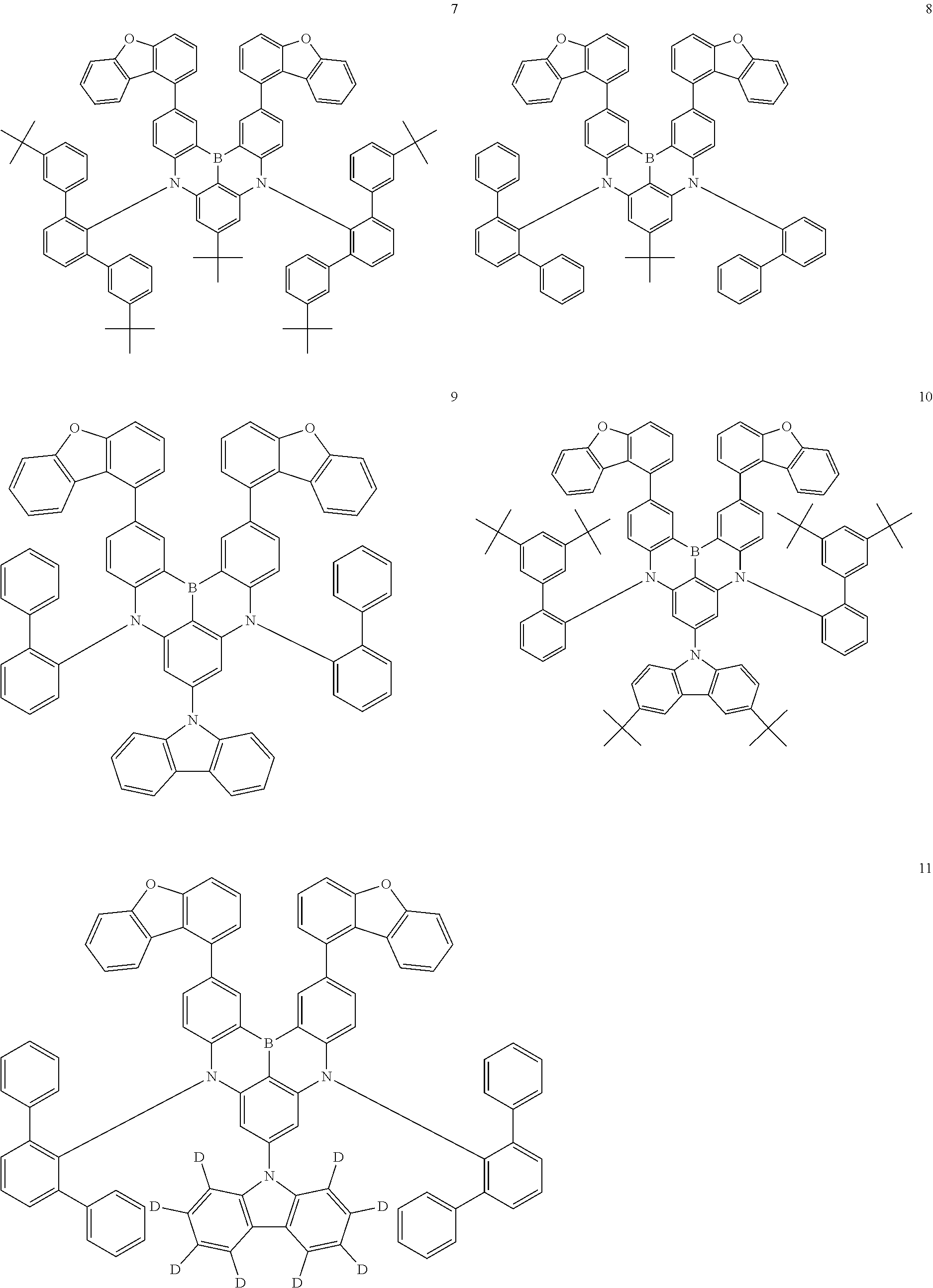

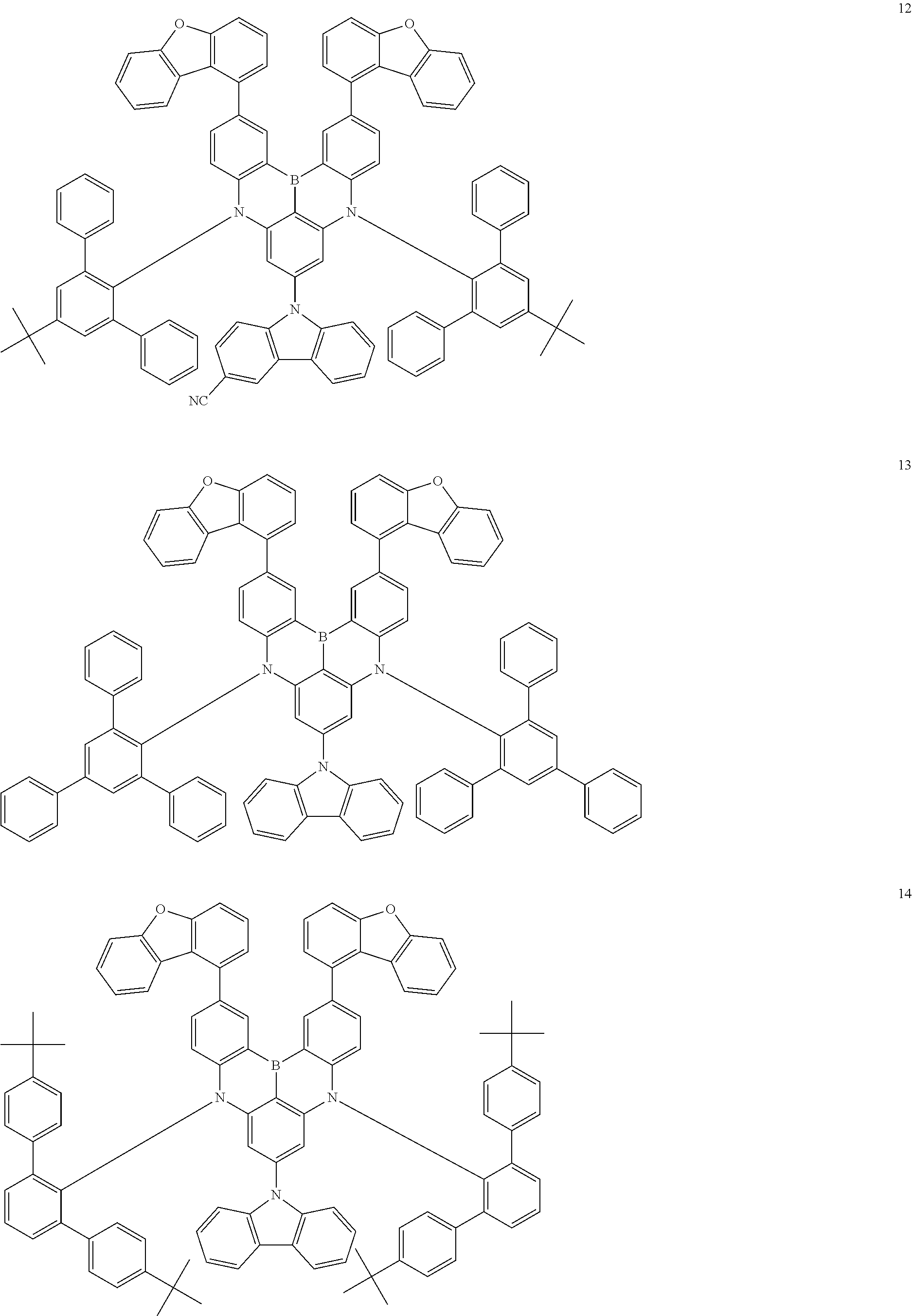

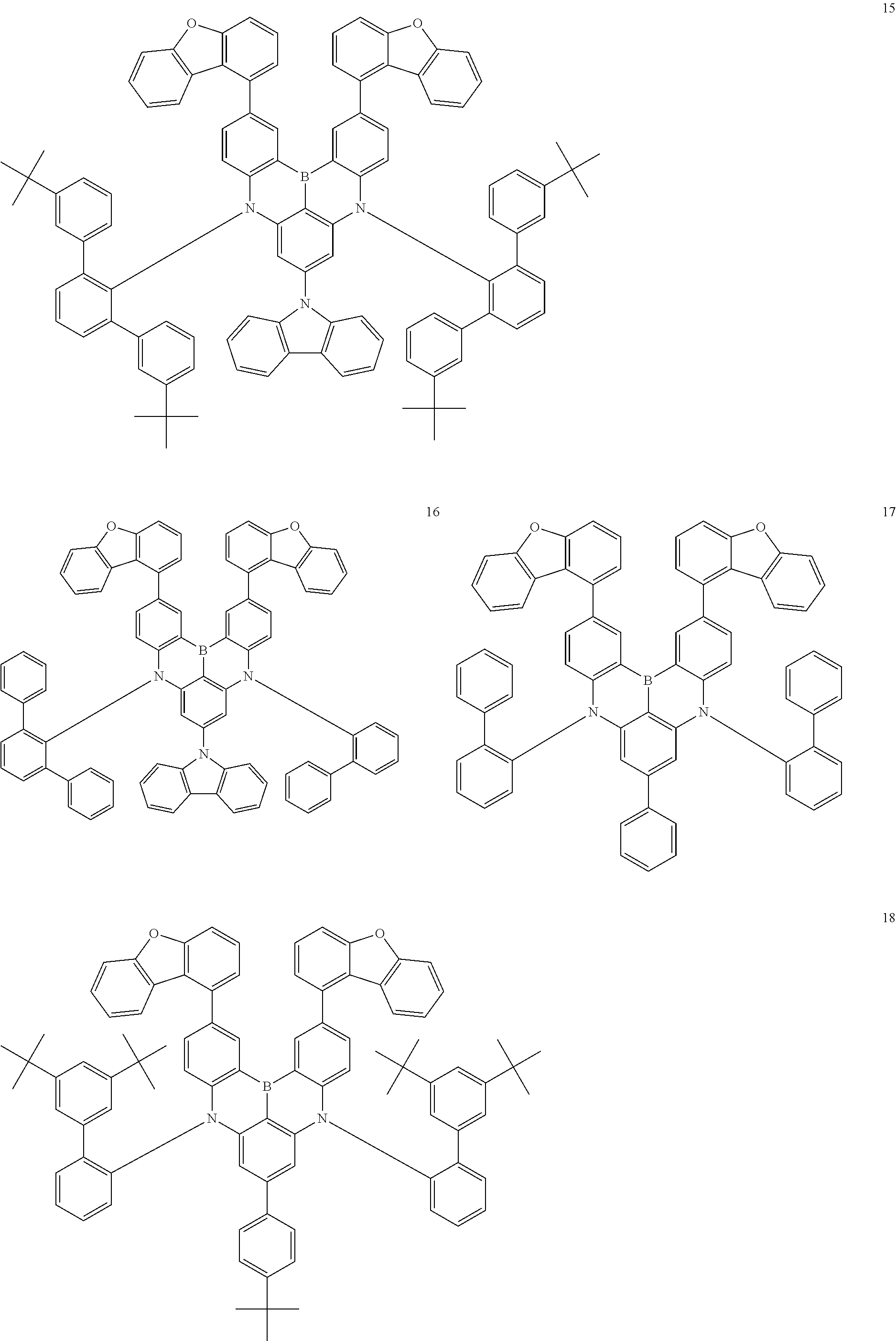

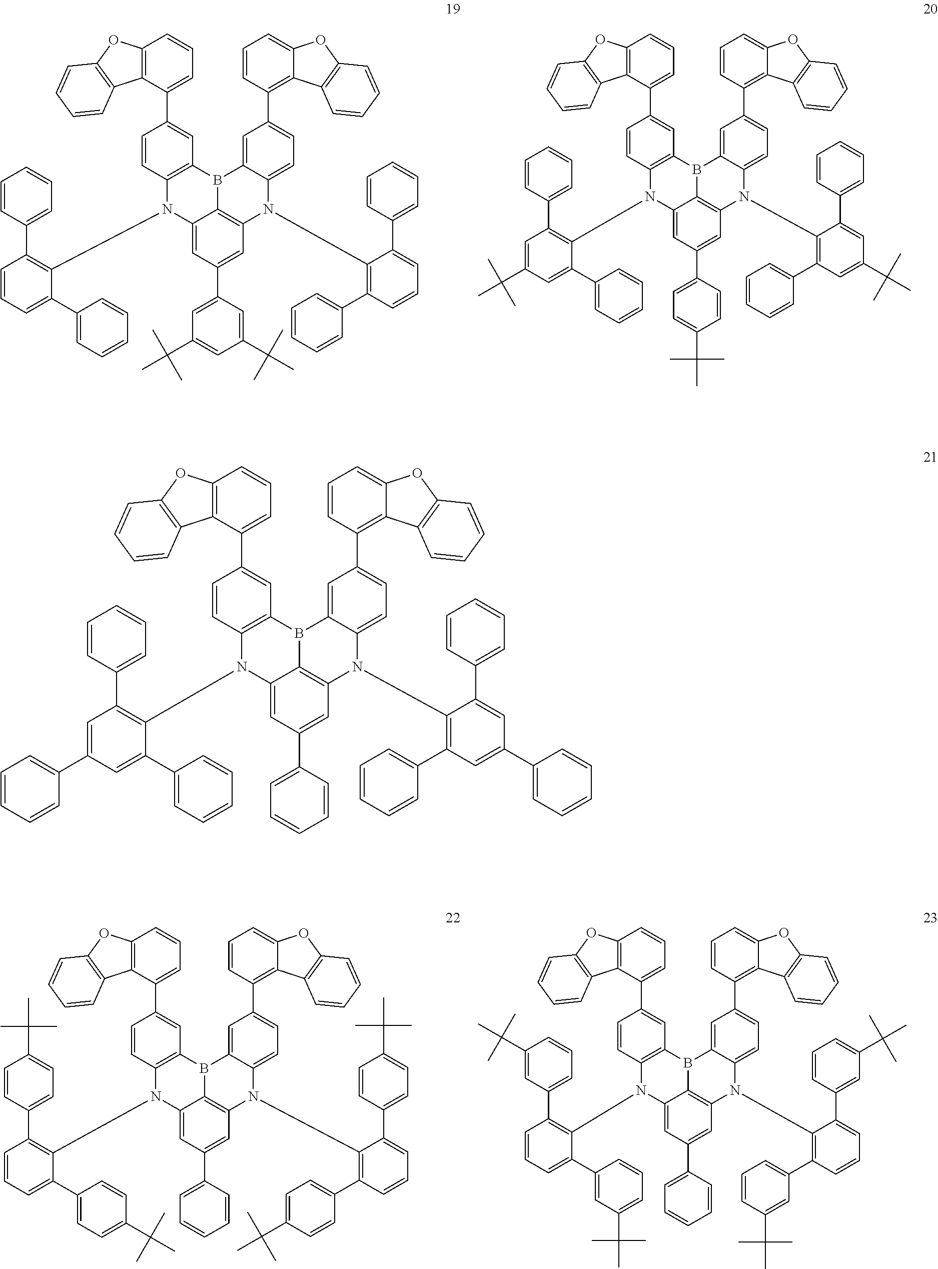

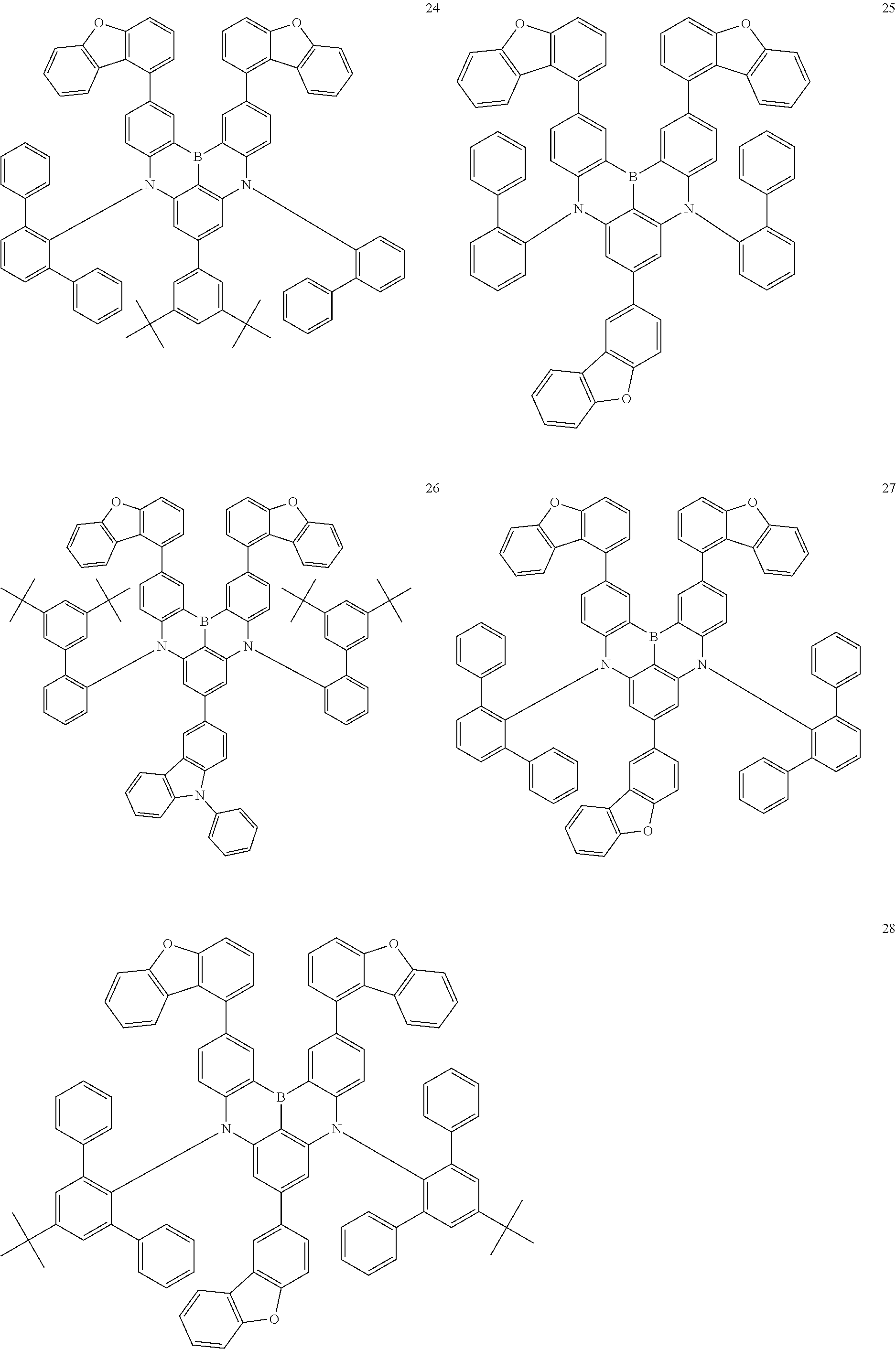

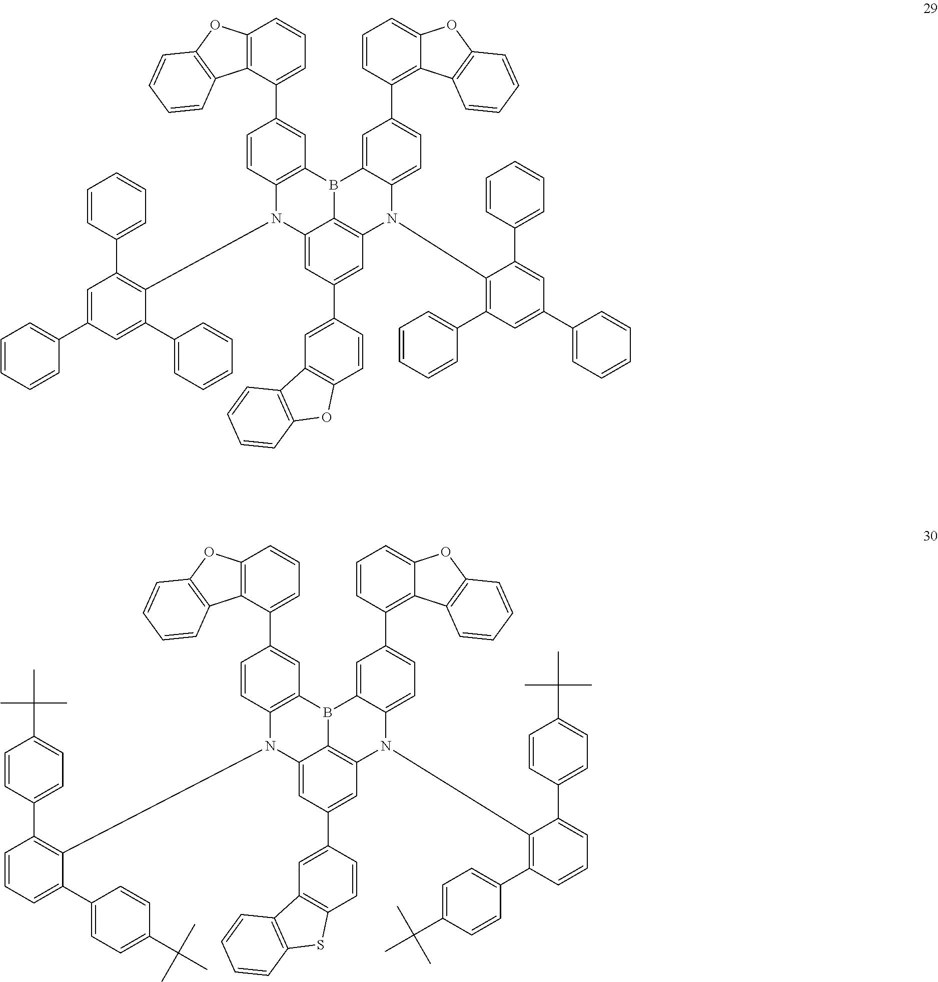 [SMILES: c1ccc(-c2cc(-c3ccccc3)c(N3c4ccc(-c5cccc6oc7ccccc7c56)cc4B4c5cc(-c6cccc7oc8ccccc8c67)ccc5N(c5c(-c6ccccc6)cc(-c6ccccc6)cc5-c5ccccc5)c5cc(-c6ccc7oc8ccccc8c7c6)cc3c54)c(-c3ccccc3)c2)cc1 ; CC(C)(C)c1ccc(-c2cccc(-c3ccc(C(C)(C)C)cc3)c2N2c3ccc(-c4cccc5oc6ccccc6c45)cc3B3c4cc(-c5cccc6oc7ccccc7c56)ccc4N(c4c(-c5ccc(C(C)(C)C)cc5)cccc4-c4ccc(C(C)(C)C)cc4)c4cc(-c5ccc6sc7ccccc7c6c5)cc2c43)cc1]

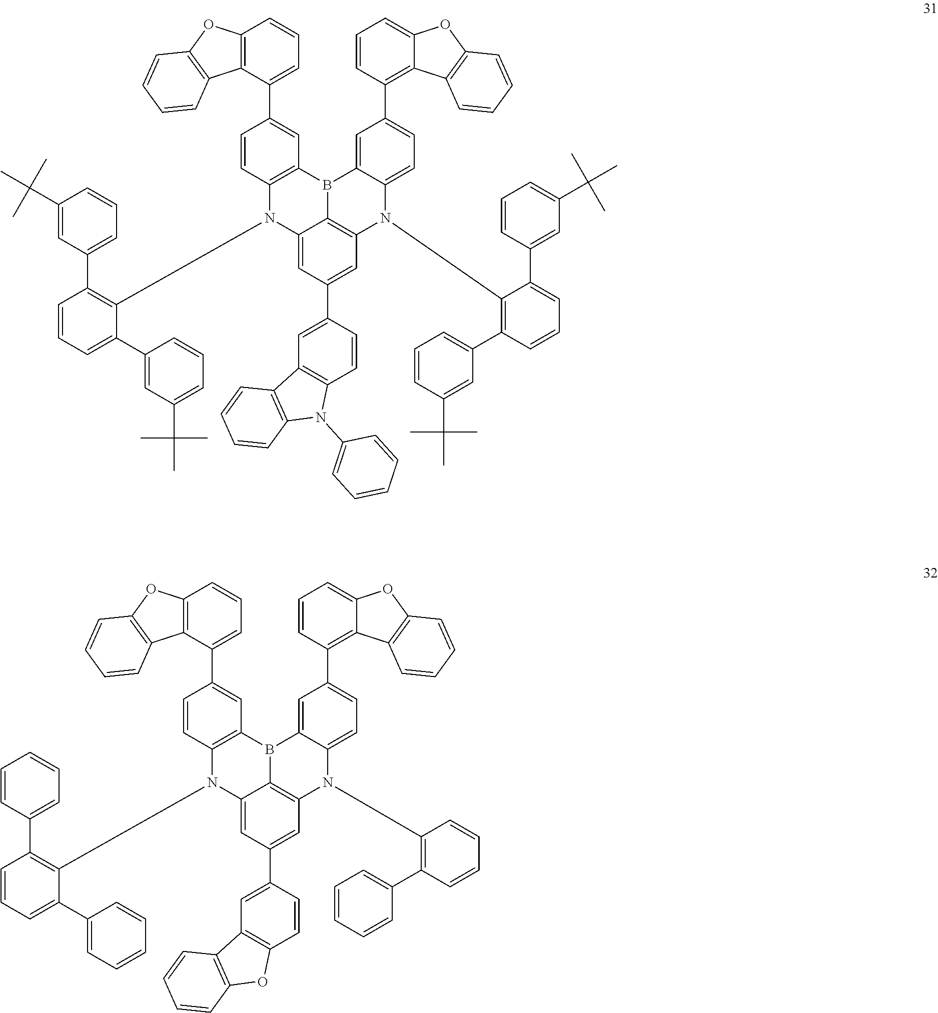 [SMILES: CC(C)(C)c1cccc(-c2cccc(-c3cccc(C(C)(C)C)c3)c2N2c3ccc(-c4cccc5oc6ccccc6c45)cc3B3c4cc(-c5cccc6oc7ccccc7c56)ccc4N(c4c(-c5cccc(C(C)(C)C)c5)cccc4-c4cccc(C(C)(C)C)c4)c4cc(-c5ccc6c(c5)c5ccccc5n6-c5ccccc5)cc2c43)c1 ; c1ccc(-c2ccccc2N2c3ccc(-c4cccc5oc6ccccc6c45)cc3B3c4cc(-c5cccc6oc7ccccc7c56)ccc4N(c4c(-c5ccccc5)cccc4-c4ccccc4)c4cc(-c5ccc6oc7ccccc7c6c5)cc2c43)cc1]

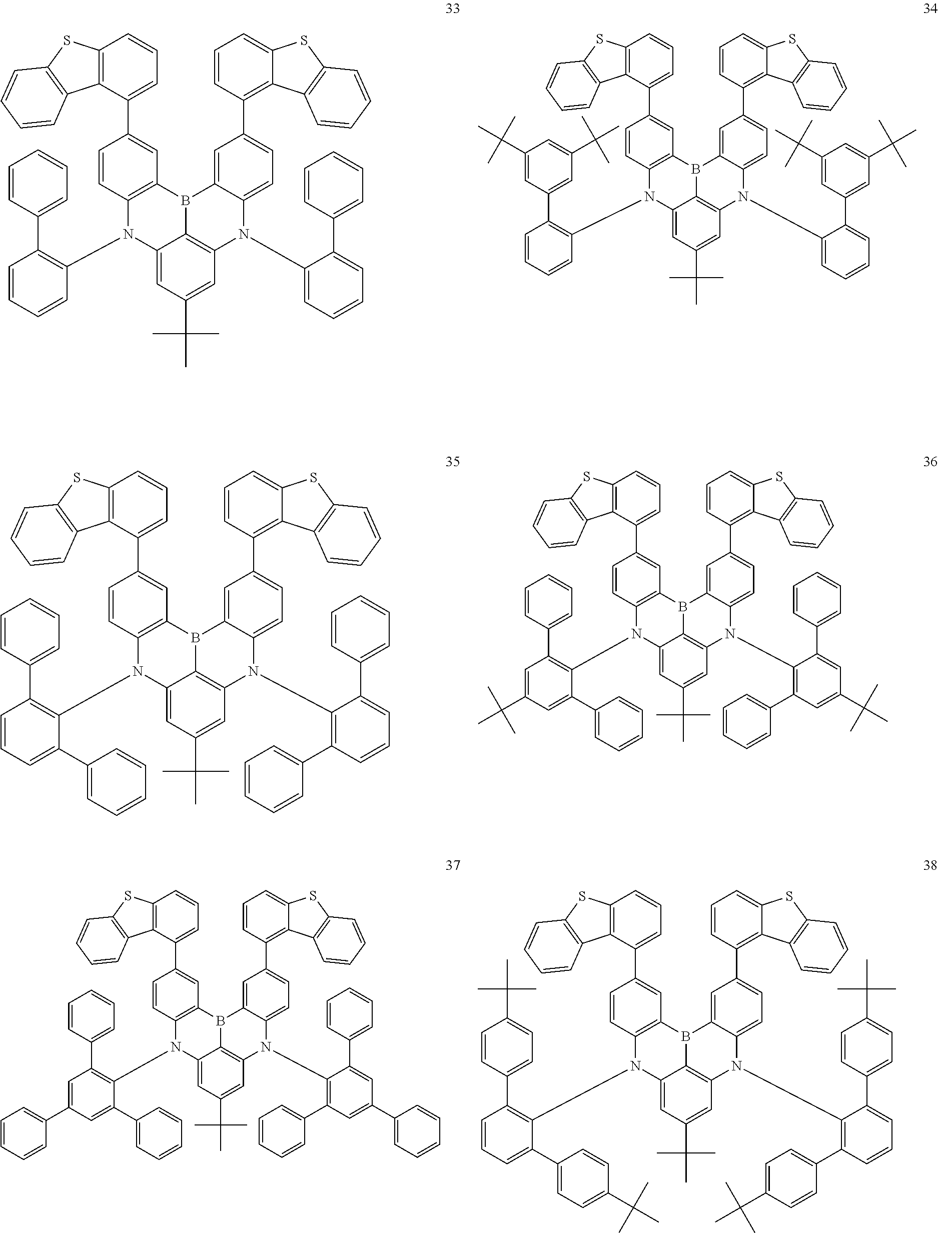

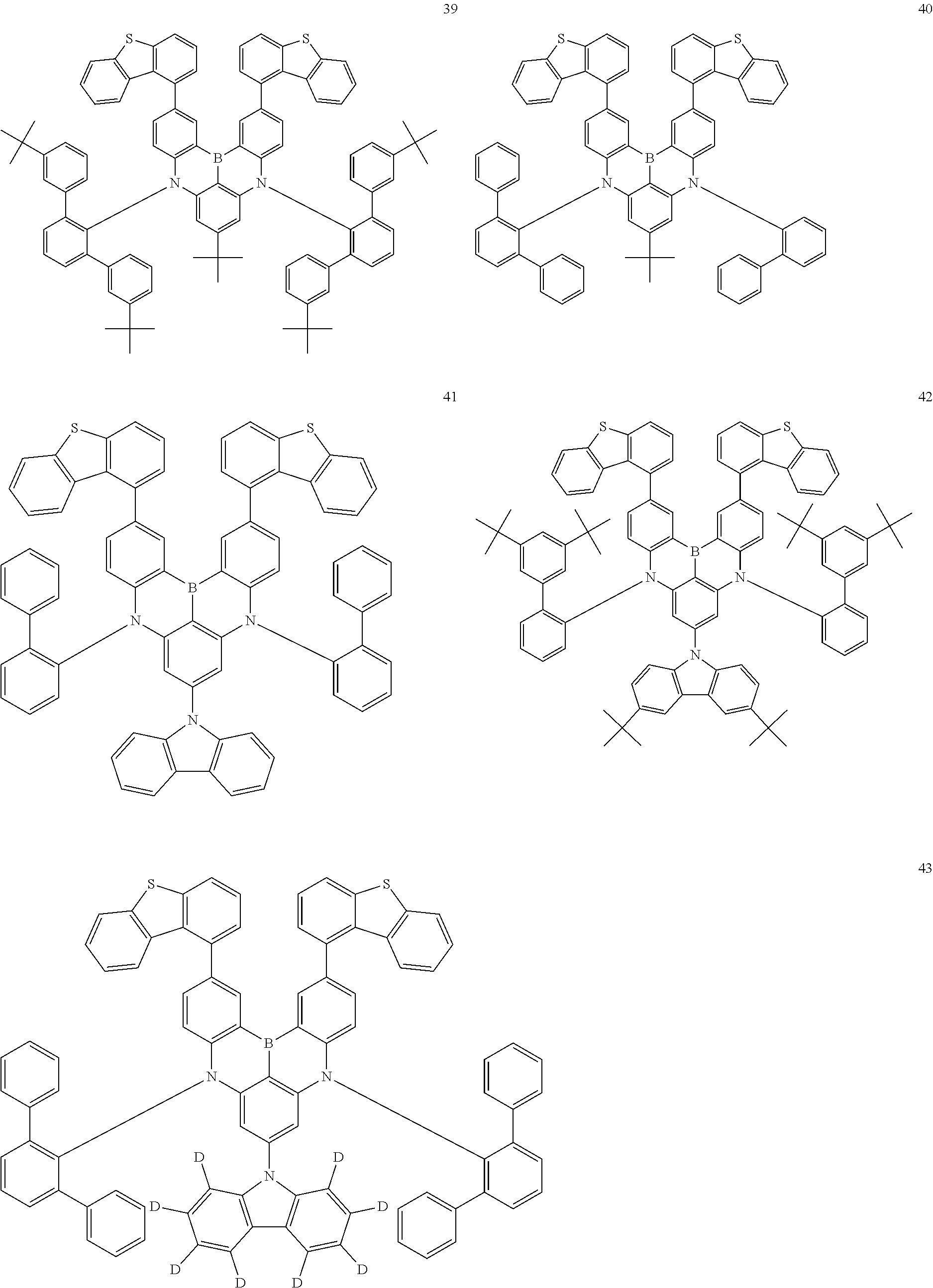

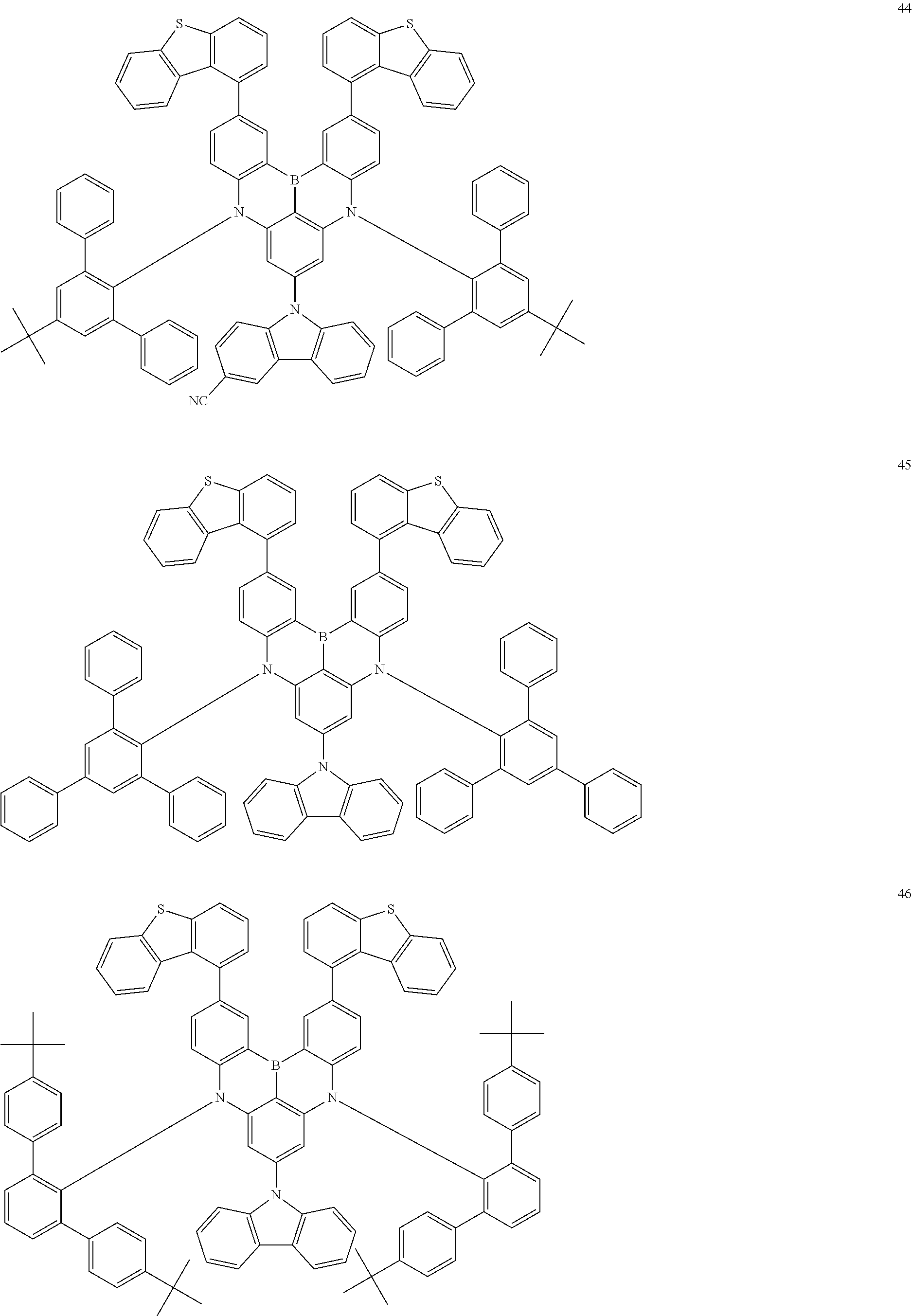

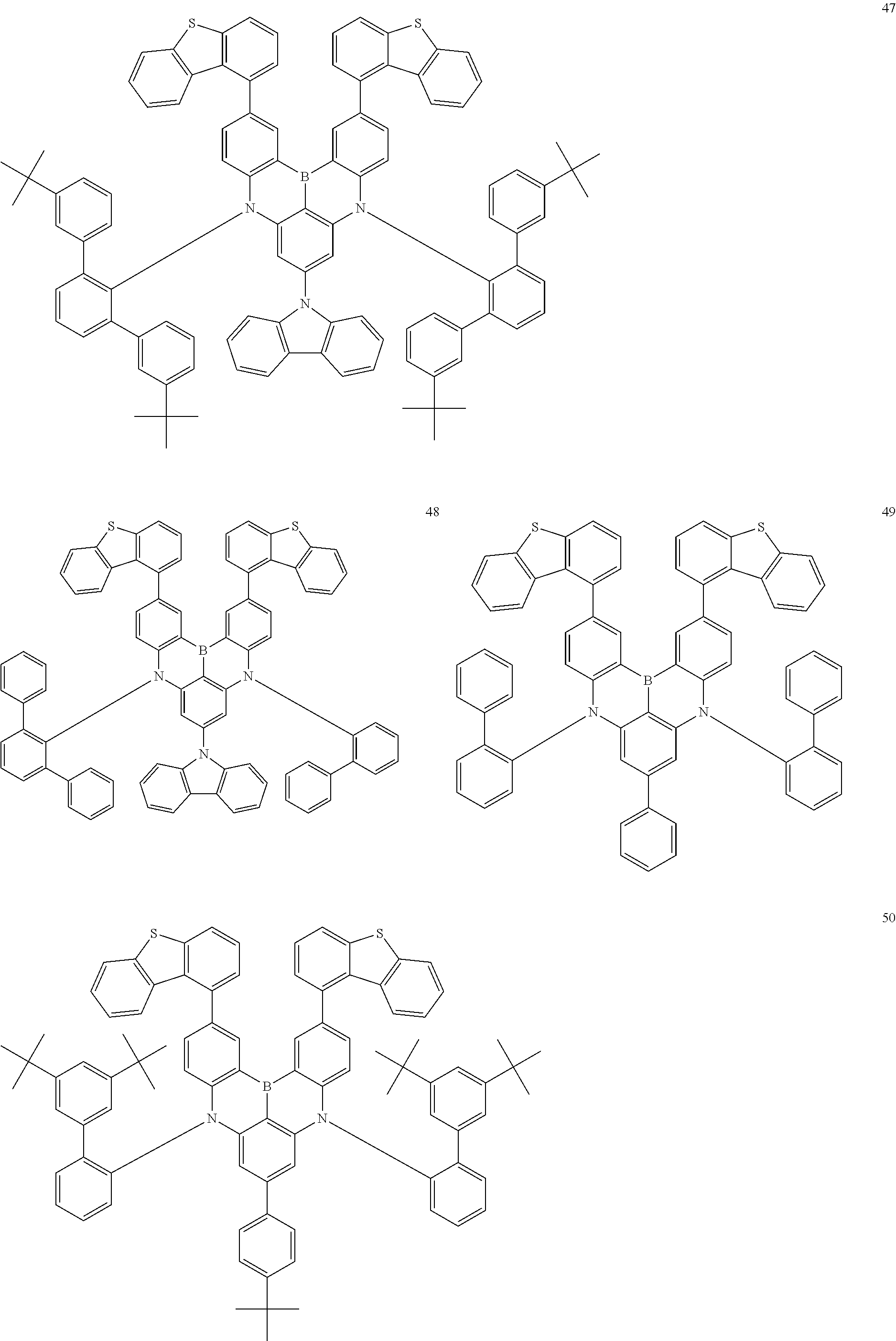

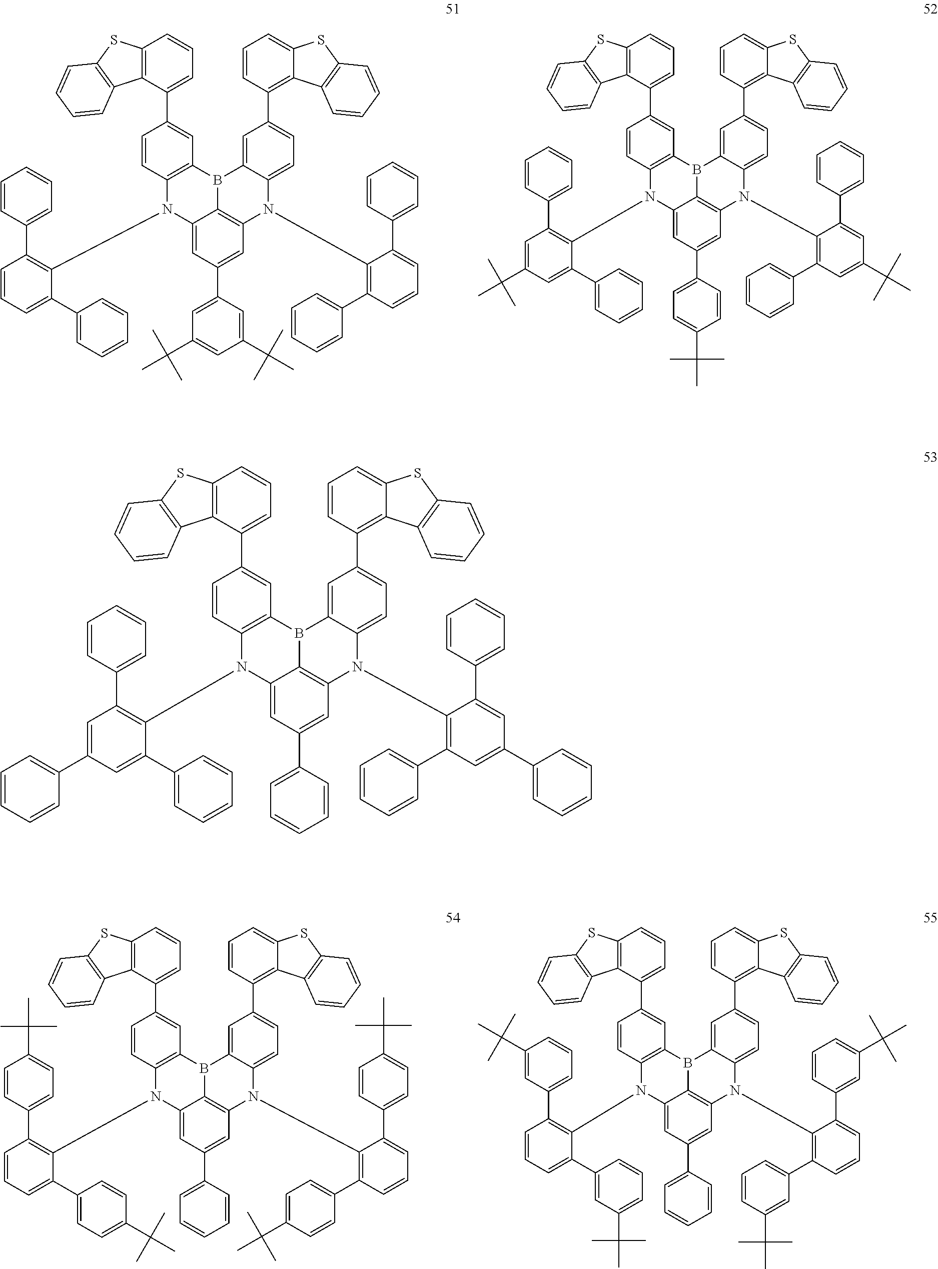

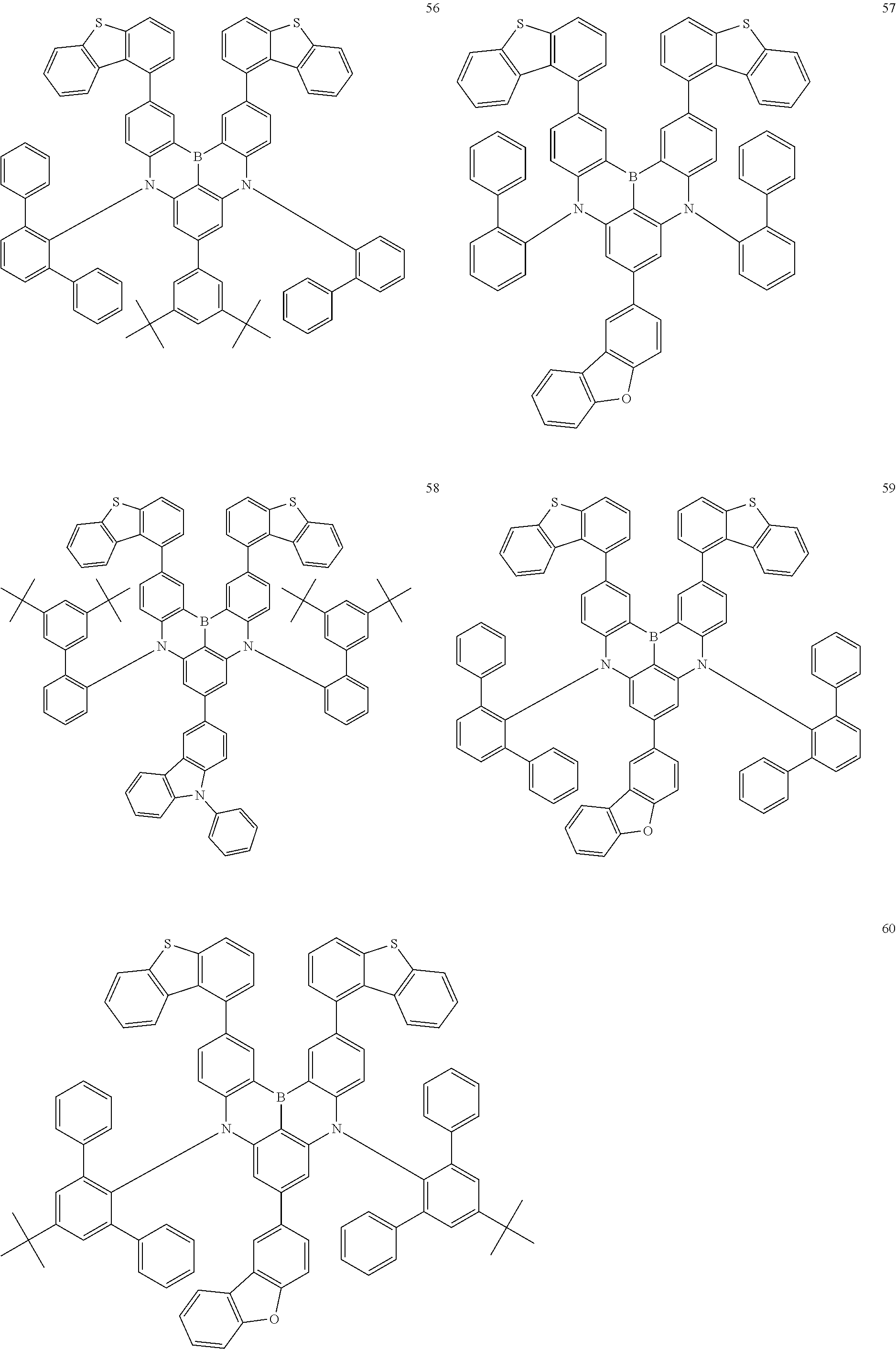

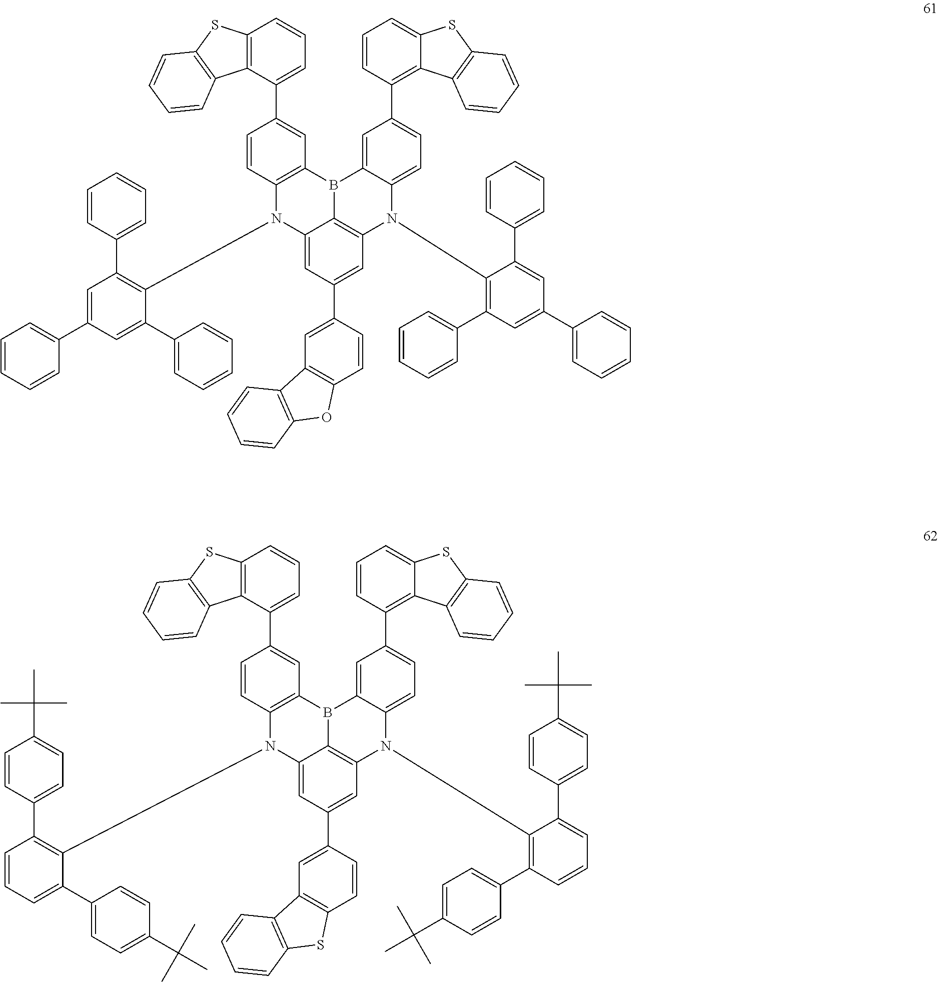 [SMILES: c1ccc(-c2cc(-c3ccccc3)c(N3c4ccc(-c5cccc6sc7ccccc7c56)cc4B4c5cc(-c6cccc7sc8ccccc8c67)ccc5N(c5c(-c6ccccc6)cc(-c6ccccc6)cc5-c5ccccc5)c5cc(-c6ccc7oc8ccccc8c7c6)cc3c54)c(-c3ccccc3)c2)cc1 ; CC(C)(C)c1ccc(-c2cccc(-c3ccc(C(C)(C)C)cc3)c2N2c3ccc(-c4cccc5sc6ccccc6c45)cc3B3c4cc(-c5cccc6sc7ccccc7c56)ccc4N(c4c(-c5ccc(C(C)(C)C)cc5)cccc4-c4ccc(C(C)(C)C)cc4)c4cc(-c5ccc6sc7ccccc7c6c5)cc2c43)cc1]

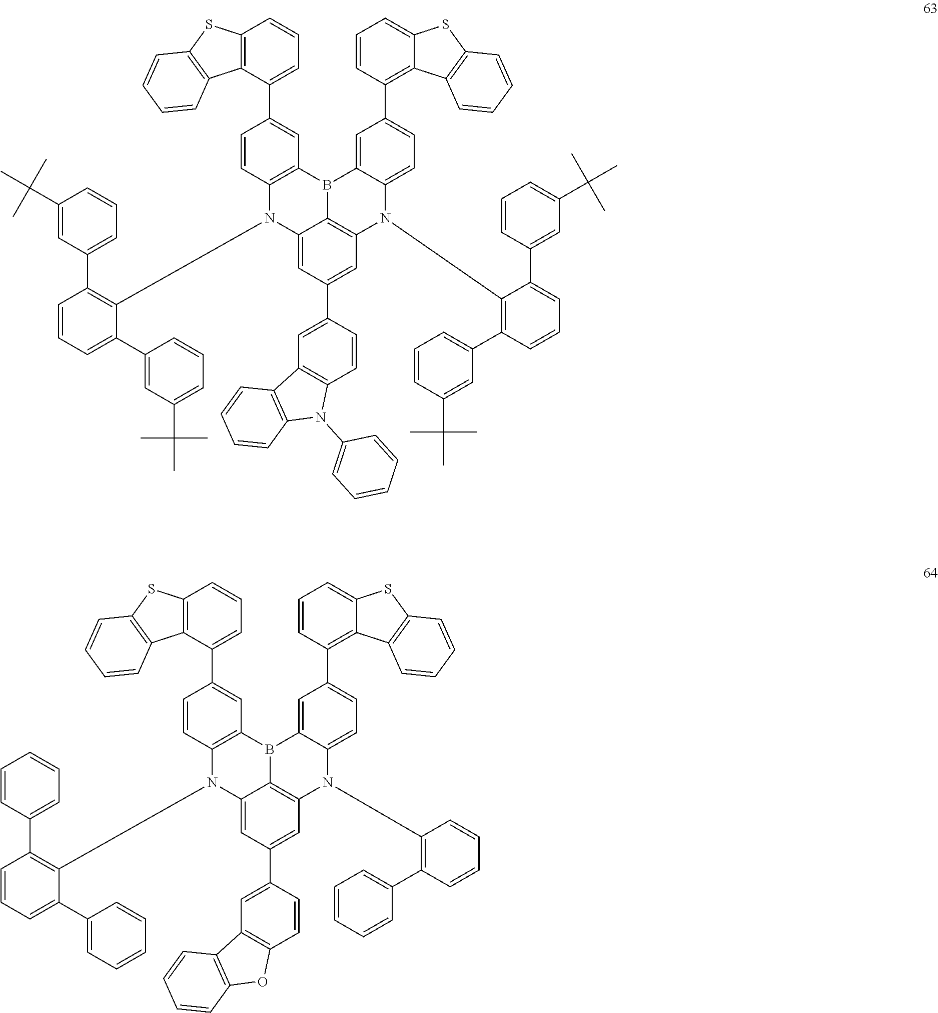 [SMILES: CC(C)(C)c1cccc(-c2cccc(-c3cccc(C(C)(C)C)c3)c2N2c3ccc(-c4cccc5sc6ccccc6c45)cc3B3c4cc(-c5cccc6sc7ccccc7c56)ccc4N(c4c(-c5cccc(C(C)(C)C)c5)cccc4-c4cccc(C(C)(C)C)c4)c4cc(-c5ccc6c(c5)c5ccccc5n6-c5ccccc5)cc2c43)c1 ; c1ccc(-c2ccccc2N2c3ccc(-c4cccc5sc6ccccc6c45)cc3B3c4cc(-c5cccc6sc7ccccc7c56)ccc4N(c4c(-c5ccccc5)cccc4-c4ccccc4)c4cc(-c5ccc6oc7ccccc7c6c5)cc2c43)cc1]

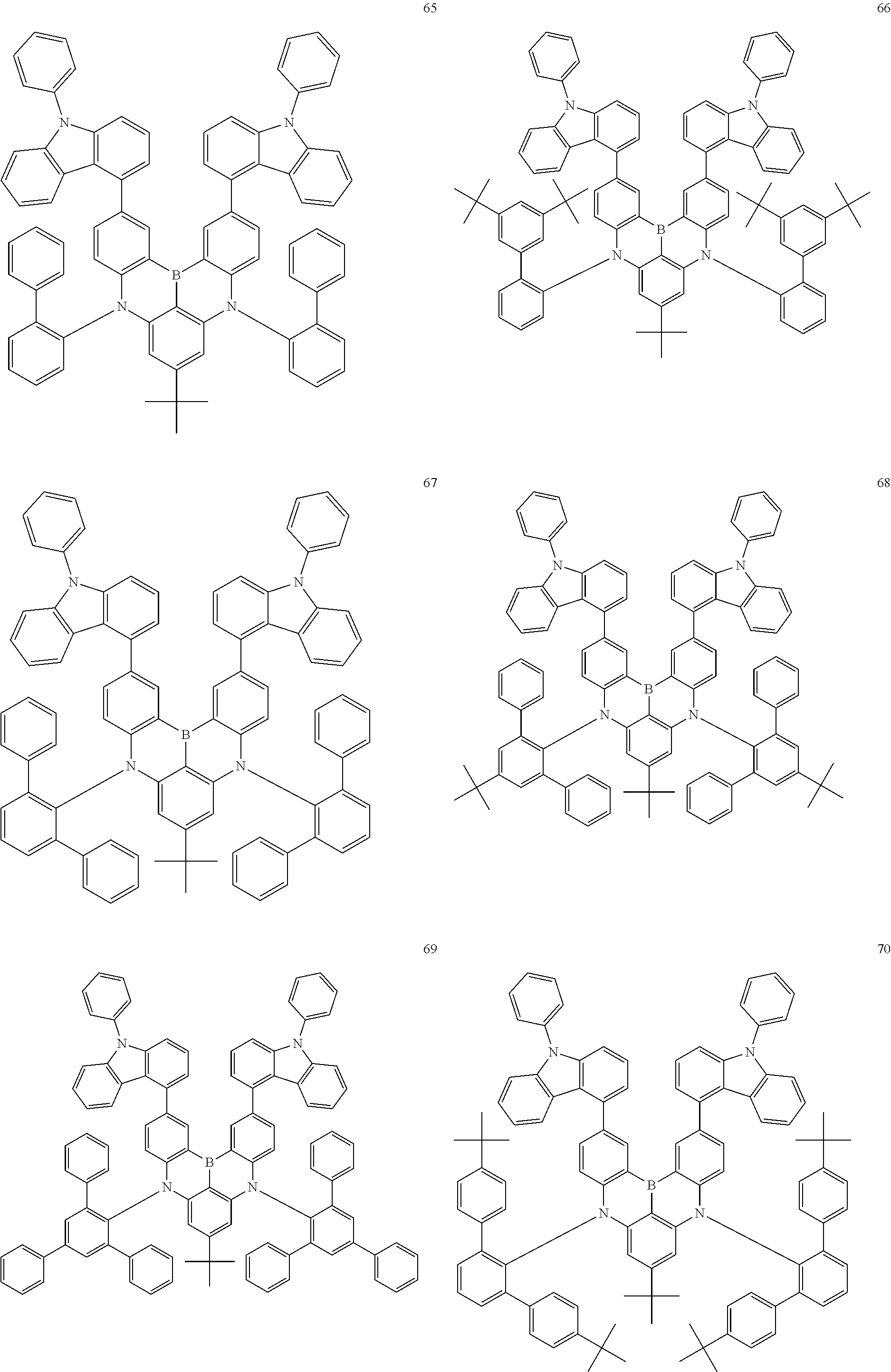

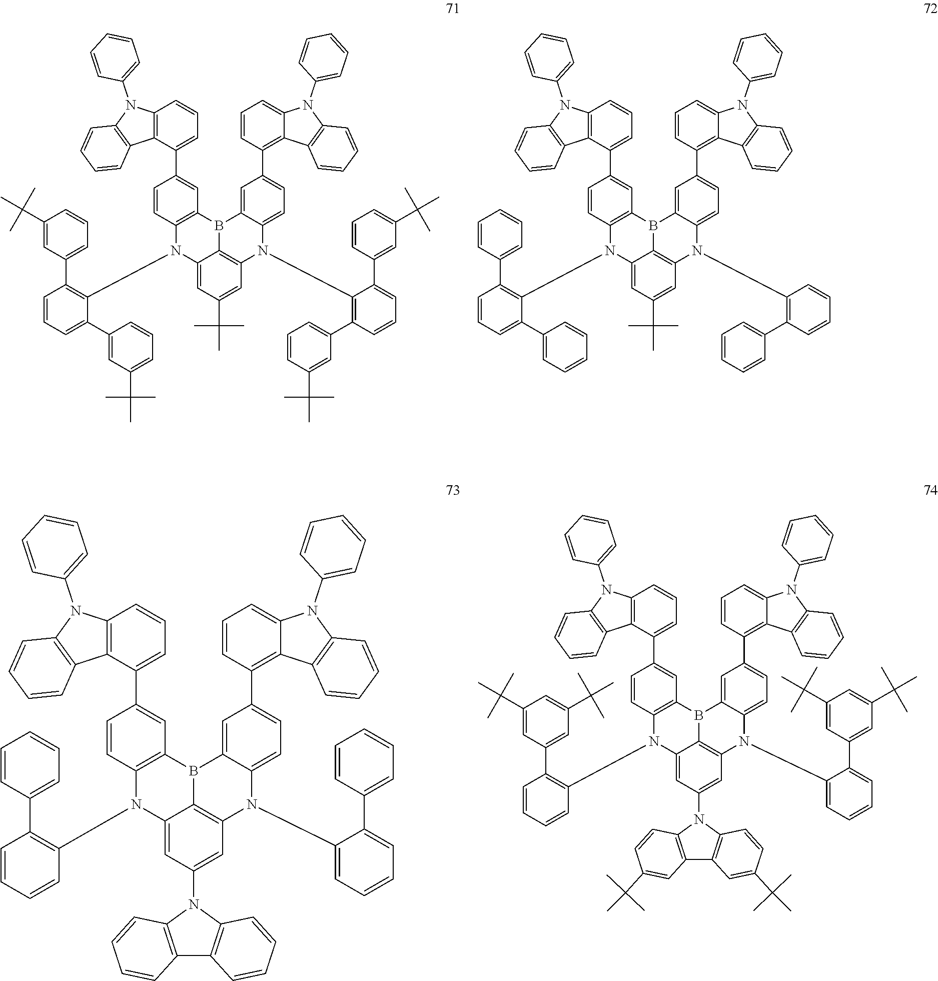

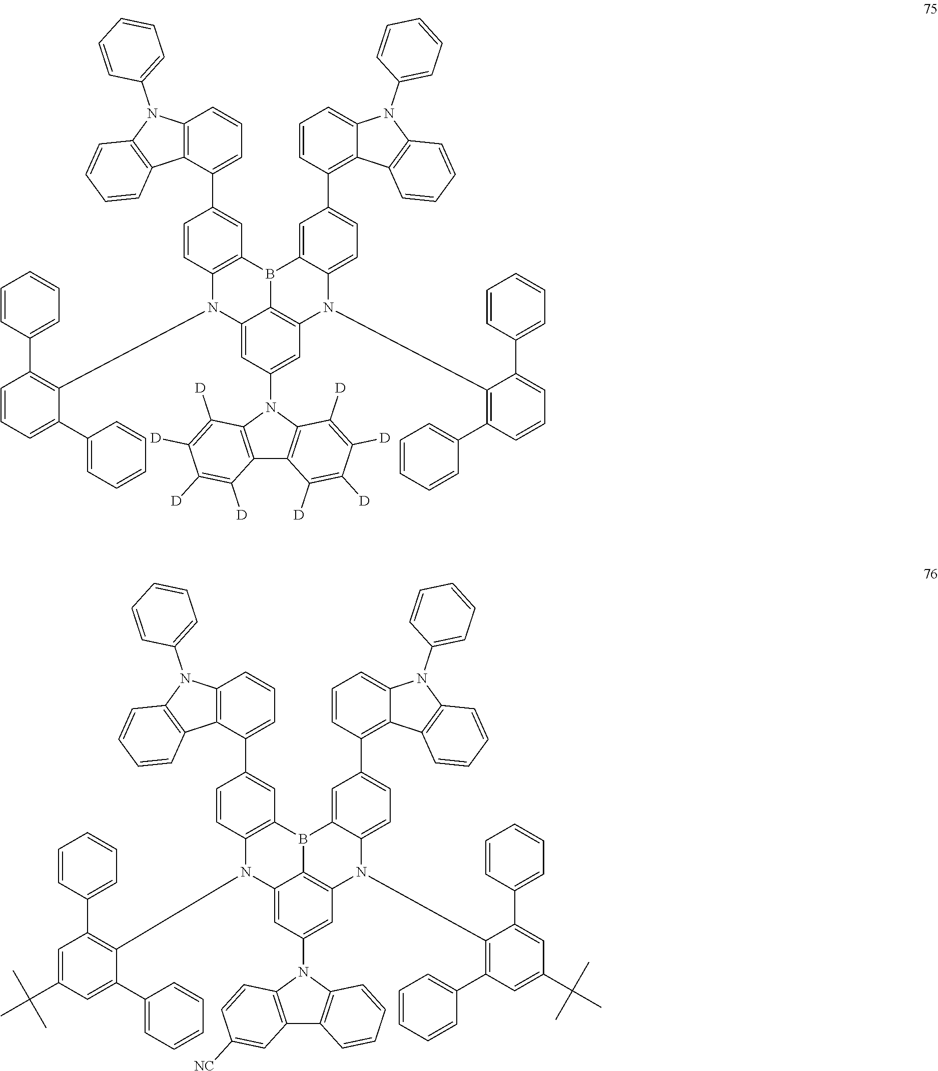 [SMILES: [2H]c1c([2H])c([2H])c2c(c1[2H])c1c([2H])c([2H])c([2H])c([2H])c1n2-c1cc2c3c(c1)N(c1c(-c4ccccc4)cccc1-c1ccccc1)c1ccc(-c4cccc5c4c4ccccc4n5-c4ccccc4)cc1B3c1cc(-c3cccc4c3c3ccccc3n4-c3ccccc3)ccc1N2c1c(-c2ccccc2)cccc1-c1ccccc1 ; CC(C)(C)c1cc(-c2ccccc2)c(N2c3ccc(-c4cccc5c4c4ccccc4n5-c4ccccc4)cc3B3c4cc(-c5cccc6c5c5ccccc5n6-c5ccccc5)ccc4N(c4c(-c5ccccc5)cc(C(C)(C)C)cc4-c4ccccc4)c4cc(-n5c6ccccc6c6cc(C#N)ccc65)cc2c43)c(-c2ccccc2)c1]

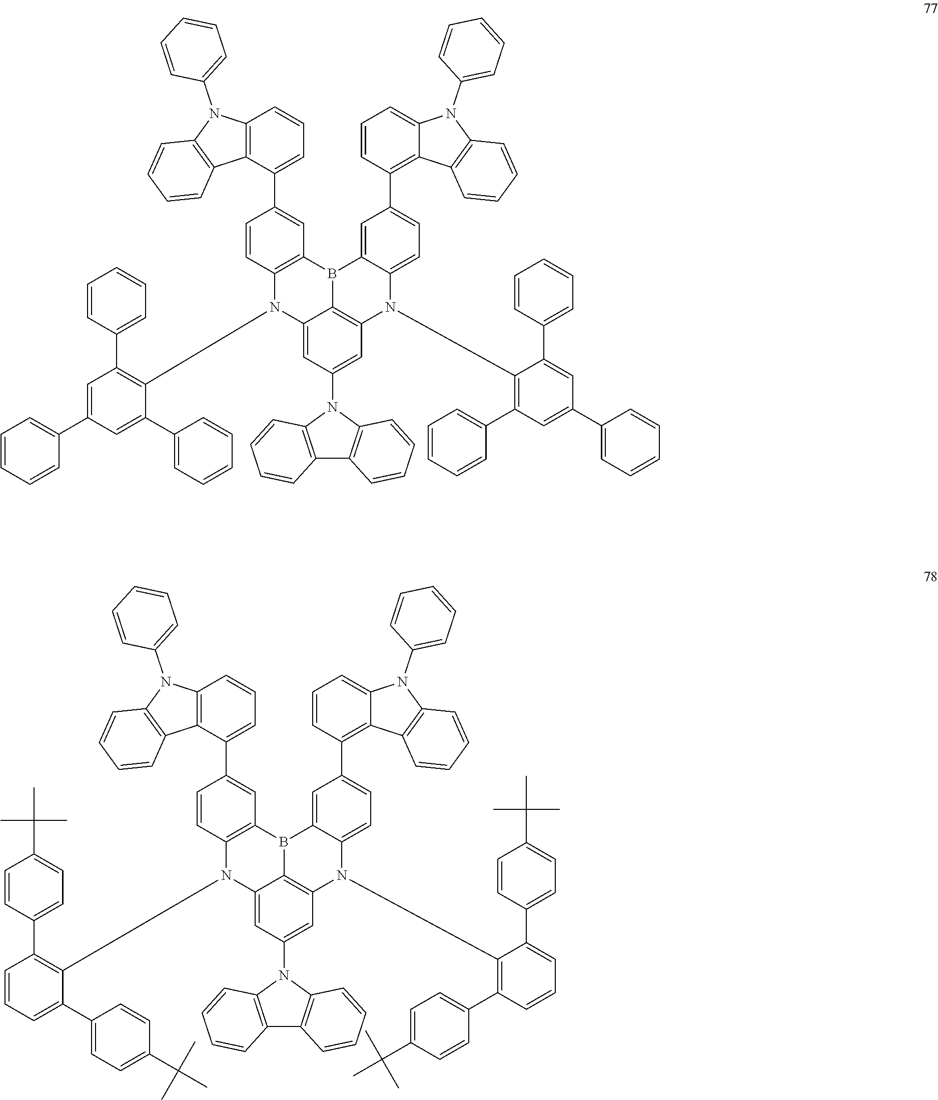 [SMILES: c1ccc(-c2cc(-c3ccccc3)c(N3c4ccc(-c5cccc6c5c5ccccc5n6-c5ccccc5)cc4B4c5cc(-c6cccc7c6c6ccccc6n7-c6ccccc6)ccc5N(c5c(-c6ccccc6)cc(-c6ccccc6)cc5-c5ccccc5)c5cc(-n6c7ccccc7c7ccccc76)cc3c54)c(-c3ccccc3)c2)cc1 ; CC(C)(C)c1ccc(-c2cccc(-c3ccc(C(C)(C)C)cc3)c2N2c3ccc(-c4cccc5c4c4ccccc4n5-c4ccccc4)cc3B3c4cc(-c5cccc6c5c5ccccc5n6-c5ccccc5)ccc4N(c4c(-c5ccc(C(C)(C)C)cc5)cccc4-c4ccc(C(C)(C)C)cc4)c4cc(-n5c6ccccc6c6ccccc65)cc2c43)cc1]

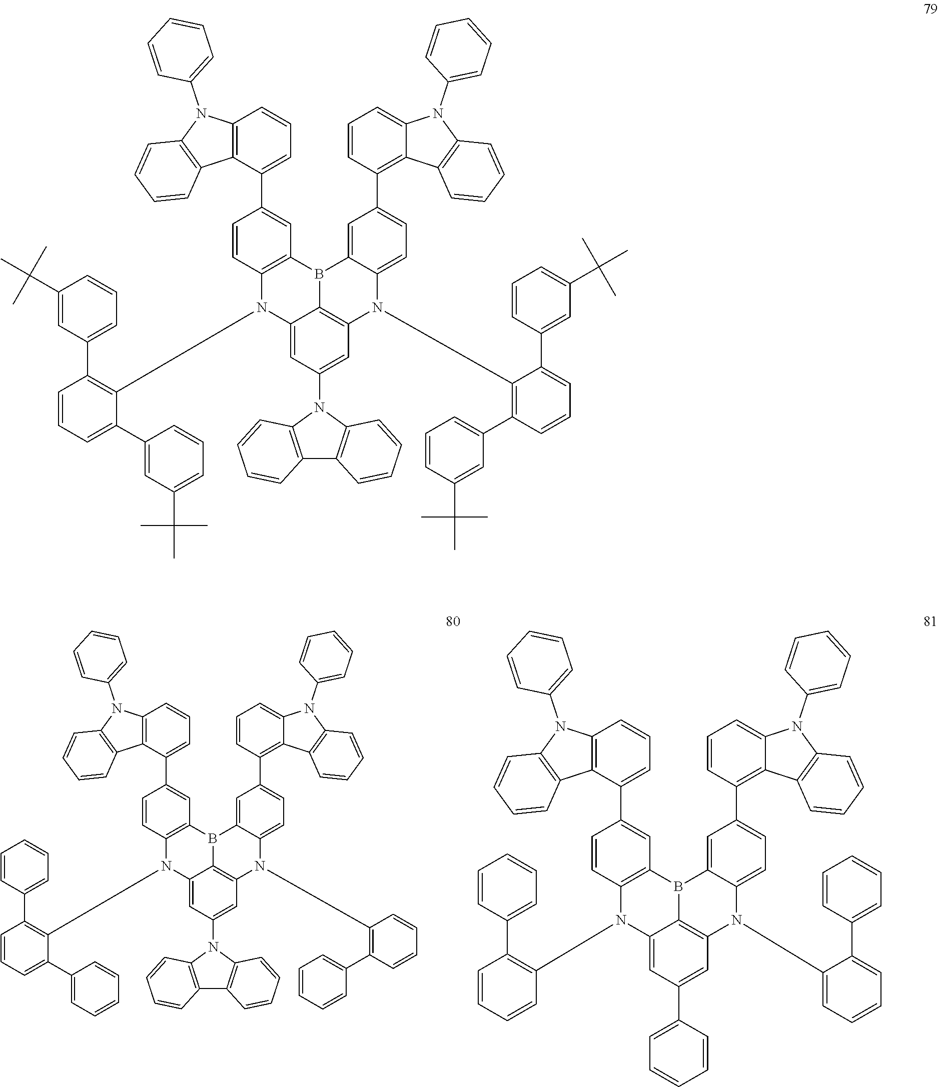

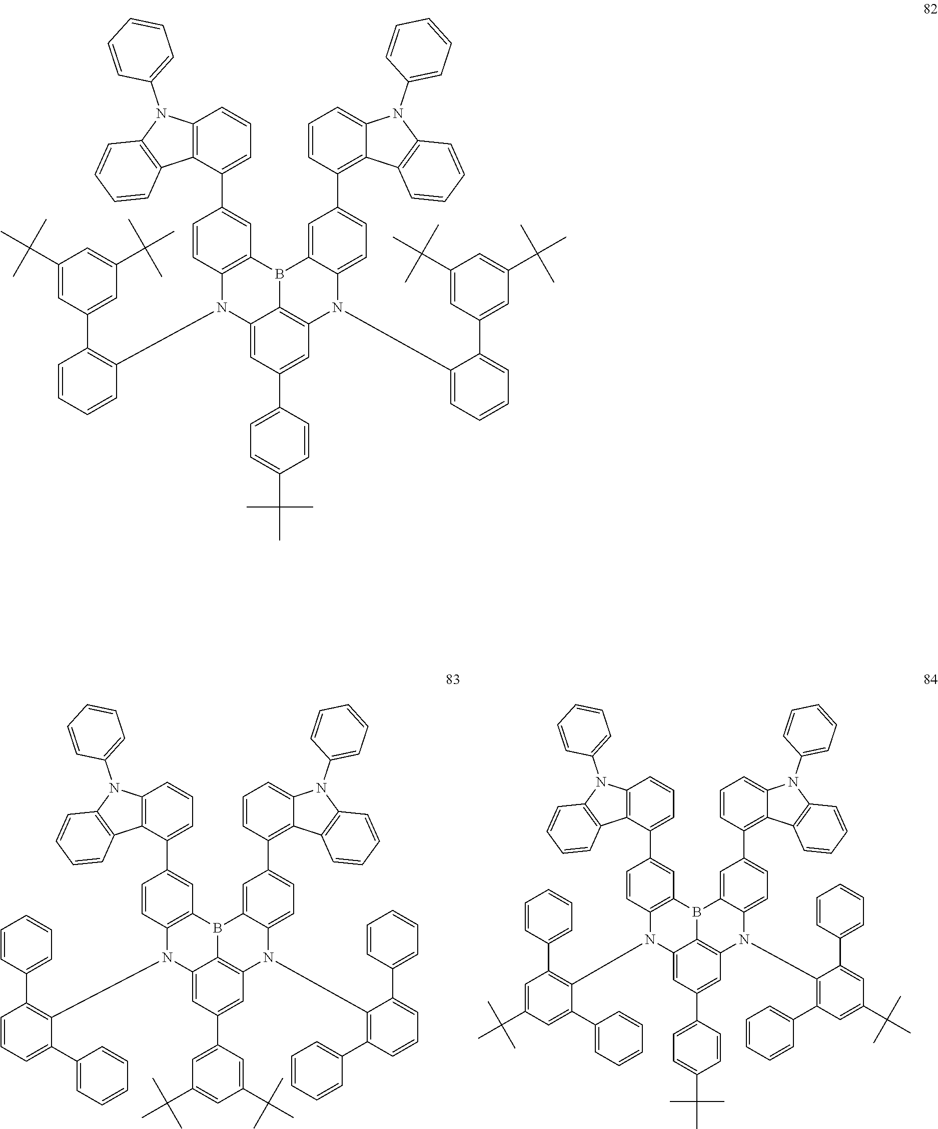

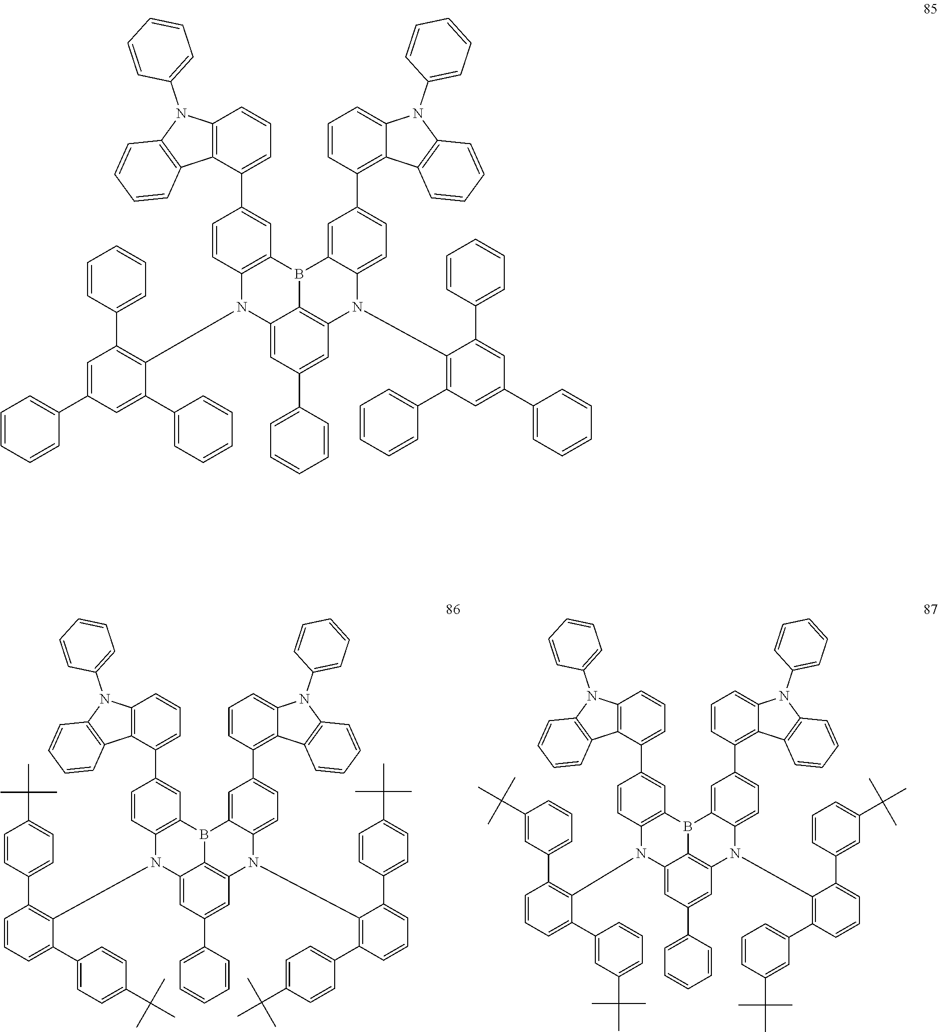

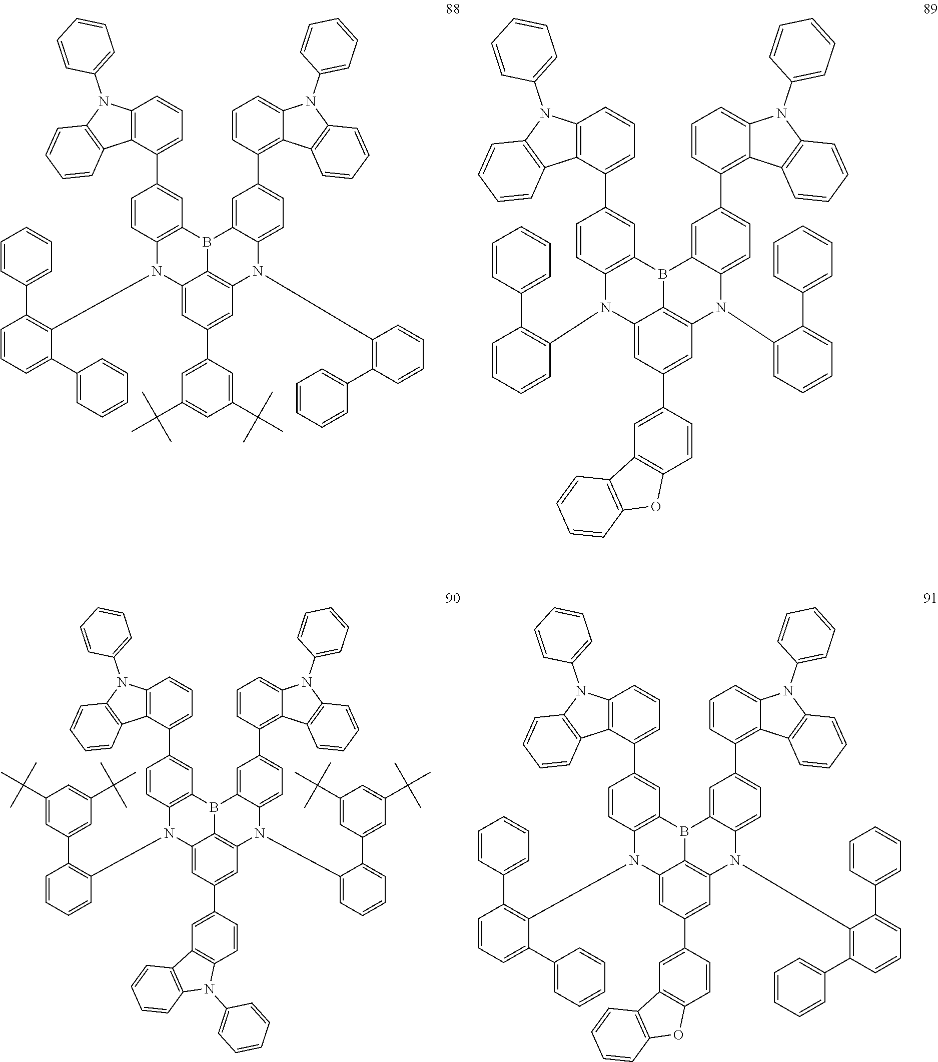

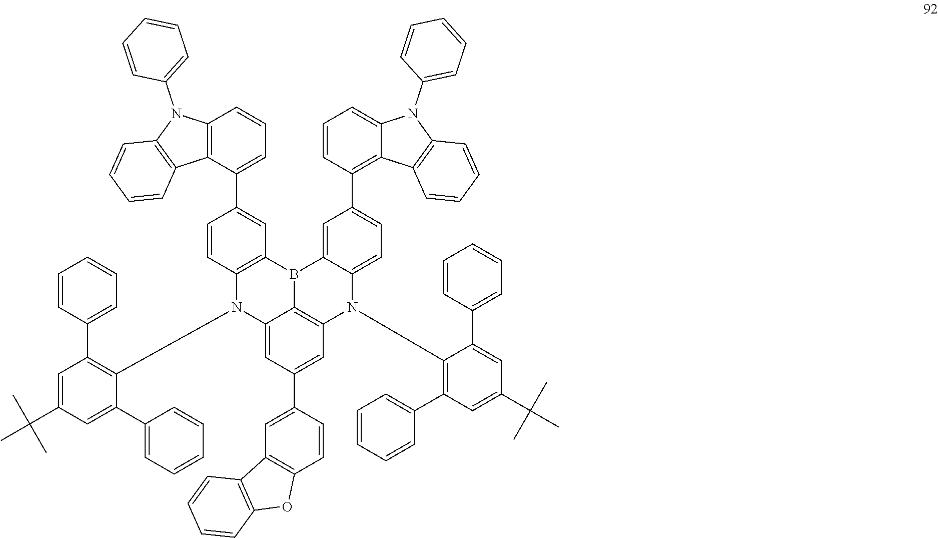 [SMILES: CC(C)(C)c1cc(-c2ccccc2)c(N2c3ccc(-c4cccc5c4c4ccccc4n5-c4ccccc4)cc3B3c4cc(-c5cccc6c5c5ccccc5n6-c5ccccc5)ccc4N(c4c(-c5ccccc5)cc(C(C)(C)C)cc4-c4ccccc4)c4cc(-c5ccc6oc7ccccc7c6c5)cc2c43)c(-c2ccccc2)c1]

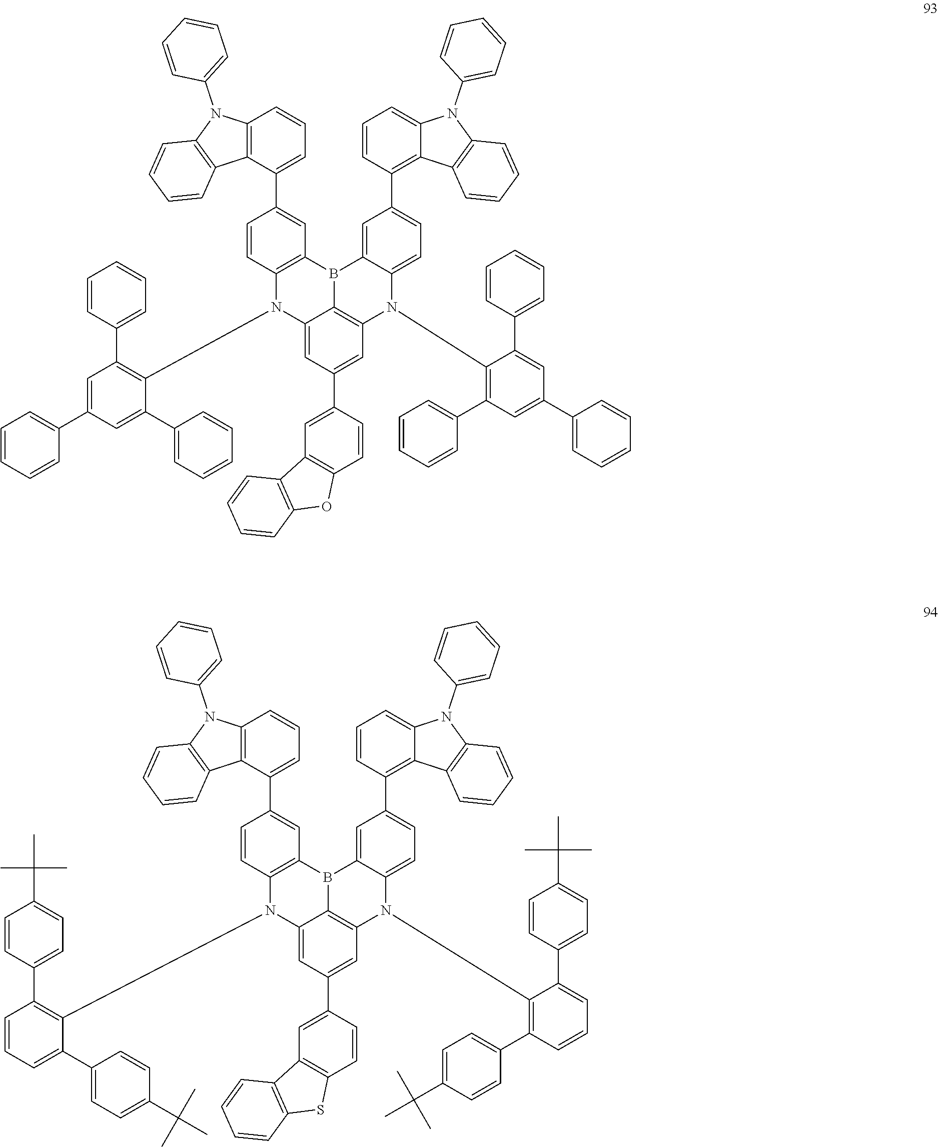 [SMILES: c1ccc(-c2cc(-c3ccccc3)c(N3c4ccc(-c5cccc6c5c5ccccc5n6-c5ccccc5)cc4B4c5cc(-c6cccc7c6c6ccccc6n7-c6ccccc6)ccc5N(c5c(-c6ccccc6)cc(-c6ccccc6)cc5-c5ccccc5)c5cc(-c6ccc7oc8ccccc8c7c6)cc3c54)c(-c3ccccc3)c2)cc1 ; CC(C)(C)c1ccc(-c2cccc(-c3ccc(C(C)(C)C)cc3)c2N2c3ccc(-c4cccc5c4c4ccccc4n5-c4ccccc4)cc3B3c4cc(-c5cccc6c5c5ccccc5n6-c5ccccc5)ccc4N(c4c(-c5ccc(C(C)(C)C)cc5)cccc4-c4ccc(C(C)(C)C)cc4)c4cc(-c5ccc6sc7ccccc7c6c5)cc2c43)cc1]

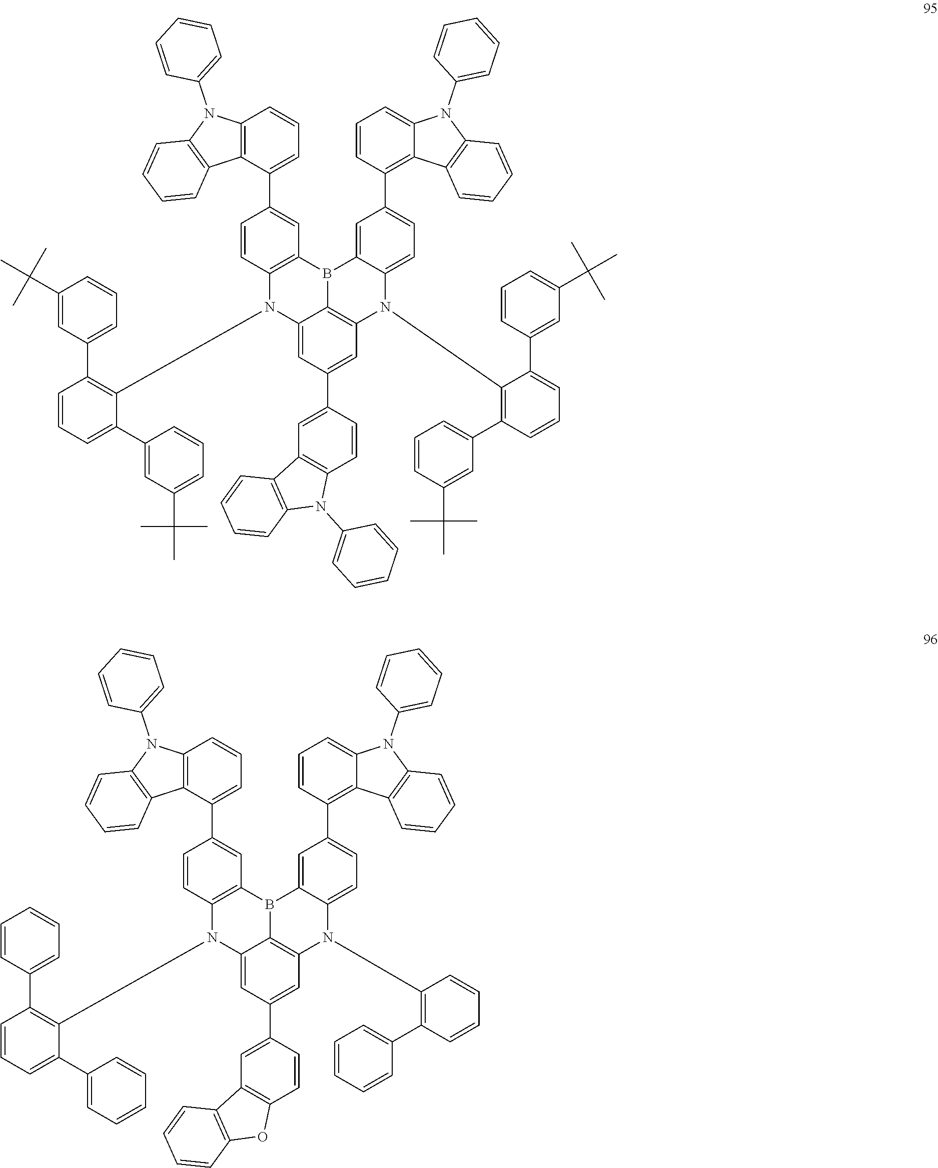 [SMILES: CC(C)(C)c1cccc(-c2cccc(-c3cccc(C(C)(C)C)c3)c2N2c3ccc(-c4cccc5c4c4ccccc4n5-c4ccccc4)cc3B3c4cc(-c5cccc6c5c5ccccc5n6-c5ccccc5)ccc4N(c4c(-c5cccc(C(C)(C)C)c5)cccc4-c4cccc(C(C)(C)C)c4)c4cc(-c5ccc6c(c5)c5ccccc5n6-c5ccccc5)cc2c43)c1 ; c1ccc(-c2ccccc2N2c3ccc(-c4cccc5c4c4ccccc4n5-c4ccccc4)cc3B3c4cc(-c5cccc6c5c5ccccc5n6-c5ccccc5)ccc4N(c4c(-c5ccccc5)cccc4-c4ccccc4)c4cc(-c5ccc6oc7ccccc7c6c5)cc2c43)cc1]

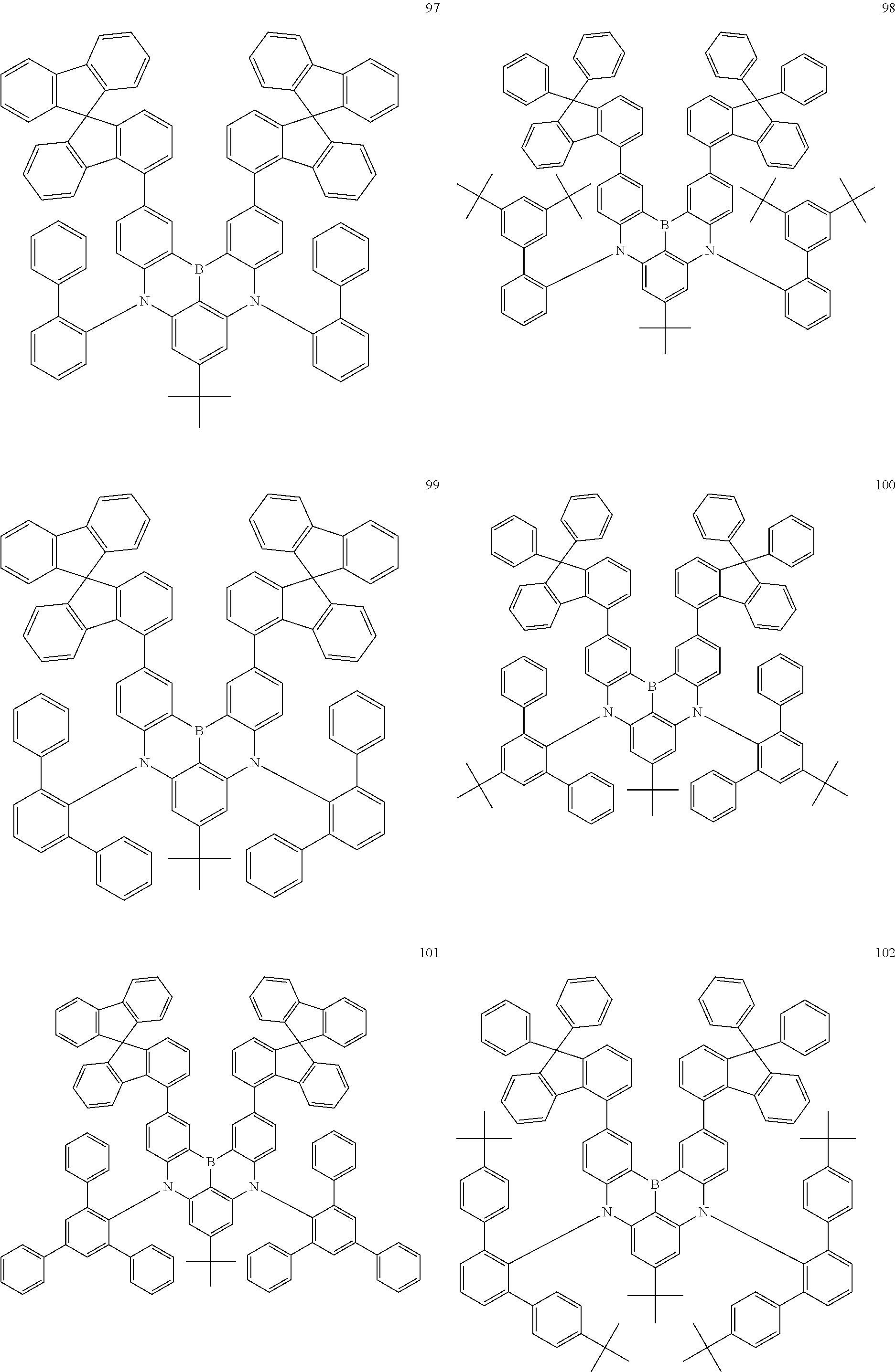

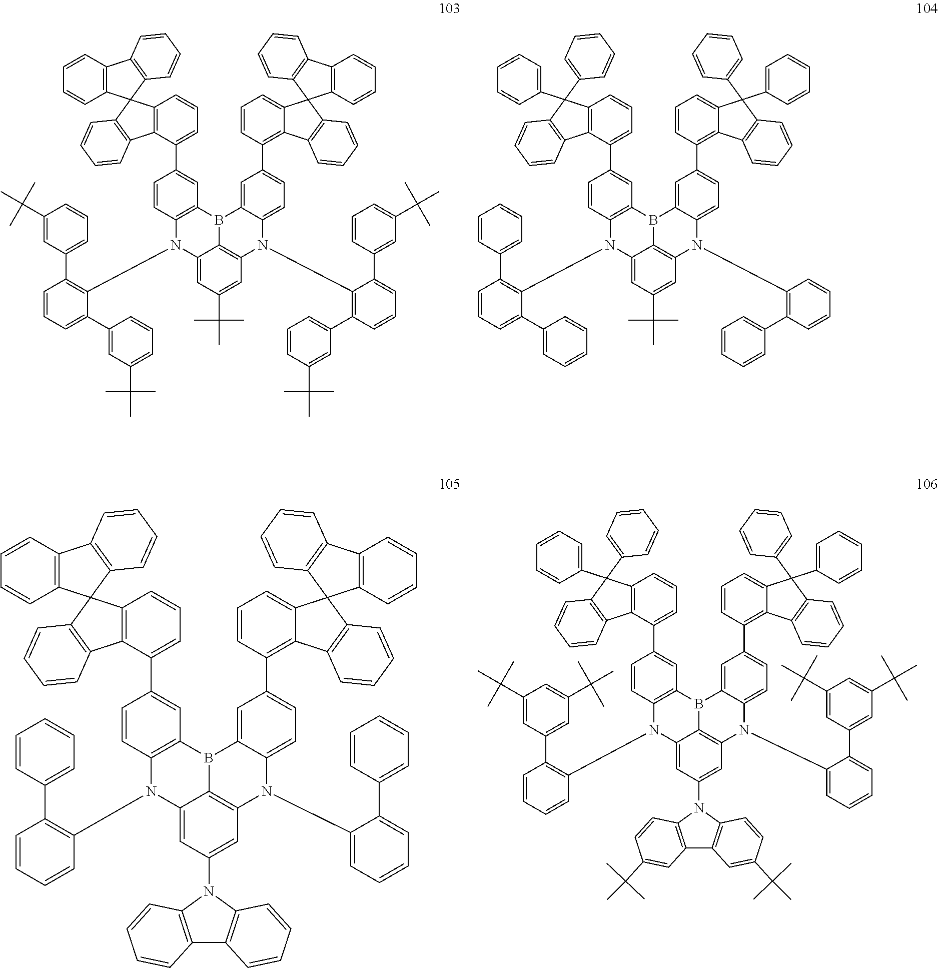

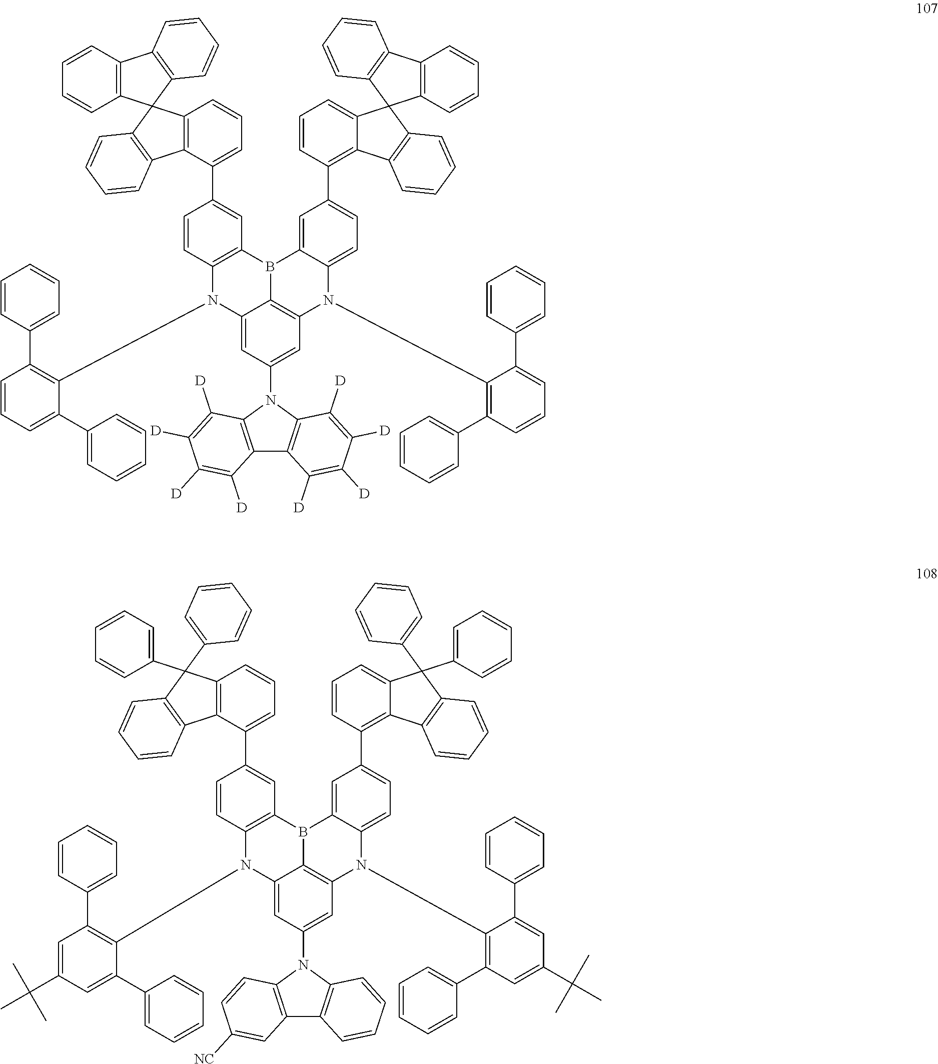 [SMILES: [2H]c1c([2H])c([2H])c2c(c1[2H])c1c([2H])c([2H])c([2H])c([2H])c1n2-c1cc2c3c(c1)N(c1c(-c4ccccc4)cccc1-c1ccccc1)c1ccc(-c4cccc5c4-c4ccccc4C54c5ccccc5-c5ccccc54)cc1B3c1cc(-c3cccc4c3-c3ccccc3C43c4ccccc4-c4ccccc43)ccc1N2c1c(-c2ccccc2)cccc1-c1ccccc1 ; CC(C)(C)c1cc(-c2ccccc2)c(N2c3ccc(-c4cccc5c4-c4ccccc4C5(c4ccccc4)c4ccccc4)cc3B3c4cc(-c5cccc6c5-c5ccccc5C6(c5ccccc5)c5ccccc5)ccc4N(c4c(-c5ccccc5)cc(C(C)(C)C)cc4-c4ccccc4)c4cc(-n5c6ccccc6c6cc(C#N)ccc65)cc2c43)c(-c2ccccc2)c1]

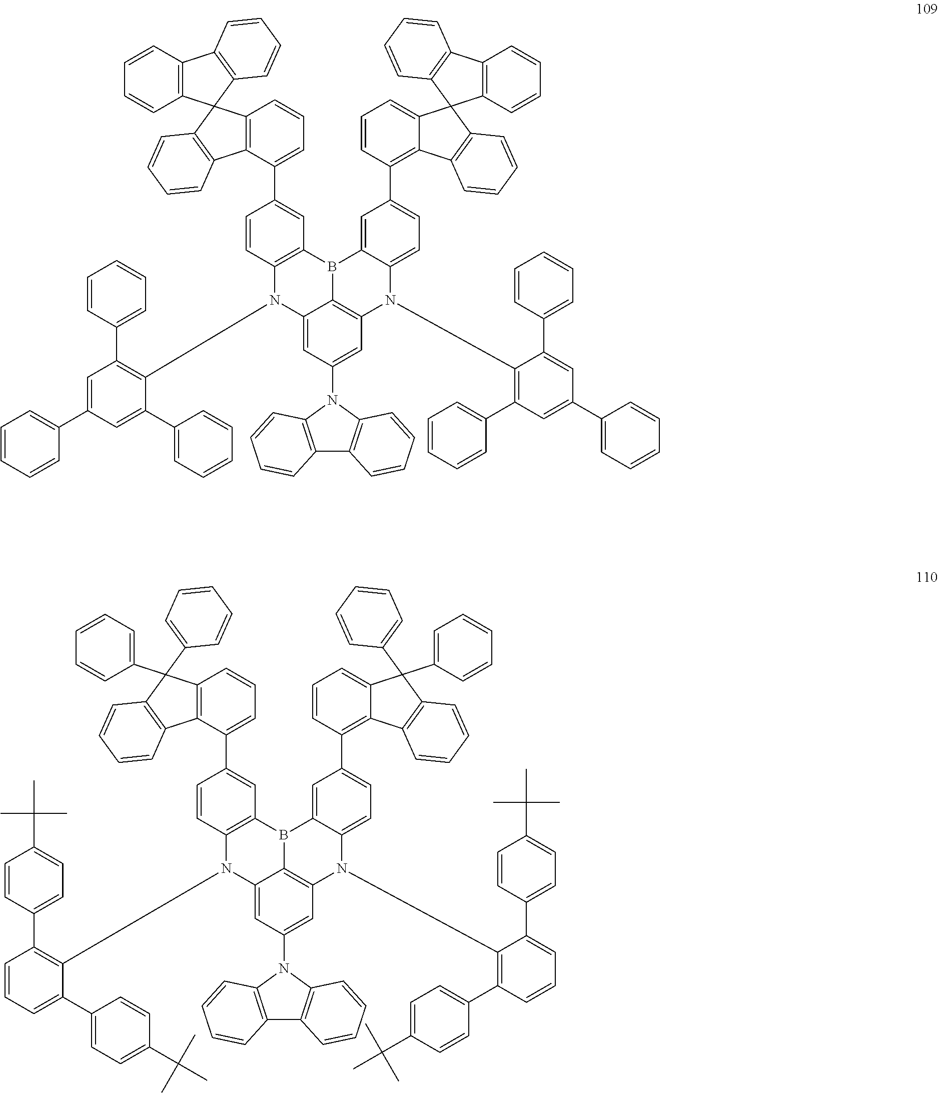 [SMILES: c1ccc(-c2cc(-c3ccccc3)c(N3c4ccc(-c5cccc6c5-c5ccccc5C65c6ccccc6-c6ccccc65)cc4B4c5cc(-c6cccc7c6-c6ccccc6C76c7ccccc7-c7ccccc76)ccc5N(c5c(-c6ccccc6)cc(-c6ccccc6)cc5-c5ccccc5)c5cc(-n6c7ccccc7c7ccccc76)cc3c54)c(-c3ccccc3)c2)cc1 ; CC(C)(C)c1ccc(-c2cccc(-c3ccc(C(C)(C)C)cc3)c2N2c3ccc(-c4cccc5c4-c4ccccc4C5(c4ccccc4)c4ccccc4)cc3B3c4cc(-c5cccc6c5-c5ccccc5C6(c5ccccc5)c5ccccc5)ccc4N(c4c(-c5ccc(C(C)(C)C)cc5)cccc4-c4ccc(C(C)(C)C)cc4)c4cc(-n5c6ccccc6c6ccccc65)cc2c43)cc1]

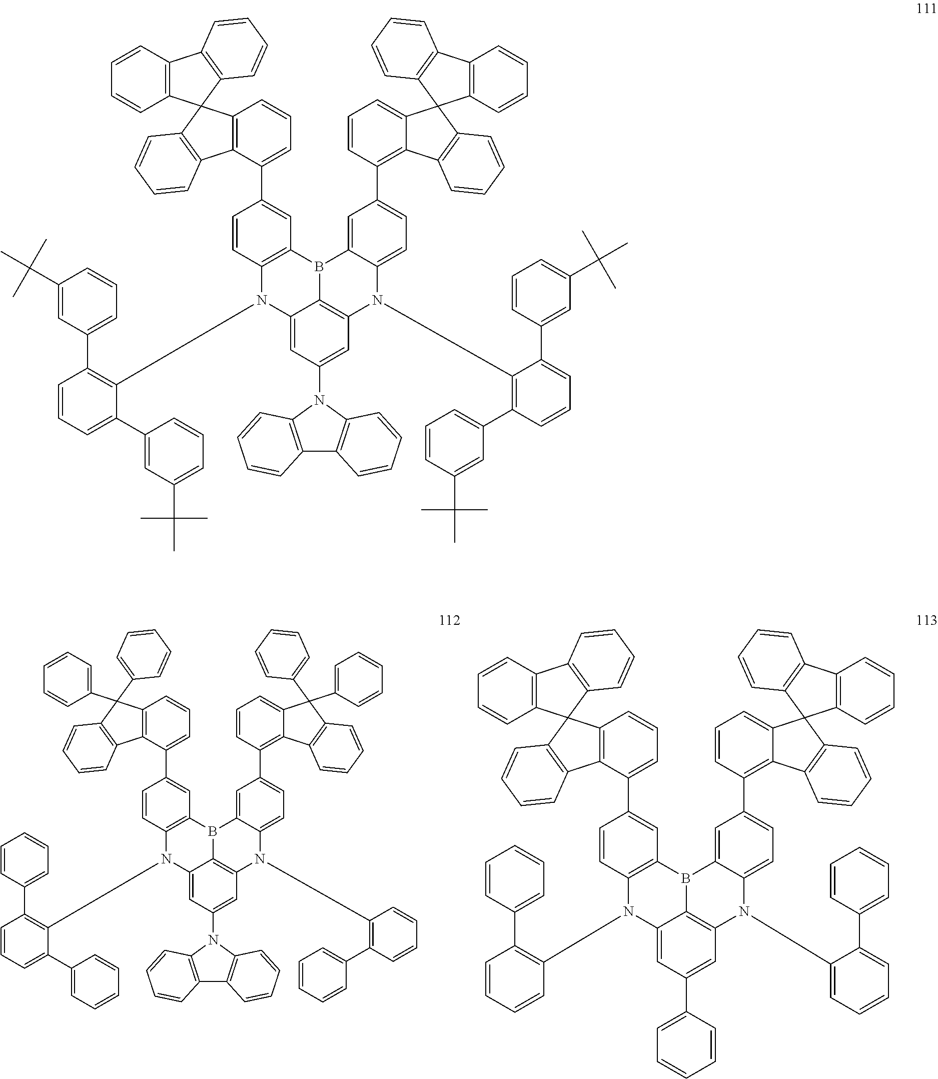

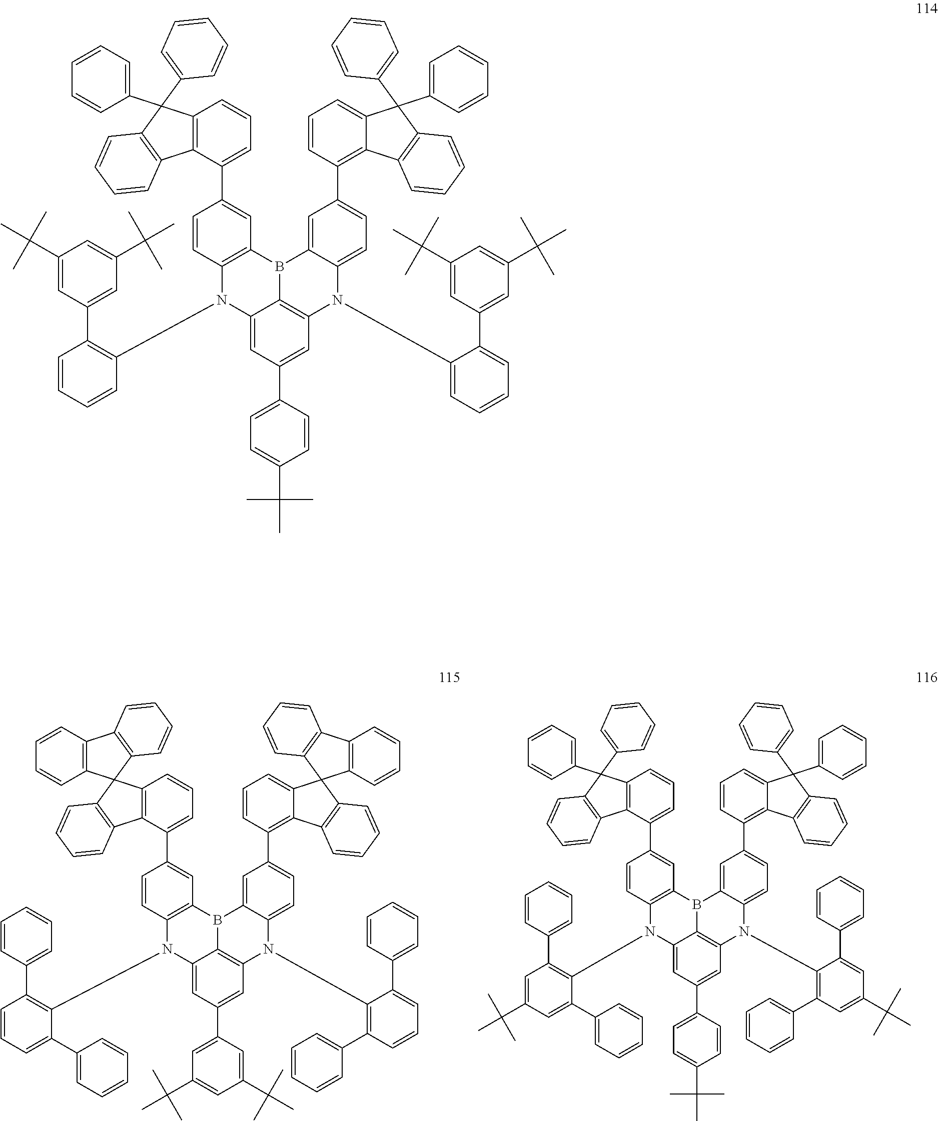

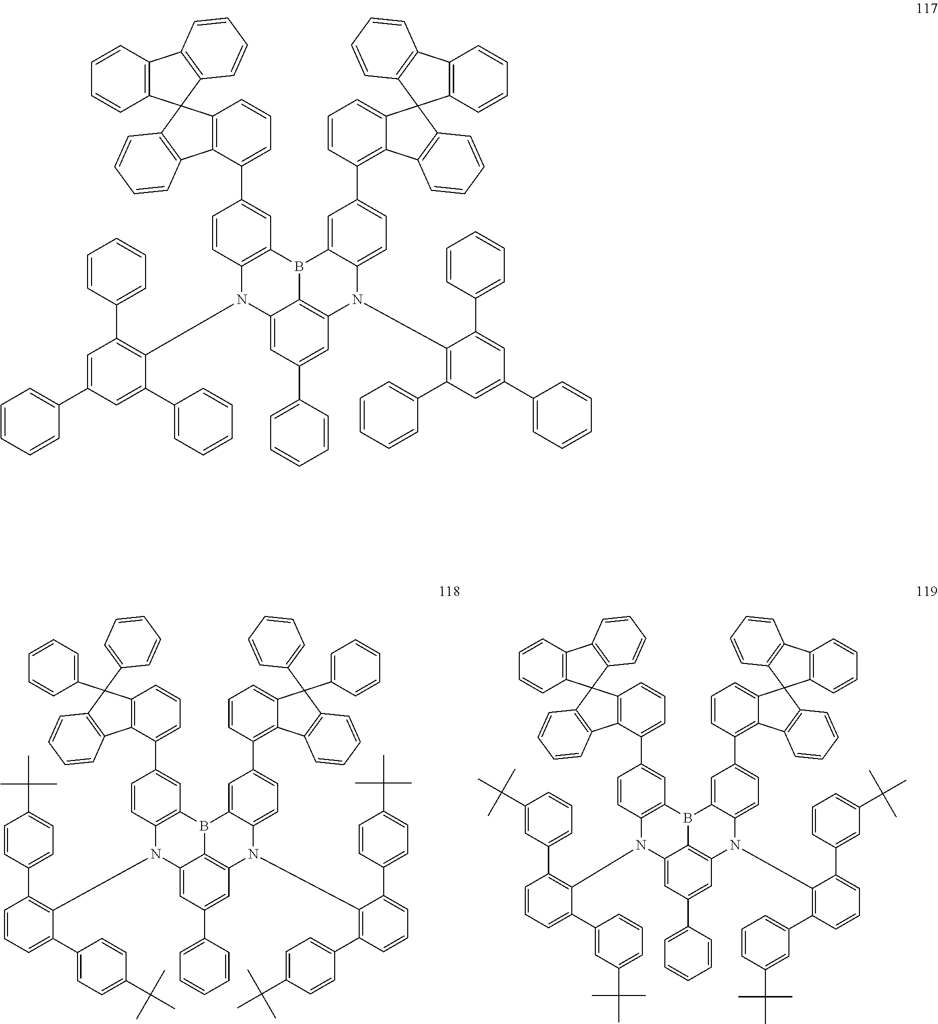

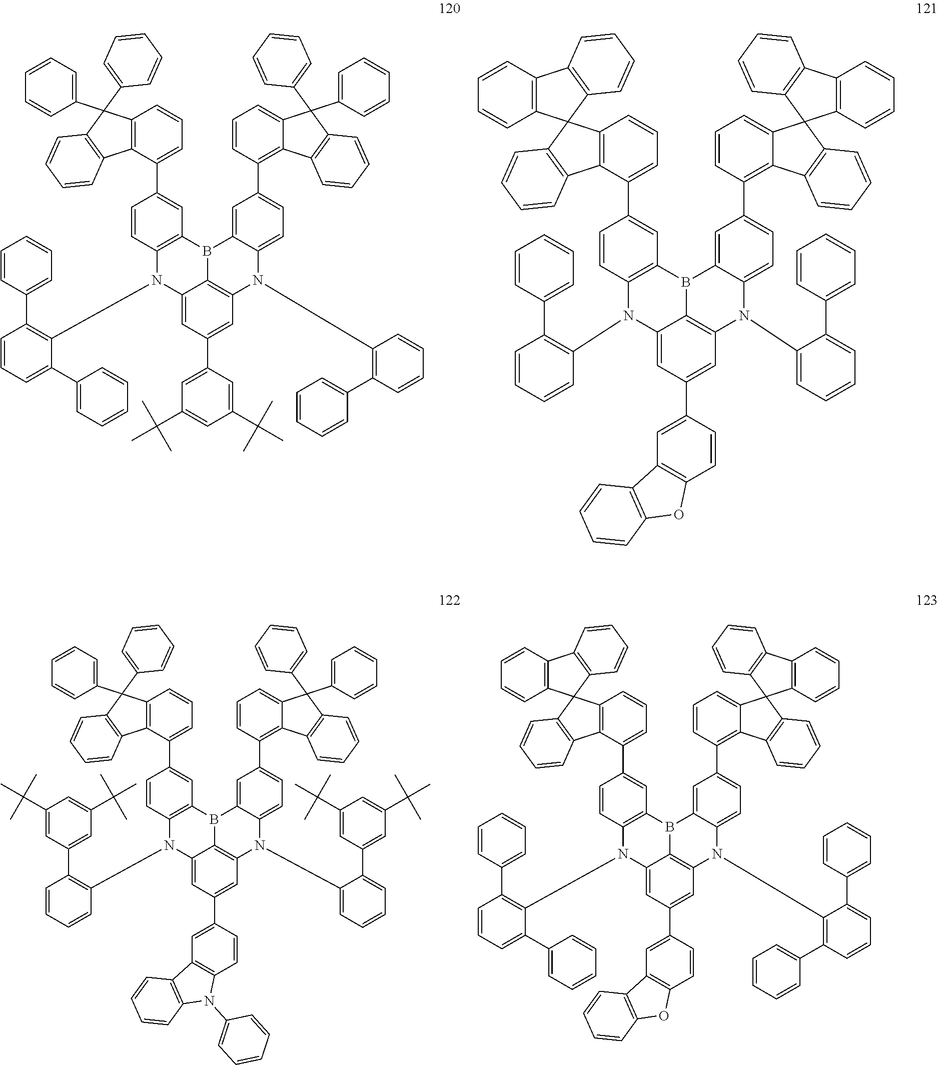

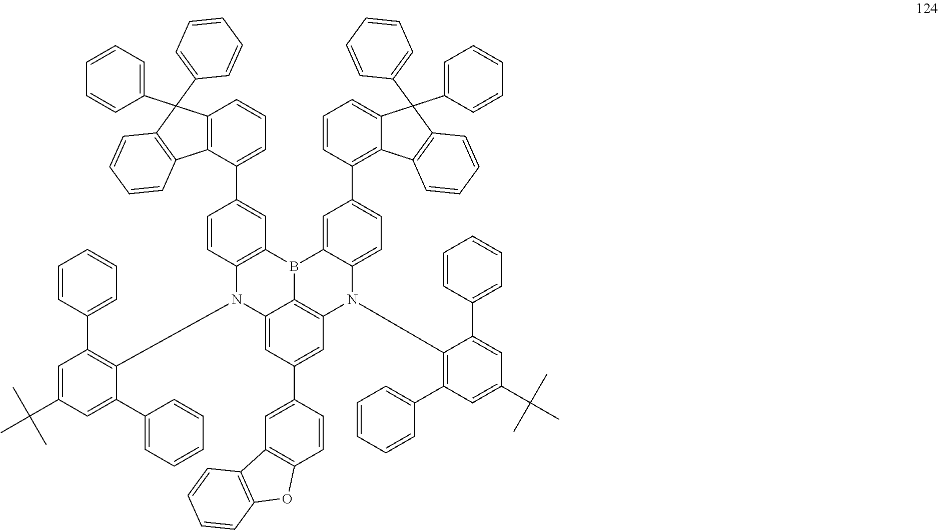 [SMILES: CC(C)(C)c1cc(-c2ccccc2)c(N2c3ccc(-c4cccc5c4-c4ccccc4C5(c4ccccc4)c4ccccc4)cc3B3c4cc(-c5cccc6c5-c5ccccc5C6(c5ccccc5)c5ccccc5)ccc4N(c4c(-c5ccccc5)cc(C(C)(C)C)cc4-c4ccccc4)c4cc(-c5ccc6oc7ccccc7c6c5)cc2c43)c(-c2ccccc2)c1]

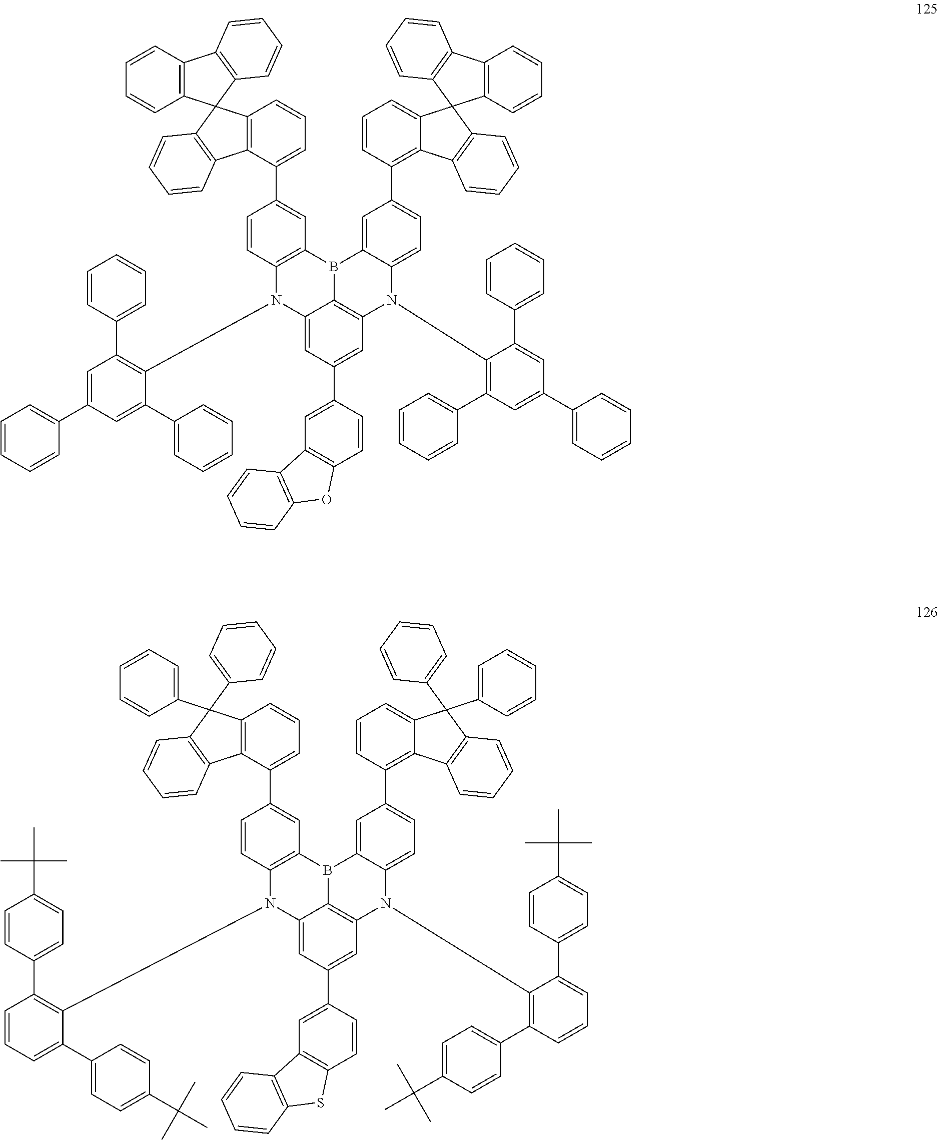 [SMILES: c1ccc(-c2cc(-c3ccccc3)c(N3c4ccc(-c5cccc6c5-c5ccccc5C65c6ccccc6-c6ccccc65)cc4B4c5cc(-c6cccc7c6-c6ccccc6C76c7ccccc7-c7ccccc76)ccc5N(c5c(-c6ccccc6)cc(-c6ccccc6)cc5-c5ccccc5)c5cc(-c6ccc7oc8ccccc8c7c6)cc3c54)c(-c3ccccc3)c2)cc1 ; CC(C)(C)c1ccc(-c2cccc(-c3ccc(C(C)(C)C)cc3)c2N2c3ccc(-c4cccc5c4-c4ccccc4C5(c4ccccc4)c4ccccc4)cc3B3c4cc(-c5cccc6c5-c5ccccc5C6(c5ccccc5)c5ccccc5)ccc4N(c4c(-c5ccc(C(C)(C)C)cc5)cccc4-c4ccc(C(C)(C)C)cc4)c4cc(-c5ccc6sc7ccccc7c6c5)cc2c43)cc1]

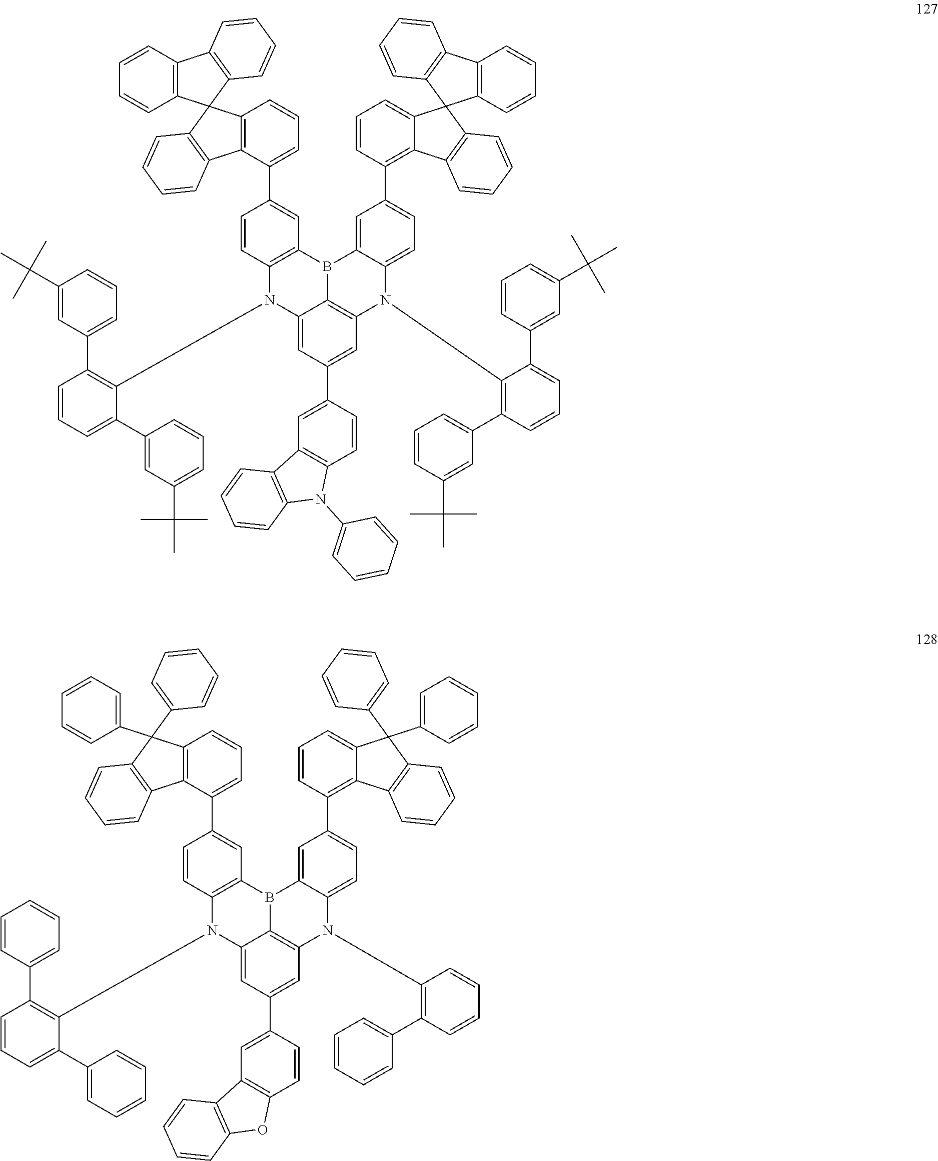 [SMILES: CC(C)(C)c1cccc(-c2cccc(-c3cccc(C(C)(C)C)c3)c2N2c3ccc(-c4cccc5c4-c4ccccc4C54c5ccccc5-c5ccccc54)cc3B3c4cc(-c5cccc6c5-c5ccccc5C65c6ccccc6-c6ccccc65)ccc4N(c4c(-c5cccc(C(C)(C)C)c5)cccc4-c4cccc(C(C)(C)C)c4)c4cc(-c5ccc6c(c5)c5ccccc5n6-c5ccccc5)cc2c43)c1 ; c1ccc(-c2ccccc2N2c3ccc(-c4cccc5c4-c4ccccc4C5(c4ccccc4)c4ccccc4)cc3B3c4cc(-c5cccc6c5-c5ccccc5C6(c5ccccc5)c5ccccc5)ccc4N(c4c(-c5ccccc5)cccc4-c4ccccc4)c4cc(-c5ccc6oc7ccccc7c6c5)cc2c43)cc1]

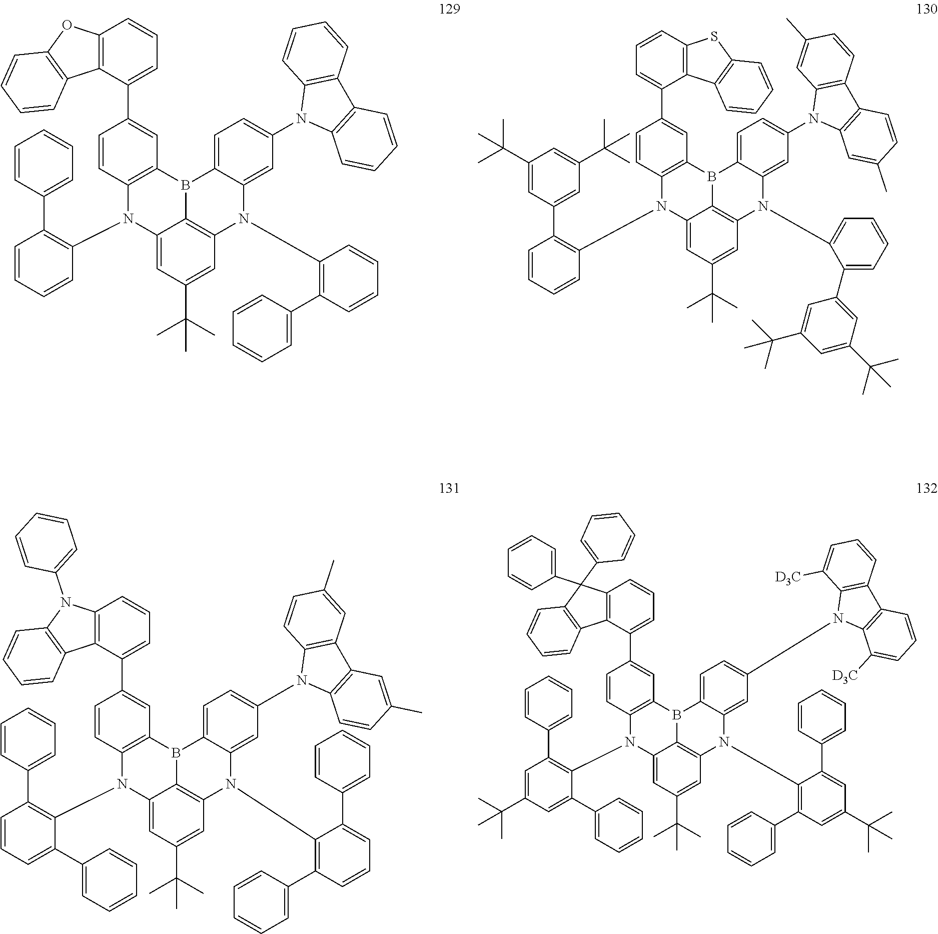

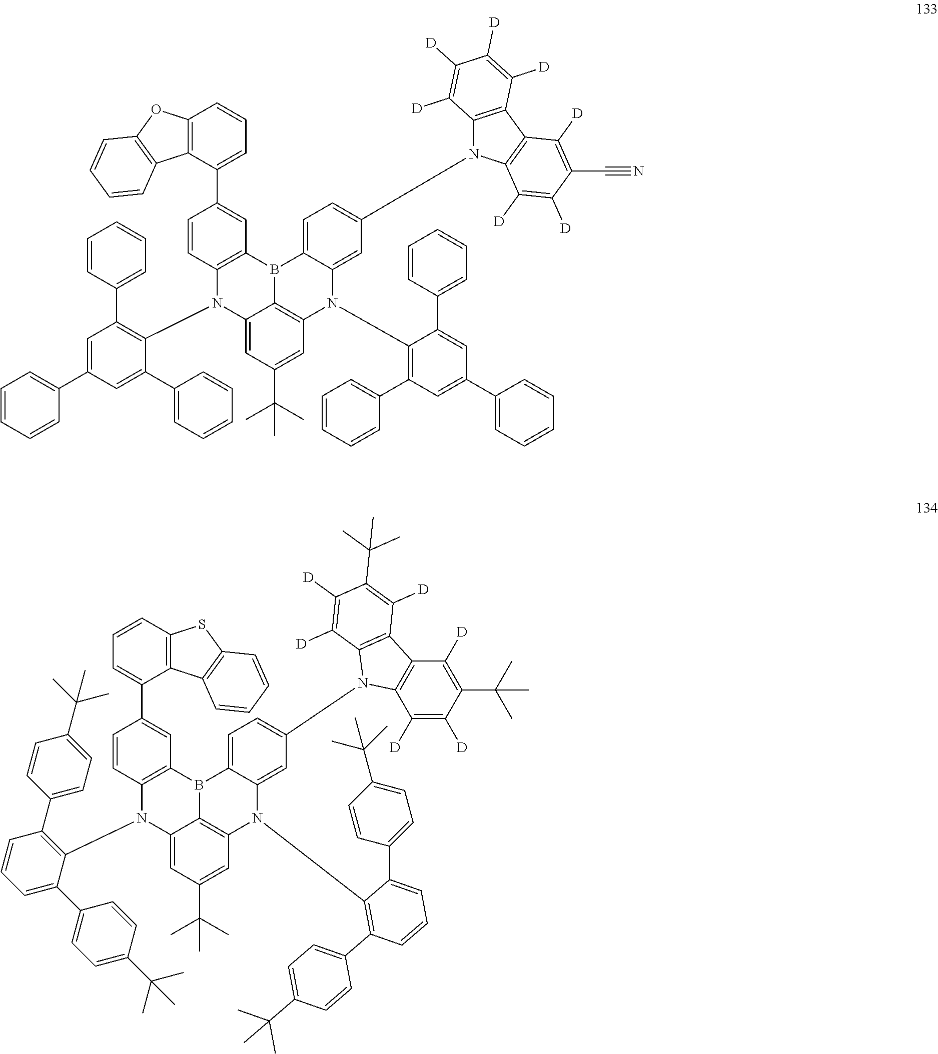 [SMILES: [2H]c1c([2H])c([2H])c2c(c1[2H])c1c([2H])c(C#N)c([2H])c([2H])c1n2-c1ccc2c(c1)N(c1c(-c3ccccc3)cc(-c3ccccc3)cc1-c1ccccc1)c1cc(C(C)(C)C)cc3c1B2c1cc(-c2cccc4oc5ccccc5c24)ccc1N3c1c(-c2ccccc2)cc(-c2ccccc2)cc1-c1ccccc1 ; [2H]c1c(C(C)(C)C)c([2H])c2c3c([2H])c(C(C)(C)C)c([2H])c([2H])c3n(-c3ccc4c(c3)N(c3c(-c5ccc(C(C)(C)C)cc5)cccc3-c3ccc(C(C)(C)C)cc3)c3cc(C(C)(C)C)cc5c3B4c3cc(-c4cccc6sc7ccccc7c46)ccc3N5c3c(-c4ccc(C(C)(C)C)cc4)cccc3-c3ccc(C(C)(C)C)cc3)c2c1[2H]]

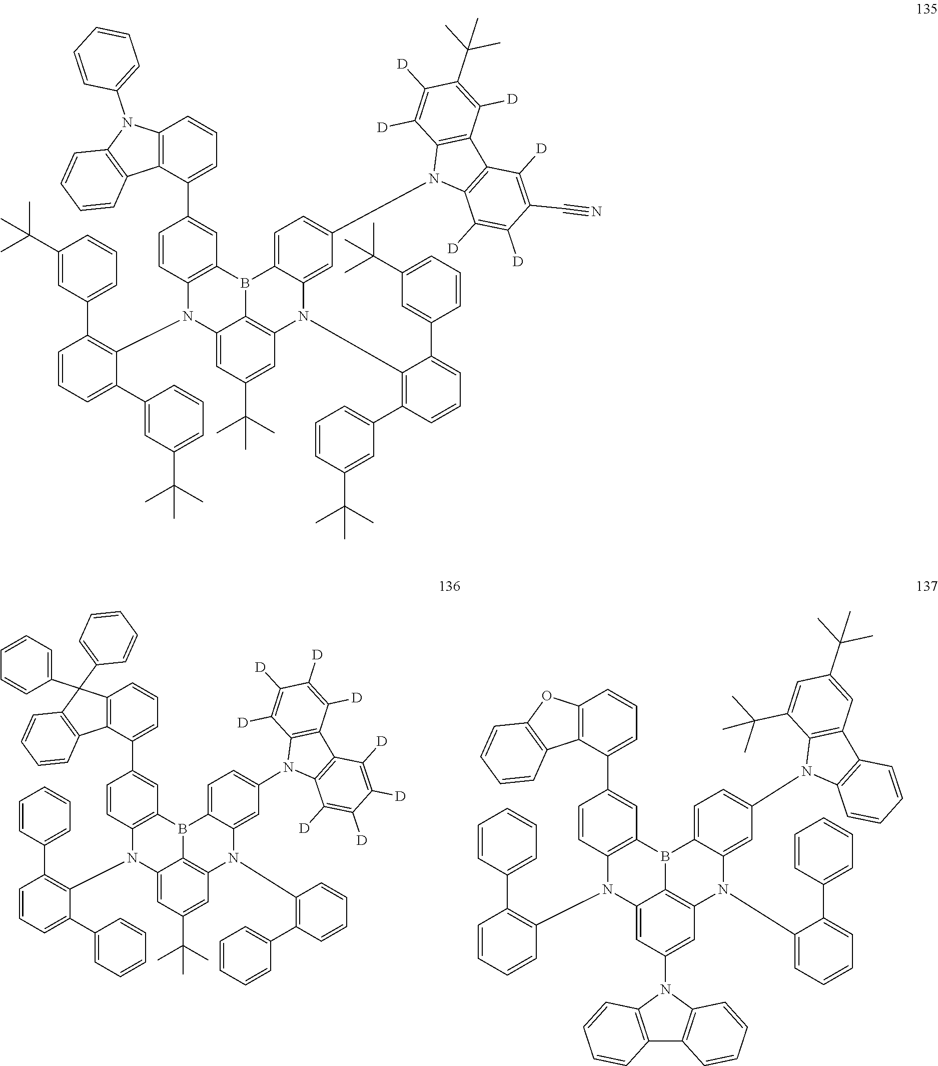

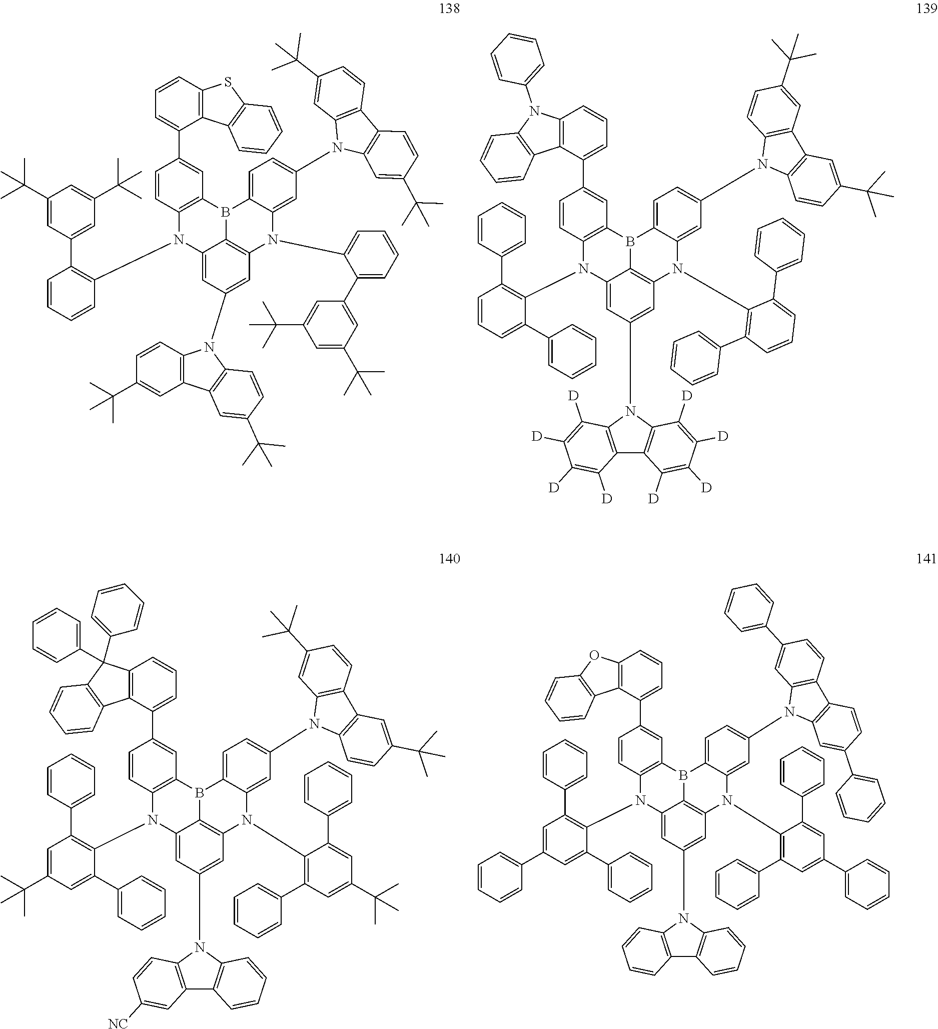

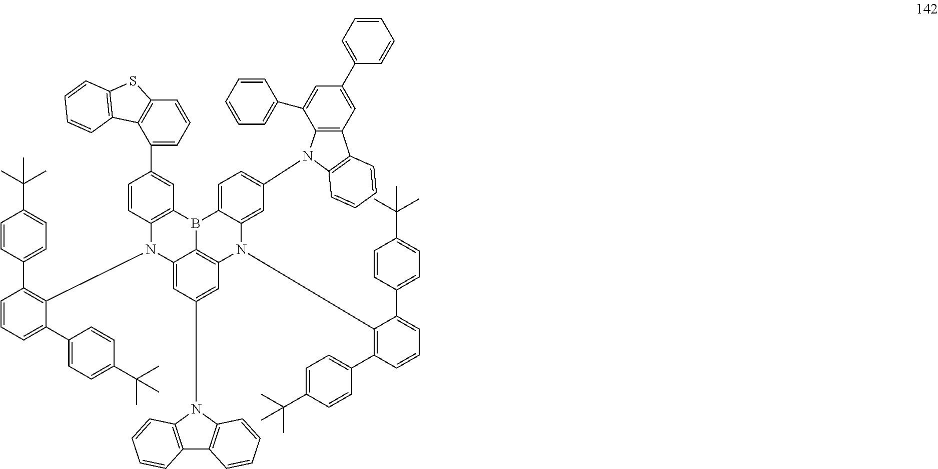 [SMILES: CC(C)(C)c1ccc(-c2cccc(-c3ccc(C(C)(C)C)cc3)c2N2c3ccc(-c4cccc5sc6ccccc6c45)cc3B3c4ccc(-n5c6ccccc6c6cc(-c7ccccc7)cc(-c7ccccc7)c65)cc4N(c4c(-c5ccc(C(C)(C)C)cc5)cccc4-c4ccc(C(C)(C)C)cc4)c4cc(-n5c6ccccc6c6ccccc65)cc2c43)cc1]

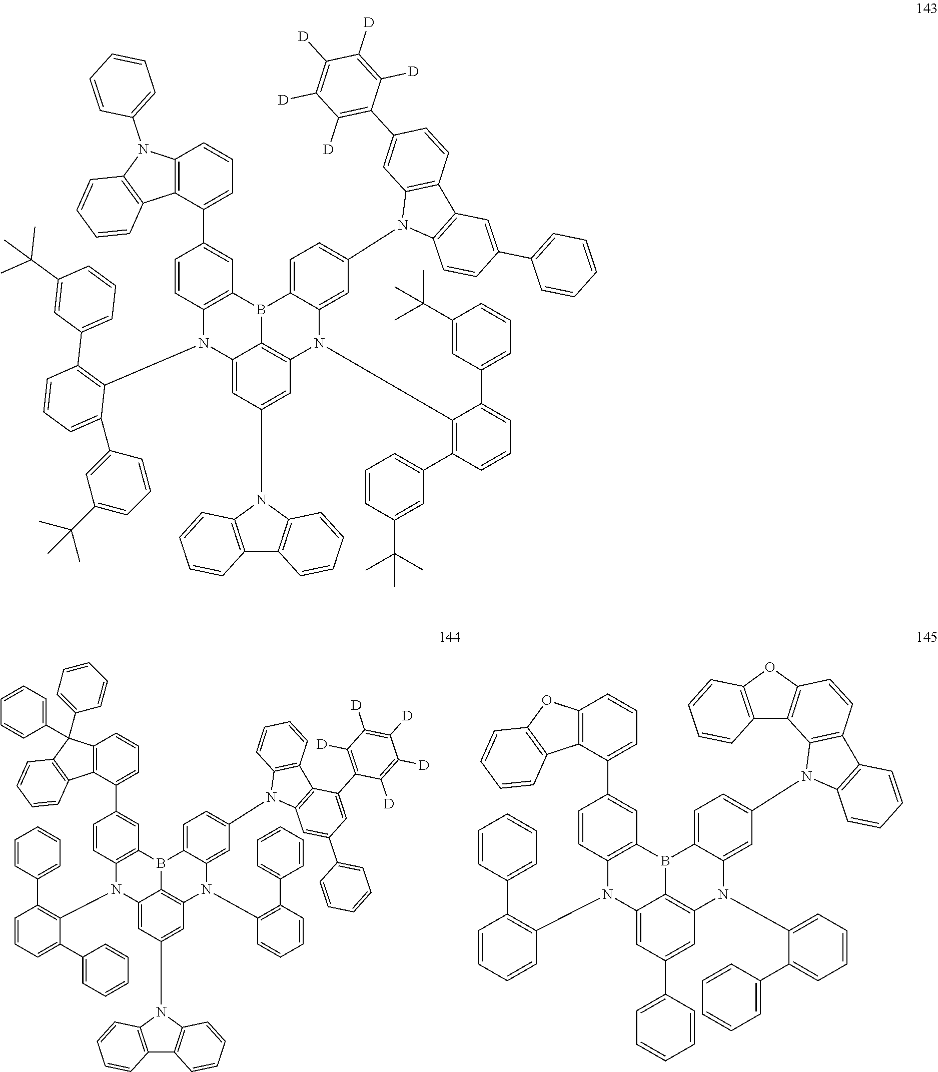

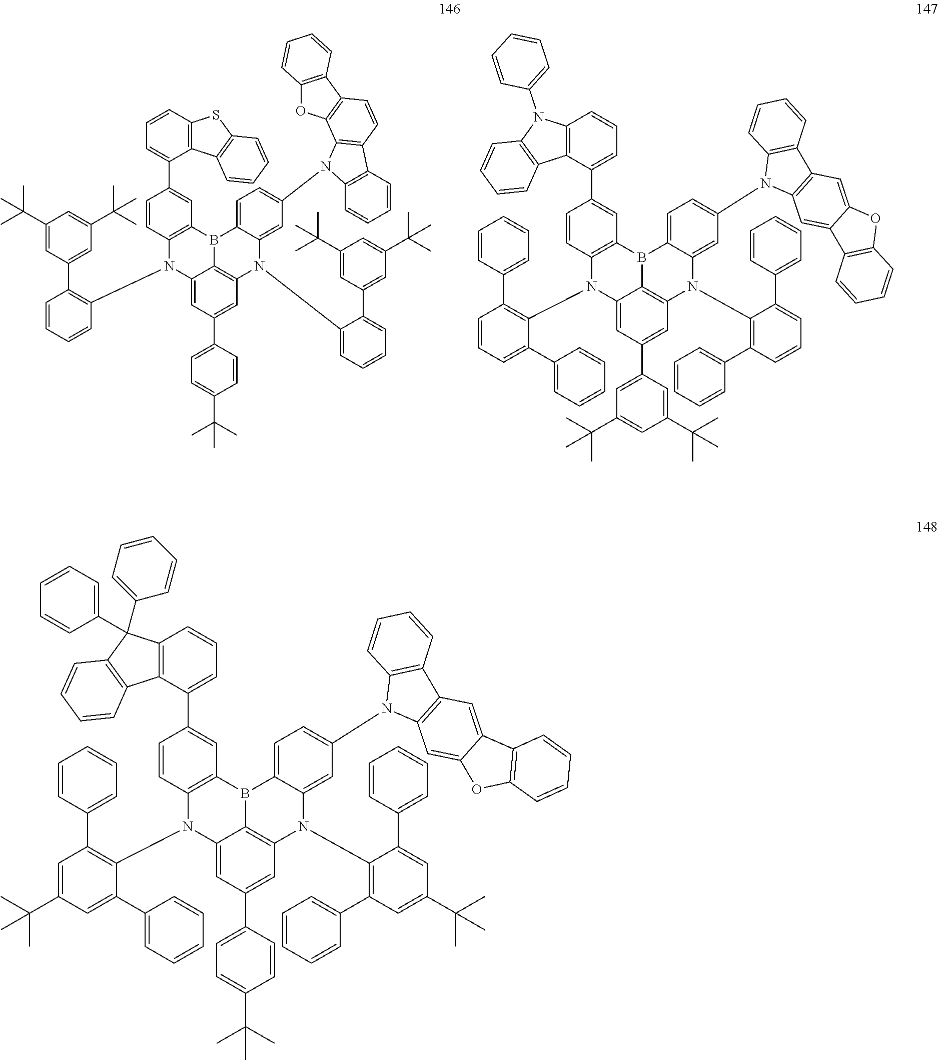

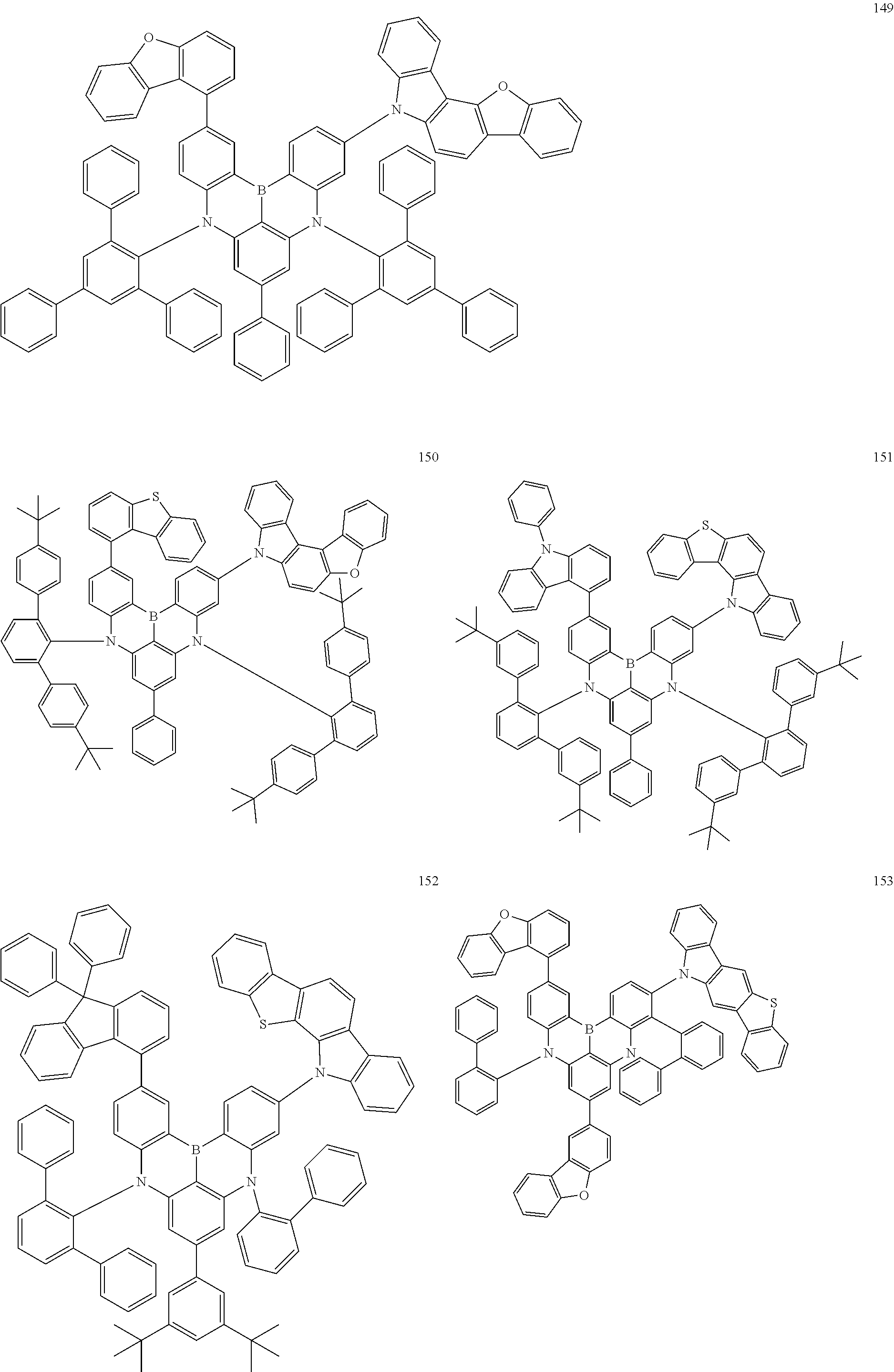

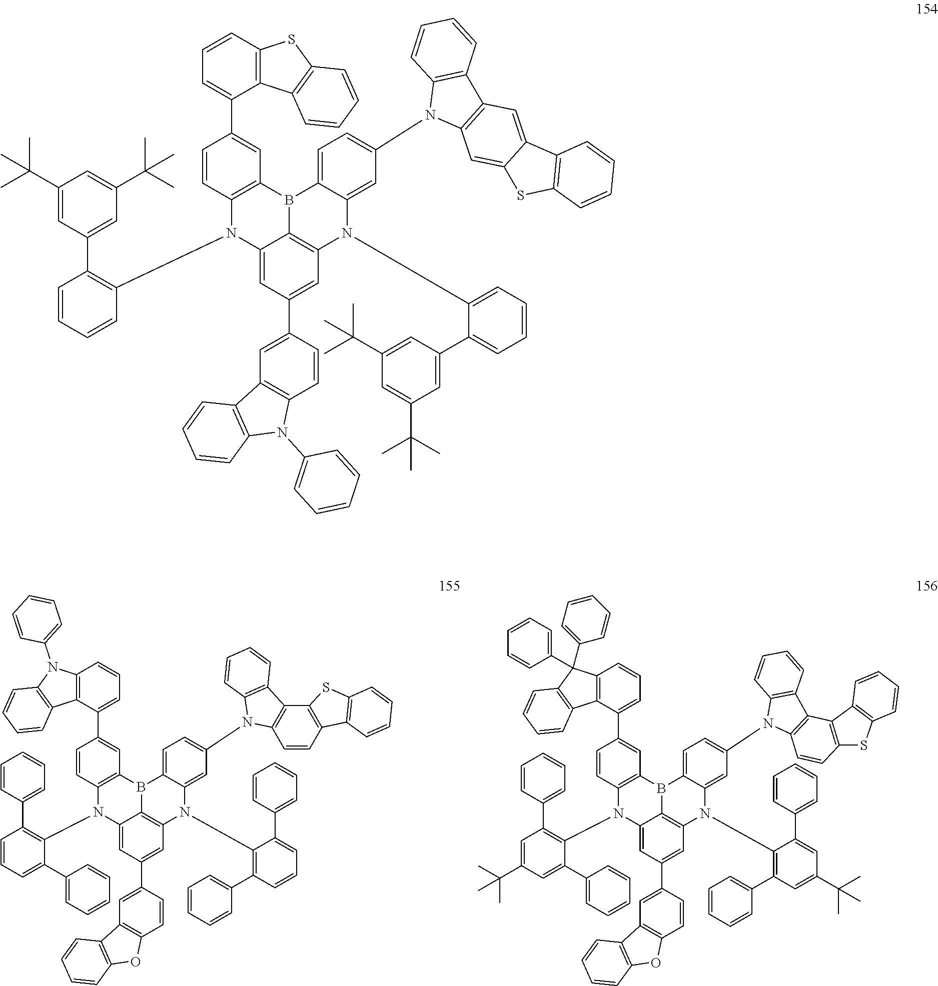

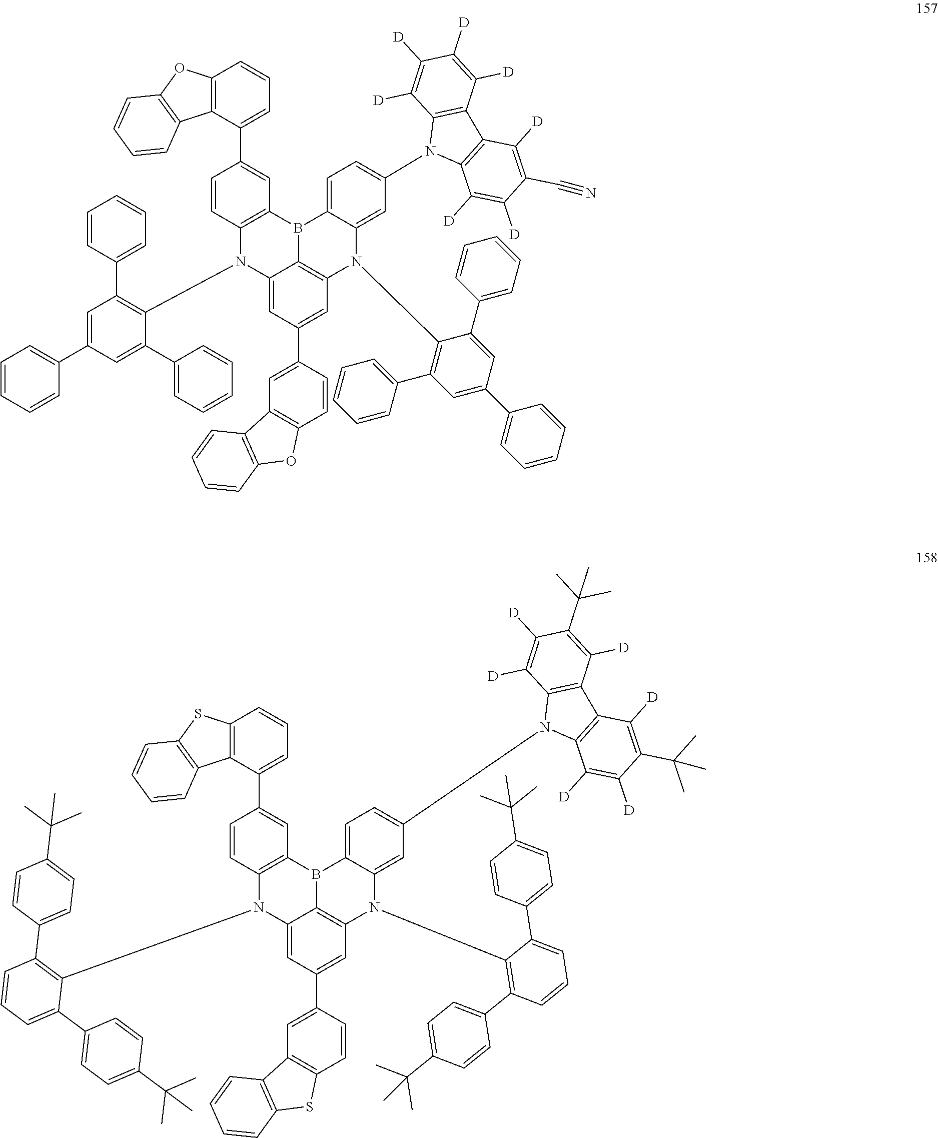 [SMILES: [2H]c1c([2H])c([2H])c2c(c1[2H])c1c([2H])c(C#N)c([2H])c([2H])c1n2-c1ccc2c(c1)N(c1c(-c3ccccc3)cc(-c3ccccc3)cc1-c1ccccc1)c1cc(-c3ccc4oc5ccccc5c4c3)cc3c1B2c1cc(-c2cccc4oc5ccccc5c24)ccc1N3c1c(-c2ccccc2)cc(-c2ccccc2)cc1-c1ccccc1 ; [2H]c1c(C(C)(C)C)c([2H])c2c3c([2H])c(C(C)(C)C)c([2H])c([2H])c3n(-c3ccc4c(c3)N(c3c(-c5ccc(C(C)(C)C)cc5)cccc3-c3ccc(C(C)(C)C)cc3)c3cc(-c5ccc6sc7ccccc7c6c5)cc5c3B4c3cc(-c4cccc6sc7ccccc7c46)ccc3N5c3c(-c4ccc(C(C)(C)C)cc4)cccc3-c3ccc(C(C)(C)C)cc3)c2c1[2H]]

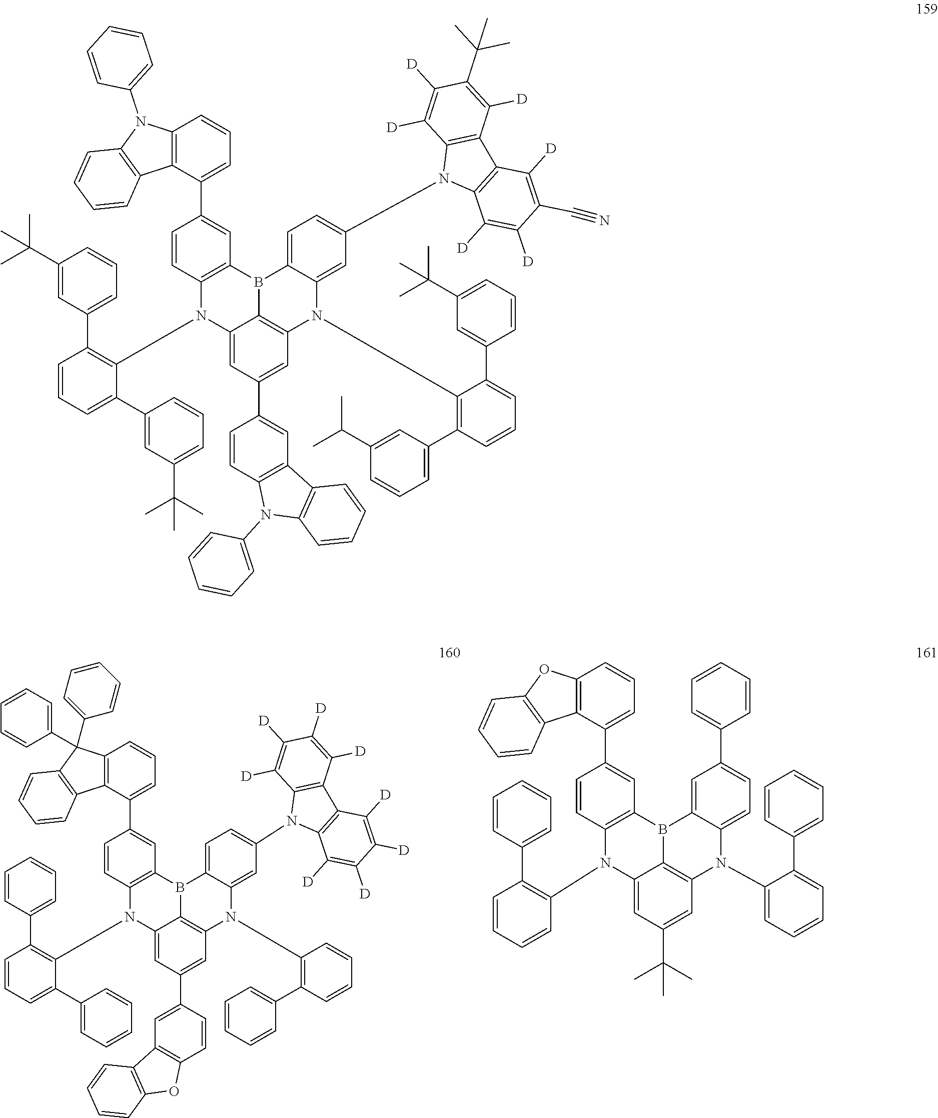

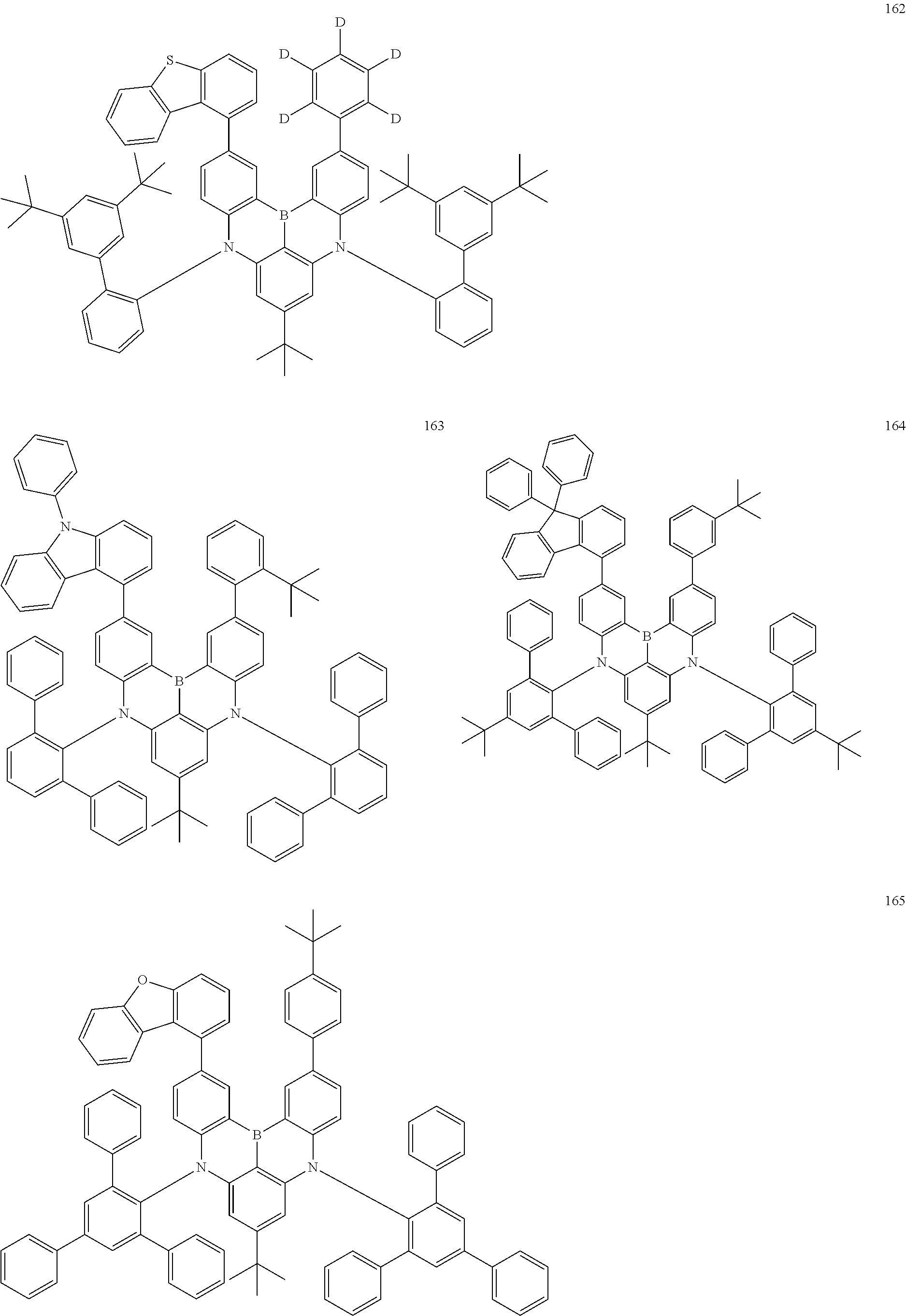

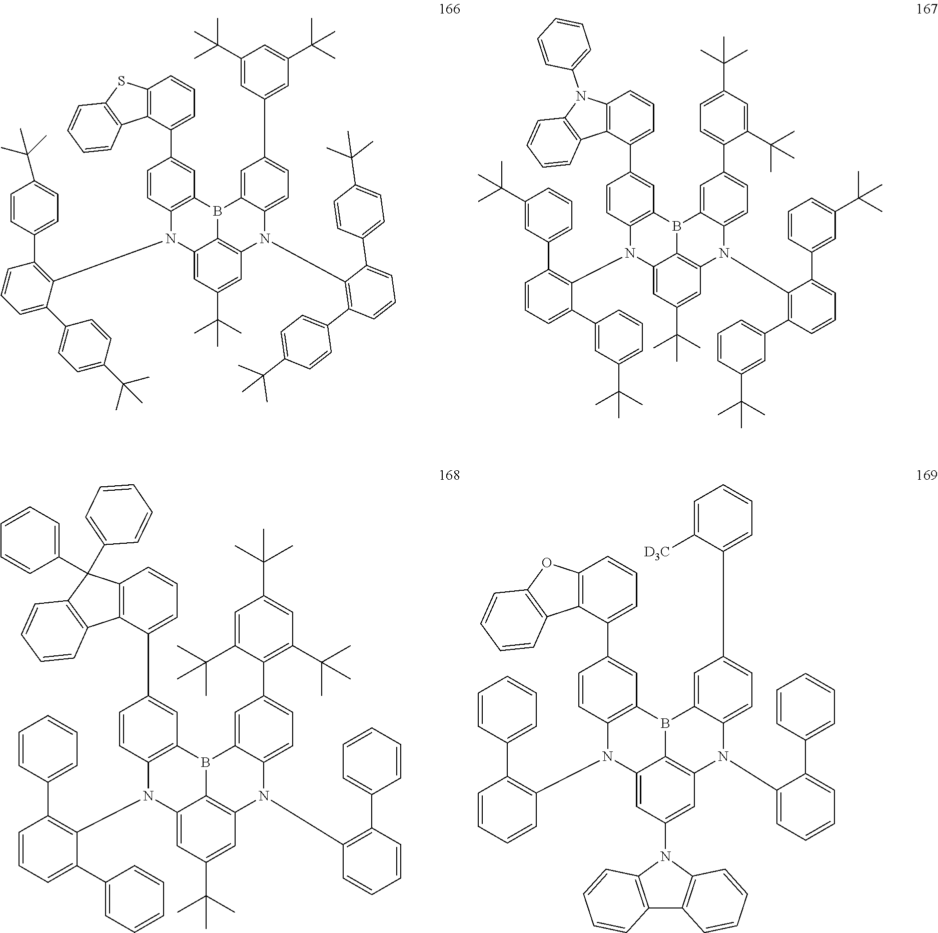

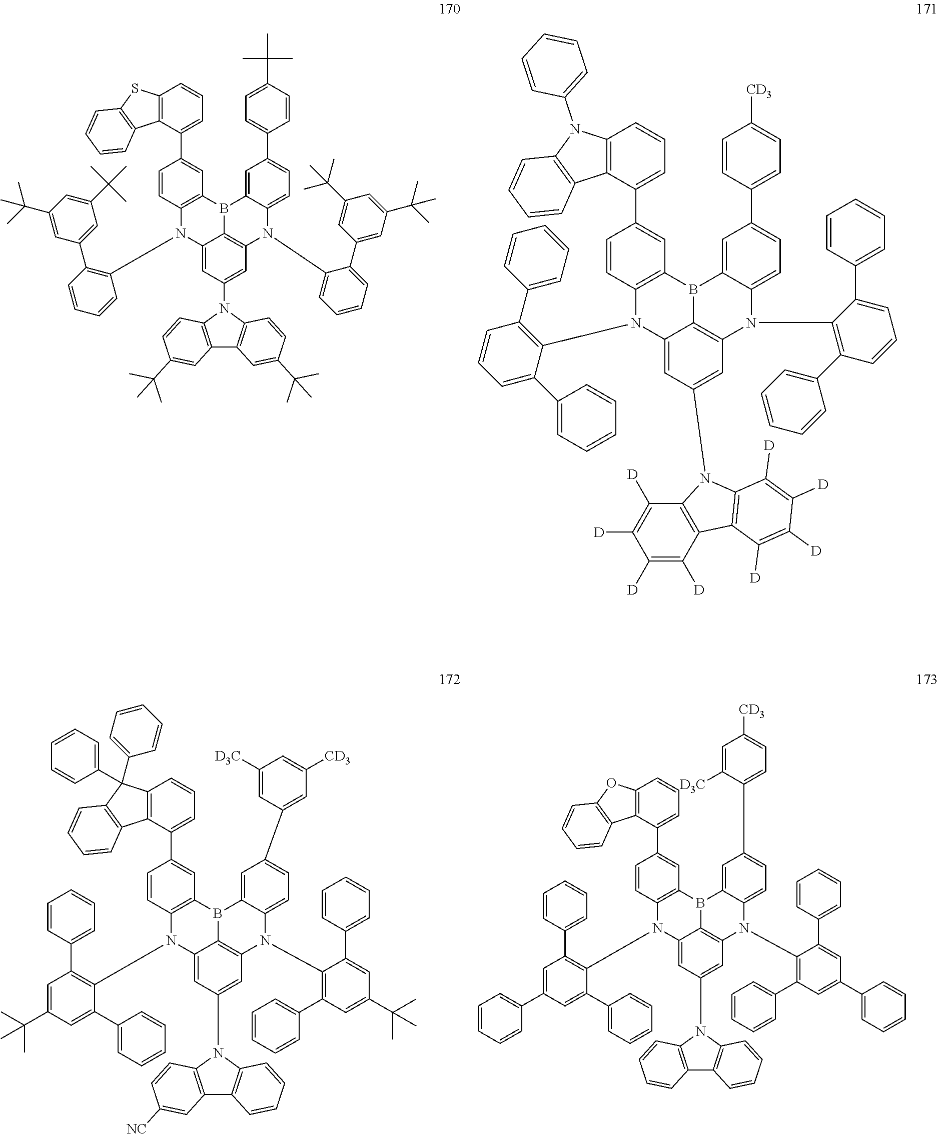

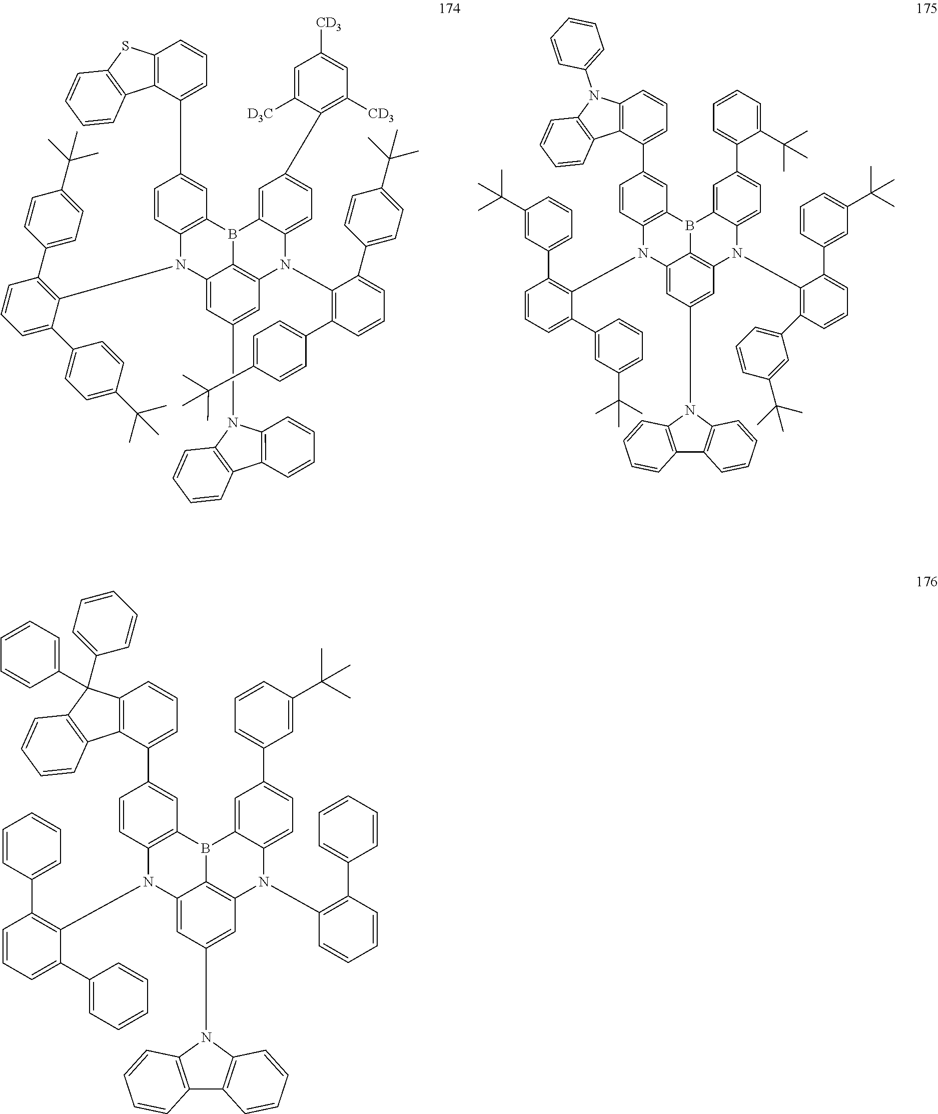

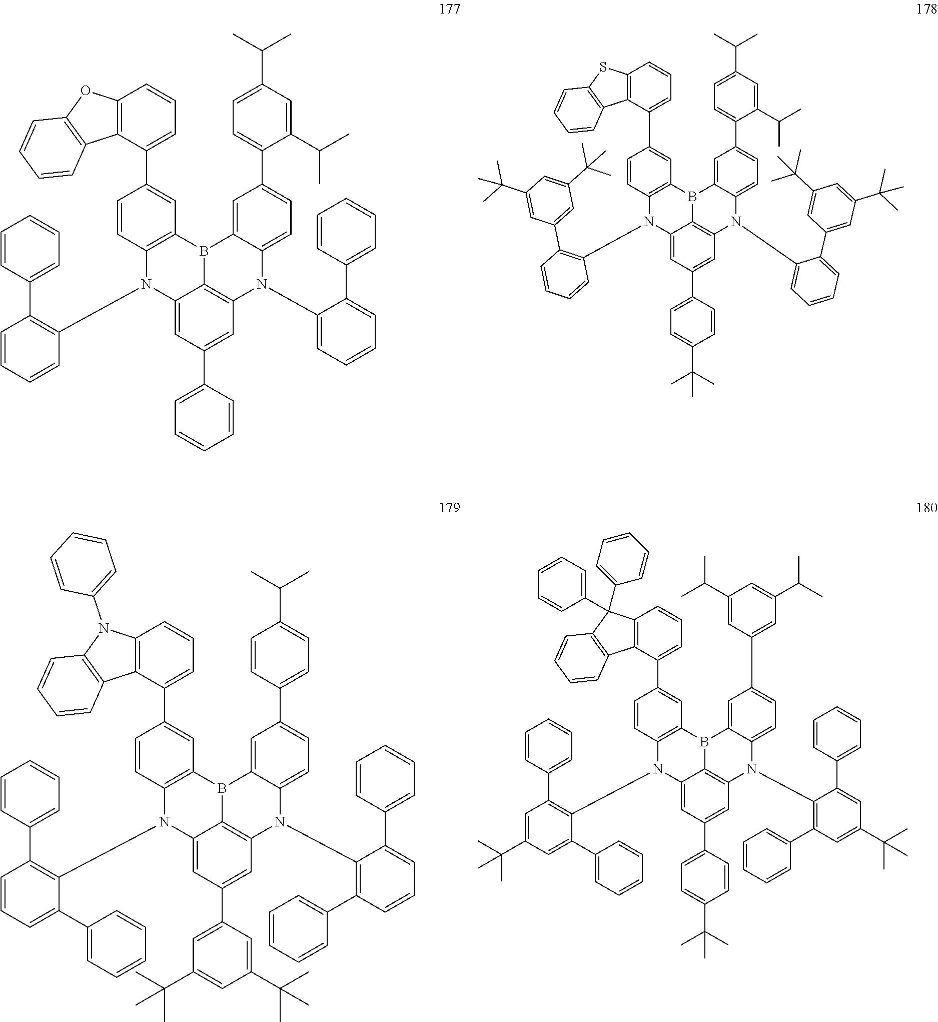

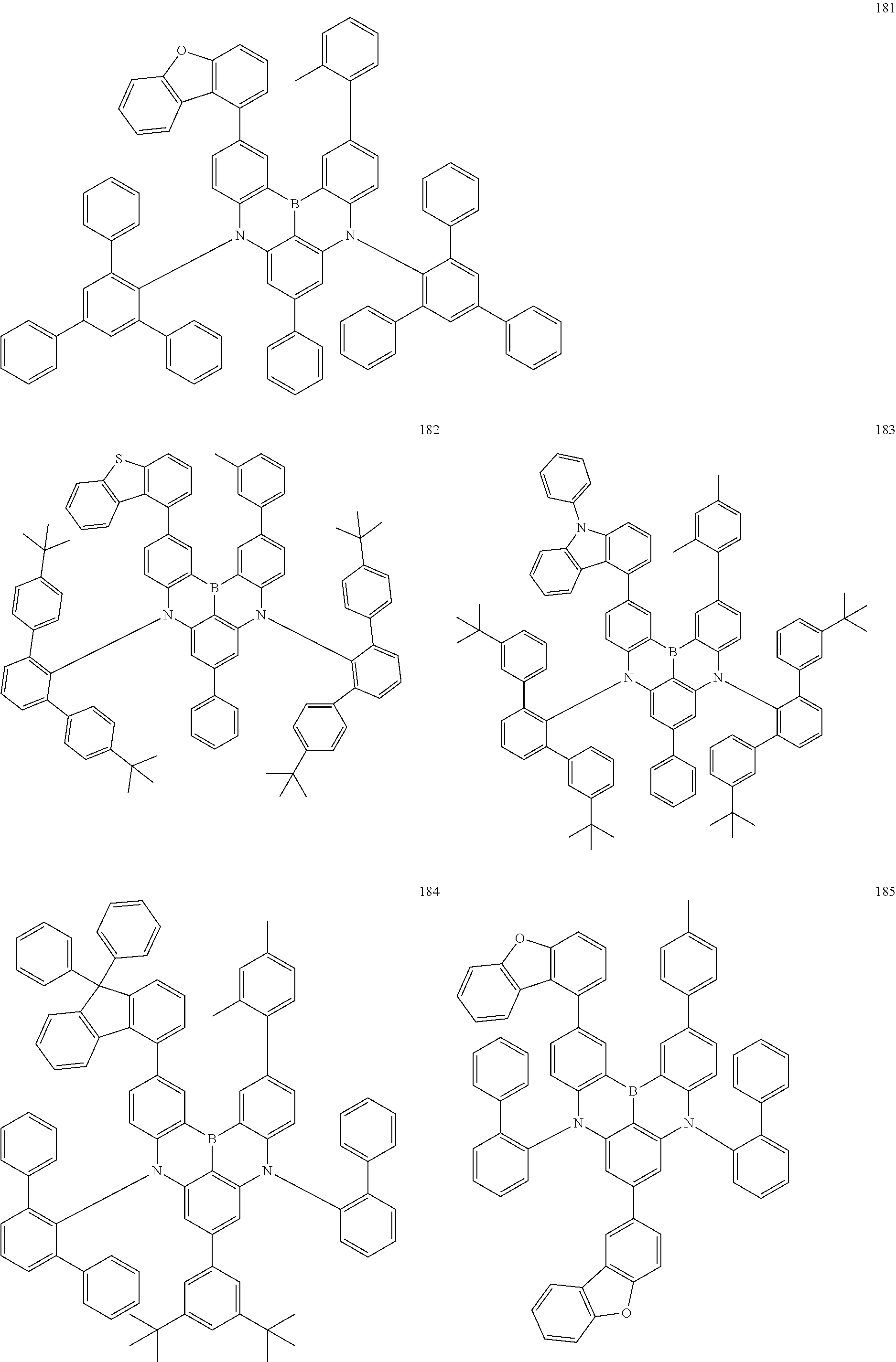

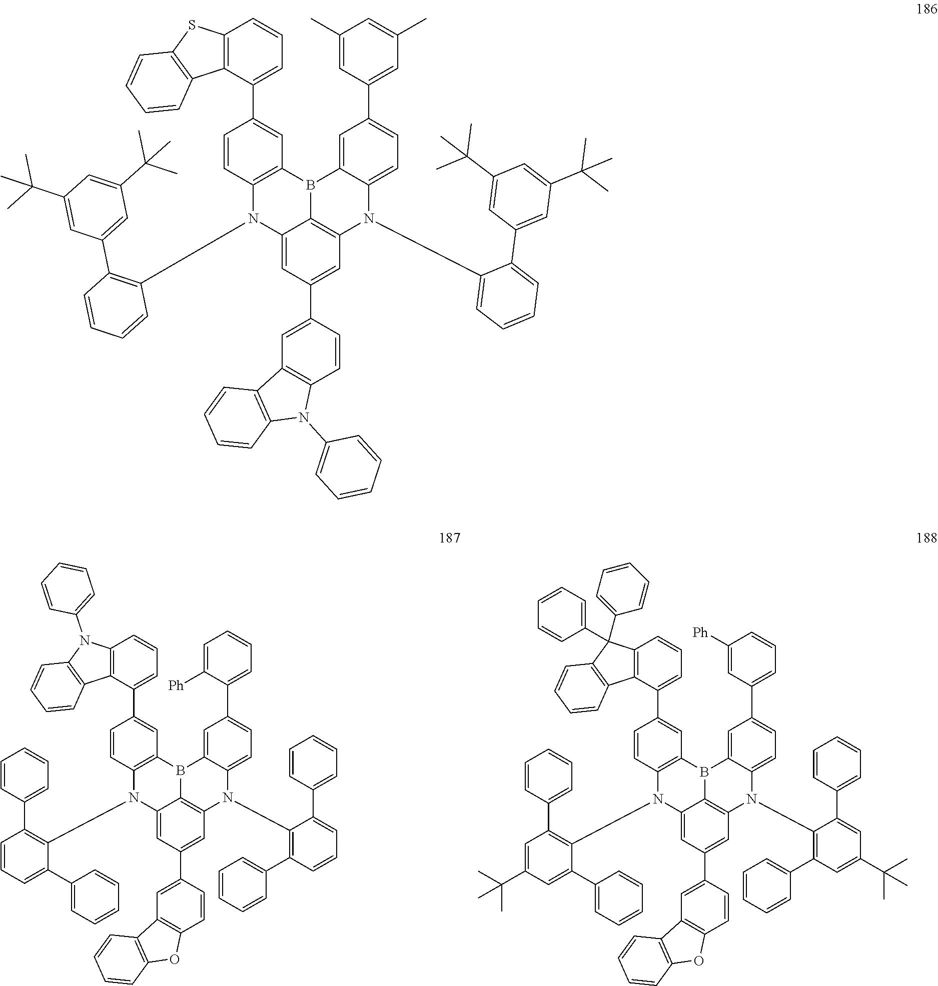

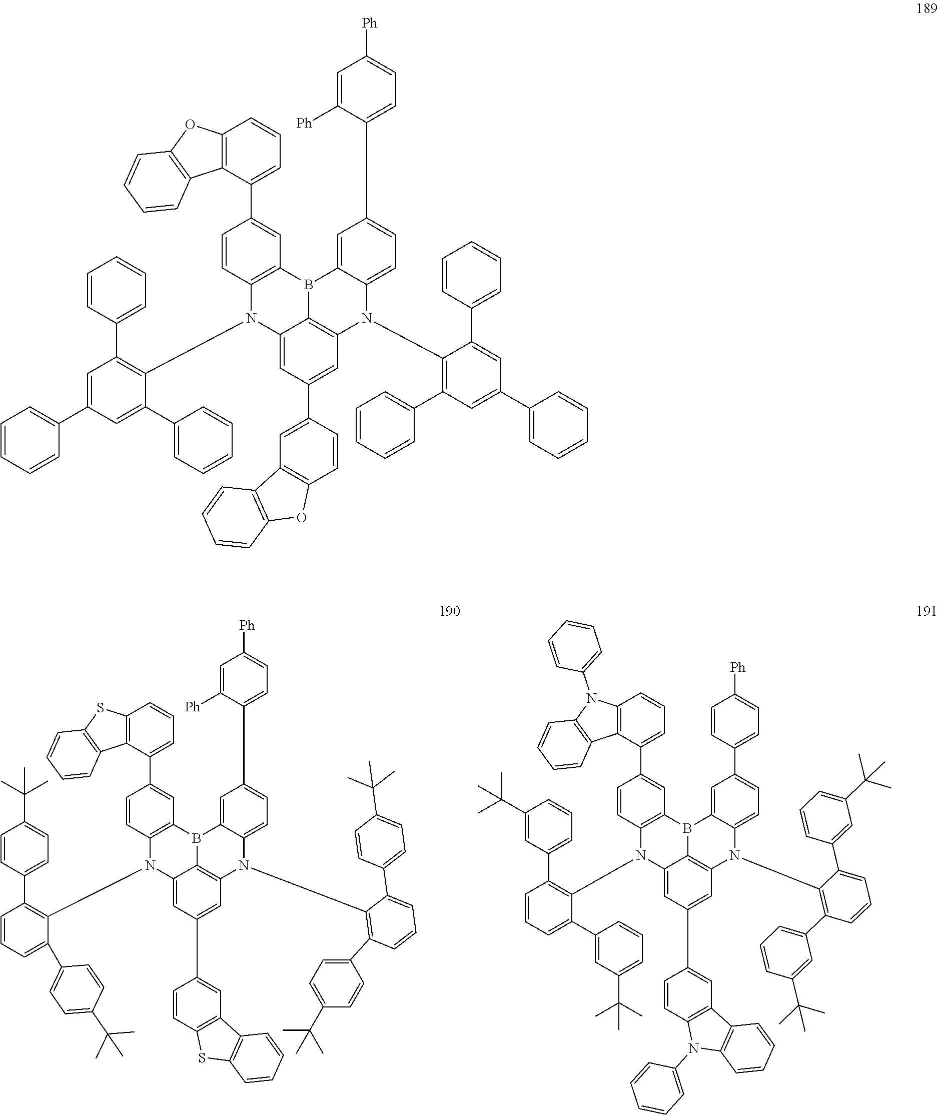

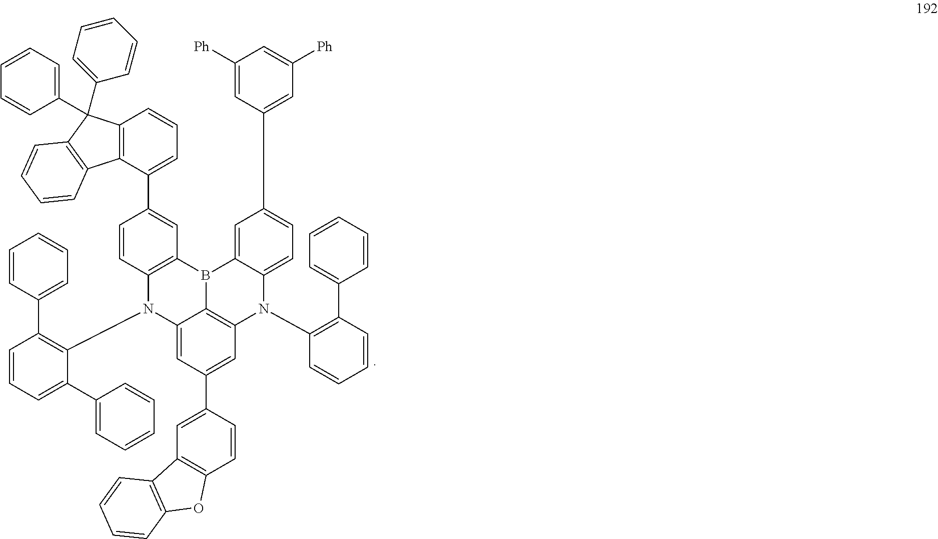 [SMILES: c1ccc(-c2cc(-c3ccccc3)cc(-c3ccc4c(c3)B3c5cc(-c6cccc7c6-c6ccccc6C7(c6ccccc6)c6ccccc6)ccc5N(c5c(-c6ccccc6)cccc5-c5ccccc5)c5cc(-c6ccc7oc8ccccc8c7c6)cc(c53)N4c3ccccc3-c3ccccc3)c2)cc1]

In the embodiment compounds presented in Compound Group 1, “D” refers to deuterium, and “Ph” refers to an unsubstituted phenyl group.

The fused polycyclic compound represented by Formula 1 according to one or more embodiments may include a structure in which the first substituent is introduced to the fused ring core at a specific position, and thus may achieve high luminous efficiency and long service life.

The fused polycyclic compound represented by Formula 1 of one or more embodiments may have a structure which includes the fused ring core in which the first to third aromatic rings are fused via the boron atom and the first and second nitrogen atoms, and in which the first substituent is linked to the second aromatic ring. In some embodiments, the fused polycyclic compound of one or more embodiments may have a feature in that carbon at position 4 of the first substituent is bonded to the second aromatic ring of the fused ring core. Consequently, the fused polycyclic compound of one or more embodiments may exhibit high luminous efficiency by having an increase in multiple resonance effects due to the first substituent. The carbon at the fourth carbon position of the first substituent has lower electron density than other carbon positions, and thus may become a lowest unoccupied molecular orbital (LUMO) position. Therefore, the fused polycyclic compound represented by Formula 1 of one or more embodiments has a structure in which the first substituent is linked to the fused ring core via the fourth carbon position, and thus the first substituent adjacent to the fused ring core may act as an acceptor in addition to the boron atom so that the multiple resonance may be enhanced. In the fused polycyclic compound represented by Formula 1, the first substituent is linked to the fused ring core through the carbon at a specific position, and thus spatial overlap of the highest occupied molecular orbital (HOMO) and the lowest unoccupied molecular orbital (LUMO) may be minimized or reduced. Accordingly, the dopant of one or more embodiments has a low ΔE_{ST} value and stabilized structure of the polycyclic aromatic ring, and thus may be selected so that the wavelength range is suitable as a blue luminescent material, and when the dopant is applied to the light emitting device ED, the efficiency of the light emitting device ED may be improved.

In some embodiments, the fused polycyclic compound of one or more embodiments may include the second substituent and the third substituent respectively linked to the first nitrogen atom and the second nitrogen atom constituting the fused ring core, which may effectively protect the boron atom, thereby achieving high efficiency and a long service life. Thus, the fused polycyclic compound of one or more embodiments may have an increase in the luminous efficiency and may suppress or reduce the red shift of luminescence wavelength because the intermolecular interaction may be suppressed or reduced by the introduction of the second substituent and the third substituent, thereby controlling the formation of excimer or exciplex. In addition, the fused polycyclic compound represented by Formula 1 has an increase in the distance between adjacent molecules due to the large steric hindrance structure, thereby suppressing the Dexter energy transfer, and thus may suppress or reduce the deterioration of service life due to the increase of triplet concentration.

In one or more embodiments, the fused polycyclic compound represented by Formula 1 may be included in the emission layer EML. In some embodiments, the fused polycyclic compound represented by Formula 1 may be included as a dopant material in the emission layer EML. In some embodiments, the fused polycyclic compound represented by Formula 1 may be a thermally activated delayed fluorescence material. In some embodiments, the fused polycyclic compound of represented by Formula 1 may be utilized as a thermally activated delayed fluorescence dopant. For example, in the light emitting device ED, the emission layer EML may include, as a thermally activated delayed fluorescence dopant, at least one selected from among the fused polycyclic compounds represented by Compound Group 1 as described above. However, a utilization of the fused polycyclic compound of one or more embodiments is not limited thereto.

In one or more embodiments, the emission layer EML may include a plurality of compounds. The emission layer EML may include the fused polycyclic compound represented by Formula 1, i.e., the first compound, and at least one of a second compound represented by Formula HT-1, a third compound represented by Formula ET-1, or a fourth compound represented by Formula D-1.

In one or more embodiments, the emission layer EML may include a second compound represented by Formula HT-1. In one or more embodiments, the second compound may be utilized as a hole transporting host material of the emission layer EML.

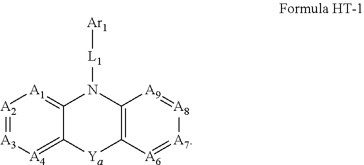

In Formula HT-1, A₁ to A₄, and A₆ to A₉ may each independently be N or CR₄₁. For example, all of A₁ to A₉ may be CR₄₁. In some embodiments, any one selected from among A₁ to A₄ and A₆ to A₉ may be N, and the rest may be CR₄₁.

In Formula HT-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, in some embodiments, L₁ may be a direct linkage, a substituted or unsubstituted phenylene group, a substituted or unsubstituted divalent biphenyl group, a substituted or unsubstituted divalent carbazole group, etc., but embodiments of the present disclosure are not limited thereto.

In Formula HT-1, Yₐ may be a direct linkage, CR₄₂R₄₃, or SiR₄₄R₄₅. For example, it may refer to that two benzene rings linked to the nitrogen atom in Formula HT-1 may be linked via a direct linkage,

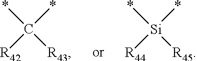

In Formula HT-1, when Yₐ is a direct linkage, the substituent represented by Formula HT-1 may include a carbazole moiety.

In Formula HT-1, Ar₁ may be a substituted or unsubstituted aryl group having 6 to 30 ring-forming carbon atoms, or a substituted or unsubstituted heteroaryl group having 2 to 30 ring-forming carbon atoms. For example, in some embodiments, Ar₁ may be a substituted or unsubstituted carbazole group, a substituted or unsubstituted dibenzofuran group, a substituted or unsubstituted dibenzothiophene group, a substituted or unsubstituted biphenyl group, etc., but embodiments of the present disclosure are not limited thereto.

In Formula HT-1, R₄₁ to R₄₅ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In some embodiments, each of R₄₁ to R₄₅ may be bonded to an adjacent group to form a ring. For example, in some embodiments, R₄₁ to R₄₅ may each independently be hydrogen or deuterium. In some embodiments, R₄₁ to R₄₅ may each independently be an unsubstituted methyl group or an unsubstituted phenyl group.

In one or more embodiments, the second compound represented by Formula HT-1 may be represented by any one selected from among the compounds represented by Compound Group 2. The emission layer EML may include at least one selected from among the compounds represented by Compound Group 2 as a hole transporting host material.

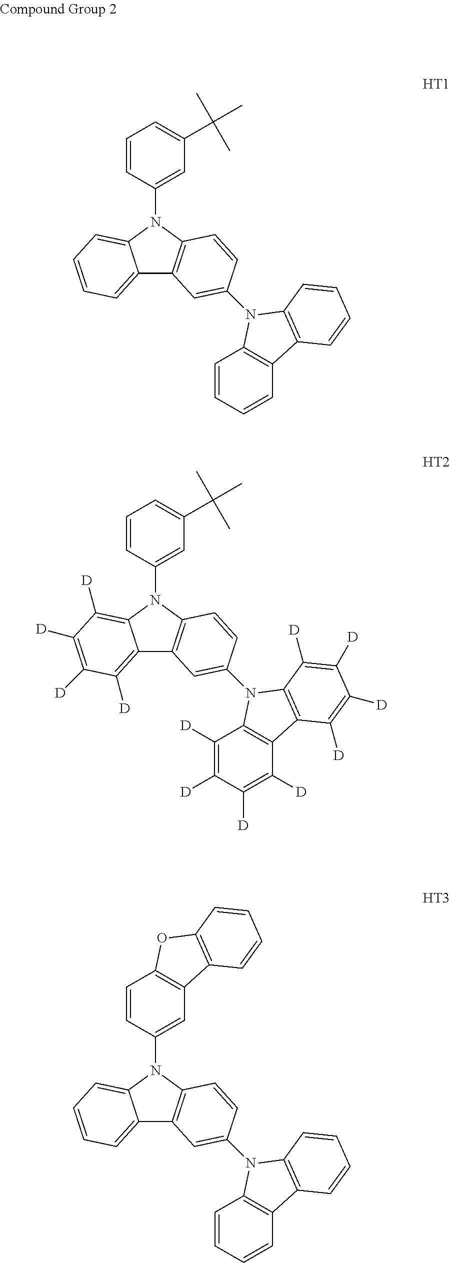 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

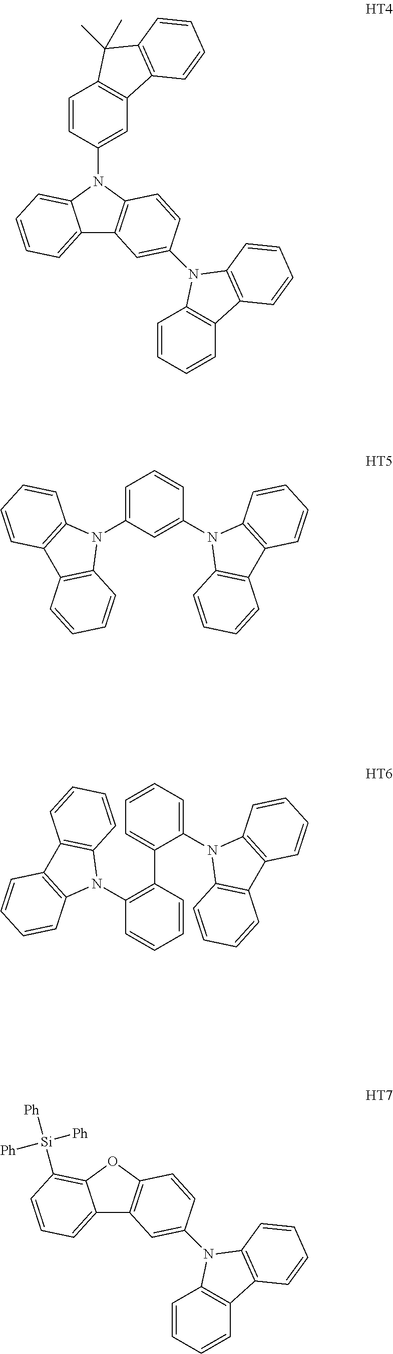 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1]

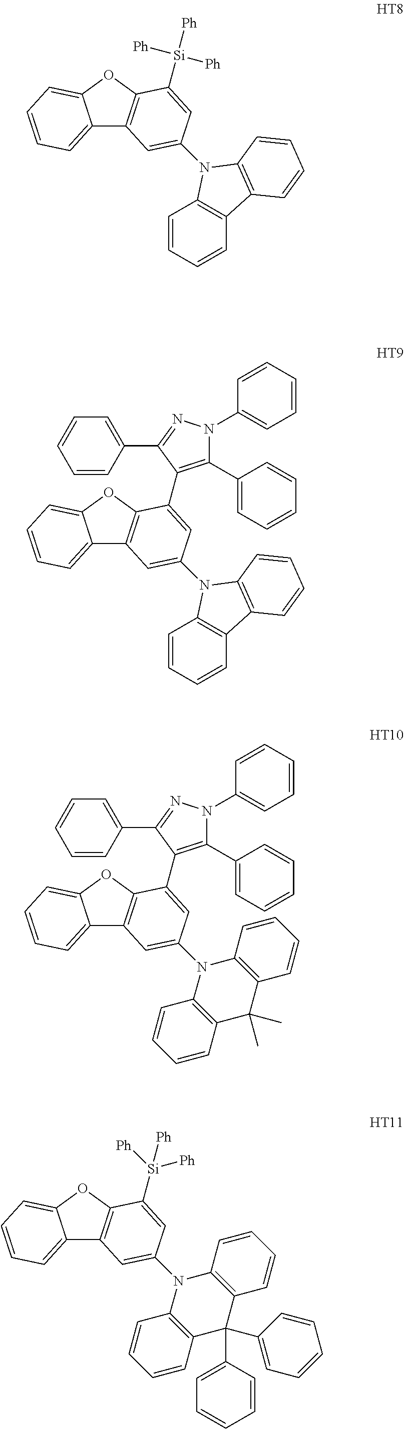 [SMILES: c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1]

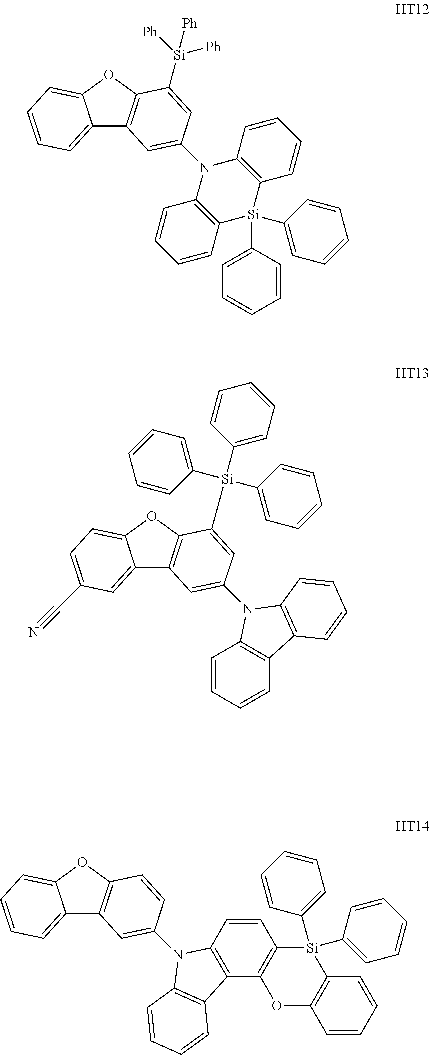 [SMILES: c1ccc([Si]2(c3ccccc3)c3ccccc3N(c3cc([Si](c4ccccc4)(c4ccccc4)c4ccccc4)c4oc5ccccc5c4c3)c3ccccc32)cc1 ; N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1]

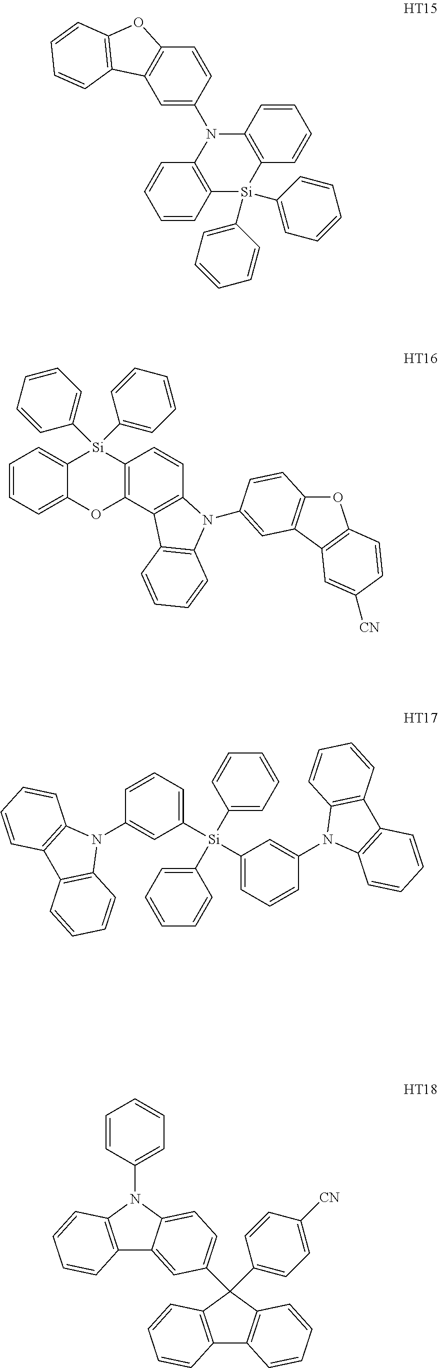 [SMILES: c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1]

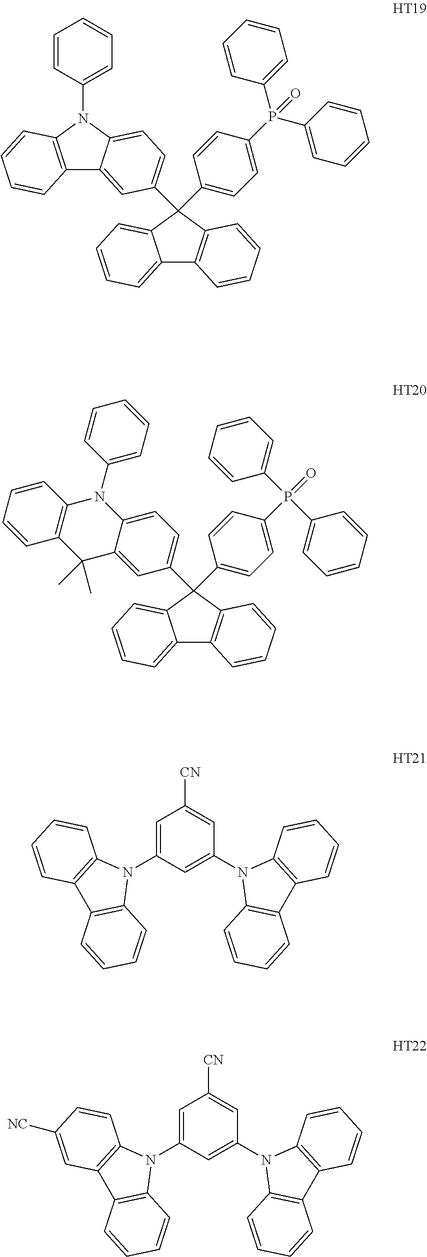 [SMILES: O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1]

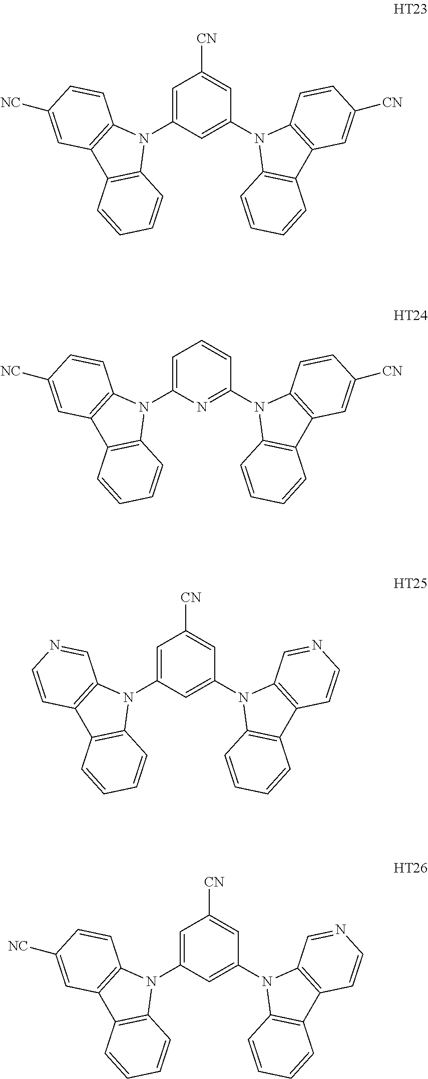 [SMILES: N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1]

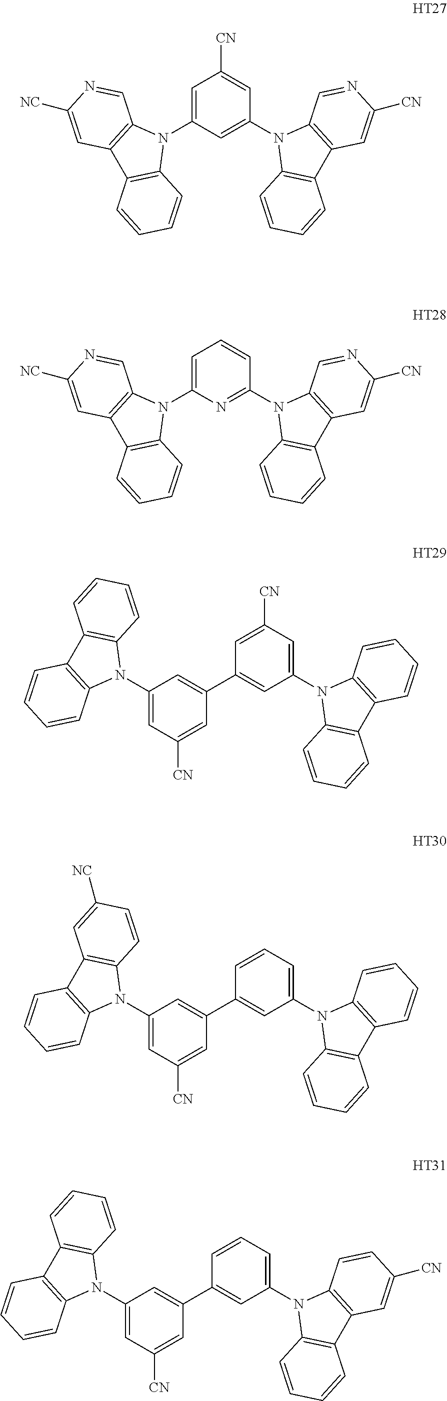 [SMILES: N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1]

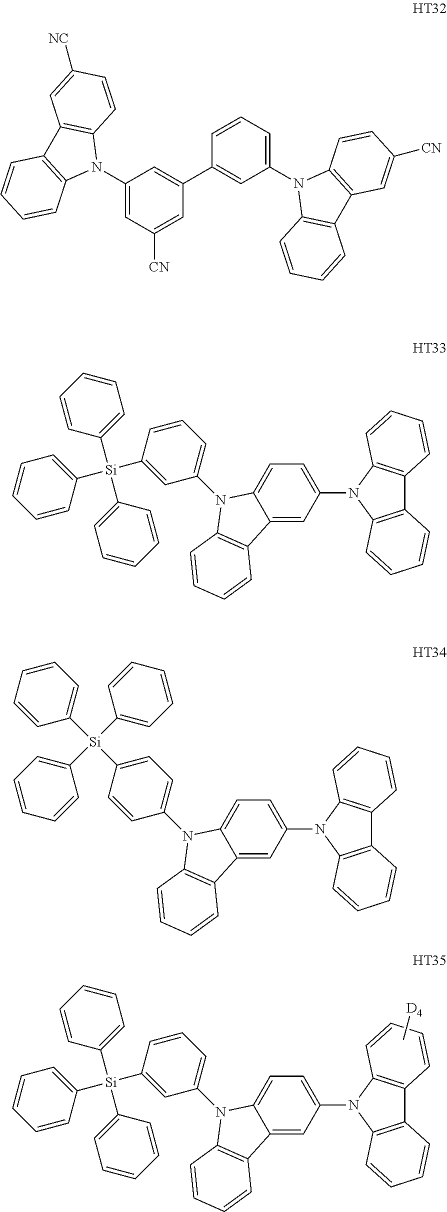

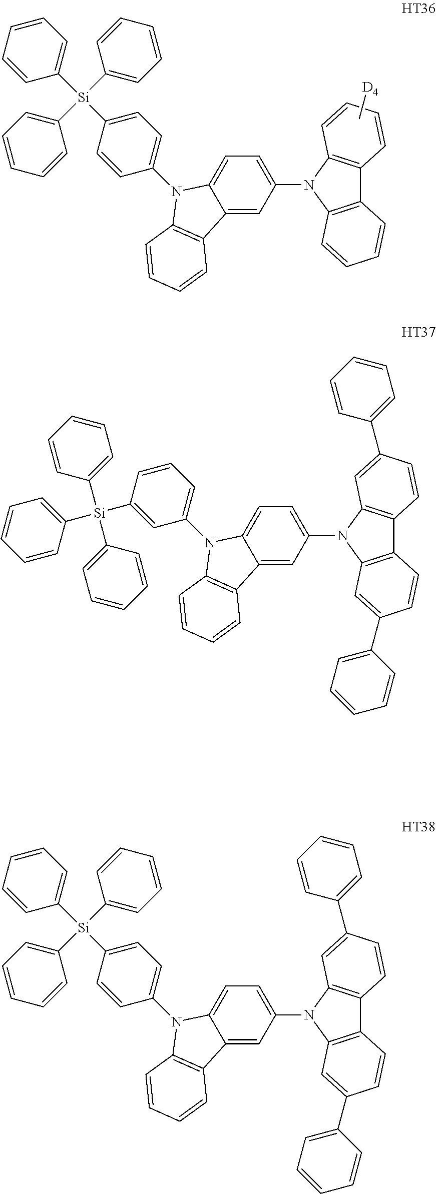

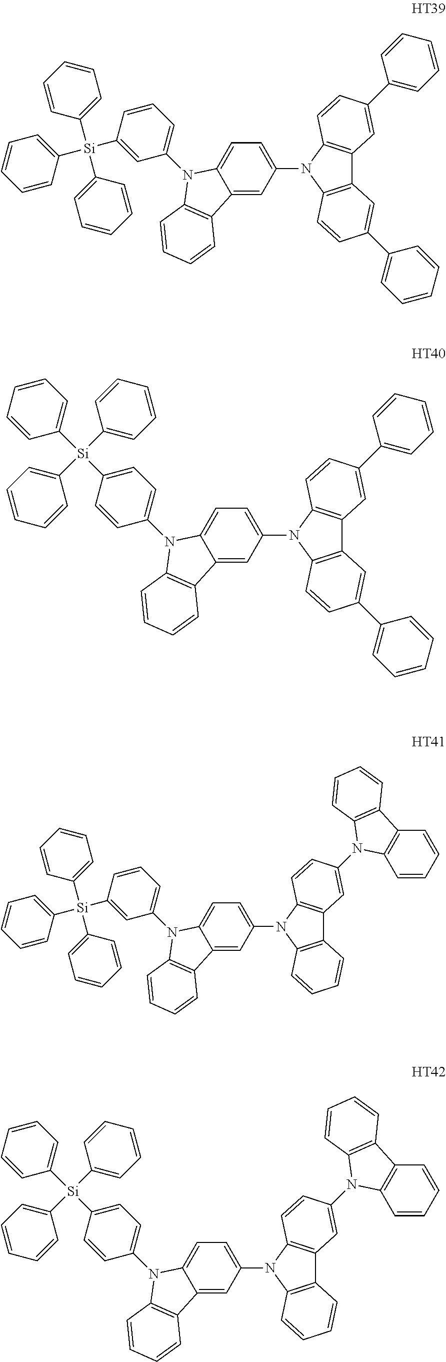 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

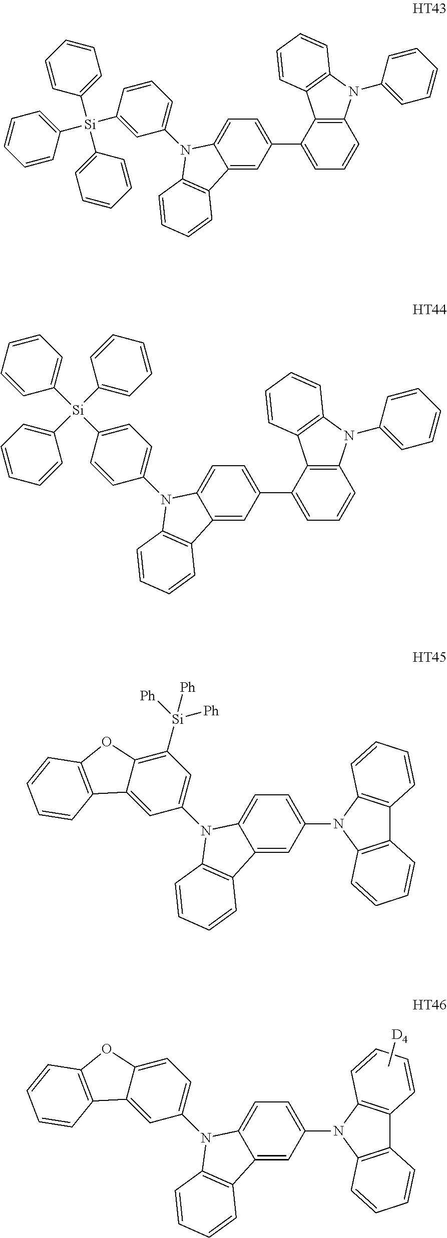

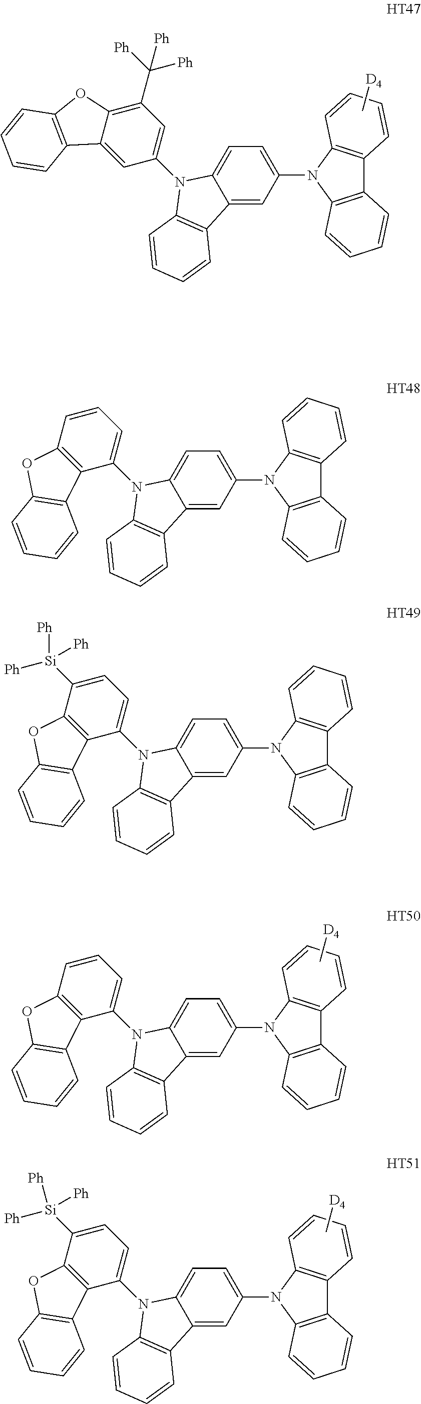

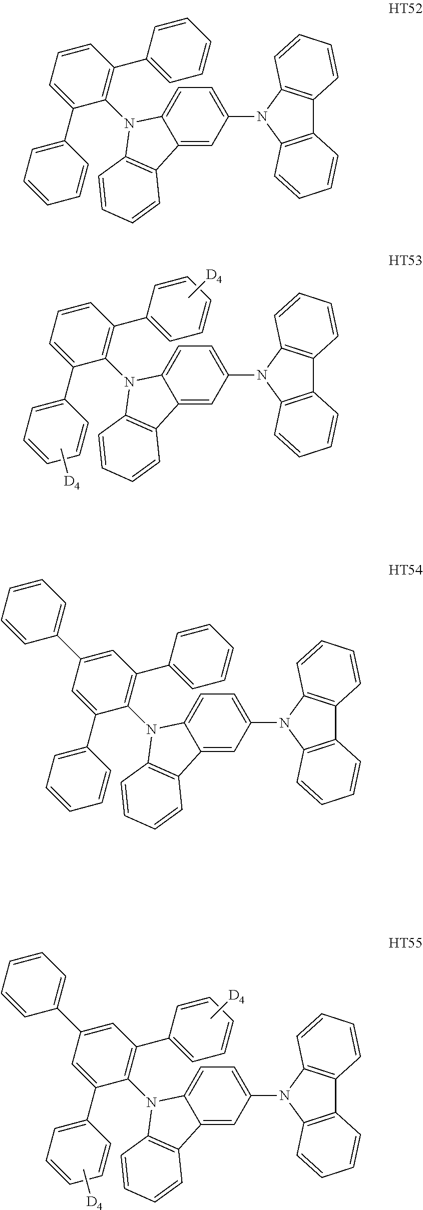

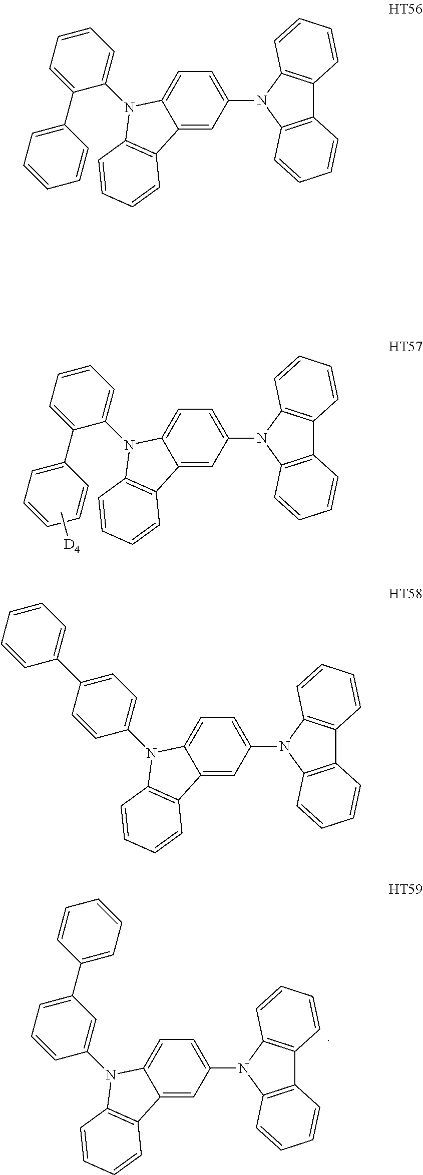

In embodiment compounds presented in Compound Group 2, “D” may refer to deuterium, and “Ph” may refer to a substituted or unsubstituted phenyl group. For example, in embodiment compounds presented in Compound Group 2, “Ph” may refer to an unsubstituted phenyl group.

In one or more embodiments, the emission layer EML may include a third compound represented by Formula ET-1. For example, the third compound may be utilized as an electron transporting host material for the emission layer EML.

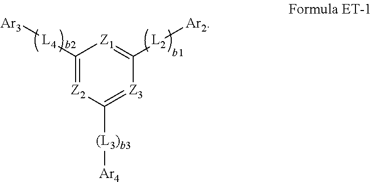

In Formula ET-1, at least one selected from among Z₁ to Z₃ may be N, and the rest may be CRₐ₃, and Rₐ₃ may be hydrogen, deuterium, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

b1 to b3 may each independently be an integer of 0 to 10. L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms.

Ar₂ to Ar₄ may each independently be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in some embodiments, Ar₂ to Ar₄ may each independently be a substituted or unsubstituted phenyl group, or a substituted or unsubstituted carbazole group.

The third compound may be represented by any one selected from among the compounds in Compound Group 3. In one or more embodiments, the light emitting device ED may include one or more selected from among the compounds of Compound Group 3:

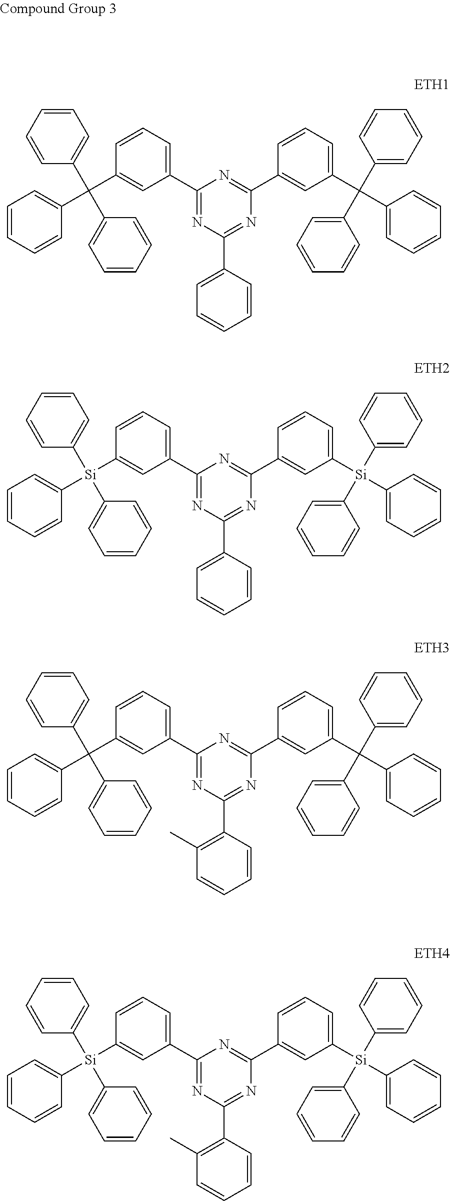 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

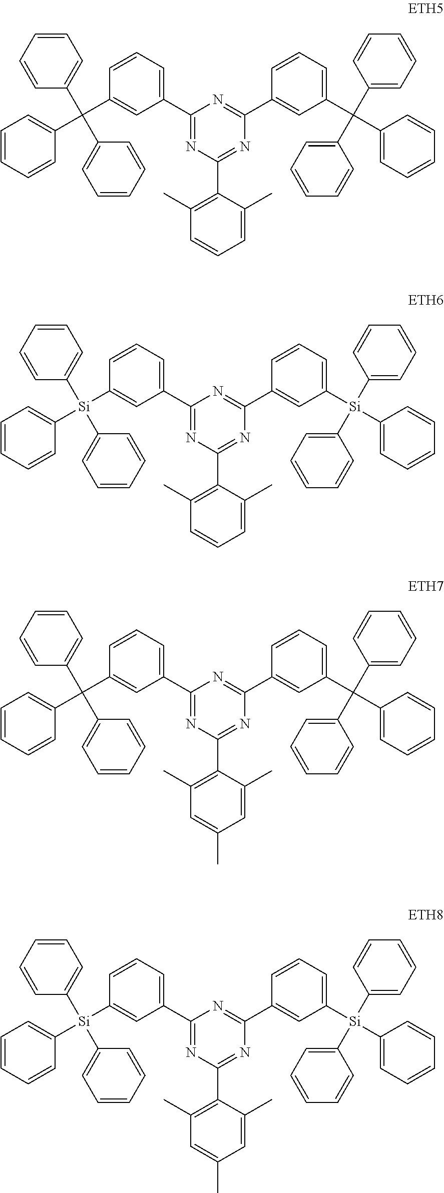 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

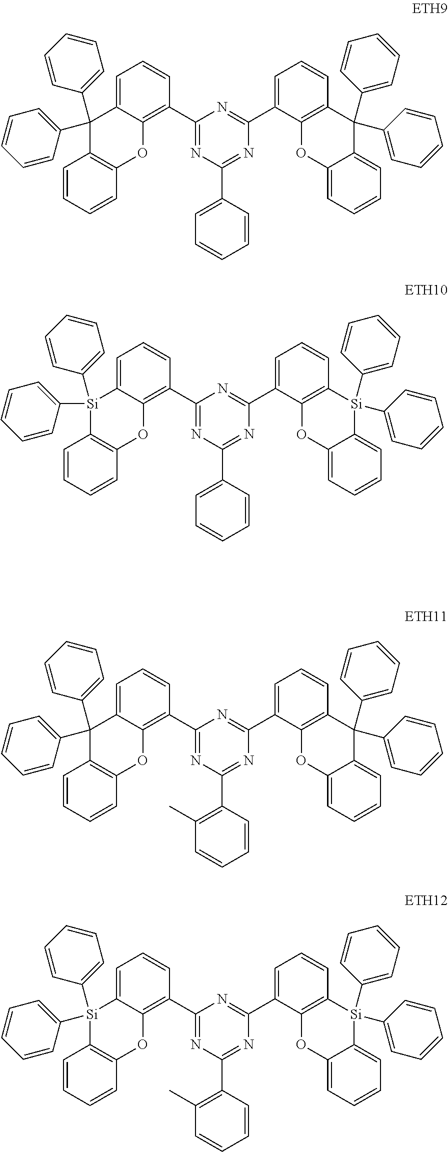 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

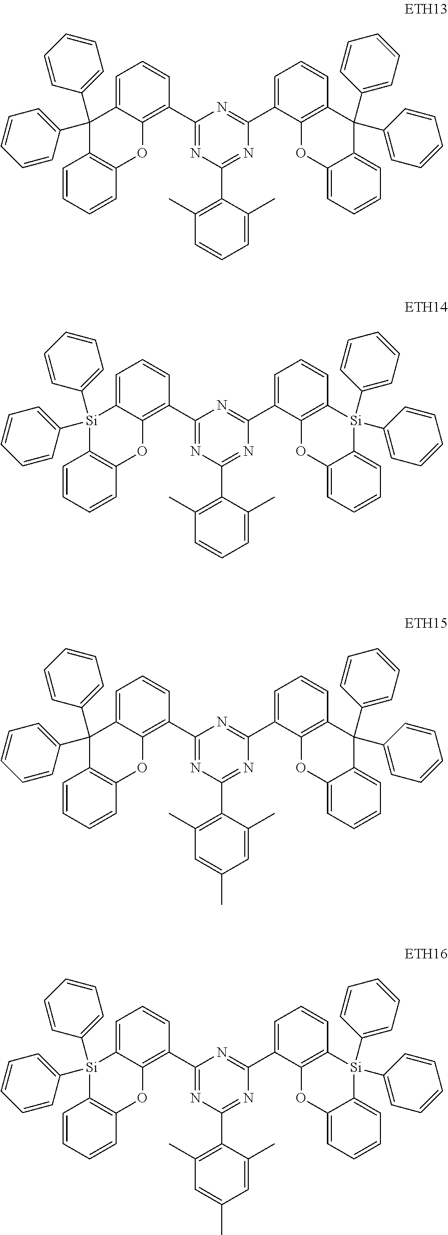 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

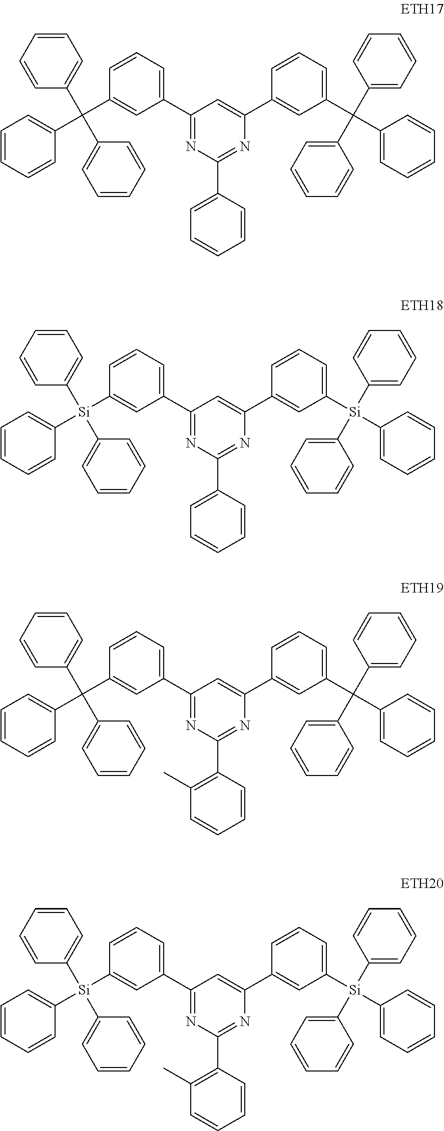 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

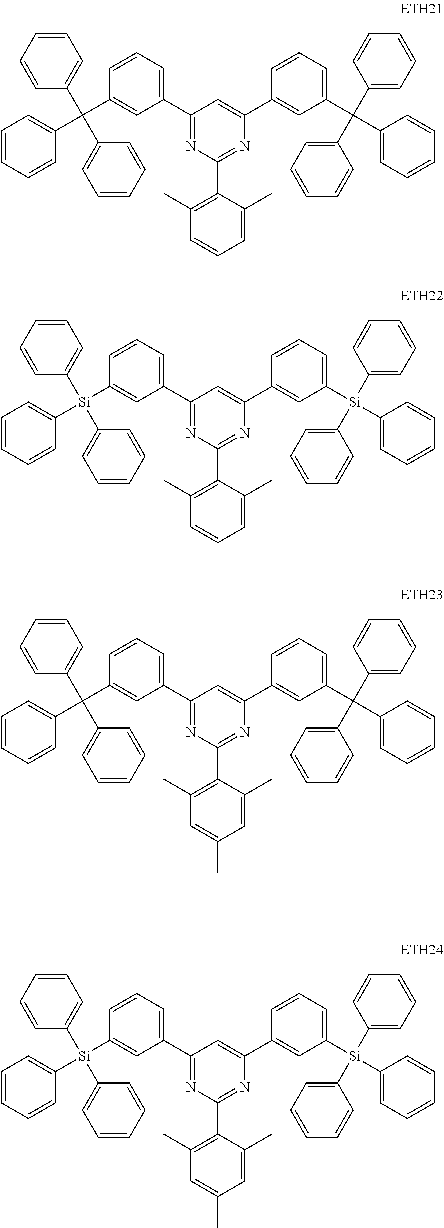 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

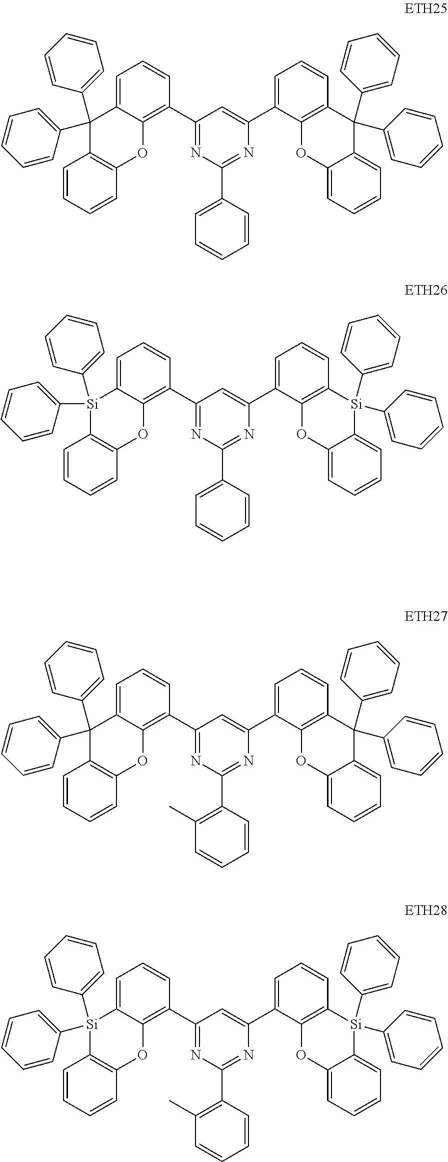 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

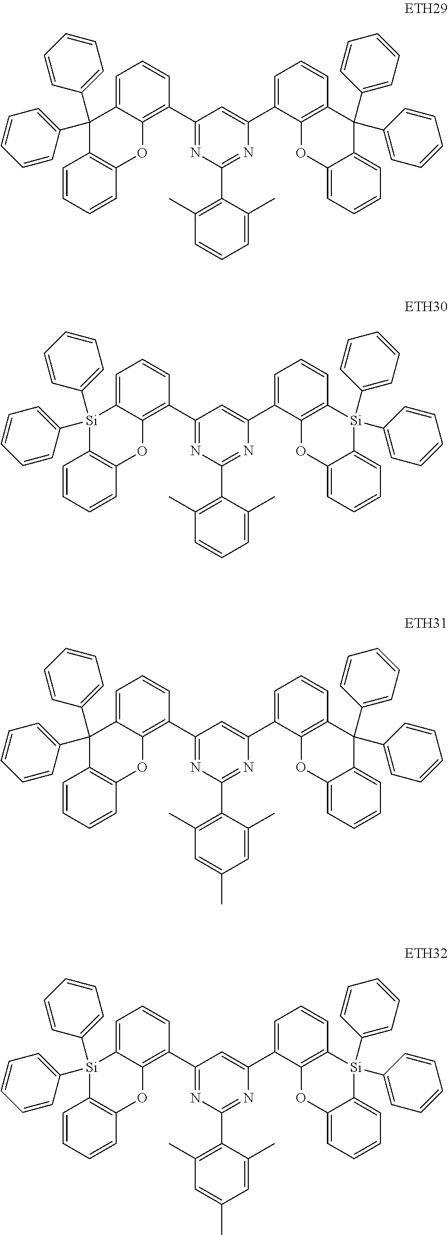 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

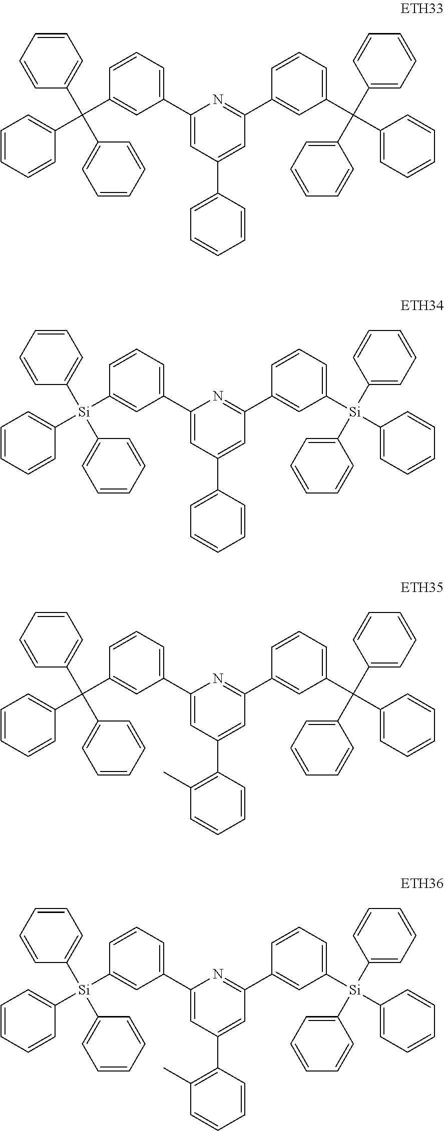 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

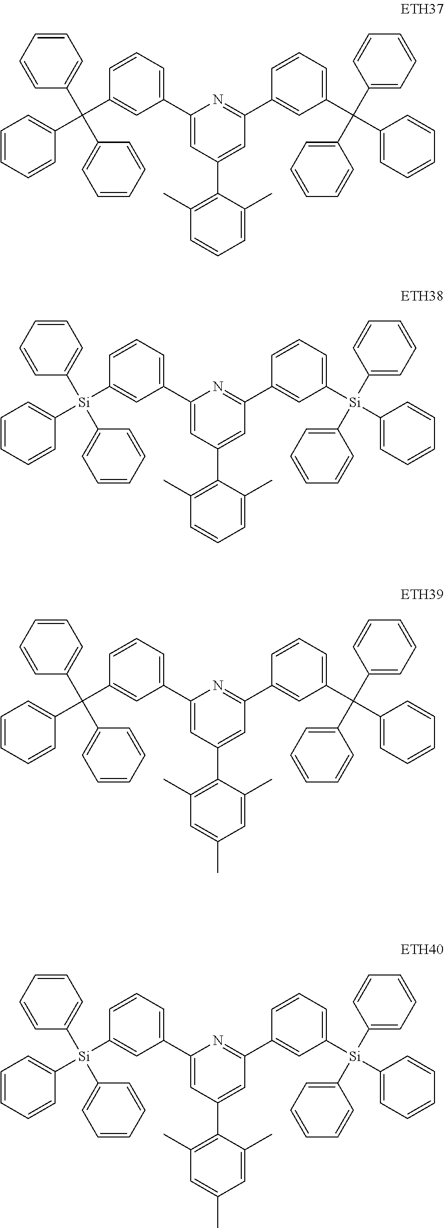 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

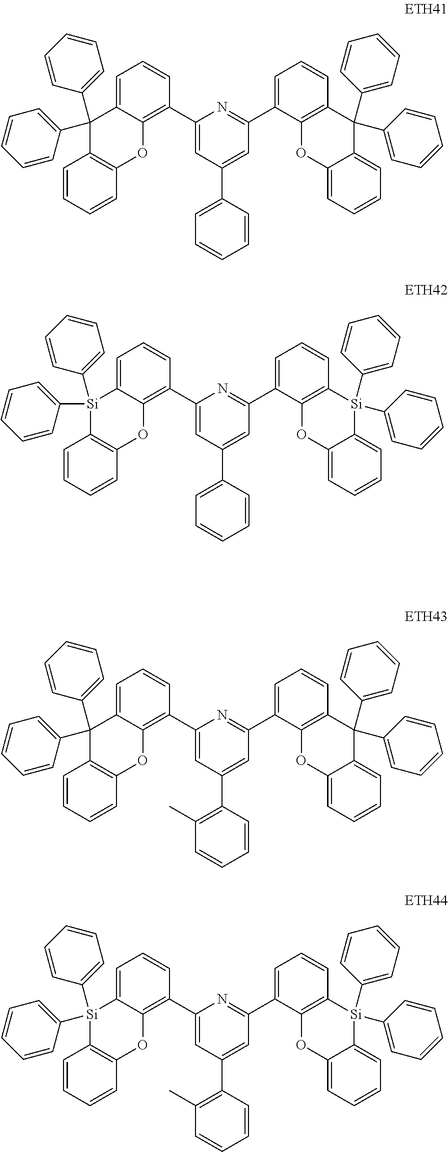 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

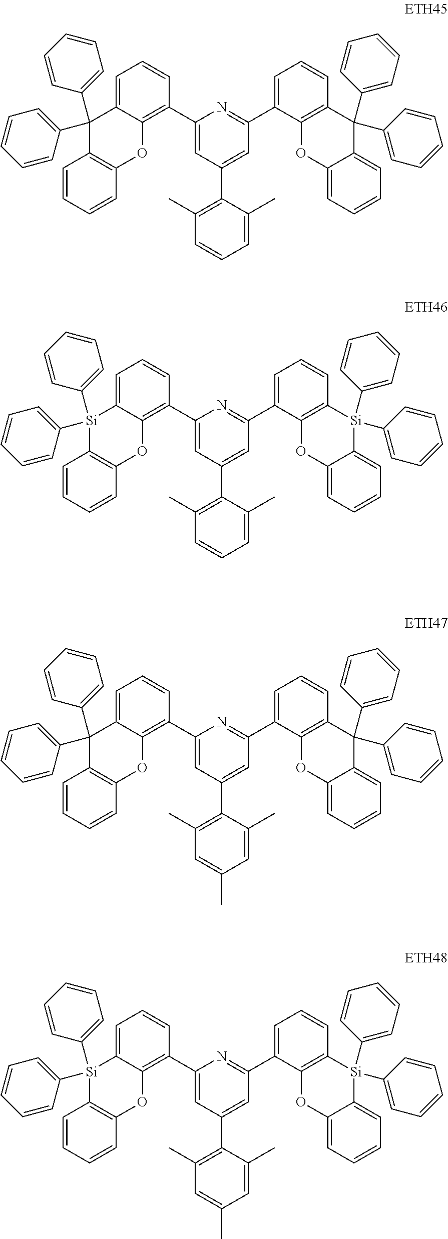 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

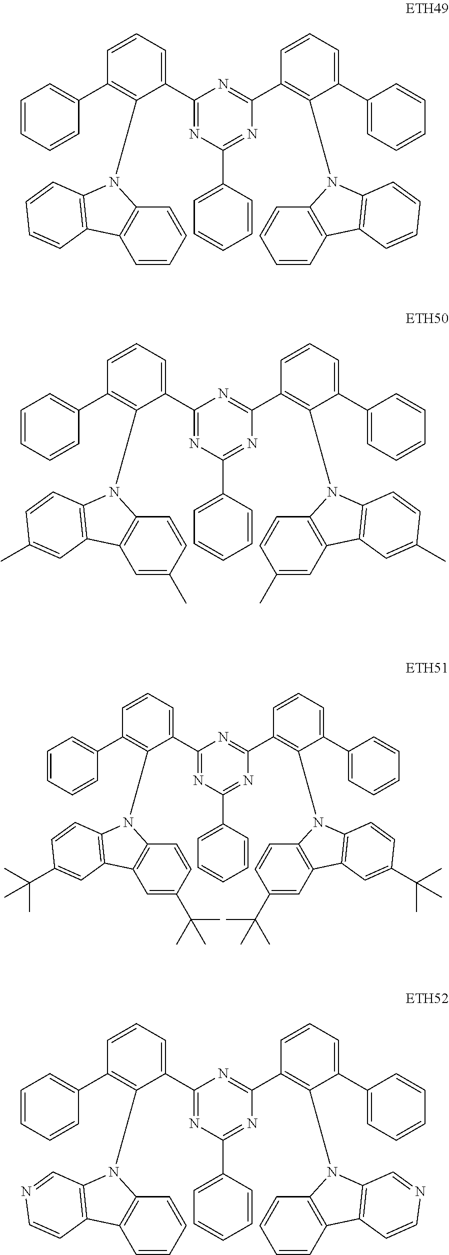

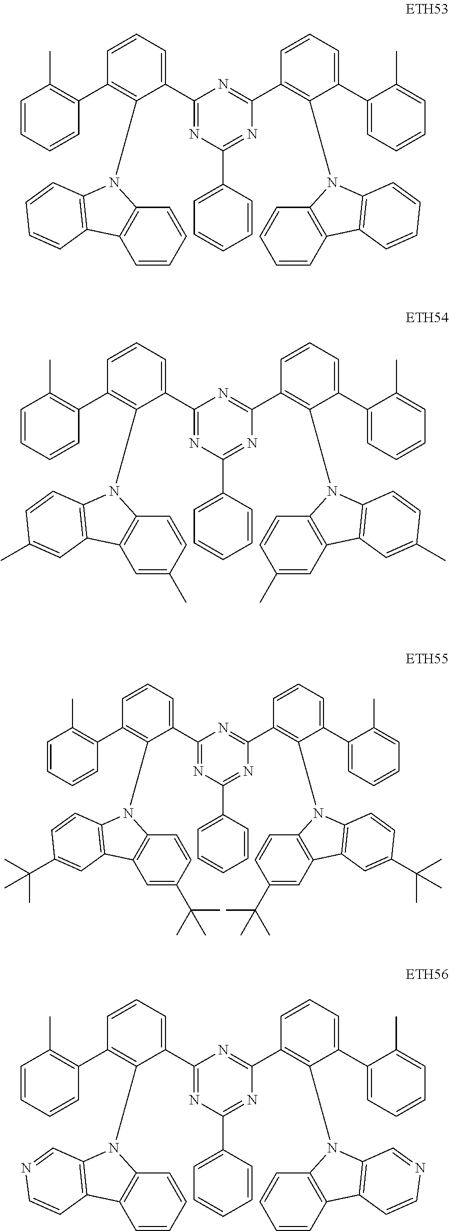

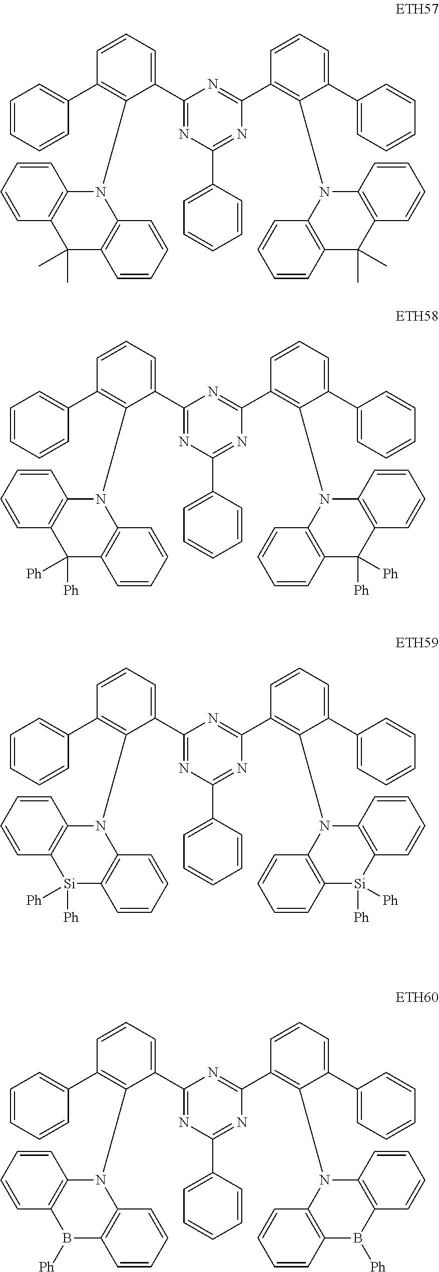

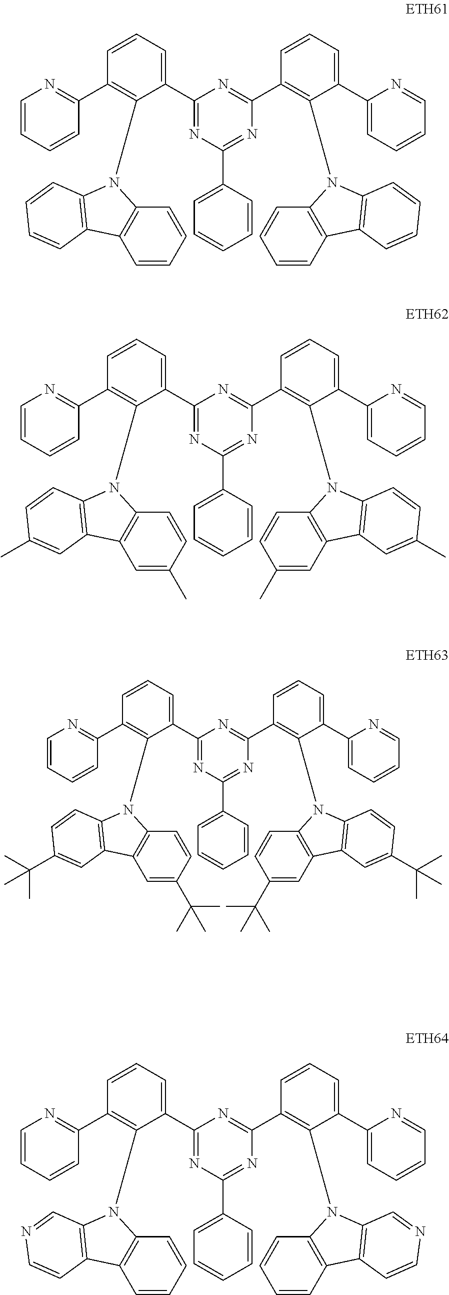

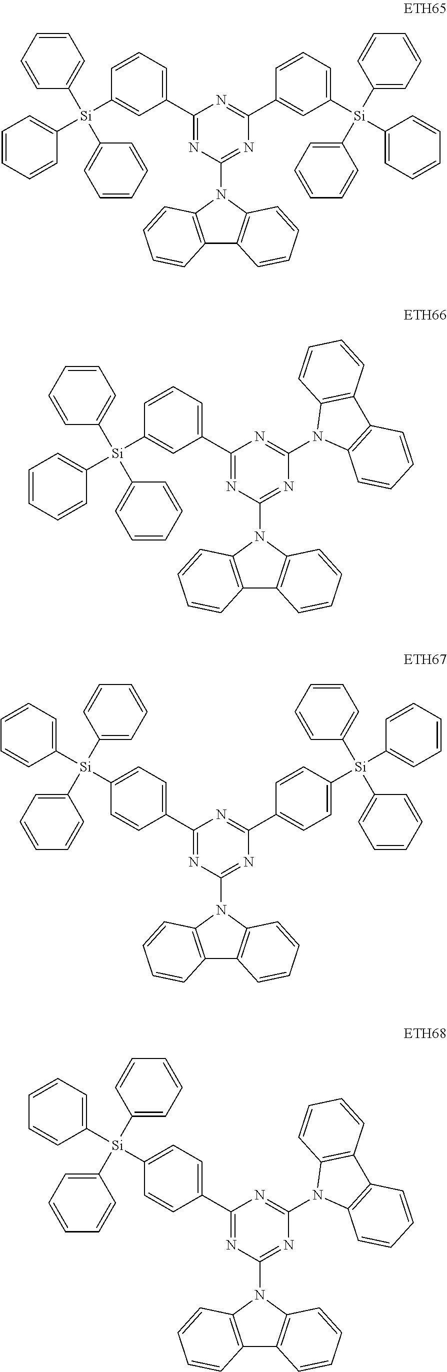 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

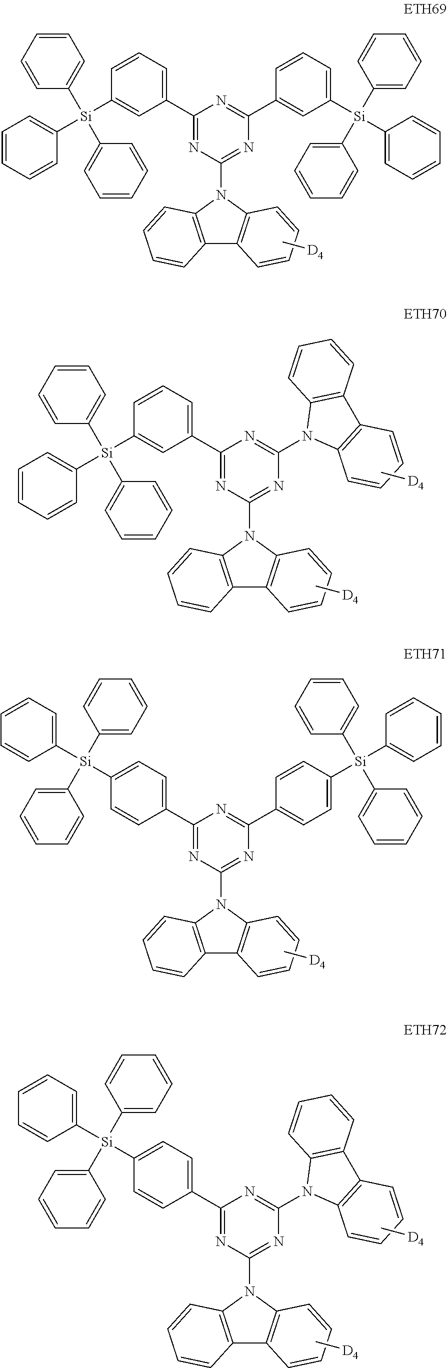

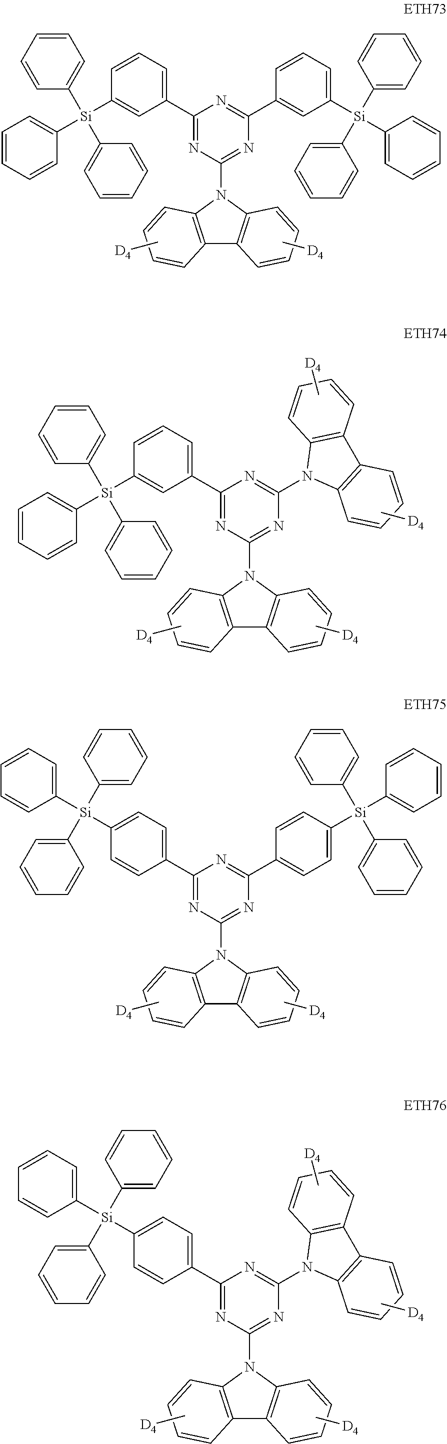

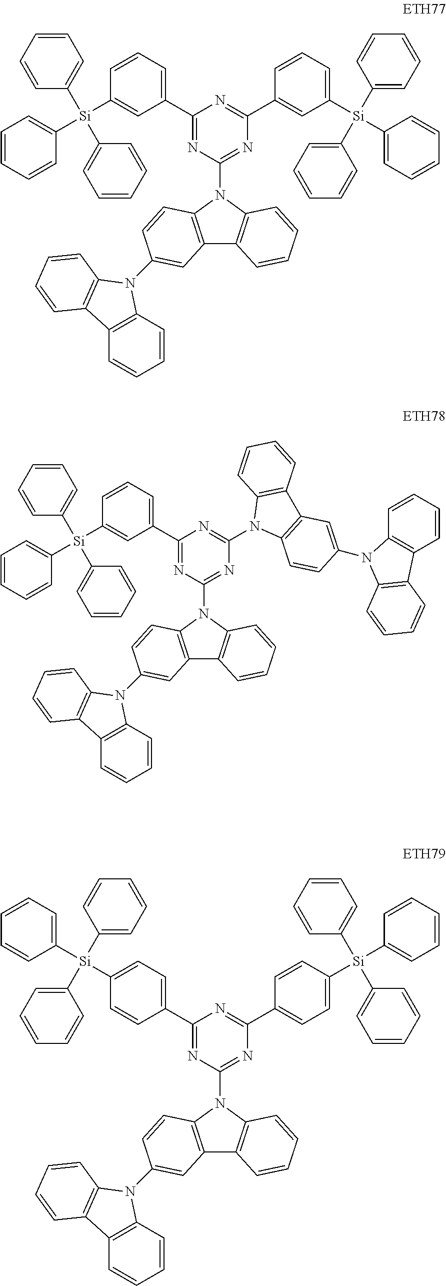 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

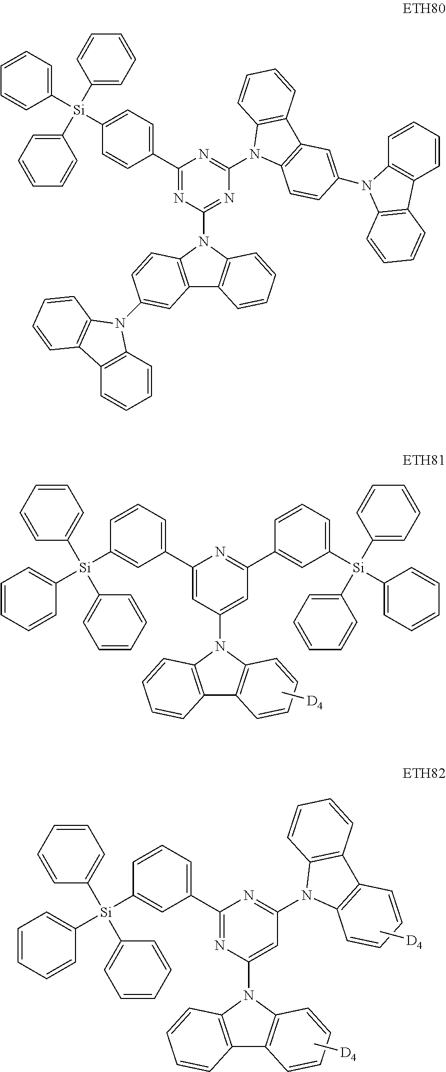

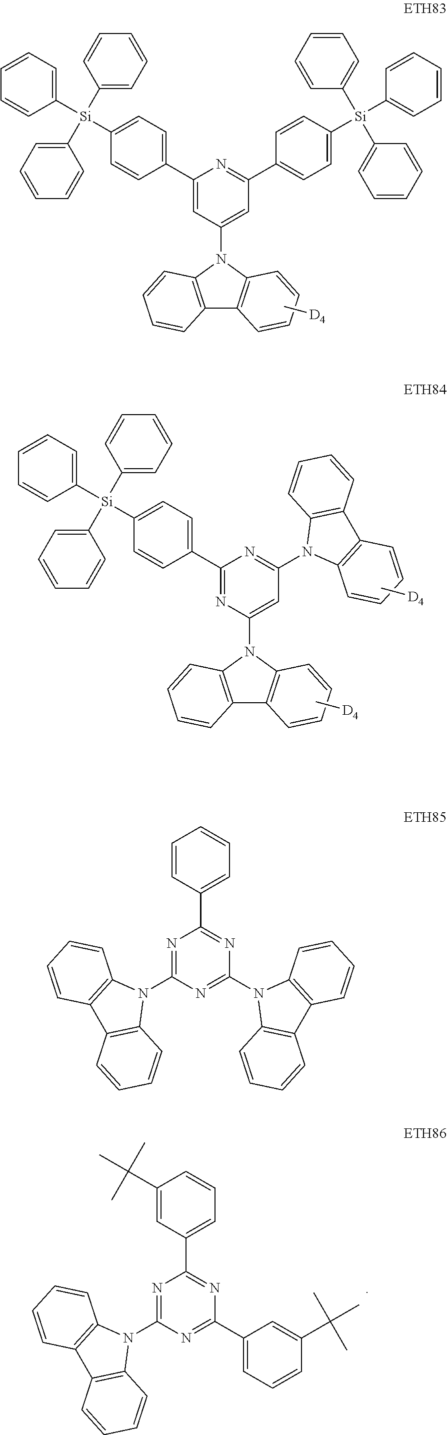

In the embodiment compounds presented in Compound Group 3, “D” refers to deuterium, and “Ph” refers to an unsubstituted phenyl group.

In one or more embodiments, the emission layer EML may include the second compound and the third compound, and the second compound and the third compound may form an exciplex. In the emission layer EML, an exciplex may be formed by the hole transporting host and the electron transporting host. A triplet energy of the exciplex formed by the hole transporting host and the electron transporting host may correspond to the difference between a lowest unoccupied molecular orbital (LUMO) energy level of the electron transporting host and a highest occupied molecular orbital (HOMO) energy level of the hole transporting host.

For example, the absolute value of the triplet energy (T1) of the exciplex formed by the hole transporting host and the electron transporting host may be about 2.4 eV to about 3.0 eV. In some embodiments, the triplet energy of the exciplex may be a value smaller than an energy gap of each host material. The exciplex may have a triplet energy of about 3.0 eV or less that is an energy gap between the hole transporting host and the electron transporting host.

In one or more embodiments, the emission layer EML may include a fourth compound in addition to the first compound to the third compound. The fourth compound may be utilized as a phosphorescent sensitizer of the emission layer EML. The energy may be transferred from the fourth compound to the first compound, thereby emitting light.

For example, in one or more embodiments, the emission layer EML may include, as the fourth compound, an organometallic complex containing platinum (Pt) as a central metal atom and ligands linked to the central metal atom. The emission layer EML in the light emitting device ED may include, as the fourth compound, a compound represented by Formula D-1:

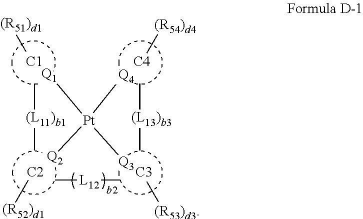

In Formula D-1, Q₁ to Q₄ may each independently be C or N.

In Formula D-1, C1 to C4 may each independently be a substituted or unsubstituted hydrocarbon ring having 5 to 30 ring-forming carbon atoms, or a substituted or unsubstituted heterocycle having 2 to 30 ring-forming carbon atoms.

In Formula D-1, L₁₁ to L₁₃ may each independently be a direct linkage,

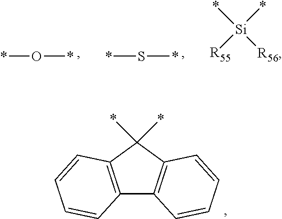

A substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃, “—*” refers to a site linked to C1 to C4.

In Formula D-1, b1 to b3 may each independently be 0 or 1. When b1 is 0, C1 and C2 may not be linked to each other. When b2 is 0, C2 and C3 may not be linked to each other. When b3 is 0, C3 and C4 may not be linked to each other.

In Formula D-1, R₅₁ to R₅₆ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In some embodiments, each of R₅₁ to R₅₆ may be bonded to an adjacent group to form a ring. In some embodiments, R₅₁ to R₅₆ may each independently be a substituted or unsubstituted methyl group, or a substituted or unsubstituted t-butyl group.

In Formula D-1, d1 to d4 may each independently be an integer of 0 to 4. In Formula D-1, when each of d1 to d4 is 0, the fourth compound may not be substituted with each of R₅₁ to R₅₄. Embodiments in which each of d1 to d4 is 4 and R₅₁(s) to R₅₄(s) are each hydrogen may be the same as embodiments in which each of d1 to d4 is 0. When each of d1 to d4 is an integer of 2 or more, a plurality of R₅₁(s) to R₅₄(s) may each be the same or at least one selected from among the plurality of R₅₁(s) to R₅₄(s) may be different from the others.

In Formula D-1, C1 to C4 may each independently be a substituted or unsubstituted hydrocarbon ring or a substituted or unsubstituted heterocycle represented by any one selected from among C-1 to C-4:

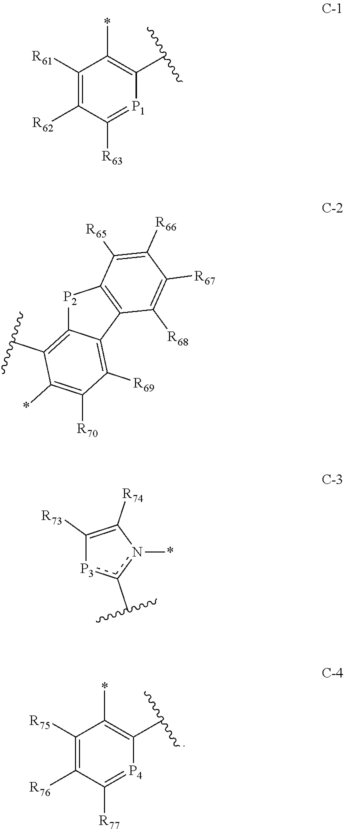

In C-1 to C-4, P₁ may be C—* or CR₆₄, P₂ may be N—* or NR₇₁, P₃ may be N—* or NR₇₂, and P₄ may be C—* or CR₇₈. R₆₁ to R₇₈ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring.

In addition, in C-1 to C-4

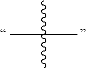

corresponds to a part linked to Pt that is a central metal atom, and “—*” corresponds to a part linked to a neighboring cyclic group (C1 to C4) or a linker (L₁₁ to L₁₃).

In one or more embodiments, the emission layer EML may include the first compound, which is a fused polycyclic compound represented by Formula 1, and at least one selected from among the second to fourth compounds. For example, in one or more embodiments, the emission layer EML may include the first compound, the second compound, and the third compound. In the emission layer EML, the second compound and the third compound may form an exciplex, and the energy may be transferred from the exciplex to the first compound, thereby emitting light.

In some embodiments, the emission layer EML may include the first compound, the second compound, the third compound, and the fourth compound. In the emission layer EML, the second compound and the third compound may form an exciplex, and the energy may be transferred from the exciplex to the fourth compound and the first compound, thereby emitting light. In one or more embodiments, the fourth compound may be a sensitizer. The fourth compound included in the emission layer EML in the light emitting device ED may serve as a sensitizer to deliver energy from the host to the first compound that is a light emitting dopant. For example, the fourth compound serving as an auxiliary dopant accelerates energy delivery to the first compound that is a light emitting dopant, thereby increasing an emission ratio of the first compound. Therefore, the emission layer EML may improve luminous efficiency. In some embodiments, when the energy delivery to the first compound is increased, an exciton formed in the emission layer EML is not accumulated inside the emission layer EML and emits light rapidly, and thus deterioration of the device may be reduced. Therefore, the service life of the light emitting device ED may increase.

In one or more embodiments, the light emitting device ED may include all of the first compound, the second compound, the third compound, and the fourth compound, and the emission layer EML may include the combination of two host materials and two dopant materials. In the light emitting device ED, the emission layer EML may concurrently (e.g., simultaneously) include the second compound and the third compound, which are two different hosts, the first compound that emits a delayed fluorescence, and the fourth compound including an organometallic complex, thereby exhibiting excellent or suitable luminous efficiency characteristics.

In one or more embodiments, the fourth compound represented by Formula D-1 may be represented by at least one selected from among the compounds represented by Compound Group 4. The emission layer EML may include at least one selected from among the compounds represented by Compound Group 4 as a sensitizer material.

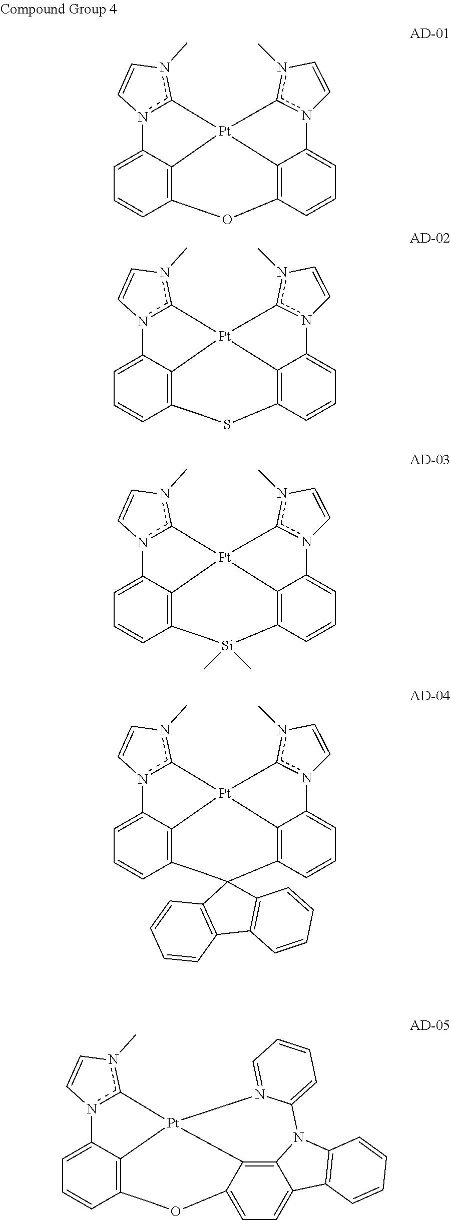

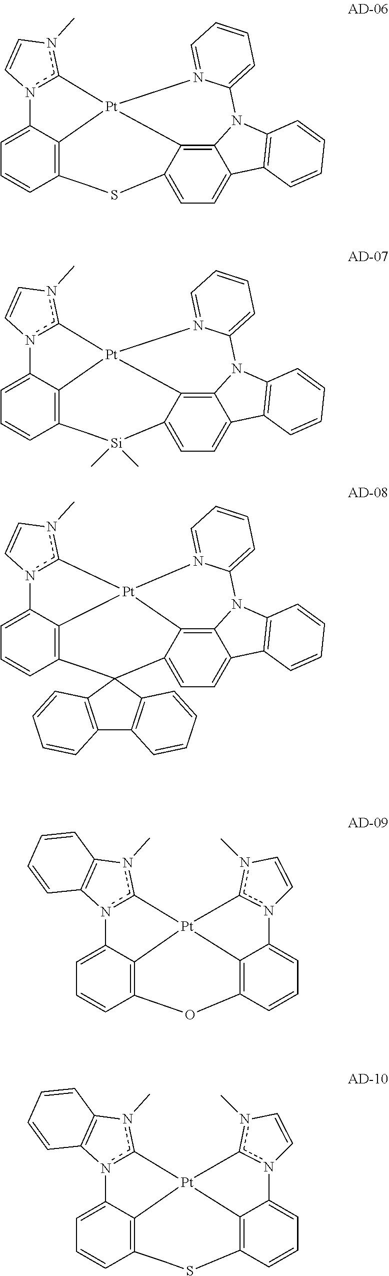

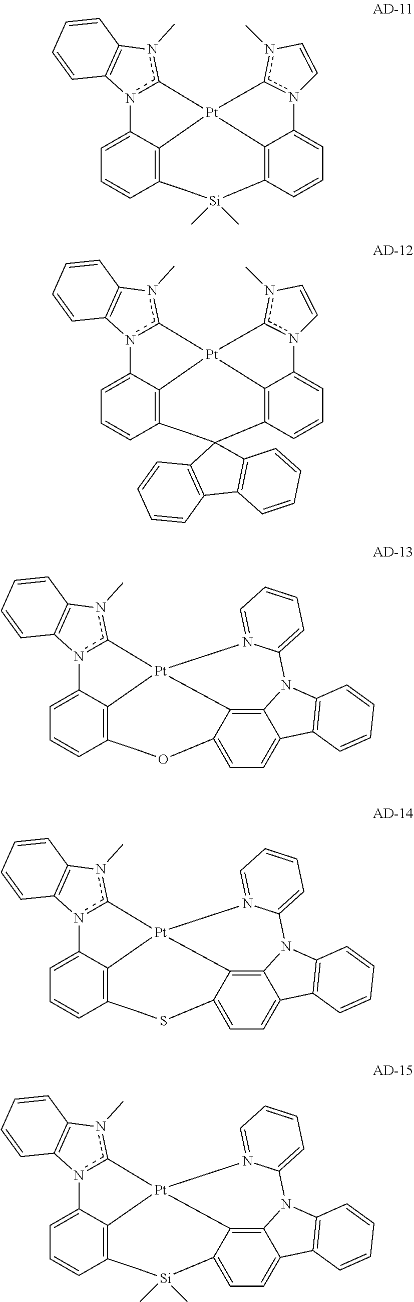

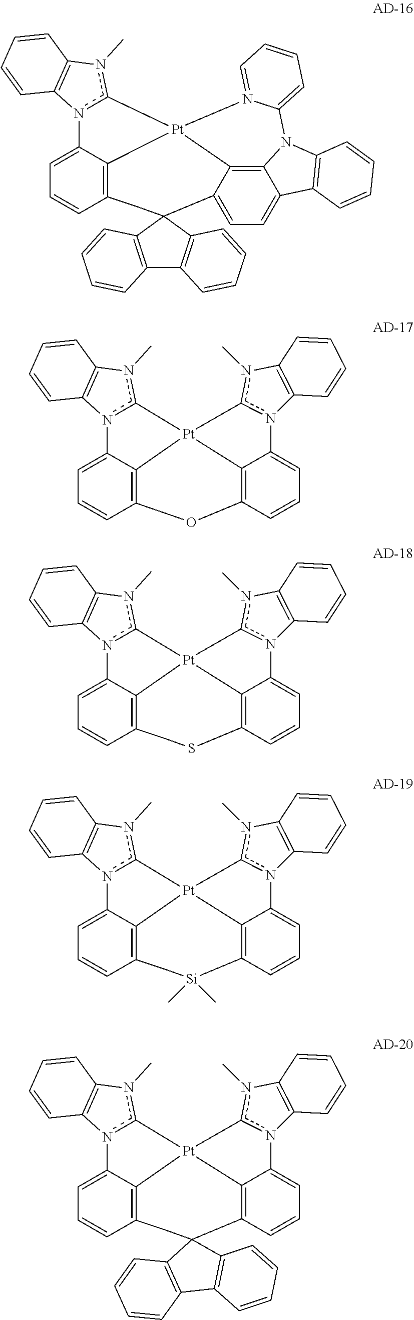

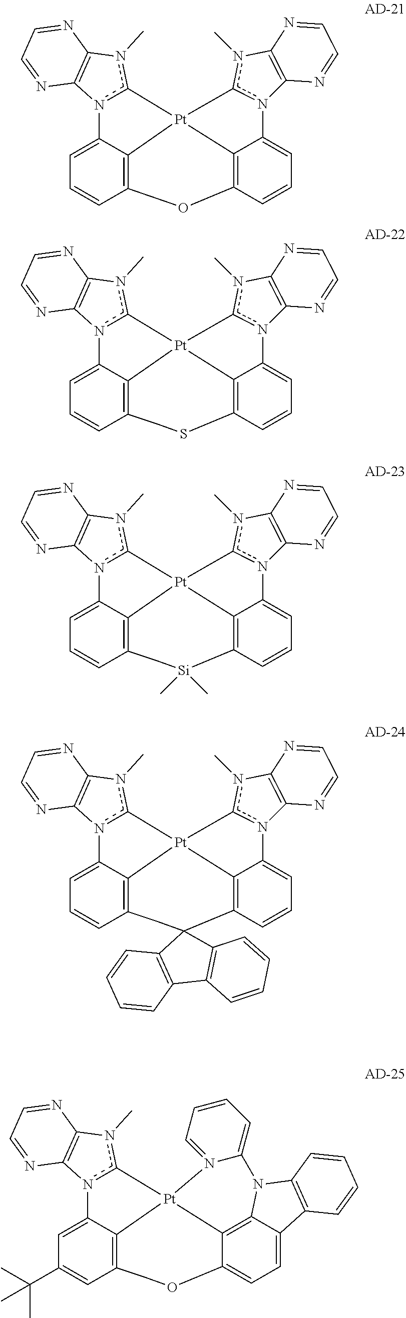

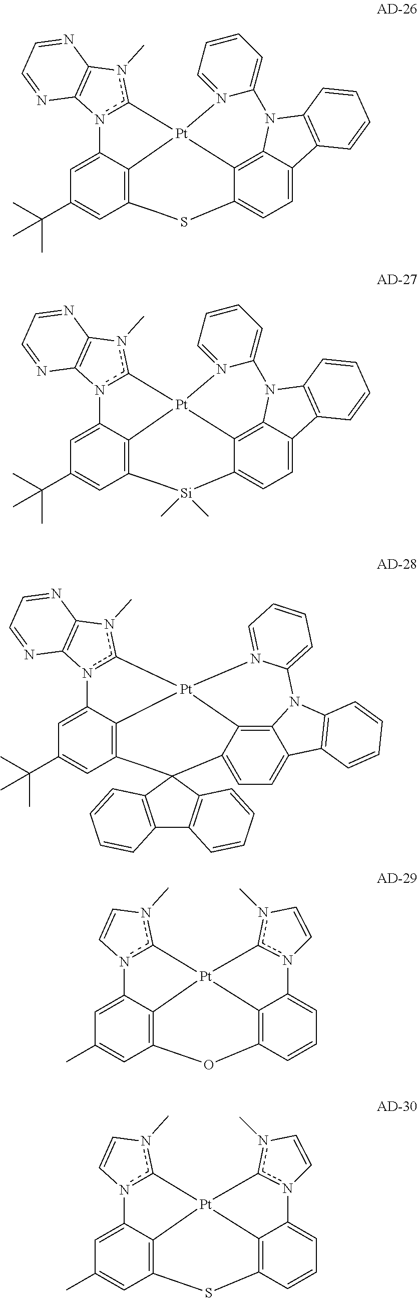

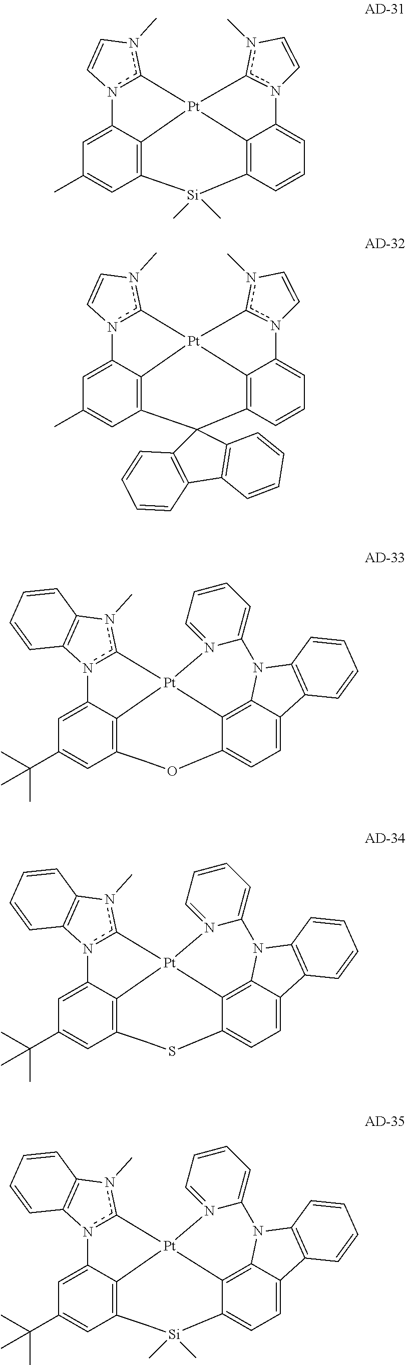

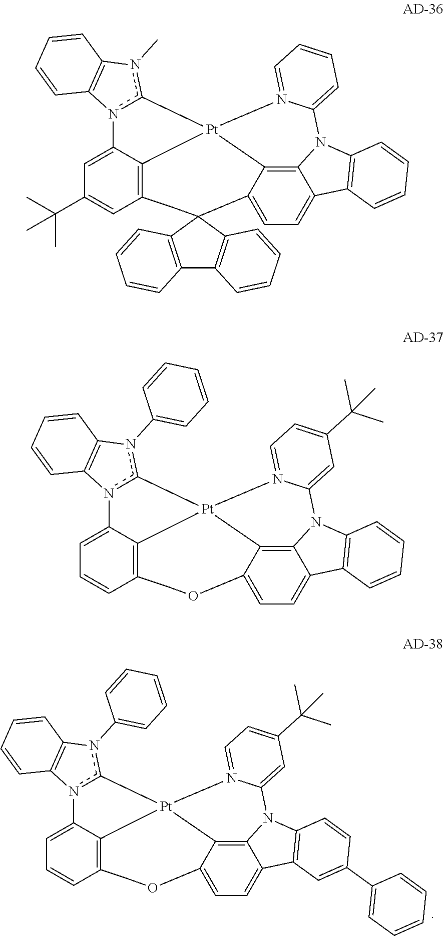

In some embodiments, the light emitting device ED may include a plurality of emission layers. The plurality of emission layers may be sequentially stacked and provided, and for example, the light emitting device ED including the plurality of emission layers may be to emit white light (e.g., combined white light). The light emitting device including the plurality of emission layers may be a light emitting device having a tandem structure. When the light emitting device ED includes a plurality of emission layers, at least one emission layer EML may include the first compound represented by Formula 1 of one or more embodiments. In some embodiments, when the light emitting device ED includes the plurality of emission layers, at least one emission layer EML may include all of the first compound, the second compound, the third compound, and the fourth compound as described above.

When the emission layer EML in the light emitting device ED of one or more embodiments includes all of the first compound, the second compound, and the third compound, with respect to the total weight of the first compound, the second compound, and the third compound, the content (e.g., amount) of the first compound may be about 0.1 wt % to about 5 wt %. However, embodiments of the present disclosure are not limited thereto. When the content (e.g., amount) of the first compound satisfy the above-described proportion, the energy transfer from the second compound and the third compound to the first compound may increase, and thus the luminous efficiency and device service life may increase.

The contents (e.g., amounts) of the second compound and the third compound in the emission layer EML may be the rest excluding the weight of the first compound. For example, the contents (e.g., amounts) of the second compound and the third compound in the emission layer EML may be about 75 wt % to about 95 wt % with respect to the total weight of the first compound, the second compound, and the third compound.

In the total weight of the second compound and the third compound, the weight ratio of the second compound and the third compound may be about 3:7 to about 7:3.

When the contents (e.g., amounts) of the second compound and the third compound satisfy the above-described ratio, a charge balance characteristic in the emission layer EML are improved, and thus the luminous efficiency and device service life may increase. When the contents (e.g., amounts) of the second compound and the third compound deviate from the above-described ratio range, a charge balance in the emission layer EML is broken, and thus the luminous efficiency may be reduced, and the device may be easily deteriorated.

When the emission layer EML includes the fourth compound, the content (e.g., amount) of the fourth compound in the emission layer EML may be about 4 wt % to about 20 wt % with respect to the total weight of the first compound, the second compound, the third compound, and the fourth compound. However, embodiments of the present disclosure are not limited thereto. When the content (e.g., amount) of the fourth compound satisfies the above-described content (e.g., amount), the energy delivery from the host to the first compound which is a light emitting dopant may be increased, thereby a luminous ratio may be improved, and thus the luminous efficiency of the emission layer EML may be improved. When the first compound, the second compound, the third compound, and the fourth compound included in the emission layer EML satisfy the above-described content (e.g., amount) ratio range, excellent or suitable luminous efficiency and long service life may be achieved.

In one or more embodiments, in the light emitting device ED, the emission layer EML may include an anthracene derivative, a pyrene derivative, a fluoranthene derivative, a chrysene derivative, a dehydrobenzanthracene derivative, or a triphenylene derivative. For example, in some embodiments, the emission layer EML may include the anthracene derivative or the pyrene derivative.

In each light emitting device ED illustrated in FIGS. 3 to 6, the emission layer EML may further include a suitable host and dopant besides the above-described hosts and dopants, and for example, the emission layer EML may include a compound represented by Formula E-1. The compound represented by Formula E-1 may be utilized as a fluorescent host material.

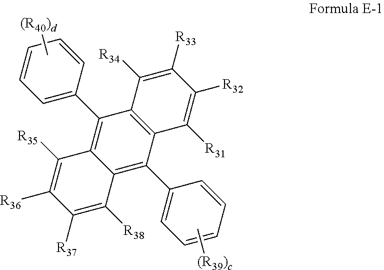

In Formula E-1, R₃₁ to R₄₀ may each independently be hydrogen, deuterium, a halogen, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In some embodiments, R₃₁ to R₄₀ may be bonded to an adjacent group to form a saturated hydrocarbon ring or an unsaturated hydrocarbon ring, a saturated heterocycle, or an unsaturated heterocycle.

In Formula E-1, c and d may each independently be an integer of 0 to 5.

Formula E-1 may be represented by any one selected from among Compound E1 to Compound E19:

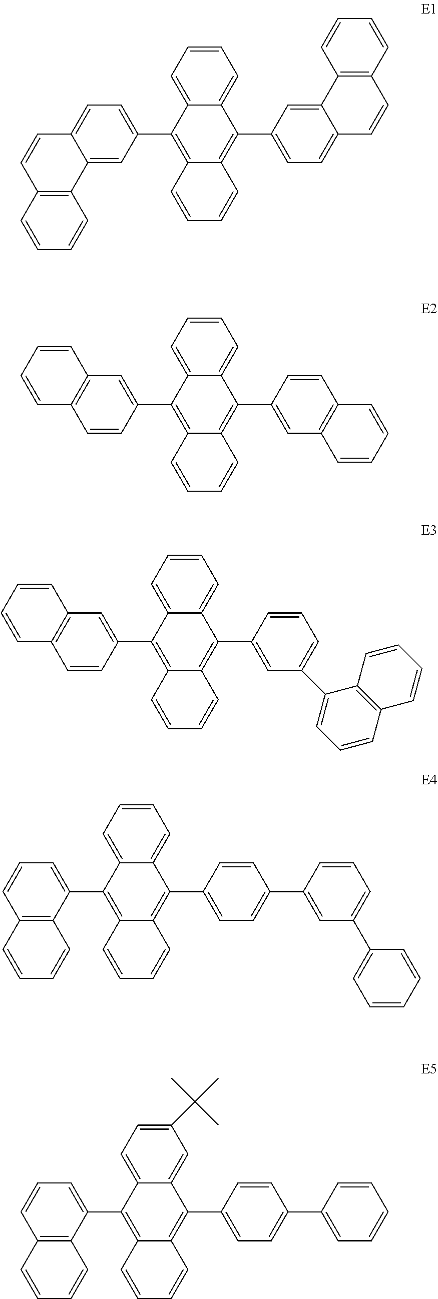

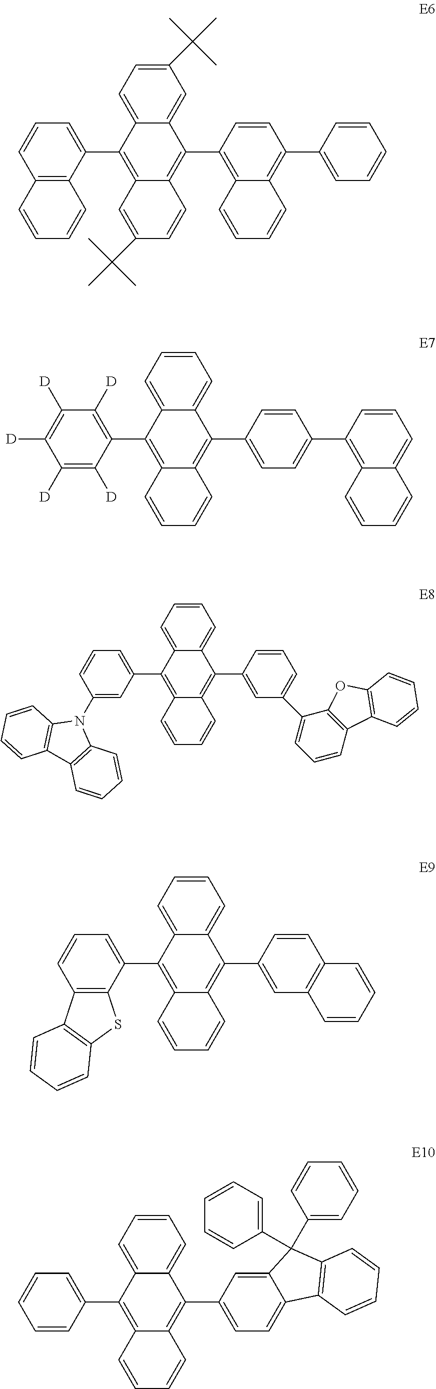

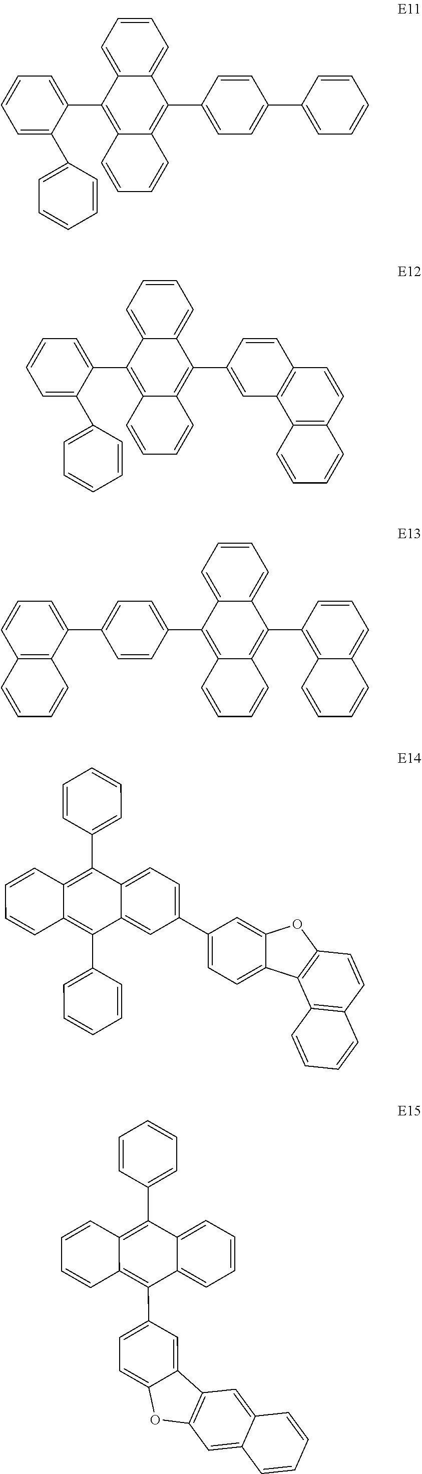

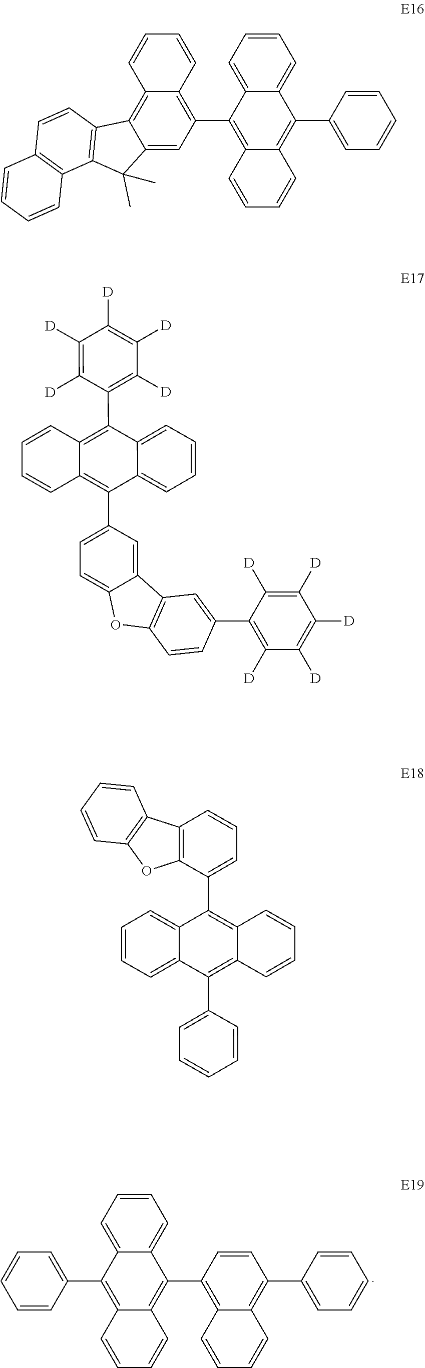

In one or more embodiments, the emission layer EML may include a compound represented by Formula E-2a or Formula E-2b. The compound represented by Formula E-2a or Formula E-2b may be utilized as a phosphorescent host material.

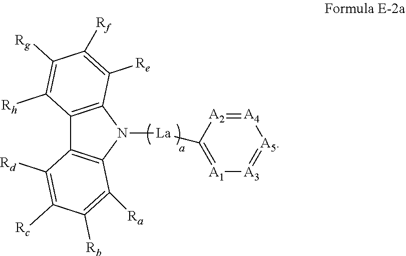

In Formula E-2a, a may be an integer of 0 to 10, La may be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a is an integer of 2 or more, a plurality of La(s) may each independently be a substituted or unsubstituted arylene group having 6 to 30 ring-forming carbon atoms, or a substituted or unsubstituted heteroarylene group having 2 to 30 ring-forming carbon atoms.

In some embodiments, in Formula E-2a, A₁ to A₅ may each independently be N or CRᵢ. Rₐ to Rᵢ may each independently be hydrogen, deuterium, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. Rₐ to Rᵢ may be bonded to an adjacent group to form a hydrocarbon ring or a heterocycle containing N, O, S, etc., as a ring-forming atom.

In some embodiments, in Formula E-2a, two or three selected from among A₁ to A₅ may be N, and the rest may be CRᵢ.

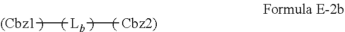

In Formula E-2b, Cbz1 and Cbz2 may each independently be an unsubstituted carbazole group, or a carbazole group substituted with an aryl group having 6 to 30 ring-forming carbon atoms. L_{b} is a direct linkage, a substituted or unsubstituted arylene group having 6 to 30 ring-forming carbon atoms, or a substituted or unsubstituted heteroarylene group having 2 to 30 ring-forming carbon atoms. In some embodiments, b is an integer of 0 to 10, and when b is an integer of 2 or more, a plurality of L_{b}(s) may each independently be a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be represented by any one selected from among the compounds of Compound Group E-2. However, the compounds listed in Compound Group E-2 are mere examples, and the compound represented by Formula E-2a or Formula E-2b is not limited to those represented in Compound Group E-2.

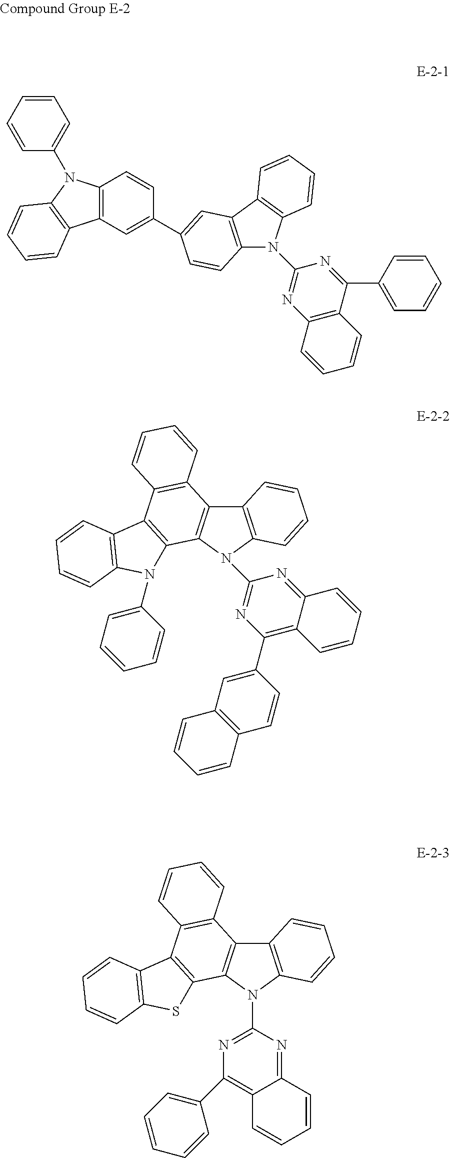 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

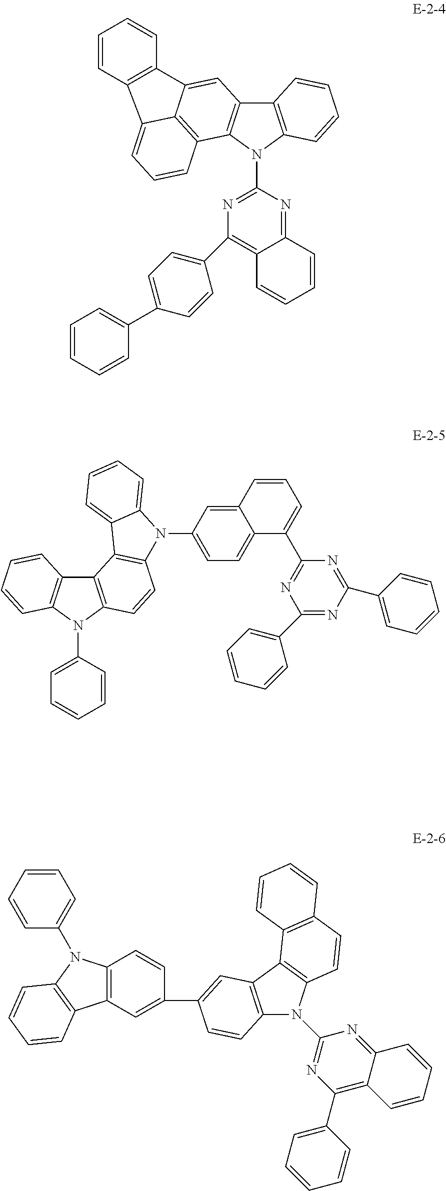 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

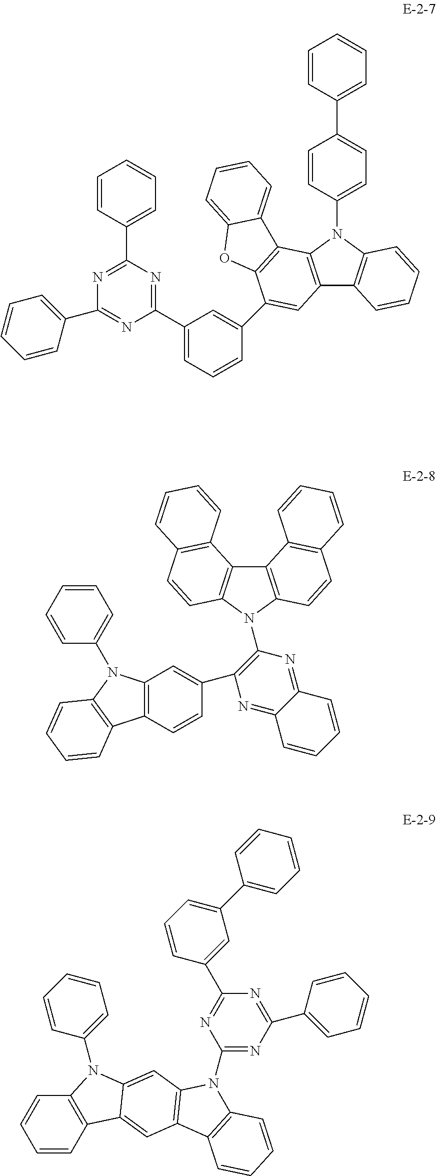 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

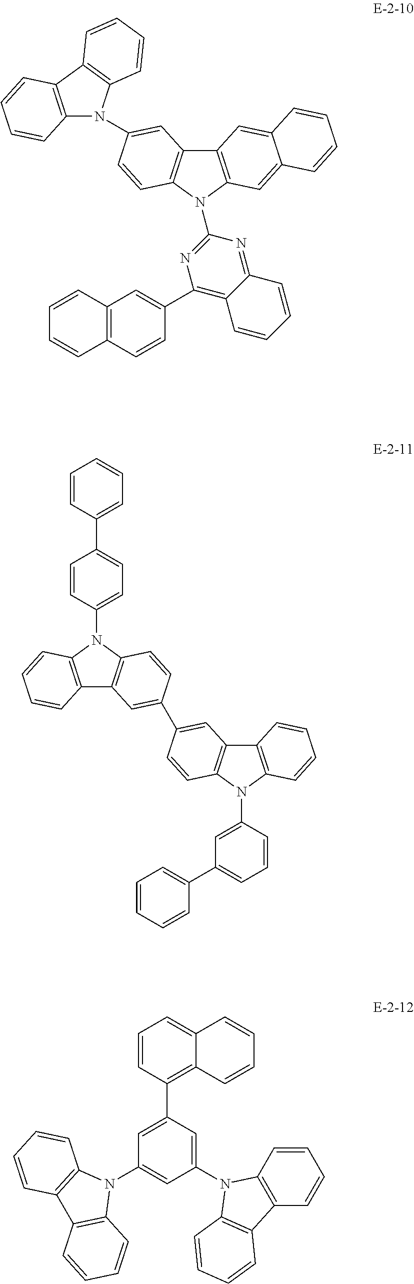 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

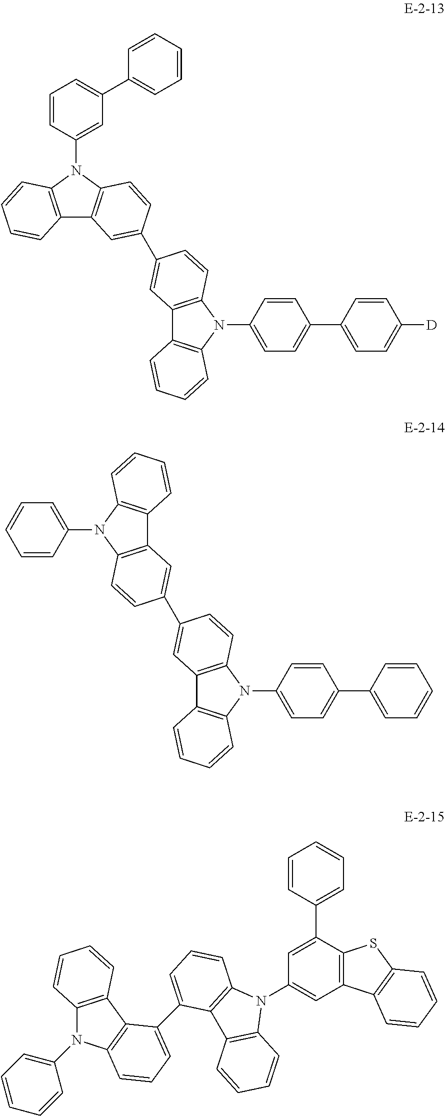 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

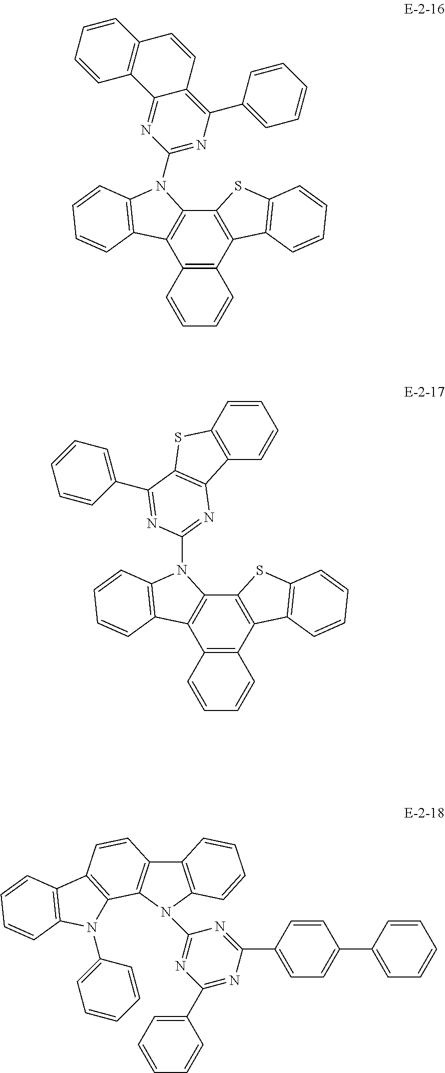 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

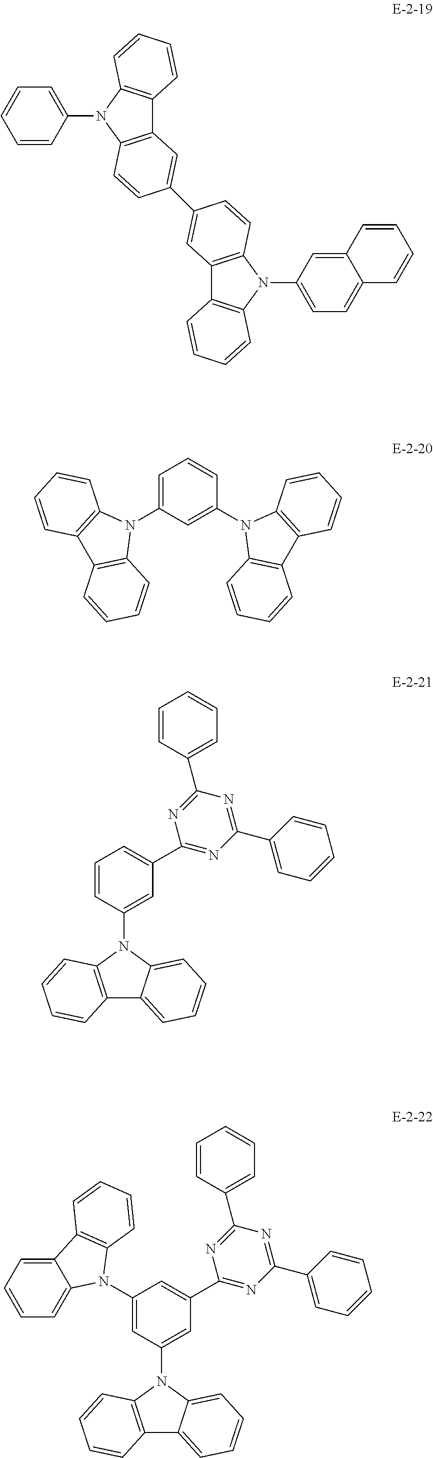 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1]

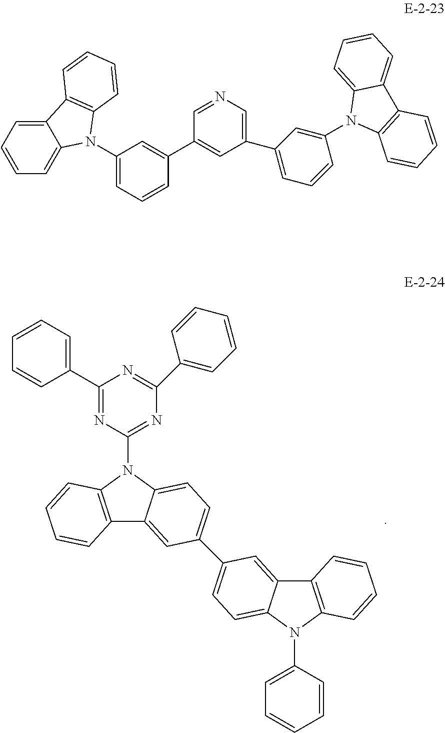 [SMILES: c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a general material suitable in the art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, embodiments of the present disclosure are not limited thereto, for example, tris(8-hydroxyquinolinato)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be utilized as a host material.

In one or more embodiments, the emission layer EML may include a compound represented by Formula M-a. The compound represented by Formula M-a may be utilized as a phosphorescent dopant material.

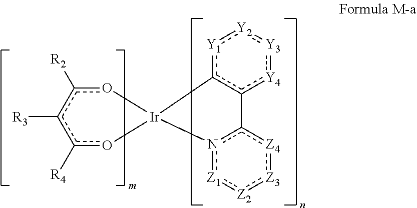

In Formula M-a, Y₁ to Y₄ and Z₁ to Z₄ may each independently be CR₁ or N, R₁ to R₄ may each independently be hydrogen, deuterium, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In Formula M-a, m is 0 or 1, and n is 2 or 3. In Formula M-a, when m is 0, n is 3, and when m is 1, n is 2.

The compound represented by Formula M-a may be utilized as a phosphorescent dopant.

The compound represented by Formula M-a may be represented by any one selected from among Compound M-a1 to Compound M-a25. However, Compounds M-a1 to M-a25 are mere examples, and the compound represented by Formula M-a is not limited to those represented by Compounds M-a1 to M-a25.

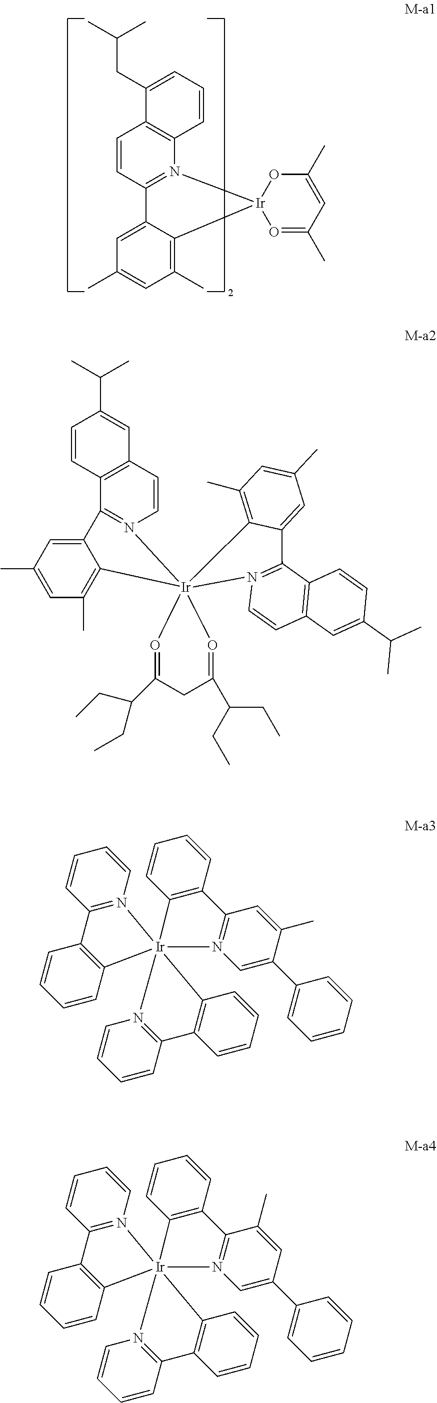

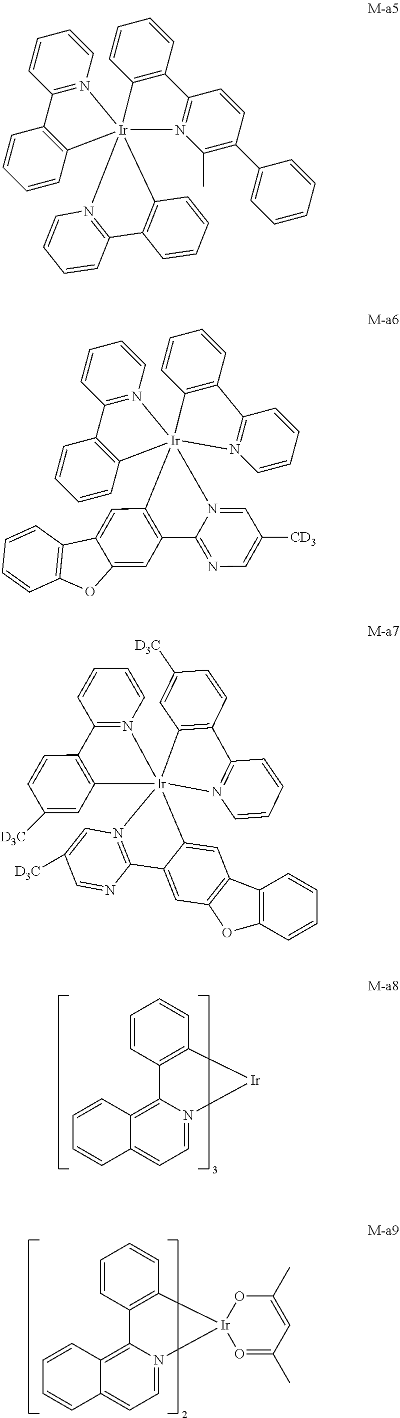

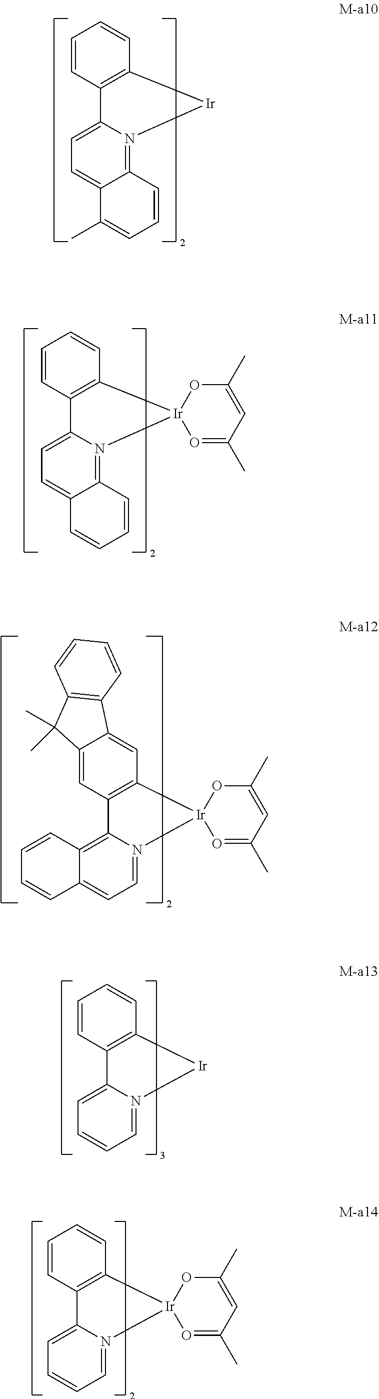

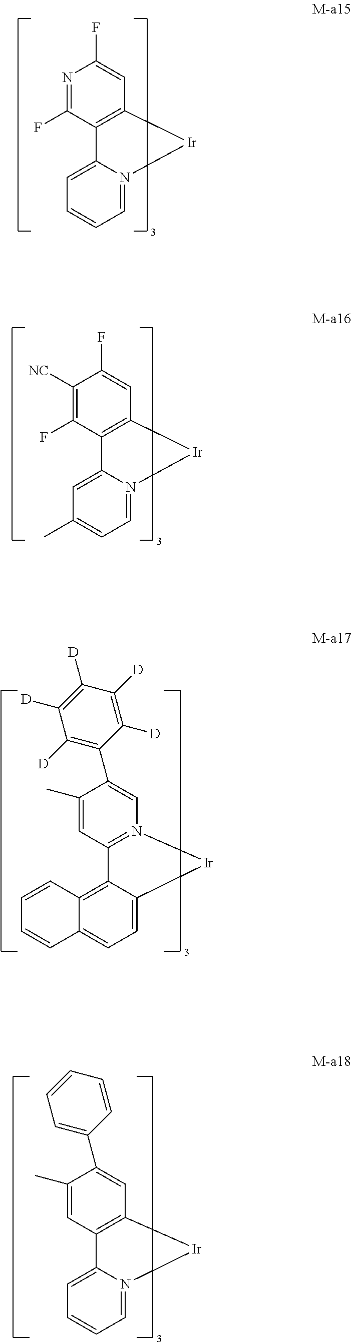

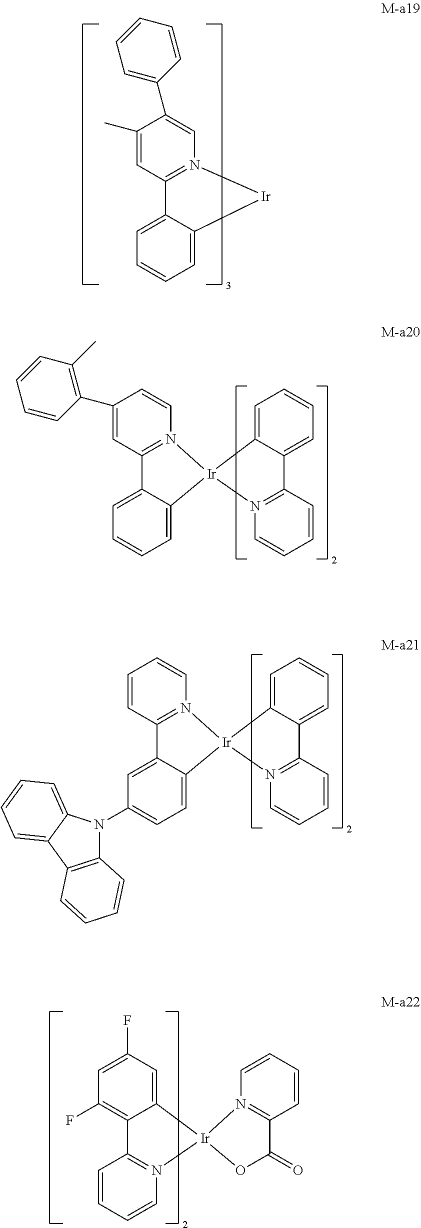

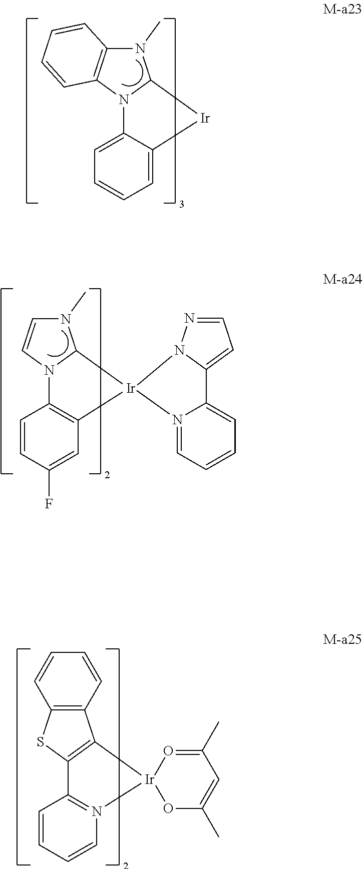

In one or more embodiments, the emission layer EML may include a compound represented by any one selected from among Formula F-a to Formula F-c. The compound represented by Formula F-a to Formula F-c may be utilized as a fluorescence dopant material.

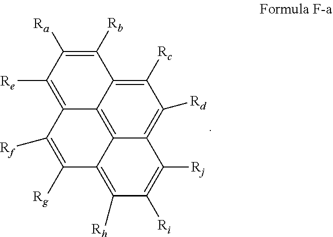

In Formula F-a, two selected from among Rₐ to Rⱼ may each independently be substituted with *—NAr₁Ar₂. The others, which are not substituted with *—NAr₁Ar₂ among Rₐ to Rⱼ may each independently be hydrogen, deuterium, a halogen, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In *—NAr₁Ar₂, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, in some embodiments, at least one of Ar₁ or Ar₂ may be a heteroaryl group containing O or S as a ring-forming atom.

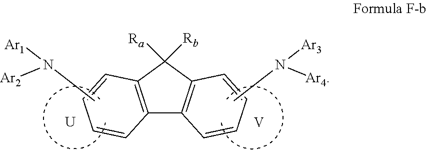

In Formula F-b, Rₐ and R_{b} may each independently be hydrogen, deuterium, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. Ar₁ to Ar₄ may each independently be a substituted or unsubstituted aryl group having 6 to 30 ring-forming carbon atoms, or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms, or a substituted or unsubstituted heterocycle having 2 to 30 ring-forming carbon atoms. At least one selected from among Ar₁ to Ar₄ may be a heteroaryl group containing O or S as a ring-forming atom.

In Formula F-b, the number of rings represented by U and V may each independently be 0 or 1. For example, in Formula F-b, it refers to that when the number of U or V is 1, one ring constitutes a fused ring at a portion indicated by U or V, and when the number of U or V is 0, a ring indicated by U or V does not exist. For example, when the number of U is 0 and the number of V is 1, or when the number of U is 1 and the number of V is 0, the fused ring having a fluorene core in Formula F-b may be a cyclic compound having four rings. In some embodiments, when each number of U and V is 0, the fused ring in Formula F-b may be a cyclic compound having three rings. In some embodiments, when each number of U and V is 1, the fused ring having a fluorene core in Formula F-b may be a cyclic compound having five rings.

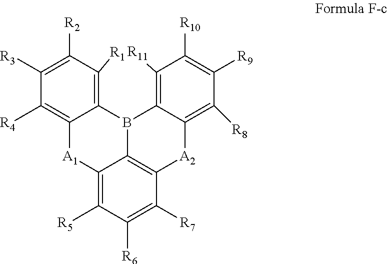

In Formula F-c, A₁ and A₂ may each independently be O, S, Se, or NRₘ, and Rₘ may be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ may each independently be hydrogen, deuterium, a halogen, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring.

In Formula F-c, A₁ and A₂ may each independently be bonded to substituents of an adjacent ring to form a fused ring. For example, in some embodiments, when A₁ and A₂ may each independently be NRₘ, A₁ may be bonded to R₄ or R₅ to form a ring. In some embodiments, A₂ may be bonded to R₇ or R₈ to form a ring.

In one or more embodiments, the emission layer EML may further include, as a suitable dopant material, one or more selected from styryl derivatives (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi)), perylene and the derivatives thereof (e.g., 2,5,8,11-tetra-t-butylperylene (TBP)), pyrene and the derivatives thereof (e.g., 1,1-dipyrene, 1,4-dipyrenylbenzene, 1,4-bis(N,N-diphenylamino)pyrene), etc.

In one or more embodiments, the emission layer EML may further include a suitable phosphorescence dopant material. For example, a metal complex containing iridium (Ir), platinum (Pt), osmium (Os), aurum (Au), titanium (Ti), zirconium (Zr), hafnium (Hf), europium (Eu), terbium (Tb), or thulium (Tm) may be utilized as a phosphorescent dopant. For example, iridium(III) bis(4,6-difluorophenylpyridinato-N,C2′)picolinate (Firpic), bis(2,4-difluorophenylpyridinato)-tetrakis(1-pyrazolyl)borate iridium(III) (Fir6), and/or platinum octaethyl porphyrin (PtOEP) may be utilized as a phosphorescent dopant. However, embodiments of the present disclosure are not limited thereto.

In one or more embodiments, the emission layer EML may include a quantum dot material. The core of the quantum dot may be selected from among a Group II-VI compound, a Group III-VI compound, a Group I-III-IV compound, a Group III-V compound, a Group III-II-V compound, a Group IV-VI compound, a Group IV element, a Group IV compound, and a combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The Group III-VI compound may include a binary compound such as In₂S₃ or In₂Se₃, a ternary compound such as InGaS₃ or InGaSe₃, or any combination thereof.

The Group I-III-VI compound may be selected from a ternary compound selected from the group consisting of AgInS, AgInS₂, CuInS, CuInS₂, AgGaS₂, CuGaS₂ CuGaO₂, AgGaO₂, AgAlO₂, and a mixture thereof, and/or a quaternary compound such as AgInGaS₂ or CuInGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof, and a quaternary compound selected from the group consisting of GaAlNP, GaAlNAs, GaAlNSb, GaAlPAs, GaAlPSb, GaInNP, GaInNAs, GalnNSb, GaInPAs, GaInPSb, InAlNP, InAlNAs, InAlNSb, InAlPAs, InAlPSb, and a mixture thereof. In some embodiments, the Group III-V compound may further include a Group II metal. For example, InZnP, etc., may be selected as a Group III-II-V compound.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof. The Group IV element may be selected from the group consisting of Si, Ge, and a mixture thereof. The Group IV compound may be a binary compound selected from the group consisting of SiC, SiGe, and a mixture thereof.

In one or more embodiments, the binary compound, the ternary compound, or the quaternary compound may be present in a particle with a substantially uniform concentration distribution, or may be present in substantially the same particle with a partially different concentration distribution. In some embodiments, the quantum dot may have a core/shell structure in which one quantum dot surrounds another quantum dot. The core/shell structure may have a concentration gradient in which the concentration of elements present in the shell decreases toward the core.

In some embodiments, the quantum dot may have the above-described core/shell structure including a core containing nanocrystals and a shell around (e.g., surrounding) the core. The shell of the quantum dot may serve as a protection layer to prevent or reduce the chemical deformation of the core to maintain semiconductor properties, and/or a charging layer to impart electrophoresis properties to the quantum dot. The shell may be a single layer or a multilayer. An example of the shell of the quantum dots may include a metal or non-metal oxide, a semiconductor compound, or a combination thereof.

For example, the metal or non-metal oxide suitable as a shell may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO, and/or a ternary compound such as MgAl₂O₄, CoFe₂O₄, NiFe₂O₄, or CoMn₂O₄, but embodiments of the present disclosure are not limited thereto.

Also, examples of the semiconductor compound suitable as a shell may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments of the present disclosure are not limited thereto.

The quantum dot may have a full width of half maximum (FWHM) of a light emitting wavelength spectrum of about 45 nm or less, about 40 nm or less, or about 30 nm or less. The color purity or color reproducibility may be improved in the above range. In some embodiments, light emitted through such a quantum dot is emitted in all directions, and thus a wide viewing angle may be improved.

In some embodiments, although the form/shape of the quantum dot is not particularly limited as long as it is a form/shape commonly utilized in the art, in some embodiments, the quantum dot in the form/shape of substantially spherical, pyramidal, multi-arm, or cubic nanoparticles, nanotubes, nanowires, nanofibers, nanoplate particles, etc., may be utilized.

A quantum dot may control the color of emitted light according to the particle size thereof and thus the quantum dot may have one or more suitable light emission colors such as green, red, etc.

In each light emitting device ED illustrated in FIGS. 3 to 6, an electron transport region ETR is provided on the emission layer EML. The electron transport region ETR may include at least one of a hole blocking layer HBL, an electron transport layer ETL, or an electron injection layer EIL, but embodiments of the present disclosure are not limited thereto.

The electron transport region ETR may have a single layer formed of a single material, a single layer formed of a plurality of different materials, or a multilayer structure including a plurality of layers formed of a plurality of different materials.

For example, in some embodiments, the electron transport region ETR may have a single layer structure of an electron injection layer EIL or an electron transport layer ETL, and may have a single layer structure formed of an electron injection material and an electron transport material. In some embodiments, the electron transport region ETR may have a single layer structure formed of a plurality of different materials, or may have a structure in which an electron transport layer ETL/electron injection layer EIL, a hole blocking layer HBL/electron transport layer ETL/electron injection layer EIL are stacked in order (e.g., in the stated order) from the emission layer EML, but embodiments of the present disclosure are not limited thereto. The electron transport region ETR may have a thickness, for example, from about 1,000 Å to about 1,500 Å.

The electron transport region ETR may be formed by utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

The electron transport region ETR may include a compound represented by Formula ET-1:

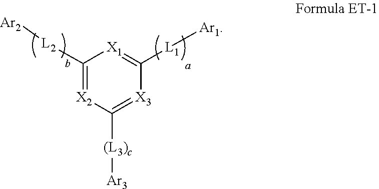

In Formula ET-1, at least one selected from among X₁ to X₃ is N, and the rest are CRₐ. Rₐ may be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may each independently be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-1, a to c may each independently be an integer of 0 to 10. In Formula ET-1, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a to c may each independently be an integer of 2 or more, L₁ to L₃ may each independently be a substituted or unsubstituted arylene group having 6 to 30 ring-forming carbon atoms, or a substituted or unsubstituted heteroarylene group having 2 to 30 ring-forming carbon atoms.

In one or more embodiments, the electron transport region ETR may include an anthracene-based compound. However, embodiments of the present disclosure are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq₂), 9,10-di(naphthalene-2-yl)anthracene (ADN), 1,3-Bis[3,5-di(pyridin-3-yl)phenyl]benzene (BmPyPhB), or a mixture thereof.

In one or more embodiments, the electron transport region ETR may include at least one selected from among Compound ET1 to Compound ET36:

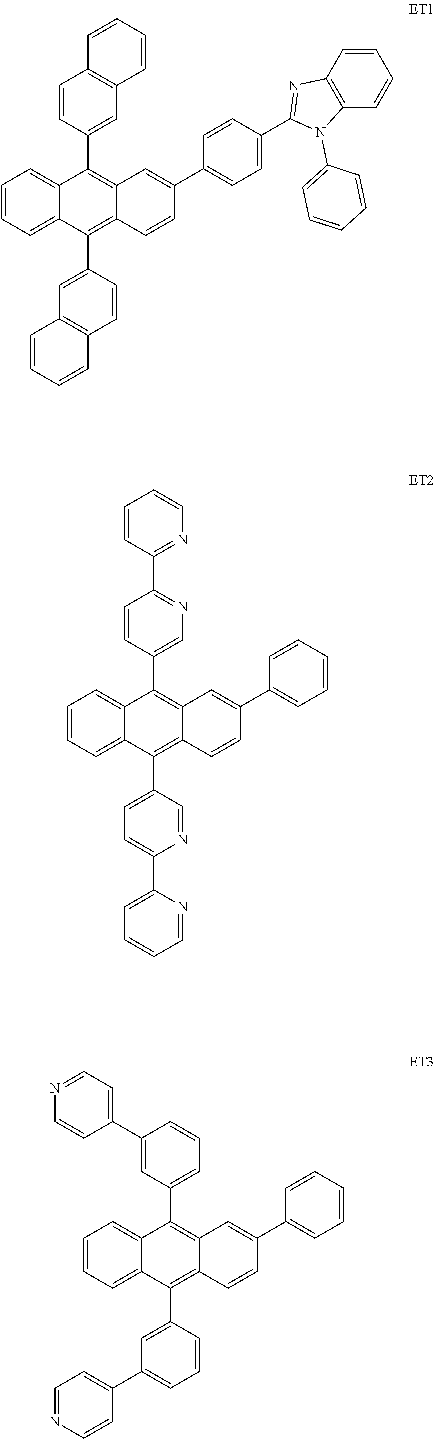 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

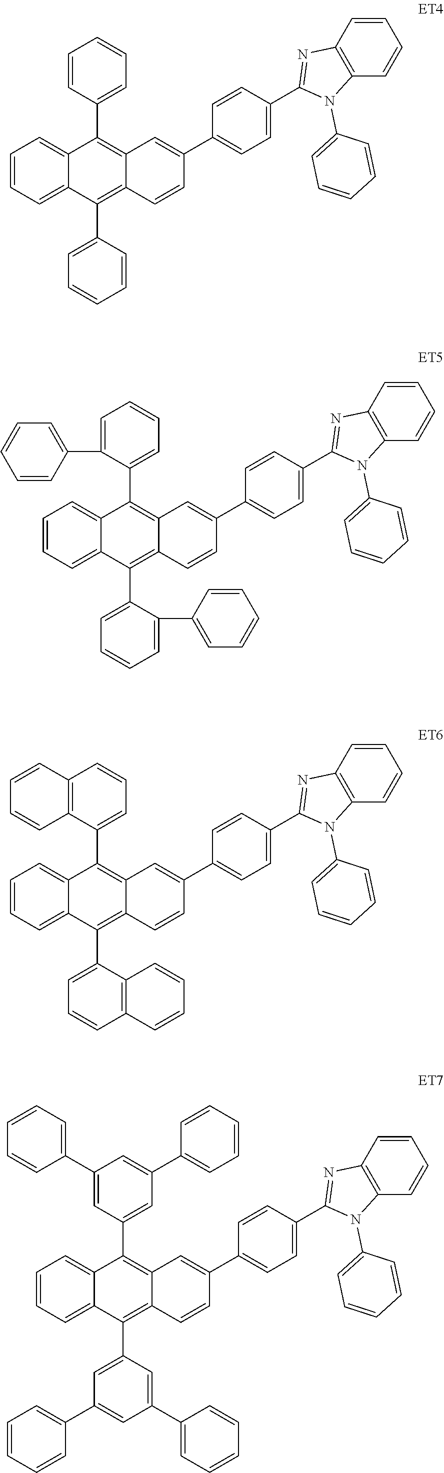 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

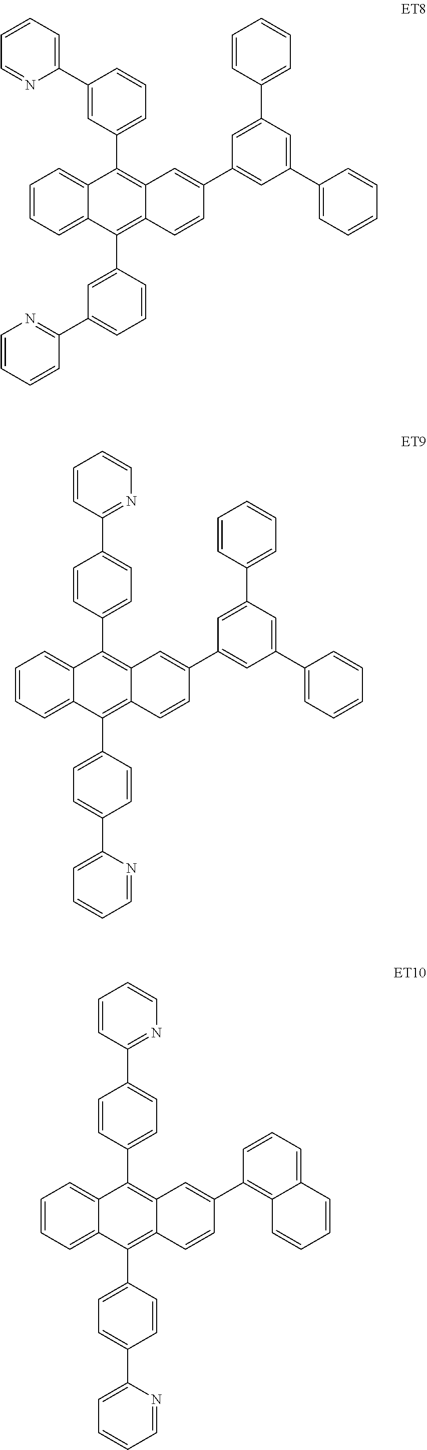 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

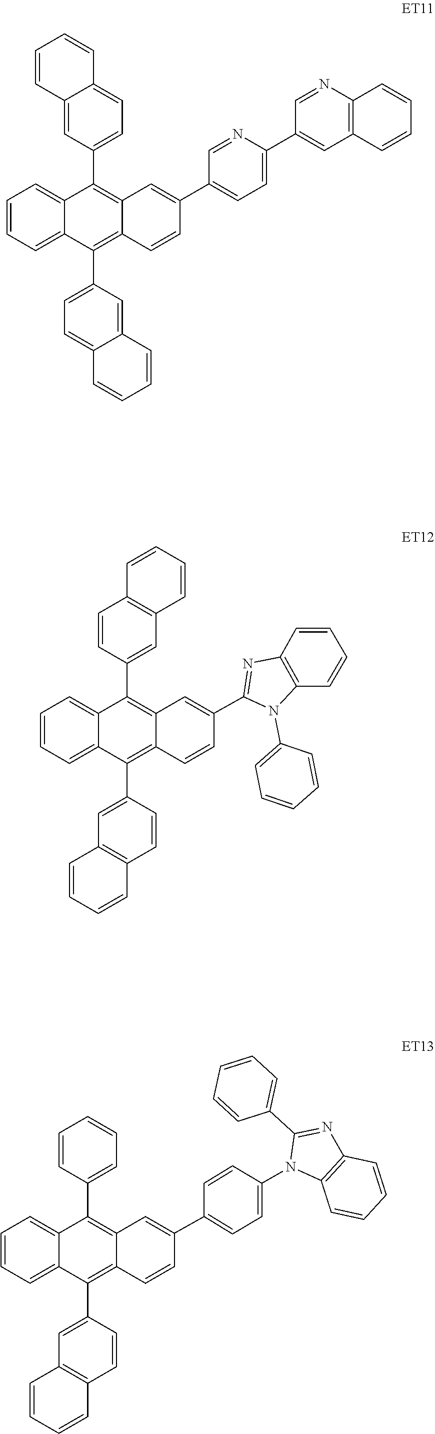 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

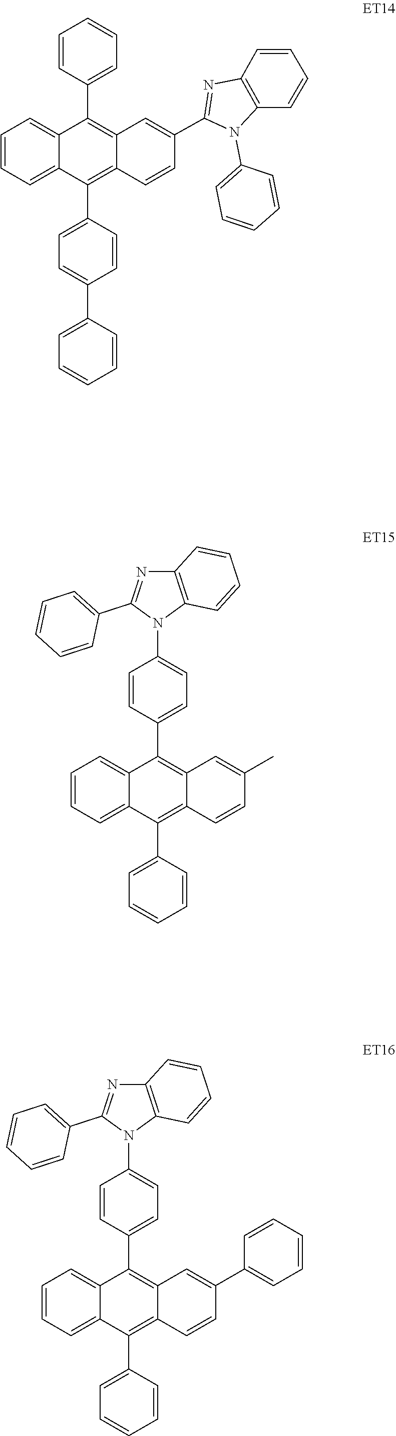 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

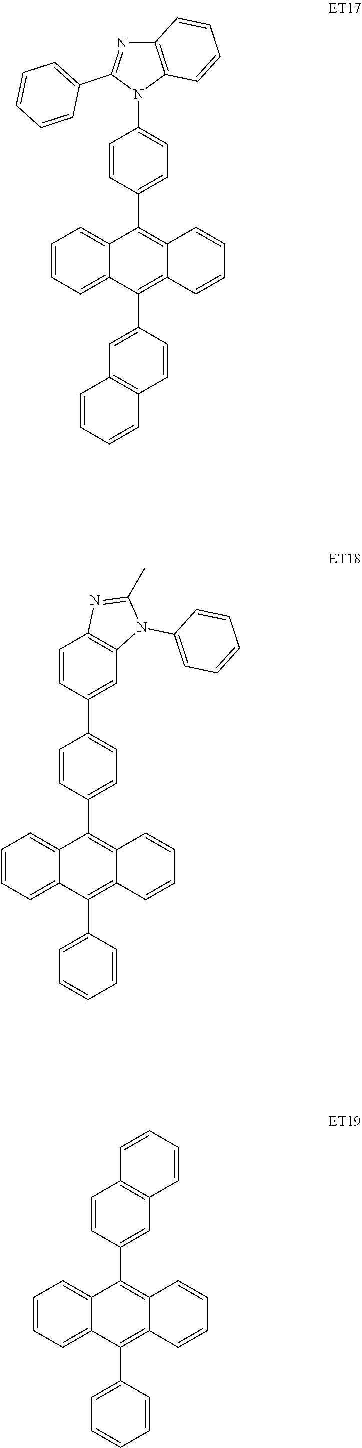

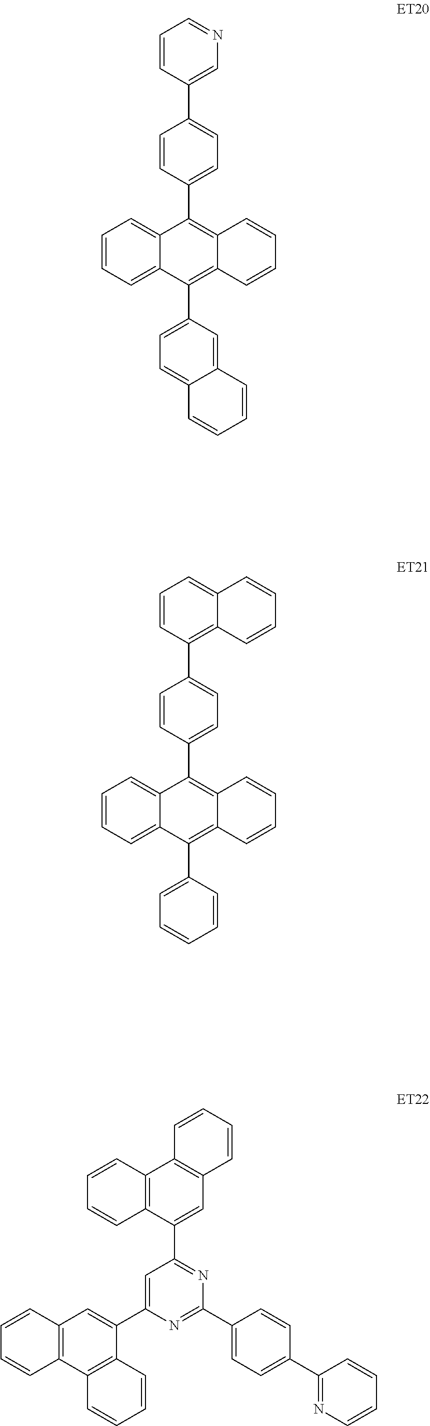

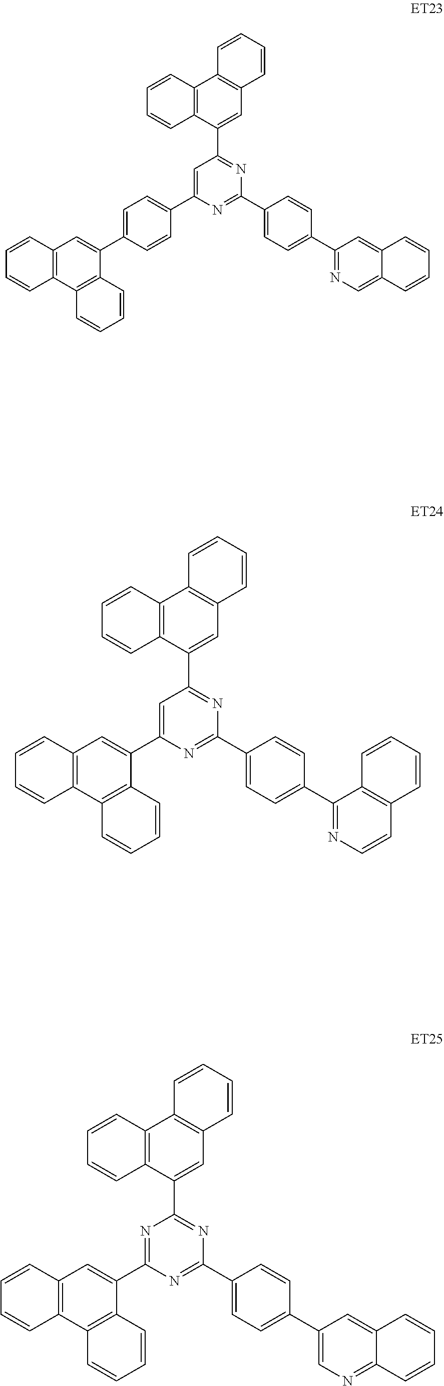 [SMILES: c1ccc2cc(-c3ccc(-c4nc(-c5ccc(-c6cc7ccccc7c7ccccc67)cc5)cc(-c5cc6ccccc6c6ccccc56)n4)cc3)ncc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

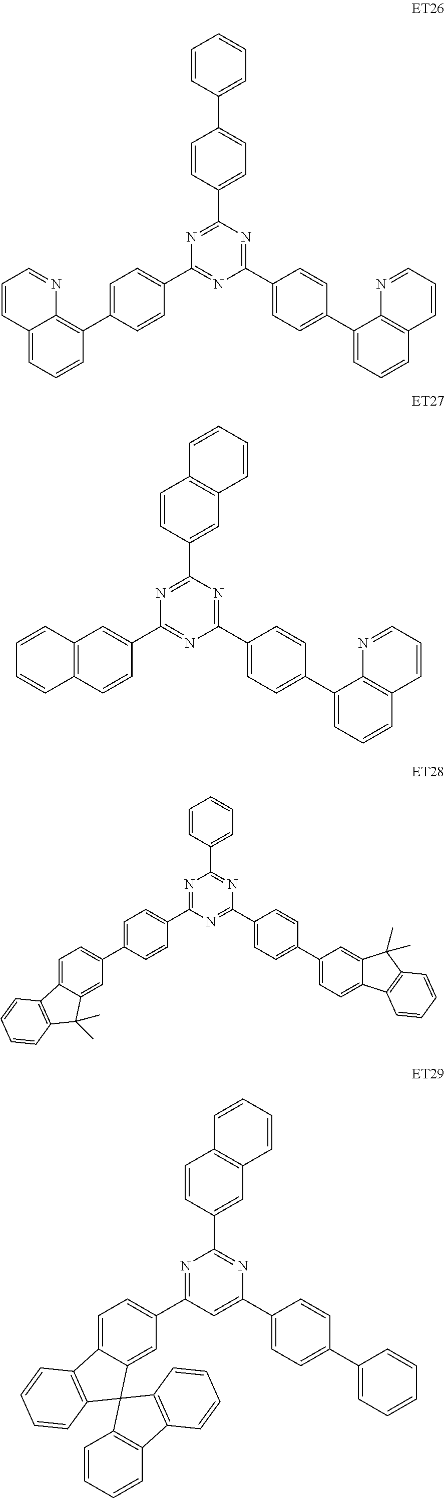 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1]

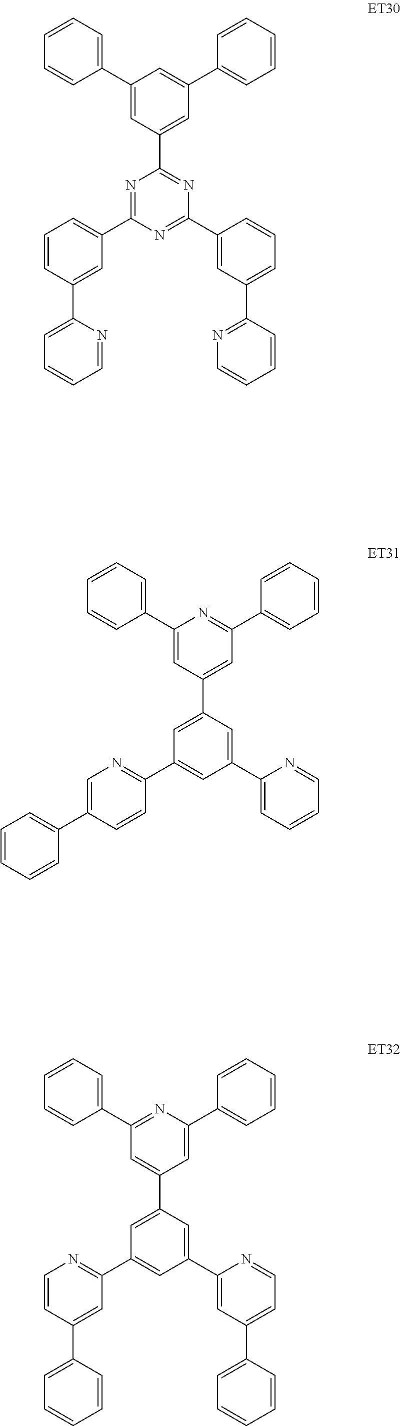 [SMILES: c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1]

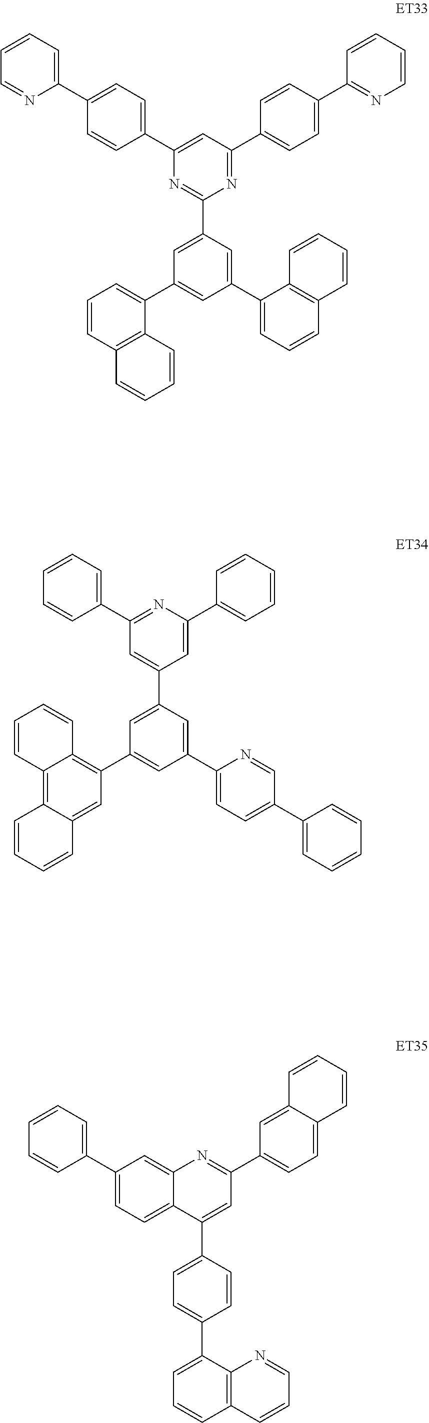 [SMILES: c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1]

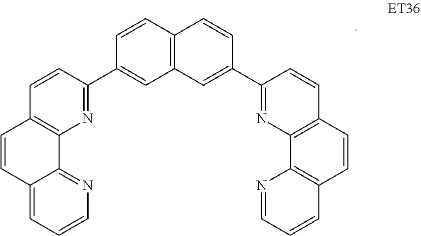 [SMILES: c1cnc2c(c1)ccc1ccc(-c3ccc4ccc(-c5ccc6ccc7cccnc7c6n5)cc4c3)nc12]

In some embodiments, the electron transport regions ETR may include a metal halide such as LiF, NaCl, CsF, RbCl, RbI, CuI, or KI, a lanthanide metal such as Yb, or a co-deposited material of the metal halide and the lanthanide metal. For example, the electron transport region ETR may include KI:Yb, RbI:Yb, LiF:Yb, etc., as a co-deposited material. In some embodiments, the electron transport region ETR may be formed utilizing a metal oxide such as Li₂O or BaO, or 8-hydroxyl-lithium quinolate (Liq), etc., but embodiments of the present disclosure are not limited thereto. In some embodiments, the electron transport region ETR may also be formed of a mixture material of an electron transport material and an insulating organometallic salt. The organometallic salt may be a material having an energy band gap of about 4 eV or more. For example, the organometallic salt may include, for example, a metal acetate, a metal benzoate, a metal acetoacetate, a metal acetylacetonate, or a metal stearate.

In one or more embodiments, the electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to the above-described materials, but embodiments of the present disclosure are not limited thereto.

The electron transport region ETR may include the above-described compounds of the hole transport region in at least one of the electron injection layer EIL, the electron transport layer ETL, or the hole blocking layer HBL.

When the electron transport region ETR includes the electron transport layer ETL, the electron transport layer ETL may have a thickness of about 100 Å to about 1,000 Å, for example, about 150 Å to about 500 Å. When the thickness of the electron transport layer ETL satisfies the aforementioned range, satisfactory electron transport characteristics may be obtained without a substantial increase in driving voltage. When the electron transport region ETR includes the electron injection layer EIL, the electron injection layer EIL may have a thickness of about 1 Å to about 100 Å, for example, about 3 Å to about 90 Å. When the thickness of the electron injection layer EIL satisfies the above-described range, satisfactory electron injection characteristics may be obtained without a substantial increase in driving voltage.

The second electrode EL2 may be provided on the electron transport region ETR. The second electrode EL2 may be a common electrode. The second electrode EL2 may be a cathode or an anode, but embodiments of the present disclosure are not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is a transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, or a compound or mixture thereof (e.g., AgMg, AgYb, or MgAg). In some embodiments, the second electrode EL2 may have a multilayer structure including a reflective film or a transflective film formed of one or more selected from the above-described materials, and a transparent conductive film formed of ITO, IZO, ZnO, ITZO, etc. For example, the second electrode EL2 may include one or more selected from the above-described metal materials, combinations of at least two metal materials of the above-described metal materials, oxides of the above-described metal materials, and/or the like.

In some embodiments, the second electrode EL2 may be connected with an auxiliary electrode. When the second electrode EL2 is connected with the auxiliary electrode, the resistance of the second electrode EL2 may be decreased.

In some embodiments, a capping layer CPL may further be disposed on the second electrode EL2 of the light emitting device ED. The capping layer CPL may include a multilayer or a single layer.

In one or more embodiments, the capping layer CPL may be an organic layer or an inorganic layer. For example, when the capping layer CPL contains an inorganic material, the inorganic material may include an alkaline metal compound (e.g., LiF), an alkaline earth metal compound (e.g., MgF₂), SiON, SiNₓ, SiOy, etc.

For example, when the capping layer CPL includes an organic material, the organic material may include 2,2′-dimethyl-N,N′-di-[(1-naphthyl)-N,N′-diphenyl]-1,1′-biphenyl-4,4′-diamine (α-NPD), NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), etc., and/or an epoxy resin, and/or acrylate such as methacrylate. However, embodiments of the present disclosure are not limited thereto, and the capping layer CPL may include at least one selected from among Compounds P1 to P5:

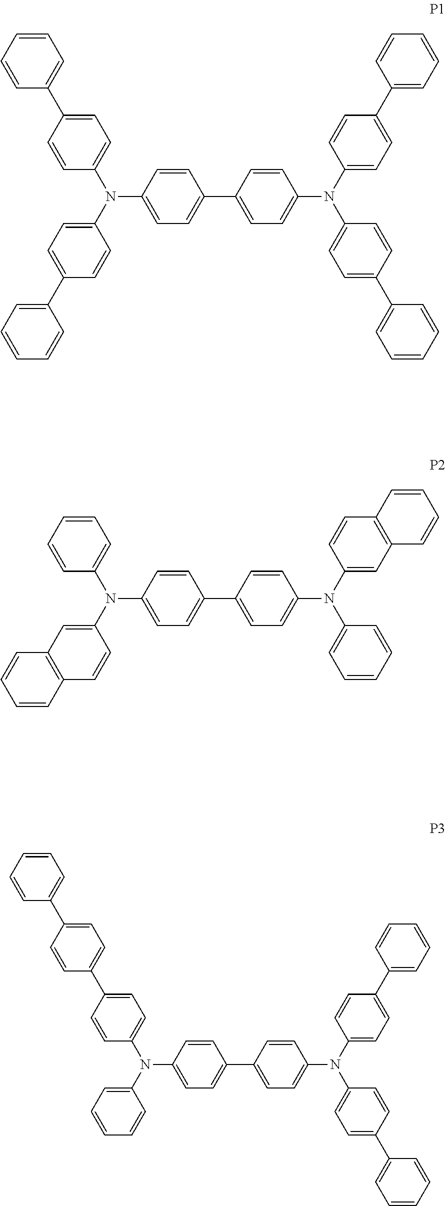 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

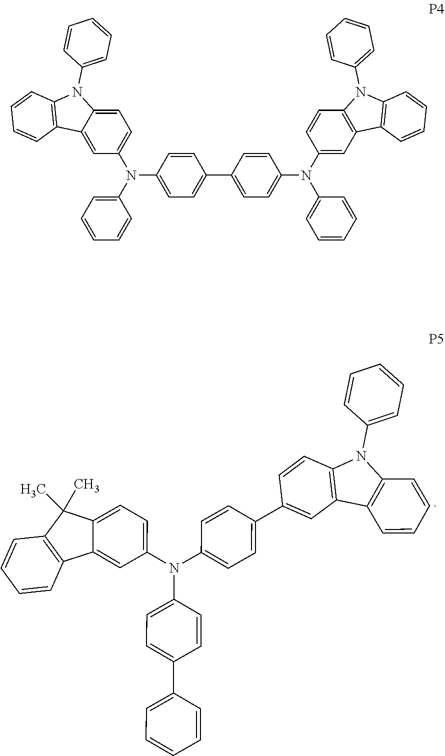 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

In some embodiments, the refractive index of the capping layer CPL may be about 1.6 or more. For example, in some embodiments, the refractive index of the capping layer CPL may be 1.6 or more with respect to light in a wavelength range of about 550 nm to about 660 nm.

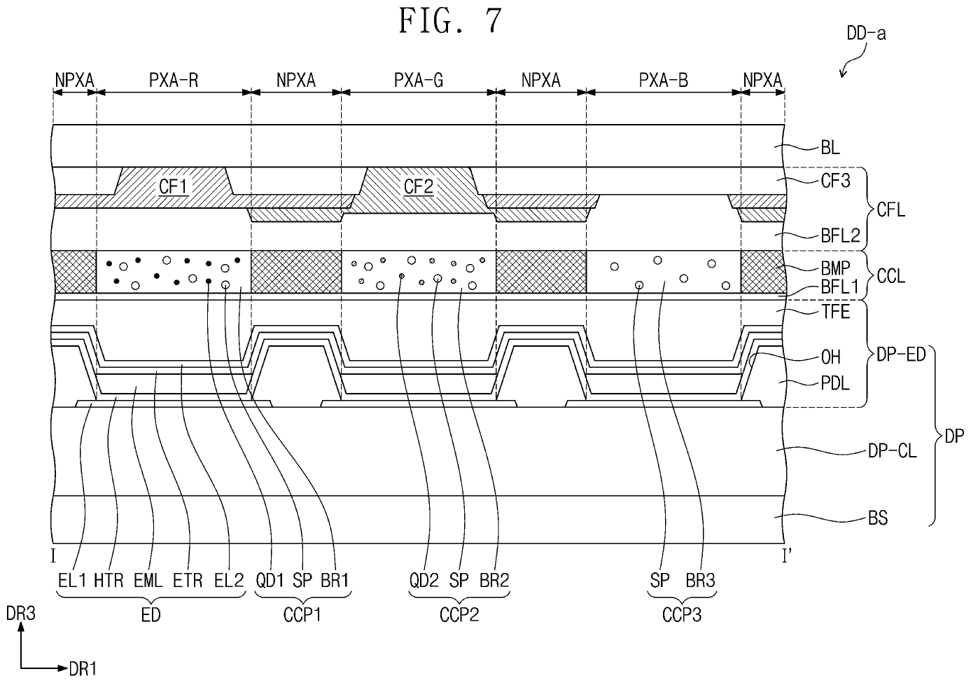

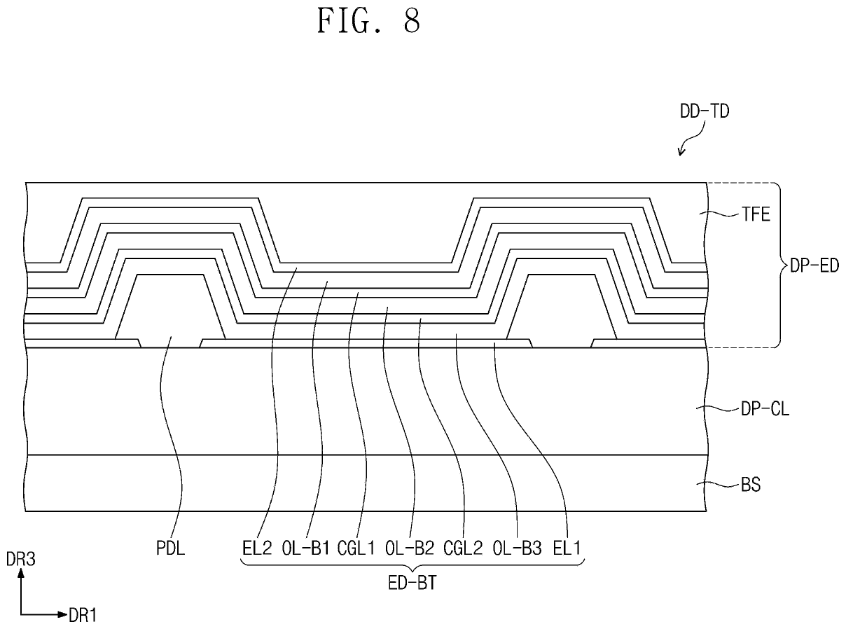

Each of FIGS. 7 and 8 is a cross-sectional view of a display apparatus according to one or more embodiments of the present disclosure. Hereinafter, in describing the display apparatuses of embodiments with reference to FIGS. 7 and 8, the duplicated features which have been described in FIGS. 1 to 6 are not described again for conciseness, but their differences will be mainly described.

Referring to FIG. 7, the display apparatus DD-a according to one or more embodiments may include a display panel DP including a display device layer DP-ED, a light control layer CCL disposed on the display panel DP, and a color filter layer CFL.

In one or more embodiments illustrated in FIG. 7, the display panel DP may include a base layer BS, a circuit layer DP-CL provided on the base layer BS, and the display device layer DP-ED, and the display device layer DP-ED may include a light emitting device ED.

The light emitting device ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In some embodiments, the structures of the light emitting devices of FIGS. 3 to 6 as described above may be equally applied to the structure of the light emitting device ED illustrated in FIG. 7.

The emission layer EML of the light emitting device ED included in the display apparatus DD-a according to one or more embodiments may include the above-described fused polycyclic compound of one or more embodiments.

Referring to FIG. 7, the emission layer EML may be disposed in an opening OH defined in a pixel defining film PDL. For example, the emission layer EML which is divided by the pixel defining film PDL and provided corresponding to each of light emitting regions PXA-R, PXA-G, and PXA-B may be to emit light in substantially the same wavelength range. In one or more embodiments, in the display apparatus DD-a, the emission layer EML may be to emit blue light. In some embodiments, the emission layer EML may be provided as a common layer in the entire light emitting regions PXA-R, PXA-G, and PXA-B.

The light control layer CCL may be disposed on the display panel DP. The light control layer CCL may include a light conversion body. The light conversion body may be a quantum dot, a phosphor, and/or the like. The light conversion body may be to emit provided light by converting the wavelength thereof. For example, the light control layer CCL may a layer containing a quantum dot or a layer containing a phosphor.

The light control layer CCL may include a plurality of light control parts CCP1, CCP2 and CCP3. The light control parts CCP1, CCP2, and CCP3 may be spaced apart from each other.

Referring to FIG. 7, divided patterns BMP may be disposed between the light control parts CCP1, CCP2, and CCP3 which are spaced apart from each other, but embodiments of the present disclosure are not limited thereto. FIG. 7 illustrates that the divided patterns BMP do not overlap the light control parts CCP1, CCP2, and CCP3, but, in some embodiments, at least a portion of the edges of the light control parts CCP1, CCP2, and CCP3 may overlap the divided patterns BMP.

The light control layer CCL may include a first light control part CCP1 containing a first quantum dot QD1 which converts first color light provided from the light emitting device ED into second color light, a second light control part CCP2 containing a second quantum dot QD2 which converts the first color light into third color light, and a third light control part CCP3 which transmits the first color light.

In one or more embodiments, the first light control part CCP1 may provide red light that is the second color light, and the second light control part CCP2 may provide green light that is the third color light. The third light control part CCP3 may provide blue light by transmitting the blue light that is the first color light provided from the light emitting device ED. For example, in some embodiments, the first quantum dot QD1 may be a red quantum dot to emit red light, and the second quantum dot QD2 may be a green quantum dot to emit greed light. The same as described above may be applied with respect to the quantum dots QD1 and QD2.

In some embodiments, the light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include (e.g., may exclude) any quantum dot but include the scatterer SP.

The scatterer SP may be inorganic particles. For example, the scatterer SP may include at least one of TiO₂, ZnO, Al₂O₃, SiO₂, or hollow sphere silica. The scatterer SP may include any one selected from among TiO₂, ZnO, Al₂O₃, SiO₂, and hollow sphere silica, or may be a mixture of at least two materials selected from among TiO₂, ZnO, Al₂O₃, SiO₂, and hollow sphere silica.

The first light control part CCP1, the second light control part CCP2, and the third light control part CCP3 each may respectively include base resins BR1, BR2, and BR3 in which the quantum dots QD1 and QD2 and the scatterer SP are dispersed. In one or more embodiments, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3. The base resins BR1, BR2, and BR3 are media in which the quantum dots QD1 and QD2 and the scatterer SP are dispersed, and may be formed of one or more suitable resin compositions, which may be generally referred to as a binder. For example, the base resins BR1, BR2, and BR3 may be acrylic-based resins, urethane-based resins, silicone-based resins, epoxy-based resins, etc. The base resins BR1, BR2, and BR3 may be transparent resins. In one or more embodiments, the first base resin BR1, the second base resin BR2, and the third base resin BR3 may be the same as or different from each other.

The light control layer CCL may include a barrier layer BFL1. The barrier layer BFL1 may serve to prevent or reduce the penetration of moisture and/or oxygen (hereinafter, referred to as ‘moisture/oxygen’). The barrier layer BFL1 may be disposed on the light control parts CCP1, CCP2, and CCP3 to block or reduce the light control parts CCP1, CCP2 and CCP3 from being exposed to moisture/oxygen. In some embodiments, the barrier layer BFL1 may cover the light control parts CCP1, CCP2, and CCP3. In some embodiments, a barrier layer BFL2 may be provided between the light control parts CCP1, CCP2, and CCP3 and the color filter layer CFL.

The barrier layers BFL1 and BFL2 may include at least one inorganic layer. For example, the barrier layers BFL1 and BFL2 may include an inorganic material. For example, in some embodiments, the barrier layers BFL1 and BFL2 may include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a thin metal film which secures a transmittance, etc. In some embodiments, the barrier layers BFL1 and BFL2 may further include an organic film. The barrier layers BFL1 and BFL2 may be formed of a single layer or a plurality of layers.

In one or more embodiments, in the display apparatus DD-a, the color filter layer CFL may be disposed on the light control layer CCL. For example, in some embodiments, the color filter layer CFL may be directly disposed on the light control layer CCL. In these embodiments, the barrier layer BFL2 may not be provided.

The color filter layer CFL may include a light shielding part BM and color filters CF1, CF2, and CF3. The color filter layer CFL may include a first filter CF1 configured to transmit the second color light, a second filter CF2 configured to transmit the third color light, and a third filter CF3 configured to transmit the first color light. For example, in some embodiments, the first filter CF1 may be a red filter, the second filter CF2 may be a green filter, and the third filter CF3 may be a blue filter. The filters CF1, CF2, and CF3 each may include a polymeric photosensitive resin and a pigment and/or dye. The first filter CF1 may include a red pigment and/or dye, the second filter CF2 may include a green pigment and/or dye, and the third filter CF3 may include a blue pigment and/or dye. However, embodiments of the present disclosure are not limited thereto, for example, in some embodiments, the third filter CF3 may not include (e.g., may exclude) a pigment or dye. The third filter CF3 may include a polymeric photosensitive resin and may not include (e.g., may exclude) a pigment or dye. The third filter CF3 may be transparent. In some embodiments, the third filter CF3 may be formed of a transparent photosensitive resin.

In one or more embodiments, the first filter CF1 and the second filter CF2 may be a yellow filter. The first filter CF1 and the second filter CF2 may not be separated but be provided as one filter.

The light shielding part BM may be a black matrix. The light shielding part BM may include an organic light shielding material and/or an inorganic light shielding material containing a black pigment or dye. The light shielding part BM may prevent or reduce light leakage, and may separate boundaries between the adjacent filters CF1, CF2, and CF3. In some embodiments, the light shielding part BM may be formed of a blue filter.

The first to third filters CF1, CF2, and CF3 may be disposed corresponding to the red light emitting region PXA-R, the green light emitting region PXA-G, and the blue light emitting region PXA-B, respectively.

A base substrate BL may be disposed on the color filter layer CFL. The base substrate BL may be a member which provides a base surface on which the color filter layer CFL, the light control layer CCL, and/or the like are disposed. The base substrate BL may be a glass substrate, a metal substrate, a plastic substrate, etc. However, embodiments of the present disclosure are not limited thereto, and the base substrate BL may be an inorganic layer, an organic layer, or a composite material layer. In some embodiments, the base substrate BL may not be provided.

FIG. 8 is a cross-sectional view illustrating a portion of a display apparatus according to one or more embodiments of the present disclosure. In a display apparatus DD-TD, a light emitting device ED-BT may include a plurality of light emitting structures OL-B1, OL-B2, and OL-B3. The light emitting device ED-BT may include a first electrode EL1 and a second electrode EL2 which face each other, and the plurality of light emitting structures OL-B1, OL-B2, and OL-B3 sequentially stacked in a thickness direction between the first electrode EL1 and the second electrode EL2. The light emitting structures OL-B1, OL-B2, and OL-B3 each may include an emission layer EML (FIG. 7) and a hole transport region HTR and an electron transport region ETR disposed with the emission layer EML (FIG. 7) located therebetween.

For example, in some embodiments, the light emitting device ED-BT included in the display apparatus DD-TD may be a light emitting device having a tandem structure and including a plurality of emission layers.

In one or more embodiments illustrated in FIG. 8, all light beams respectively emitted from the light emitting structures OL-B1, OL-B2, and OL-B3 may be blue light. However, embodiments of the present disclosure are not limited thereto, and the light beams respectively emitted from the light emitting structures OL-B1, OL-B2, and OL-B3 may have wavelength ranges different from each other. For example, in some embodiments, the light emitting device ED-BT including the plurality of light emitting structures OL-B1, OL-B2, and OL-B3 which emit light beams having wavelength ranges different from each other may be to emit white light (e.g., combined white light).

Charge generation layers CGL1 and CGL2 may be respectively disposed between two of the neighboring light emitting structures OL-B1, OL-B2, and OL-B3. The charge generation layers CGL1 and CGL2 may include a p-type or kind charge (e.g., P-charge) generation layer and/or an n-type or kind charge (e.g., N-charge) generation layer.

In one or more embodiments, at least one selected from among the light emitting structures OL-B1, OL-B2, and OL-B3 included in the display apparatus DD-TD may contain the above-described fused polycyclic compound of one or more embodiments. For example, at least one selected from among the plurality of emission layers included in the light emitting device ED-BT may include the fused polycyclic compound of one or more embodiments of the present disclosure.

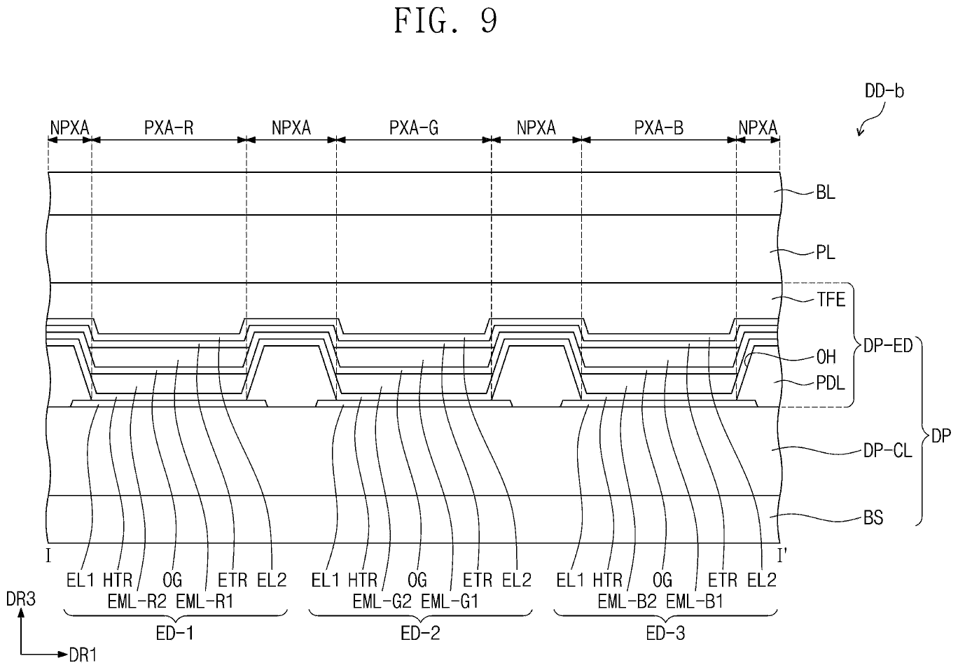

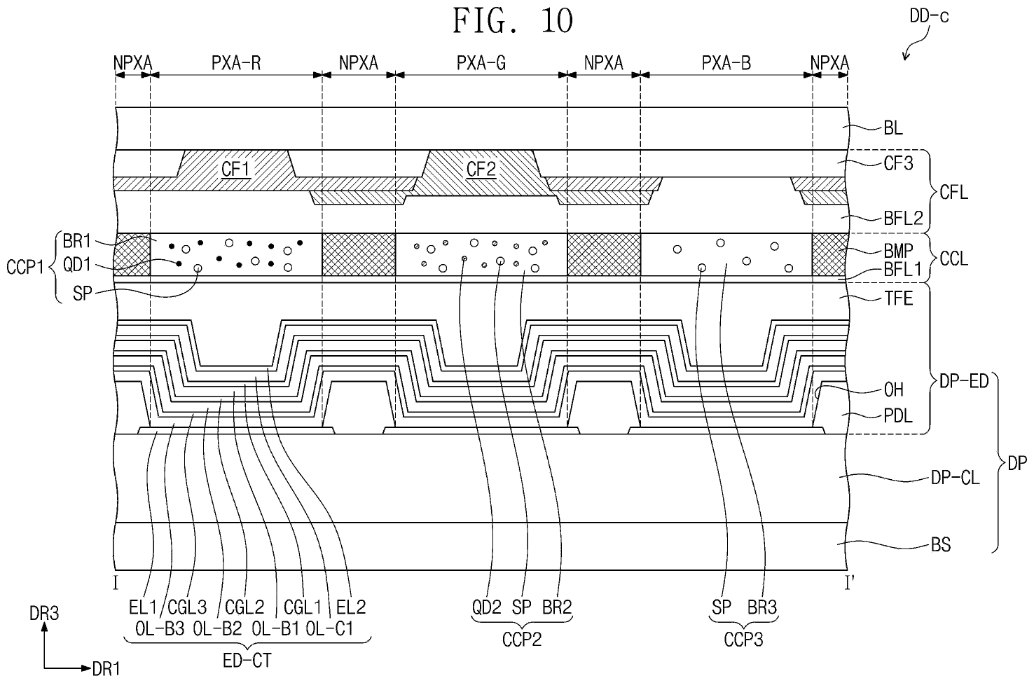

FIG. 9 is a cross-sectional view illustrating a display apparatus according to an embodiment of the present disclosure; and FIG. 10 is a cross-sectional view illustrating a display apparatus according to an embodiment of the present disclosure.

Referring to FIG. 9, the display apparatus DD-b according to one or more embodiments may include light emitting devices ED-1, ED-2, and ED-3 in which two emission layers are stacked. Compared with the display apparatus DD illustrated in FIG. 2, the display apparatus illustrated in FIG. 9 has a difference in that the first to third light emitting devices ED-1, ED-2, and ED-3 each include two emission layers stacked in a thickness direction. In each of the first to third light emitting devices ED-1, ED-2, and ED-3, the two emission layers may be to emit light in substantially the same wavelength region.

In one or more embodiments, the first light emitting device ED-1 may include a first red emission layer EML-R1 and a second red emission layer EML-R2. The second light emitting device ED-2 may include a first green emission layer EML-G1 and a second green emission layer EML-G2. In addition, the third light emitting device ED-3 may include a first blue emission layer EML-B1 and a second blue emission layer EML-B2. An emission auxiliary part OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may include a single layer or a multilayer. The emission auxiliary part OG may include a charge generation layer. In one or more embodiments, the emission auxiliary part OG may include an electron transport region, a charge generation layer, and a hole transport region that are sequentially stacked. The emission auxiliary part OG may be provided as a common layer in the whole of the first to third light emitting devices ED-1, ED-2, and ED-3. However, embodiments of the present disclosure are not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may be disposed between the electron transport region ETR and the emission auxiliary part OG. The second red emission layer EML-R2, the second green emission layer EML-G2, and the second blue emission layer EML-B2 may be disposed between the emission auxiliary part OG and the hole transport region HTR.

For example, in some embodiments, the first light emitting device ED-1 may include the first electrode EL1, the hole transport region HTR, the second red emission layer EML-R2, the emission auxiliary part OG, the first red emission layer EML-R1, the electron transport region ETR, and the second electrode EL2 that are sequentially stacked. The second light emitting device ED-2 may include the first electrode EL1, the hole transport region HTR, the second green emission layer EML-G2, the emission auxiliary part OG, the first green emission layer EML-G1, the electron transport region ETR, and the second electrode EL2 that are sequentially stacked. The third light emitting device ED-3 may include the first electrode EL1, the hole transport region HTR, the second blue emission layer EML-B2, the emission auxiliary part OG, the first blue emission layer EML-B1, the electron transport region ETR, and the second electrode EL2 that are sequentially stacked.

In some embodiments, an optical auxiliary layer PL may be disposed on the display device layer DP-ED. The optical auxiliary layer PL may include a polarizing layer. The optical auxiliary layer PL may be disposed on the display panel DP and control reflected light in the display panel DP due to external light. In some embodiments, the optical auxiliary layer PL in the display apparatus may not be provided.

In one or more embodiments, at least one emission layer included in the display apparatus DD-b illustrated in FIG. 9 may include the above-described fused polycyclic compound of one or more embodiments. For example, in one or more embodiments, at least one of the first blue emission layer EML-B1 or the second blue emission layer may include the fused polycyclic compound of one or more embodiments of the present disclosure.

Unlike FIGS. 8 and 9, FIG. 10 illustrates that a display apparatus DD-c may include four light emitting structures OL-B1, OL-B2, OL-B3, and OL-C1. A light emitting device ED-CT may include a first electrode EL1 and a second electrode EL2 which face each other, and first to fourth light emitting structures OL-B1, OL-B2, OL-B3, and OL-C1 that are stacked in a thickness direction between the first electrode EL1 and the second electrode EL2. Charge generation layers CGL1, CGL2, and CGL3 may be disposed between the first to fourth light emitting structures OL-B1, OL-B2, OL-B3, and OL-C1. In some embodiments, among the four light emitting structures, the first to third light emitting structures OL-B1, OL-B2, and OL-B3 may be to emit blue light, and the fourth light emitting structure OL-C1 may be to emit green light. However, embodiments of the present disclosure are not limited thereto, and the first to fourth light emitting structures OL-B1, OL-B2, OL-B3, and OL-C1 may be to emit light beams in different wavelength regions.

The charge generation layers CGL1, CGL2, and CGL3 disposed between adjacent light emitting structures OL-B1, OL-B2, OL-B3, and OL-C1 may include a p-type or kind charge (e.g., P-charge) generation layer and/or an n-type or kind charge (e.g., N-charge) generation layer.

In one or more embodiments, at least one selected from among the light emitting structures OL-B1, OL-B2, OL-B3, and OL-C1 included in the display apparatus DD-c may contain the above-described fused polycyclic compound of one or more embodiments. For example, in one or more embodiments, at least one selected from among the first to third light emitting structures OL-B1, OL-B2, and OL-B3 may include the fused polycyclic compound of one or more embodiments described-above.

Hereinafter, with reference to Examples and Comparative Examples, a fused polycyclic compound according to one or more embodiments of the present disclosure and a luminescence device (e.g., a light-emitting device) of one or more embodiments of the present disclosure will be described in more detail. In addition, examples described are only illustrations to assist the understanding of the present disclosure, and the scope of the present disclosure is not limited thereto.

### EXAMPLES

### 1. Synthesis of Fused Polycyclic Compound

First, a synthetic method of the fused polycyclic compound according to one or more embodiments of the present disclosure will be explained in more detail by illustrating the synthetic methods of Compounds 3, 28, 99, 133, 147, and 170. In addition, the synthetic methods of the fused polycyclic compounds as described are only examples, and the synthetic method of the fused polycyclic compound according to one or more embodiments of the present disclosure is not limited to the following examples.

### (1) Synthesis of Compound 3

Fused polycyclic compound 3 according to one or more embodiments may be synthesized by, for example, the following reaction.

### Synthesis of Intermediate 3-1

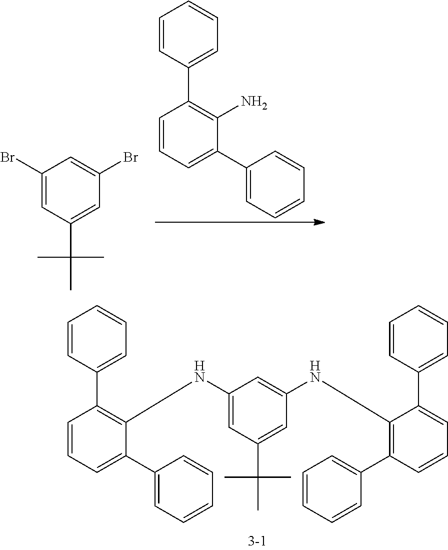

1,3-dibromo-5-(tert-butyl)benzene (1 eq), [1,1′:3′,1″-terphenyl]-2′-amine (2 eq), tris(dibenzylideneacetone)dipalladium(0) (0.05 eq), tri-tert-butylphosphine (0.1 eq), and sodium tert-butoxide (3 eq) were dissolved in toluene, and then the resultant mixture was stirred at about 110° C. for about 12 hours. After cooled, the mixture was washed three times with ethyl acetate and water, and then separated to obtain an organic layer. The obtained organic layer was dried over MgSO₄, and then dried under reduced pressure. The resulting product was purified by column chromatography utilizing methylene chloride and n-hexane as an eluent to obtain Intermediate 3-1. (yield: 81%)

### Synthesis of Intermediate 3-2

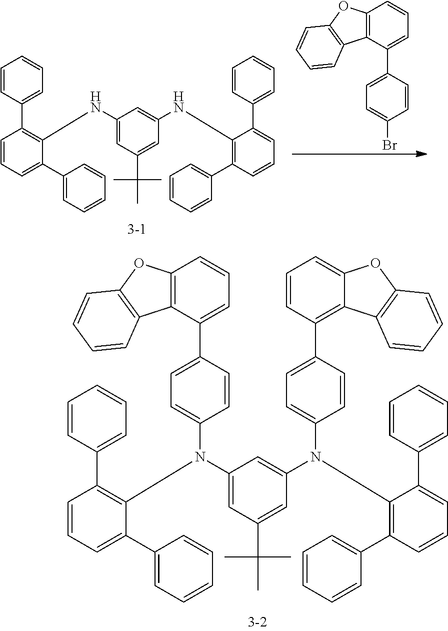

Intermediate 3-1 (1 eq), 1-(4-bromophenyl)dibenzo[b,d]furan (3 eq), tris(dibenzylideneacetone)dipalladium(0) (0.15 eq), tri-tert-butylphosphine (0.3 eq), and sodium tert-butoxide (3 eq) were dissolved in o-xylene, and then the resultant mixture was stirred at about 150° C. for about 60 hours. After cooled, the mixture was washed three times with ethyl acetate and water, and then separated to obtain an organic layer. The obtained organic layer was dried over MgSO₄, and then dried under reduced pressure. The resulting product was purified by column chromatography utilizing methylene chloride and n-hexane as an eluent to obtain Intermediate 3-2. (yield: 31%)

### Synthesis of Compound 3

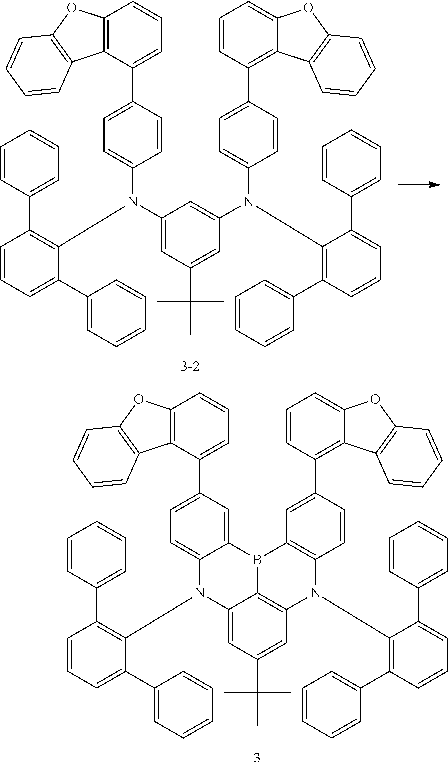 [SMILES: CC(C)(C)c1cc(N(c2ccc(-c3cccc4oc5ccccc5c34)cc2)c2c(-c3ccccc3)cccc2-c2ccccc2)cc(N(c2ccc(-c3cccc4oc5ccccc5c34)cc2)c2c(-c3ccccc3)cccc2-c2ccccc2)c1 ; CC(C)(C)c1cc2c3c(c1)N(c1c(-c4ccccc4)cccc1-c1ccccc1)c1ccc(-c4cccc5oc6ccccc6c45)cc1B3c1cc(-c3cccc4oc5ccccc5c34)ccc1N2c1c(-c2ccccc2)cccc1-c1ccccc1]

Intermediate 3-2 (1 eq) was dissolved in ortho dichlorobenezene, the mixture was then cooled to about 0° C., and then BBr₃ (3 eq) was slowly injected thereto in a nitrogen atmosphere. After dropping was completed, the temperature was elevated to about 180° C., and the mixture was stirred for about 24 hours. After cooled, the reaction was terminated by dropping triethylamine slowly in the flask containing the reactant, and then ethyl alcohol was added to the reactant and extracted and filtered to obtain solids. The obtained solids were purified by column chromatography utilizing methylene chloride and n-hexane as an eluent, and were then subjected to recrystallization utilizing toluene and acetone to obtain Compound 3. (yield: 4%)

### (2) Synthesis of Compound 28

Fused Polycyclic Compound 28 according to an example may be synthesized, for example, by the reaction:

### Synthesis of Intermediate 28-1

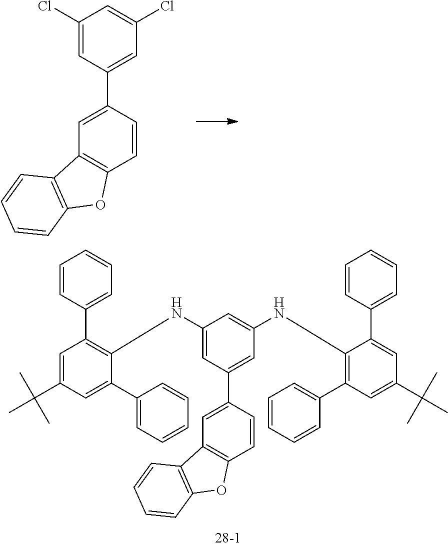

2-(3,5-dichlorophenyl)dibenzo[b,d]furan (1 eq), 5′-(tert-butyl)-[1,1′:3′,1″-terphenyl]-2′-amine (2 eq), tris(dibenzylideneacetone)dipalladium(0) (0.05 eq), tri-tert-butylphosphine (0.1 eq), and sodium tert-butoxide (3 eq) were dissolved in toluene, and then the resultant mixture was stirred at about 110° C. for about 12 hours. After cooled, the mixture was washed three times with ethyl acetate and water, and then separated to obtain an organic layer. The obtained organic layer was dried over MgSO₄, and then dried under reduced pressure. The resulting product was purified by column chromatography utilizing methylene chloride and n-hexane as an eluent to obtain Intermediate 28-1. (yield: 77%)

### Synthesis of Intermediate 28-2

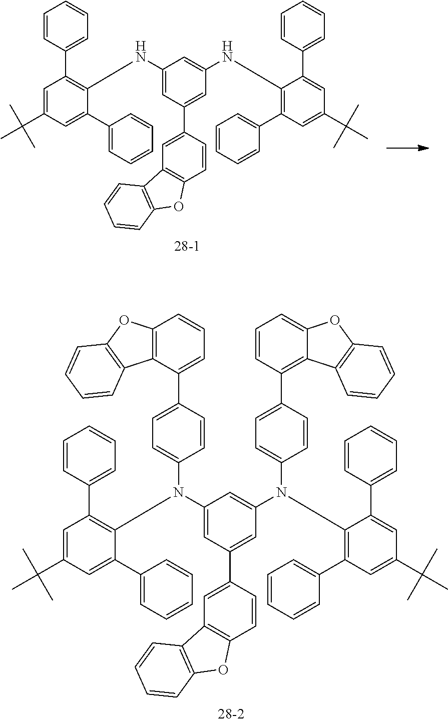

Intermediate 28-1 (1 eq), 1-(4-bromophenyl)dibenzo[b,d]furan (3 eq), tris(dibenzylideneacetone)dipalladium(0) (0.15 eq), tri-tert-butylphosphine (0.3 eq), and sodium tert-butoxide (3 eq) were dissolved in o-xylene, and then the resultant mixture was stirred at about 150° C. for about 60 hours. After cooled, the mixture was washed three times with ethyl acetate and water, and then separated to obtain an organic layer. The obtained organic layer was dried over MgSO₄, and then dried under reduced pressure. The resulting product was purified by column chromatography utilizing methylene chloride and n-hexane as an eluent to obtain Intermediate 28-2. (yield: 36%)

### Synthesis of Compound 28

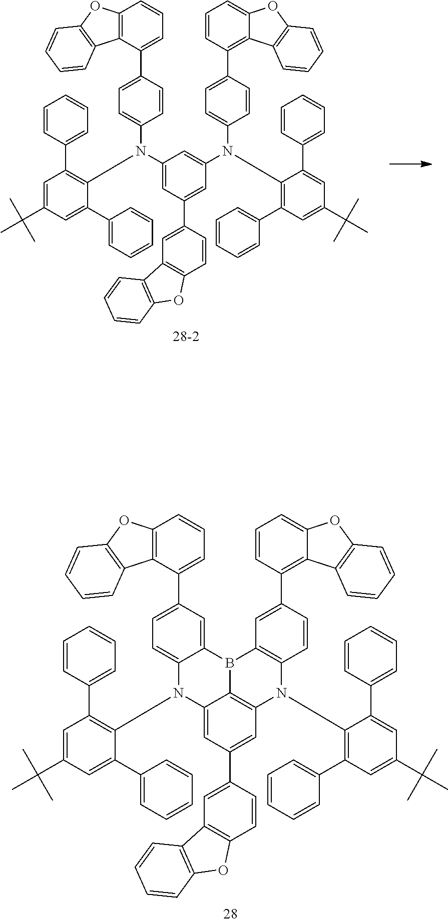

Intermediate 28-2 (1 eq) was dissolved in ortho dichlorobenezene, the mixture was then cooled to about 0° C., and then BBr₃ (3 eq) was slowly injected thereto in a nitrogen atmosphere. After dropping was completed, the temperature was elevated to about 180° C., and the mixture was stirred for about 24 hours. After cooled, the reaction was terminated by dropping triethylamine slowly in the flask containing the reactant, and then ethyl alcohol was added to the reactant and extracted and filtered to obtain solids. The obtained solids were purified by column chromatography utilizing methylene chloride and n-hexane as an eluent, and were then subjected to recrystallization utilizing toluene and acetone to obtain Compound 28. (yield: 5%)

### (3) Synthesis of Compound 99

Fused Polycyclic Compound 99 according to an example may be synthesized by, for example, the reaction:

### Synthesis of Intermediate 99-1

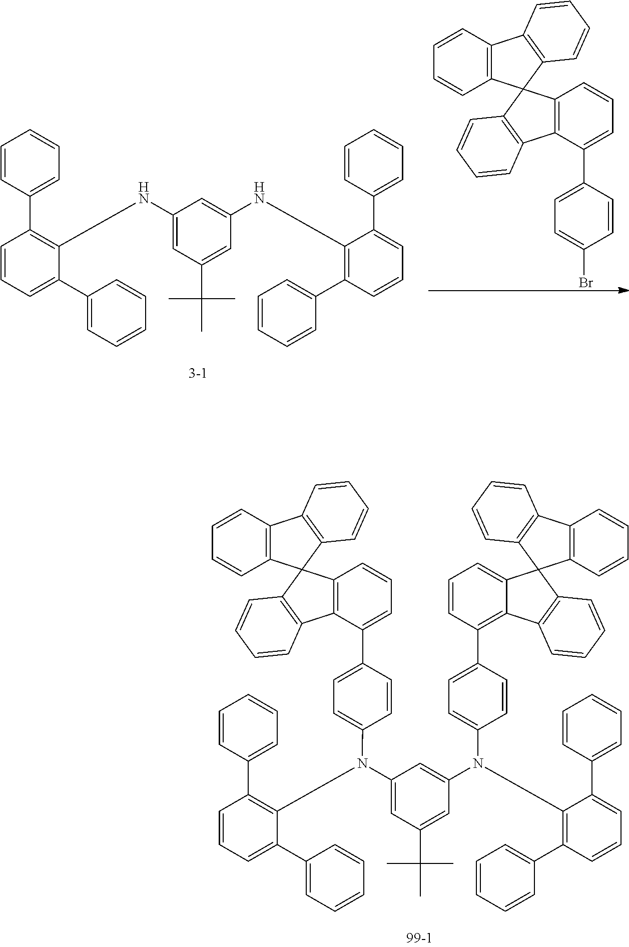

Intermediate 3-1 (1 eq), 4-(4-bromophenyl)-9,9′-spirobi[fluorene] (3 eq), Tris(dibenzylideneacetone)dipalladium(0) (0.15 eq), tri-tert-butylphosphine (0.3 eq), and sodium tert-butoxide (3 eq) were dissolved in o-xylene, and then the resultant mixture was stirred at about 150° C. for about 60 hours. After cooled, the mixture was washed three times with ethyl acetate and water, and then separated to obtain an organic layer. The obtained organic layer was dried over MgSO₄, and then dried under reduced pressure. The resulting product was purified by column chromatography utilizing methylene chloride and n-hexane as an eluent to obtain Intermediate 99-1. (yield: 28%)

### Synthesis of Compound 99

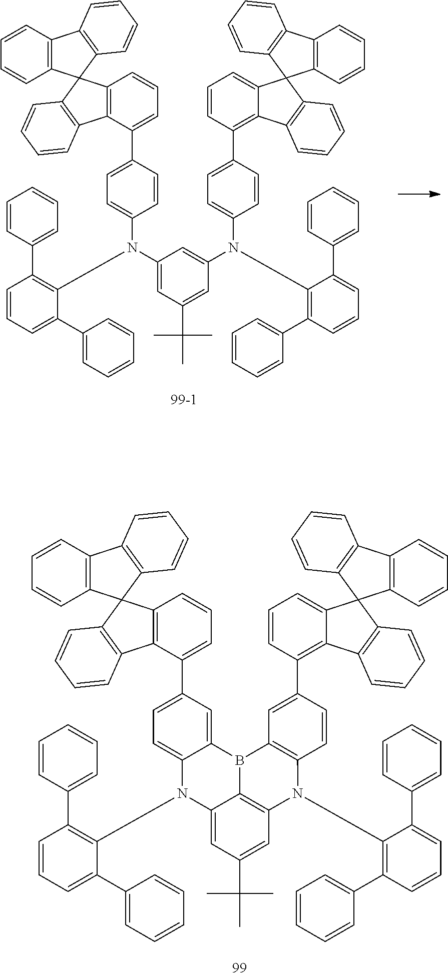

Intermediate 99-1 (1 eq) was dissolved in ortho dichlorobenezene, the mixture was then cooled to about 0° C., and then BBr₃ (3 eq) was slowly injected thereto in a nitrogen atmosphere. After dropping was completed, the temperature was elevated to about 180° C., and the mixture was stirred for about 24 hours. After cooled, the reaction was terminated by slowly dropping triethylamine in the flask containing the reactant, and then ethyl alcohol was added to the reactant, followed by extraction and filtration to obtain solids. The obtained solids were purified by column chromatography utilizing methylene chloride and n-hexane as an eluent, and were then subjected to recrystallization utilizing toluene and acetone to obtain Compound 99. (yield: 3%)

### (4) Synthesis of Compound 133

Fused Polycyclic Compound 133 according to an example may be synthesized, for example, by the reaction:

### Synthesis of Intermediate 133-1

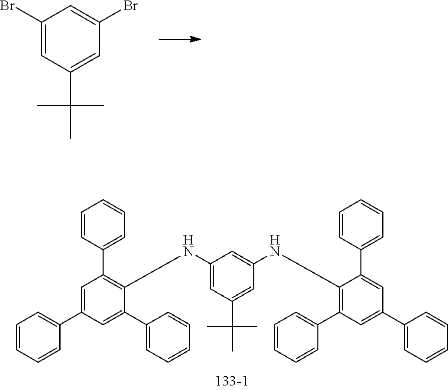

1,3-dibromo-5-(tert-butyl)benzene (1 eq), 5′-phenyl-[1,1′:3′,1″-terphenyl]-2′-amine (2 eq), tris(dibenzylideneacetone)dipalladium(0) (0.05 eq), tri-tert-butylphosphine (0.1 eq), and sodium tert-butoxide (3 eq) were dissolved in toluene, and then the resultant mixture was stirred at about 110° C. for about 12 hours. After cooled, the mixture was washed three times with ethyl acetate and water, and then separated to obtain an organic layer. The obtained organic layer was dried over MgSO₄, and then dried under reduced pressure. The resulting product was purified by column chromatography utilizing methylene chloride and n-hexane as an eluent to obtain Intermediate 133-1. (yield: 72%)

### Synthesis of Intermediate 133-2

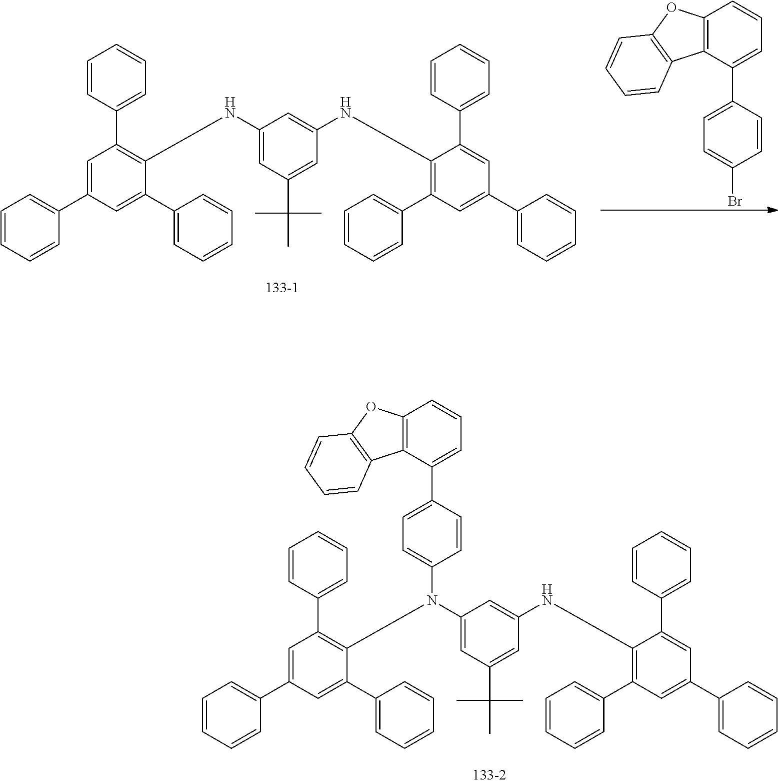

Intermediate 133-1 (1 eq), 1-(4-bromophenyl)dibenzo[b,d]furan (1.2 eq), tris(dibenzylideneacetone)dipalladium(0) (0.1 eq), tri-tert-butylphosphine (0.2 eq), and sodium tert-butoxide (3 eq) were dissolved in o-xylene, and then the resultant mixture was stirred at about 140° C. for about 24 hours. After cooled, the mixture was washed three times with ethyl acetate and water, and then separated to obtain an organic layer. The obtained organic layer was dried over MgSO₄, and then dried under reduced pressure. The resulting product was purified by column chromatography utilizing methylene chloride and n-hexane as an eluent to obtain Intermediate 133-2. (yield: 21%)

### Synthesis of Intermediate 133-3

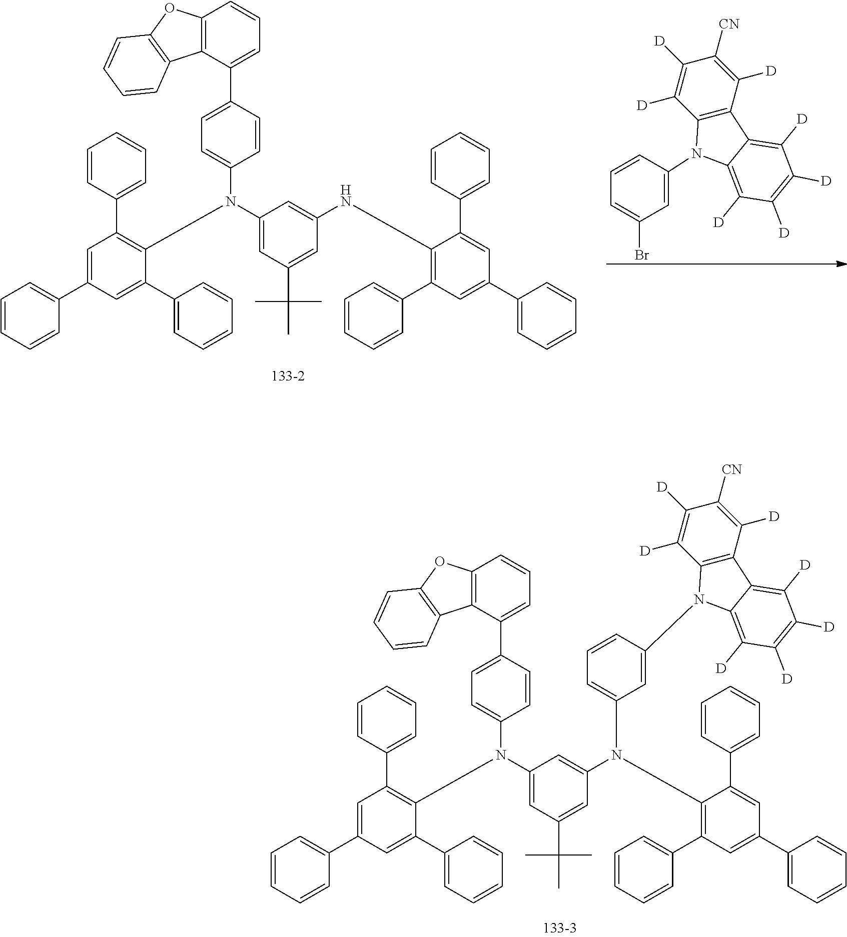

Intermediate 133-2 (1 eq), 9-(3-bromophenyl)-9H-carbazole(D7)-3-carbonitrile (2 eq), tris(dibenzylideneacetone)dipalladium(0) (0.15 eq), tri-tert-butylphosphine (0.3 eq), and sodium tert-butoxide (3 eq) were dissolved in o-xylene, and then the resultant mixture was stirred at about 150° C. for about 60 hours. After cooled, the mixture was washed three times with ethyl acetate and water, and then separated to obtain an organic layer. The obtained organic layer was dried over MgSO₄, and then dried under reduced pressure. The resulting product was purified by column chromatography utilizing methylene chloride and n-hexane as an eluent to obtain Intermediate 133-3. (yield: 25%)

### Synthesis of Compound 133

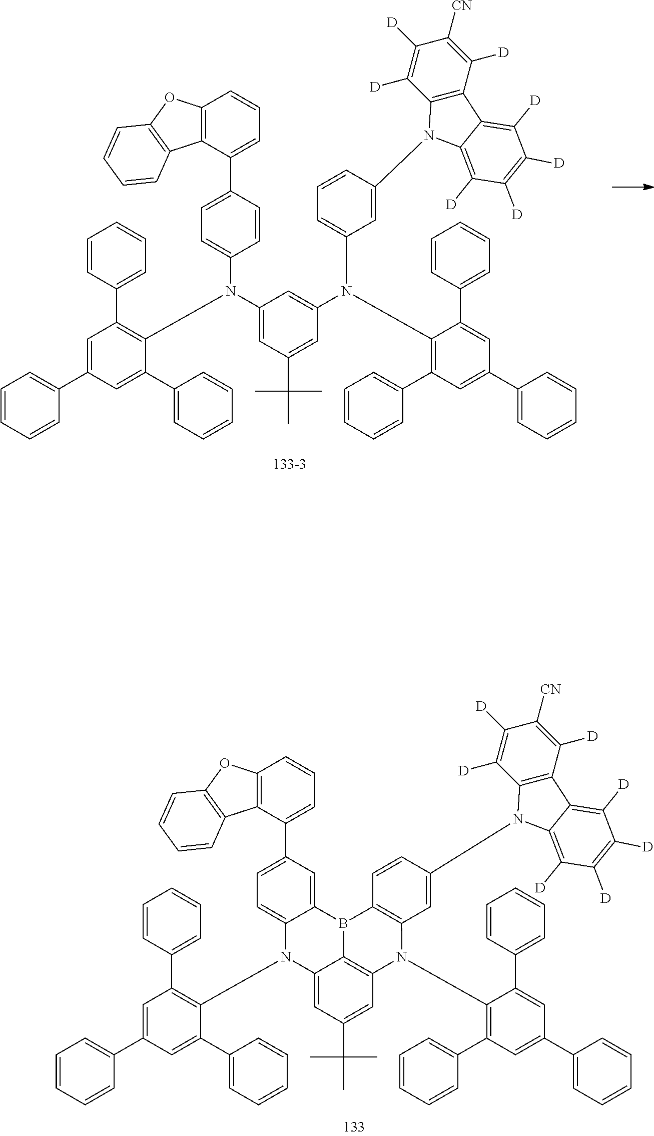

Intermediate 133-3 (1 eq) was dissolved in ortho dichlorobenezene, the mixture was then cooled to about 0° C., and then BBr₃ (3 eq) was slowly injected thereto in a nitrogen atmosphere. After dropping was completed, the temperature was elevated to about 180° C., and the mixture was stirred for about 24 hours. After cooled, the reaction was terminated by dropping triethylamine slowly in the flask containing the reactant, and then ethyl alcohol was added to the reactant and extracted and filtered to obtain solids. The obtained solids were purified by column chromatography utilizing methylene chloride and n-hexane as an eluent, and were then subjected to recrystallization utilizing toluene and acetone to obtain Compound 133. (yield: 2%)

### (5) Synthesis of Compound 147

Fused Polycyclic Compound 147 according to an example may be synthesized, for example, by the reaction:

### Synthesis of Intermediate 147-1

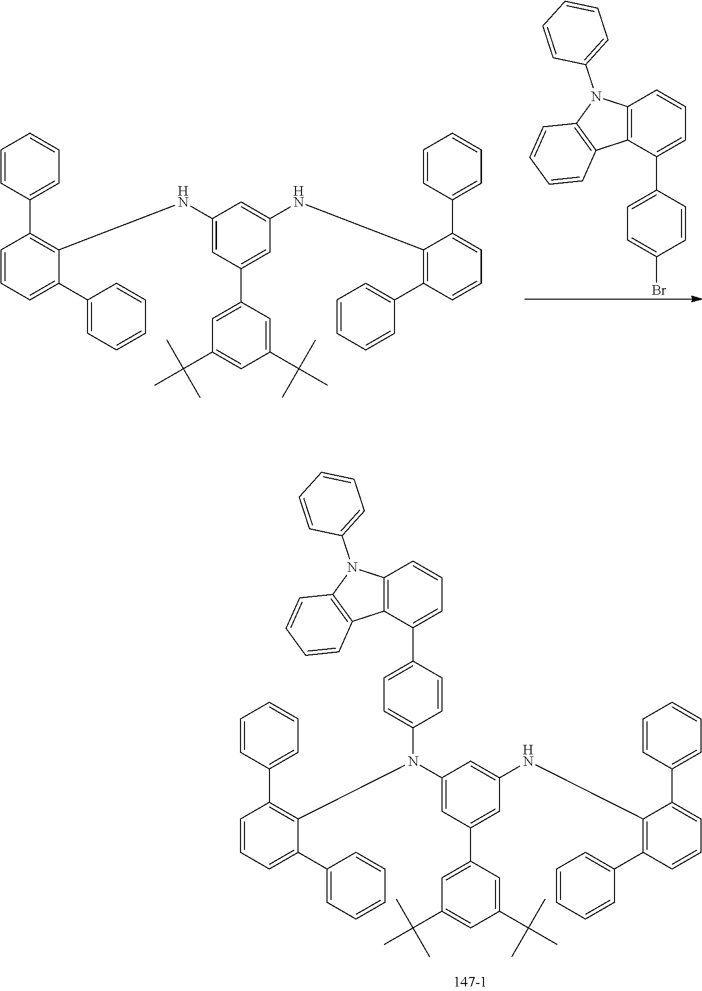

N3,N5-di([1,1′:3′,1″-terphenyl]-2′-yl)-3′,5′-di-tert-butyl-[1,1′-biphenyl]-3,5-diamine (1 eq), 4-(4-bromophenyl)-9-phenyl-9H-carbazole (1.2 eq), tris(dibenzylideneacetone)dipalladium(0) (0.1 eq), tri-tert-butylphosphine (0.2 eq), and sodium tert-butoxide (3 eq) were dissolved in o-xylene, and then the resultant mixture was stirred at about 140° C. for about 24 hours. After cooled, the mixture was washed three times with ethyl acetate and water, and then separated to obtain an organic layer. The obtained organic layer was dried over MgSO₄, and then dried under reduced pressure. The resulting product was purified by column chromatography utilizing methylene chloride and n-hexane as an eluent to obtain Intermediate 147-1. (yield: 18%)

### Synthesis of Intermediate 147-2

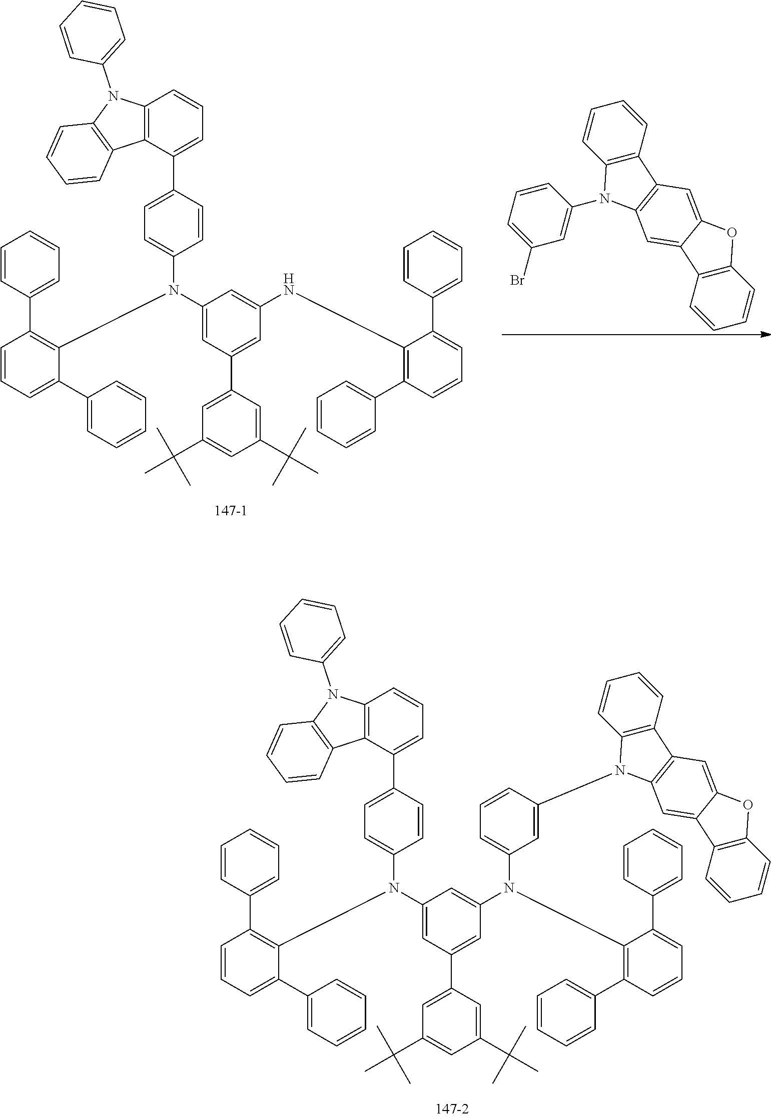

Intermediate 147-1 (1 eq), 11-(3-bromophenyl)-11H-benzofuro[3,2-b]carbazole (2 eq), tris(dibenzylideneacetone)dipalladium(0) (0.15 eq), tri-tert-butylphosphine (0.3 eq), and sodium tert-butoxide (3 eq) were dissolved in o-xylene, and then the resultant mixture was stirred at about 150° C. for about 60 hours. After cooled, the mixture was washed three times with ethyl acetate and water, and then separated to obtain an organic layer. The obtained organic layer was dried over MgSO₄, and then dried under reduced pressure. The resulting product was purified by column chromatography utilizing methylene chloride and n-hexane as an eluent to obtain Intermediate 147-2. (yield: 34%)

### Synthesis of Compound 147

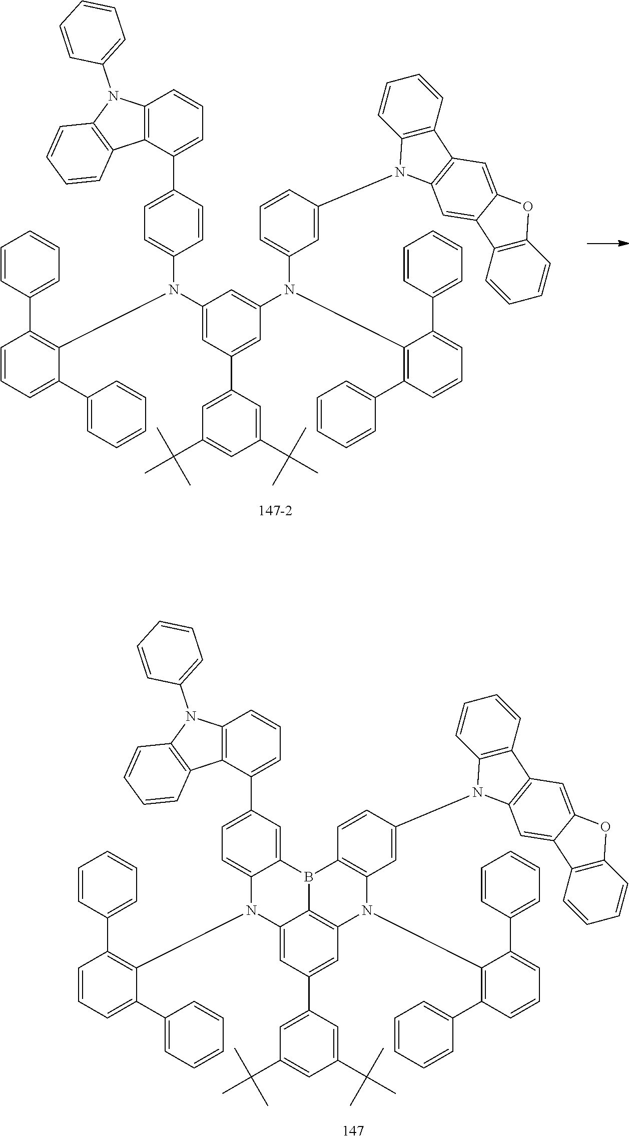 [SMILES: CC(C)(C)c1cc(-c2cc(N(c3ccc(-c4cccc5c4c4ccccc4n5-c4ccccc4)cc3)c3c(-c4ccccc4)cccc3-c3ccccc3)cc(N(c3cccc(-n4c5ccccc5c5cc6oc7ccccc7c6cc54)c3)c3c(-c4ccccc4)cccc3-c3ccccc3)c2)cc(C(C)(C)C)c1 ; CC(C)(C)c1cc(-c2cc3c4c(c2)N(c2c(-c5ccccc5)cccc2-c2ccccc2)c2cc(-n5c6ccccc6c6cc7oc8ccccc8c7cc65)ccc2B4c2cc(-c4cccc5c4c4ccccc4n5-c4ccccc4)ccc2N3c2c(-c3ccccc3)cccc2-c2ccccc2)cc(C(C)(C)C)c1]

Intermediate 147-2 (1 eq) was dissolved in ortho dichlorobenezene, the mixture was then cooled to about 0° C., and then BBr₃ (3 eq) was slowly injected thereto in a nitrogen atmosphere. After dropping was completed, the temperature was elevated to about 180° C., and the mixture was stirred for about 24 hours. After cooled, the reaction was terminated by dropping triethylamine slowly in the flask containing the reactant, and then ethyl alcohol was added to the reactant and extracted and filtered to obtain solids. The obtained solids were purified by column chromatography utilizing methylene chloride and n-hexane as an eluent, and were then subjected to recrystallization utilizing toluene and acetone to obtain Compound 147. (yield: 4%)

### (6) Synthesis of Compound 170

Fused Polycyclic Compound 170 according to an example may be synthesized, for example, by the reaction:

### Synthesis of Intermediate 170-1

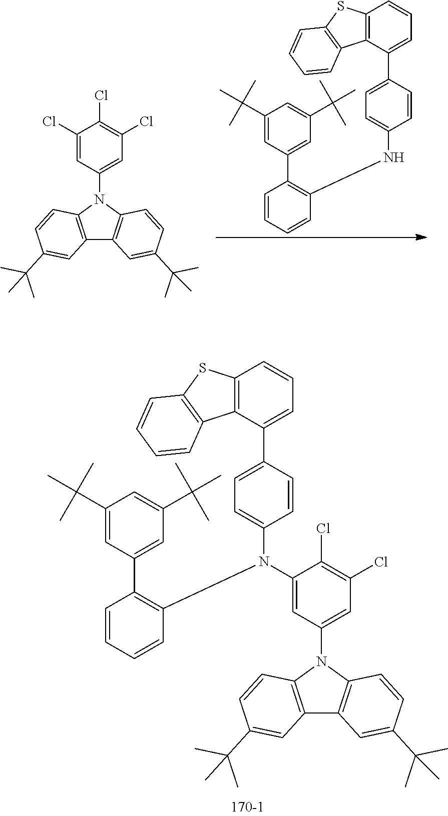 [SMILES: CC(C)(C)c1ccc2c(c1)c1cc(C(C)(C)C)ccc1n2-c1cc(Cl)c(Cl)c(Cl)c1 ; CC(C)(C)c1cc(-c2ccccc2Nc2ccc(-c3cccc4sc5ccccc5c34)cc2)cc(C(C)(C)C)c1 ; CC(C)(C)c1cc(-c2ccccc2N(c2ccc(-c3cccc4sc5ccccc5c34)cc2)c2cc(-n3c4ccc(C(C)(C)C)cc4c4cc(C(C)(C)C)ccc43)cc(Cl)c2Cl)cc(C(C)(C)C)c1]

3,6-di-tert-butyl-9-(3,4,5-trichlorophenyl)-9H-carbazole (1 eq), 3′,5′-di-tert-butyl-N-(4-(dibenzo[b,d]thiophen-1-yl)phenyl)-[1,1′-biphenyl]-2-amine (1 eq), tris(dibenzylideneacetone)dipalladium(0) (0.05 eq), tri-tert-butylphosphine (0.1 eq), and sodium tert-butoxide (3 eq) were dissolved in toluene, and then the resultant mixture was stirred at about 90° C. for about 6 hours. After cooled, the mixture was washed three times with ethyl acetate and water, and then separated to obtain an organic layer. The obtained organic layer was dried over MgSO₄, and then dried under reduced pressure. The resulting product was purified by column chromatography utilizing methylene chloride and n-hexane as an eluent to obtain Intermediate 170-1. (yield: 47%)

### Synthesis of Intermediate 170-2

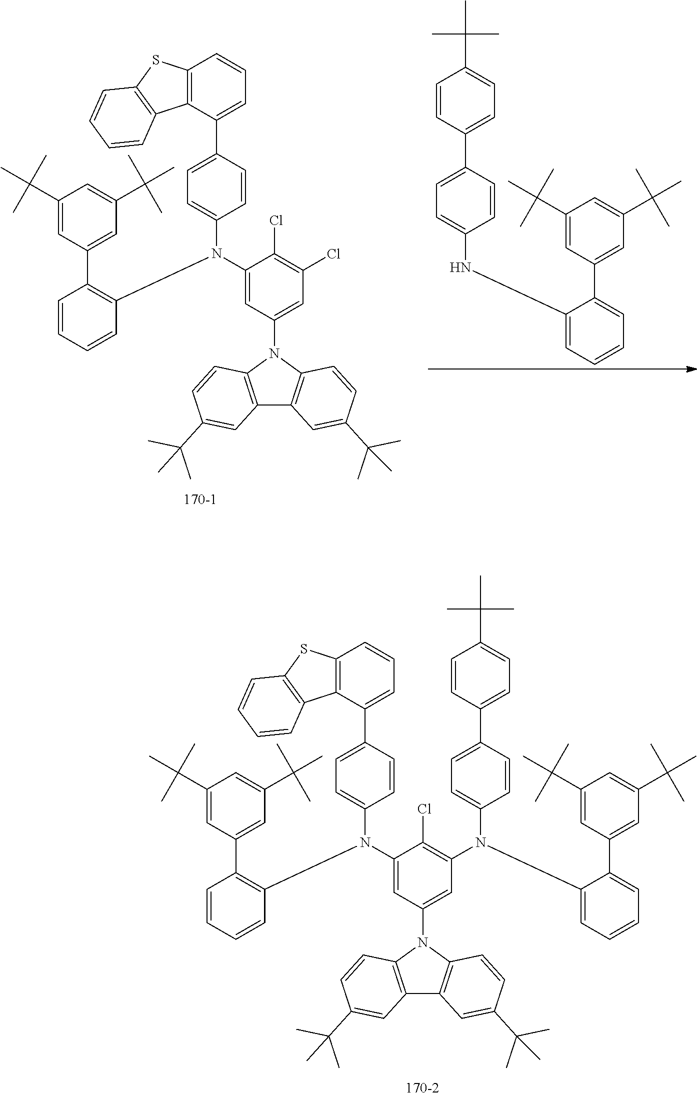 [SMILES: CC(C)(C)c1cc(-c2ccccc2N(c2ccc(-c3cccc4sc5ccccc5c34)cc2)c2cc(-n3c4ccc(C(C)(C)C)cc4c4cc(C(C)(C)C)ccc43)cc(Cl)c2Cl)cc(C(C)(C)C)c1 ; CC(C)(C)c1ccc(-c2ccc(Nc3ccccc3-c3cc(C(C)(C)C)cc(C(C)(C)C)c3)cc2)cc1 ; CC(C)(C)c1ccc(-c2ccc(N(c3ccccc3-c3cc(C(C)(C)C)cc(C(C)(C)C)c3)c3cc(-n4c5ccc(C(C)(C)C)cc5c5cc(C(C)(C)C)ccc54)cc(N(c4ccc(-c5cccc6sc7ccccc7c56)cc4)c4ccccc4-c4cc(C(C)(C)C)cc(C(C)(C)C)c4)c3Cl)cc2)cc1]

Intermediate 170-1 (1 eq), 3′,5′-di-tert-butyl-N-(4′-(tert-butyl)-[1,1′-biphenyl]-4-yl)-[1,1′-biphenyl]-2-amine (1 eq), tris(dibenzylideneacetone)dipalladium(0) (0.05 eq), tri-tert-butylphosphine (0.1 eq), and sodium tert-butoxide (3 eq) were dissolved in toluene, and then the resultant mixture was stirred at about 90° C. for about 6 hours. After cooled, the mixture was washed three times with ethyl acetate and water, and then separated to obtain an organic layer. The obtained organic layer was dried over MgSO₄, and then dried under reduced pressure. The resulting product was purified by column chromatography utilizing methylene chloride and n-hexane as an eluent to obtain Intermediate 170-2. (yield: 45%)

### Synthesis of Compound 170

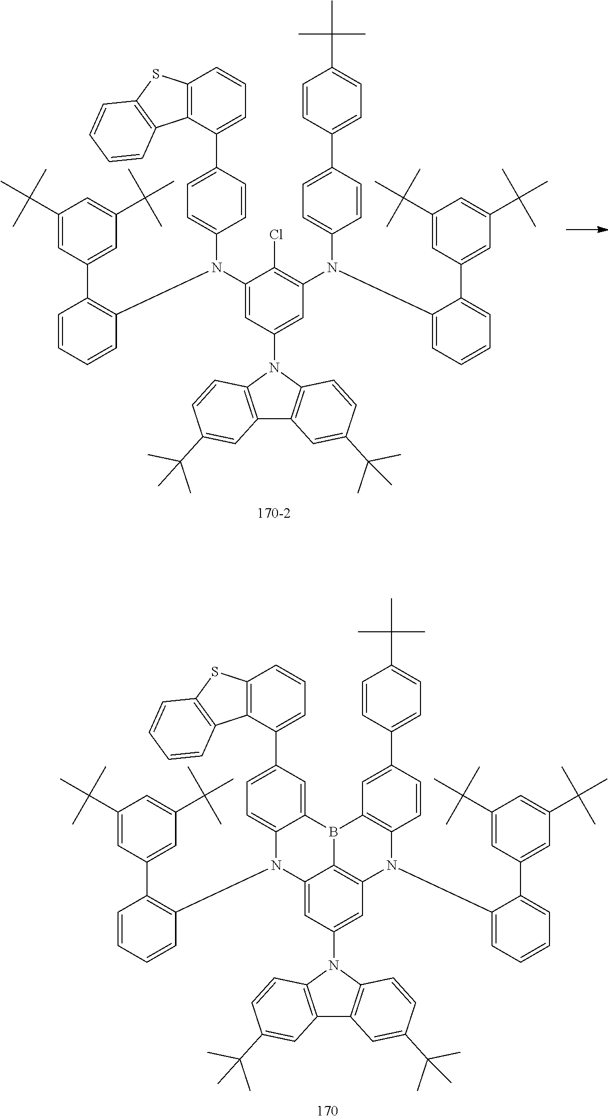

Intermediate 170-2 (1 eq) was dissolved in o-xylene, and then cooled to about 0° C. in a nitrogen atmosphere. n-BuLi (2 eq) was slowly injected thereto, the temperature was then elevated to about 70° C., the resultant mixture was stirred for about 2 hours, and then heated to about 120° C. and stirred for about 2 hours. The temperature of the reactor was cooled to about 0° C., and then BBr₃ (2 eq) was slowly injected thereto. After dropping was completed, the mixture was stirred for about 1 hour. After the mixture was cooled to about 0° C., triethylamine (3 eq) was injected thereto, and then the mixture was heated to about 140° C. and stirred for about 24 hours. After cooled, the reaction was terminated by slowly dropping triethylamine in the flask containing the reactant, and then ethyl alcohol was added to the reactant, followed by extraction and filtration to obtain solids. The obtained solids were purified by column chromatography to obtain Compound 170. (yield: 6%)

¹H NMR and MS/FAB in synthesized compounds of Synthetic Examples (1) to (6) above are shown in Table 1. The synthetic methods of other compounds may be easily recognized by those skilled in the art with reference to the above synthetic path and raw materials.

TABLE 1

| | ¹H NMR chemical shift | MS-Cal | MS-Meas. |
|---|---|---|---|
| 3 | 9.22-9.18 (2H, s), 7.95-7.95 (2H, d), 7.65-7.49 (16H, | 1113.180 | 1113.175 |
| | m)7.41-7.38 (2H, m), 7.32-7.26 (2H, m), 7.18 (2H, d), | | |
| | 7.09-6.96 (20H, m), 6.26 (2H, s), 1.09 (9H, s) | | |
| 28 | 9.19-9.16 (2H, s), 7.99-7.89 (4H, m), 7.65-7.51 (17H, m), | 1335.467 | 1335.462 |
| | 7.41-7.38 (3H, m), 7.32-7.26 (3H, m), 7.18 (2H, d), | | |
| | 7.05-6.91 (20H, m), 6.33 (2H, s), 1.39 (18H, s) | | |
| 99 | 9.20-9.17 (2H, s), 7.93-7.90 (6H, d), 7.63-7.53 (10H, | 1409.596 | 1409.594 |
| | m)7.48-7.36 (8H, m), 7.24-7.18 (10H, m), 7.05-6.91 | | |
| | (20H, m) | | |
| | 6.75-6.72 (6H, m), 6.23 (2H, s), 1.09 (9H, s) | | |
| 133 | 9.19-9.15 (1H, s), 8.93-8.89 (1H, d), 7.95-7.88 (2H, d) | 1296.445 | 1296.438 |
| | 7.63-7.49 (6H, m), 7.41-7.38 (2H, m), 7.39-7.27 (12H, m) | | |
| | 7.18-7.13 (3H, m), 7.05-6.94 (20H, m), 6.25 (2H, s) | | |
| | 1.07(9H, s) | | |
| 147 | 9.21-9.17 (1H, s), 8.93-8.89 (1H, d), 8.25-8.22 (2H, d) | 1409.597 | 1409.594 |
| | 7.97-7.94(1H, s), 7.87-7.78(5H, m), 7.75-7.71(1H, s) | | |
| | 7.65-7.49 (12H, m), 7.46-7.37 (9H, m), 7.25-7.21 (4H, m) | | |
| | 7.18 (2H, d), 7.11-6.95 (20H, m), 6.33 (2H, s) | | |
| | 1.44-1.40 (18H, s) | | |
| 170 | 9.24-9.20 (1H, s), 9.15-9.12 (1H, s), 8.28-8.22 (2H, | 1388.807 | 1388.806 |
| | m)8.16-8.13 (1H, d), 7.85-7.82 (2H, d), 7.71-7.78 (6H, d) | | |
| | 7.65-7.55 (6H, m), 7.51-7.41 (8H, m), 7.43-7.41 (6H, m) | | |
| | 7.36-7.33 (2H, m), 7.18 (2H, d), 6.22 (2H, s), | | |
| | 1.53 (18H, s), 1.37 (9H, s), 1.32 (36H, s) | | |

### 2. Manufacture and Evaluation of Light Emitting Device Including Fused Polycyclic Compound

The light emitting device of an example including the fused polycyclic compound of an example in an emission layer was manufactured as follows. Fused polycyclic compounds of Compounds 3, 28, 99, 133, 147, and 170, which are Example Compounds as described above, were utilized as dopant materials for the emission layers to manufacture the light emitting devices of Examples 1 to 16. Comparative Examples 1 to 14 correspond to the light emitting devices manufactured by utilizing Comparative Example Compounds C1 to C7 as dopant materials for the emission layers.

### EXAMPLE COMPOUNDS

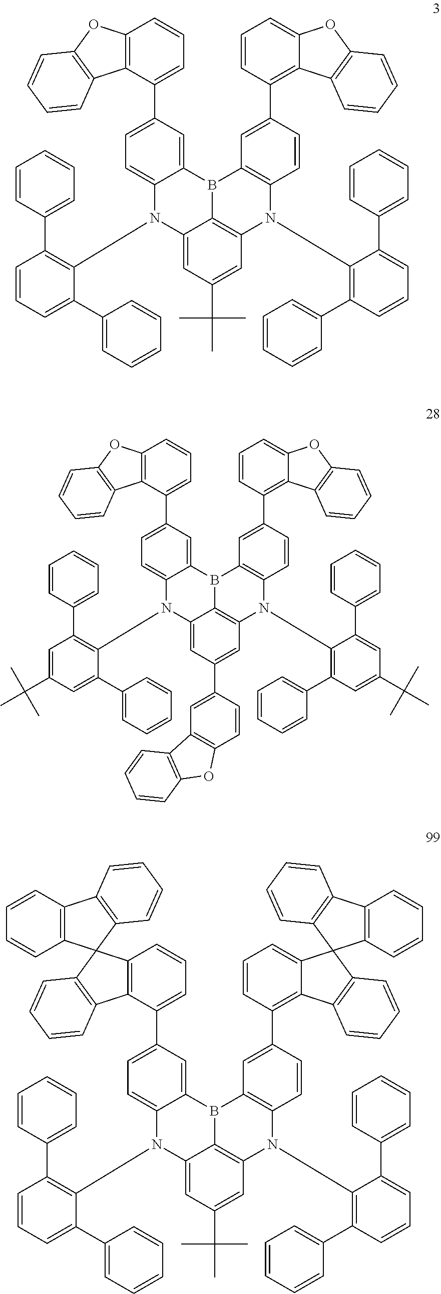

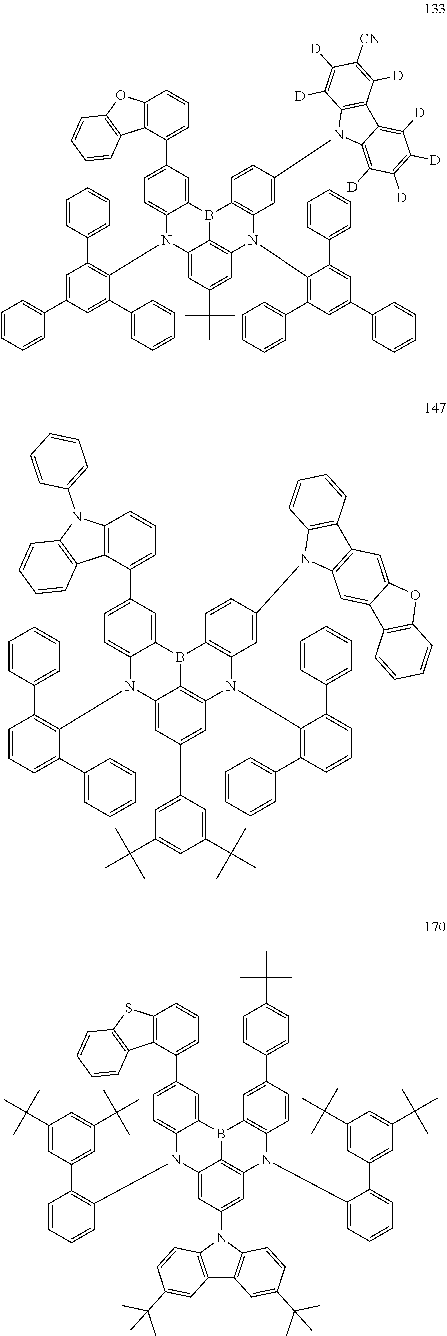

### Comparative Example Compounds

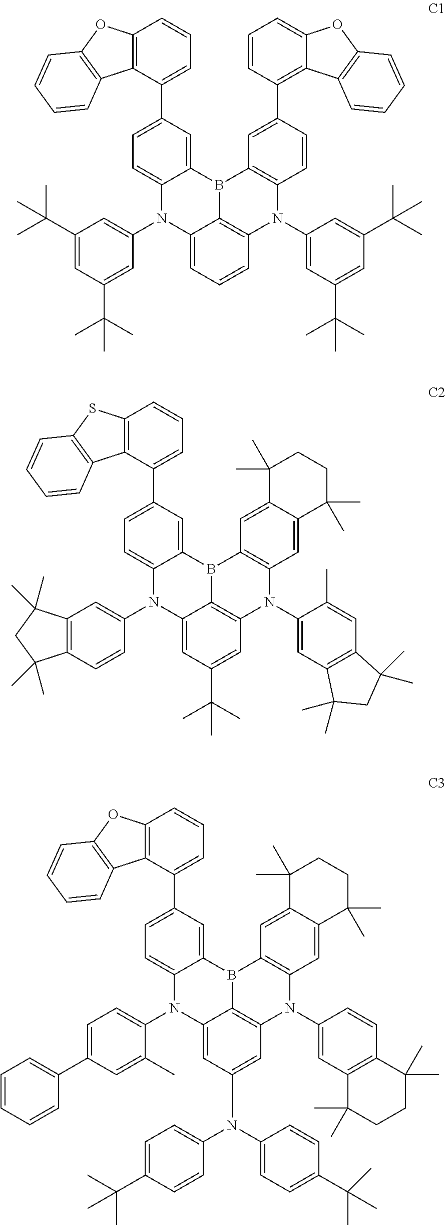

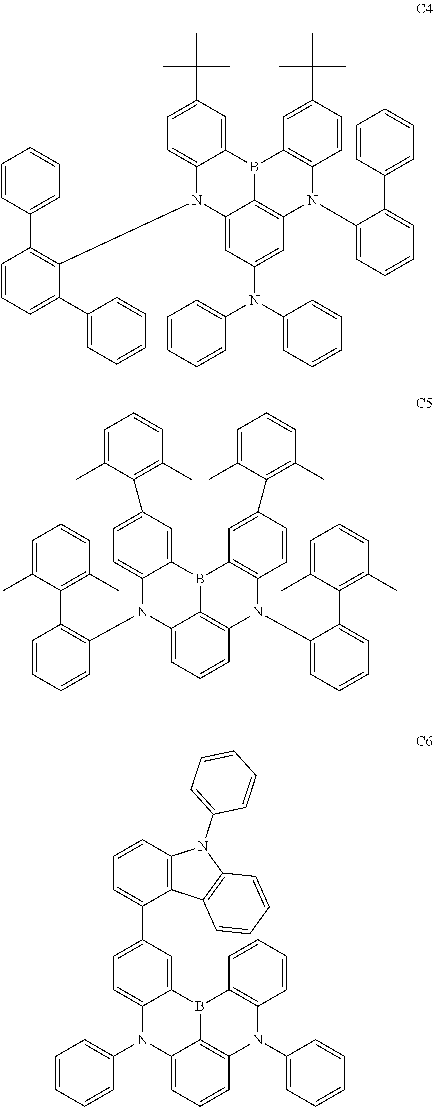

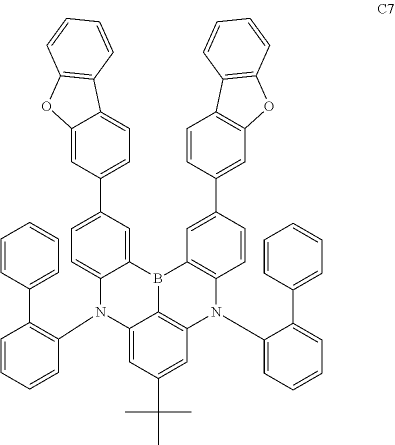 [SMILES: CC(C)(C)c1cc2c3c(c1)N(c1ccccc1-c1ccccc1)c1ccc(-c4ccc5c(c4)oc4ccccc45)cc1B3c1cc(-c3ccc4c(c3)oc3ccccc34)ccc1N2c1ccccc1-c1ccccc1]

### Manufacture of Light Emitting Device

In the light emitting devices of Examples and Comparative Examples, a glass substrate (made by Corning Co.), on which an ITO electrode of about 15 Ω/cm² (about 1200 Å) is formed as an anode, was cut to a size of about 50 mm×50 mm×0.7 mm, cleansed by ultrasonic waves in isopropyl alcohol and pure water for about five minutes each, and then irradiated with ultraviolet rays for about 30 minutes and exposed to ozone and cleansed. The ITO glass substrate was installed on a vacuum deposition apparatus.

NPD was deposited on the upper portion of the anode to form a 300 Å-thick hole injection layer, HT-1-1 was then deposited on the upper portion of the hole injection layer to form a 200 Å-thick hole transport layer, and CzSi was then deposited on the upper portion of the hole transport layer to form a 100 Å-thick emission-auxiliary layer.

Then, a host compound in which the second compound and the third compound according to one or more embodiments were mixed in an amount of about 1:1, the fourth compound, and Example Compound or Comparative Example Compound were co-deposited in a weight ratio of about 85:14:1 to form a 200 Å-thick emission layer, and on the upper portion of the emission layer, TSPO1 was deposited to form a 200 Å-thick hole blocking layer. Then, on the upper portion of the hole blocking layer, TPBI was deposited to form a 300 Å-thick electron transport layer, and then on the upper portion of the electron transport layer, LiF was deposited to form a 10 Å-thick electron injection layer. Next, on the electron injection layer, Al was deposited to form a 3,000 Å-thick cathode, thereby manufacturing a light emitting device.

Each layer was formed by a vacuum deposition method. In some embodiments, HT1, HT2, and HT3 among the compounds in Compound Group 2 as described above were utilized as the second compound, ETH85, ETH66, and EHT86 among the compounds in Compound Group 3 as described above were utilized as the third compound, and AD-37 and AD-38 among the compounds in Compound Group 4 as described above were utilized as the fourth compound.

Compounds utilized for manufacturing the light emitting devices of Examples and Comparative Examples are disclosed. The materials were utilized to manufacture the devices by subjecting commercial products to sublimation purification.

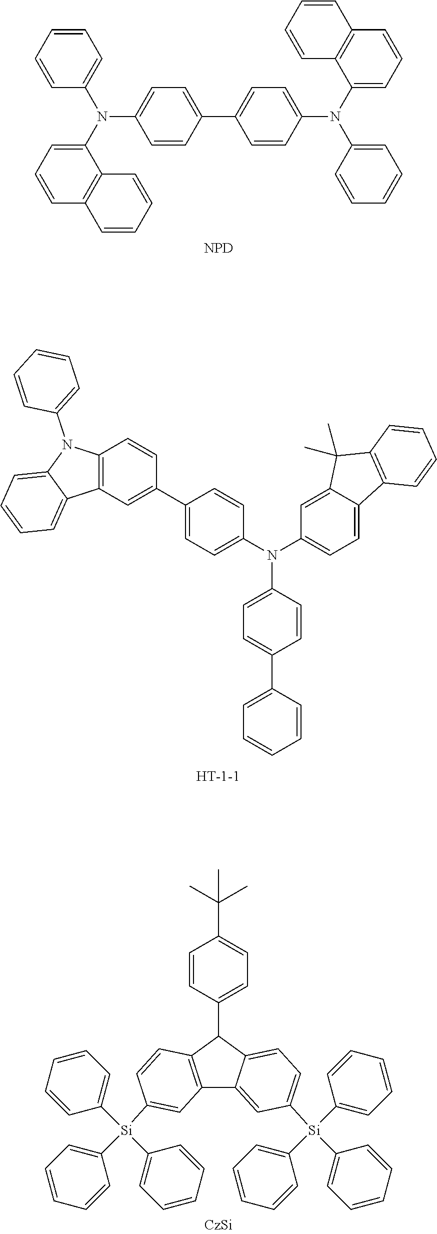

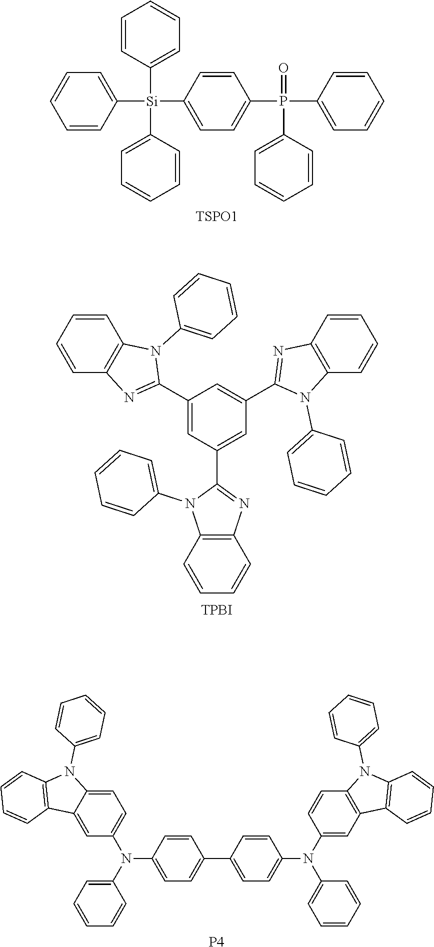

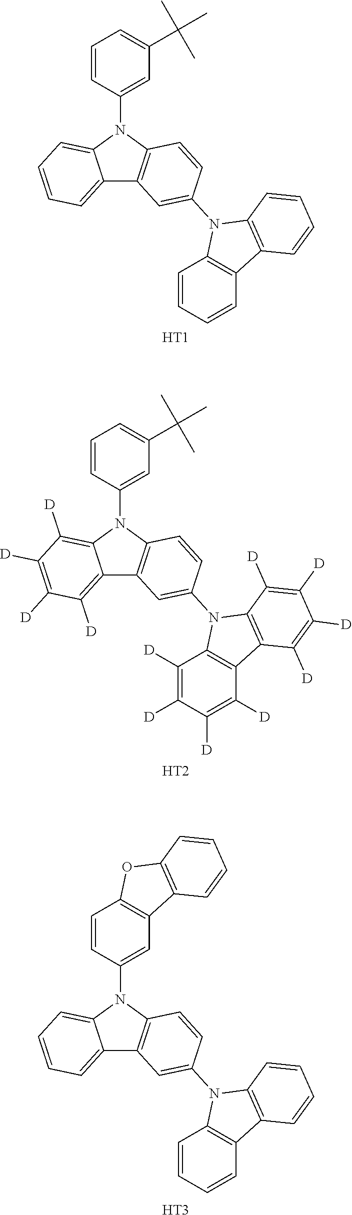

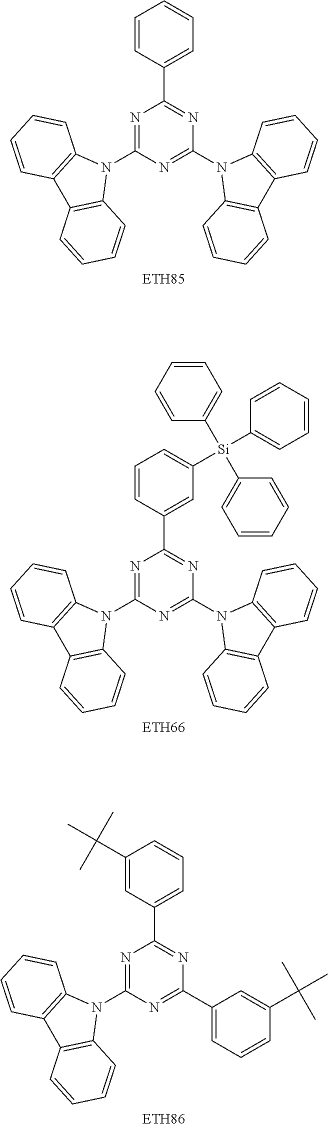 [SMILES: c1ccc(-c2nc(-n3c4ccccc4c4ccccc43)nc(-n3c4ccccc4c4ccccc43)n2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; CC(C)(C)c1cccc(-c2nc(-c3cccc(C(C)(C)C)c3)nc(-n3c4ccccc4c4ccccc43)n2)c1]

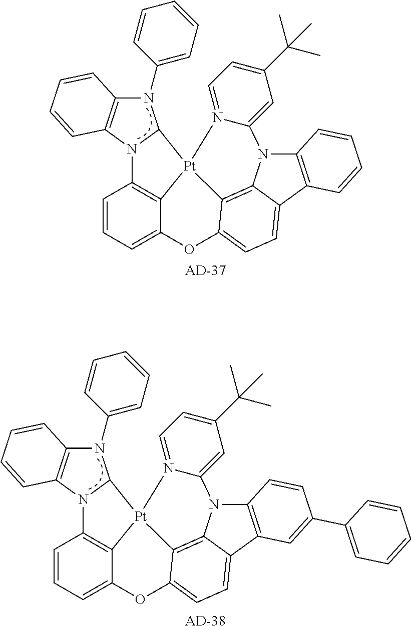

### Evaluation of Light Emitting Device Characteristics

Device efficiency and device service life of the light emitting device manufactured with Example Compounds 3, 28, 99, 133, 147, and 170, and Comparative Example Compounds C1 to C7 as described above were evaluated. Evaluation results of the light emitting devices of Examples 1 to 16 and Comparative Examples 1 to 14 are listed in Tables 2 and 3. To evaluate the characteristics of the light emitting devices manufactured in Examples 1 to 16 and Comparative Examples 1 to 14 above, each of driving voltages (V), luminous efficiencies (cd/A), and emission colors at a current density of 1,000 cd/m² was measured by utilizing Keithley SMU 236 and a luminance meter PR650, and the time taken to reach 95% brightness relative to an initial brightness was measured as a service life (T95), and a relative service life was calculated on the basis of the device of Comparative Example 1, and the results are listed in Tables 2 and 3.

TABLE 2

| | Host | | | | | Maximum | | |
|---|---|---|---|---|---|---|---|---|
| | (second | | | | | external | Service | |
| | compound:third | | | Driving | | quantum | life | |
| | compound = | Fourth | First | voltage | Efficiency | efficiency | ratio | Emission |
| | 5:5) | compound | compound | (V) | (cd/A) | (%) | (T95) | color |
| Example 1 | HT2/ETH86 | AD-37 | Example | 4.4 | 26.8 | 25.3 | 325 | Blue |
| | | | Compound | | | | | |
| | | | 3 | | | | | |
| Example 2 | HT3/ETH66 | AD-37 | Example | 4.4 | 27.3 | 25.7 | 350 | Blue |
| | | | Compound | | | | | |
| | | | 28 | | | | | |
| Example 3 | HT1/ETH85 | AD-38 | Example | 4.4 | 25.9 | 24.6 | 335 | Blue |
| | | | Compound | | | | | |
| | | | 99 | | | | | |
| Example 4 | HT2/ETH66 | AD-38 | Example | 4.3 | 27.2 | 25.6 | 375 | Blue |
| | | | Compound | | | | | |
| | | | 133 | | | | | |
| Example 5 | HT3/ETH66 | AD-37 | Example | 4.2 | 25.4 | 24.1 | 315 | Blue |
| | | | Compound | | | | | |
| | | | 147 | | | | | |
| Example 6 | HT2/ETH85 | AD-38 | Example | 4.4 | 26.6 | 25.2 | 320 | Blue |
| | | | Compound | | | | | |
| | | | 170 | | | | | |
| Example 7 | HT2/ETH66 | AD-37 | Example | 4.3 | 26.3 | 25.0 | 340 | Blue |
| | | | Compound | | | | | |
| | | | 3 | | | | | |
| Example 8 | HT2/ETH66 | AD-37 | Example | 4.4 | 26.5 | 25.4 | 342 | Blue |
| | | | Compound | | | | | |
| | | | 28 | | | | | |
| Example 9 | HT3/ETH66 | AD-38 | Example | 4.4 | 24.9 | 24.4 | 335 | Blue |
| | | | Compound | | | | | |
| | | | 99 | | | | | |
| Example 10 | HT3/ETH66 | AD-38 | Example | 4.3 | 25.8 | 24.7 | 331 | Blue |
| | | | Compound | | | | | |
| | | | 133 | | | | | |
| Comparative | HT3/ETH85 | AD-38 | Comparative | 4.8 | 21.3 | 20.5 | 100 | Blue |
| Example | | | Example | | | | | |
| 1 | | | Compound | | | | | |
| | | | C1 | | | | | |
| Comparative | HT2/ETH86 | AD-37 | Comparative | 4.8 | 20.7 | 19.6 | 155 | Blue |
| Example | | | Example | | | | | |
| 2 | | | Compound | | | | | |
| | | | C2 | | | | | |
| Comparative | HT1/ETH66 | AD-37 | Comparative | 4.9 | 21.8 | 20.2 | 120 | Blue |
| Example | | | Example | | | | | |
| 3 | | | Compound | | | | | |
| | | | C3 | | | | | |
| Comparative | HT3/ETH66 | AD-37 | Comparative | 4.9 | 21.5 | 20.3 | 105 | Blue |
| Example | | | Example | | | | | |
| 4 | | | Compound | | | | | |
| | | | C4 | | | | | |
| Comparative | HT2/ETH66 | AD-38 | Comparative | 5.2 | 20.3 | 19.7 | 140 | Blue |
| Example | | | Example | | | | | |
| 5 | | | Compound | | | | | |
| | | | C5 | | | | | |
| Comparative | HT2/ETH85 | AD-38 | Comparative | 5.3 | 18.5 | 17.6 | 75 | Blue |
| Example | | | Example | | | | | |
| 6 | | | Compound | | | | | |
| | | | C6 | | | | | |
| Comparative | HT3/ETH85 | AD-38 | Comparative | 4.9 | 21.6 | 20.6 | 164 | Blue |
| Example | | | Example | | | | | |
| 7 | | | Compound | | | | | |
| | | | C7 | | | | | |

Referring to the results of Table 2, it may be confirmed that Examples of the light emitting devices in which the fused polycyclic compounds according to examples of the present disclosure are utilized as a luminescent material exhibit lower driving voltage, and have improved luminous efficiency and service life characteristics as compared with Comparative Examples.

Example Compounds include the fused ring core in which the first to third aromatic rings are fused around the boron atom and the first and second nitrogen atoms, and the first substituent is bonded to the fused ring core at the fourth carbon position of the first substituent, and thus Example Compounds may have an increase in the multiple resonance effects and have a low ΔE_{ST} value. Accordingly, because reverse intersystem crossing (RISC) from the triplet excited state to the singlet excited state easily occurs, delayed fluorescence characteristics may be enhanced, thereby improving the luminous efficiency.

In addition, each of Example Compounds includes the second and third substituents, which are steric hindrance substituents, linked to the first and second nitrogen atoms constituting the fused ring, and thus may effectively protect the boron atom, thereby achieving high efficiency and a long service life. Example Compounds may each have an increase in the luminous efficiency and may suppress or reduce the red shift of luminescence wavelength because the intermolecular interaction may be suppressed or reduced by the introduction of the second and third substituents, thereby controlling the formation of excimer or exciplex. In addition, Example Compounds each have an increase in the distance between adjacent molecules due to the large steric hindrance structure to suppress or reduce the Dexter energy transfer, and thus may suppress or reduce the deterioration of service life due to the increase of triplet concentration. The above-described substituted position effects and steric hindrance effects work synergistically, and thus when the fused polycyclic compound of an example is introduced as a material for the emission layer of the light emitting device, high efficiency and a long service life may be achieved.

The light emitting device of an example includes the first dopant of an example as a light emitting dopant of a thermally activated delayed fluorescence (TADF) light emitting device, and thus may achieve high device efficiency in a blue wavelength region, particularly, a deep blue wavelength region.

Referring to Comparative Examples 1 to 3, it may be confirmed that Comparative Example Compounds C1 to C3 each include a planar skeleton structure having one boron atom, and two nitrogen atoms at the center thereof and include, in the planar skeleton structure, the first substituent proposed by the present disclosure, but do not include the second substituent and the third substituent proposed by the present disclosure, and thus when Comparative Example Compounds C1 to C3 are applied to the devices, the devices have higher driving voltages, and lower luminous efficiencies and device service lives than Examples. Like the fused polycyclic compound of an example of the present disclosure, the essential inclusion of the first to third substituents, which are linked to the fused ring core, may achieve high luminous efficiency and long service life in a blue light wavelength region.

Referring to Comparative Examples 4 and 5, it may be confirmed that Comparative Example Compounds C4 and C5 each include a steric hindrance substituent like Example Compounds, but luminous efficiency and device service life are deteriorated. Without being bound by any theory, it is thought that Comparative Example Compound C4 does not include a dibenzoheterole group, a carbazole group, or a fluorenyl group as a substituent linked to the fused ring skeleton, and thus has a decrease in luminous efficiency and service life characteristics as compared with Example Compounds.

Referring to Comparative Example 6, it may be confirmed that a service life ratio of Comparative Example 6 is significantly reduced as compared with Examples. Without being bound by any theory, it is thought that Comparative Example Compound C6 has a structure in which a carbazole group is linked at the fourth carbon position with the fused ring core, but does not include a steric hindrance substituent, thus the intermolecular interaction is increased, and therefore the service life characteristics are significantly deteriorated. It may be expected to have a great increase in service life when steric hindrance substituents are respectively linked to the two nitrogen atoms constituting the fused ring core in a structure in which the first substituent is bonded to the fused ring core via carbon at position 4 like the fused polycyclic compound of an example of the present disclosure.

When Example 1 and Comparative Example 7 are compared, it may be confirmed that Comparative Example 7 has a decrease in both (e.g., simultaneously) luminous efficiency and device service life as compared with Example 1. Comparative Example Compound C7 included in Comparative Example 7 includes a steric hindrance substituent and has a structure in which a dibenzofuran group is linked to the fused ring core like Compound 3 included in Example 1, but the dibenzofuran group is linked to the fused ring core at the third carbon position rather than the fourth carbon position, and thus has a decrease in both (e.g., simultaneously) luminous efficiency and device service life as compared with Example 1. Without being bound by any theory, it is thought that Comparative Example Compound C7 is different from Example Compound 3 in the substituted position of the dibenzofuran group, thus additional acceptor effects due to the dibenzofuran group are not sufficient, therefore structure stability of the polycyclic aromatic ring is reduced, and thus Comparative Example 7 has a decrease in both (e.g., simultaneously) luminous efficiency and service life as compared with Examples.

TABLE 3

| | | | | Maximum | |
|---|---|---|---|---|---|
| | Host | | | external | |
| | (second | | | quantum | |
| | compound:third | | Efficiency | efficiency | Emission |
| | compound = 5:5) | First compound | (cd/A) | (%) | color |
| Example 11 | HT2/ETH86 | Example Compound | 8.8 | 8.3 | Blue |
| | | 3 | | | |
| Example 12 | HT3/ETH66 | Example Compound | 9.0 | 8.4 | Blue |
| | | 28 | | | |
| Example 13 | HT1/ETH85 | Example Compound | 8.5 | 8.1 | Blue |
| | | 99 | | | |
| Example 14 | HT2/ETH66 | Example Compound | 8.9 | 8.4 | Blue |
| | | 133 | | | |
| Example 15 | HT3/ETH66 | Example Compound | 8.3 | 7.9 | Blue |
| | | 147 | | | |
| Example 16 | HT2/ETH85 | Example Compound | 8.7 | 8.3 | Blue |
| | | 170 | | | |
| Comparative | HT3/ETH85 | Comparative | 6.8 | 6.5 | Blue |
| Example 8 | | Example Compound | | | |
| | | C1 | | | |
| Comparative | HT2/ETH86 | Comparative | 6.6 | 6.2 | Blue |
| Example 9 | | Example Compound | | | |
| | | C2 | | | |
| Comparative | HT1/ETH66 | Comparative | 6.9 | 6.4 | Blue |
| Example 10 | | Example Compound | | | |
| | | C3 | | | |
| Comparative | HT1/ETH85 | Comparative | 8.9 | 8.7 | Blue |
| Example 11 | | Example Compound | | | |
| | | C4 | | | |
| Comparative | HT2/ETH85 | Comparative | 9.5 | 7.6 | Blue-green |
| Example 12 | | Example Compound | | | |
| | | C5 | | | |
| Comparative | HT3/ETH66 | Comparative | 9.7 | 6.9 | Blue-green |
| Example 13 | | Example Compound | | | |
| | | C6 | | | |
| Comparative | HT2/ETH85 | Comparative | 10.5 | 7.8 | Blue-green |
| Example 14 | | Example Compound | | | |
| | | C7 | | | |

Referring to the results of Table 3, it may be confirmed that Examples of the light emitting devices, in which the fused polycyclic compounds according to examples of the present disclosure are utilized as a luminescent material, have improved luminous efficiency and service life characteristics as compared with Comparative Examples. In addition, when Examples 1 to 10 in Table 2 and Examples 11 to 16 in Table 3 are compared, it may be seen that Examples 1 to 10 have improved luminous efficiency and service life characteristics as compared with Examples 11 to 16 that do not include the fourth compound of an example in the emission layer.

Therefore, the light emitting device of one or more embodiments may exhibit improved device characteristics with high efficiency and a long service life.

The fused polycyclic compound of one or more embodiments of the present disclosure may be included in the emission layer of the light emitting device to contribute to high efficiency and a long service life of the light emitting device.

In the present disclosure, singular expressions may include plural expressions unless the context clearly indicates otherwise.

Throughout the present disclosure, when a component such as a layer, a film, a region, or a plate is mentioned to be placed “on” another component, it will be understood that it may be directly on another component or that another component may be interposed therebetween. In some embodiments, “directly on” may refer to that there are no additional layers, films, regions, plates, etc., between a layer, a film, a region, a plate, etc. and the other part. For example, “directly on” may refer to two layers or two members are disposed without utilizing an additional member such as an adhesive member therebetween.

In the present disclosure, although the terms “first,” “second,” etc., may be utilized herein to describe one or more elements, components, regions, and/or layers, these elements, components, regions, and/or layers should not be limited by these terms. These terms are only utilized to distinguish one component from another component.

As utilized herein, the singular forms “a,” “an,” “one,” and “the” are intended to include the plural forms as well, unless the context clearly indicates otherwise. Further, the use of “may” when describing embodiments of the present disclosure refers to “one or more embodiments of the present disclosure”.

In the present disclosure, when particles are spherical, “diameter” indicates a particle diameter or an average particle diameter, and when the particles are non-spherical, the “diameter” indicates a major axis length or an average major axis length. The diameter (or size) of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter (or size) is referred to as D50. D50 refers to the average diameter (or size) of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The light-emitting device, the display apparatus, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure

Although the present disclosure has been described with reference to some embodiments of the present disclosure, it will be understood that the present disclosure should not be limited to these embodiments, but one or more suitable changes and modifications can be made by those skilled in the art without departing from the spirit and scope of the present disclosure.

Accordingly, the technical scope of the present disclosure is not intended to be limited to the contents set forth in the detailed description of the specification, but is intended to be defined by the appended claims and equivalent thereof.

What is claimed is:

1. A light emitting device comprising:
a first electrode;
a second electrode facing the first electrode; and
an emission layer between the first electrode and the second electrode,
wherein the emission layer comprises a first compound represented by Formula 1: 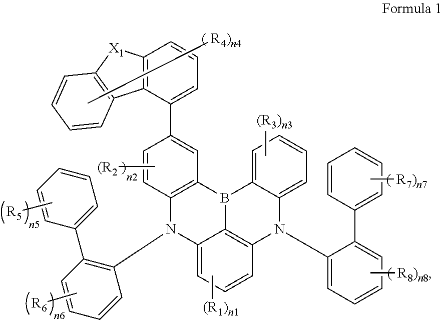
and
wherein, in Formula 1,
X₁ is NRₐ, CR_{b}R_{c}, O, or S,
R₁ to R₈ are each independently hydrogen, deuterium, a halogen, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
Rₐ to R_{c} are each independently a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring,
n1 and n2 are each independently an integer of 0 to 3,
n3, n6 and n8 are each independently an integer of 0 to 4,
n4 is an integer of 0 to 7, and
n5 and n7 are each independently an integer of 0 to 5.

2. The light emitting device of claim 1, wherein the first compound represented by Formula 1 is represented by any one selected from among Formula 2-1 to Formula 2-5: 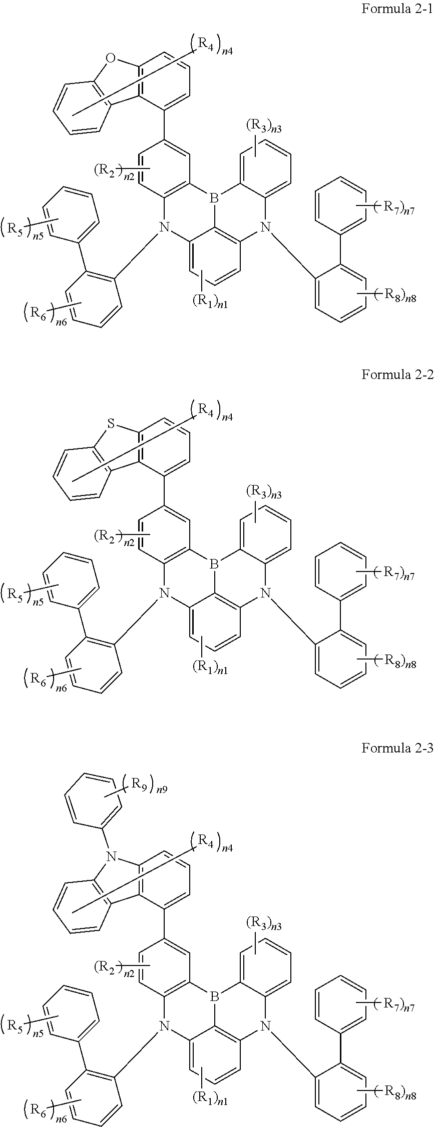 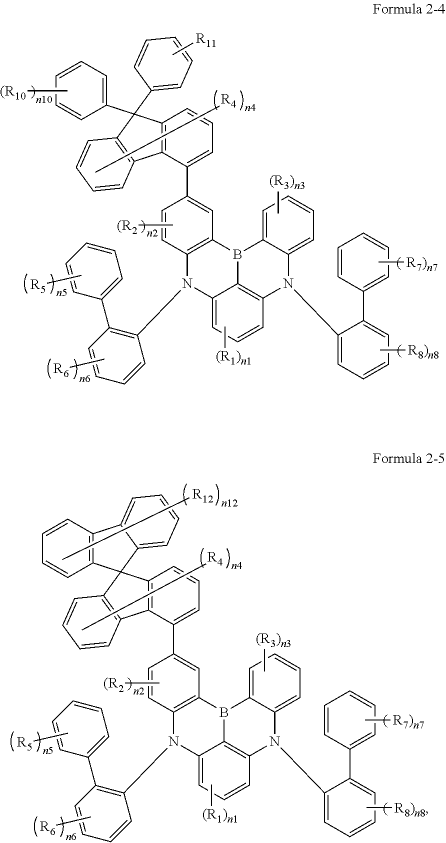
and
wherein, in Formula 2-1 to Formula 2-5,
R₉ to R₁₂ are each independently hydrogen, deuterium, a halogen, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
n9 to n11 are each independently an integer of 0 to 5,
n12 is an integer of 0 to 8, and
R₁ to R₈, and n1 to n8 are the same as defined in Formula 1.

3. The light emitting device of claim 1, wherein the first compound represented by Formula 1 is represented by Formula 3-1 or Formula 3-2: 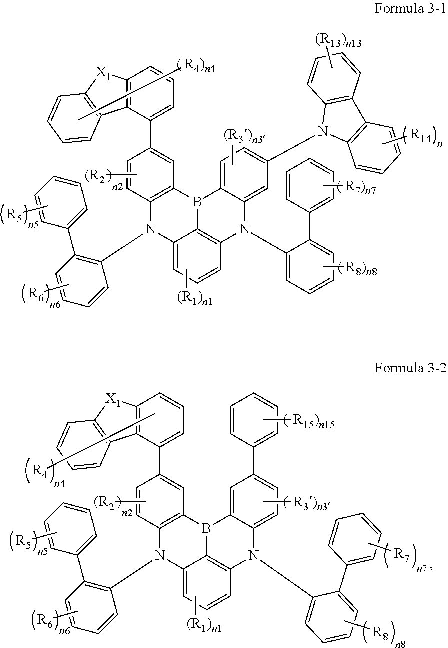
and
wherein, in Formula 3-1 and Formula 3-2,
R₃′ is hydrogen, deuterium, halogen, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
R₁₃ to R₁₅ are each independently hydrogen, deuterium, a halogen, a cyano group, a substituted or unsubstituted amine group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring,
n3′ is an integer of 0 to 3,
n13 and n14 are each independently an integer of 0 to 4,
n15 is an integer of 0 to 5, and
X₁, R₁, R₂, R₄ to R₈, n1, n2, and n4 to n8 are the same as defined in Formula 1.

4. The light emitting device of claim 1, wherein the first compound represented by Formula 1 is represented by Formula 4: 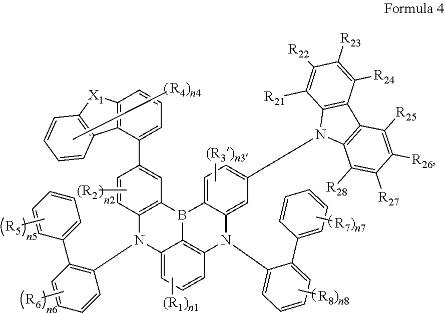
wherein, in Formula 4,
R₃′ is hydrogen, deuterium, a halogen, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
R₂₁ to R₂₈ are each independently hydrogen, deuterium, a halogen, a cyano group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring,
at least one pair selected from among adjacent pairs of R₂₁ to R₂₈ are positions at which a substituent represented by Formula 4-A is fused, and
n3′ is an integer of 0 to 3: 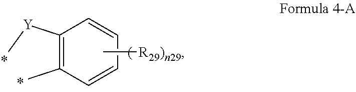
wherein, in Formula 4-A,
Y is NR₃₀, O, or S,
—* is a position which is fused to any one adjacent pair selected from among R₂₁ to R₂₈ in Formula 4,
R₂₉ and R₃₀ are each independently hydrogen, deuterium, a halogen, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
n29 is an integer of 0 to 4, and
wherein, in Formula 4,
X₁, R₁, R₂, R₄ to R₈, n1, n2, and n4 to n8 are the same as defined in Formula 1.

5. The light emitting device of claim 1, wherein the first compound represented by Formula 1 is represented by Formula 5: 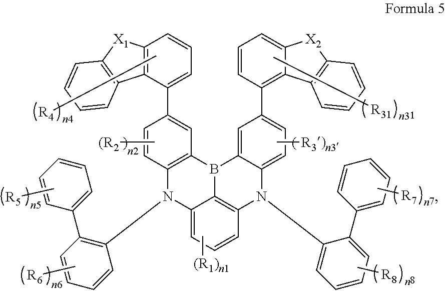
and
wherein, in Formula 5,
X₂ is NR_{d}, CRₑR_{f}, O, or S,
R₃′ and R₃₁ are each independently hydrogen, deuterium, a halogen, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
R_{d} to R_{f} are each independently a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring,
n3′ is an integer of 0 to 3,
n31 is an integer of 0 to 7, and
X₁, R₁, R₂, R₄ to R₈, n1, n2, and n4 to n8 are the same as defined in Formula 1.

6. The light emitting device of claim 5, wherein the first compound represented by Formula 5 is represented by any one selected from among Formula 6-1 to Formula 6-5: 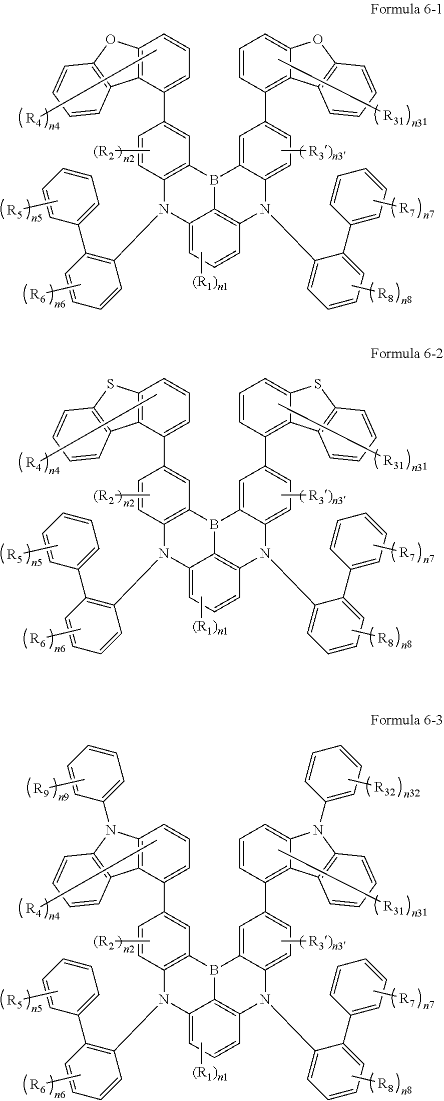 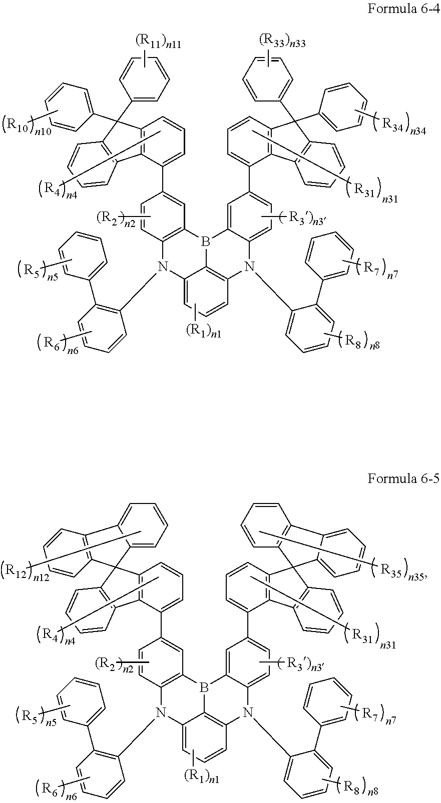
and
wherein, in Formula 6-1 to Formula 6-5,
R₉ to R₁₂ and R₃₂ to R₃₅ are each independently hydrogen, deuterium, a halogen, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
n9 to n11 and n32 to n34 are each independently an integer of 0 to 5,
n12 and n35 are each independently an integer of 0 to 8, and
R₁, R₂, R₃′, R₄ to R₈, R₃₁, n1, n2, n3′, n4 to n8, and n31 are the same as defined in Formula 1 and Formula 5.

7. The light emitting device of claim 1, wherein the first compound represented by Formula 1 is represented by Formula 7: 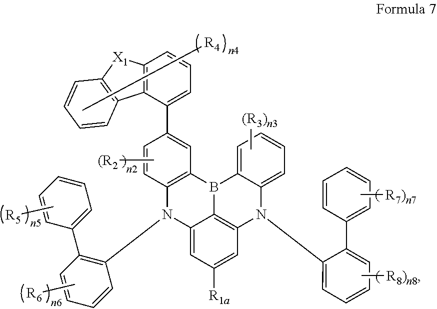
wherein, in Formula 7,
R₁ₐ is a substituted or unsubstituted alkyl group having 1 to 10 carbon atoms, or is represented by any one selected from among Formula A-1 to Formula A-3: 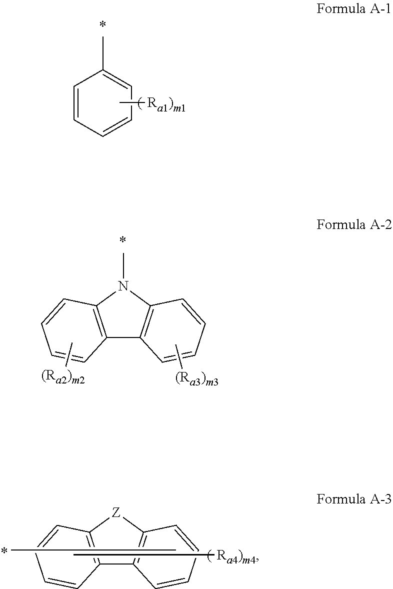
wherein, in Formula A-1 to Formula A-3,
Z is NRₐ₅, O, or S,
Rₐ₁ to Rₐ₅ are each independently hydrogen, deuterium, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
m1 is an integer of 0 to 5,
m2 and m3 are each independently an integer of 0 to 4, and
m4 is an integer of 0 to 7, and
wherein, in Formula 7,
X₁, R₂ to R₈, and n2 to n8 are the same as defined in Formula 1.

8. The light emitting device of claim 1, wherein the first compound represented by Formula 1 is represented by Formula 8-1 or Formula 8-2: 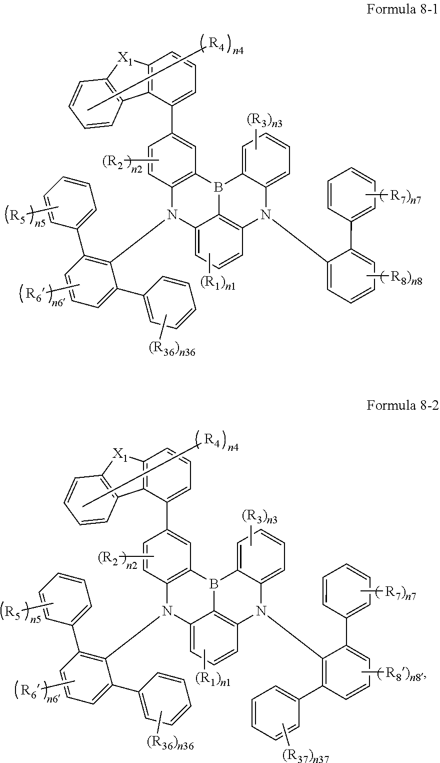
and
wherein, in Formula 8-1 and Formula 8-2,
R₆′, R₈′, R₃₆, and R₃₇ are each independently hydrogen, deuterium, a halogen, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
n6′ and n8′ are each independently an integer of 0 to 3,
n36 and n37 are each independently an integer of 0 to 5, and
X₁, R₁ to R₅, R₇, R₈, n1 to n5, n7, and n8 are the same as defined in Formula 1.

9. The light emitting device of claim 1, wherein the first compound represented by Formula 1 comprises at least one selected from among compounds in Compound Group 1:

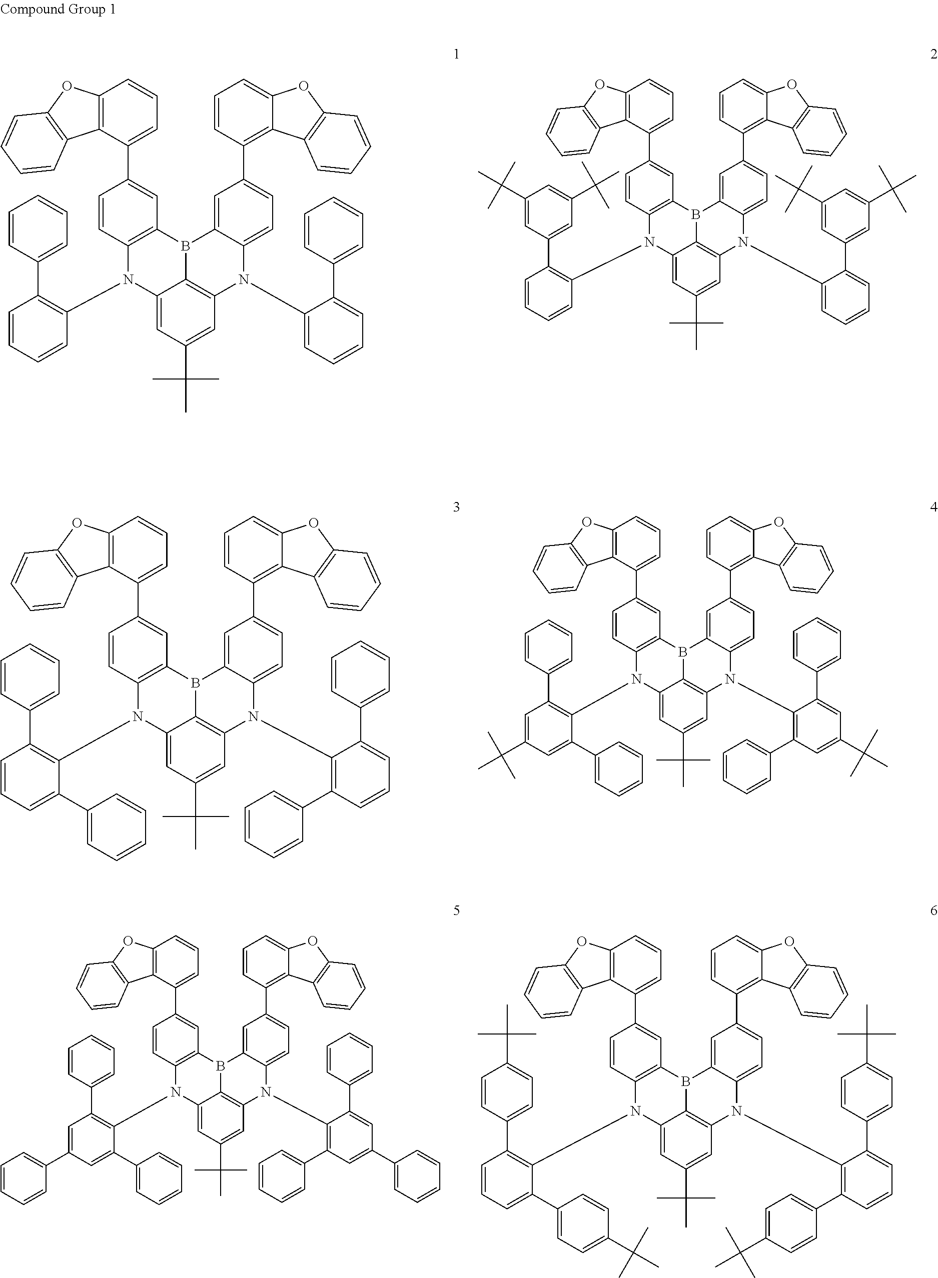

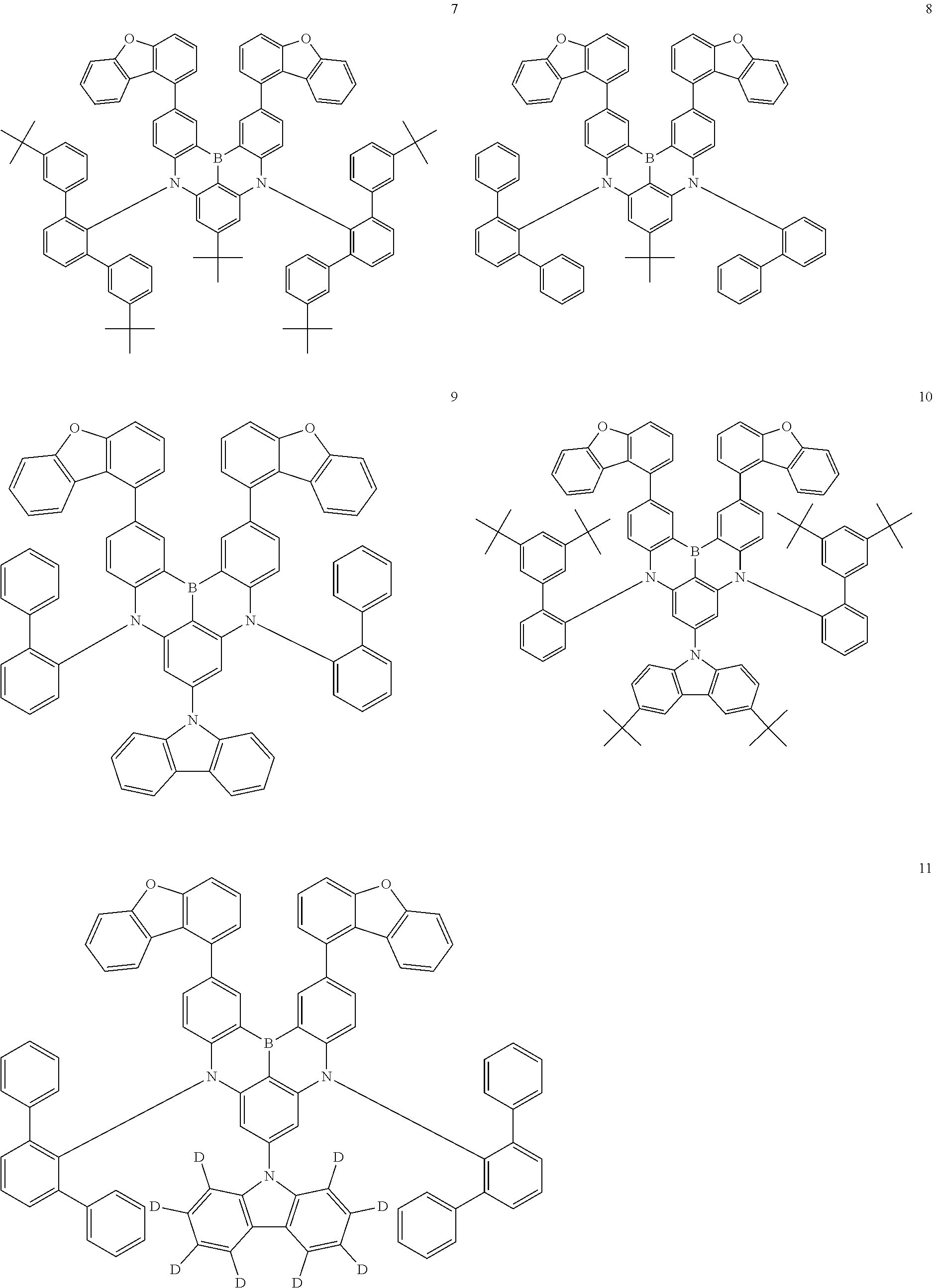

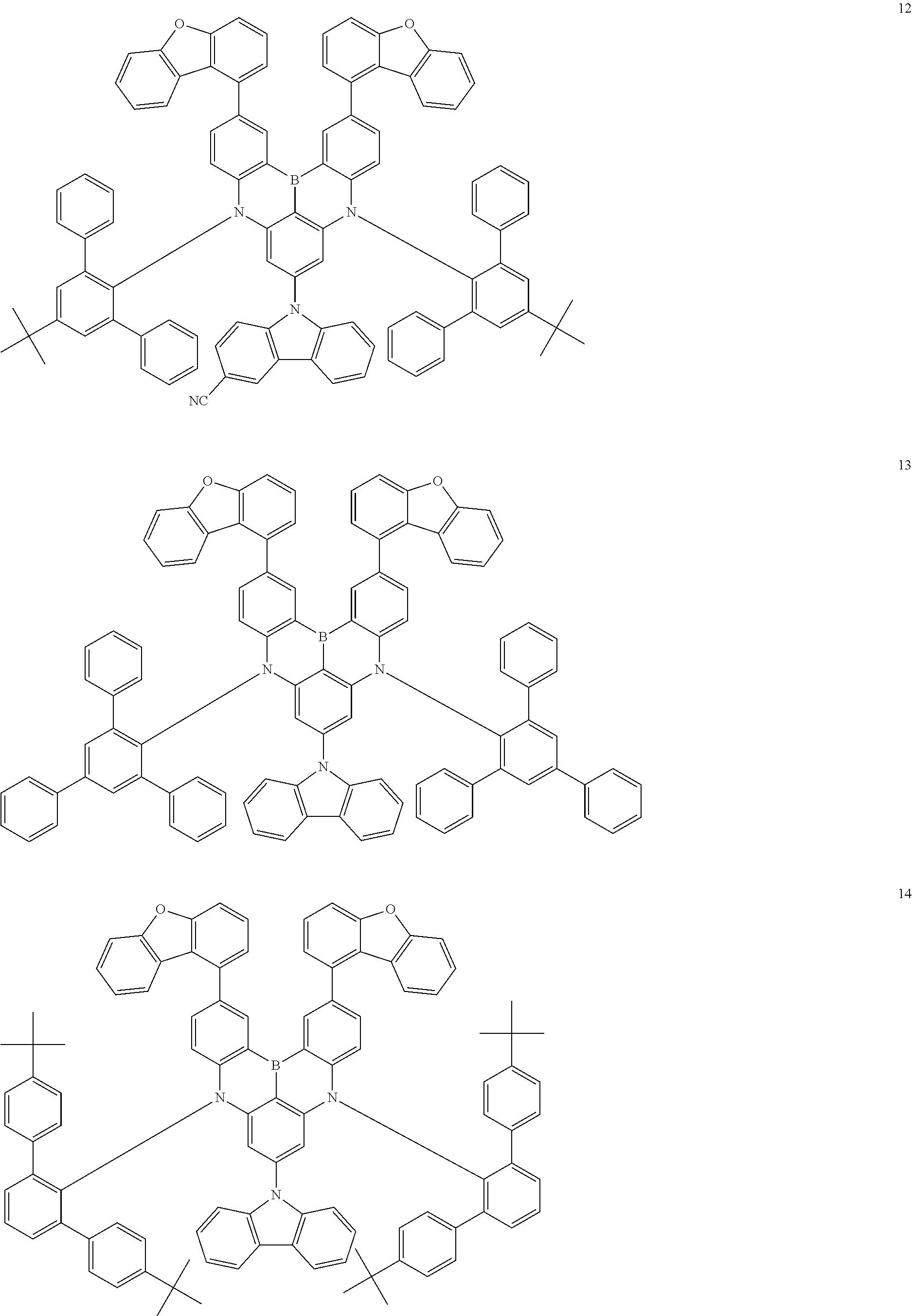

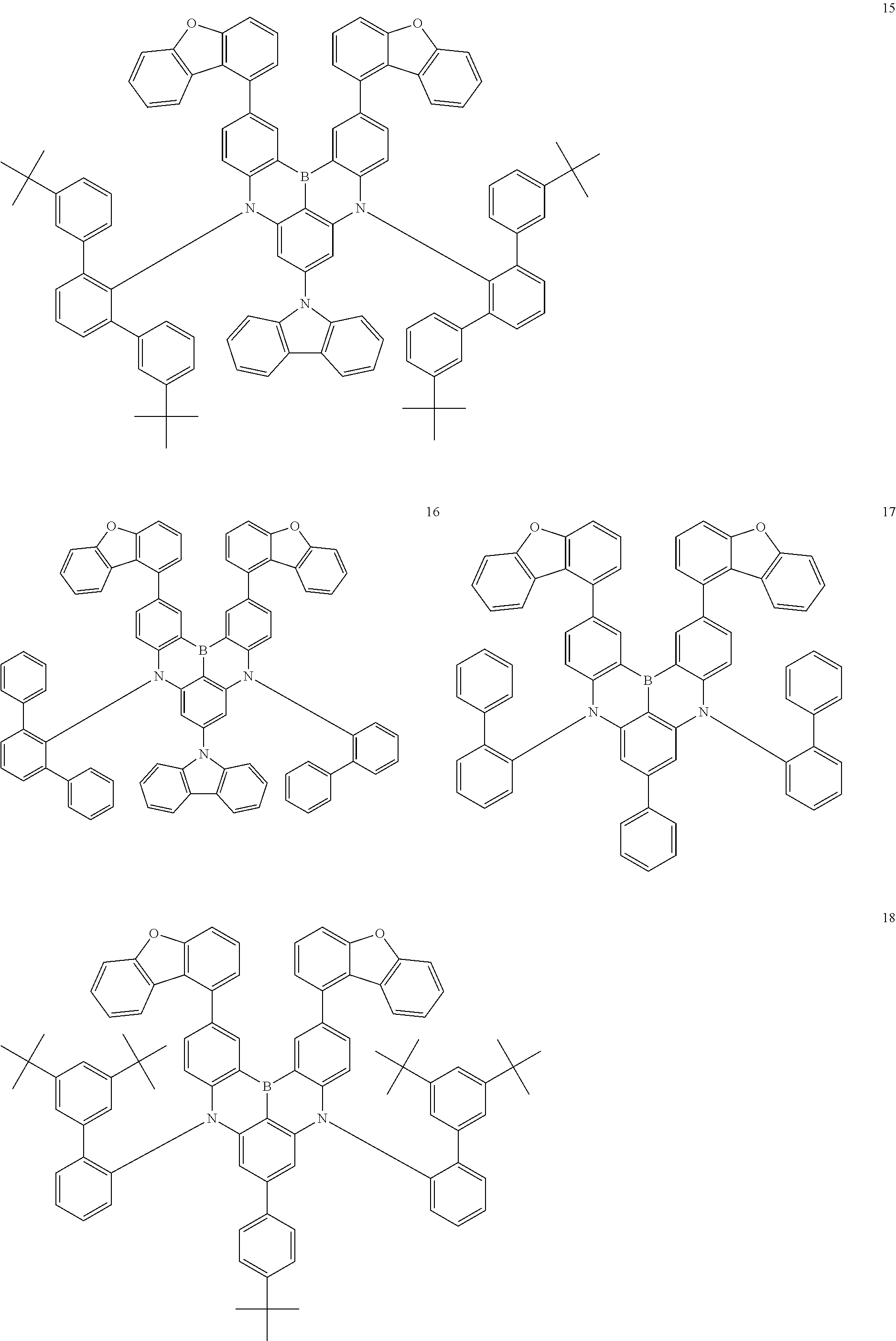

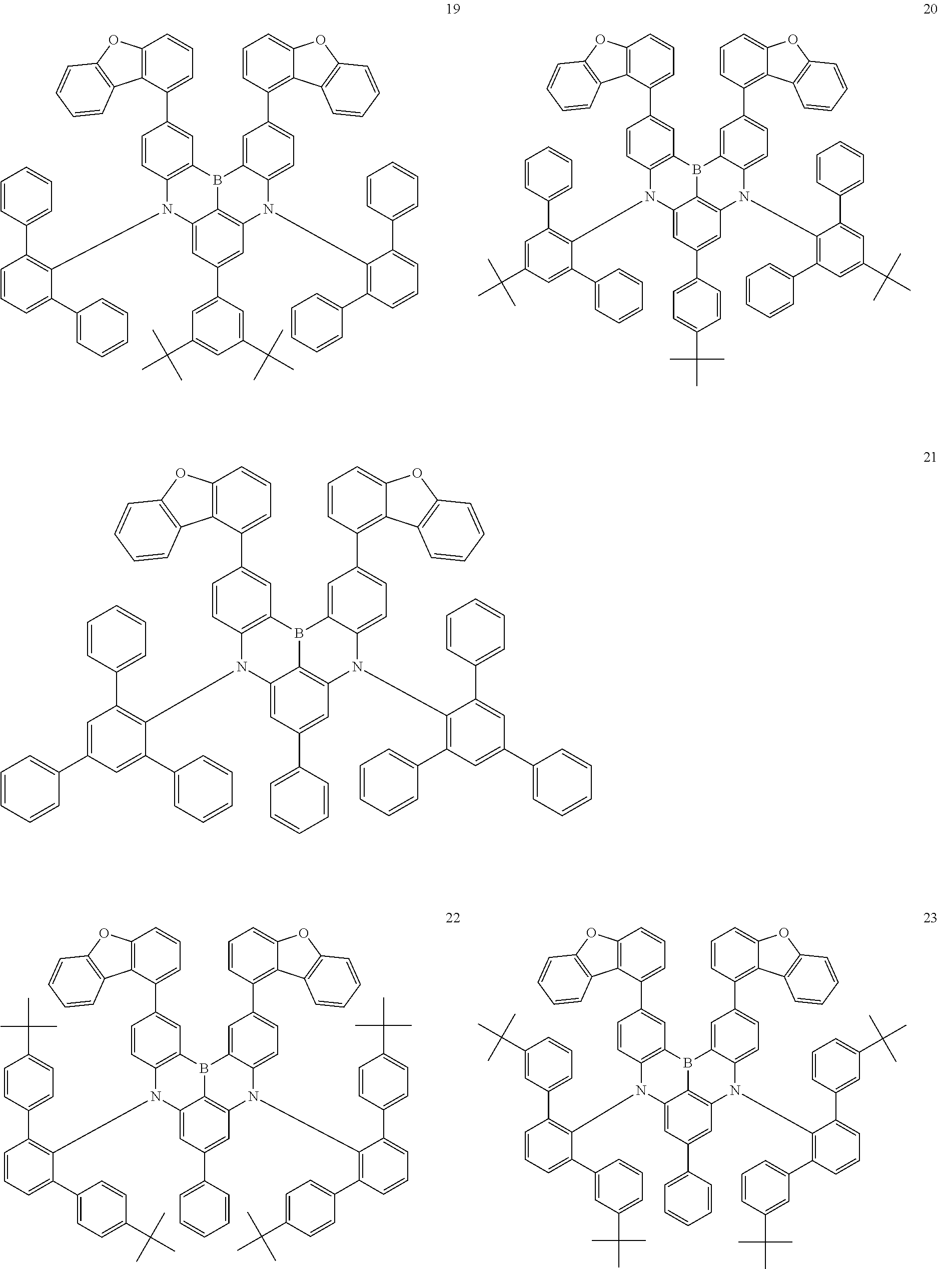

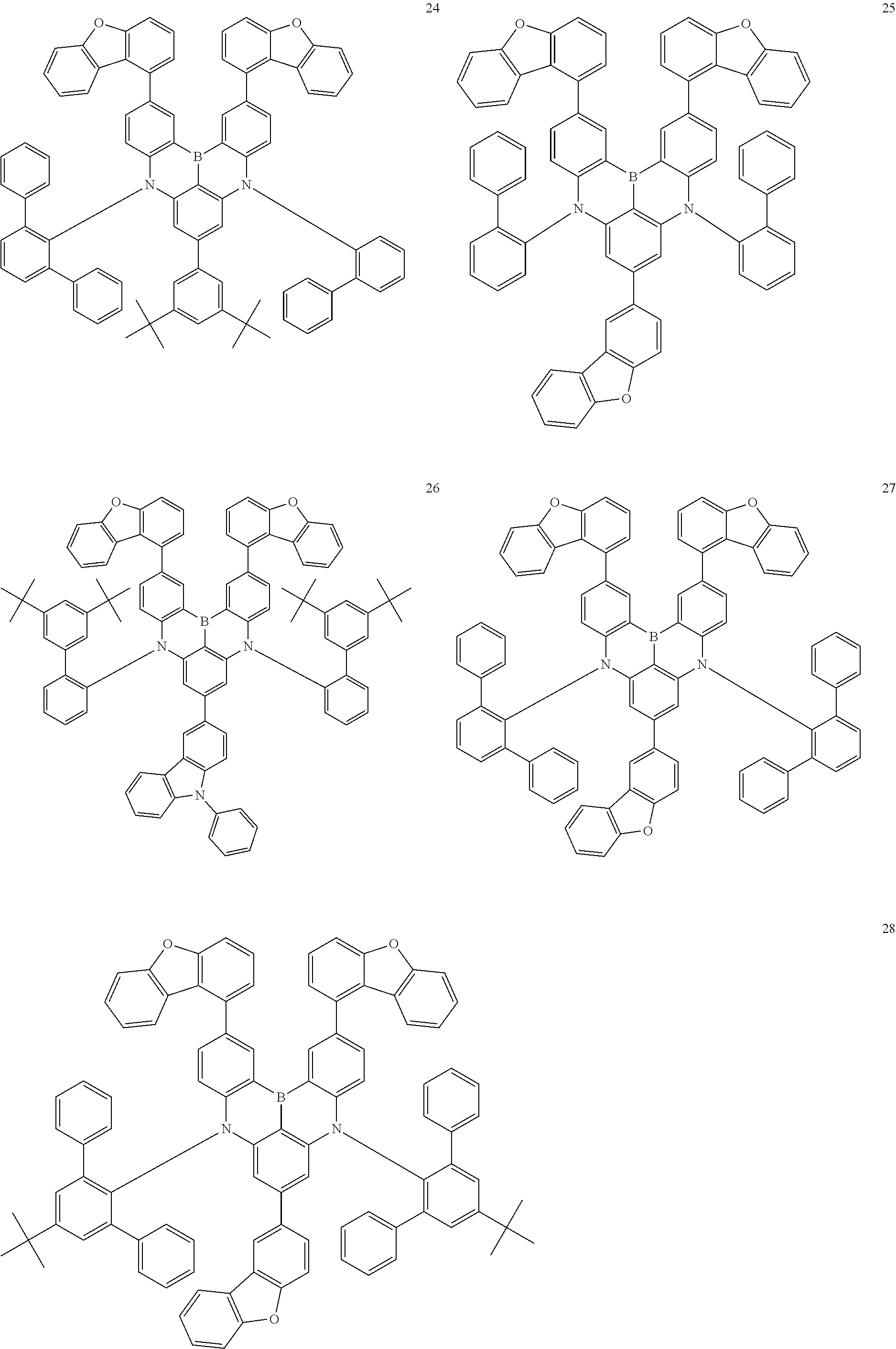

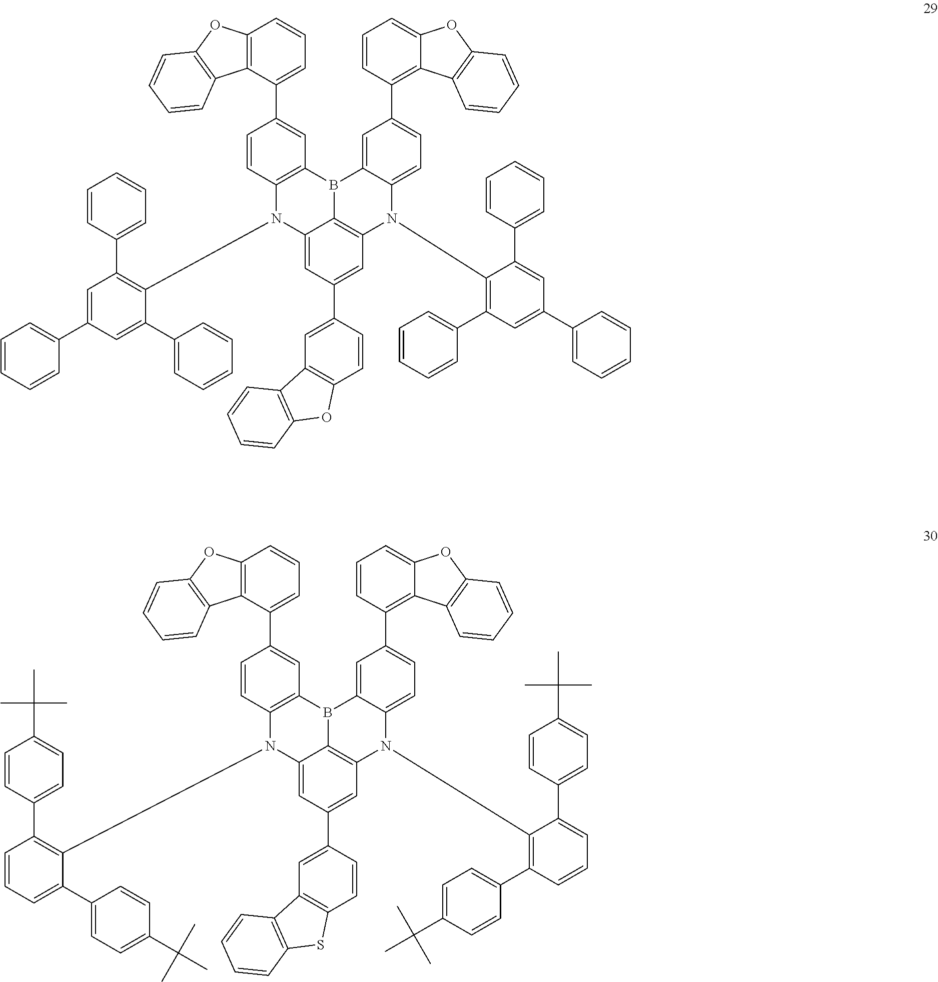 [SMILES: c1ccc(-c2cc(-c3ccccc3)c(N3c4ccc(-c5cccc6oc7ccccc7c56)cc4B4c5cc(-c6cccc7oc8ccccc8c67)ccc5N(c5c(-c6ccccc6)cc(-c6ccccc6)cc5-c5ccccc5)c5cc(-c6ccc7oc8ccccc8c7c6)cc3c54)c(-c3ccccc3)c2)cc1 ; CC(C)(C)c1ccc(-c2cccc(-c3ccc(C(C)(C)C)cc3)c2N2c3ccc(-c4cccc5oc6ccccc6c45)cc3B3c4cc(-c5cccc6oc7ccccc7c56)ccc4N(c4c(-c5ccc(C(C)(C)C)cc5)cccc4-c4ccc(C(C)(C)C)cc4)c4cc(-c5ccc6sc7ccccc7c6c5)cc2c43)cc1]

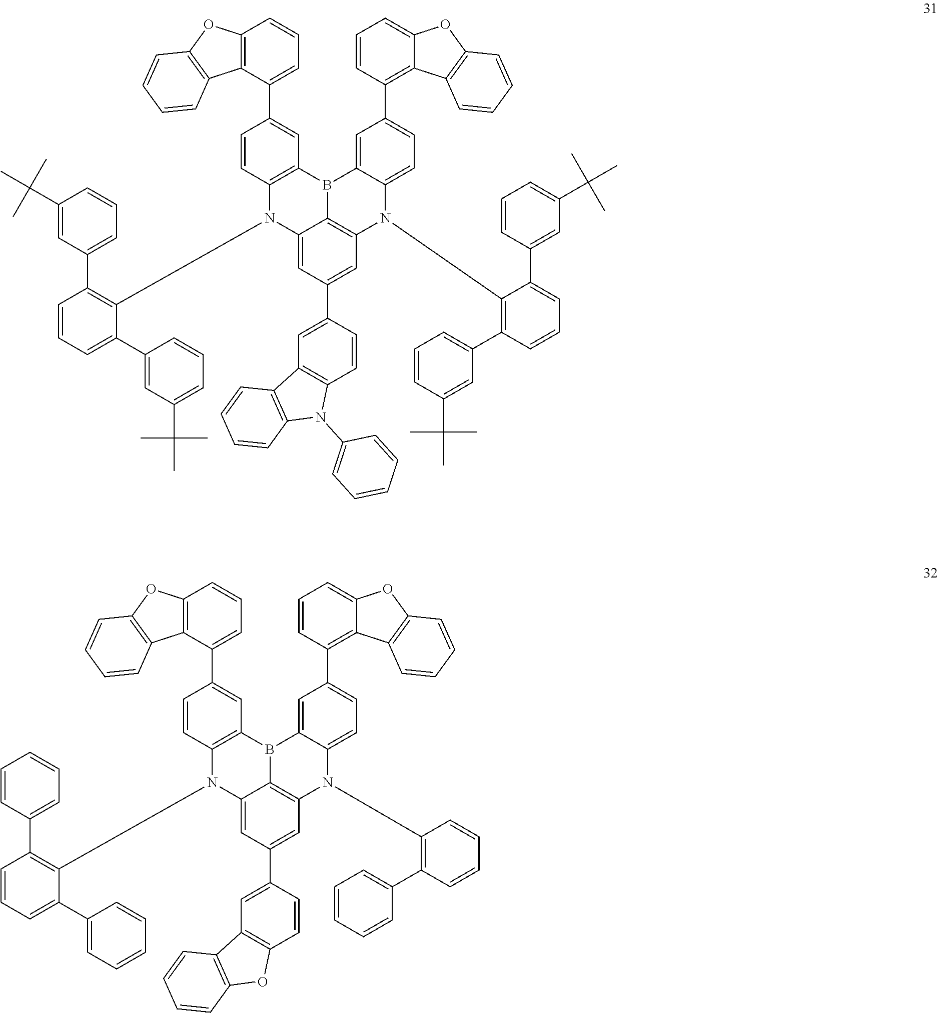 [SMILES: CC(C)(C)c1cccc(-c2cccc(-c3cccc(C(C)(C)C)c3)c2N2c3ccc(-c4cccc5oc6ccccc6c45)cc3B3c4cc(-c5cccc6oc7ccccc7c56)ccc4N(c4c(-c5cccc(C(C)(C)C)c5)cccc4-c4cccc(C(C)(C)C)c4)c4cc(-c5ccc6c(c5)c5ccccc5n6-c5ccccc5)cc2c43)c1 ; c1ccc(-c2ccccc2N2c3ccc(-c4cccc5oc6ccccc6c45)cc3B3c4cc(-c5cccc6oc7ccccc7c56)ccc4N(c4c(-c5ccccc5)cccc4-c4ccccc4)c4cc(-c5ccc6oc7ccccc7c6c5)cc2c43)cc1]

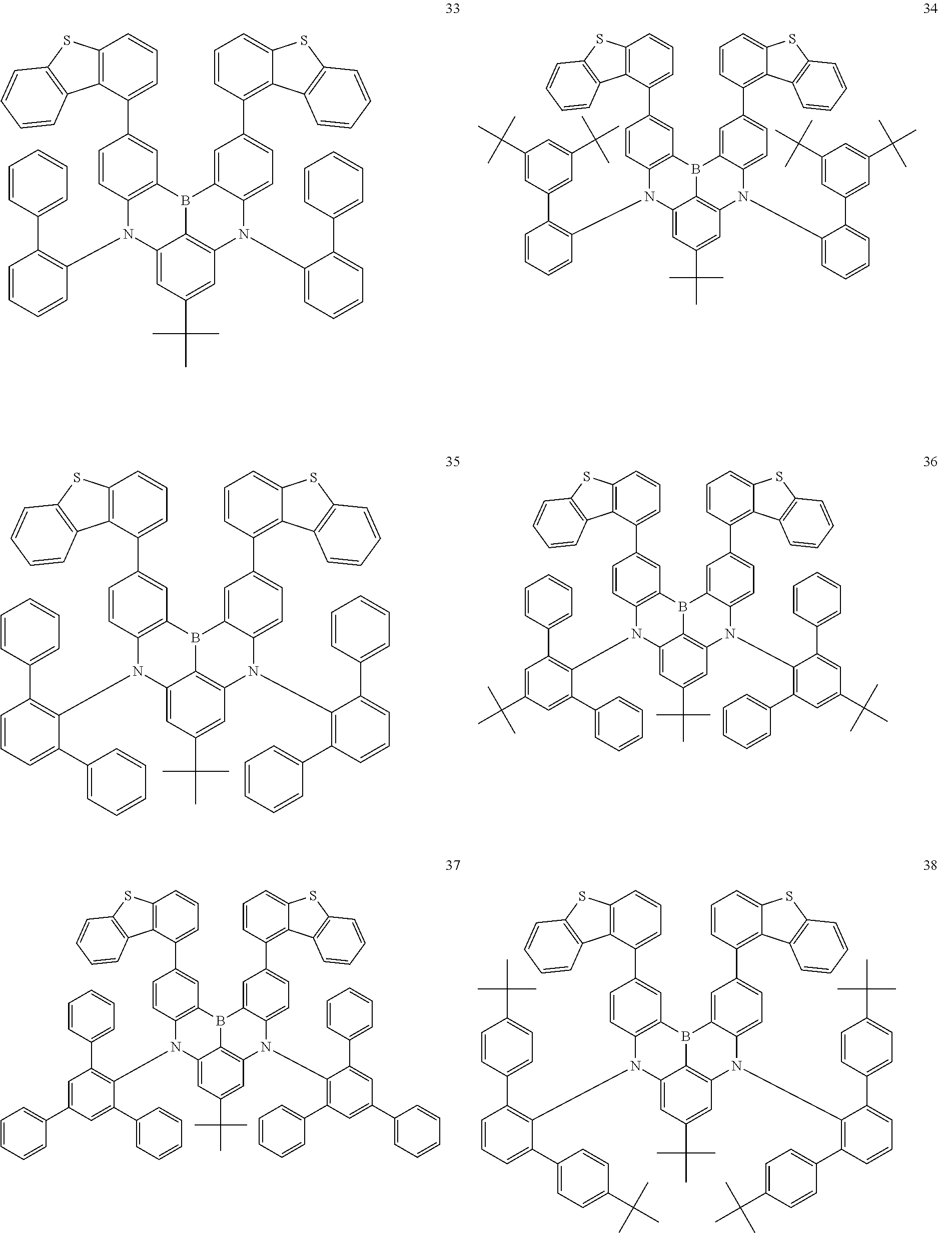

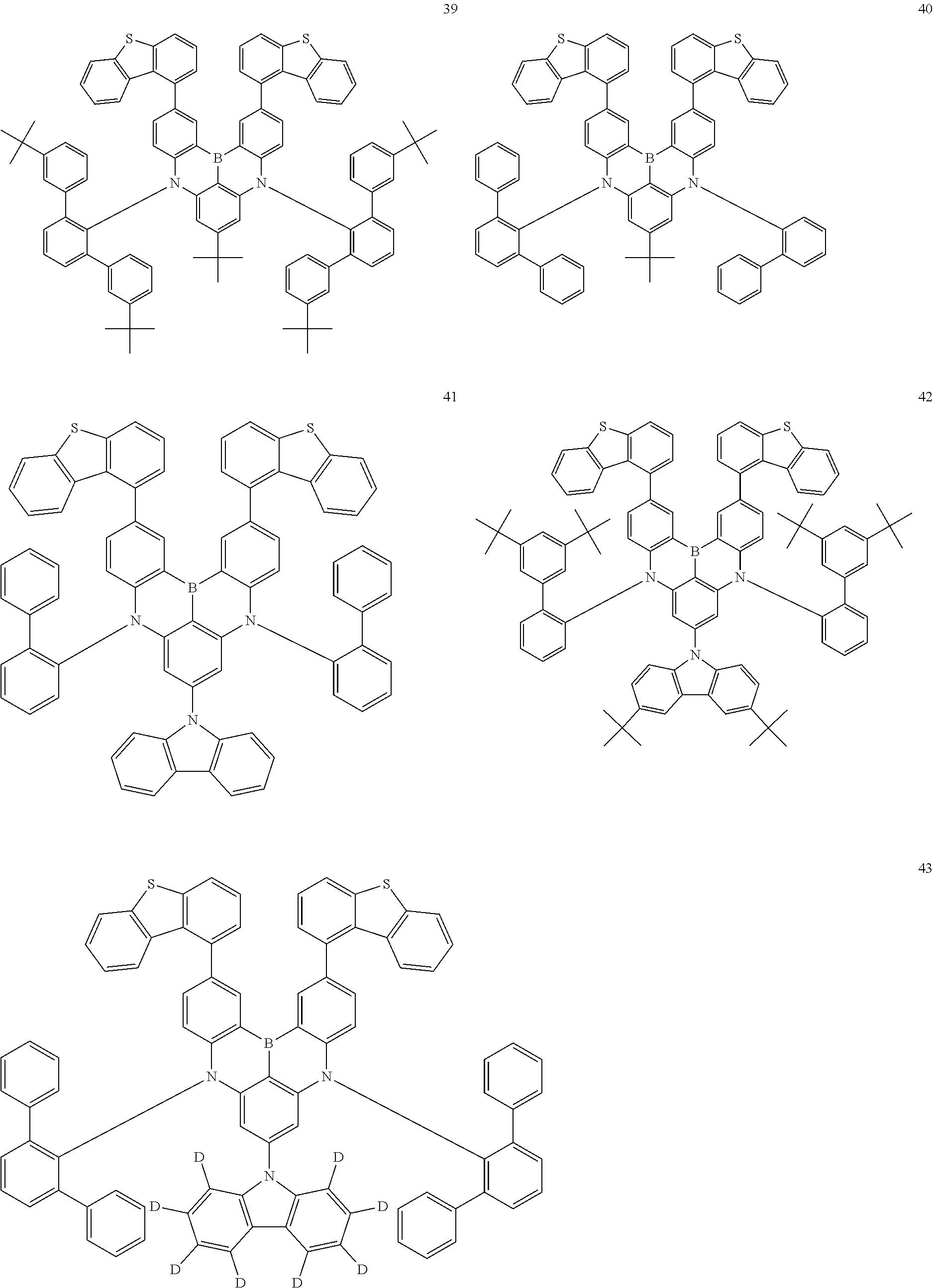

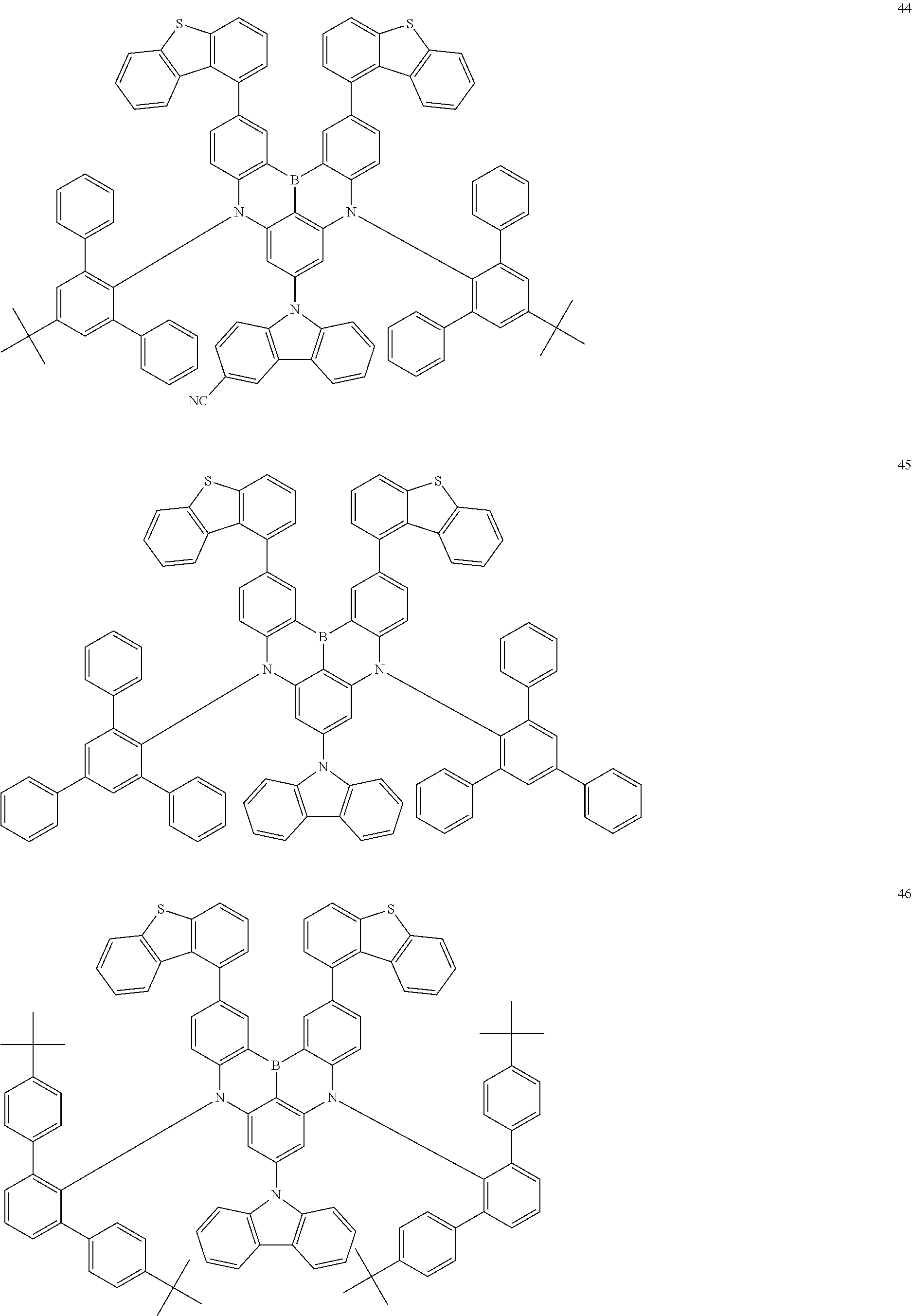

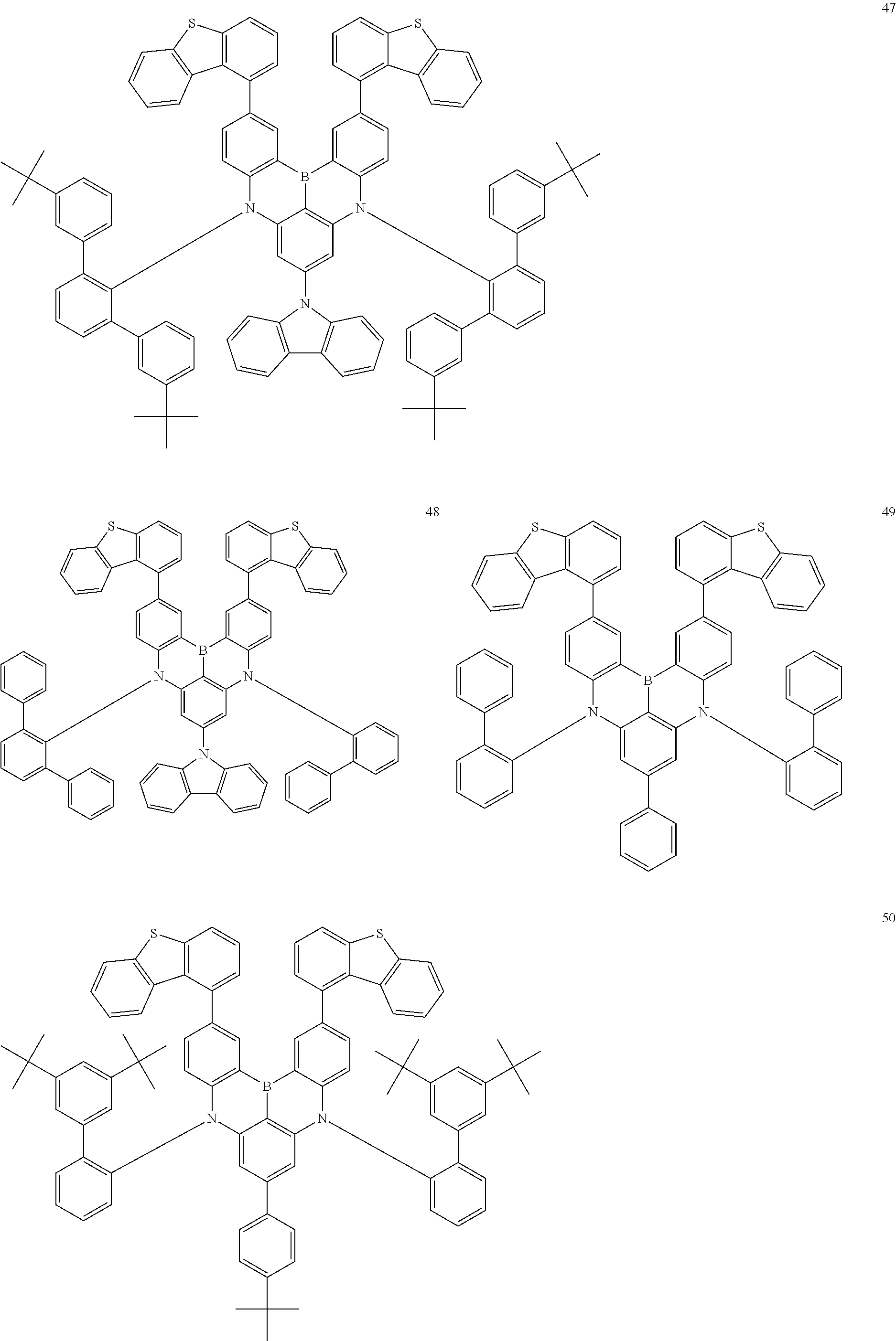

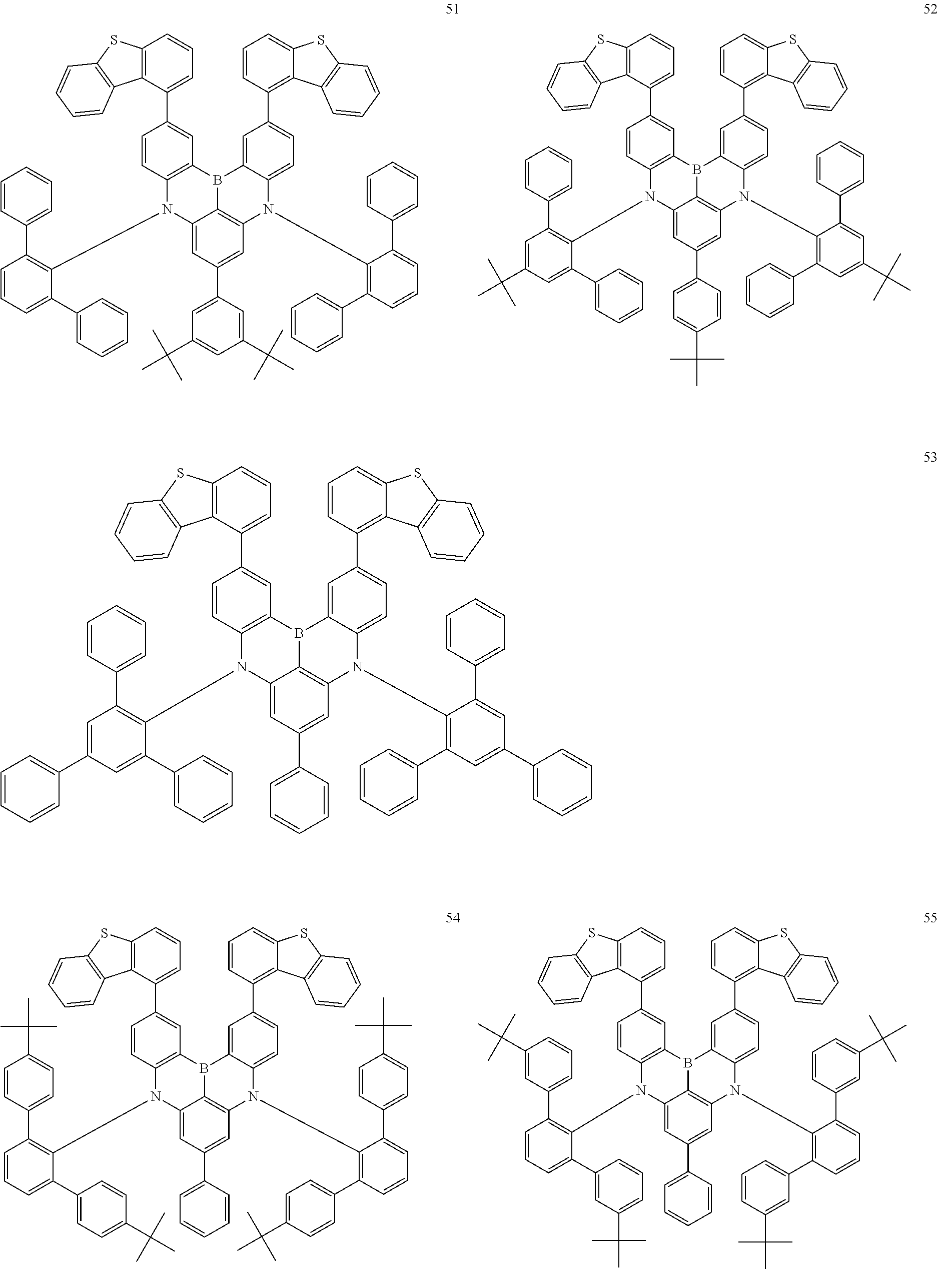

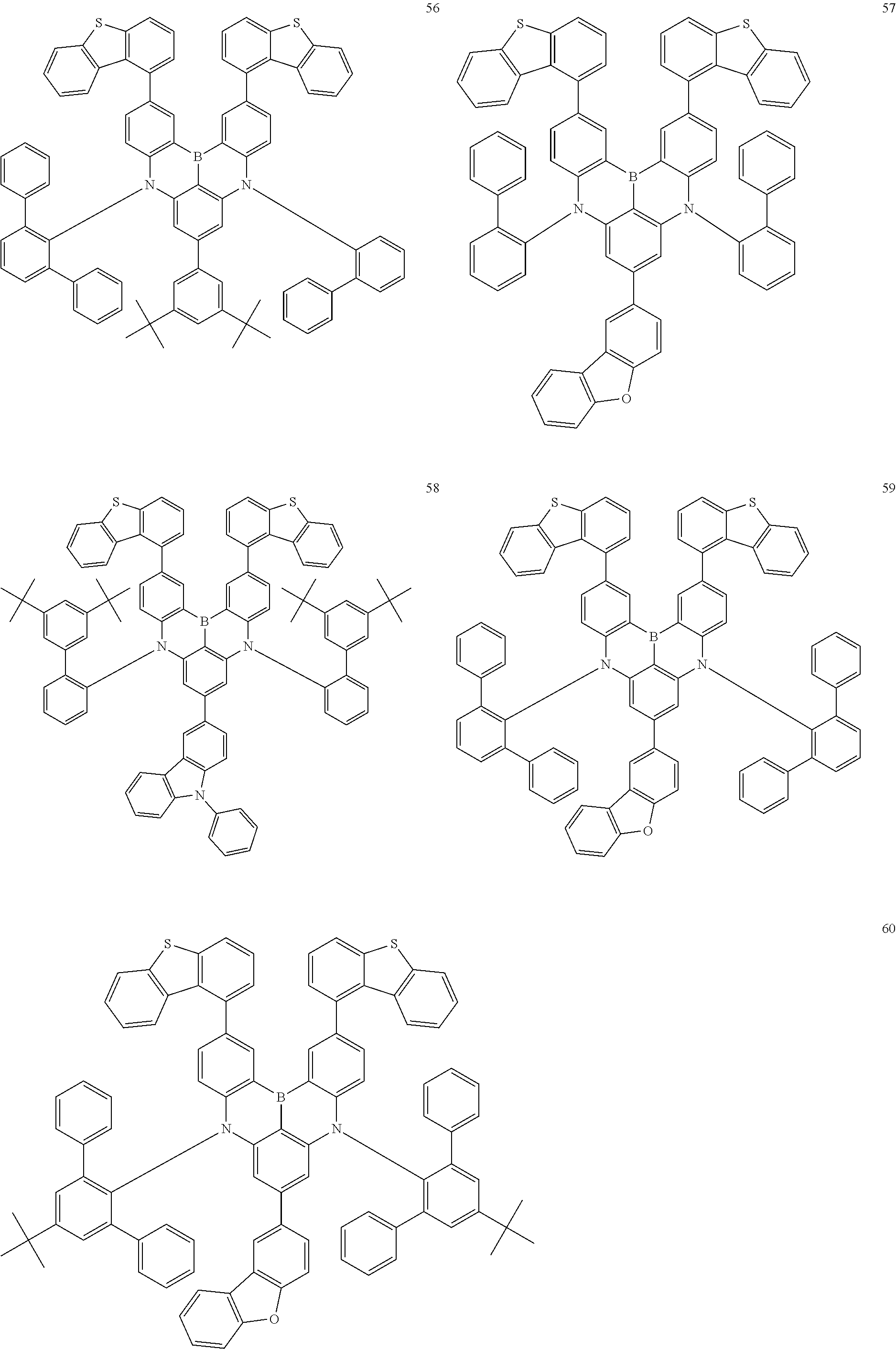

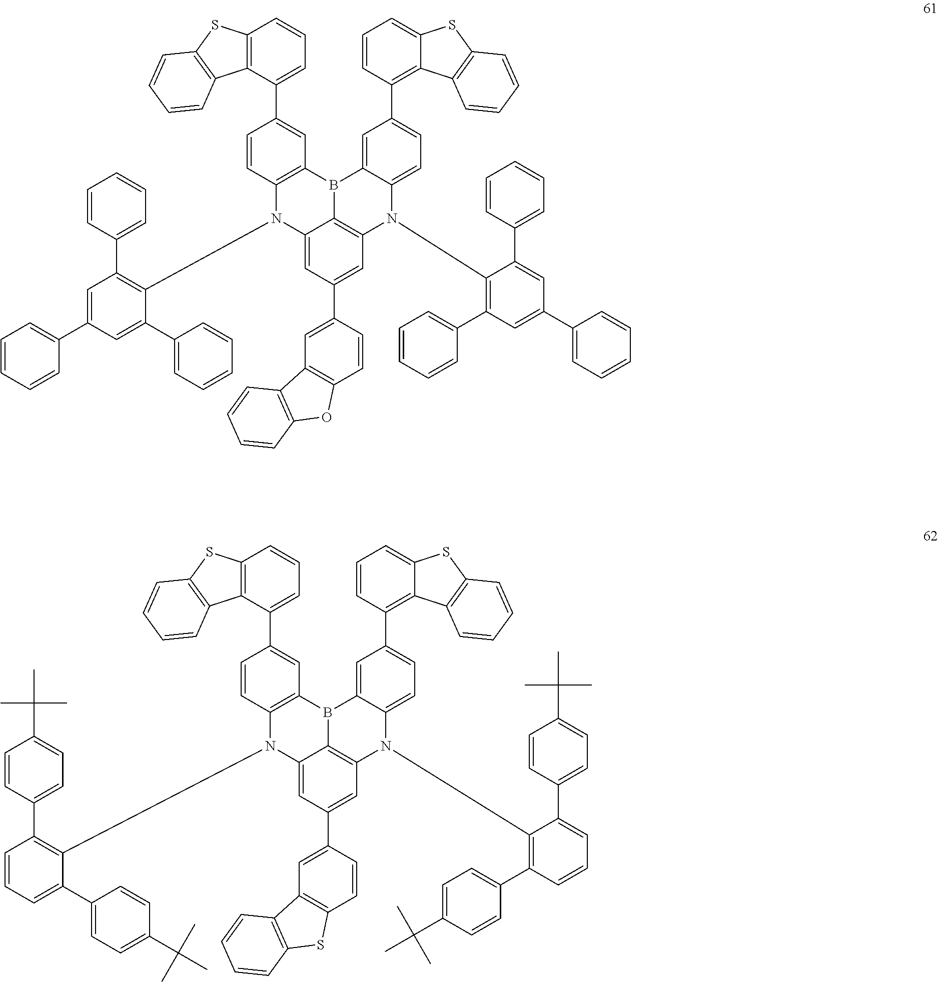 [SMILES: c1ccc(-c2cc(-c3ccccc3)c(N3c4ccc(-c5cccc6sc7ccccc7c56)cc4B4c5cc(-c6cccc7sc8ccccc8c67)ccc5N(c5c(-c6ccccc6)cc(-c6ccccc6)cc5-c5ccccc5)c5cc(-c6ccc7oc8ccccc8c7c6)cc3c54)c(-c3ccccc3)c2)cc1 ; CC(C)(C)c1ccc(-c2cccc(-c3ccc(C(C)(C)C)cc3)c2N2c3ccc(-c4cccc5sc6ccccc6c45)cc3B3c4cc(-c5cccc6sc7ccccc7c56)ccc4N(c4c(-c5ccc(C(C)(C)C)cc5)cccc4-c4ccc(C(C)(C)C)cc4)c4cc(-c5ccc6sc7ccccc7c6c5)cc2c43)cc1]

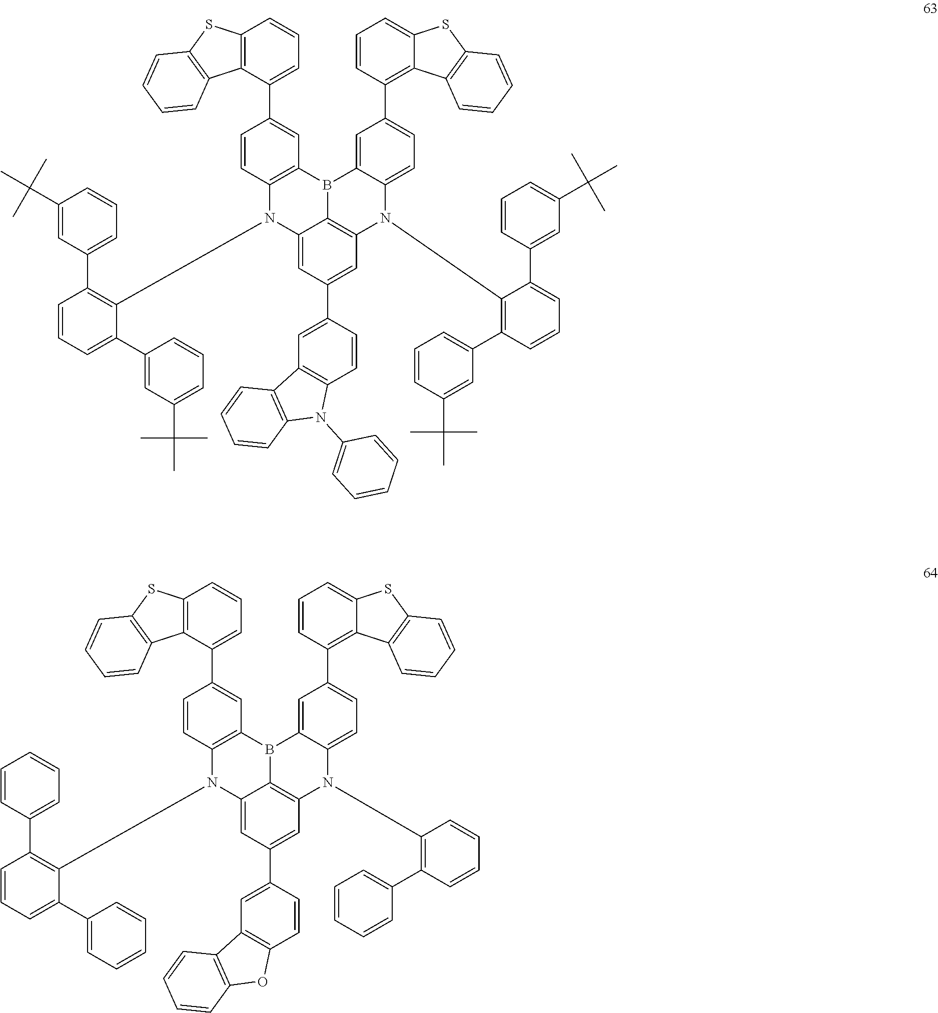 [SMILES: CC(C)(C)c1cccc(-c2cccc(-c3cccc(C(C)(C)C)c3)c2N2c3ccc(-c4cccc5sc6ccccc6c45)cc3B3c4cc(-c5cccc6sc7ccccc7c56)ccc4N(c4c(-c5cccc(C(C)(C)C)c5)cccc4-c4cccc(C(C)(C)C)c4)c4cc(-c5ccc6c(c5)c5ccccc5n6-c5ccccc5)cc2c43)c1 ; c1ccc(-c2ccccc2N2c3ccc(-c4cccc5sc6ccccc6c45)cc3B3c4cc(-c5cccc6sc7ccccc7c56)ccc4N(c4c(-c5ccccc5)cccc4-c4ccccc4)c4cc(-c5ccc6oc7ccccc7c6c5)cc2c43)cc1]

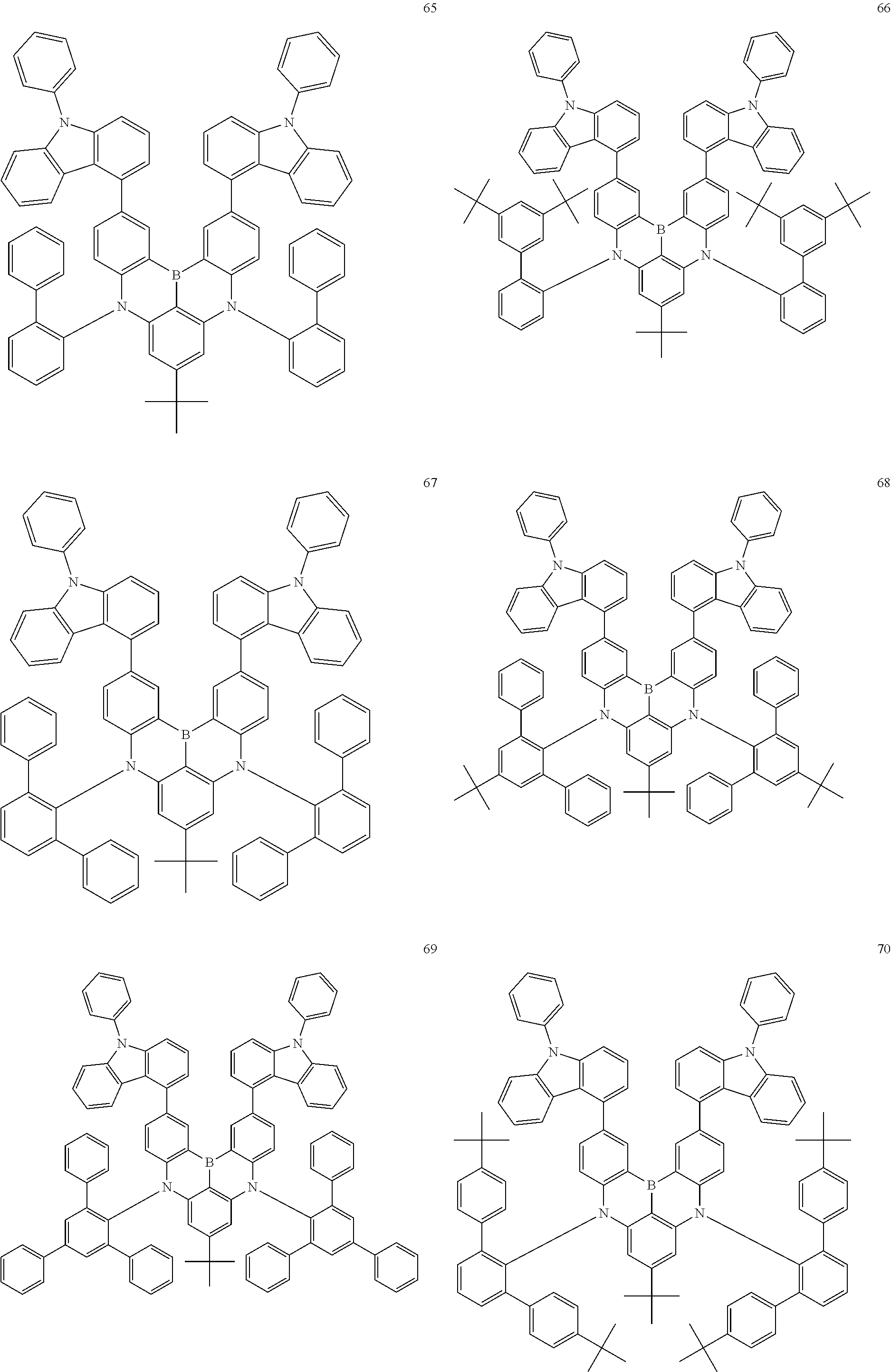

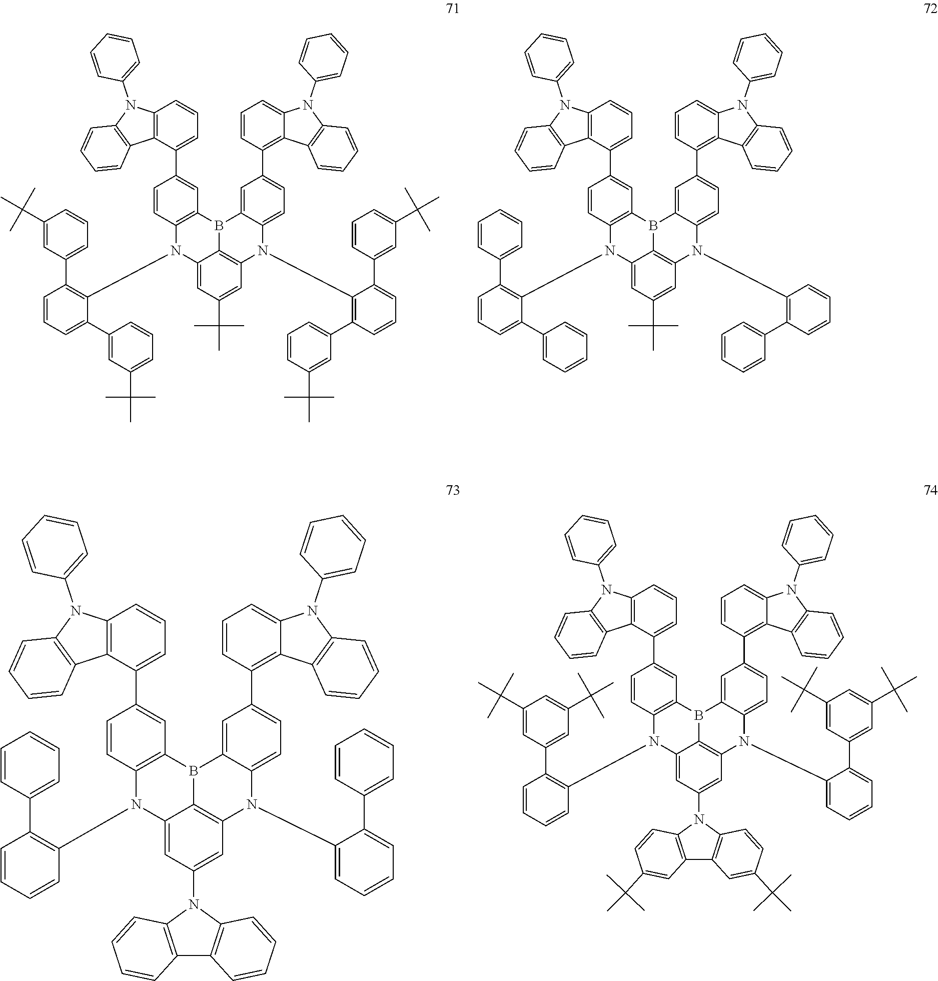

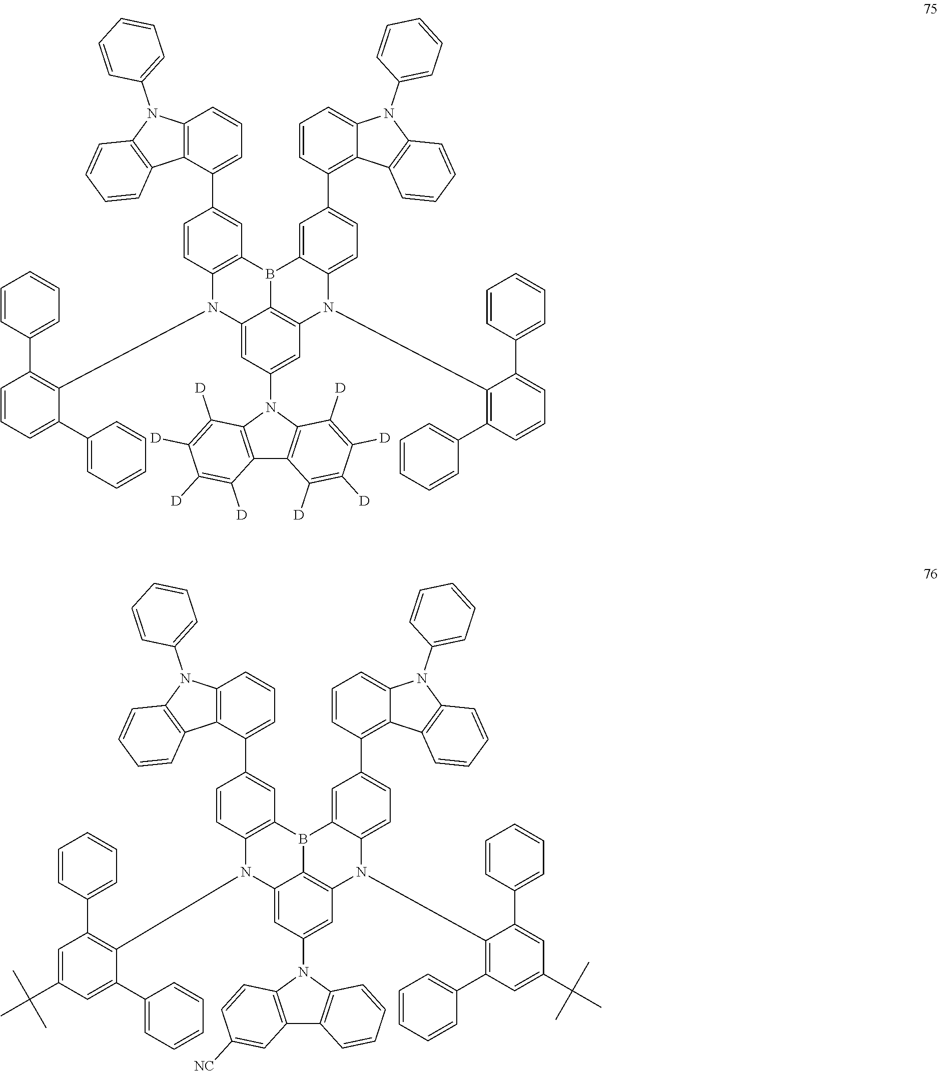 [SMILES: [2H]c1c([2H])c([2H])c2c(c1[2H])c1c([2H])c([2H])c([2H])c([2H])c1n2-c1cc2c3c(c1)N(c1c(-c4ccccc4)cccc1-c1ccccc1)c1ccc(-c4cccc5c4c4ccccc4n5-c4ccccc4)cc1B3c1cc(-c3cccc4c3c3ccccc3n4-c3ccccc3)ccc1N2c1c(-c2ccccc2)cccc1-c1ccccc1 ; CC(C)(C)c1cc(-c2ccccc2)c(N2c3ccc(-c4cccc5c4c4ccccc4n5-c4ccccc4)cc3B3c4cc(-c5cccc6c5c5ccccc5n6-c5ccccc5)ccc4N(c4c(-c5ccccc5)cc(C(C)(C)C)cc4-c4ccccc4)c4cc(-n5c6ccccc6c6cc(C#N)ccc65)cc2c43)c(-c2ccccc2)c1]

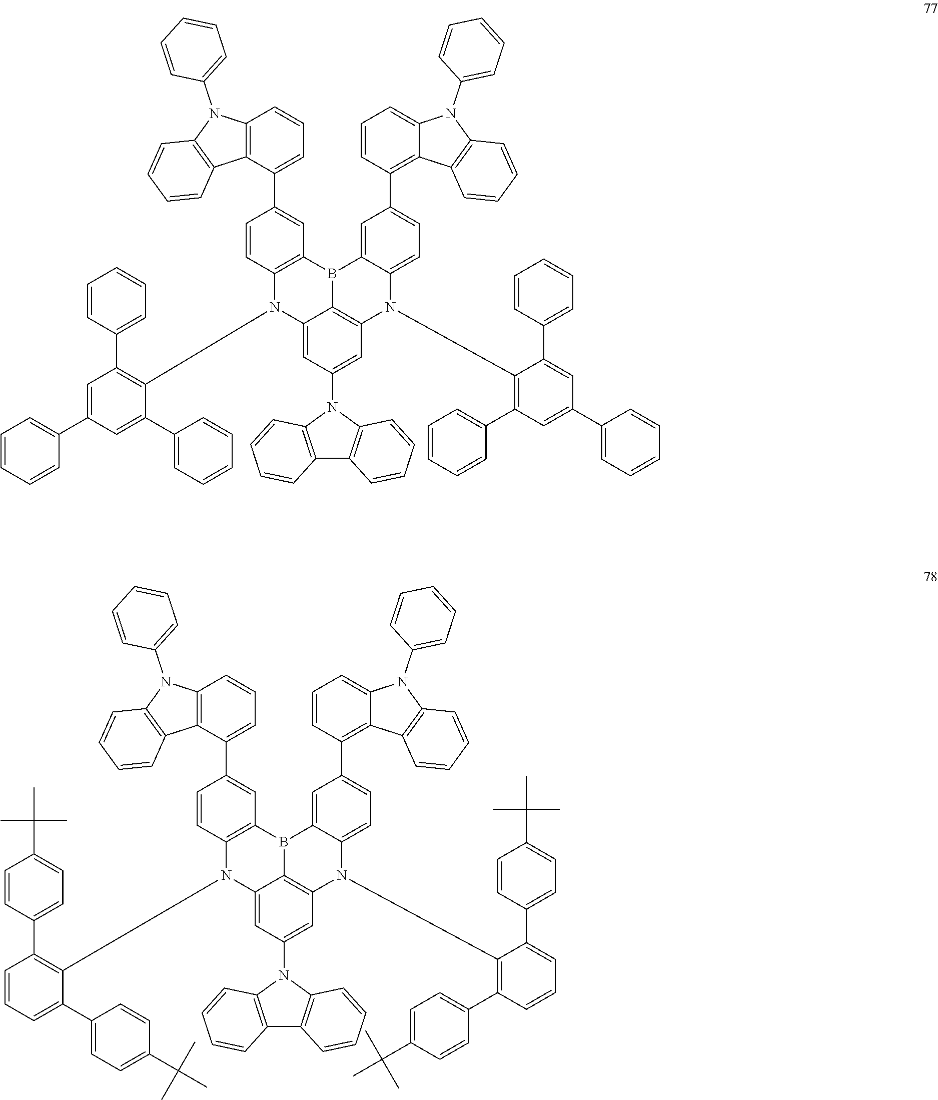 [SMILES: c1ccc(-c2cc(-c3ccccc3)c(N3c4ccc(-c5cccc6c5c5ccccc5n6-c5ccccc5)cc4B4c5cc(-c6cccc7c6c6ccccc6n7-c6ccccc6)ccc5N(c5c(-c6ccccc6)cc(-c6ccccc6)cc5-c5ccccc5)c5cc(-n6c7ccccc7c7ccccc76)cc3c54)c(-c3ccccc3)c2)cc1 ; CC(C)(C)c1ccc(-c2cccc(-c3ccc(C(C)(C)C)cc3)c2N2c3ccc(-c4cccc5c4c4ccccc4n5-c4ccccc4)cc3B3c4cc(-c5cccc6c5c5ccccc5n6-c5ccccc5)ccc4N(c4c(-c5ccc(C(C)(C)C)cc5)cccc4-c4ccc(C(C)(C)C)cc4)c4cc(-n5c6ccccc6c6ccccc65)cc2c43)cc1]

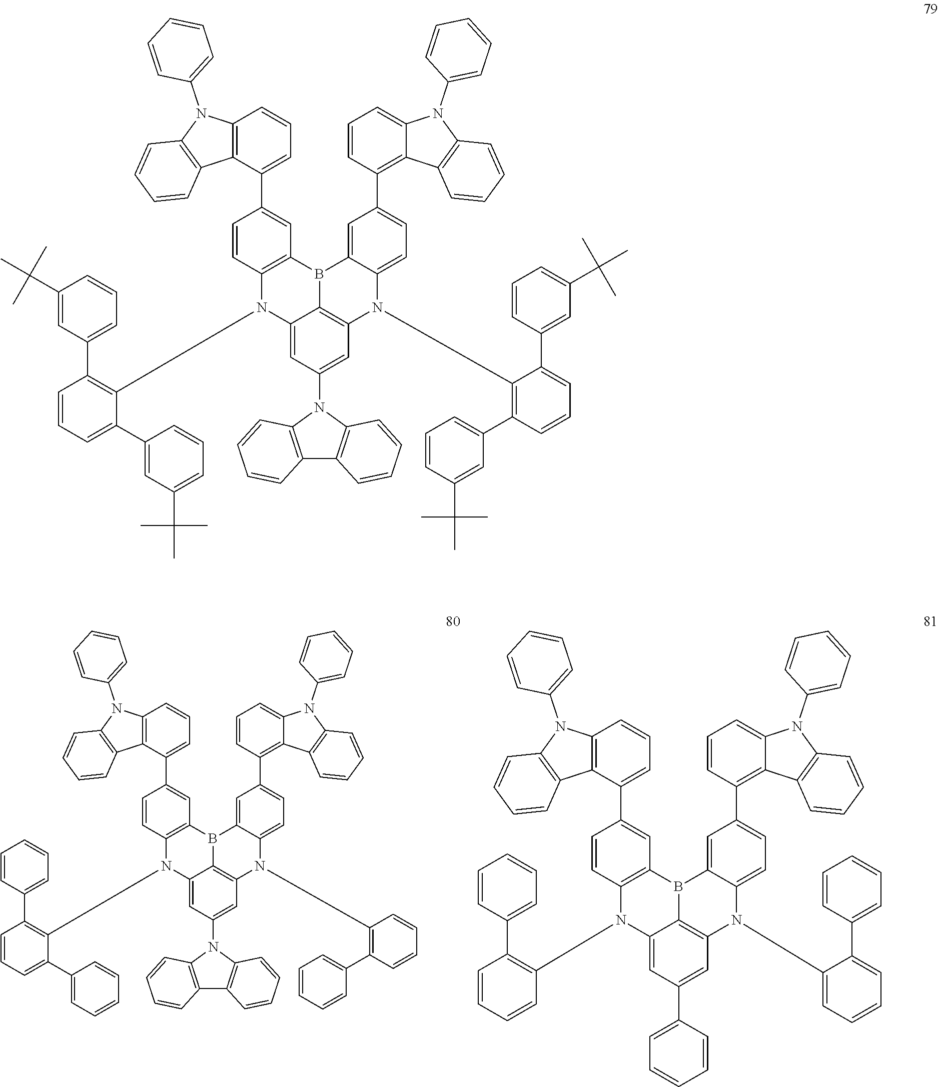

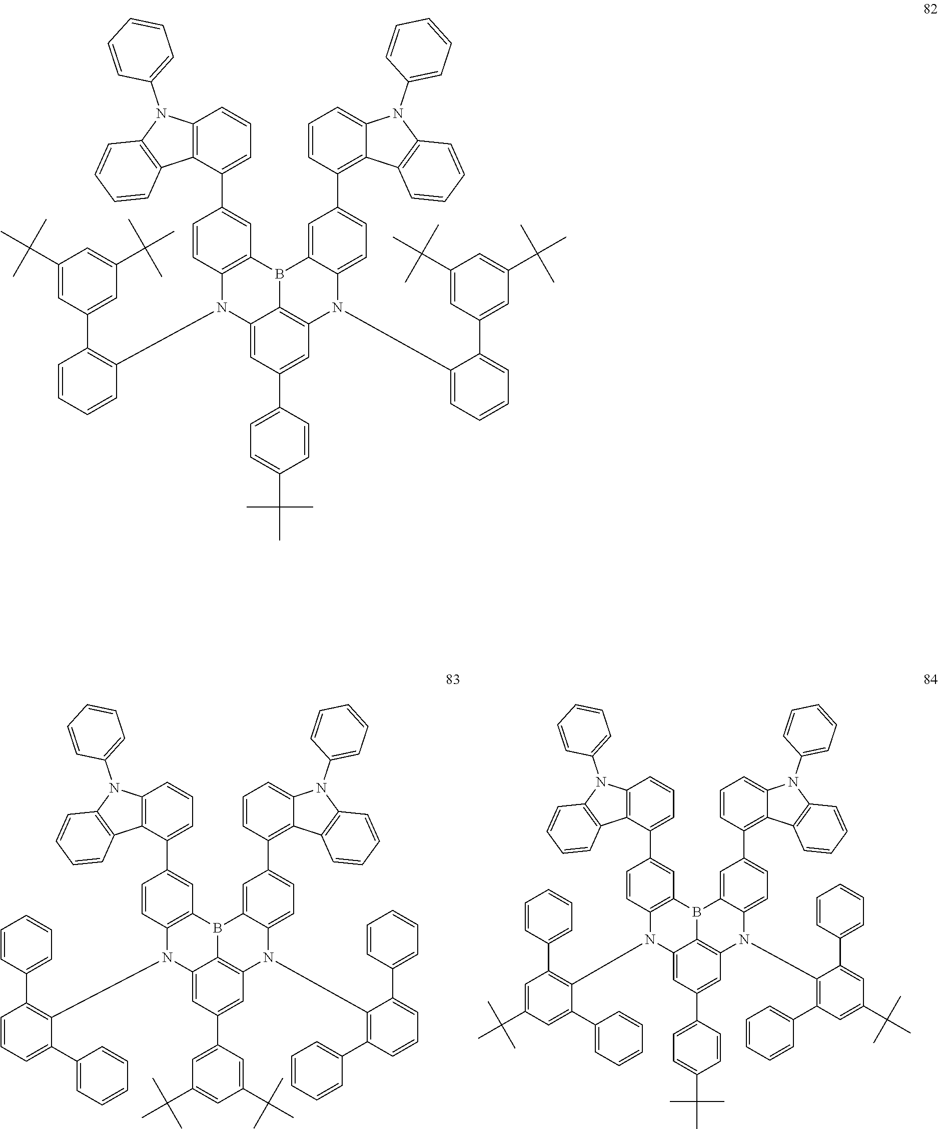

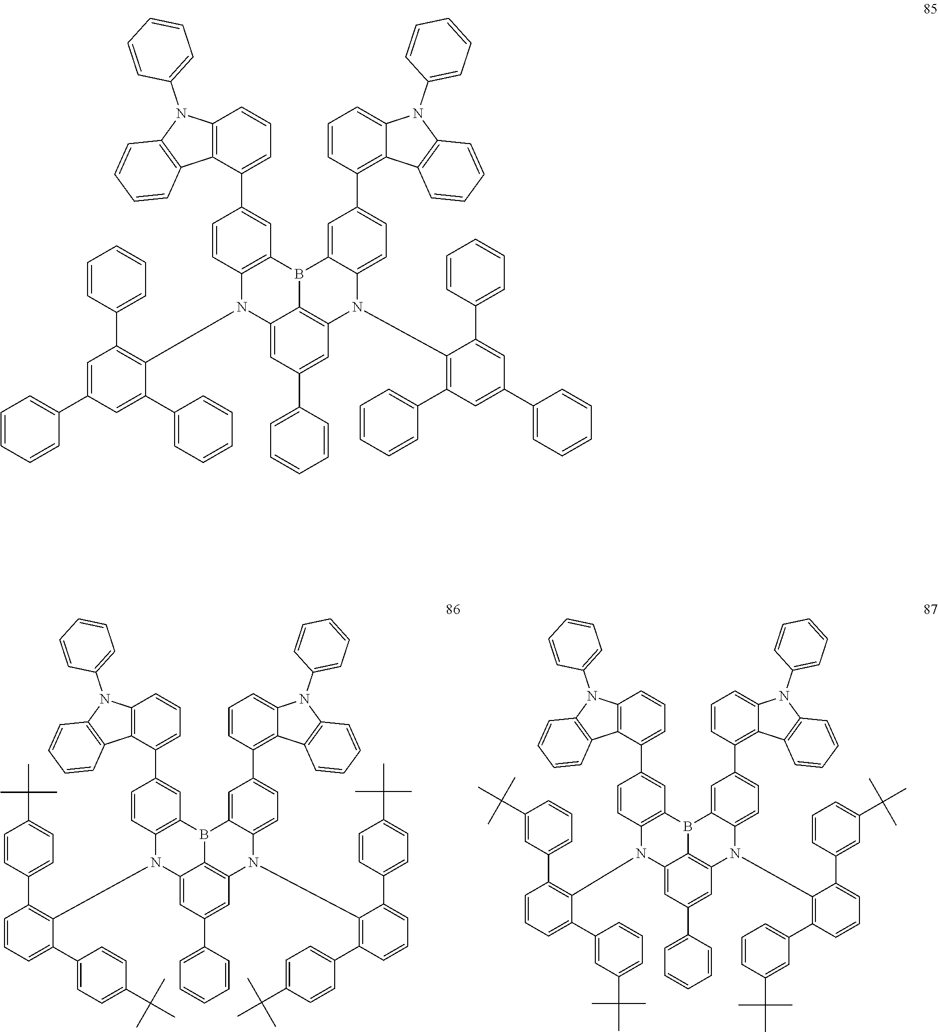

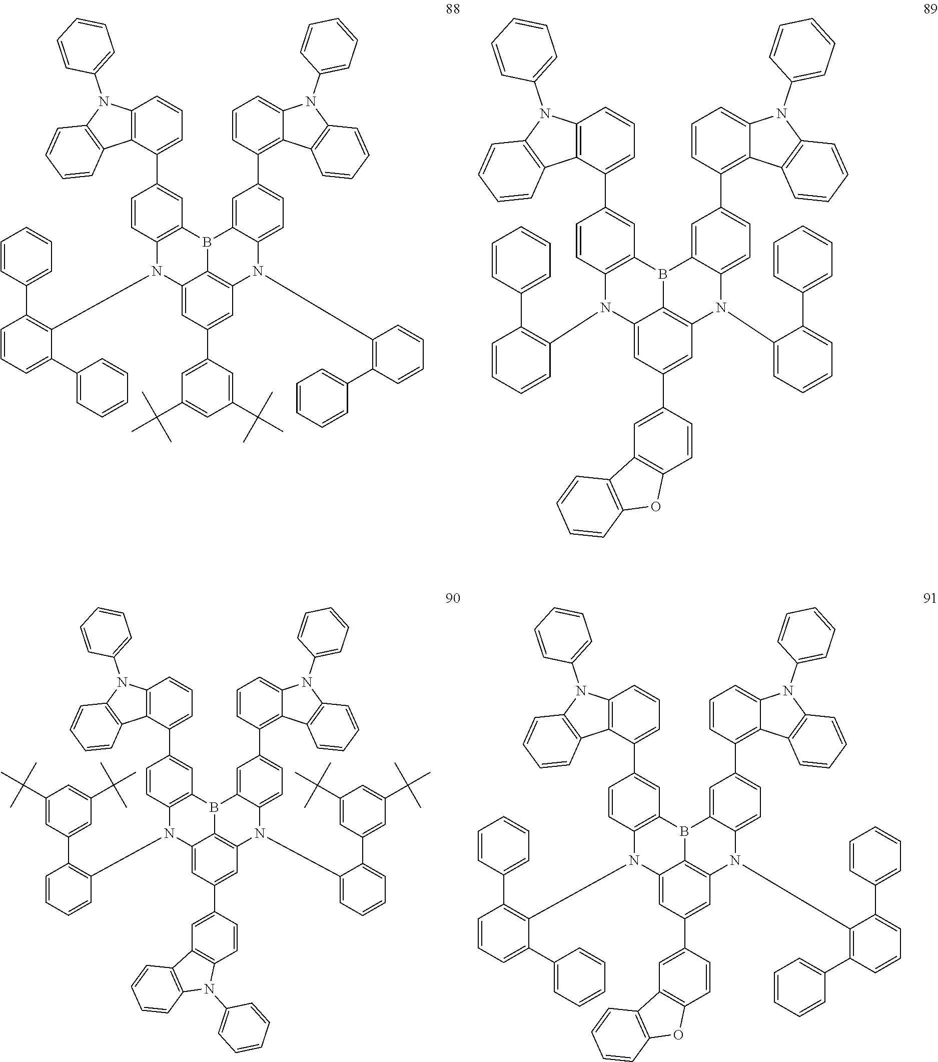

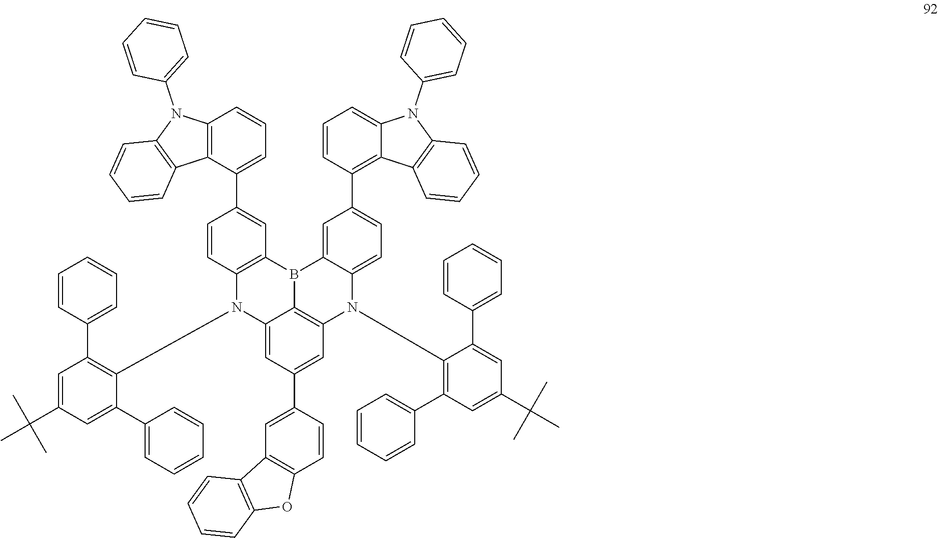 [SMILES: CC(C)(C)c1cc(-c2ccccc2)c(N2c3ccc(-c4cccc5c4c4ccccc4n5-c4ccccc4)cc3B3c4cc(-c5cccc6c5c5ccccc5n6-c5ccccc5)ccc4N(c4c(-c5ccccc5)cc(C(C)(C)C)cc4-c4ccccc4)c4cc(-c5ccc6oc7ccccc7c6c5)cc2c43)c(-c2ccccc2)c1]

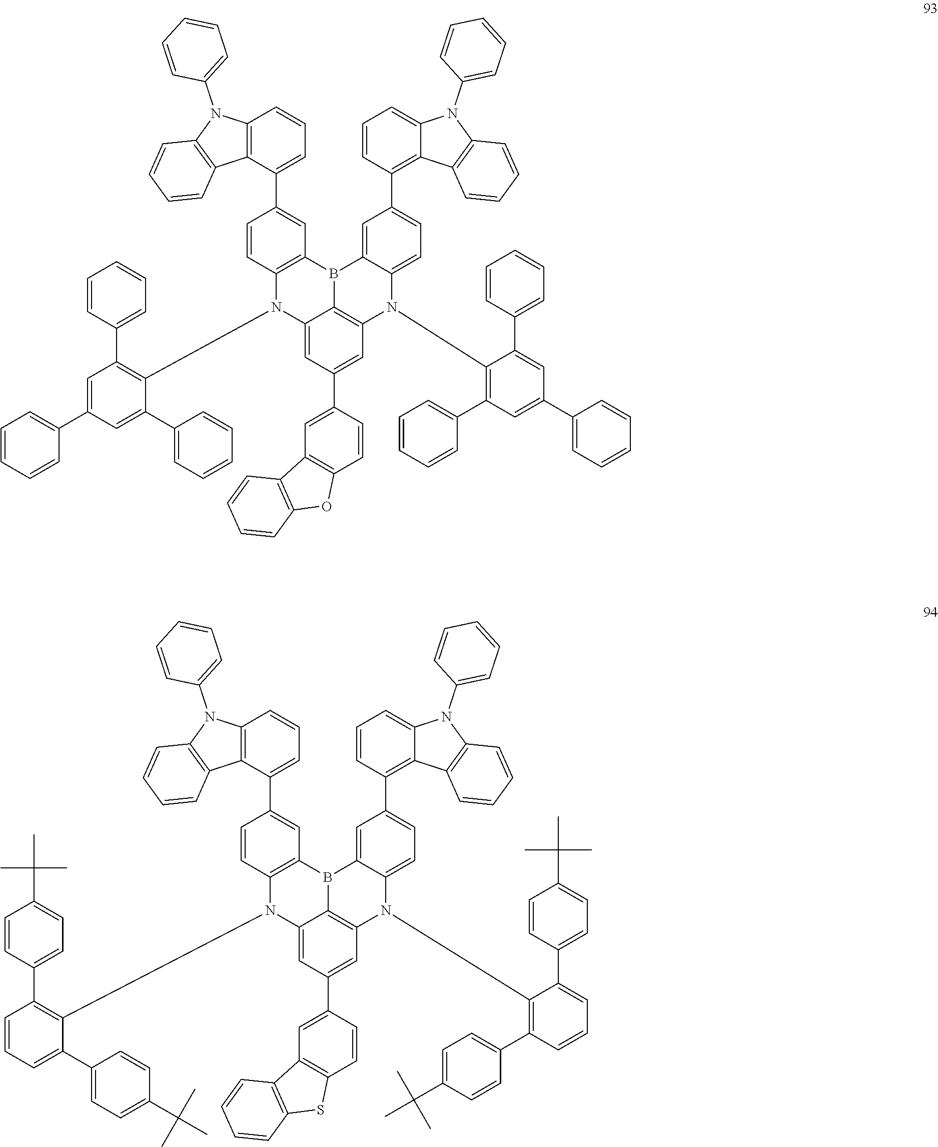 [SMILES: c1ccc(-c2cc(-c3ccccc3)c(N3c4ccc(-c5cccc6c5c5ccccc5n6-c5ccccc5)cc4B4c5cc(-c6cccc7c6c6ccccc6n7-c6ccccc6)ccc5N(c5c(-c6ccccc6)cc(-c6ccccc6)cc5-c5ccccc5)c5cc(-c6ccc7oc8ccccc8c7c6)cc3c54)c(-c3ccccc3)c2)cc1 ; CC(C)(C)c1ccc(-c2cccc(-c3ccc(C(C)(C)C)cc3)c2N2c3ccc(-c4cccc5c4c4ccccc4n5-c4ccccc4)cc3B3c4cc(-c5cccc6c5c5ccccc5n6-c5ccccc5)ccc4N(c4c(-c5ccc(C(C)(C)C)cc5)cccc4-c4ccc(C(C)(C)C)cc4)c4cc(-c5ccc6sc7ccccc7c6c5)cc2c43)cc1]

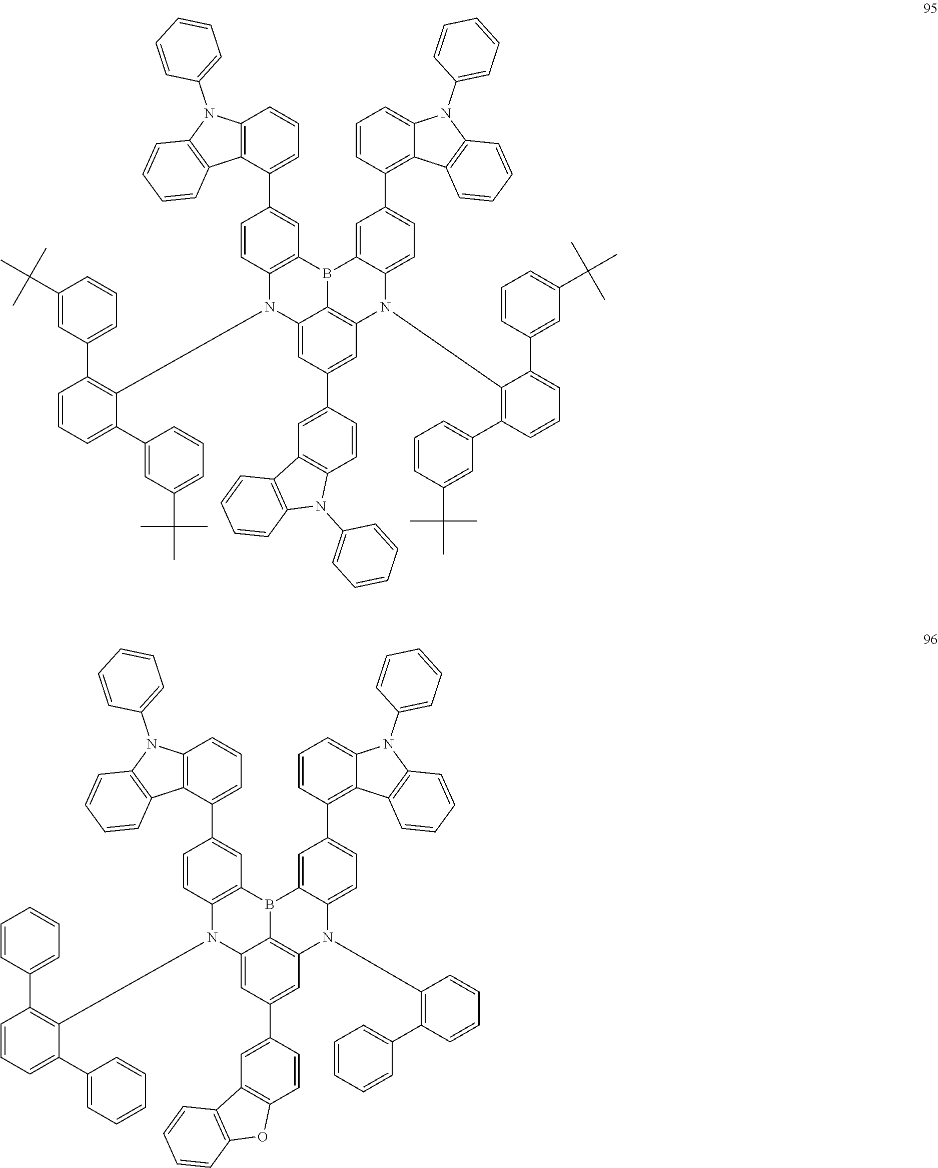 [SMILES: CC(C)(C)c1cccc(-c2cccc(-c3cccc(C(C)(C)C)c3)c2N2c3ccc(-c4cccc5c4c4ccccc4n5-c4ccccc4)cc3B3c4cc(-c5cccc6c5c5ccccc5n6-c5ccccc5)ccc4N(c4c(-c5cccc(C(C)(C)C)c5)cccc4-c4cccc(C(C)(C)C)c4)c4cc(-c5ccc6c(c5)c5ccccc5n6-c5ccccc5)cc2c43)c1 ; c1ccc(-c2ccccc2N2c3ccc(-c4cccc5c4c4ccccc4n5-c4ccccc4)cc3B3c4cc(-c5cccc6c5c5ccccc5n6-c5ccccc5)ccc4N(c4c(-c5ccccc5)cccc4-c4ccccc4)c4cc(-c5ccc6oc7ccccc7c6c5)cc2c43)cc1]

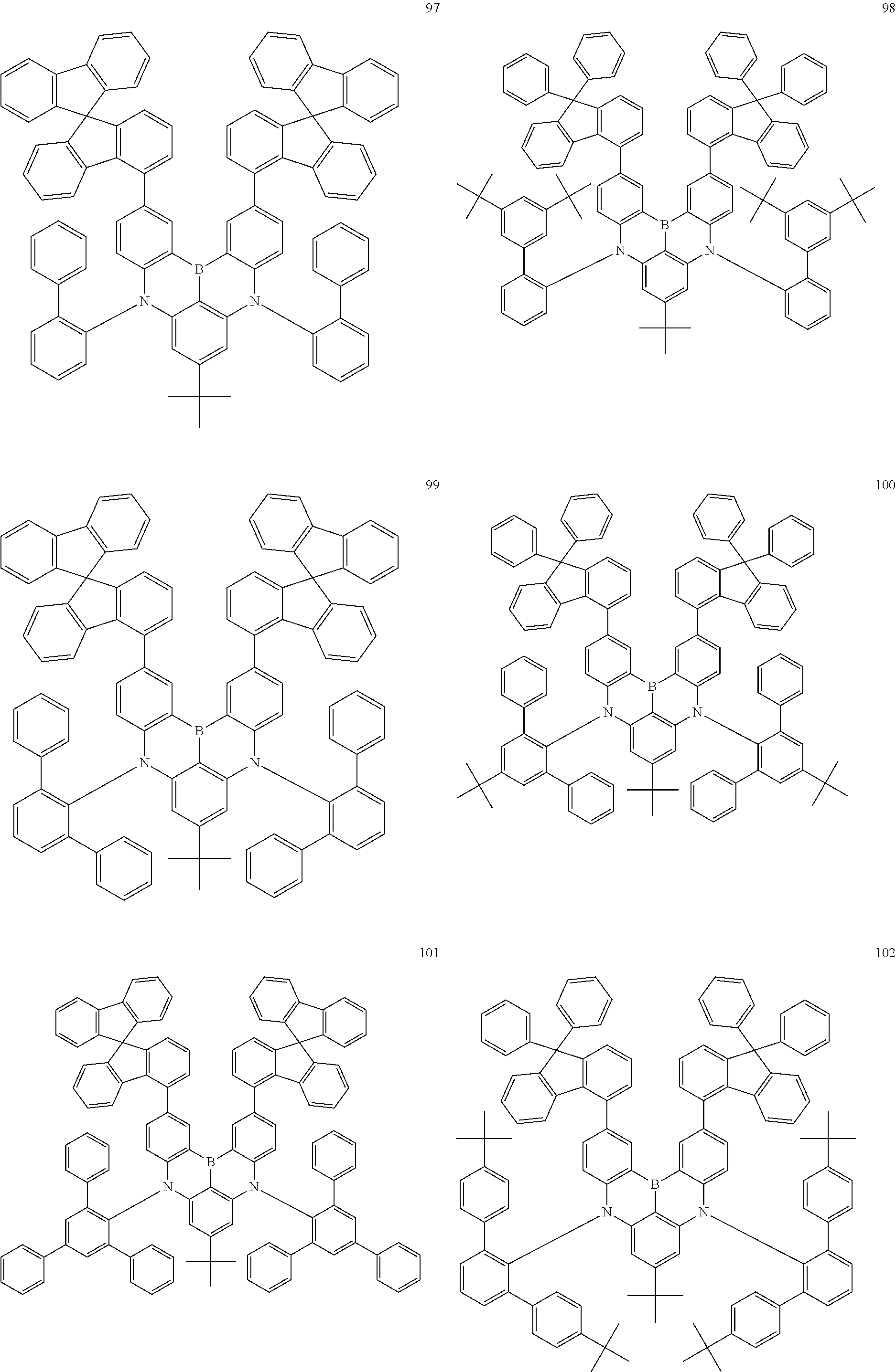

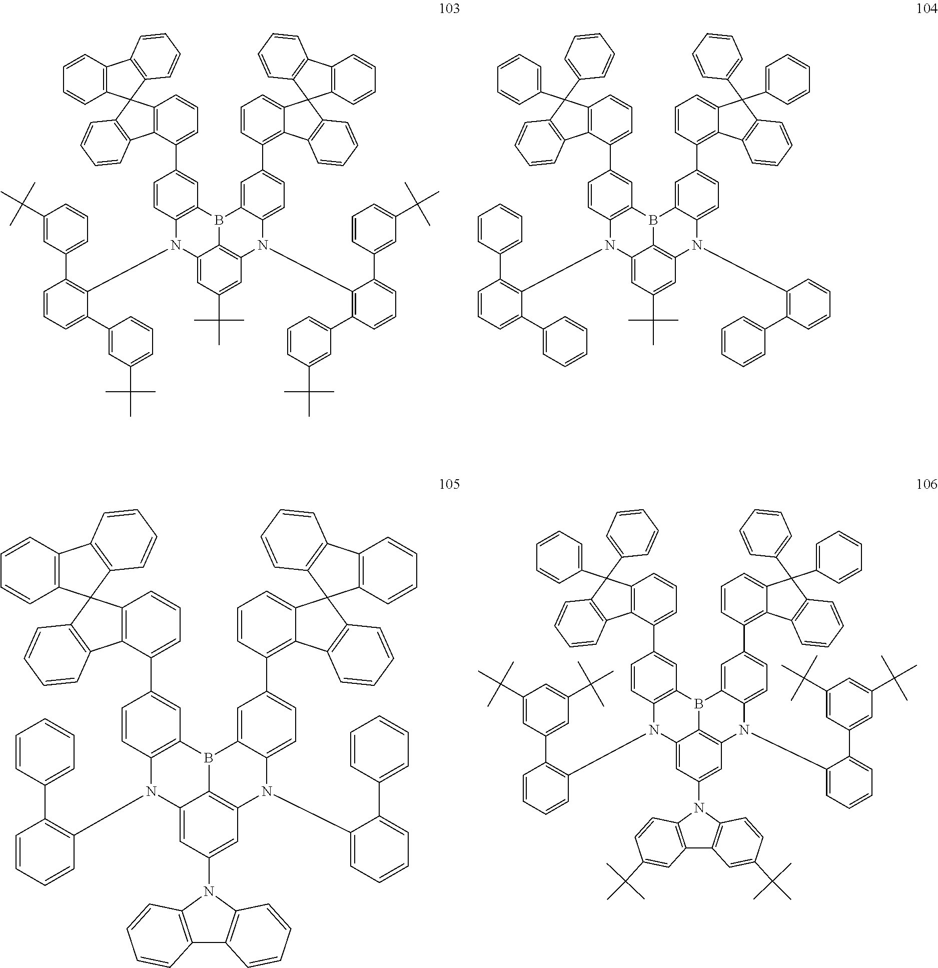

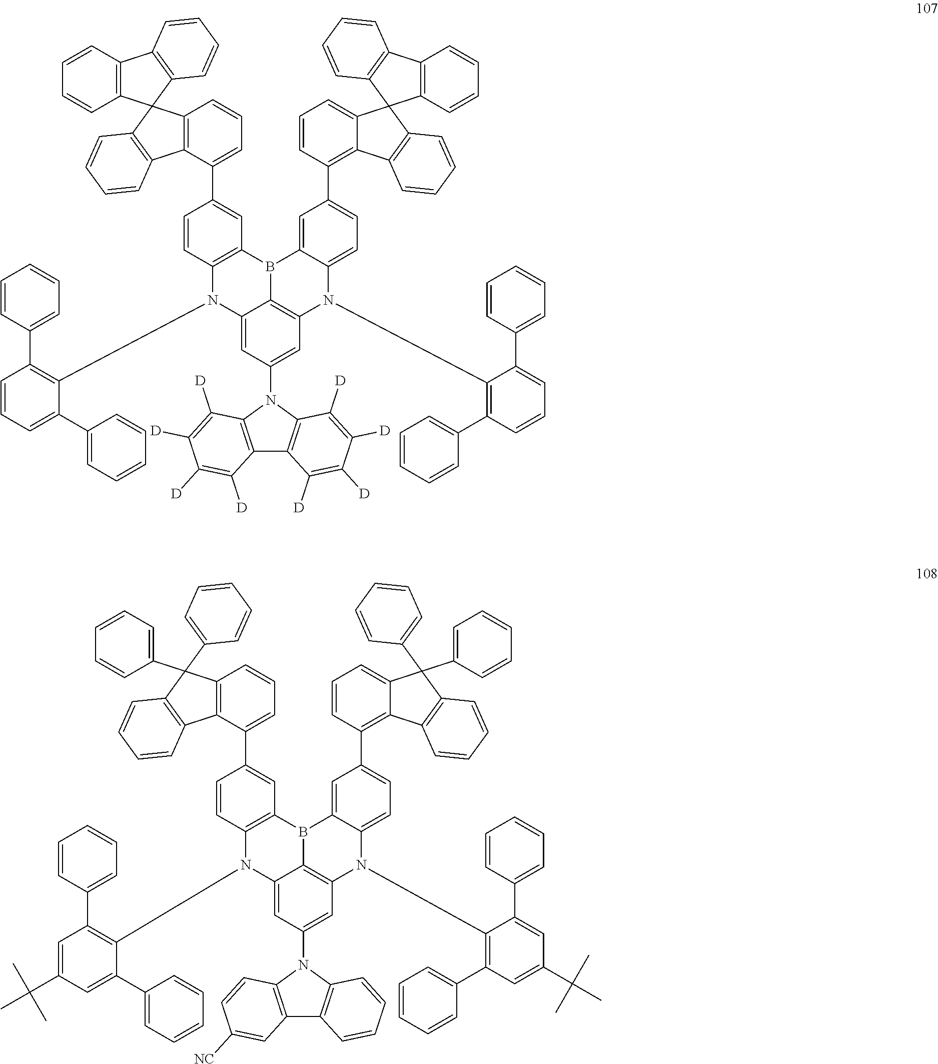 [SMILES: [2H]c1c([2H])c([2H])c2c(c1[2H])c1c([2H])c([2H])c([2H])c([2H])c1n2-c1cc2c3c(c1)N(c1c(-c4ccccc4)cccc1-c1ccccc1)c1ccc(-c4cccc5c4-c4ccccc4C54c5ccccc5-c5ccccc54)cc1B3c1cc(-c3cccc4c3-c3ccccc3C43c4ccccc4-c4ccccc43)ccc1N2c1c(-c2ccccc2)cccc1-c1ccccc1 ; CC(C)(C)c1cc(-c2ccccc2)c(N2c3ccc(-c4cccc5c4-c4ccccc4C5(c4ccccc4)c4ccccc4)cc3B3c4cc(-c5cccc6c5-c5ccccc5C6(c5ccccc5)c5ccccc5)ccc4N(c4c(-c5ccccc5)cc(C(C)(C)C)cc4-c4ccccc4)c4cc(-n5c6ccccc6c6cc(C#N)ccc65)cc2c43)c(-c2ccccc2)c1]

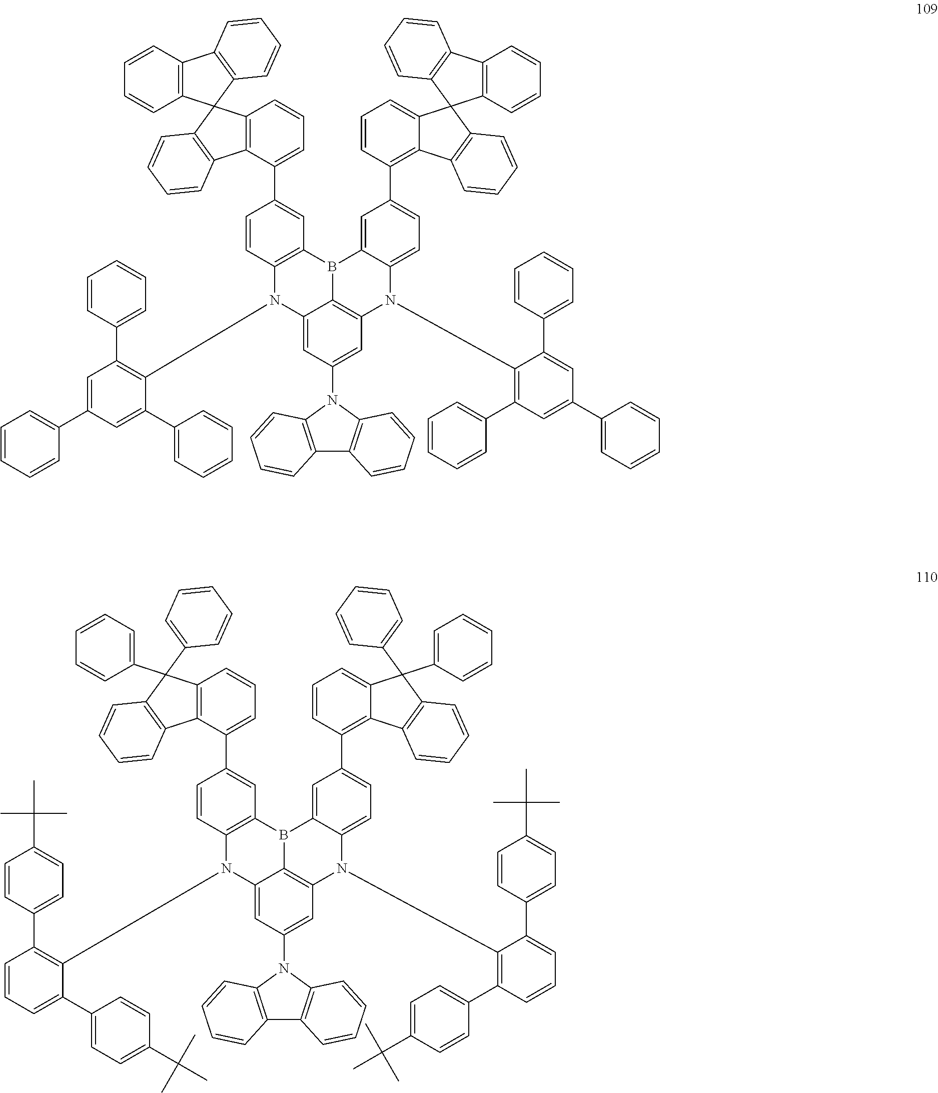 [SMILES: c1ccc(-c2cc(-c3ccccc3)c(N3c4ccc(-c5cccc6c5-c5ccccc5C65c6ccccc6-c6ccccc65)cc4B4c5cc(-c6cccc7c6-c6ccccc6C76c7ccccc7-c7ccccc76)ccc5N(c5c(-c6ccccc6)cc(-c6ccccc6)cc5-c5ccccc5)c5cc(-n6c7ccccc7c7ccccc76)cc3c54)c(-c3ccccc3)c2)cc1 ; CC(C)(C)c1ccc(-c2cccc(-c3ccc(C(C)(C)C)cc3)c2N2c3ccc(-c4cccc5c4-c4ccccc4C5(c4ccccc4)c4ccccc4)cc3B3c4cc(-c5cccc6c5-c5ccccc5C6(c5ccccc5)c5ccccc5)ccc4N(c4c(-c5ccc(C(C)(C)C)cc5)cccc4-c4ccc(C(C)(C)C)cc4)c4cc(-n5c6ccccc6c6ccccc65)cc2c43)cc1]

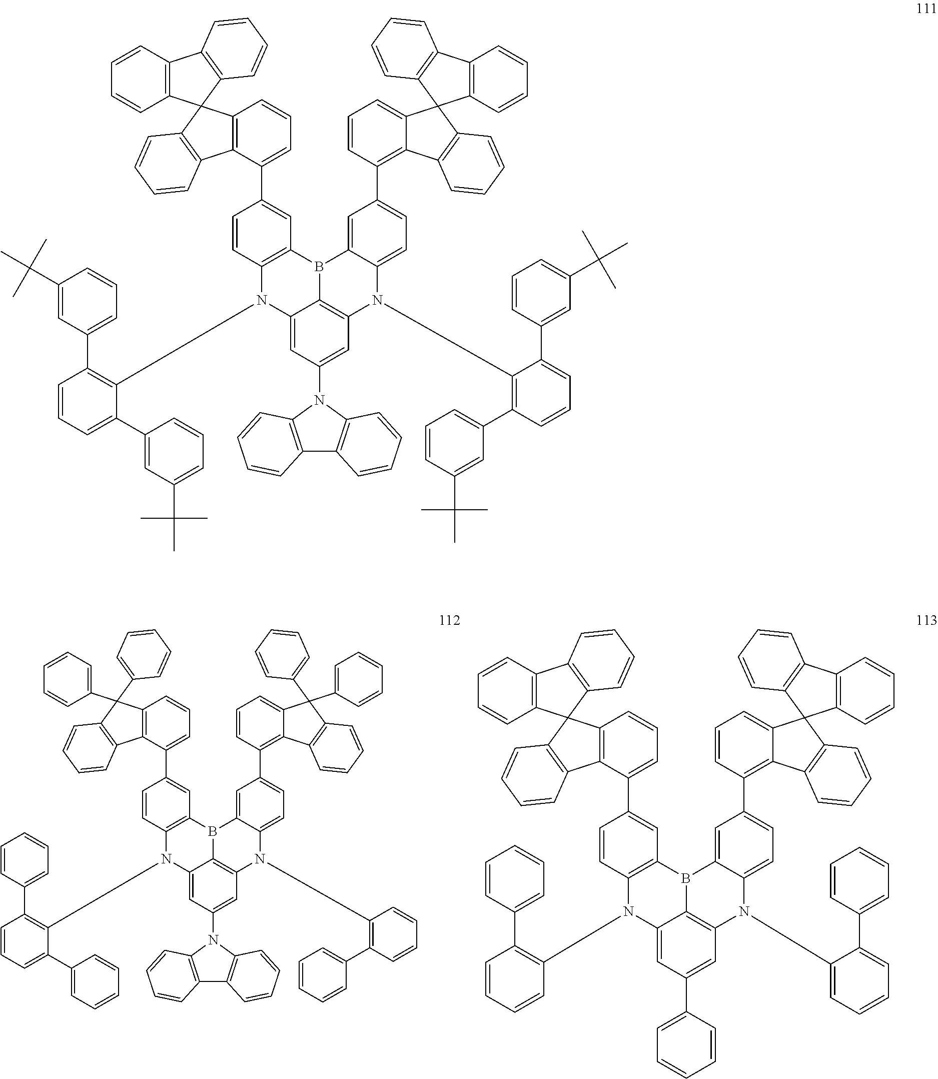

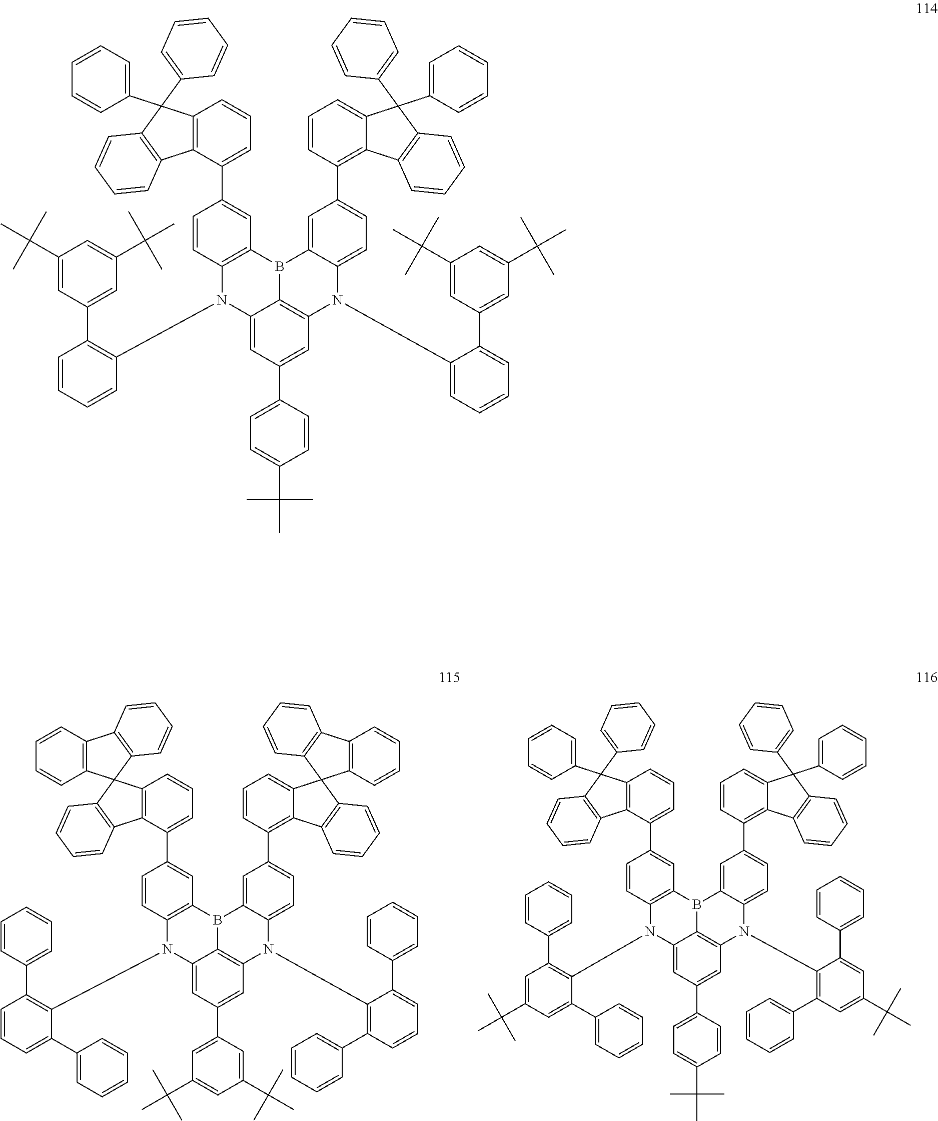

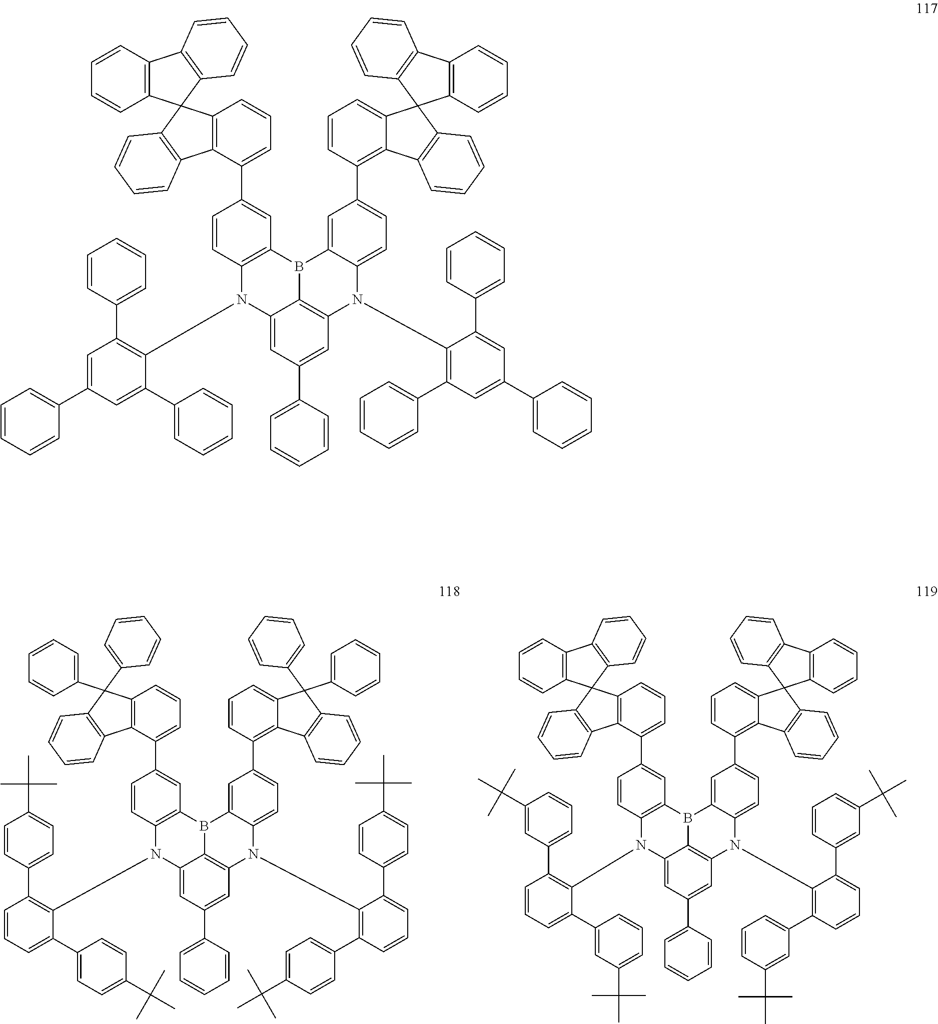

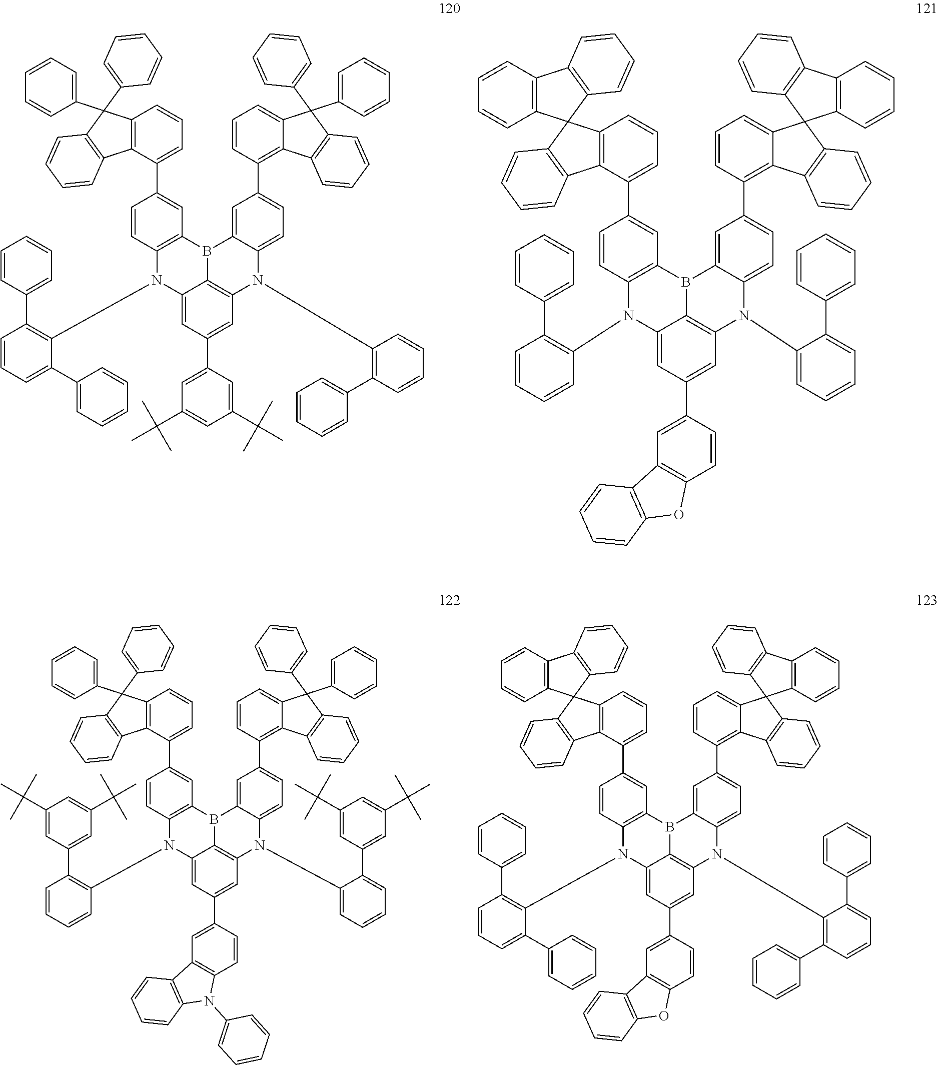

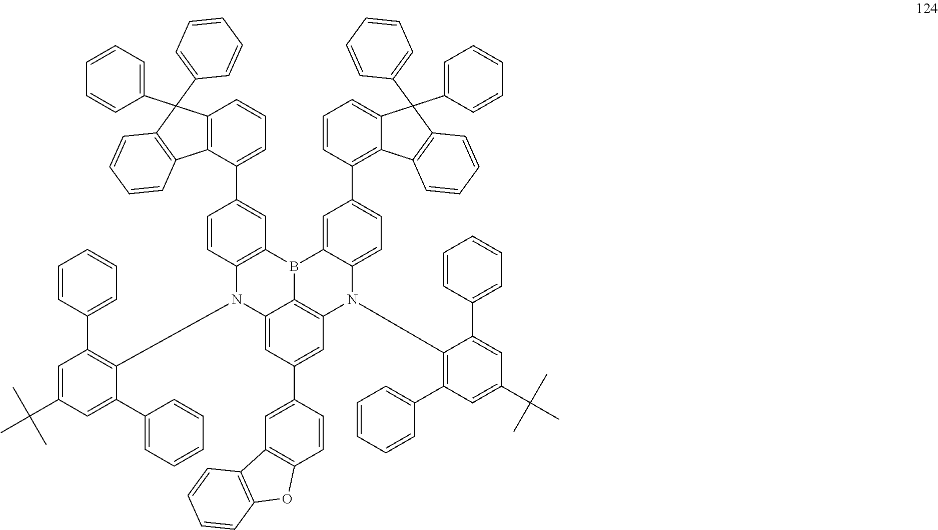 [SMILES: CC(C)(C)c1cc(-c2ccccc2)c(N2c3ccc(-c4cccc5c4-c4ccccc4C5(c4ccccc4)c4ccccc4)cc3B3c4cc(-c5cccc6c5-c5ccccc5C6(c5ccccc5)c5ccccc5)ccc4N(c4c(-c5ccccc5)cc(C(C)(C)C)cc4-c4ccccc4)c4cc(-c5ccc6oc7ccccc7c6c5)cc2c43)c(-c2ccccc2)c1]

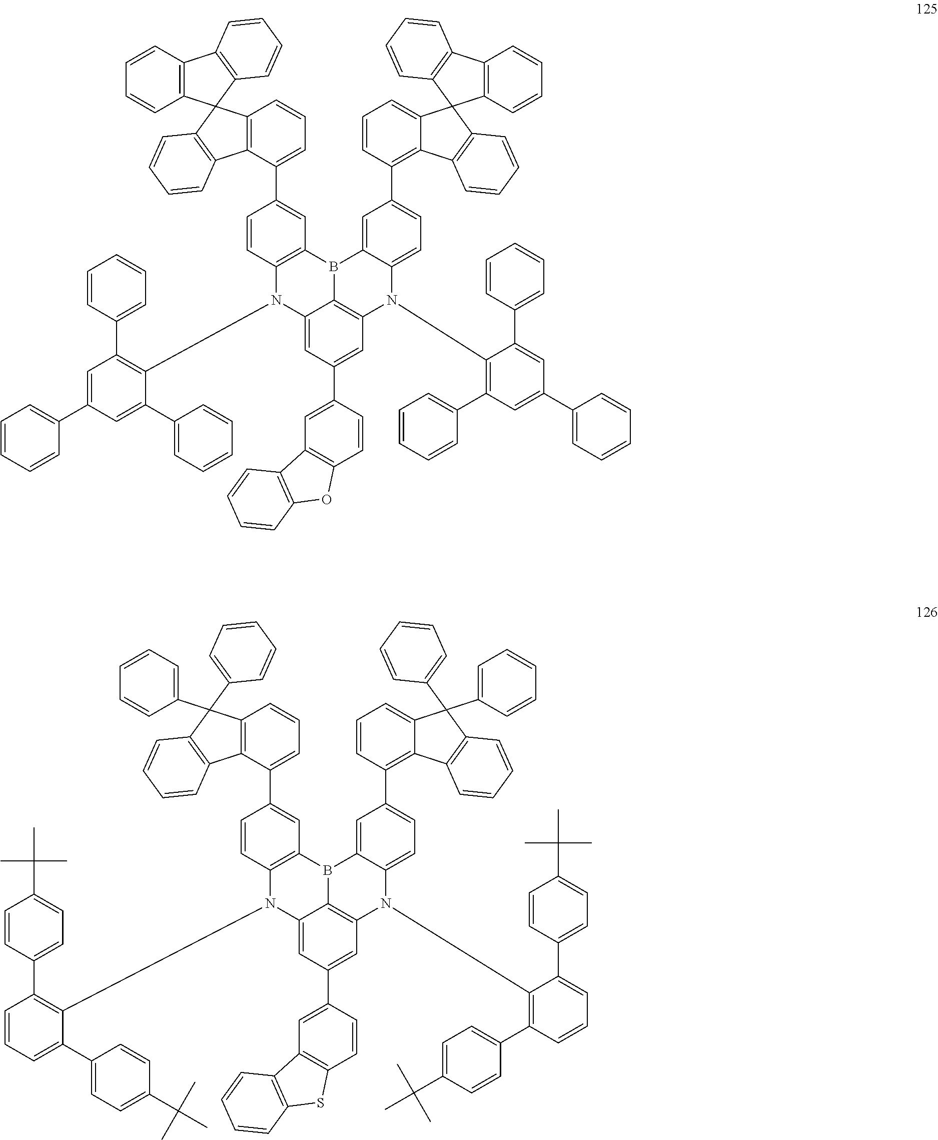 [SMILES: c1ccc(-c2cc(-c3ccccc3)c(N3c4ccc(-c5cccc6c5-c5ccccc5C65c6ccccc6-c6ccccc65)cc4B4c5cc(-c6cccc7c6-c6ccccc6C76c7ccccc7-c7ccccc76)ccc5N(c5c(-c6ccccc6)cc(-c6ccccc6)cc5-c5ccccc5)c5cc(-c6ccc7oc8ccccc8c7c6)cc3c54)c(-c3ccccc3)c2)cc1 ; CC(C)(C)c1ccc(-c2cccc(-c3ccc(C(C)(C)C)cc3)c2N2c3ccc(-c4cccc5c4-c4ccccc4C5(c4ccccc4)c4ccccc4)cc3B3c4cc(-c5cccc6c5-c5ccccc5C6(c5ccccc5)c5ccccc5)ccc4N(c4c(-c5ccc(C(C)(C)C)cc5)cccc4-c4ccc(C(C)(C)C)cc4)c4cc(-c5ccc6sc7ccccc7c6c5)cc2c43)cc1]

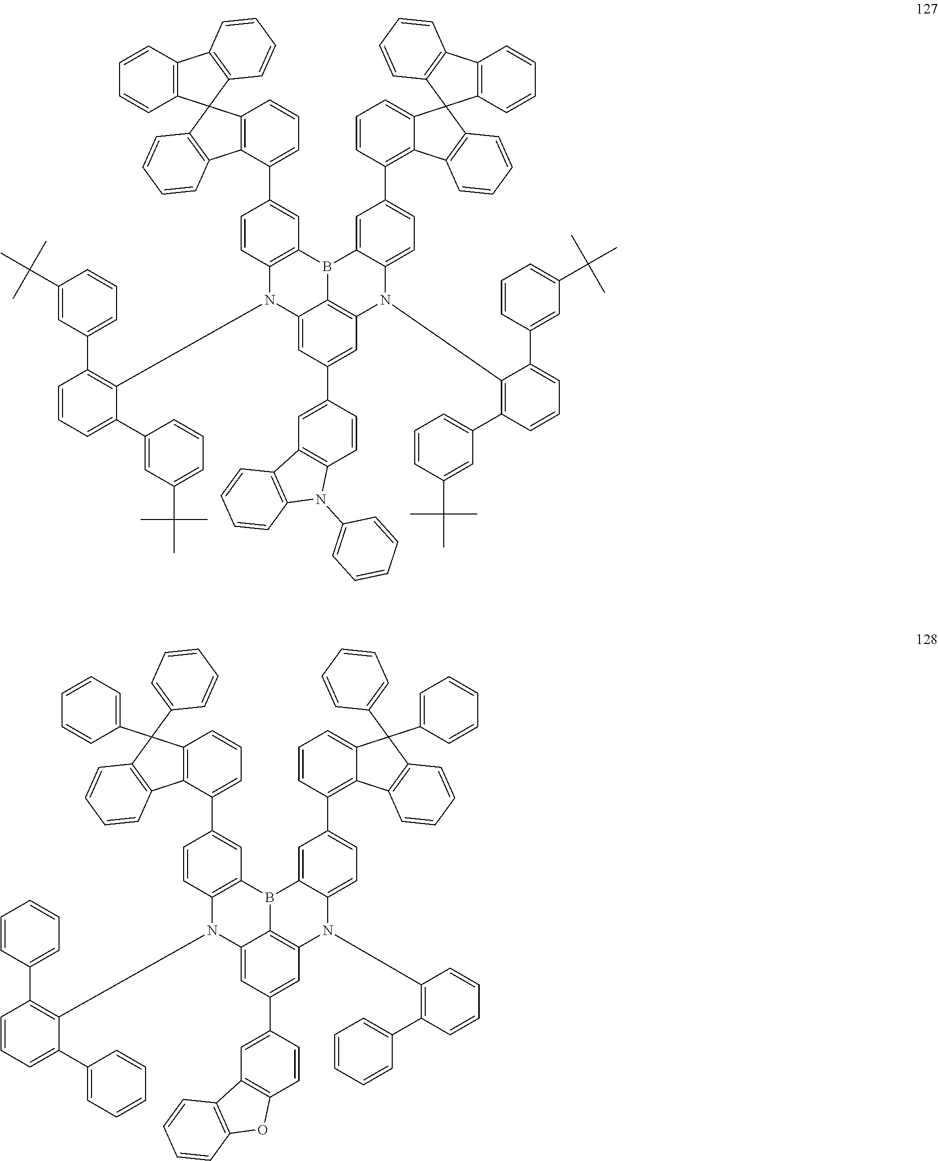 [SMILES: CC(C)(C)c1cccc(-c2cccc(-c3cccc(C(C)(C)C)c3)c2N2c3ccc(-c4cccc5c4-c4ccccc4C54c5ccccc5-c5ccccc54)cc3B3c4cc(-c5cccc6c5-c5ccccc5C65c6ccccc6-c6ccccc65)ccc4N(c4c(-c5cccc(C(C)(C)C)c5)cccc4-c4cccc(C(C)(C)C)c4)c4cc(-c5ccc6c(c5)c5ccccc5n6-c5ccccc5)cc2c43)c1 ; c1ccc(-c2ccccc2N2c3ccc(-c4cccc5c4-c4ccccc4C5(c4ccccc4)c4ccccc4)cc3B3c4cc(-c5cccc6c5-c5ccccc5C6(c5ccccc5)c5ccccc5)ccc4N(c4c(-c5ccccc5)cccc4-c4ccccc4)c4cc(-c5ccc6oc7ccccc7c6c5)cc2c43)cc1]

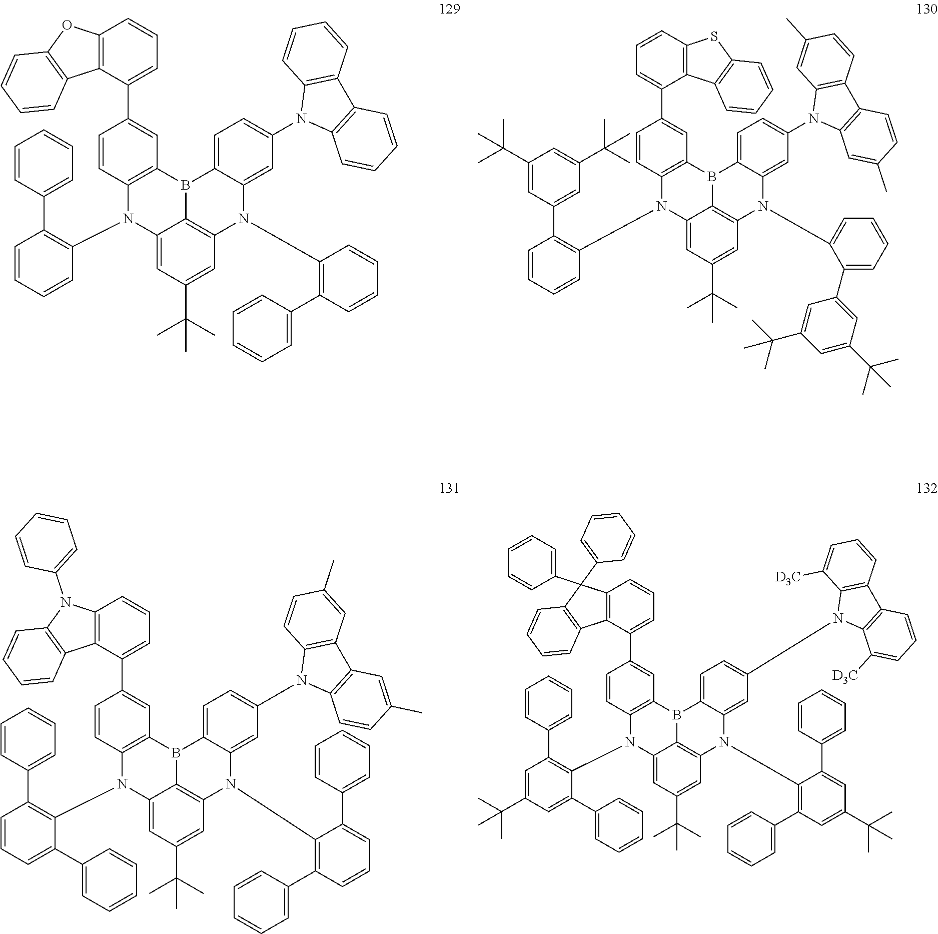

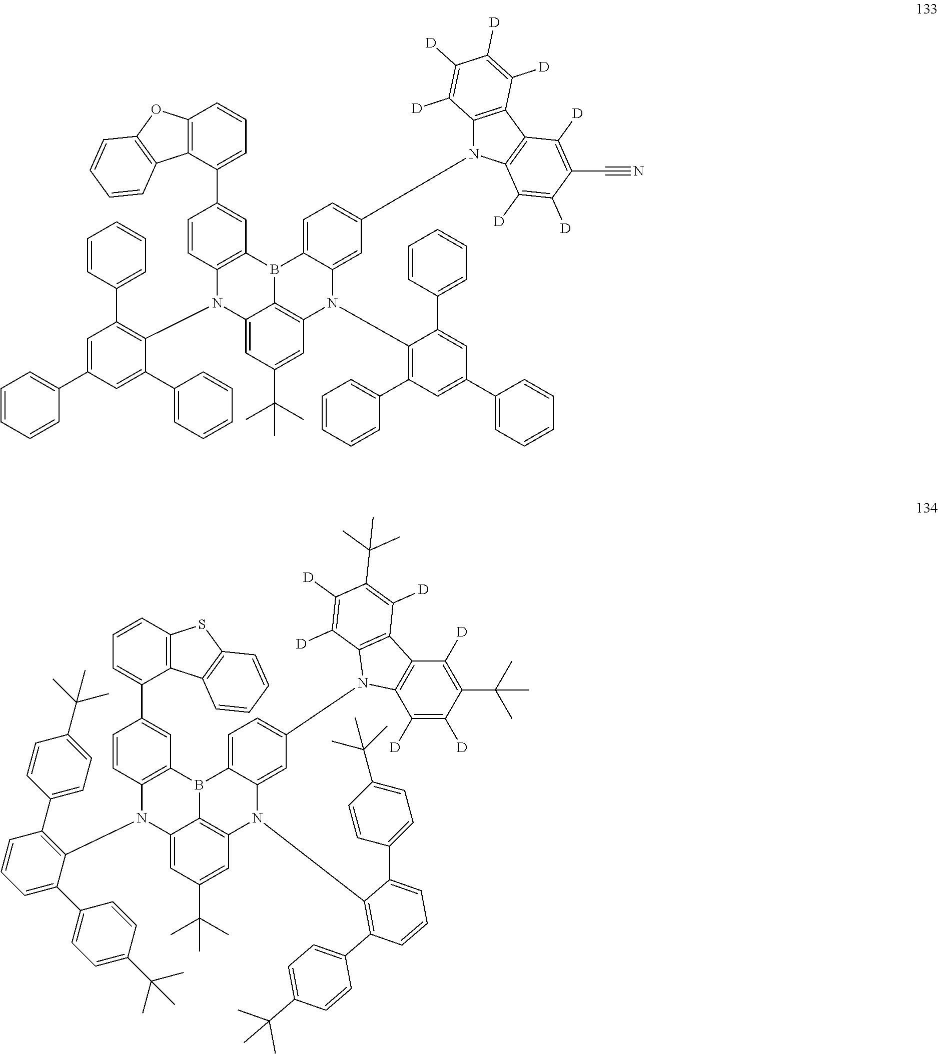 [SMILES: [2H]c1c([2H])c([2H])c2c(c1[2H])c1c([2H])c(C#N)c([2H])c([2H])c1n2-c1ccc2c(c1)N(c1c(-c3ccccc3)cc(-c3ccccc3)cc1-c1ccccc1)c1cc(C(C)(C)C)cc3c1B2c1cc(-c2cccc4oc5ccccc5c24)ccc1N3c1c(-c2ccccc2)cc(-c2ccccc2)cc1-c1ccccc1 ; [2H]c1c(C(C)(C)C)c([2H])c2c3c([2H])c(C(C)(C)C)c([2H])c([2H])c3n(-c3ccc4c(c3)N(c3c(-c5ccc(C(C)(C)C)cc5)cccc3-c3ccc(C(C)(C)C)cc3)c3cc(C(C)(C)C)cc5c3B4c3cc(-c4cccc6sc7ccccc7c46)ccc3N5c3c(-c4ccc(C(C)(C)C)cc4)cccc3-c3ccc(C(C)(C)C)cc3)c2c1[2H]]

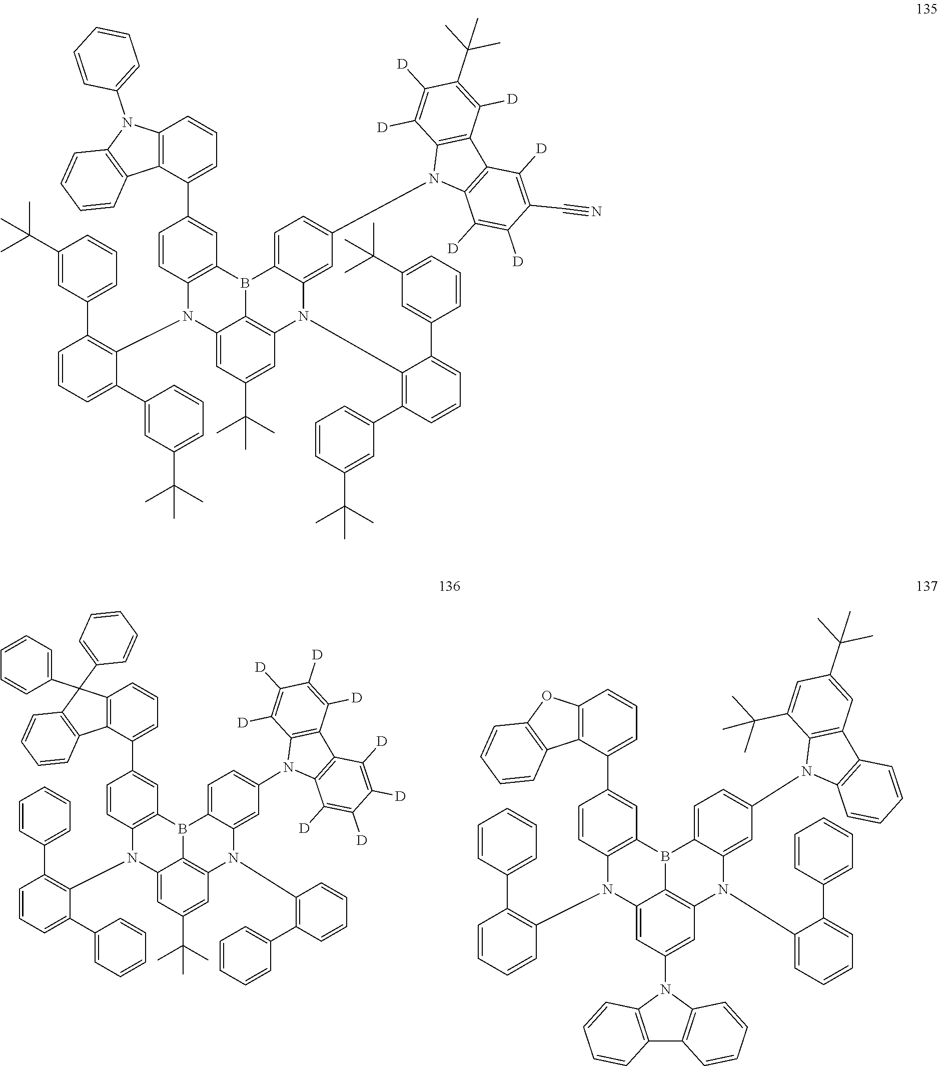

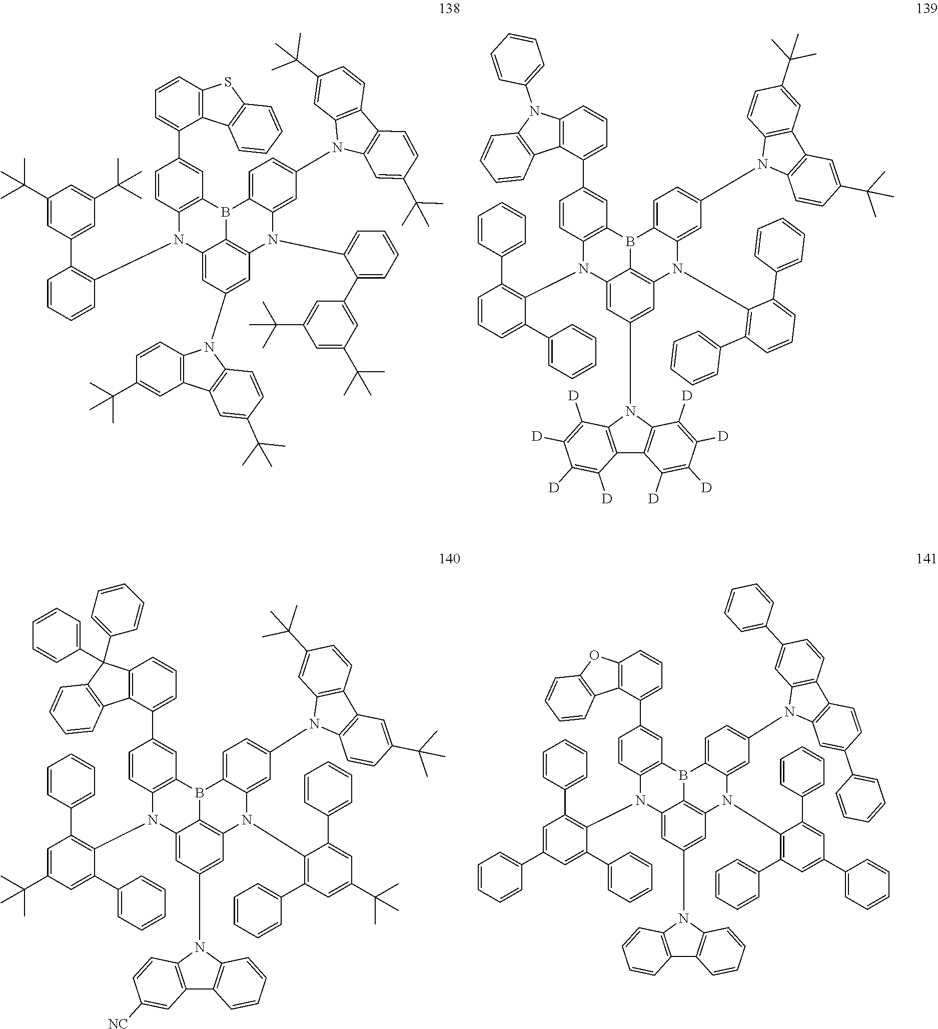

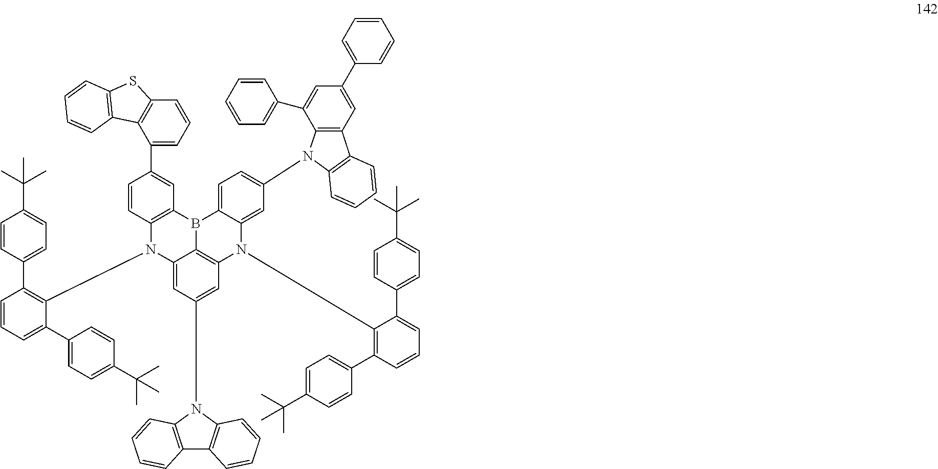 [SMILES: CC(C)(C)c1ccc(-c2cccc(-c3ccc(C(C)(C)C)cc3)c2N2c3ccc(-c4cccc5sc6ccccc6c45)cc3B3c4ccc(-n5c6ccccc6c6cc(-c7ccccc7)cc(-c7ccccc7)c65)cc4N(c4c(-c5ccc(C(C)(C)C)cc5)cccc4-c4ccc(C(C)(C)C)cc4)c4cc(-n5c6ccccc6c6ccccc65)cc2c43)cc1]

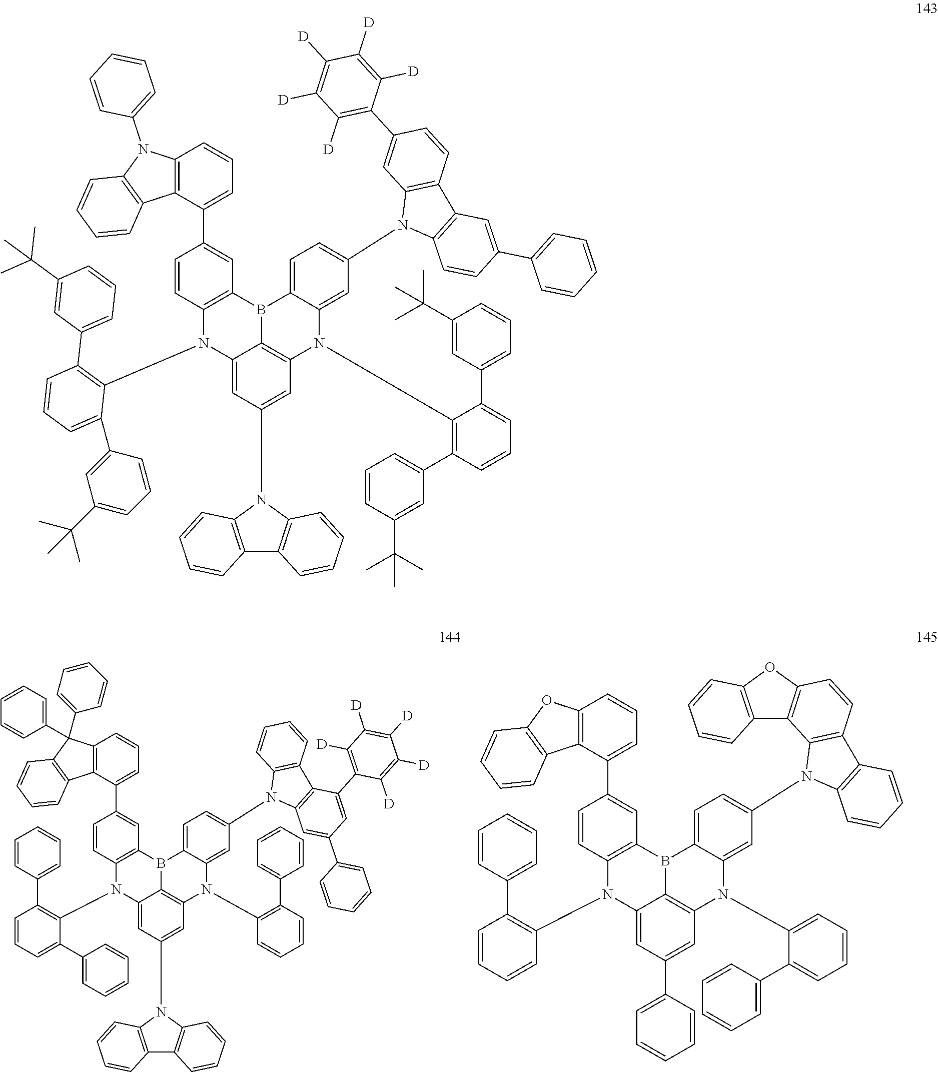

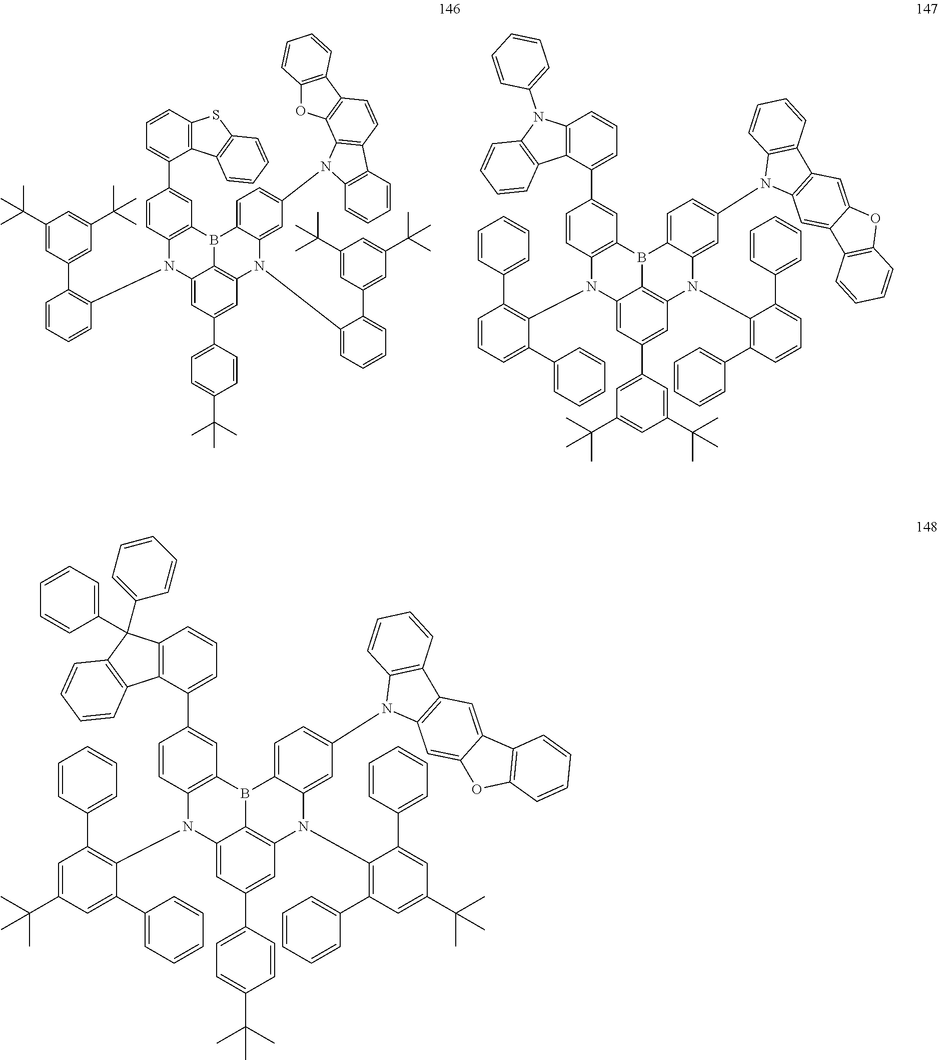

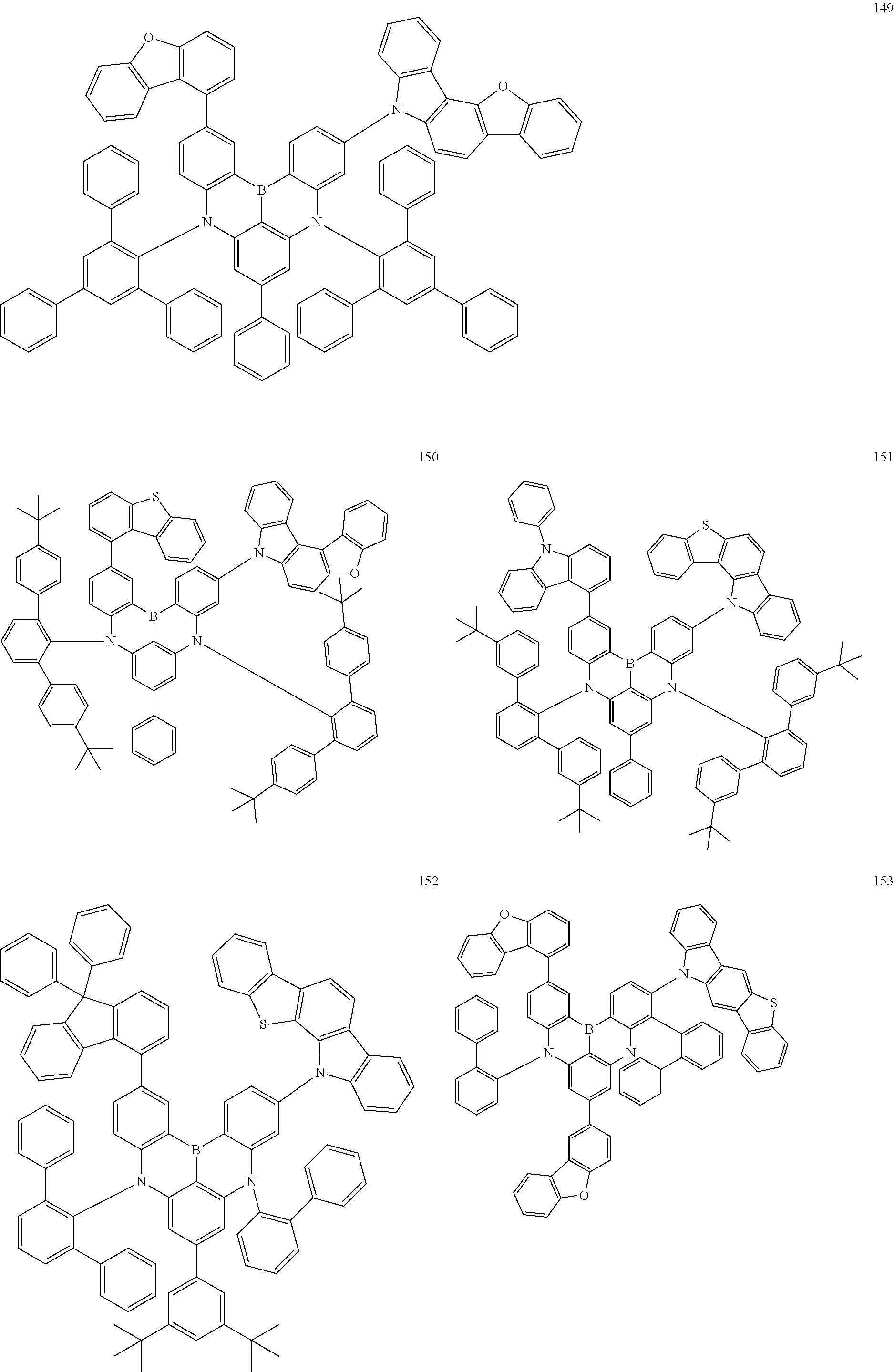

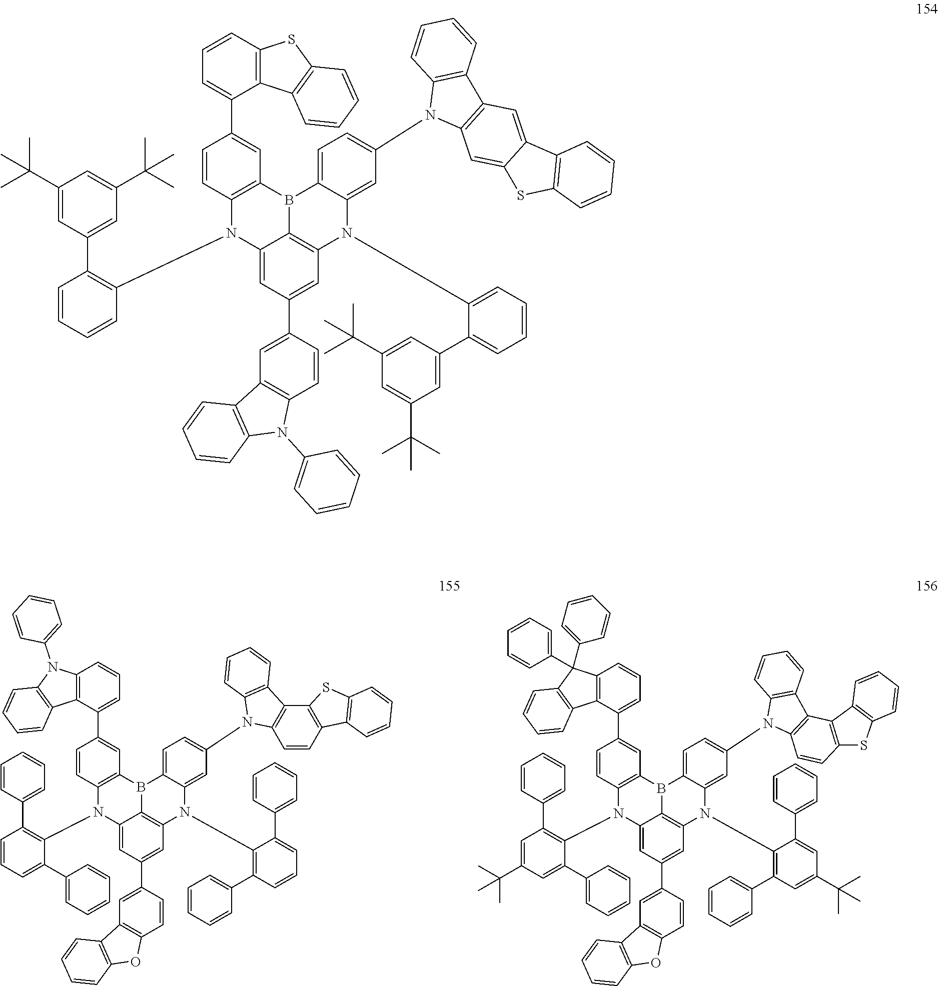

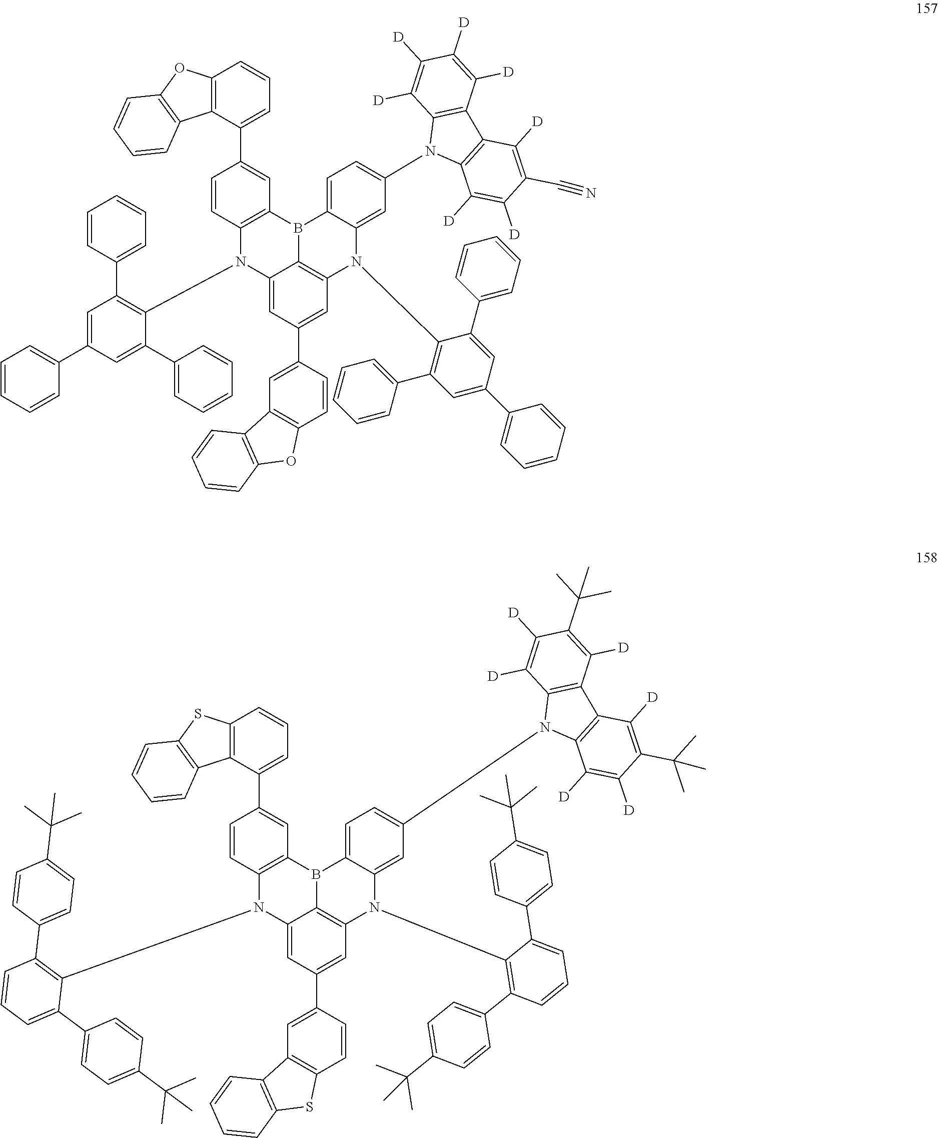 [SMILES: [2H]c1c([2H])c([2H])c2c(c1[2H])c1c([2H])c(C#N)c([2H])c([2H])c1n2-c1ccc2c(c1)N(c1c(-c3ccccc3)cc(-c3ccccc3)cc1-c1ccccc1)c1cc(-c3ccc4oc5ccccc5c4c3)cc3c1B2c1cc(-c2cccc4oc5ccccc5c24)ccc1N3c1c(-c2ccccc2)cc(-c2ccccc2)cc1-c1ccccc1 ; [2H]c1c(C(C)(C)C)c([2H])c2c3c([2H])c(C(C)(C)C)c([2H])c([2H])c3n(-c3ccc4c(c3)N(c3c(-c5ccc(C(C)(C)C)cc5)cccc3-c3ccc(C(C)(C)C)cc3)c3cc(-c5ccc6sc7ccccc7c6c5)cc5c3B4c3cc(-c4cccc6sc7ccccc7c46)ccc3N5c3c(-c4ccc(C(C)(C)C)cc4)cccc3-c3ccc(C(C)(C)C)cc3)c2c1[2H]]

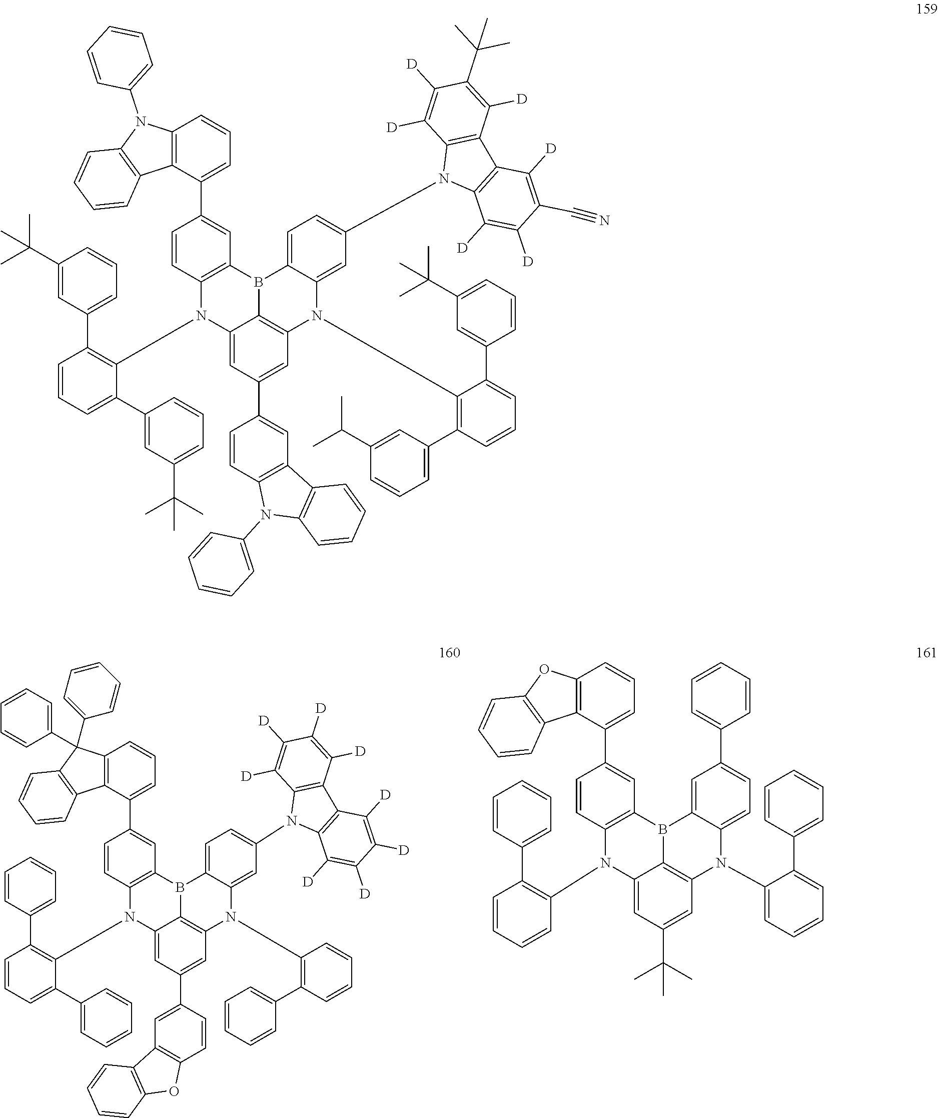

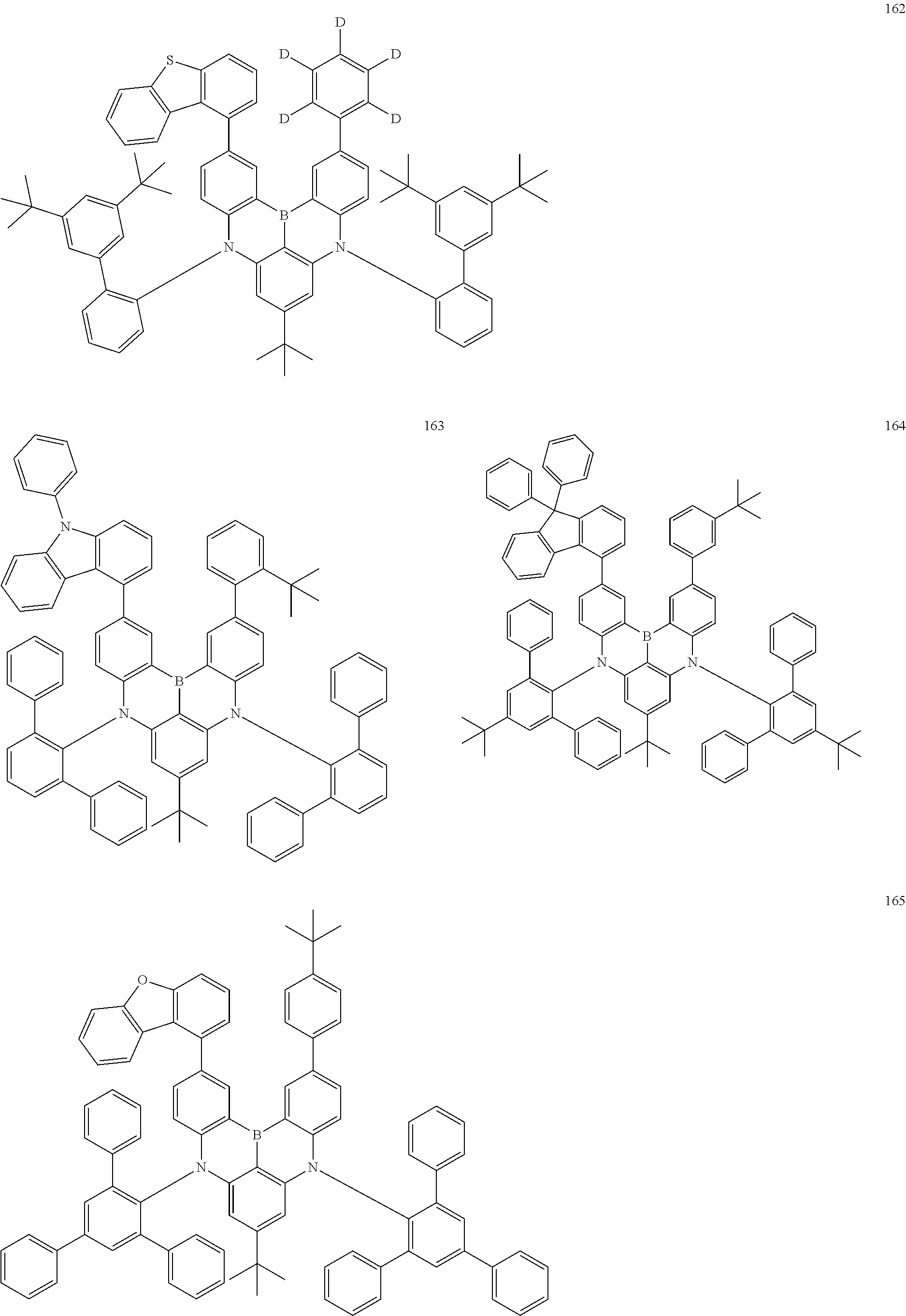

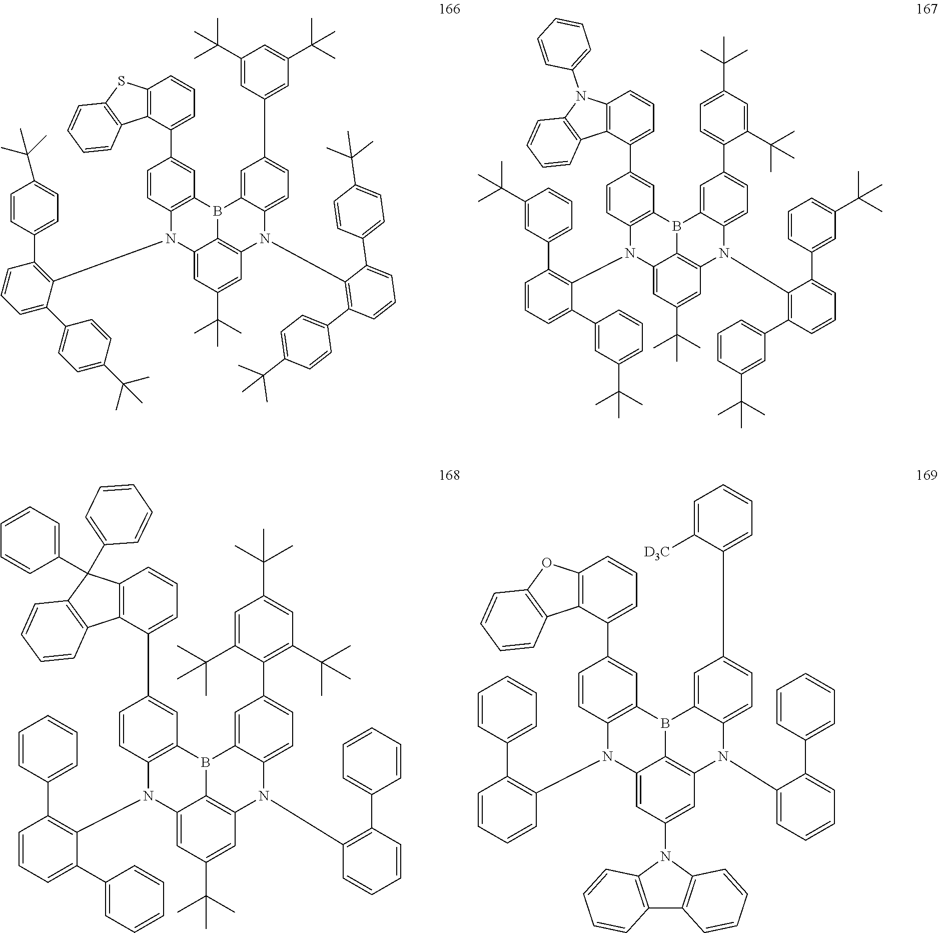

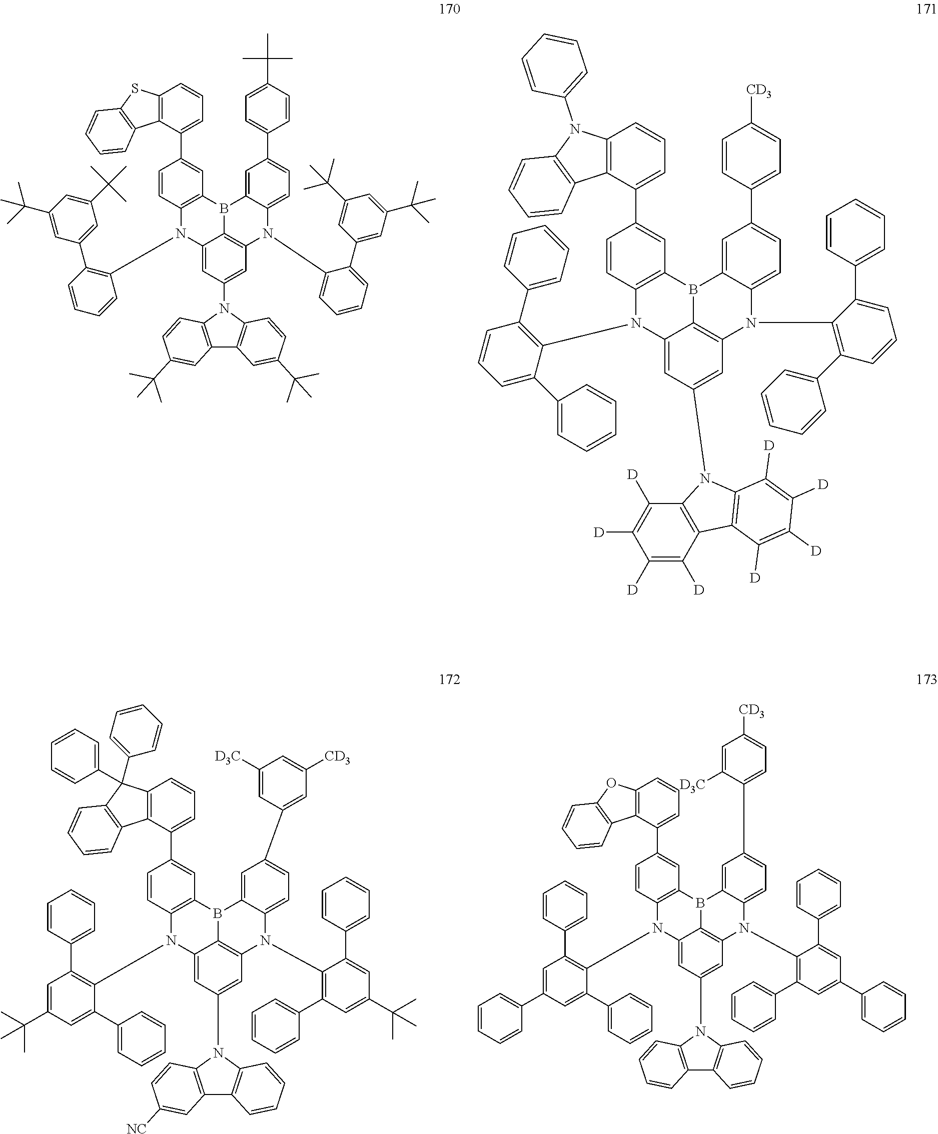

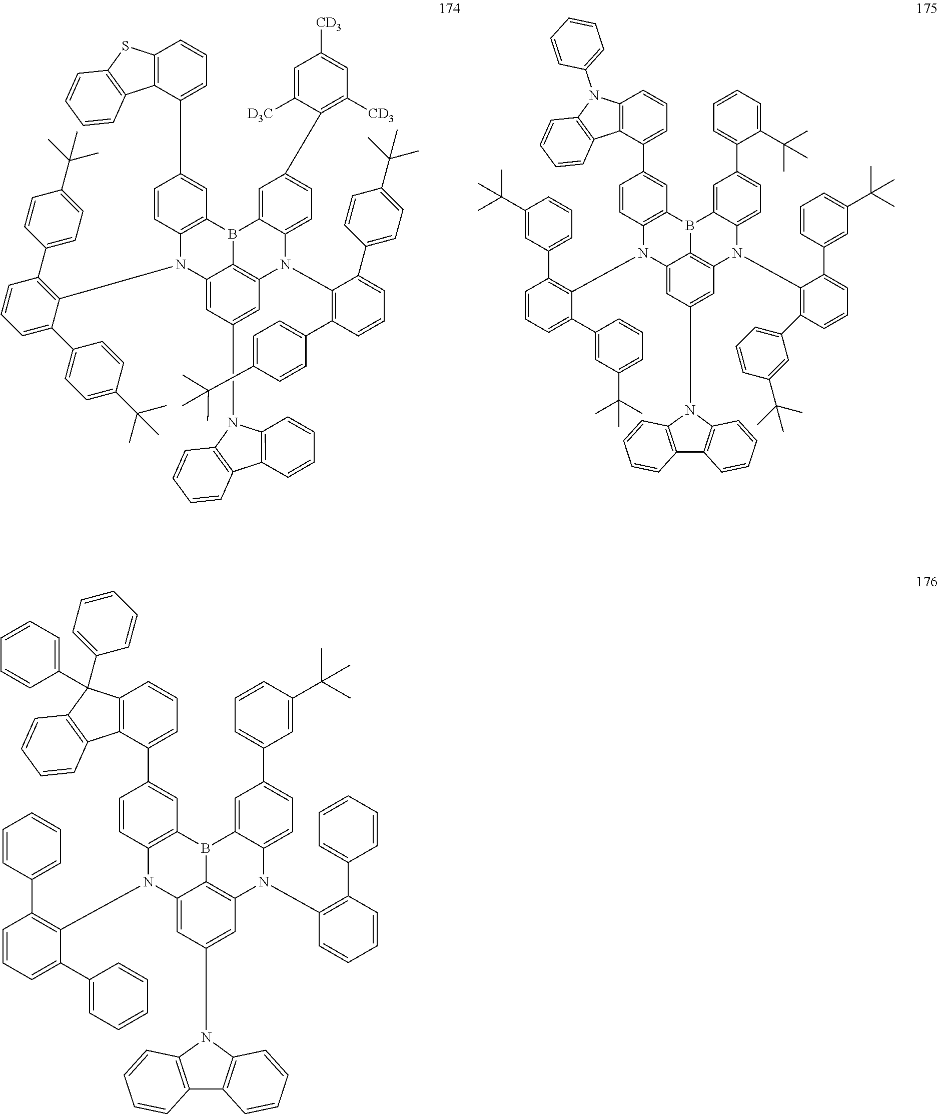

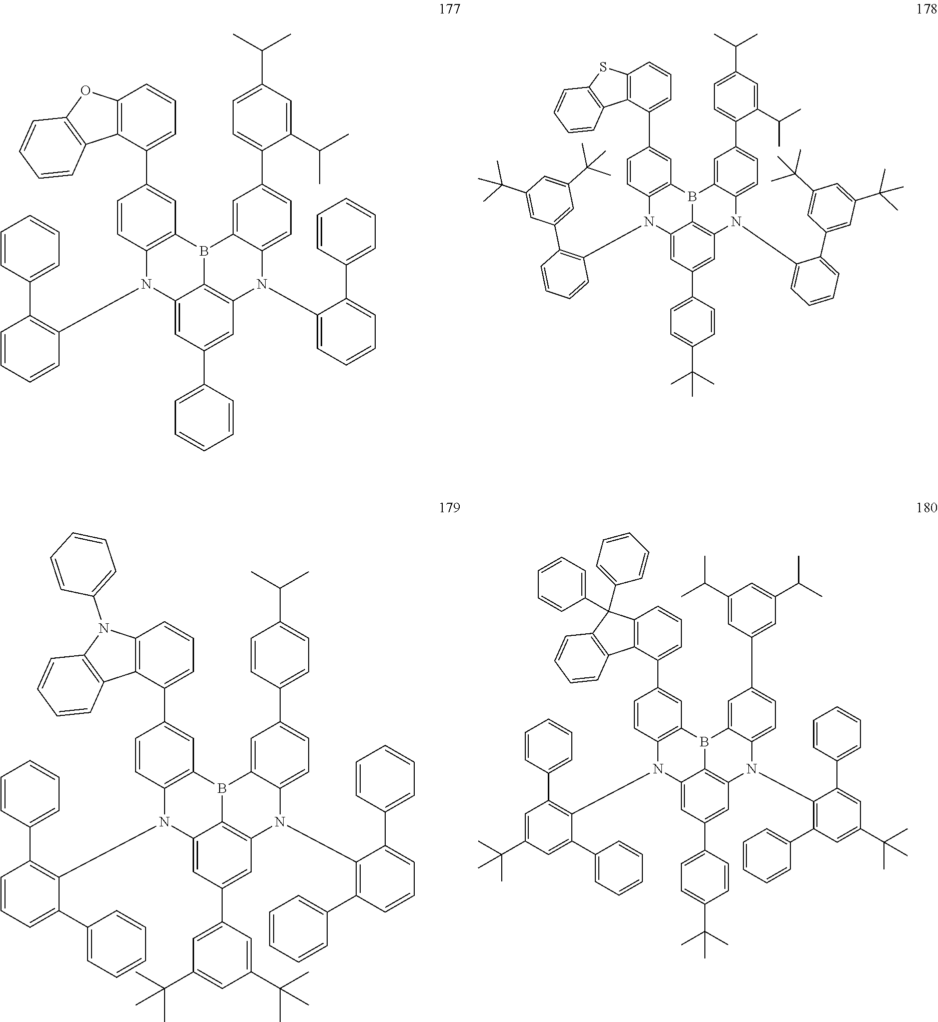

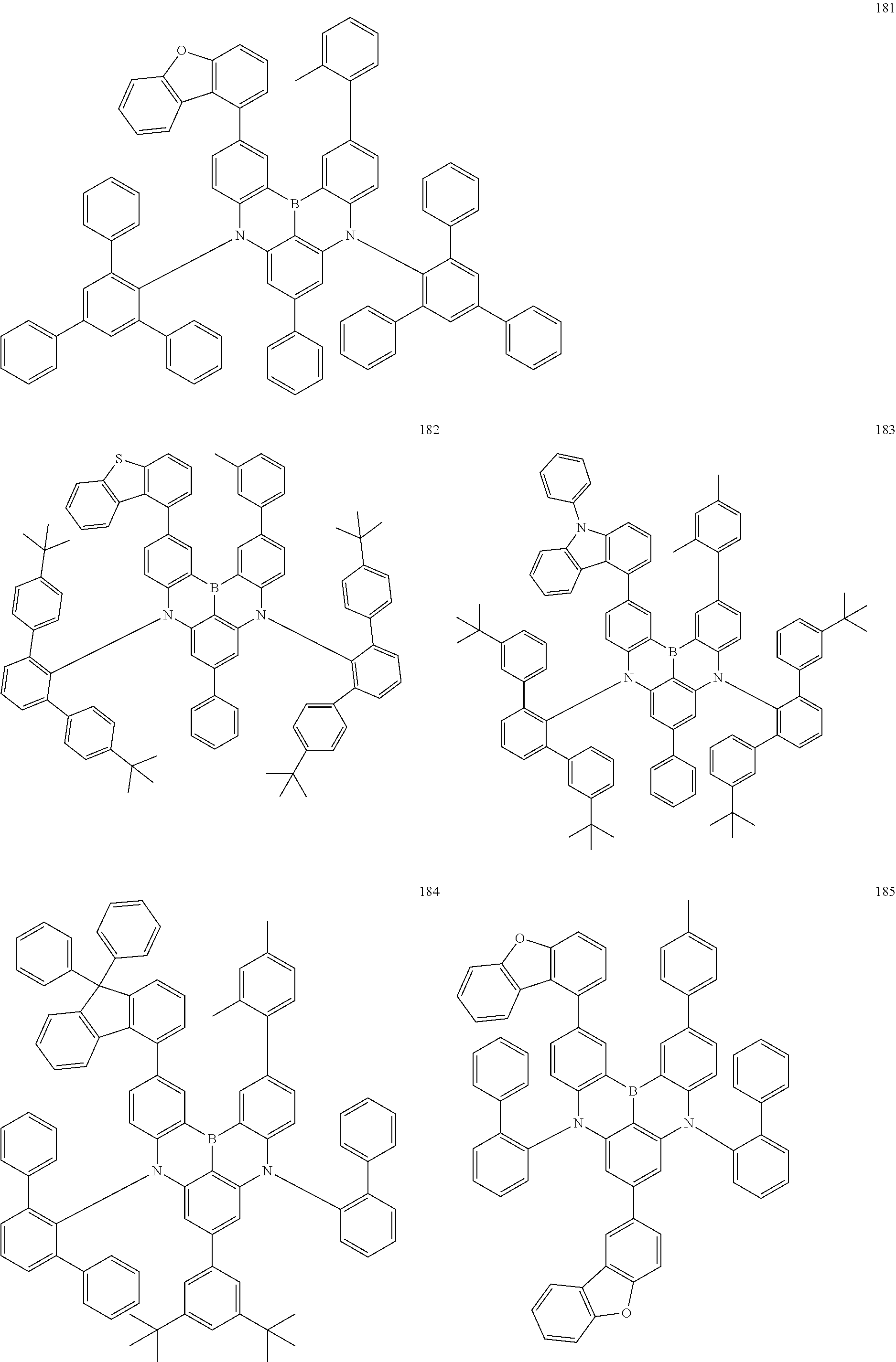

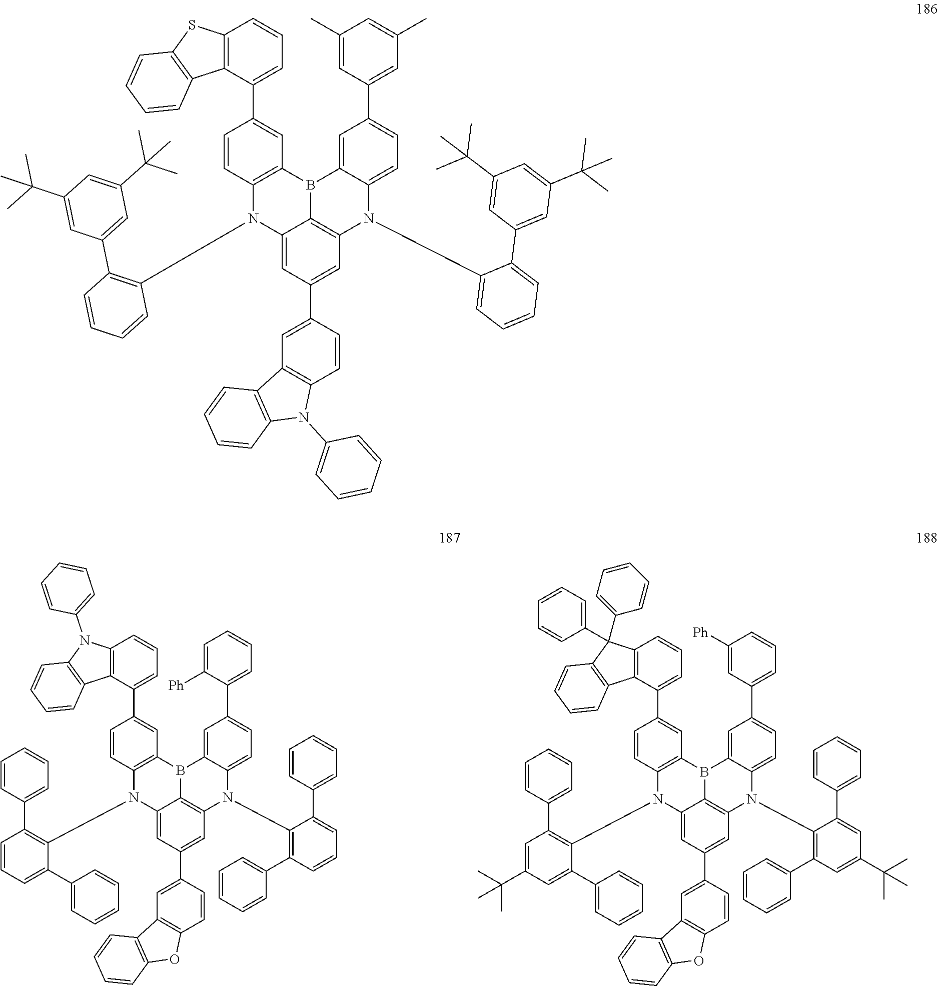

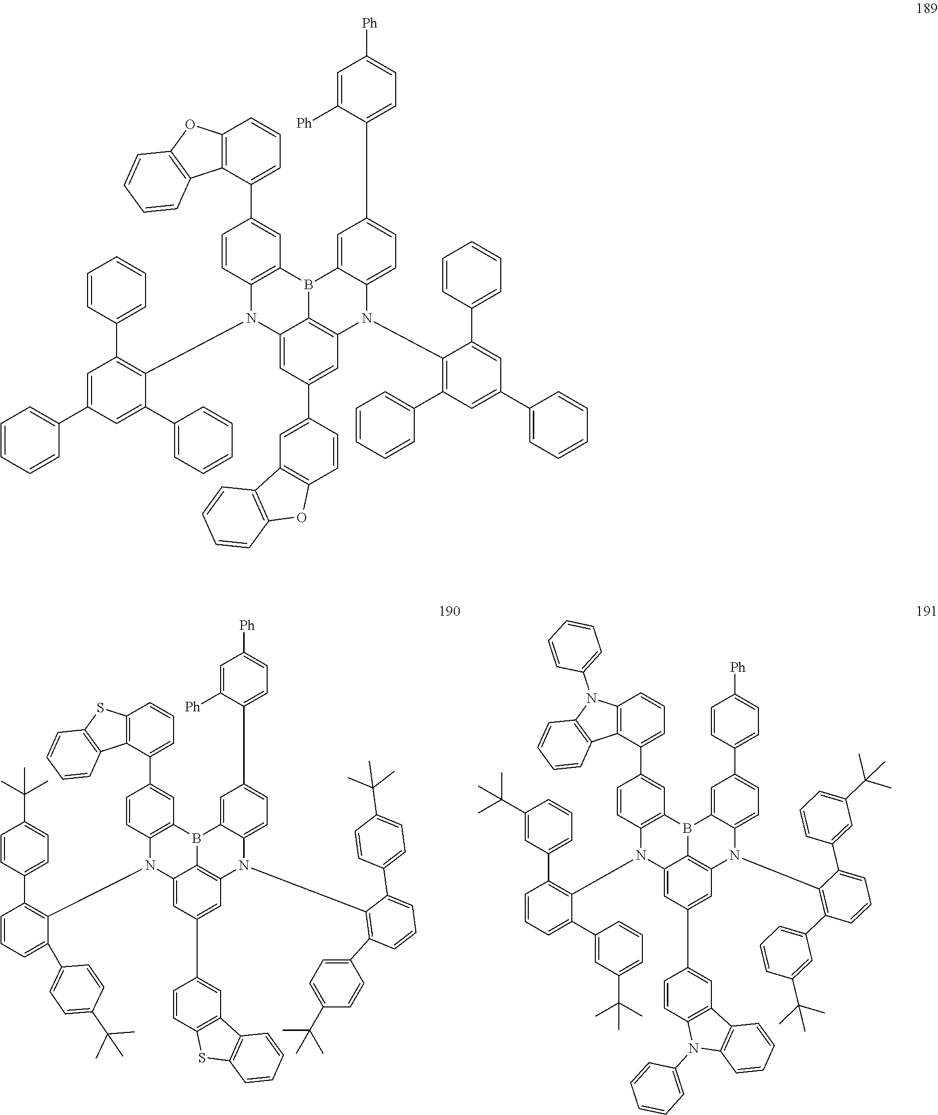

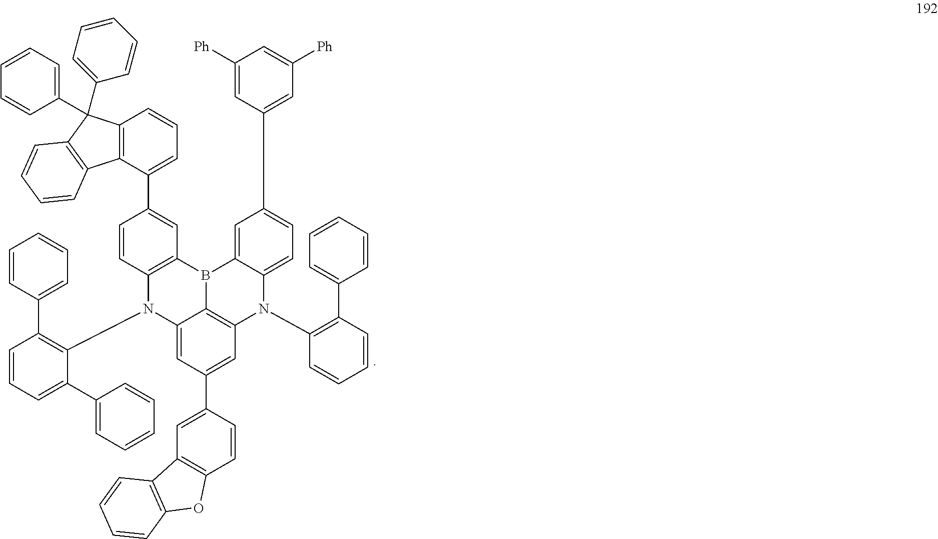 [SMILES: c1ccc(-c2cc(-c3ccccc3)cc(-c3ccc4c(c3)B3c5cc(-c6cccc7c6-c6ccccc6C7(c6ccccc6)c6ccccc6)ccc5N(c5c(-c6ccccc6)cccc5-c5ccccc5)c5cc(-c6ccc7oc8ccccc8c7c6)cc(c53)N4c3ccccc3-c3ccccc3)c2)cc1]

10. The light emitting device of claim 1, wherein the emission layer further comprises at least one of a second compound represented by Formula HT-1 or a third compound represented by Formula ET-1: 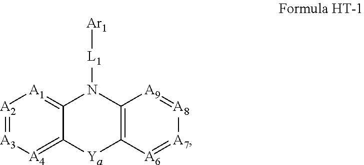
and
wherein, in Formula HT-1,
A₁ to A₅, and A₆ to A₉ are each independently N or CR₄₁,
L₁ is a direct linkage, a substituted or unsubstituted arylene group having 6 to 30 ring-forming carbon atoms, or a substituted or unsubstituted heteroarylene group having 2 to 30 ring-forming carbon atoms,
Yₐ is a direct linkage, CR₄₂R₄₃, or SiR₄₄R₄₅,
Ar₁ is a substituted or unsubstituted aryl group having 6 to 30 ring-forming carbon atoms, or a substituted or unsubstituted heteroaryl group having 2 to 30 ring-forming carbon atoms, and
R₄₁ to R₄₅ are each independently hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring, and 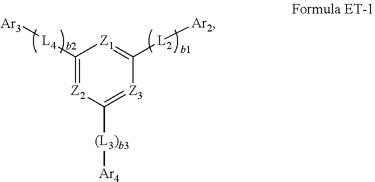
and
wherein, in Formula ET-1,
at least one selected from among Z₁ to Z₃ is N, and the rest are CR₄₆,
R₄₆ is hydrogen, deuterium, a substituted or unsubstituted alkyl group having 1 to 20 carbon atoms, a substituted or unsubstituted aryl group having 6 to 60 ring-forming carbon atoms, or a substituted or unsubstituted heteroaryl group of 2 to 60 ring-forming carbon atoms,
b1 to b3 are each independently an integer of 0 to 10,
L₂ to L₄ are each independently a direct linkage, a substituted or unsubstituted arylene group having 6 to 30 ring-forming carbon atoms, or a substituted or unsubstituted heteroarylene group having 2 to 30 ring-forming carbon atoms, and
Ar₂ to Ar₄ are each independently hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

11. The light emitting device of claim 1, wherein the emission layer further comprises a fourth compound represented by Formula D-1: 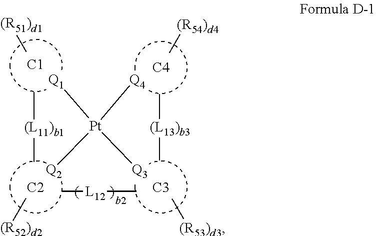
and
wherein, in Formula D-1,
Q₁ to Q₄ are each independently C or N,
C1 to C4 are each independently a substituted or unsubstituted hydrocarbon ring having 5 to 30 ring-forming carbon atoms, or a substituted or unsubstituted heterocycle having 2 to 30 ring-forming carbon atoms,
L₁₁ to L₁₃ are each independently a direct linkage, 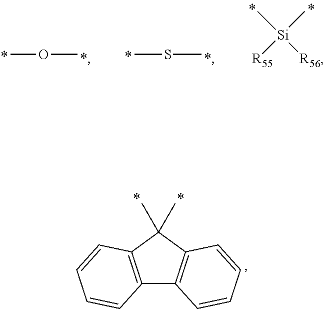
a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
b1 to b3 are each independently 0 or 1,
R₅₁ to R₅₆ are each independently hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring, and
d1 to d4 are each independently an integer of 0 to 4.

12. A fused polycyclic compound represented by Formula 1: 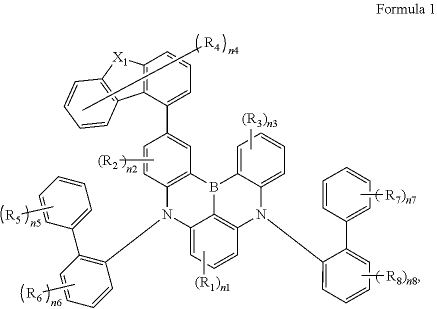
wherein, in Formula 1,
X₁ is NRₐ, CR_{b}R_{c}, O, or S,
R₁ to R₈ are each independently hydrogen, deuterium, a halogen, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
Rₐ to R_{c} are each independently a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring,
n1 and n2 are each independently an integer of 0 to 3,
n3, n6 and n8 are each independently an integer of 0 to 4,
n4 is an integer of 0 to 7, and
n5 and n7 are each independently an integer of 0 to 5.

13. The fused polycyclic compound of claim 12, wherein the fused polycyclic compound represented by Formula 1 is represented by any one selected from among Formula 2-1 to Formula 2-5: 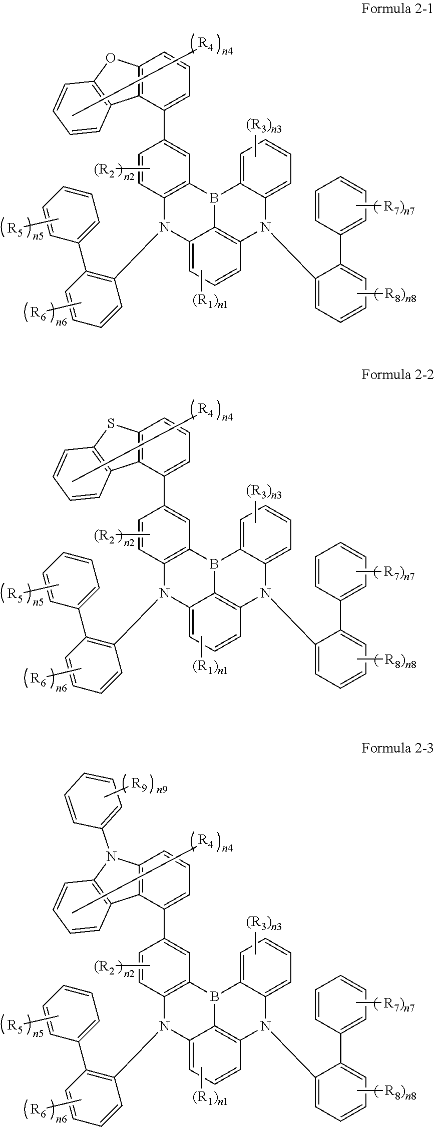 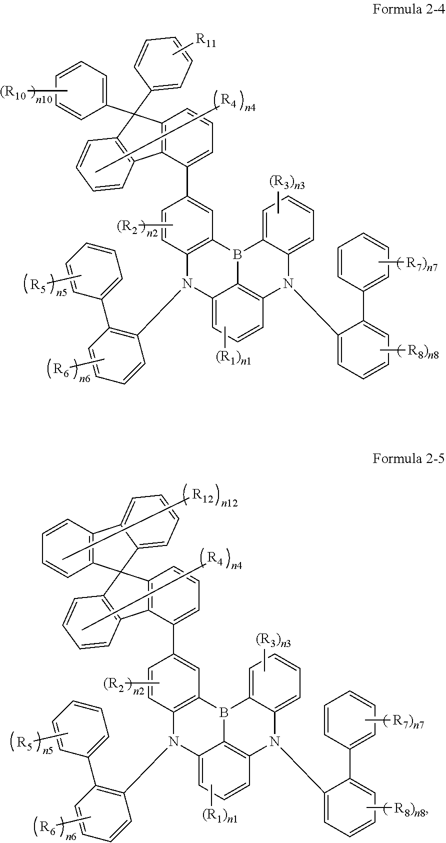
and
wherein, in Formula 2-1 to Formula 2-5,
R₉ to R₁₂ are each independently hydrogen, deuterium, a halogen, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
n9 to n11 are each independently an integer of 0 to 5,
n12 is an integer of 0 to 8, and
R₁ to R₈, and n1 to n8 are the same as defined in Formula 1.

14. The fused polycyclic compound of claim 12, wherein the fused polycyclic compound represented by Formula 1 is represented by Formula 3-1 or Formula 3-2: 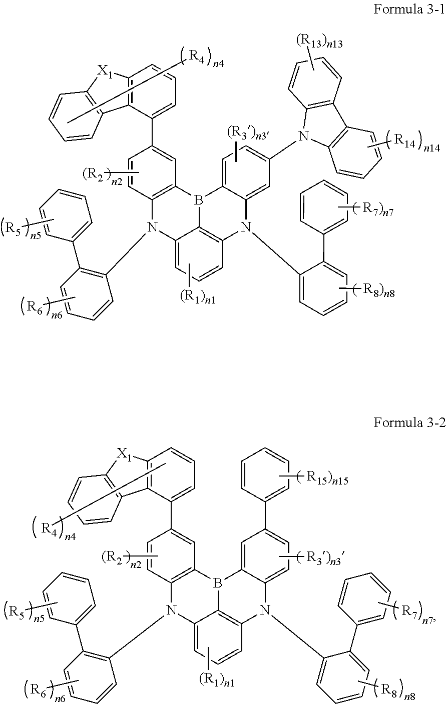
and
wherein, in Formula 3-1 and Formula 3-2,
R₃′ is hydrogen, deuterium, a halogen, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
R₁₃ to R₁₅ are each independently hydrogen, deuterium, a halogen, a cyano group, a substituted or unsubstituted amine group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring,
n3′ is an integer of 0 to 3,
n13 and n14 are each independently an integer of 0 to 4,
n15 is an integer of 0 to 5, and
X₁, R₁, R₂, R₄ to R₈, n1, n2, and n4 to n8 are the same as defined in Formula 1.

15. The fused polycyclic compound of claim 12, wherein the fused polycyclic compound represented by Formula 1 is represented by Formula 4: 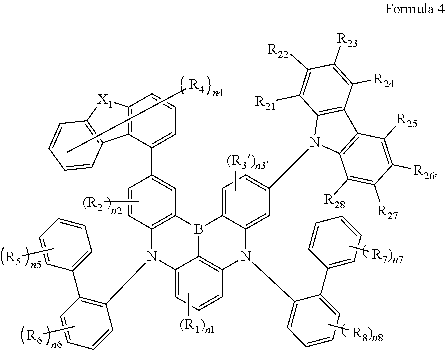
and
wherein, in Formula 4,
R₃′ is hydrogen, deuterium, a halogen, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
R₂₁ to R₂₈ are each independently hydrogen, deuterium, a halogen, a cyano group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring,
at least one pair selected from among adjacent pairs of R₂₁ to R₂₈ are positions at which a substituent represented by Formula 4-A is fused, and
n3′ is an integer of 0 to 3: 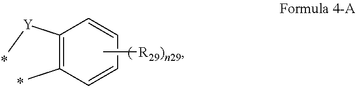
wherein, in Formula 4-A,
Y is NR₃₀, O, or S,
—* is a position which is fused to any one adjacent pair selected from among R₂₁ to R₂₈ in Formula 4,
R₂₉ and R₃₀ are each independently hydrogen, deuterium, a halogen, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
n29 is an integer of 0 to 4, and
wherein, in Formula 4,
X₁, R₁, R₂, R₄ to R₈, n1, n2, and n4 to n8 are the same as defined in Formula 1.

16. The fused polycyclic compound of claim 12, wherein the fused polycyclic compound represented by Formula 1 is represented by Formula 5: 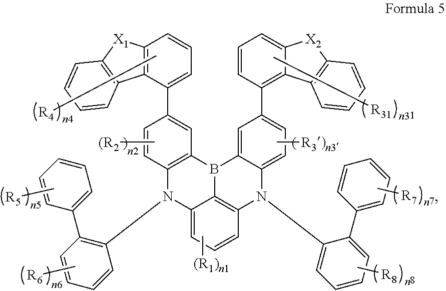
and
wherein, in Formula 5,
X₂ is NR_{d}, CRₑR_{f}, O, or S,
R₃′ and R₃₁ are each independently hydrogen, deuterium, a halogen, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
R_{d} to R_{f} are each independently a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring,
n3′ is an integer of 0 to 3,
n31 is an integer of 0 to 7, and
X₁, R₁, R₂, R₄ to R₈, n1, n2, and n4 to n8 are the same as defined in Formula 1.

17. The fused polycyclic compound of claim 16, wherein the fused polycyclic compound represented by Formula 5 is represented by any one selected from among Formula 6-1 to Formula 6-5: 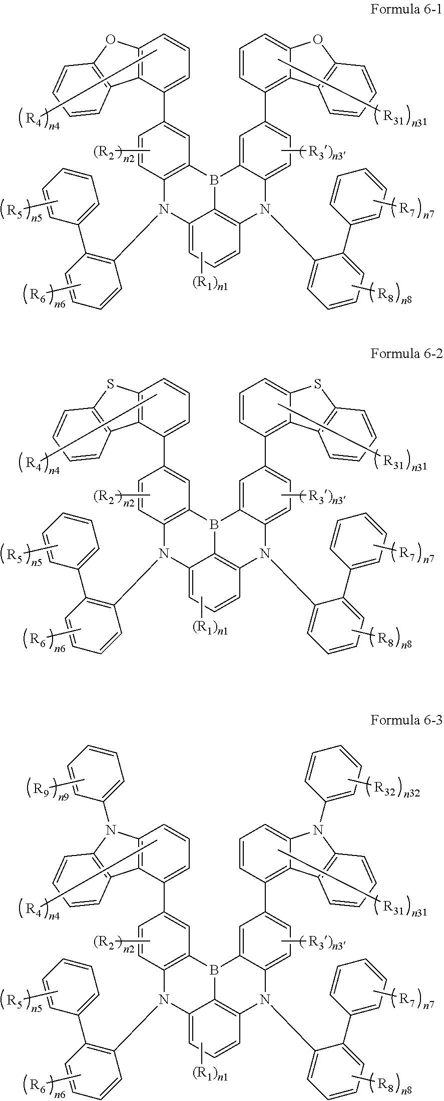 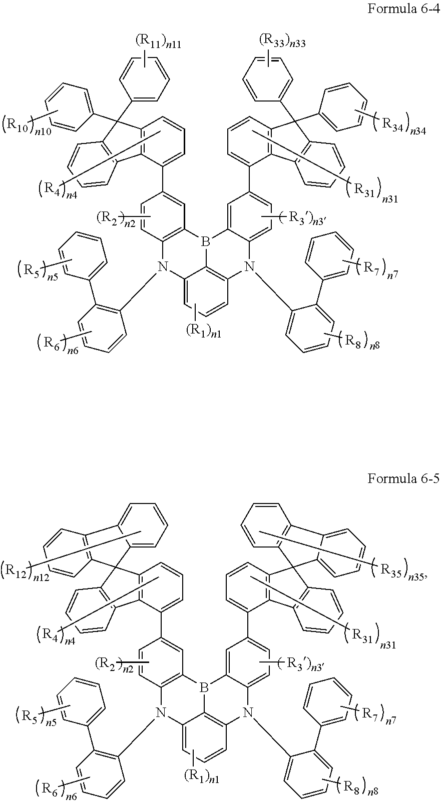
and
wherein, in Formula 6-1 to Formula 6-5,
R₉ to R₁₂ and R₃₂ to R₃₅ are each independently hydrogen, deuterium, a halogen, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
n9 to n11 and n32 to n34 are each independently an integer of 0 to 5,
n12 and n35 are each independently an integer of 0 to 8, and
R₁, R₂, R₃′, R₄ to R₈, R₃₁, n1, n2, n3′, n4 to n8, and n31 are the same as defined in Formula 1 and Formula 5.

18. The fused polycyclic compound of claim 12, wherein the fused polycyclic compound represented by Formula 1 is represented by Formula 7: 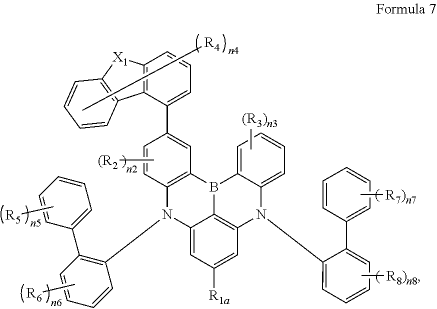
and
wherein, in Formula 7,
R₁ₐ is a substituted or unsubstituted alkyl group having 1 to 10 carbon atoms, or is represented by any one selected from among Formula A-1 to Formula A-3: 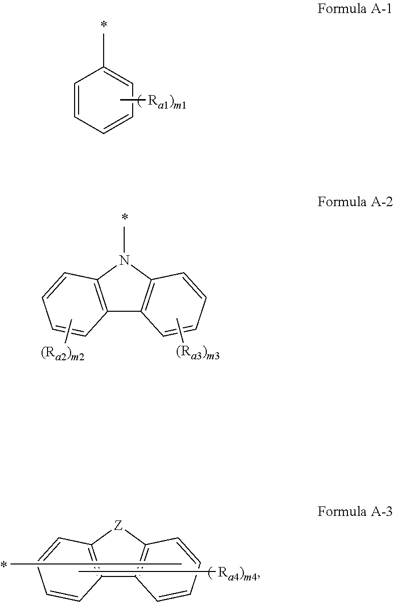
and
wherein, in Formula A-1 to Formula A-3,
Z is NRₐ₅, O, or S,
Rₐ₁ to Rₐ₅ are each independently hydrogen, deuterium, a halogen, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
m1 is an integer of 0 to 5,
m2 and m3 are each independently an integer of 0 to 4, and
m4 is an integer of 0 to 7, and
wherein, in Formula 7,
X₁, R₂ to R₈, and n2 to n8 are the same as defined in Formula 1.

19. The fused polycyclic compound of claim 12, wherein the fused polycyclic compound represented by Formula 1 is represented by Formula 8-1 or Formula 8-2: 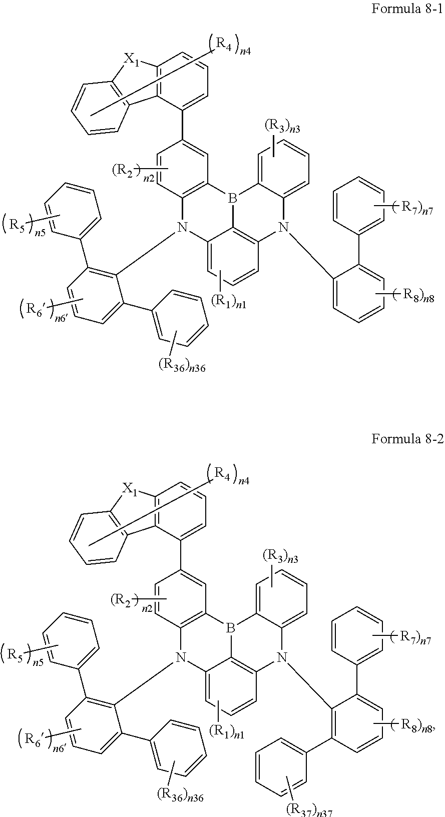
and
wherein, in Formula 8-1 and Formula 8-2,
R₆′, R₈′, R₃₆, and R₃₇ are each independently hydrogen, deuterium, a halogen, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
n6′ and n8′ are each independently an integer of 0 to 3,
n36 and n37 are each independently an integer of 0 to 5, and
X₁, R₁ to R₅, R₇, R₈, n1 to n5, n7, and n8 are the same as defined in Formula 1.

20. The fused polycyclic compound of claim 12, wherein the fused polycyclic compound represented by Formula 1 comprises at least one selected from among compounds represented in Compound Group 1: 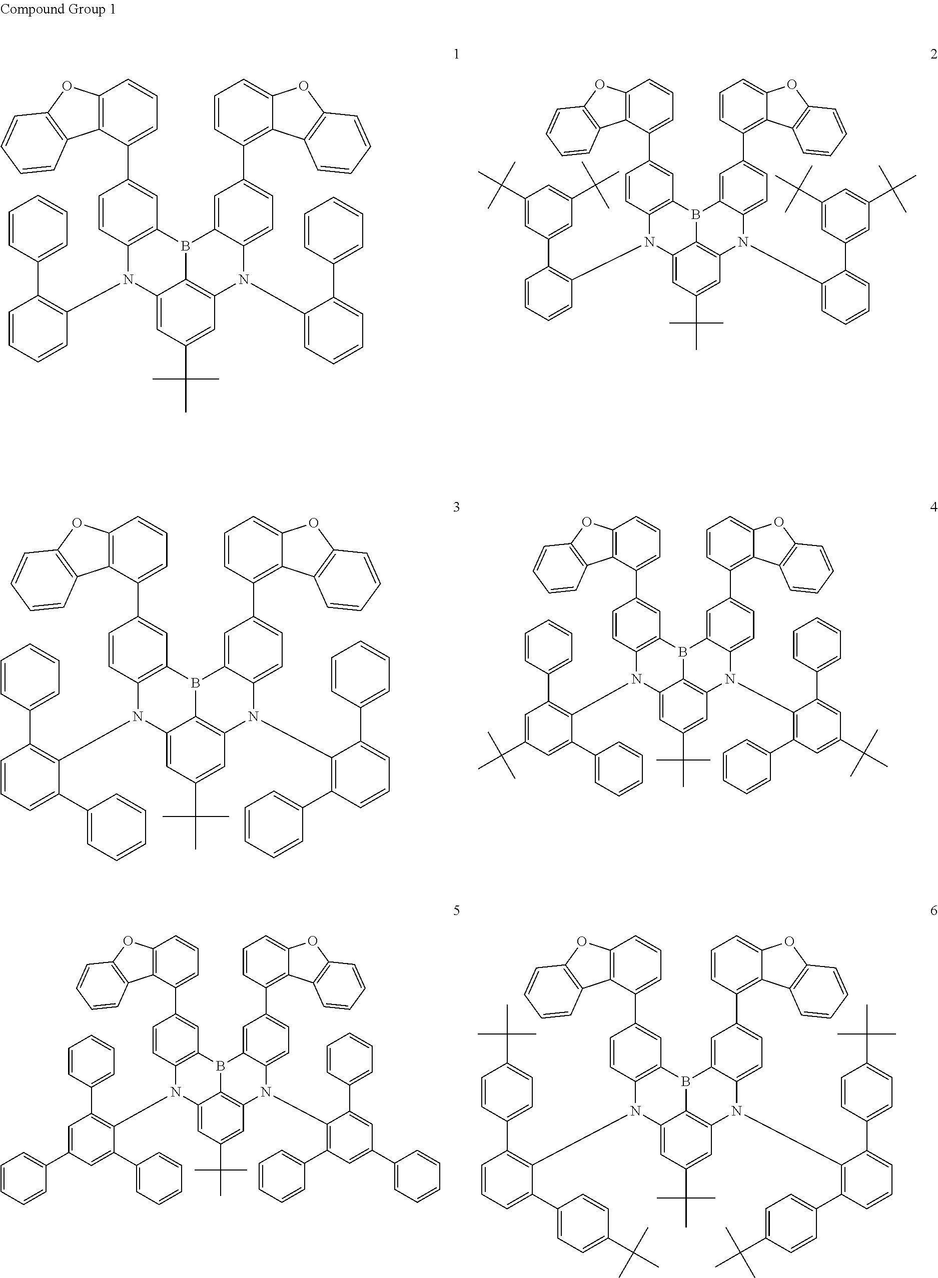 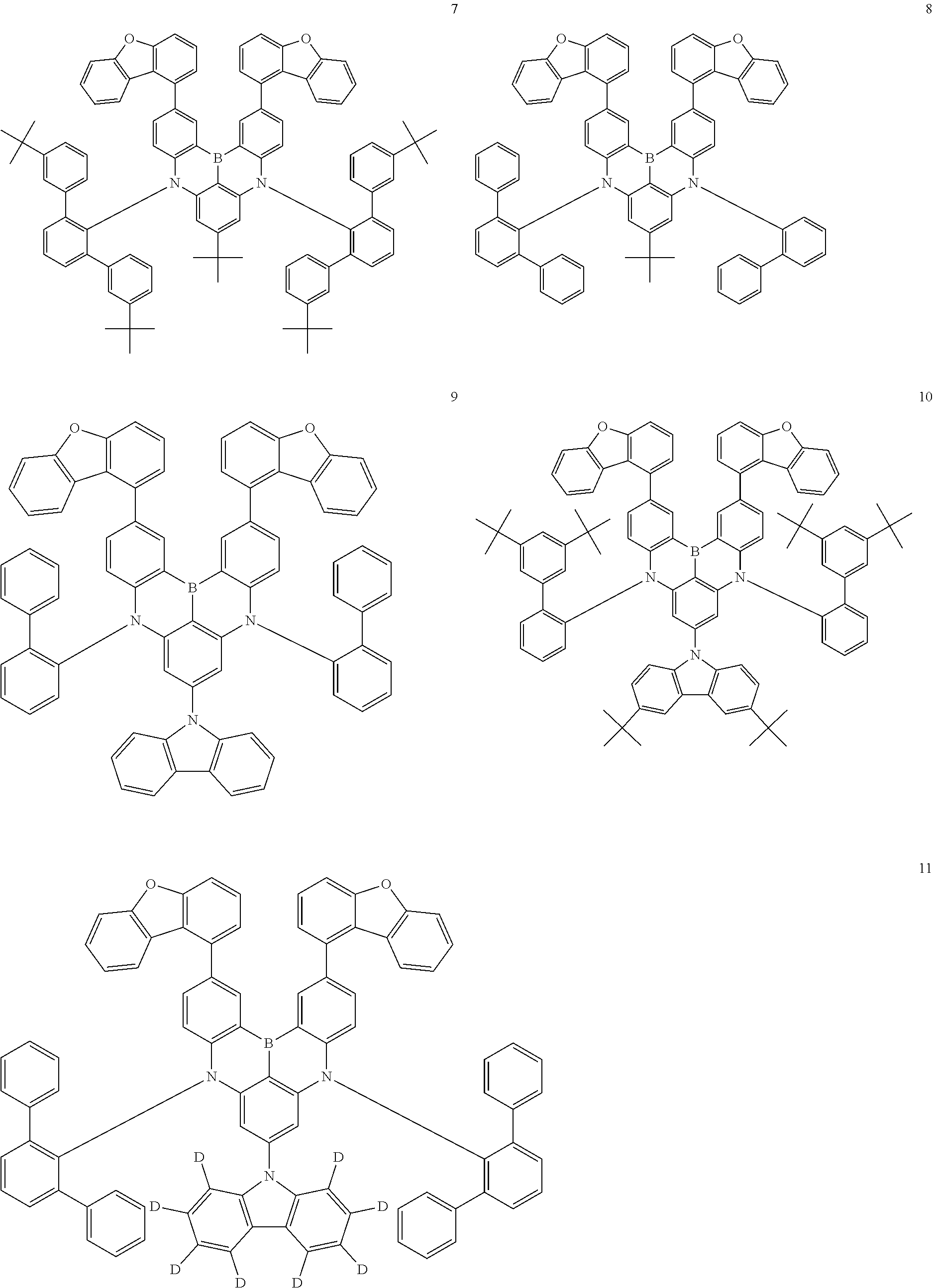 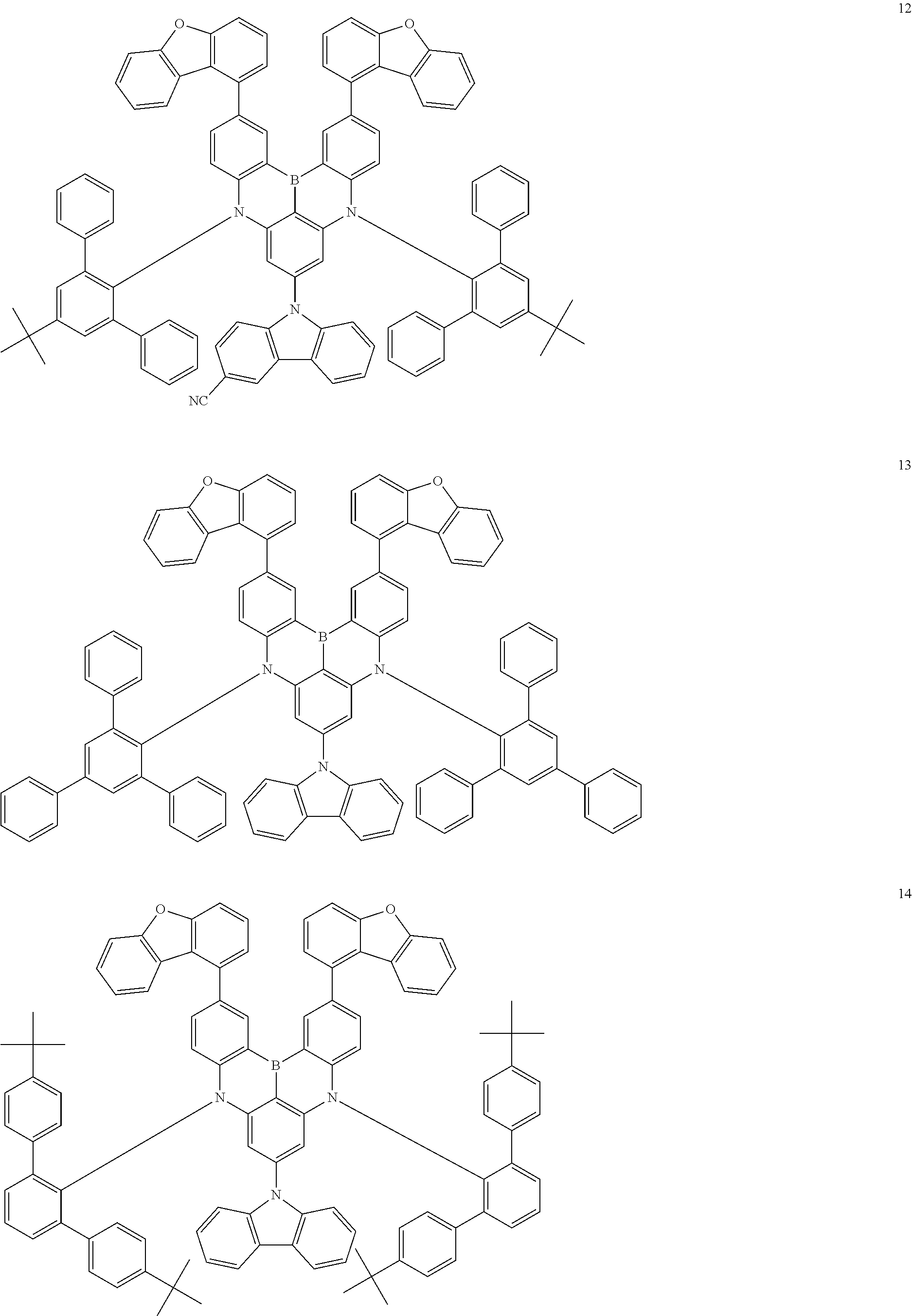 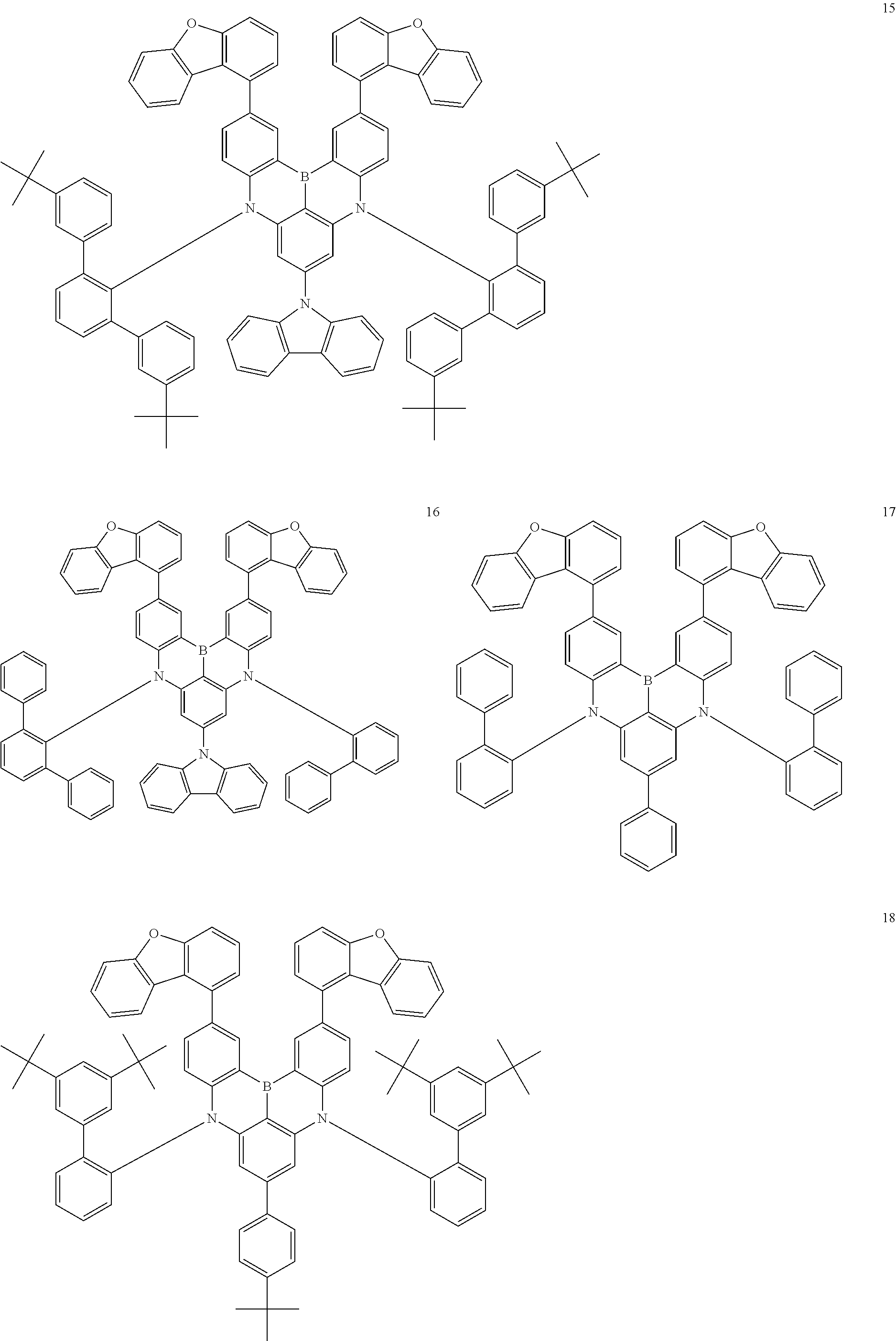 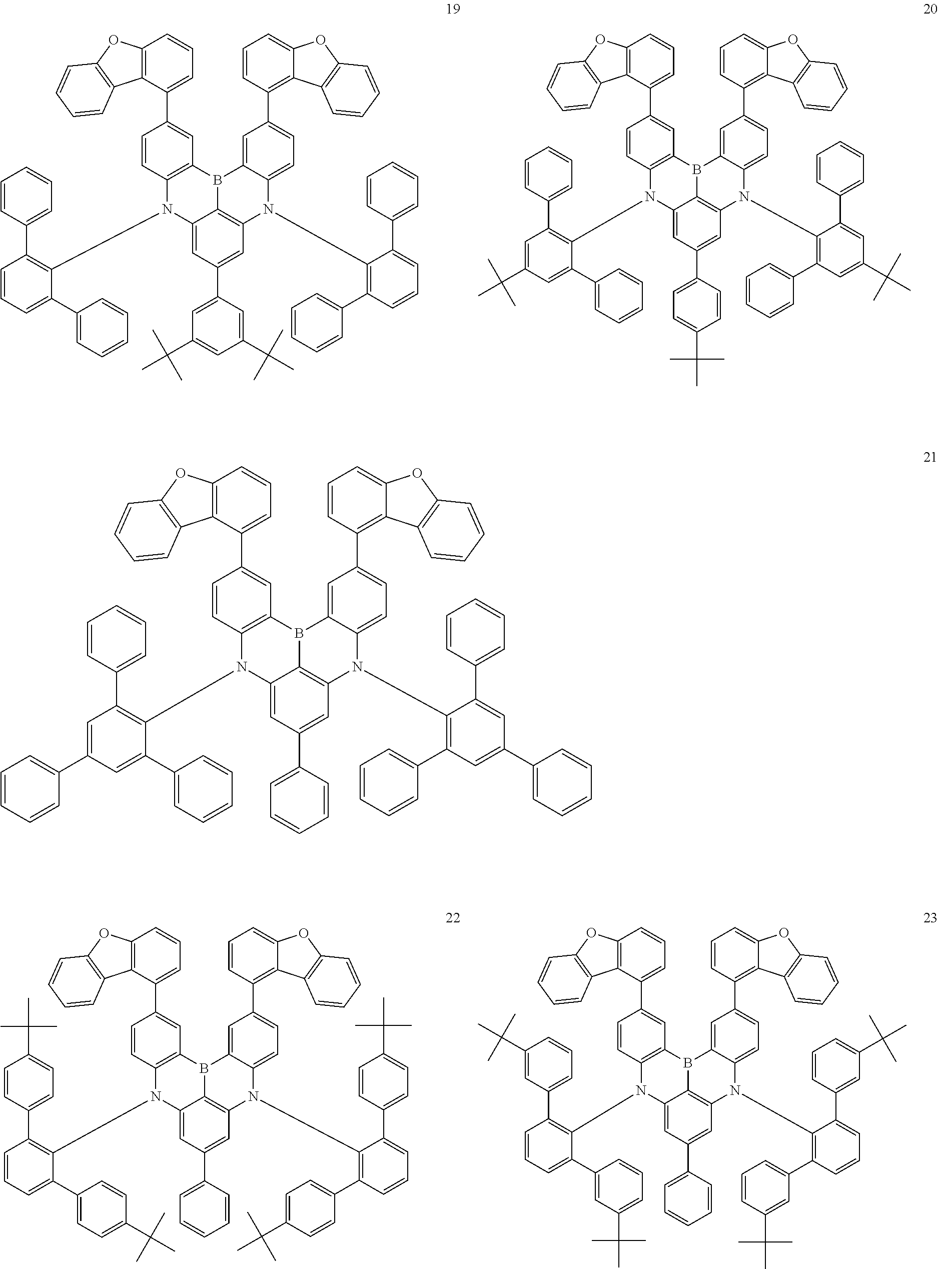 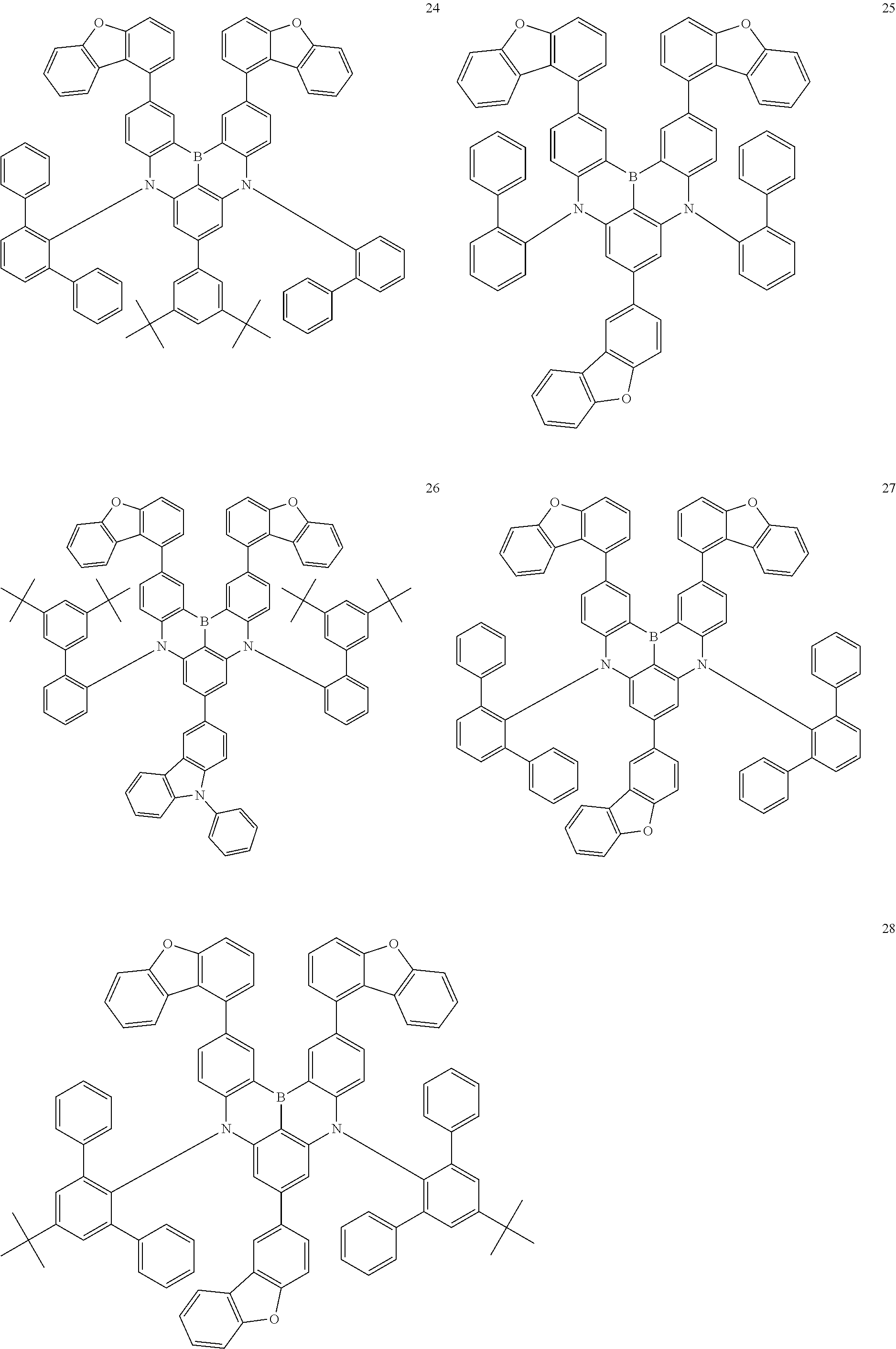 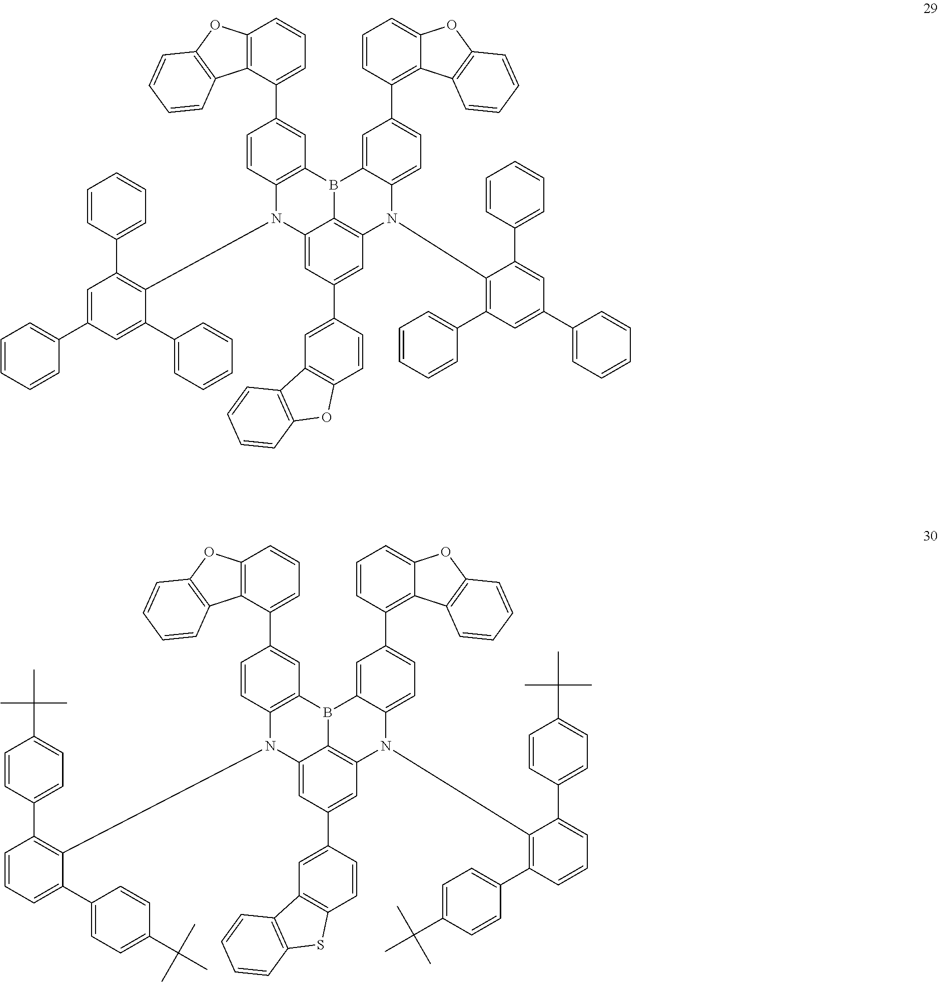 [SMILES: c1ccc(-c2cc(-c3ccccc3)c(N3c4ccc(-c5cccc6oc7ccccc7c56)cc4B4c5cc(-c6cccc7oc8ccccc8c67)ccc5N(c5c(-c6ccccc6)cc(-c6ccccc6)cc5-c5ccccc5)c5cc(-c6ccc7oc8ccccc8c7c6)cc3c54)c(-c3ccccc3)c2)cc1 ; CC(C)(C)c1ccc(-c2cccc(-c3ccc(C(C)(C)C)cc3)c2N2c3ccc(-c4cccc5oc6ccccc6c45)cc3B3c4cc(-c5cccc6oc7ccccc7c56)ccc4N(c4c(-c5ccc(C(C)(C)C)cc5)cccc4-c4ccc(C(C)(C)C)cc4)c4cc(-c5ccc6sc7ccccc7c6c5)cc2c43)cc1] 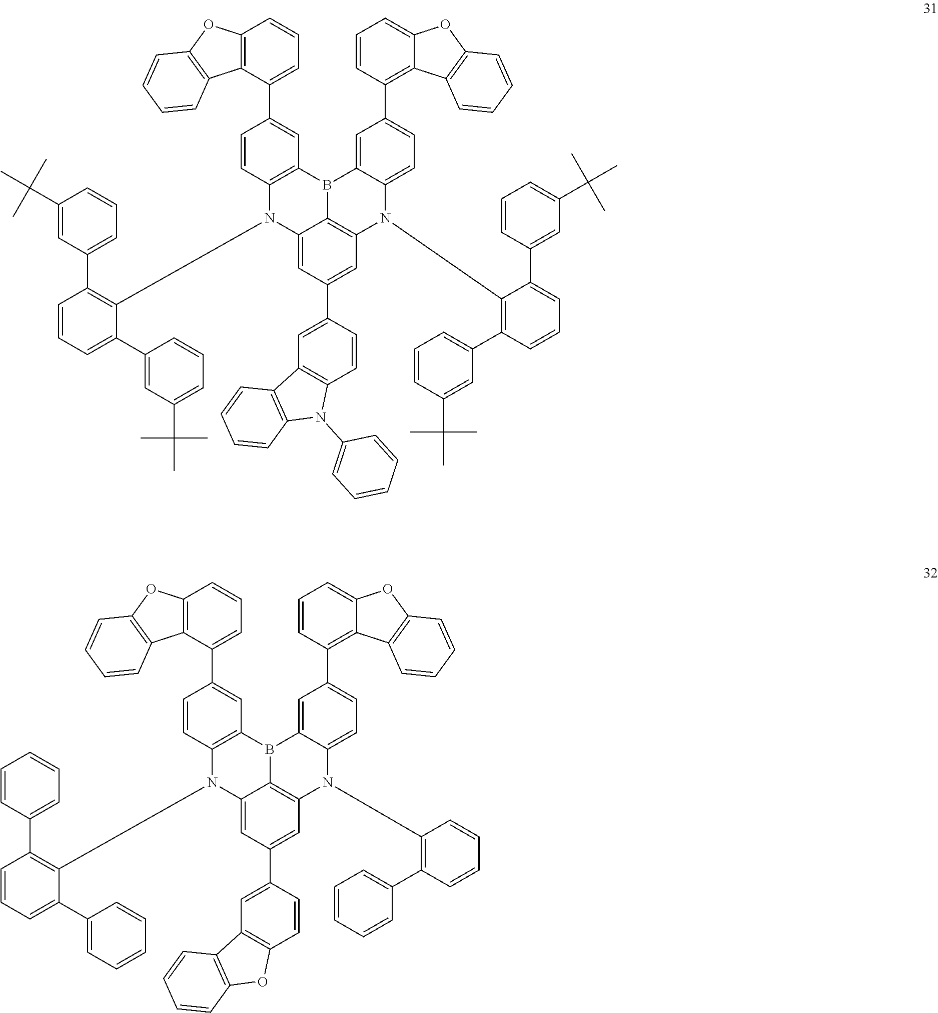 [SMILES: CC(C)(C)c1cccc(-c2cccc(-c3cccc(C(C)(C)C)c3)c2N2c3ccc(-c4cccc5oc6ccccc6c45)cc3B3c4cc(-c5cccc6oc7ccccc7c56)ccc4N(c4c(-c5cccc(C(C)(C)C)c5)cccc4-c4cccc(C(C)(C)C)c4)c4cc(-c5ccc6c(c5)c5ccccc5n6-c5ccccc5)cc2c43)c1 ; c1ccc(-c2ccccc2N2c3ccc(-c4cccc5oc6ccccc6c45)cc3B3c4cc(-c5cccc6oc7ccccc7c56)ccc4N(c4c(-c5ccccc5)cccc4-c4ccccc4)c4cc(-c5ccc6oc7ccccc7c6c5)cc2c43)cc1] 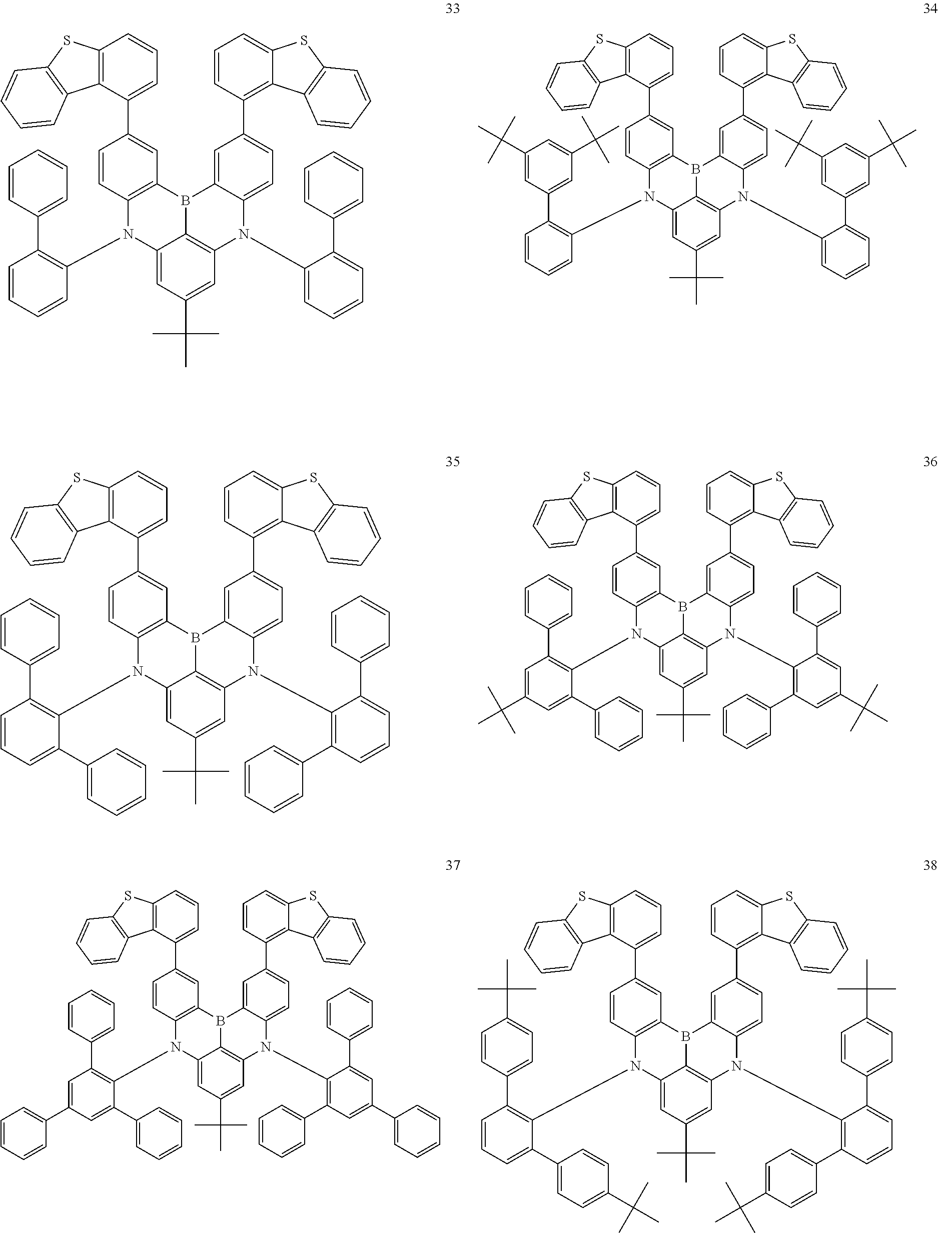 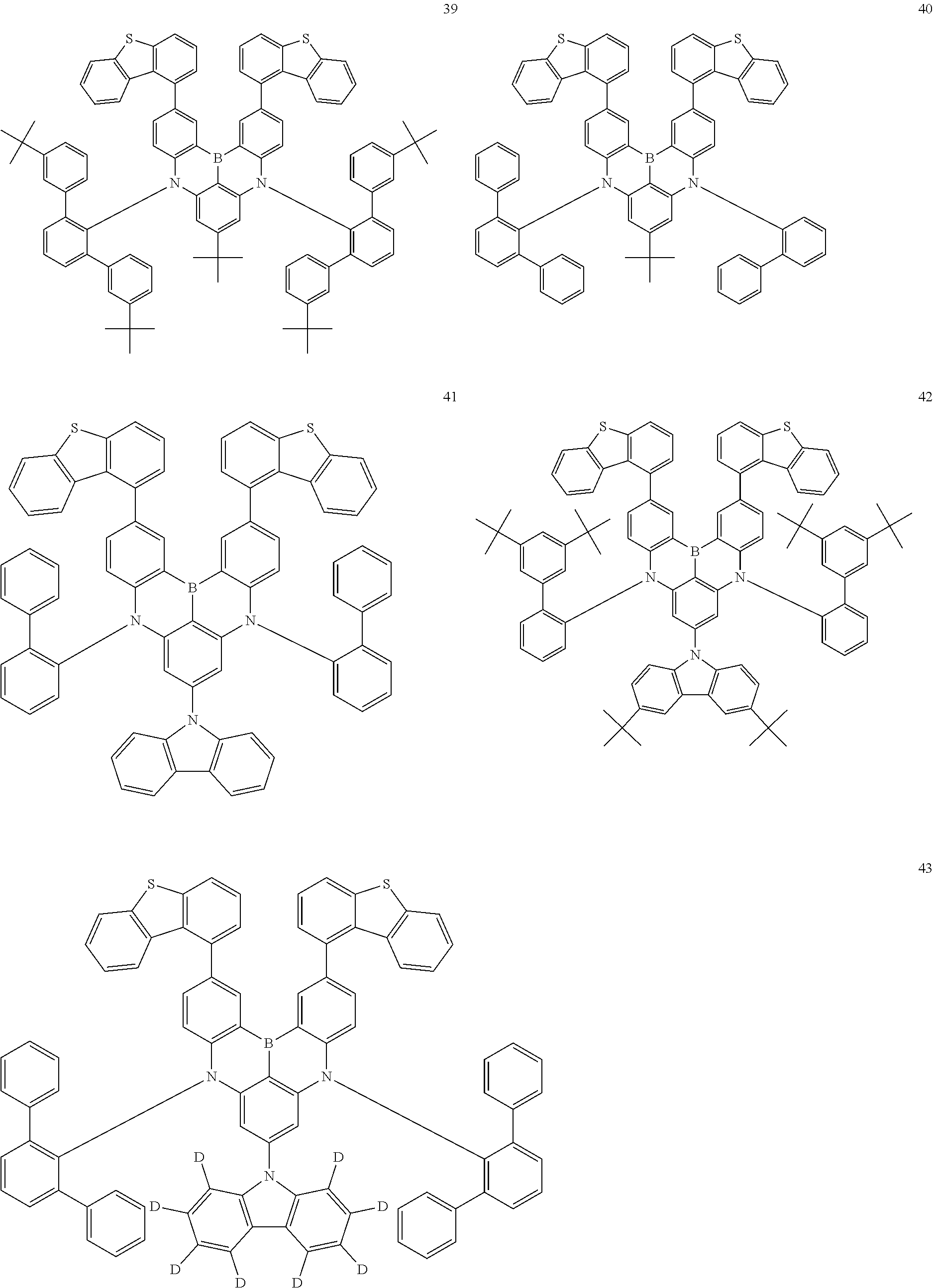 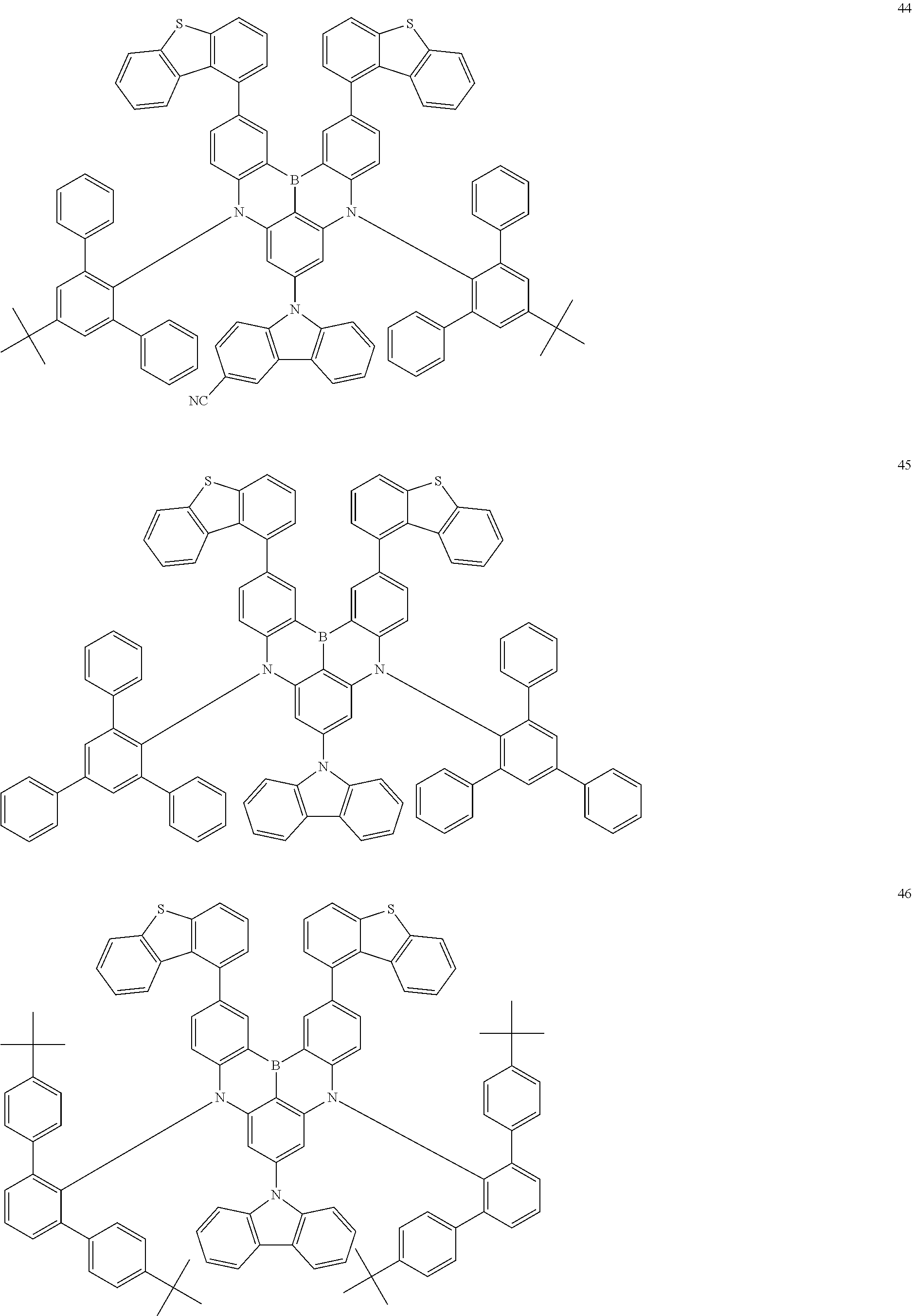 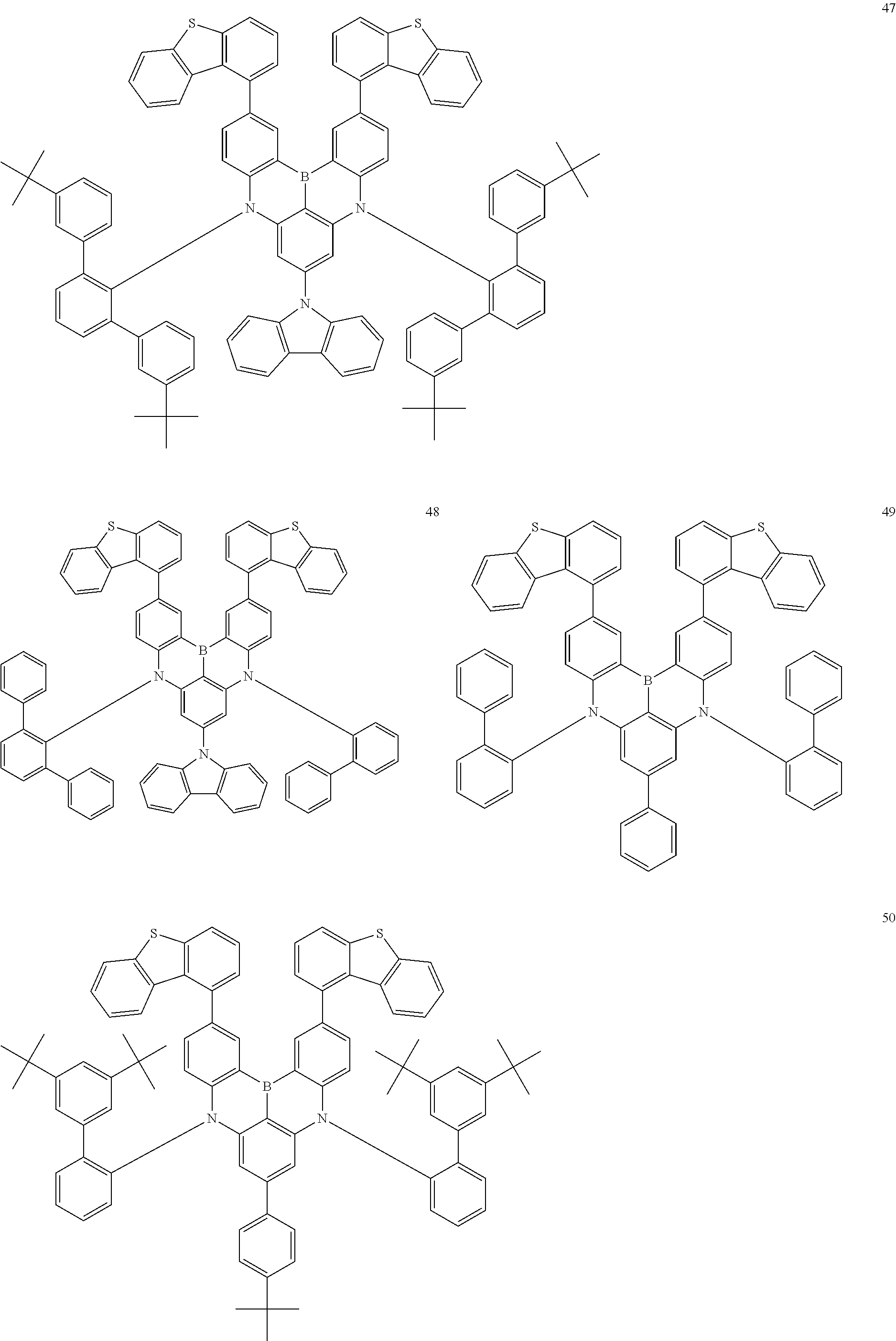 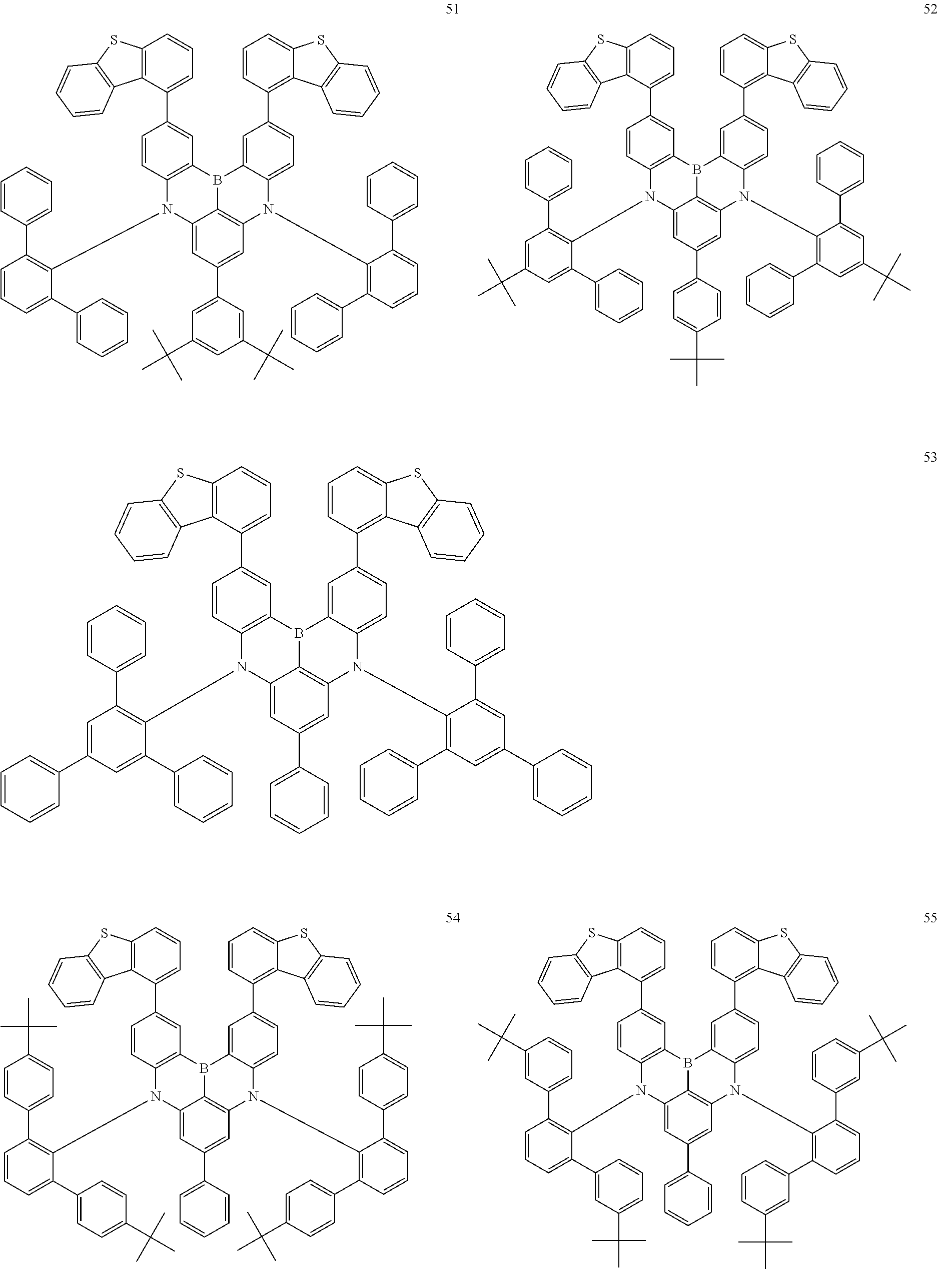 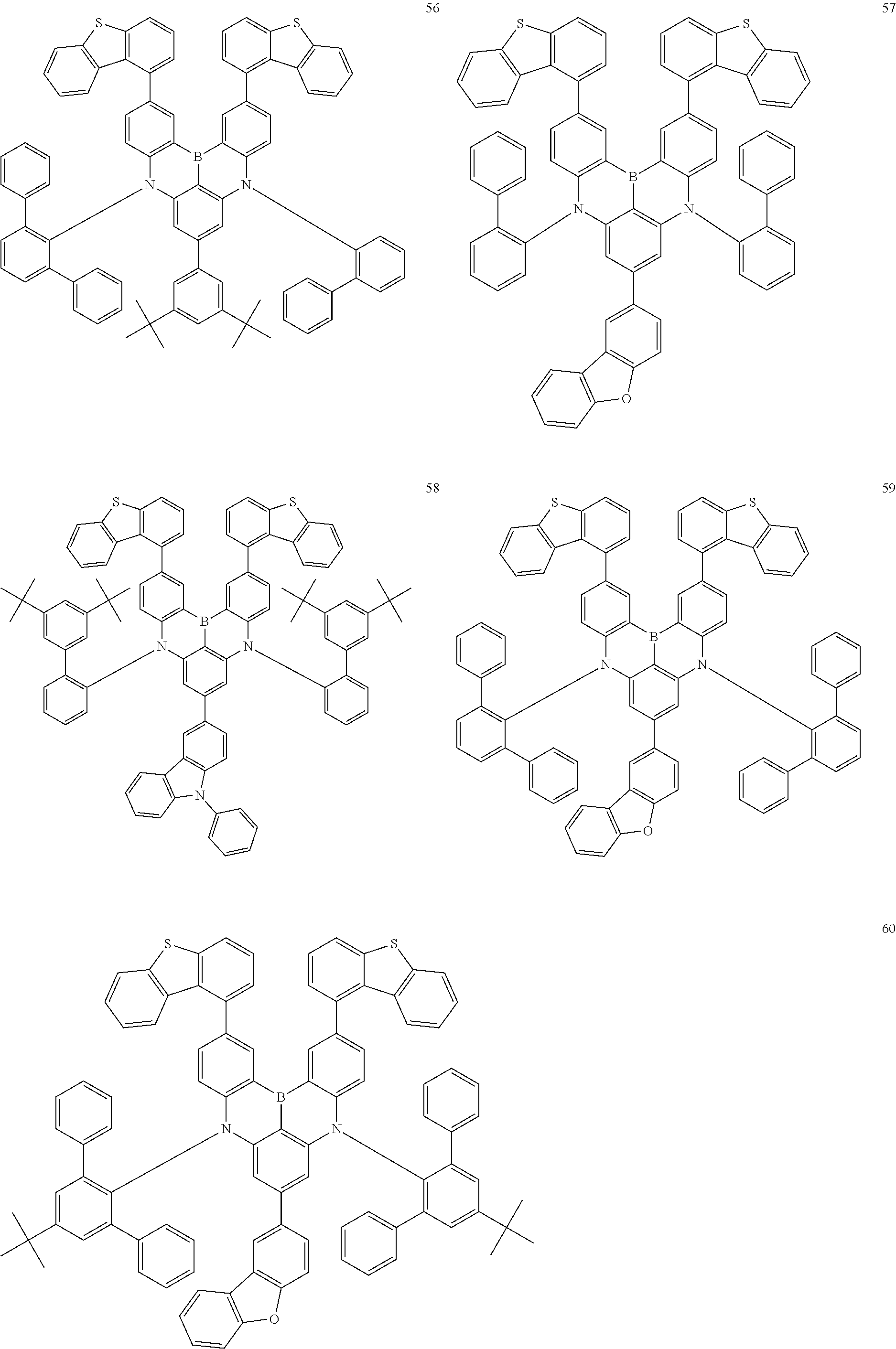 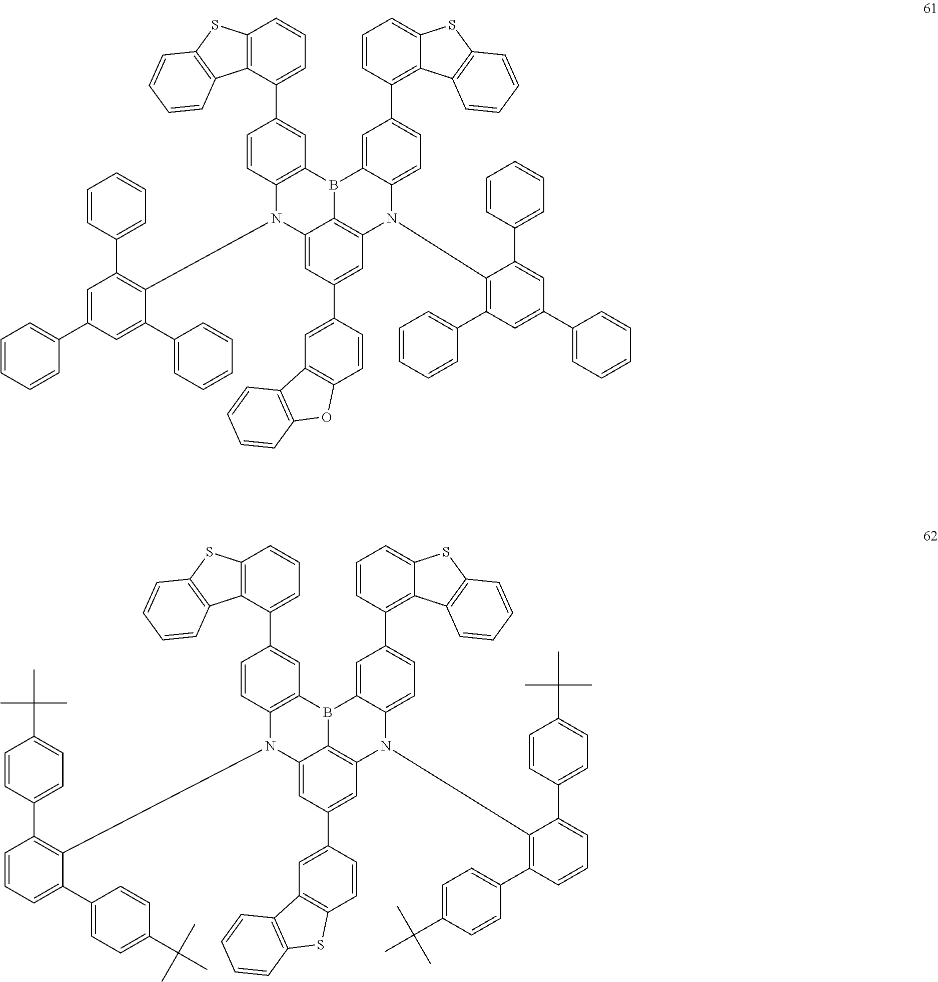 [SMILES: c1ccc(-c2cc(-c3ccccc3)c(N3c4ccc(-c5cccc6sc7ccccc7c56)cc4B4c5cc(-c6cccc7sc8ccccc8c67)ccc5N(c5c(-c6ccccc6)cc(-c6ccccc6)cc5-c5ccccc5)c5cc(-c6ccc7oc8ccccc8c7c6)cc3c54)c(-c3ccccc3)c2)cc1 ; CC(C)(C)c1ccc(-c2cccc(-c3ccc(C(C)(C)C)cc3)c2N2c3ccc(-c4cccc5sc6ccccc6c45)cc3B3c4cc(-c5cccc6sc7ccccc7c56)ccc4N(c4c(-c5ccc(C(C)(C)C)cc5)cccc4-c4ccc(C(C)(C)C)cc4)c4cc(-c5ccc6sc7ccccc7c6c5)cc2c43)cc1] 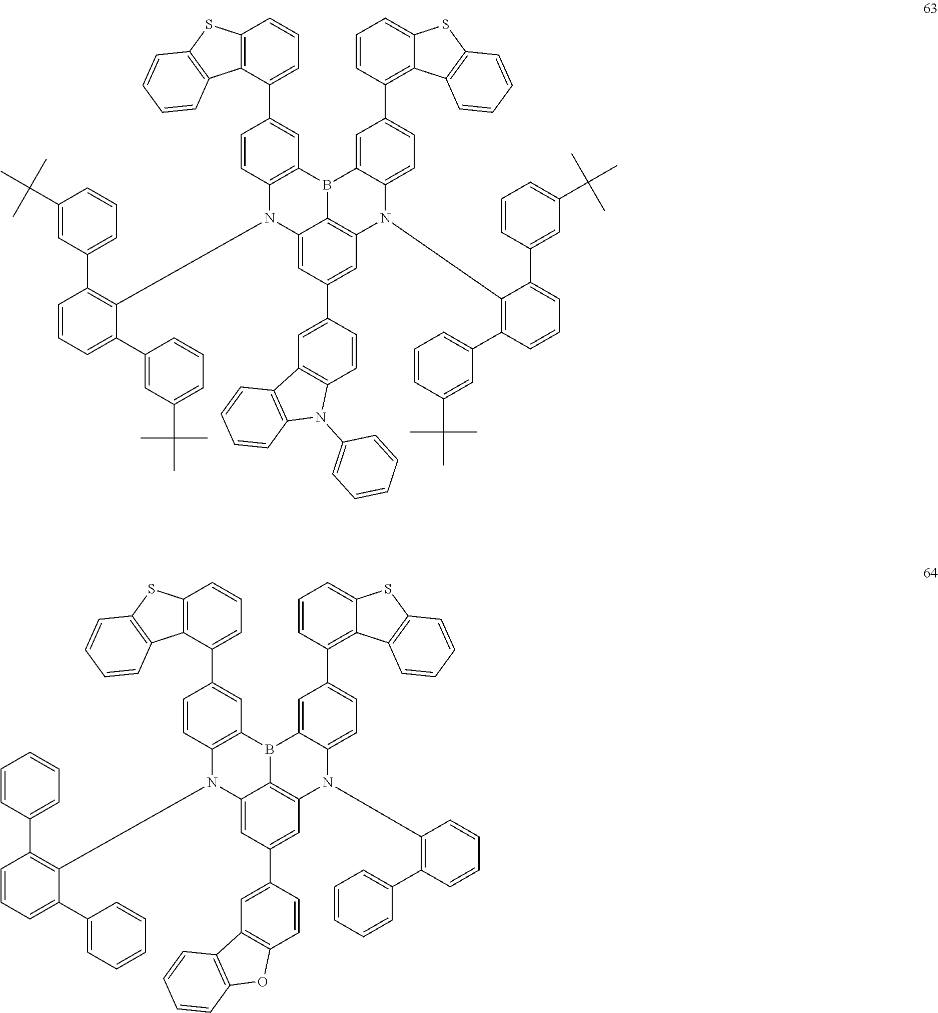 [SMILES: CC(C)(C)c1cccc(-c2cccc(-c3cccc(C(C)(C)C)c3)c2N2c3ccc(-c4cccc5sc6ccccc6c45)cc3B3c4cc(-c5cccc6sc7ccccc7c56)ccc4N(c4c(-c5cccc(C(C)(C)C)c5)cccc4-c4cccc(C(C)(C)C)c4)c4cc(-c5ccc6c(c5)c5ccccc5n6-c5ccccc5)cc2c43)c1 ; c1ccc(-c2ccccc2N2c3ccc(-c4cccc5sc6ccccc6c45)cc3B3c4cc(-c5cccc6sc7ccccc7c56)ccc4N(c4c(-c5ccccc5)cccc4-c4ccccc4)c4cc(-c5ccc6oc7ccccc7c6c5)cc2c43)cc1] 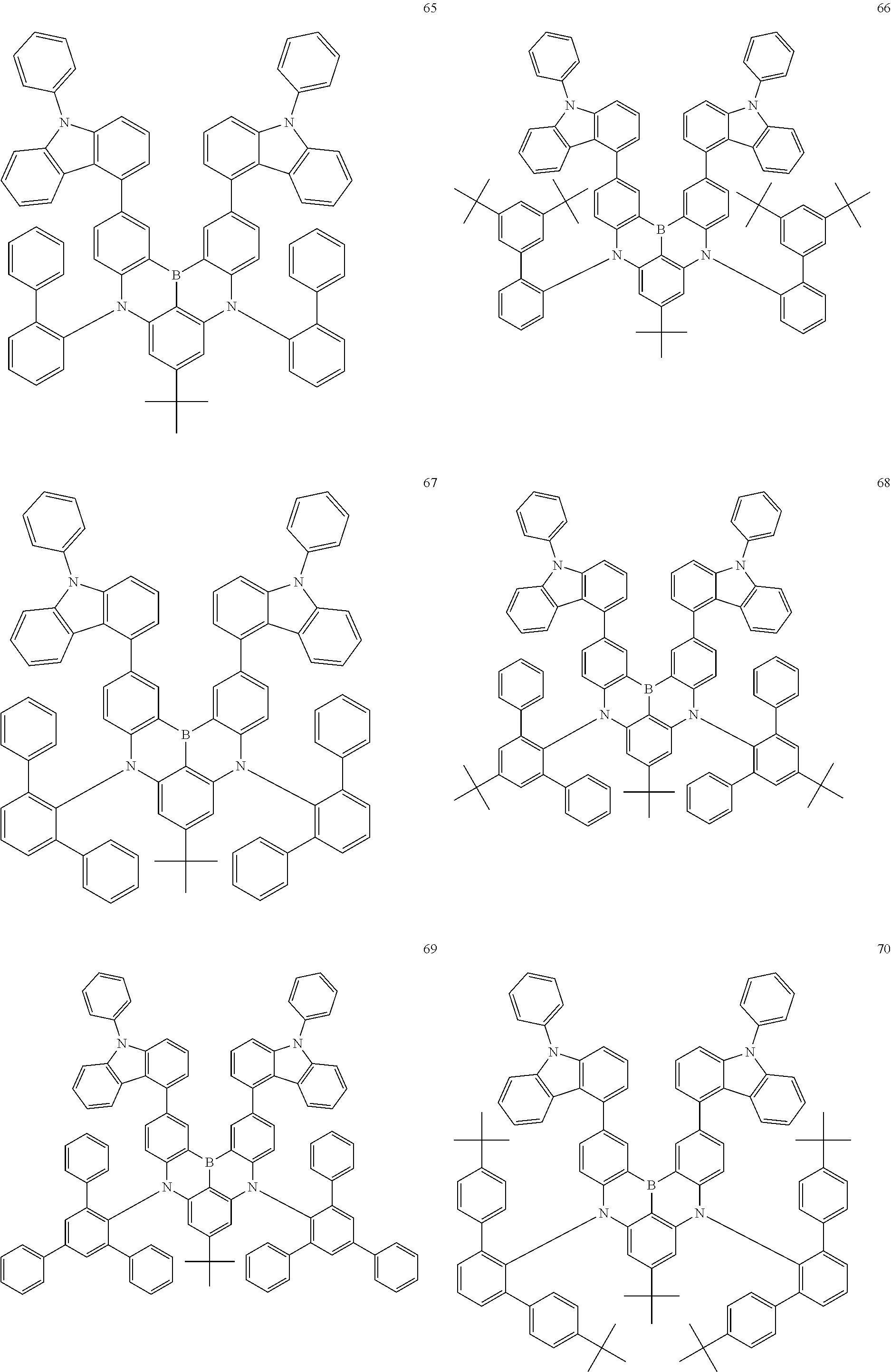 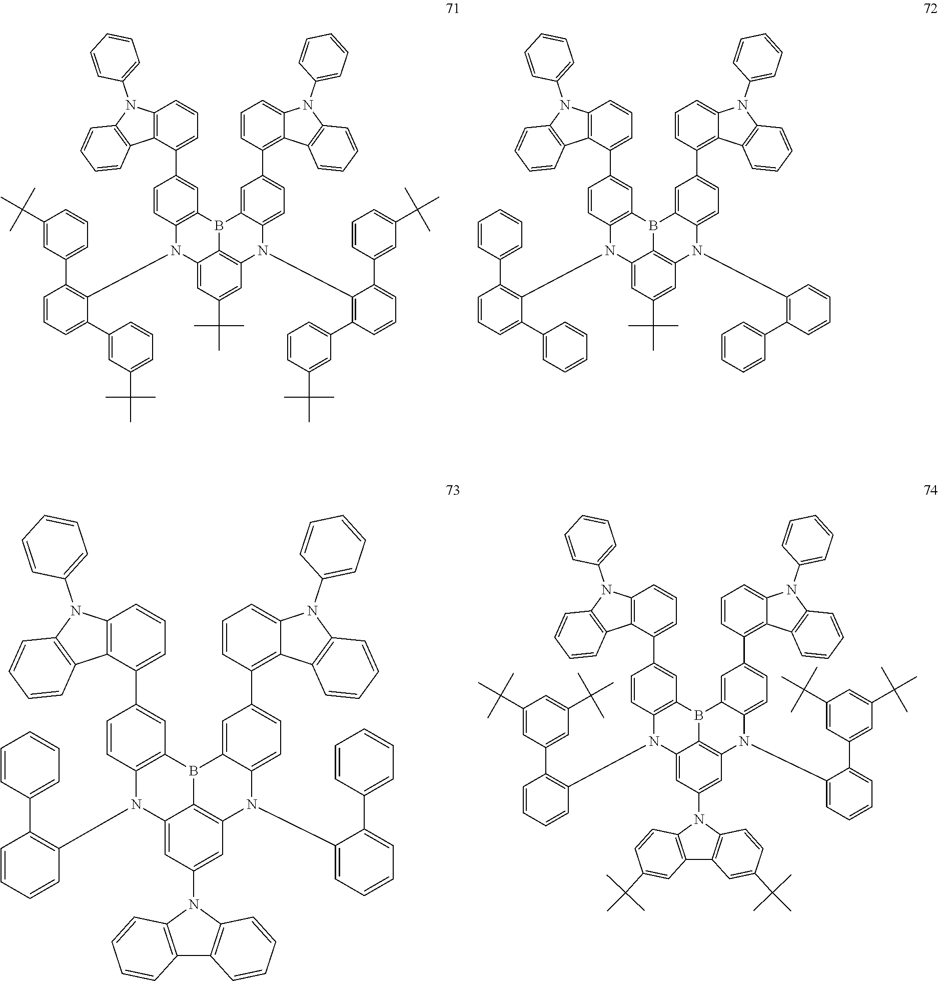 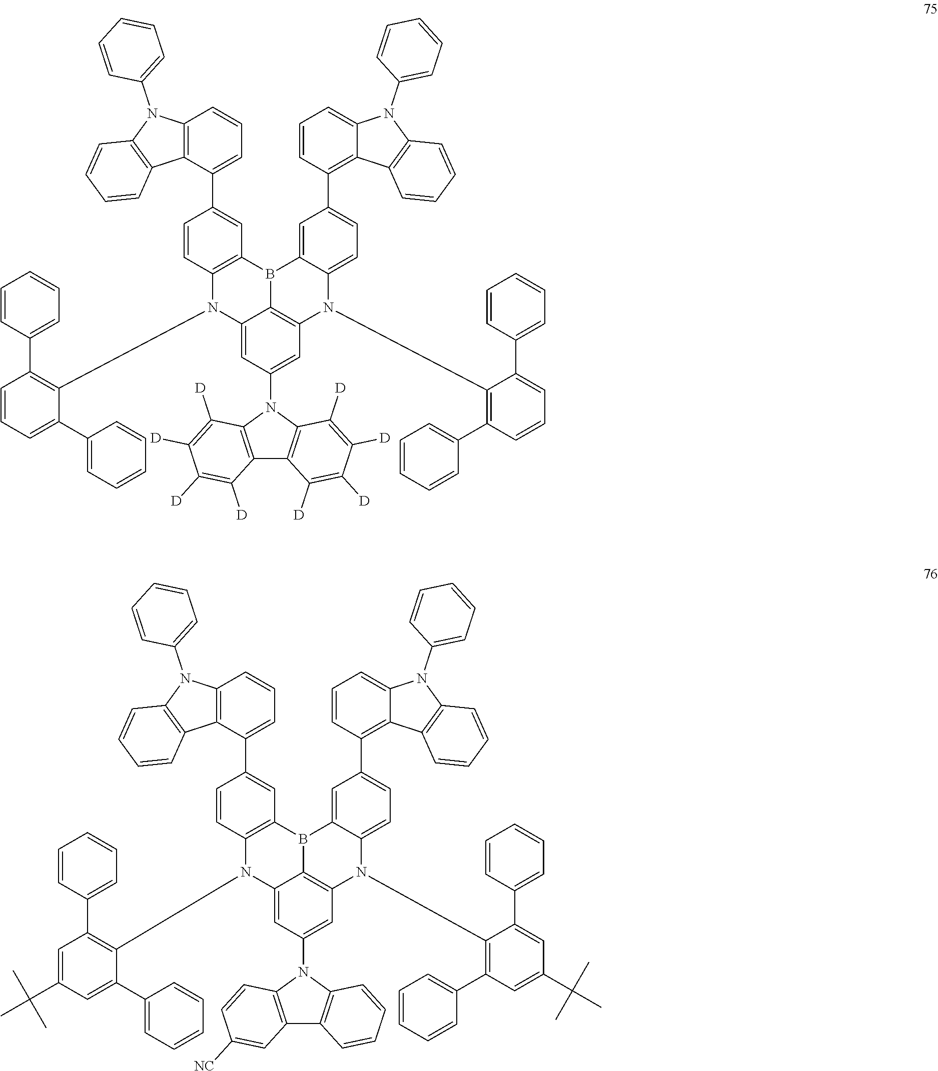 [SMILES: [2H]c1c([2H])c([2H])c2c(c1[2H])c1c([2H])c([2H])c([2H])c([2H])c1n2-c1cc2c3c(c1)N(c1c(-c4ccccc4)cccc1-c1ccccc1)c1ccc(-c4cccc5c4c4ccccc4n5-c4ccccc4)cc1B3c1cc(-c3cccc4c3c3ccccc3n4-c3ccccc3)ccc1N2c1c(-c2ccccc2)cccc1-c1ccccc1 ; CC(C)(C)c1cc(-c2ccccc2)c(N2c3ccc(-c4cccc5c4c4ccccc4n5-c4ccccc4)cc3B3c4cc(-c5cccc6c5c5ccccc5n6-c5ccccc5)ccc4N(c4c(-c5ccccc5)cc(C(C)(C)C)cc4-c4ccccc4)c4cc(-n5c6ccccc6c6cc(C#N)ccc65)cc2c43)c(-c2ccccc2)c1] 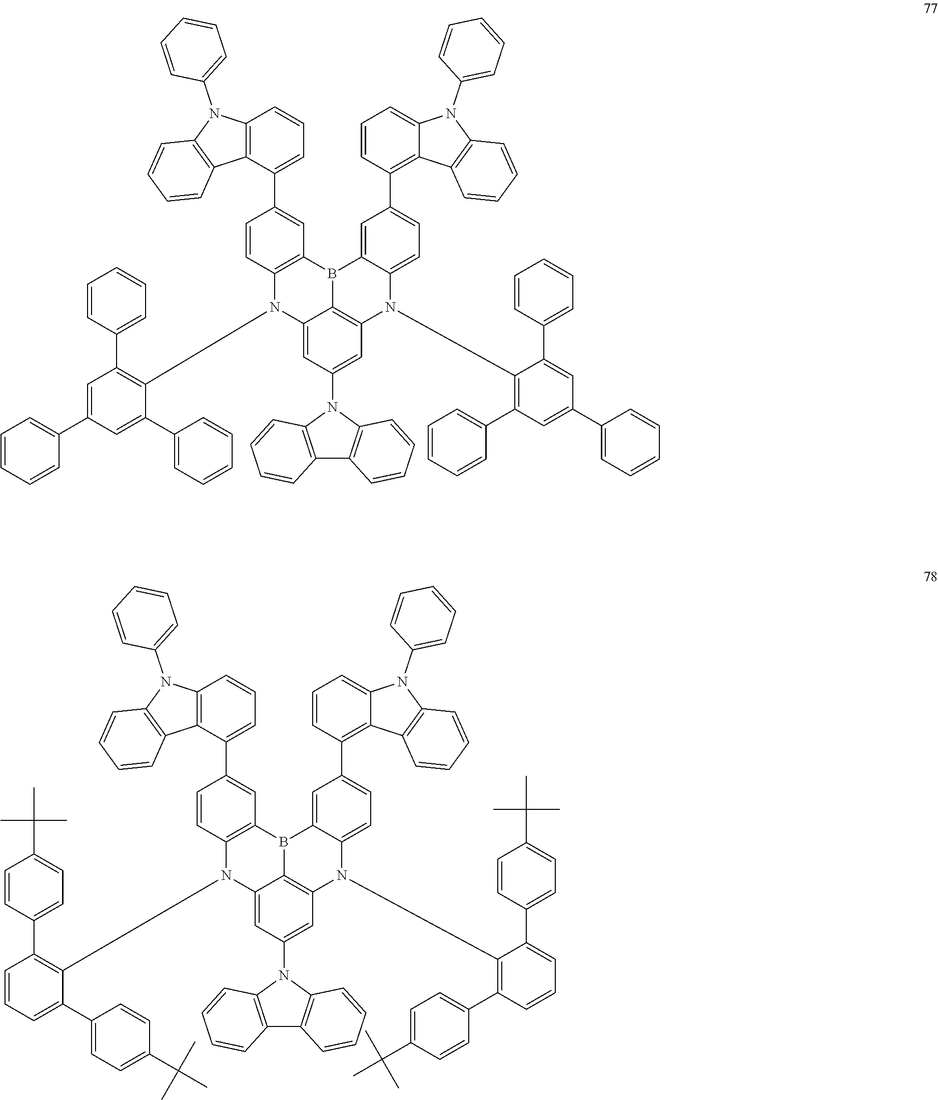 [SMILES: c1ccc(-c2cc(-c3ccccc3)c(N3c4ccc(-c5cccc6c5c5ccccc5n6-c5ccccc5)cc4B4c5cc(-c6cccc7c6c6ccccc6n7-c6ccccc6)ccc5N(c5c(-c6ccccc6)cc(-c6ccccc6)cc5-c5ccccc5)c5cc(-n6c7ccccc7c7ccccc76)cc3c54)c(-c3ccccc3)c2)cc1 ; CC(C)(C)c1ccc(-c2cccc(-c3ccc(C(C)(C)C)cc3)c2N2c3ccc(-c4cccc5c4c4ccccc4n5-c4ccccc4)cc3B3c4cc(-c5cccc6c5c5ccccc5n6-c5ccccc5)ccc4N(c4c(-c5ccc(C(C)(C)C)cc5)cccc4-c4ccc(C(C)(C)C)cc4)c4cc(-n5c6ccccc6c6ccccc65)cc2c43)cc1] 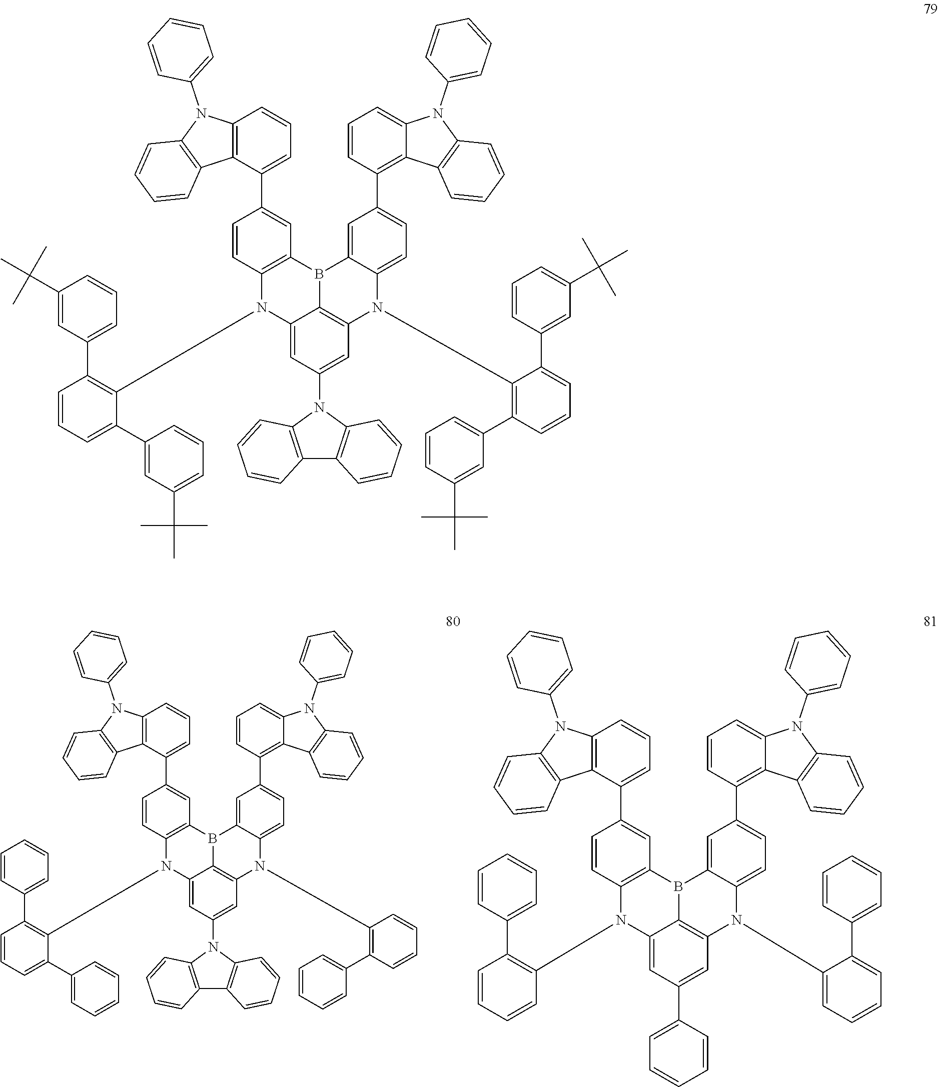 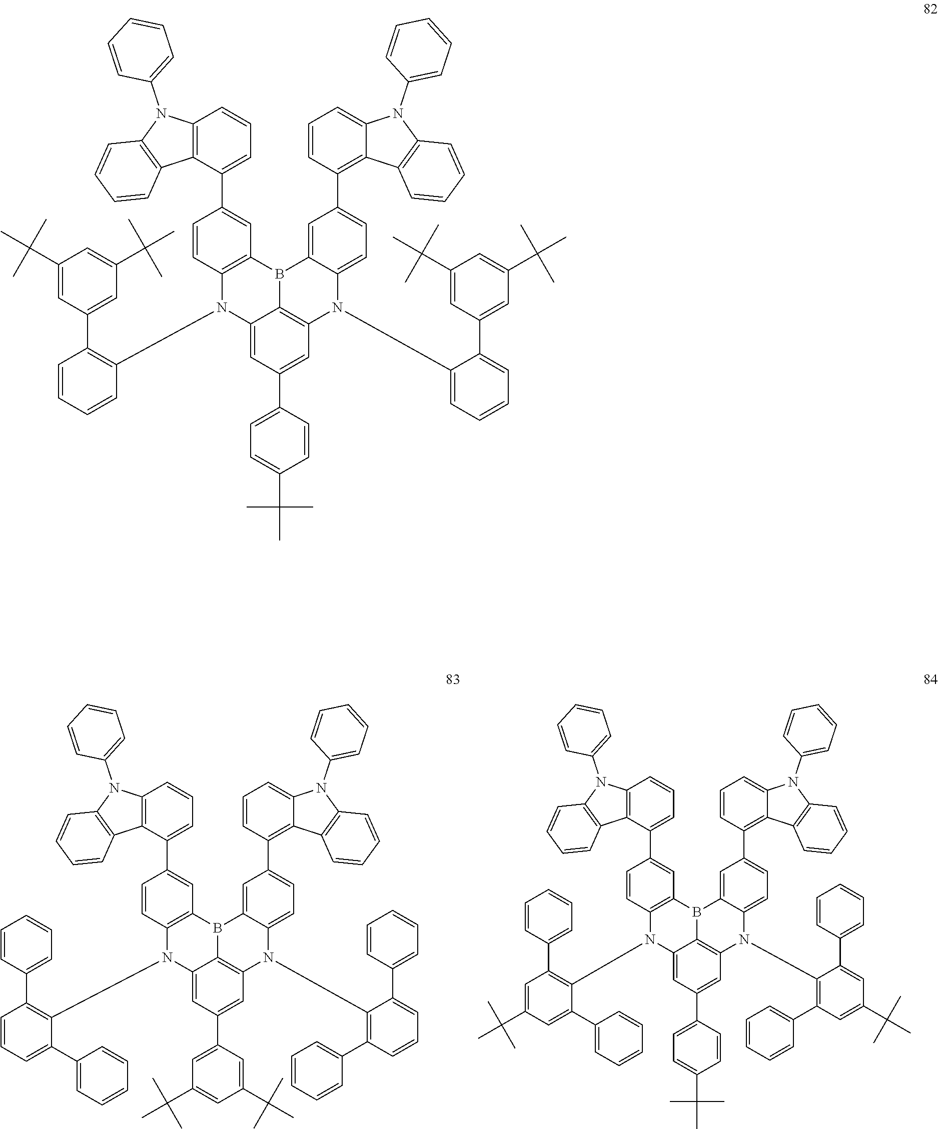 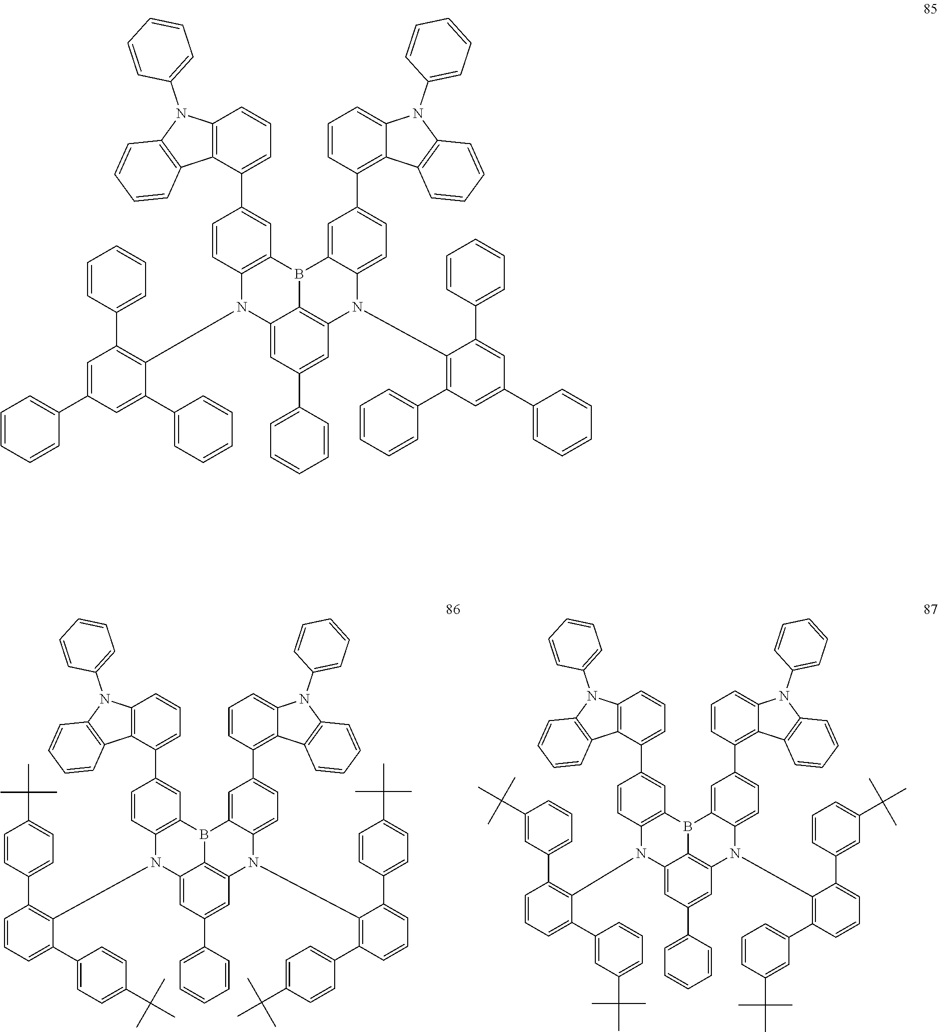 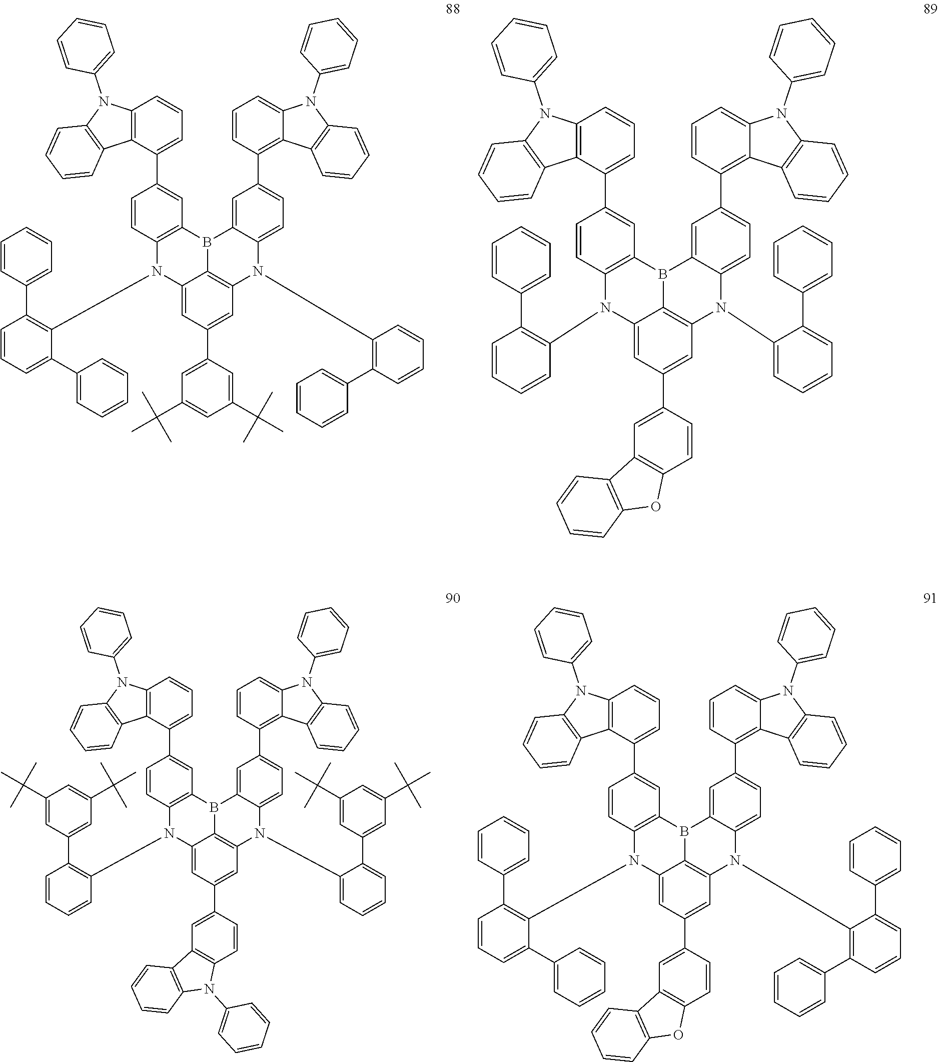 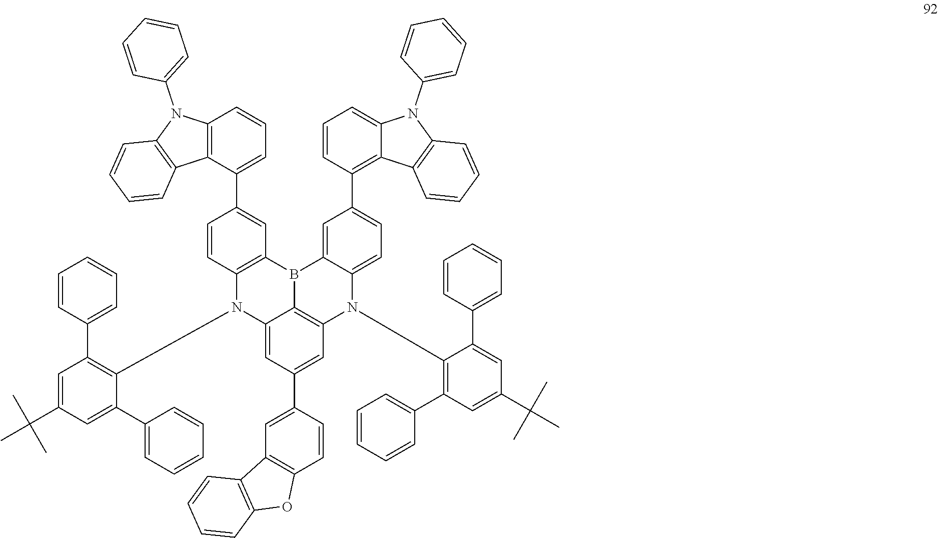 [SMILES: CC(C)(C)c1cc(-c2ccccc2)c(N2c3ccc(-c4cccc5c4c4ccccc4n5-c4ccccc4)cc3B3c4cc(-c5cccc6c5c5ccccc5n6-c5ccccc5)ccc4N(c4c(-c5ccccc5)cc(C(C)(C)C)cc4-c4ccccc4)c4cc(-c5ccc6oc7ccccc7c6c5)cc2c43)c(-c2ccccc2)c1] 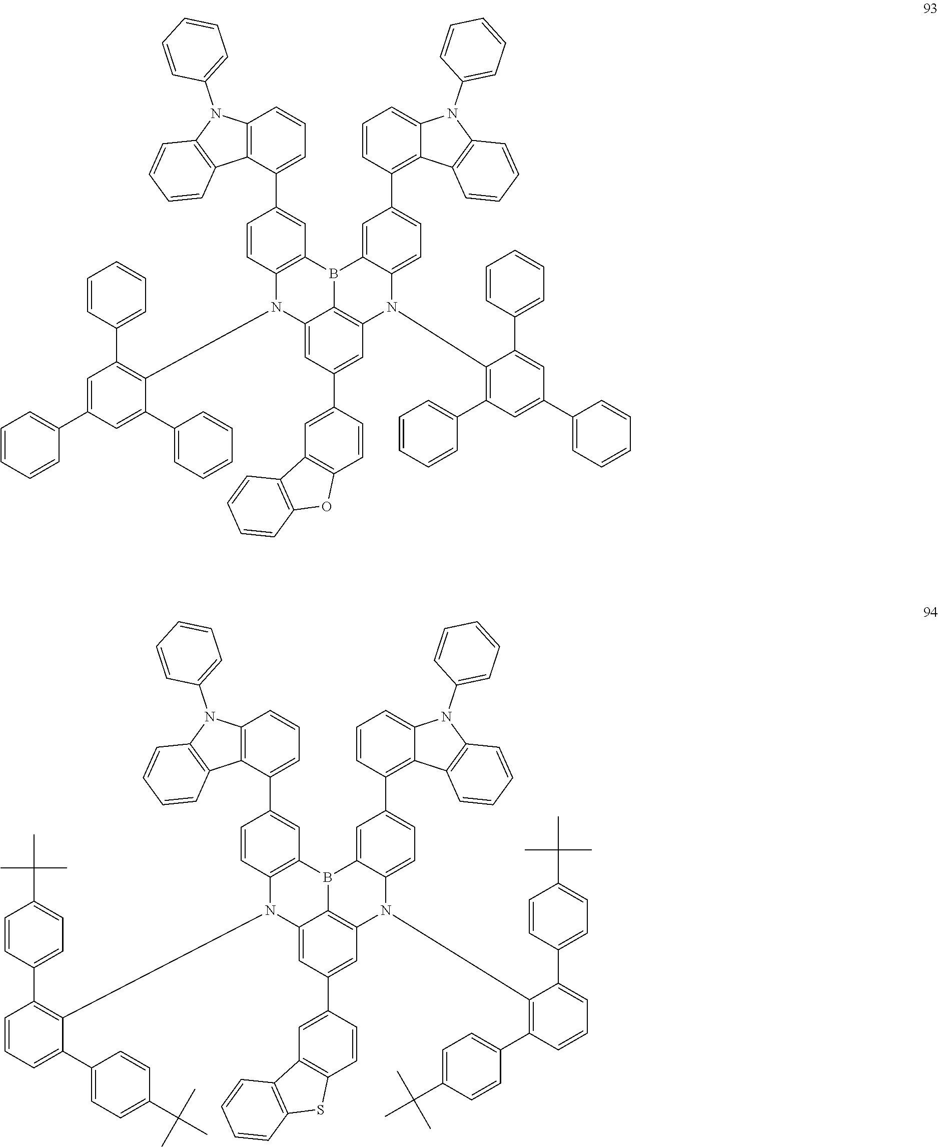 [SMILES: c1ccc(-c2cc(-c3ccccc3)c(N3c4ccc(-c5cccc6c5c5ccccc5n6-c5ccccc5)cc4B4c5cc(-c6cccc7c6c6ccccc6n7-c6ccccc6)ccc5N(c5c(-c6ccccc6)cc(-c6ccccc6)cc5-c5ccccc5)c5cc(-c6ccc7oc8ccccc8c7c6)cc3c54)c(-c3ccccc3)c2)cc1 ; CC(C)(C)c1ccc(-c2cccc(-c3ccc(C(C)(C)C)cc3)c2N2c3ccc(-c4cccc5c4c4ccccc4n5-c4ccccc4)cc3B3c4cc(-c5cccc6c5c5ccccc5n6-c5ccccc5)ccc4N(c4c(-c5ccc(C(C)(C)C)cc5)cccc4-c4ccc(C(C)(C)C)cc4)c4cc(-c5ccc6sc7ccccc7c6c5)cc2c43)cc1] 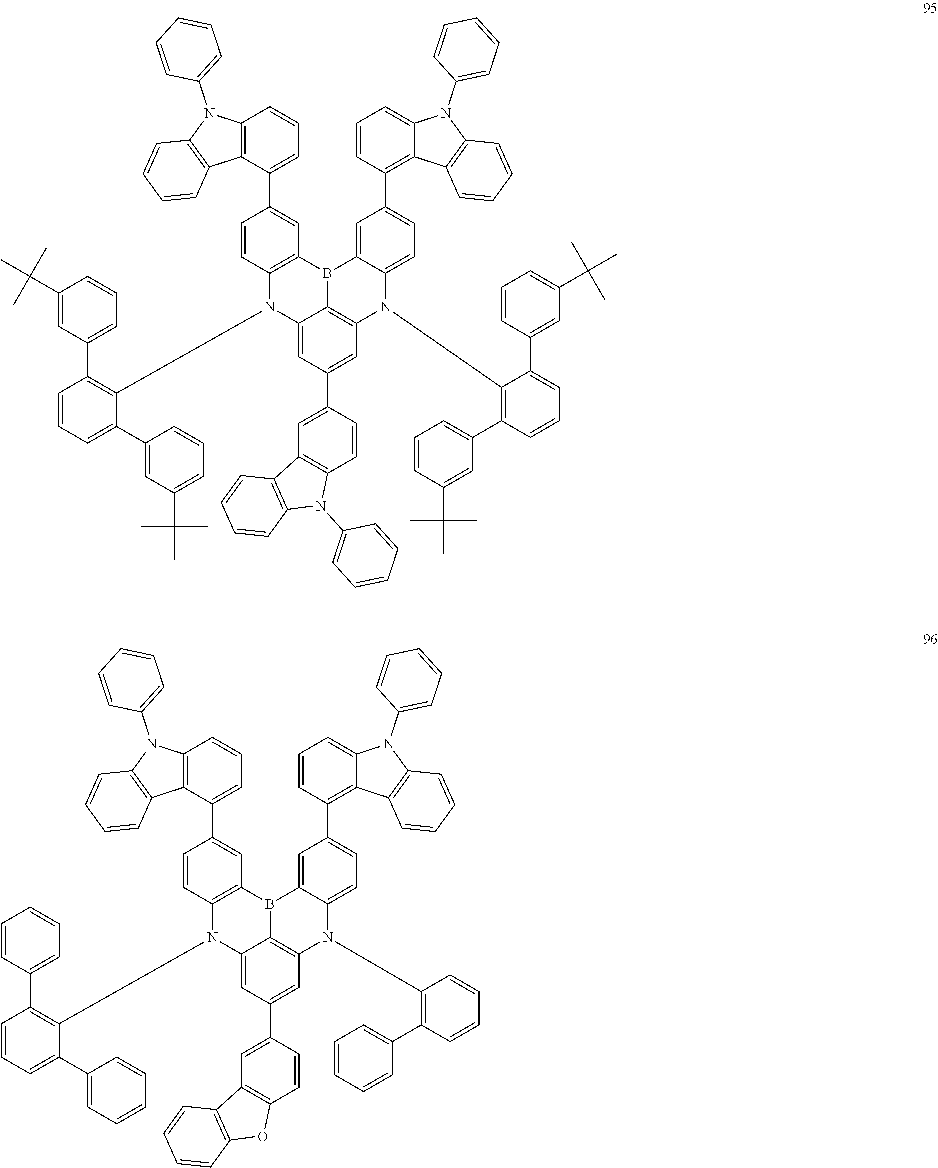 [SMILES: CC(C)(C)c1cccc(-c2cccc(-c3cccc(C(C)(C)C)c3)c2N2c3ccc(-c4cccc5c4c4ccccc4n5-c4ccccc4)cc3B3c4cc(-c5cccc6c5c5ccccc5n6-c5ccccc5)ccc4N(c4c(-c5cccc(C(C)(C)C)c5)cccc4-c4cccc(C(C)(C)C)c4)c4cc(-c5ccc6c(c5)c5ccccc5n6-c5ccccc5)cc2c43)c1 ; c1ccc(-c2ccccc2N2c3ccc(-c4cccc5c4c4ccccc4n5-c4ccccc4)cc3B3c4cc(-c5cccc6c5c5ccccc5n6-c5ccccc5)ccc4N(c4c(-c5ccccc5)cccc4-c4ccccc4)c4cc(-c5ccc6oc7ccccc7c6c5)cc2c43)cc1] 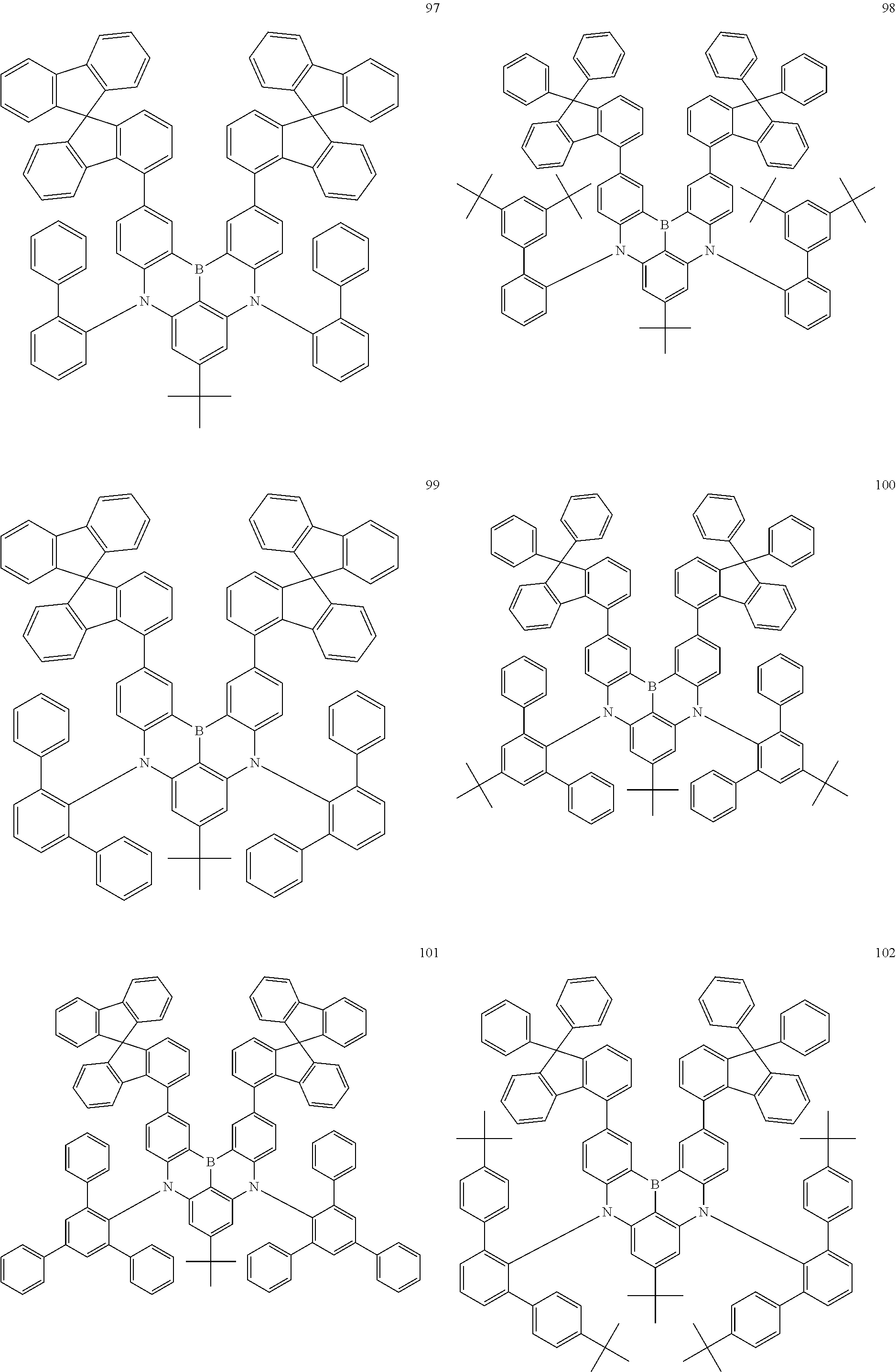 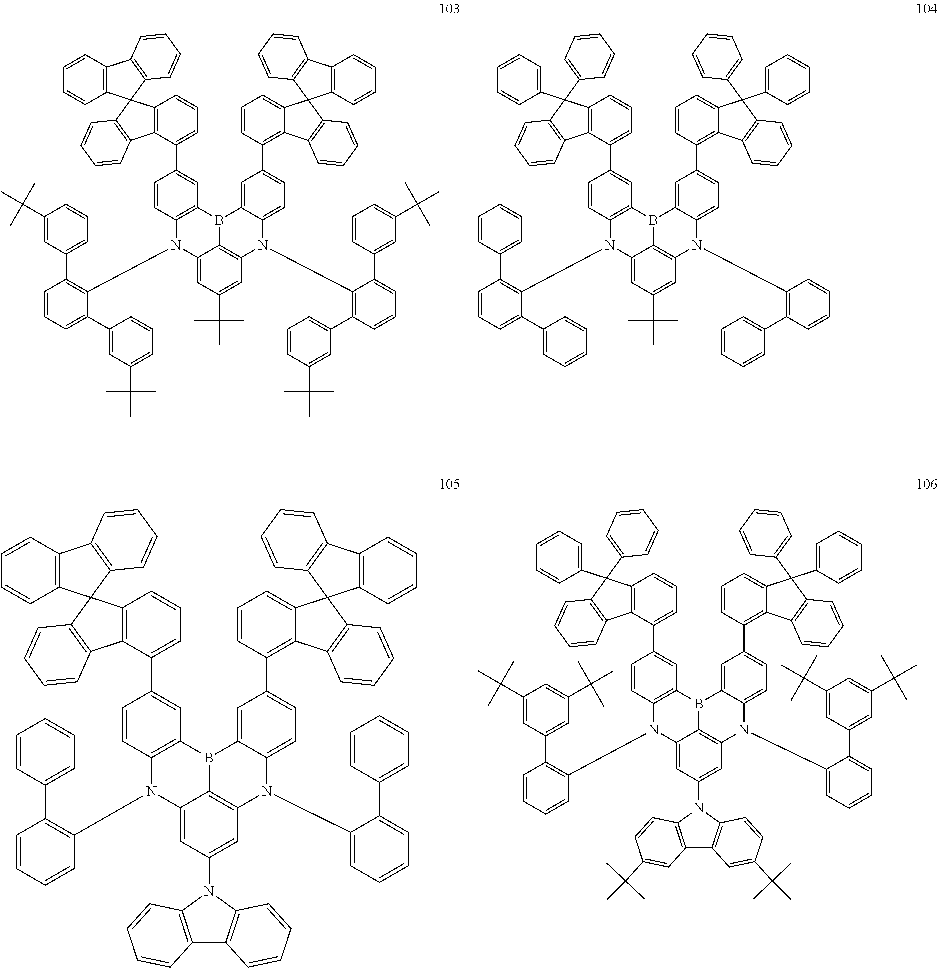 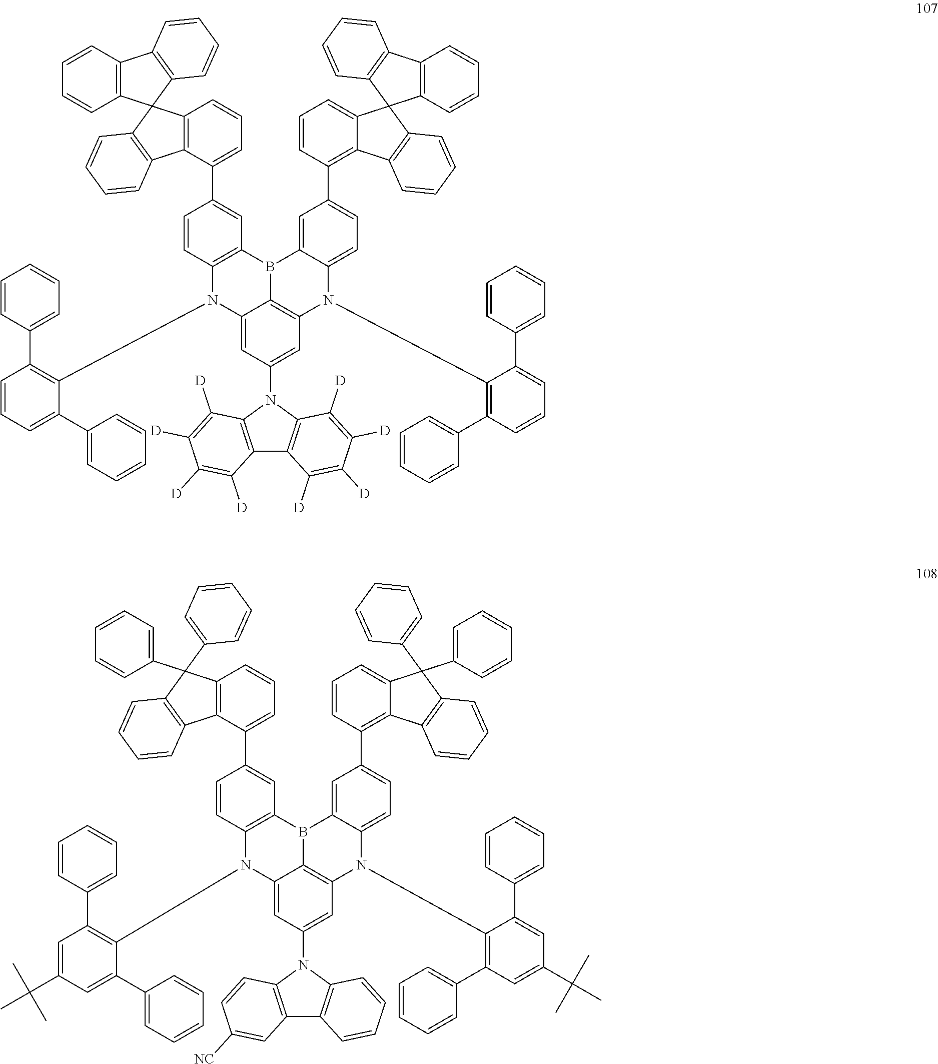 [SMILES: [2H]c1c([2H])c([2H])c2c(c1[2H])c1c([2H])c([2H])c([2H])c([2H])c1n2-c1cc2c3c(c1)N(c1c(-c4ccccc4)cccc1-c1ccccc1)c1ccc(-c4cccc5c4-c4ccccc4C54c5ccccc5-c5ccccc54)cc1B3c1cc(-c3cccc4c3-c3ccccc3C43c4ccccc4-c4ccccc43)ccc1N2c1c(-c2ccccc2)cccc1-c1ccccc1 ; CC(C)(C)c1cc(-c2ccccc2)c(N2c3ccc(-c4cccc5c4-c4ccccc4C5(c4ccccc4)c4ccccc4)cc3B3c4cc(-c5cccc6c5-c5ccccc5C6(c5ccccc5)c5ccccc5)ccc4N(c4c(-c5ccccc5)cc(C(C)(C)C)cc4-c4ccccc4)c4cc(-n5c6ccccc6c6cc(C#N)ccc65)cc2c43)c(-c2ccccc2)c1] 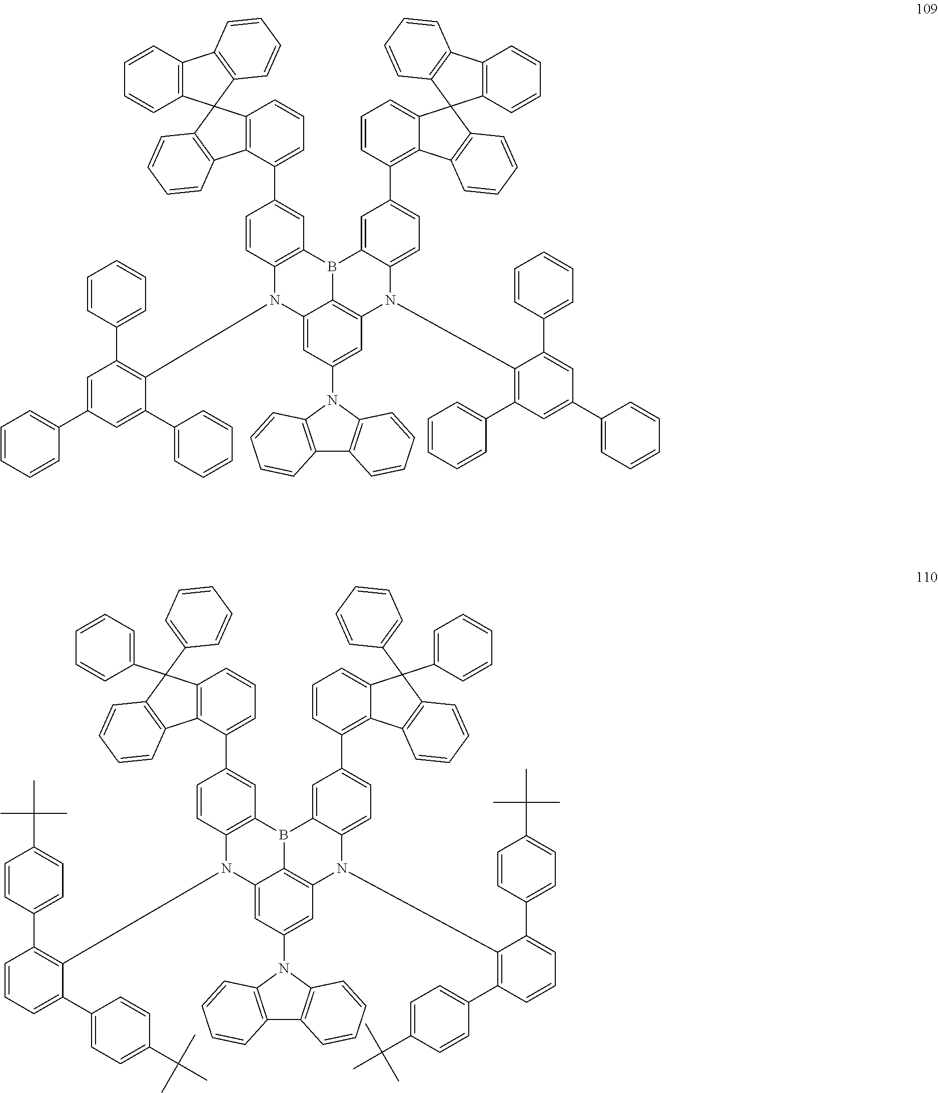 [SMILES: c1ccc(-c2cc(-c3ccccc3)c(N3c4ccc(-c5cccc6c5-c5ccccc5C65c6ccccc6-c6ccccc65)cc4B4c5cc(-c6cccc7c6-c6ccccc6C76c7ccccc7-c7ccccc76)ccc5N(c5c(-c6ccccc6)cc(-c6ccccc6)cc5-c5ccccc5)c5cc(-n6c7ccccc7c7ccccc76)cc3c54)c(-c3ccccc3)c2)cc1 ; CC(C)(C)c1ccc(-c2cccc(-c3ccc(C(C)(C)C)cc3)c2N2c3ccc(-c4cccc5c4-c4ccccc4C5(c4ccccc4)c4ccccc4)cc3B3c4cc(-c5cccc6c5-c5ccccc5C6(c5ccccc5)c5ccccc5)ccc4N(c4c(-c5ccc(C(C)(C)C)cc5)cccc4-c4ccc(C(C)(C)C)cc4)c4cc(-n5c6ccccc6c6ccccc65)cc2c43)cc1] 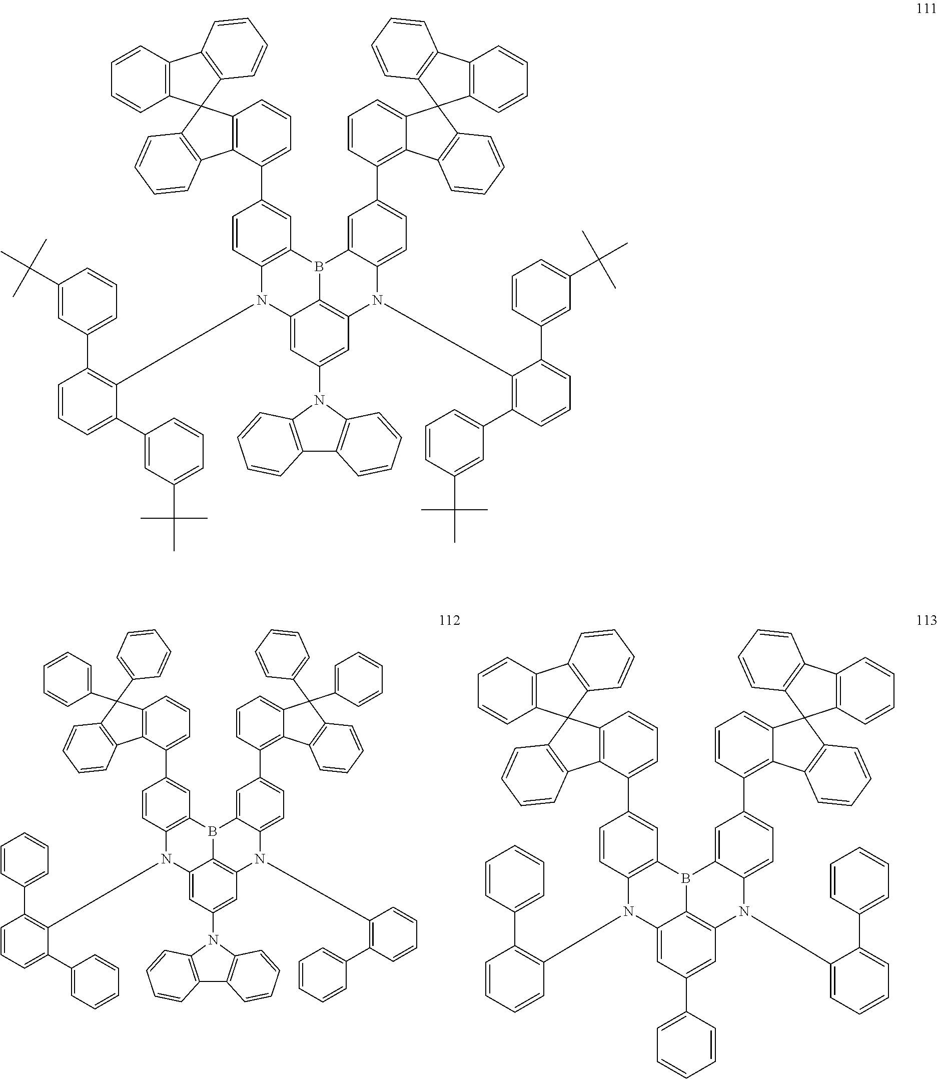 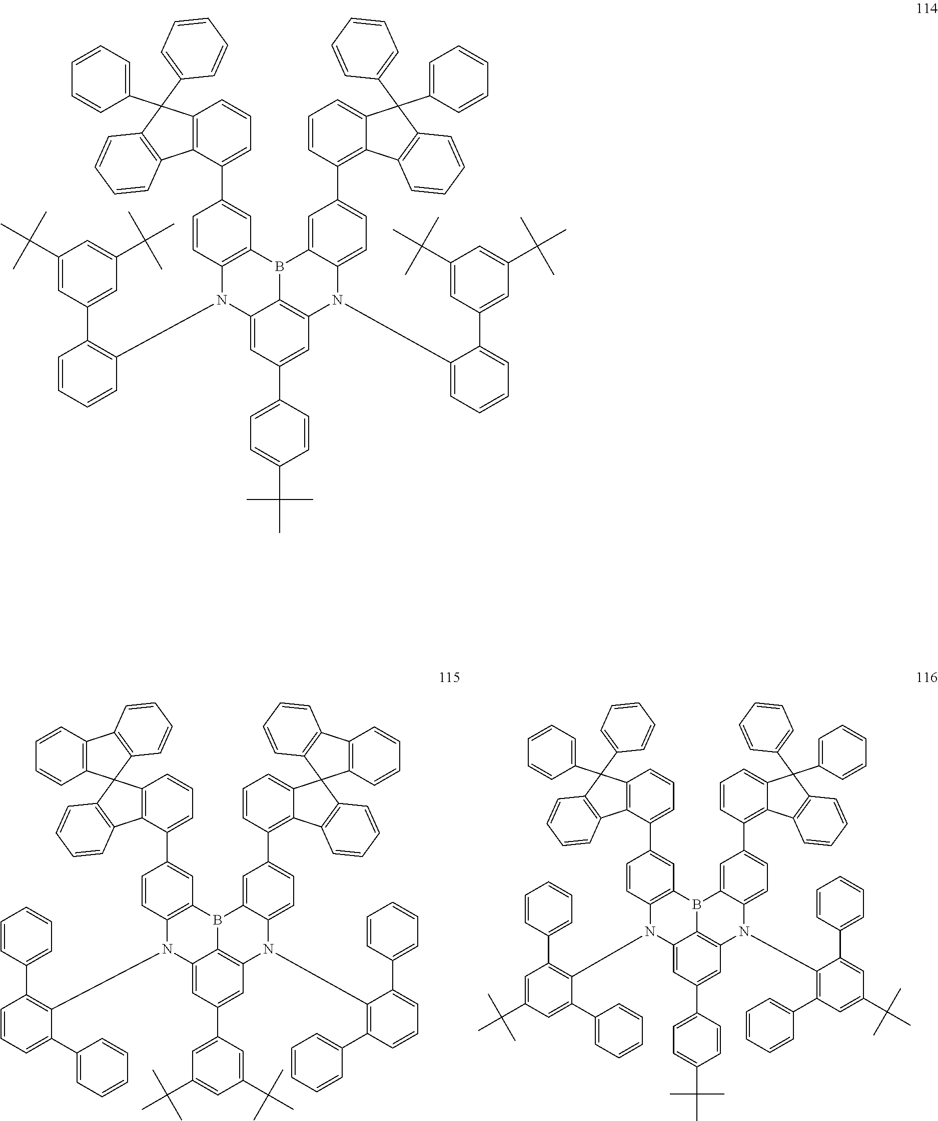 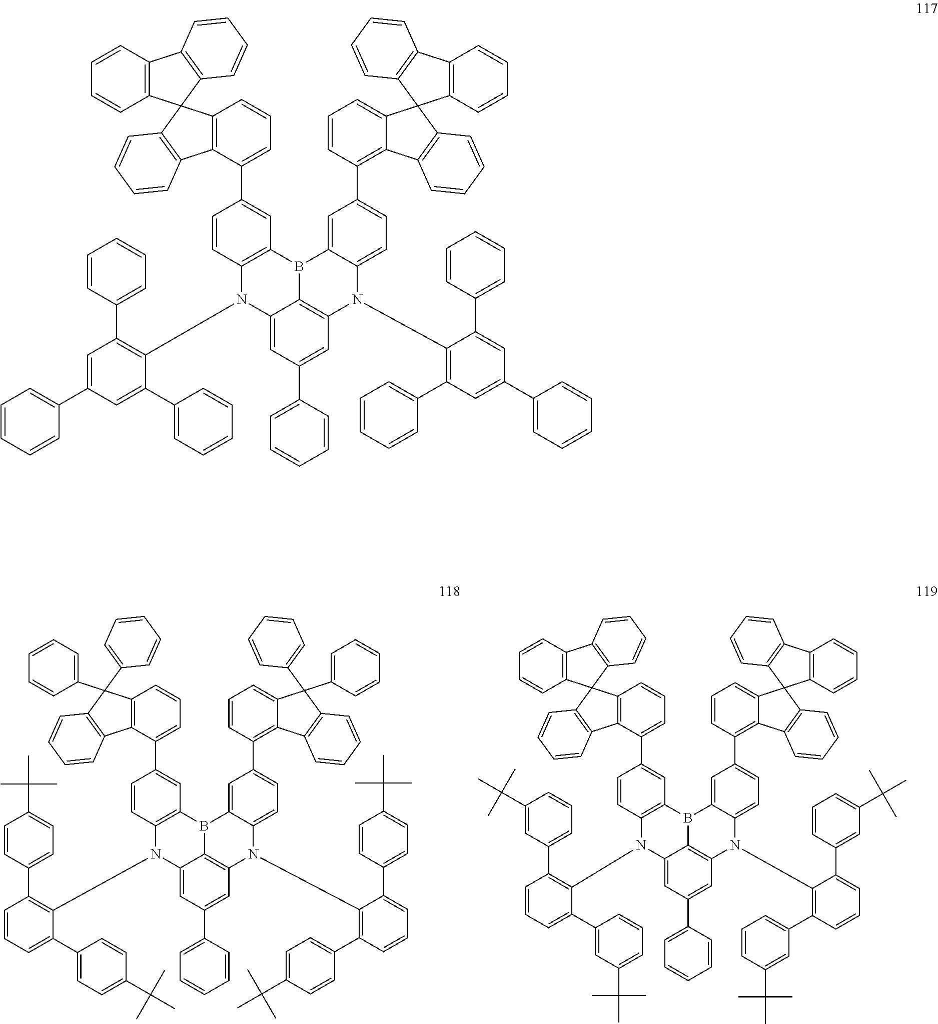 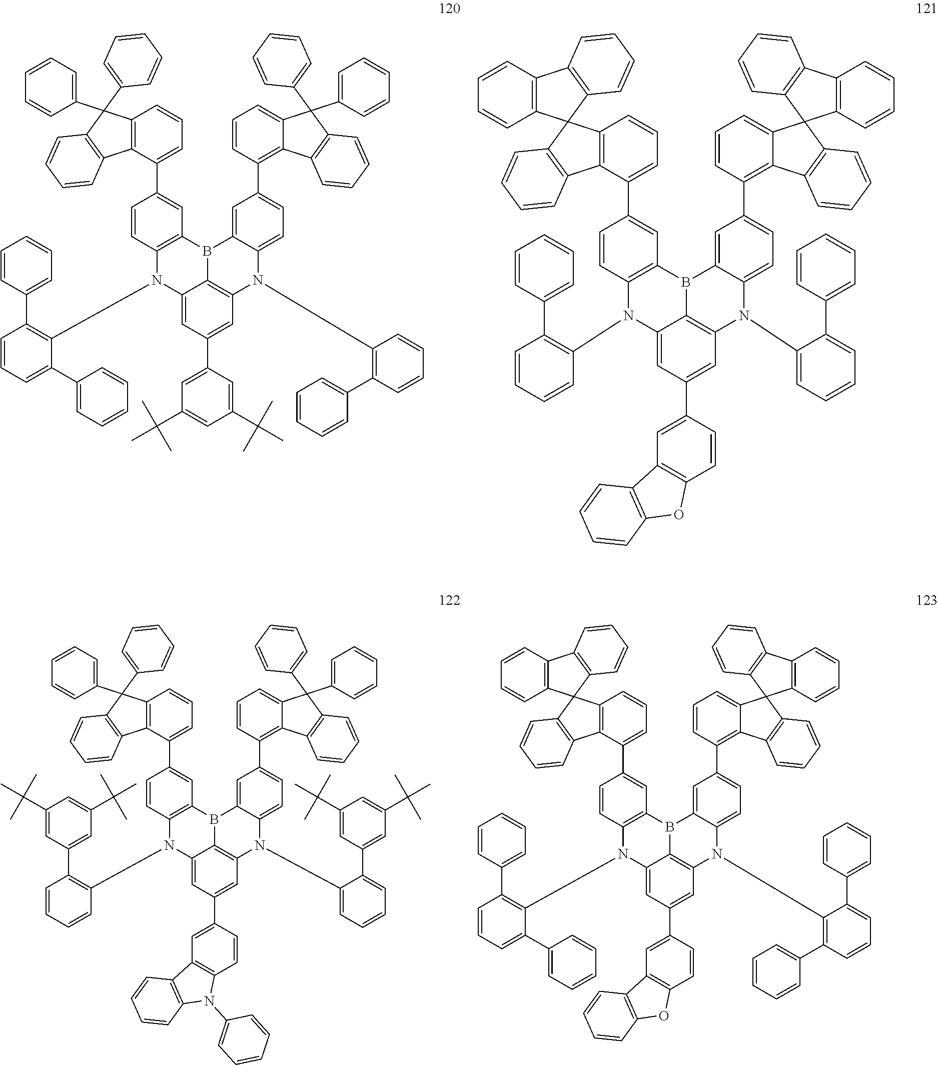 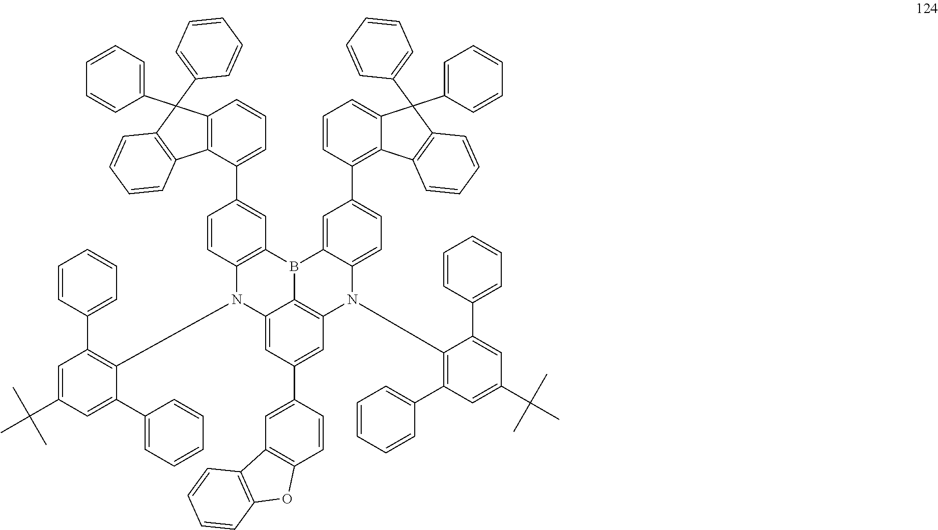 [SMILES: CC(C)(C)c1cc(-c2ccccc2)c(N2c3ccc(-c4cccc5c4-c4ccccc4C5(c4ccccc4)c4ccccc4)cc3B3c4cc(-c5cccc6c5-c5ccccc5C6(c5ccccc5)c5ccccc5)ccc4N(c4c(-c5ccccc5)cc(C(C)(C)C)cc4-c4ccccc4)c4cc(-c5ccc6oc7ccccc7c6c5)cc2c43)c(-c2ccccc2)c1] 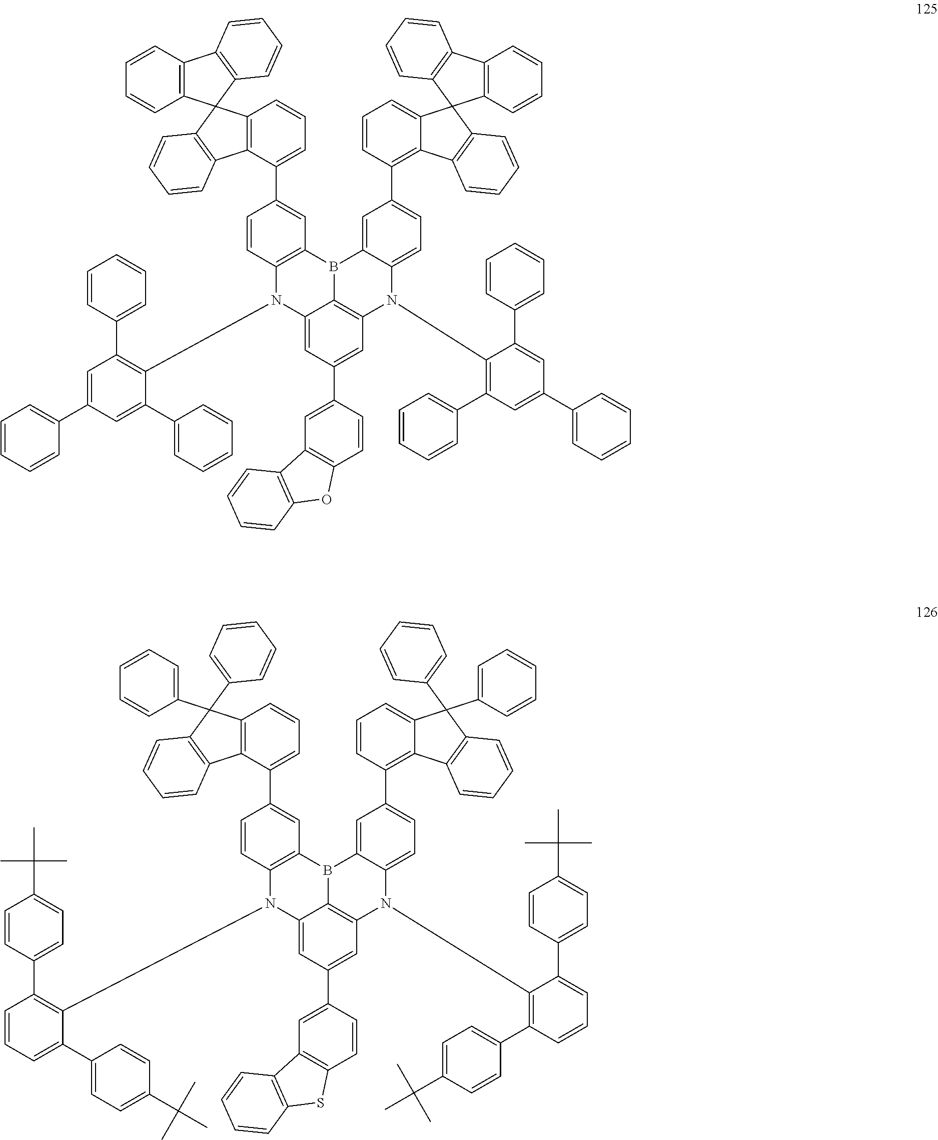 [SMILES: c1ccc(-c2cc(-c3ccccc3)c(N3c4ccc(-c5cccc6c5-c5ccccc5C65c6ccccc6-c6ccccc65)cc4B4c5cc(-c6cccc7c6-c6ccccc6C76c7ccccc7-c7ccccc76)ccc5N(c5c(-c6ccccc6)cc(-c6ccccc6)cc5-c5ccccc5)c5cc(-c6ccc7oc8ccccc8c7c6)cc3c54)c(-c3ccccc3)c2)cc1 ; CC(C)(C)c1ccc(-c2cccc(-c3ccc(C(C)(C)C)cc3)c2N2c3ccc(-c4cccc5c4-c4ccccc4C5(c4ccccc4)c4ccccc4)cc3B3c4cc(-c5cccc6c5-c5ccccc5C6(c5ccccc5)c5ccccc5)ccc4N(c4c(-c5ccc(C(C)(C)C)cc5)cccc4-c4ccc(C(C)(C)C)cc4)c4cc(-c5ccc6sc7ccccc7c6c5)cc2c43)cc1] 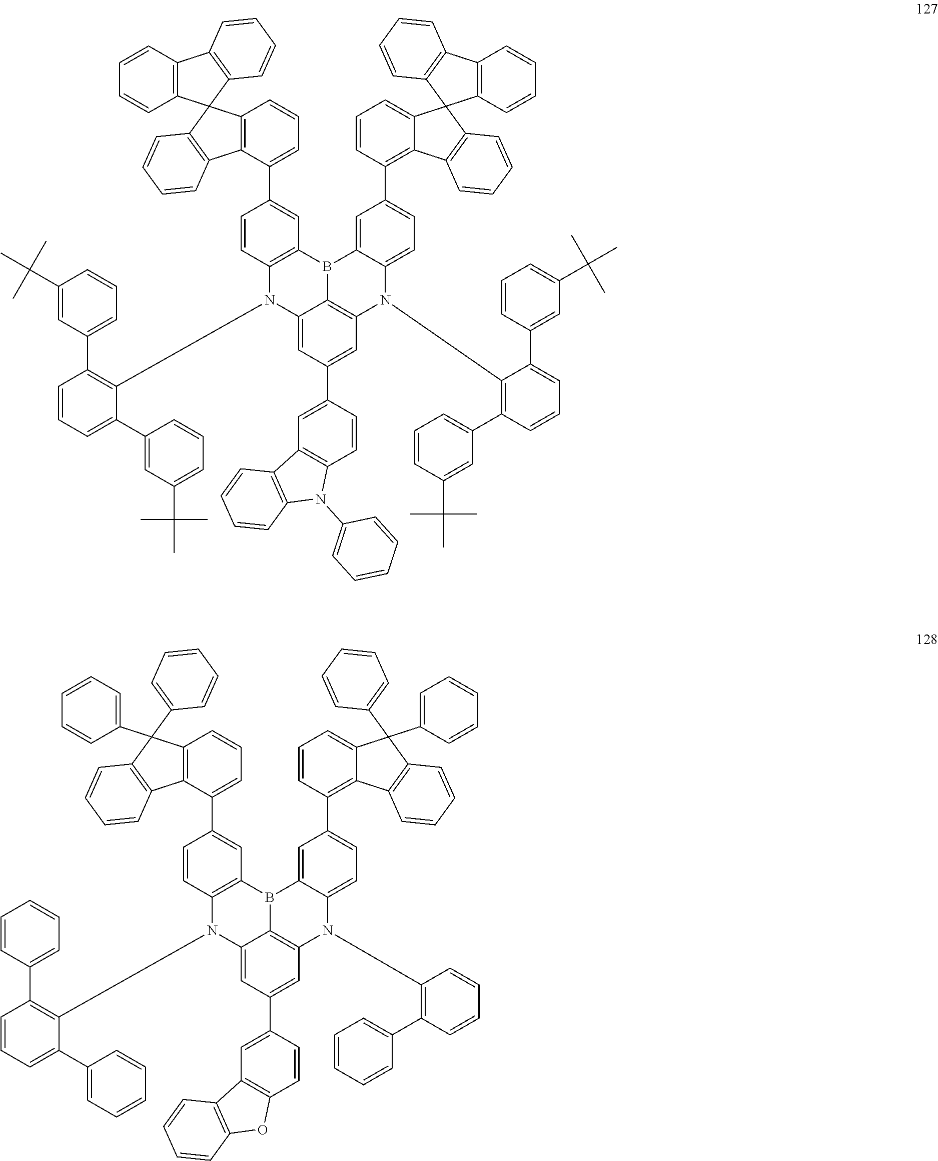 [SMILES: CC(C)(C)c1cccc(-c2cccc(-c3cccc(C(C)(C)C)c3)c2N2c3ccc(-c4cccc5c4-c4ccccc4C54c5ccccc5-c5ccccc54)cc3B3c4cc(-c5cccc6c5-c5ccccc5C65c6ccccc6-c6ccccc65)ccc4N(c4c(-c5cccc(C(C)(C)C)c5)cccc4-c4cccc(C(C)(C)C)c4)c4cc(-c5ccc6c(c5)c5ccccc5n6-c5ccccc5)cc2c43)c1 ; c1ccc(-c2ccccc2N2c3ccc(-c4cccc5c4-c4ccccc4C5(c4ccccc4)c4ccccc4)cc3B3c4cc(-c5cccc6c5-c5ccccc5C6(c5ccccc5)c5ccccc5)ccc4N(c4c(-c5ccccc5)cccc4-c4ccccc4)c4cc(-c5ccc6oc7ccccc7c6c5)cc2c43)cc1] 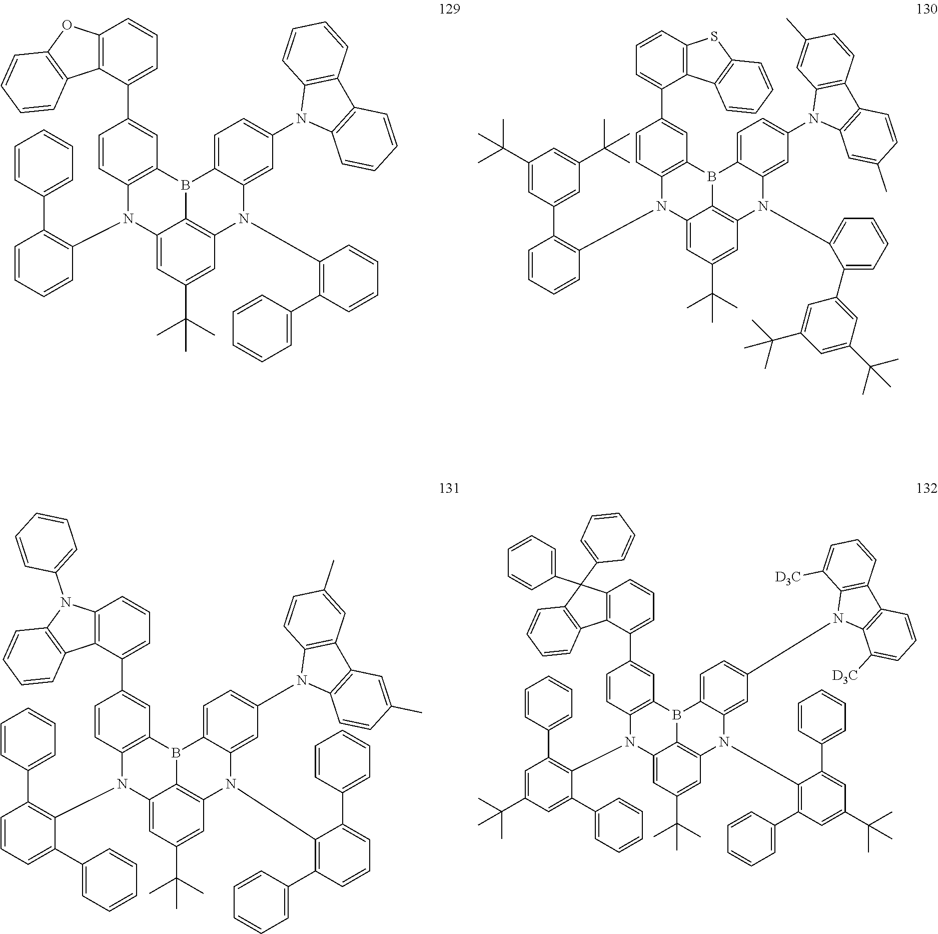 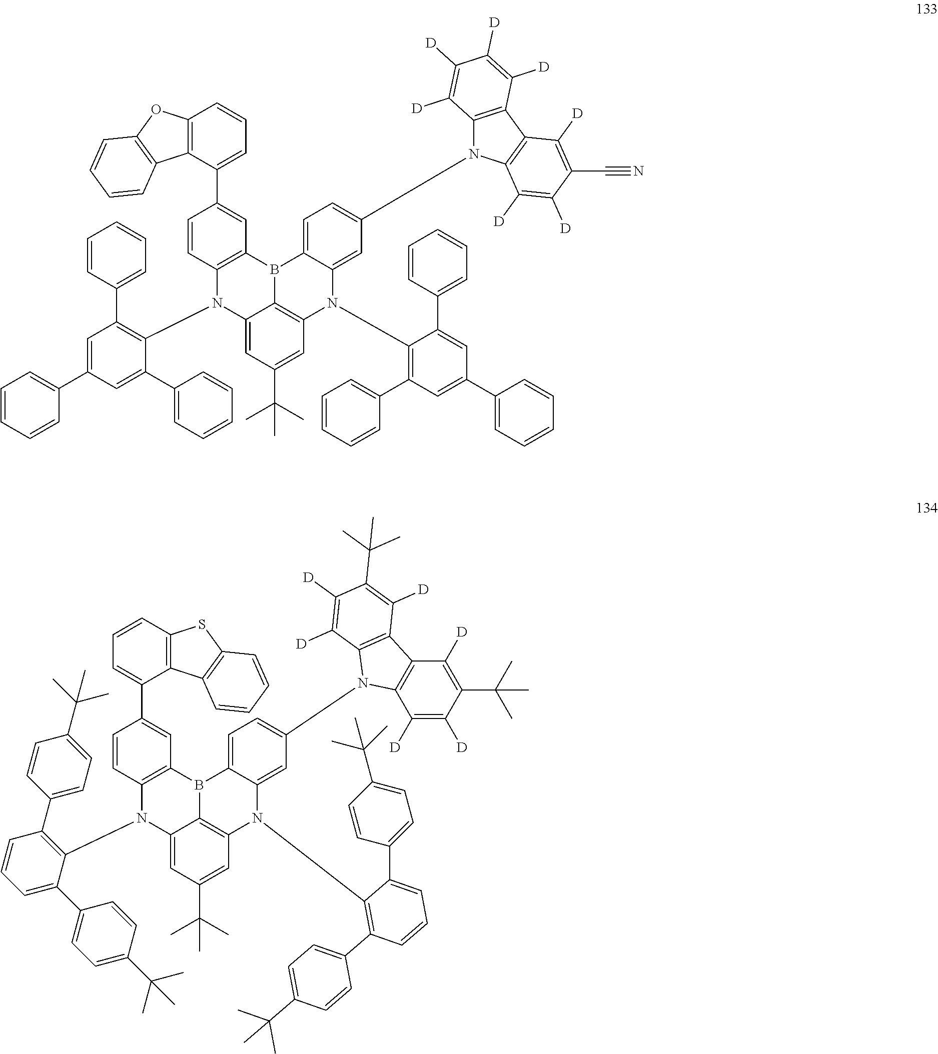 [SMILES: [2H]c1c([2H])c([2H])c2c(c1[2H])c1c([2H])c(C#N)c([2H])c([2H])c1n2-c1ccc2c(c1)N(c1c(-c3ccccc3)cc(-c3ccccc3)cc1-c1ccccc1)c1cc(C(C)(C)C)cc3c1B2c1cc(-c2cccc4oc5ccccc5c24)ccc1N3c1c(-c2ccccc2)cc(-c2ccccc2)cc1-c1ccccc1 ; [2H]c1c(C(C)(C)C)c([2H])c2c3c([2H])c(C(C)(C)C)c([2H])c([2H])c3n(-c3ccc4c(c3)N(c3c(-c5ccc(C(C)(C)C)cc5)cccc3-c3ccc(C(C)(C)C)cc3)c3cc(C(C)(C)C)cc5c3B4c3cc(-c4cccc6sc7ccccc7c46)ccc3N5c3c(-c4ccc(C(C)(C)C)cc4)cccc3-c3ccc(C(C)(C)C)cc3)c2c1[2H]] 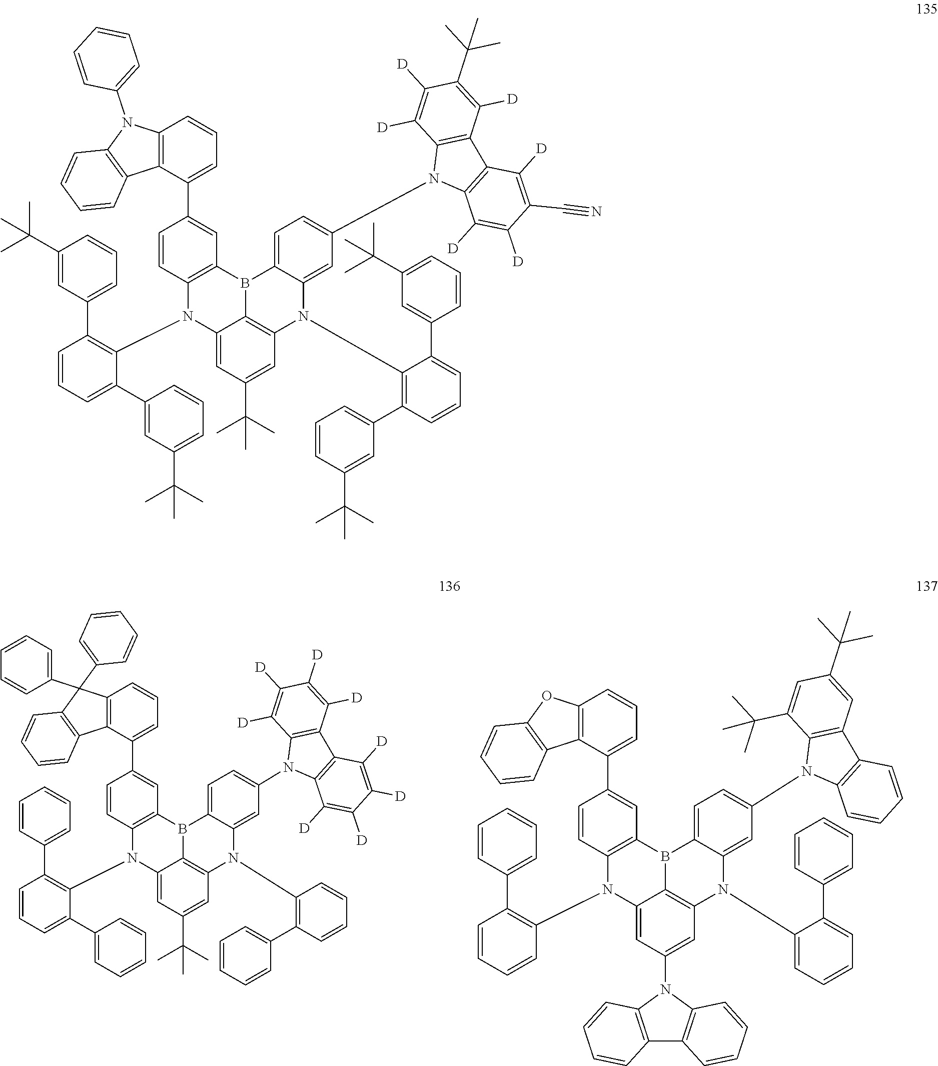 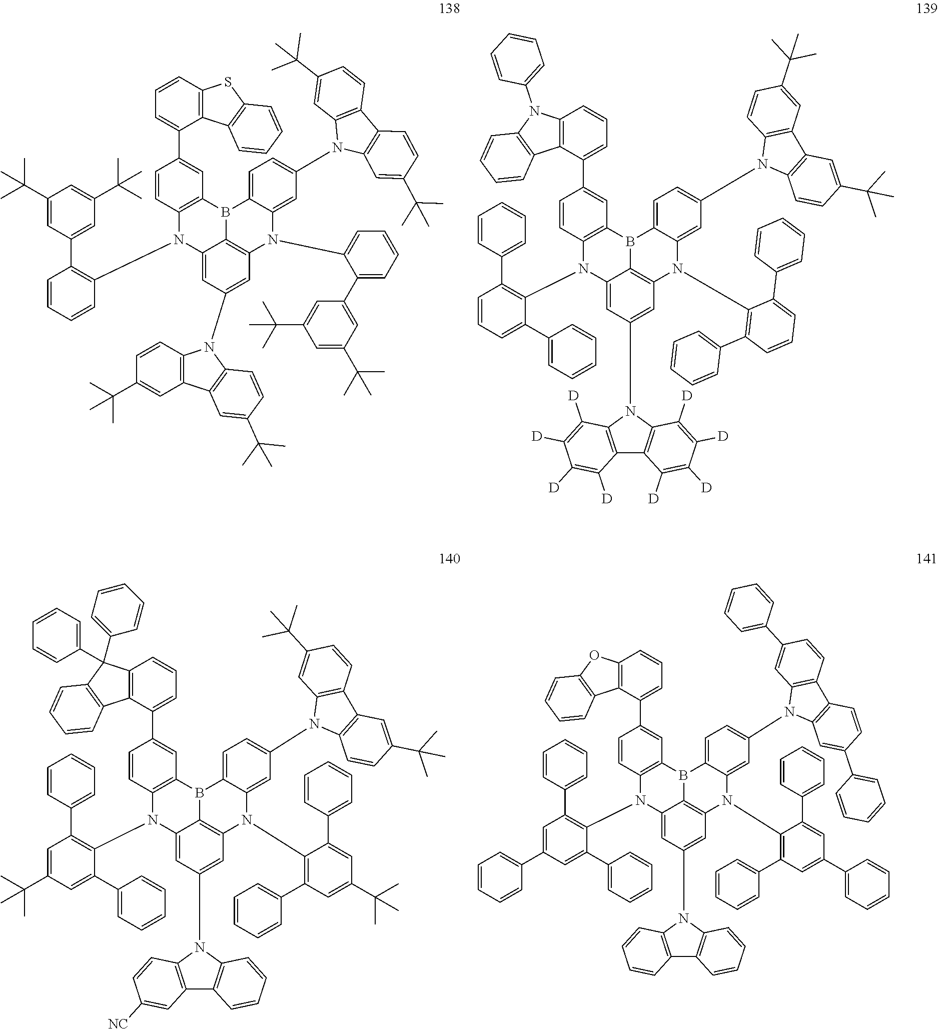 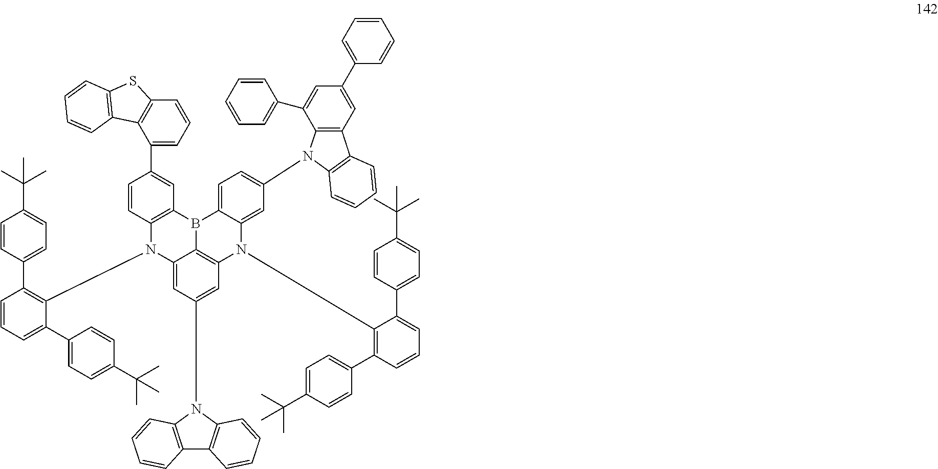 [SMILES: CC(C)(C)c1ccc(-c2cccc(-c3ccc(C(C)(C)C)cc3)c2N2c3ccc(-c4cccc5sc6ccccc6c45)cc3B3c4ccc(-n5c6ccccc6c6cc(-c7ccccc7)cc(-c7ccccc7)c65)cc4N(c4c(-c5ccc(C(C)(C)C)cc5)cccc4-c4ccc(C(C)(C)C)cc4)c4cc(-n5c6ccccc6c6ccccc65)cc2c43)cc1] 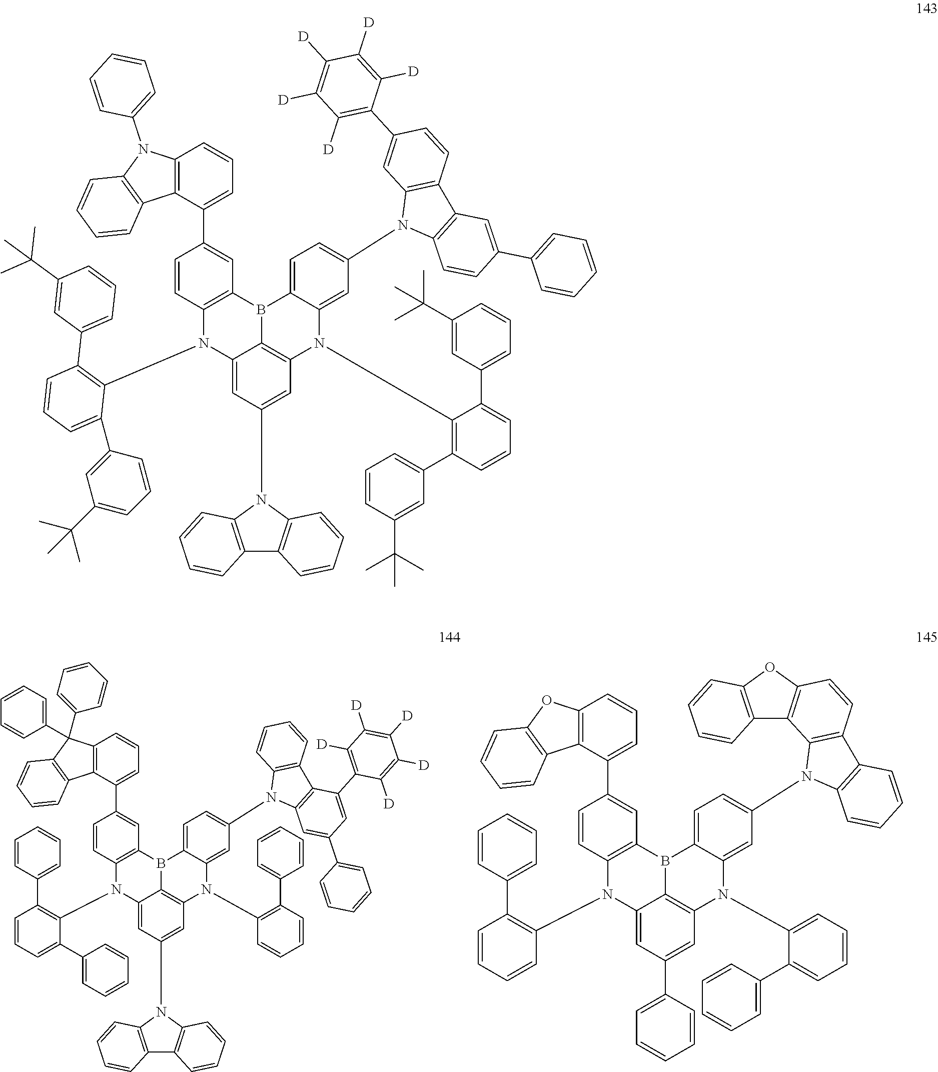 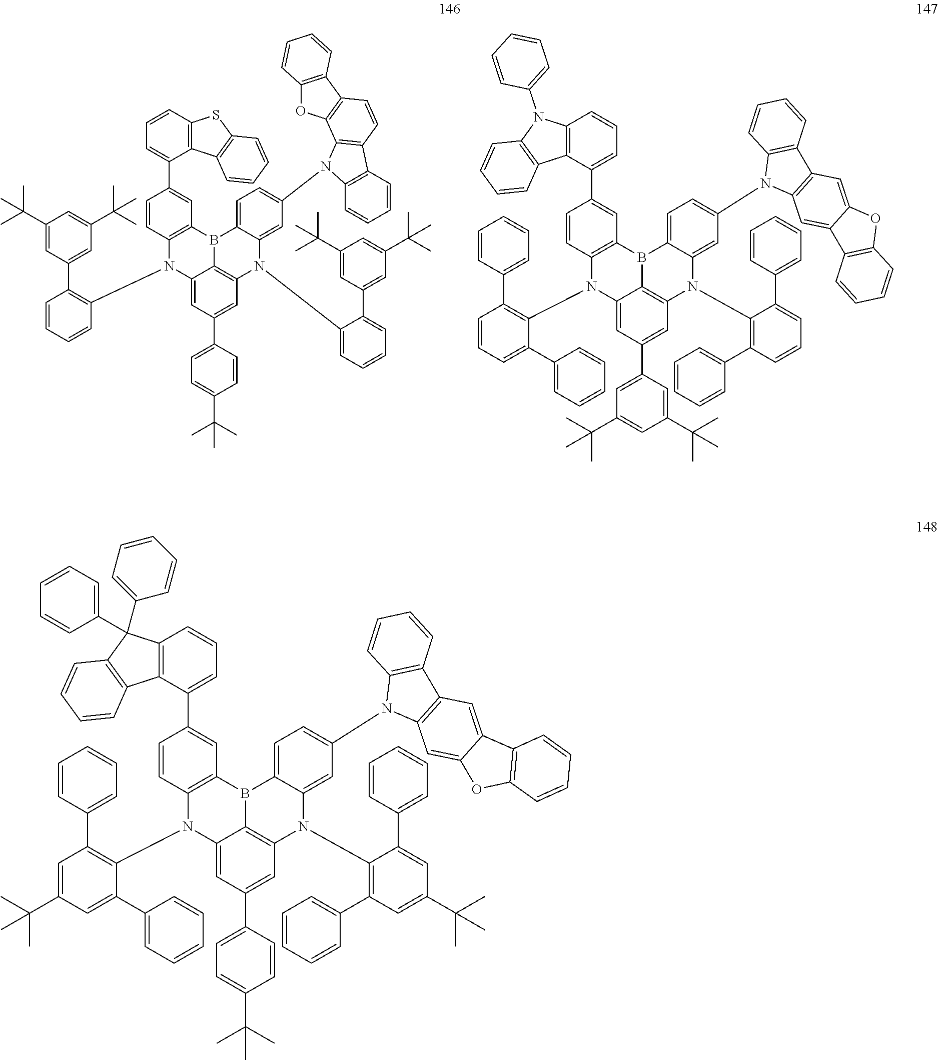 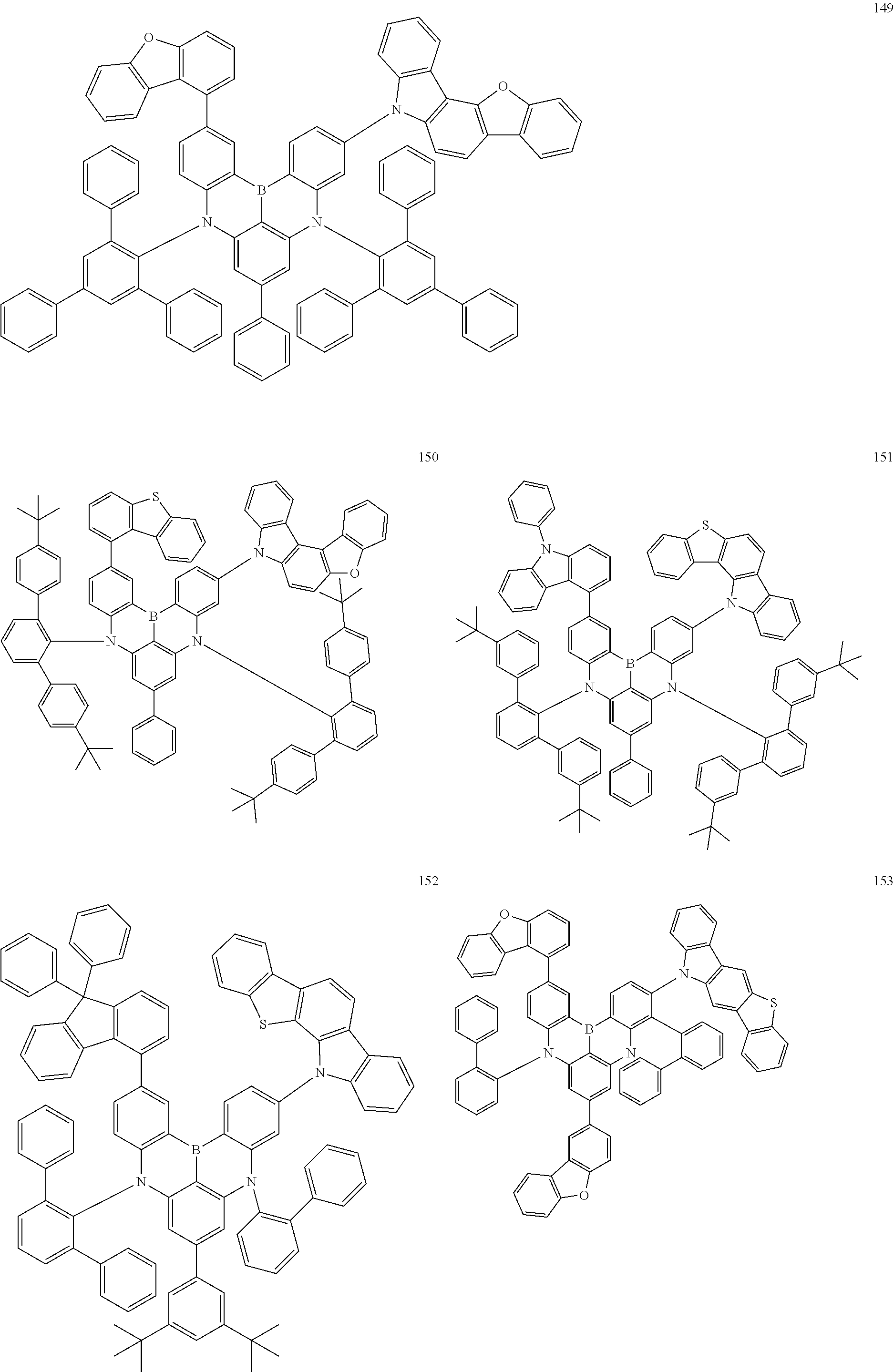 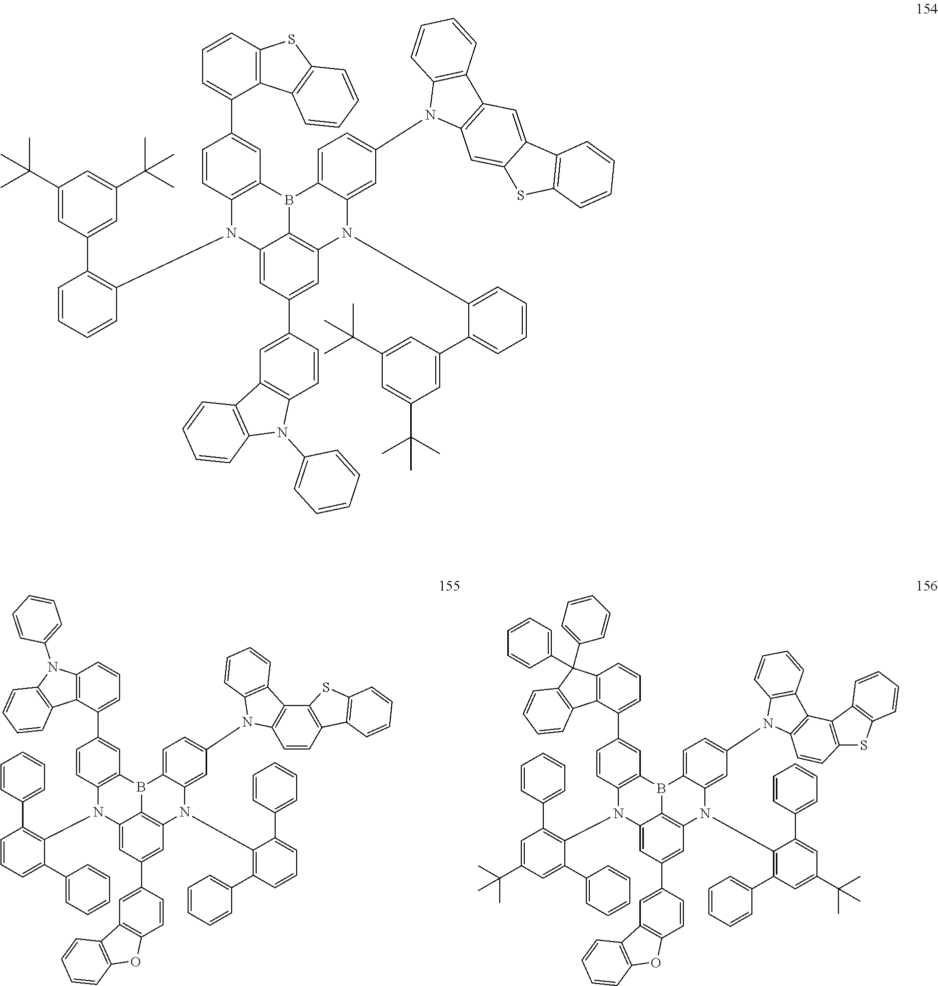 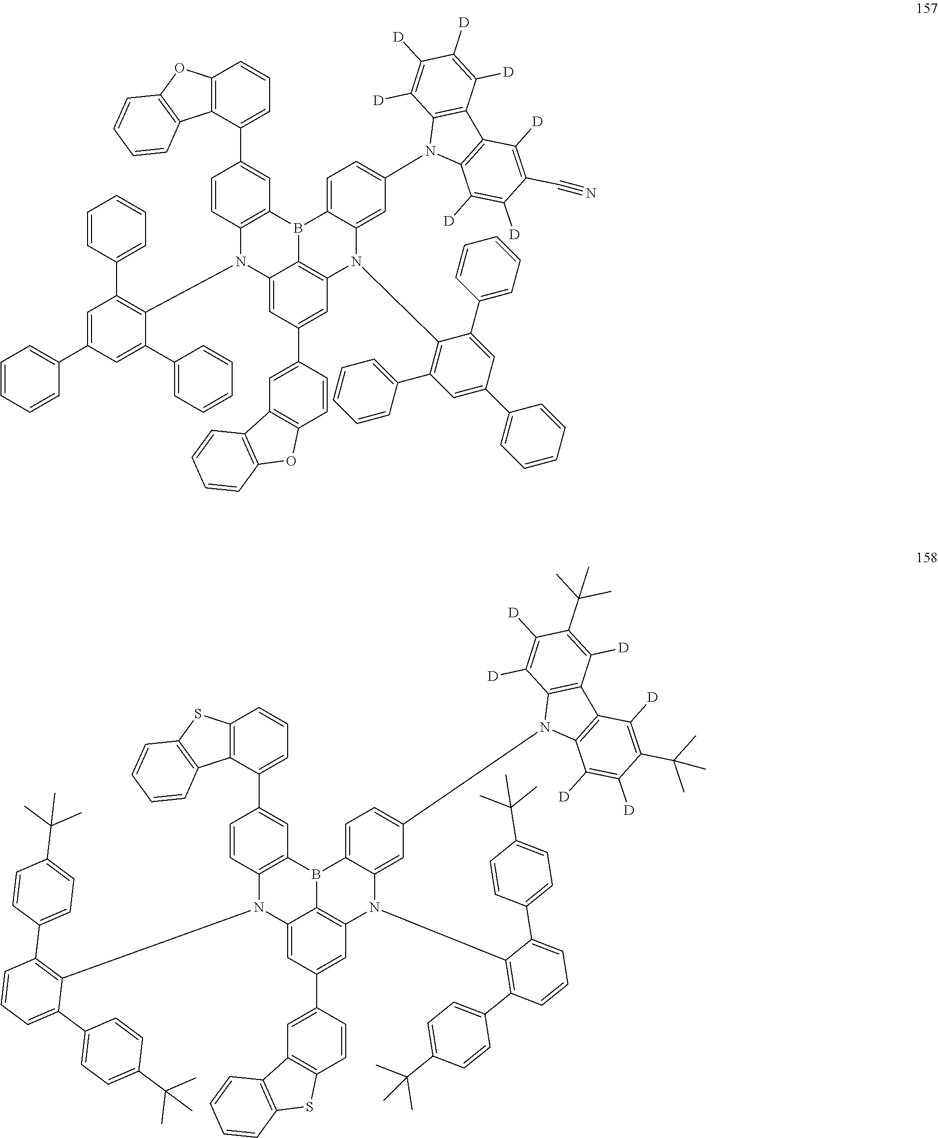 [SMILES: [2H]c1c([2H])c([2H])c2c(c1[2H])c1c([2H])c(C#N)c([2H])c([2H])c1n2-c1ccc2c(c1)N(c1c(-c3ccccc3)cc(-c3ccccc3)cc1-c1ccccc1)c1cc(-c3ccc4oc5ccccc5c4c3)cc3c1B2c1cc(-c2cccc4oc5ccccc5c24)ccc1N3c1c(-c2ccccc2)cc(-c2ccccc2)cc1-c1ccccc1 ; [2H]c1c(C(C)(C)C)c([2H])c2c3c([2H])c(C(C)(C)C)c([2H])c([2H])c3n(-c3ccc4c(c3)N(c3c(-c5ccc(C(C)(C)C)cc5)cccc3-c3ccc(C(C)(C)C)cc3)c3cc(-c5ccc6sc7ccccc7c6c5)cc5c3B4c3cc(-c4cccc6sc7ccccc7c46)ccc3N5c3c(-c4ccc(C(C)(C)C)cc4)cccc3-c3ccc(C(C)(C)C)cc3)c2c1[2H]] 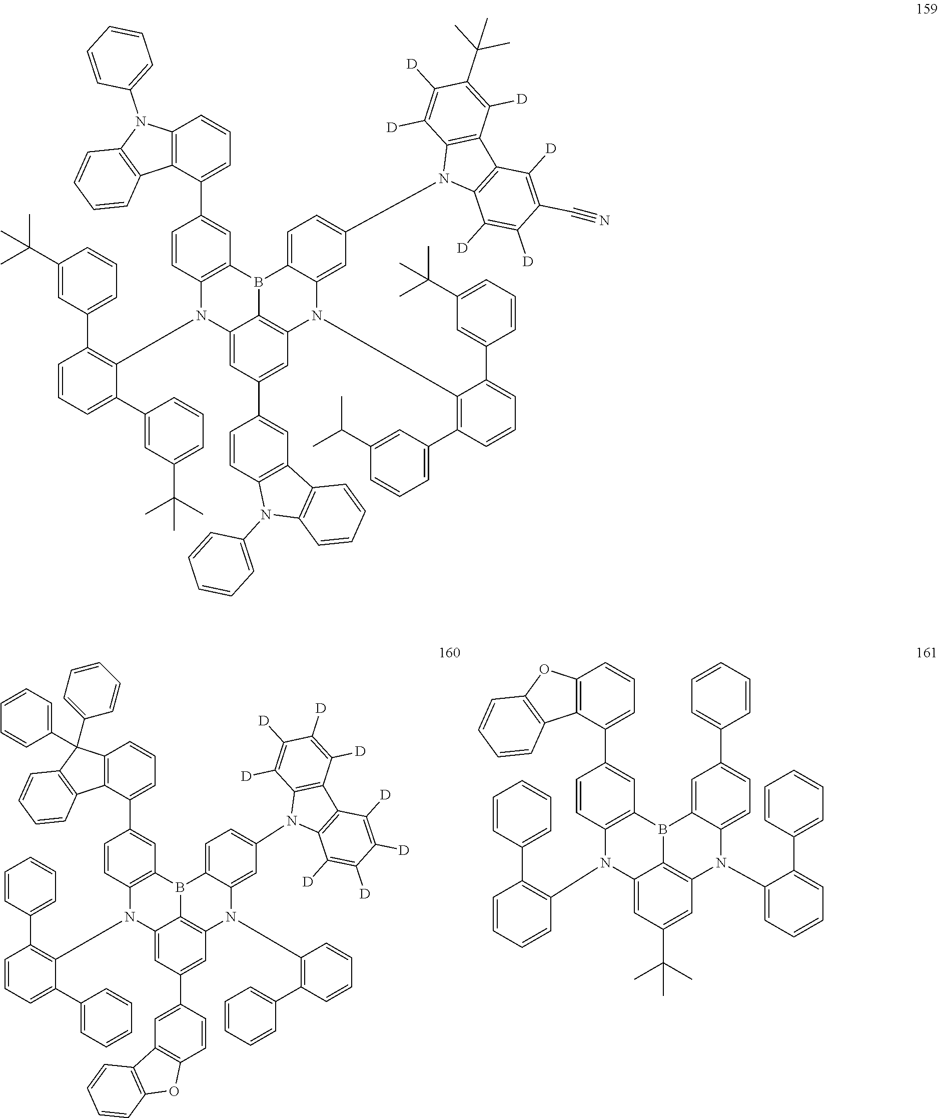 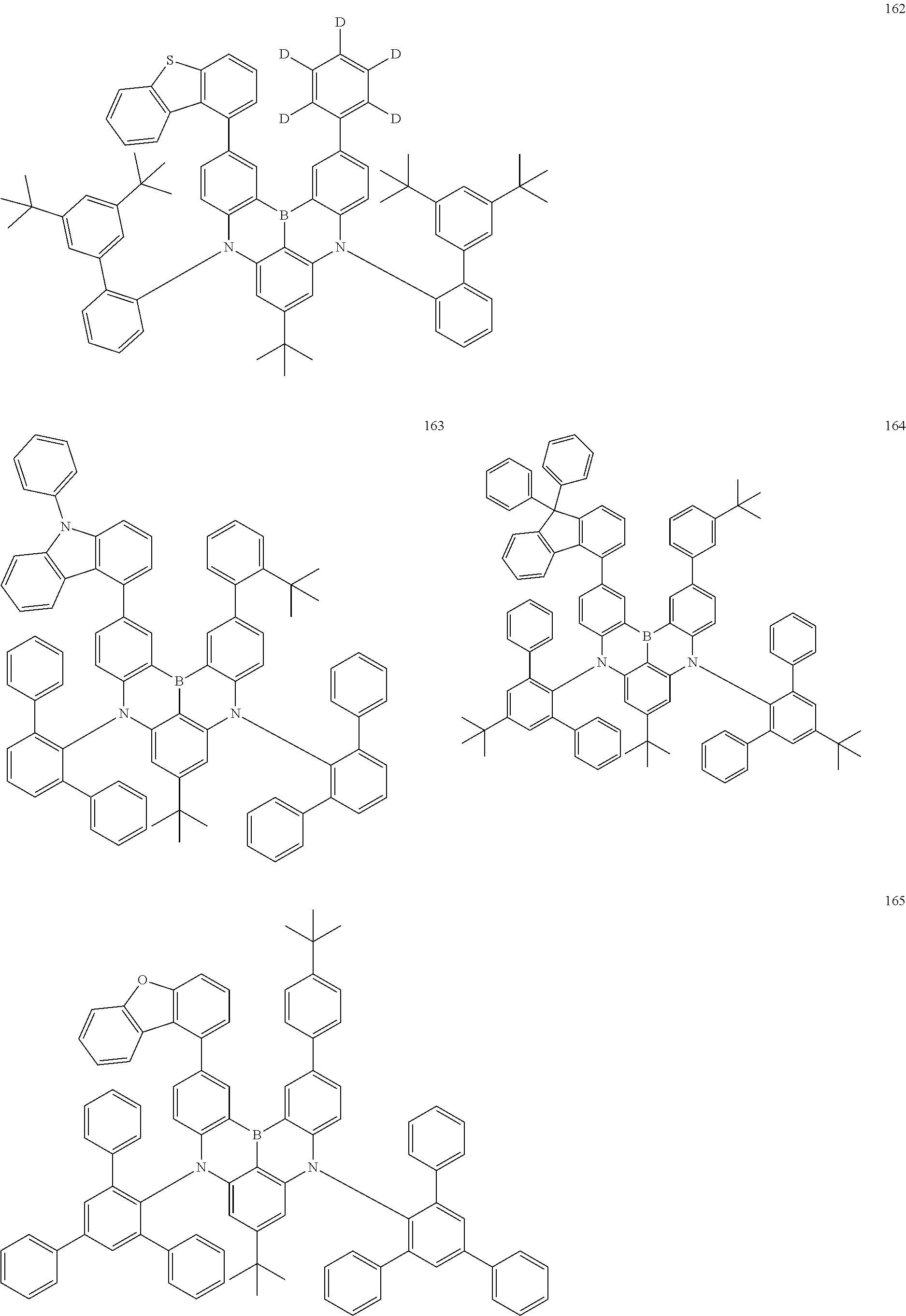 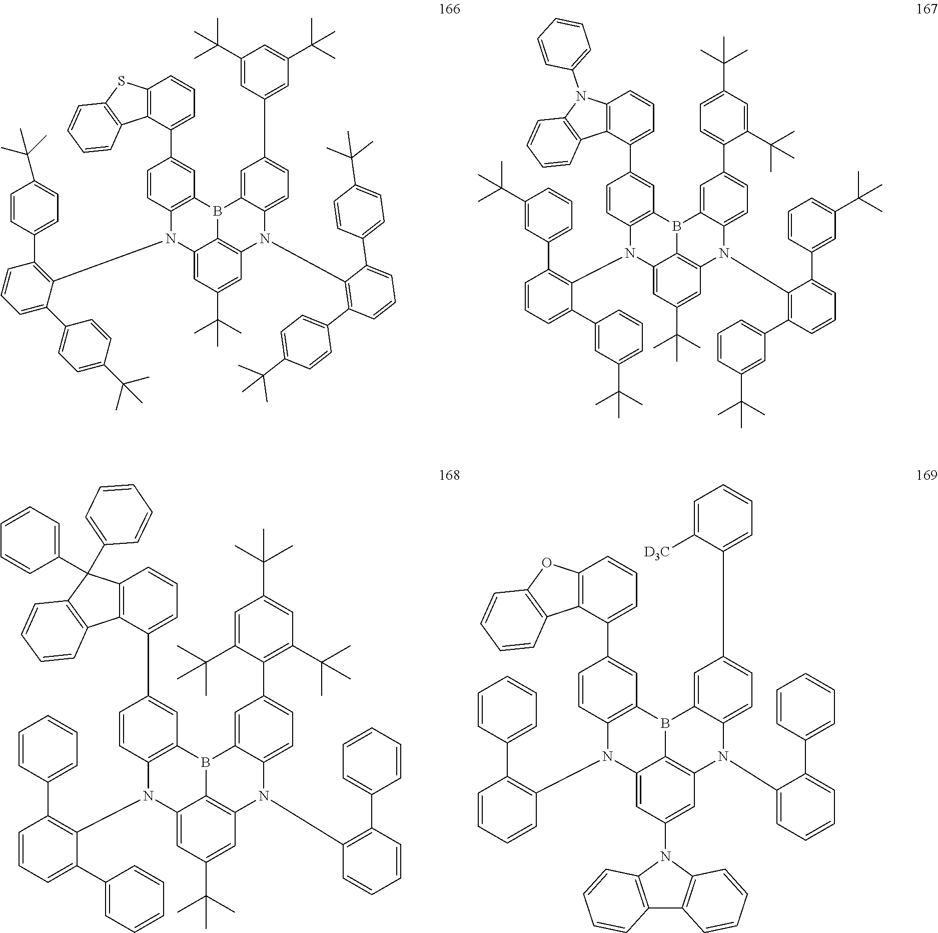 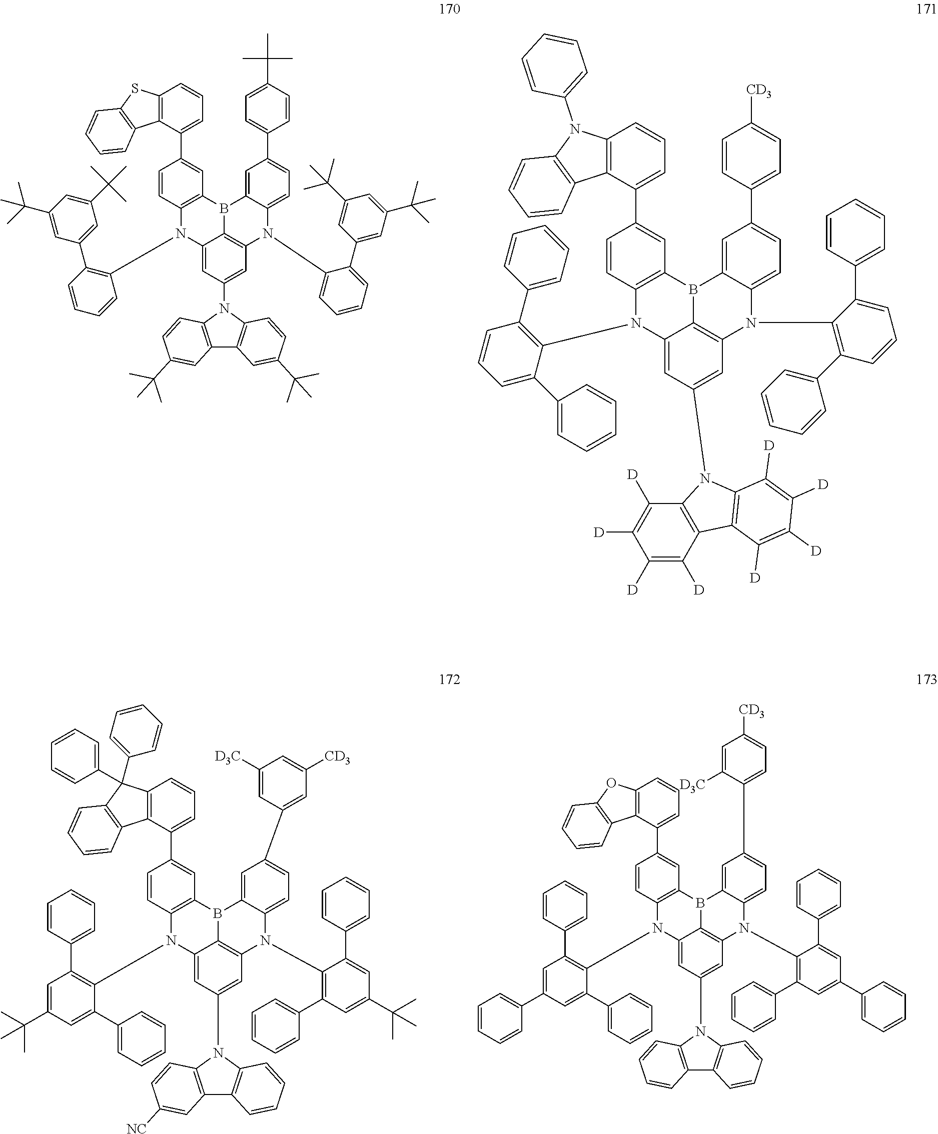 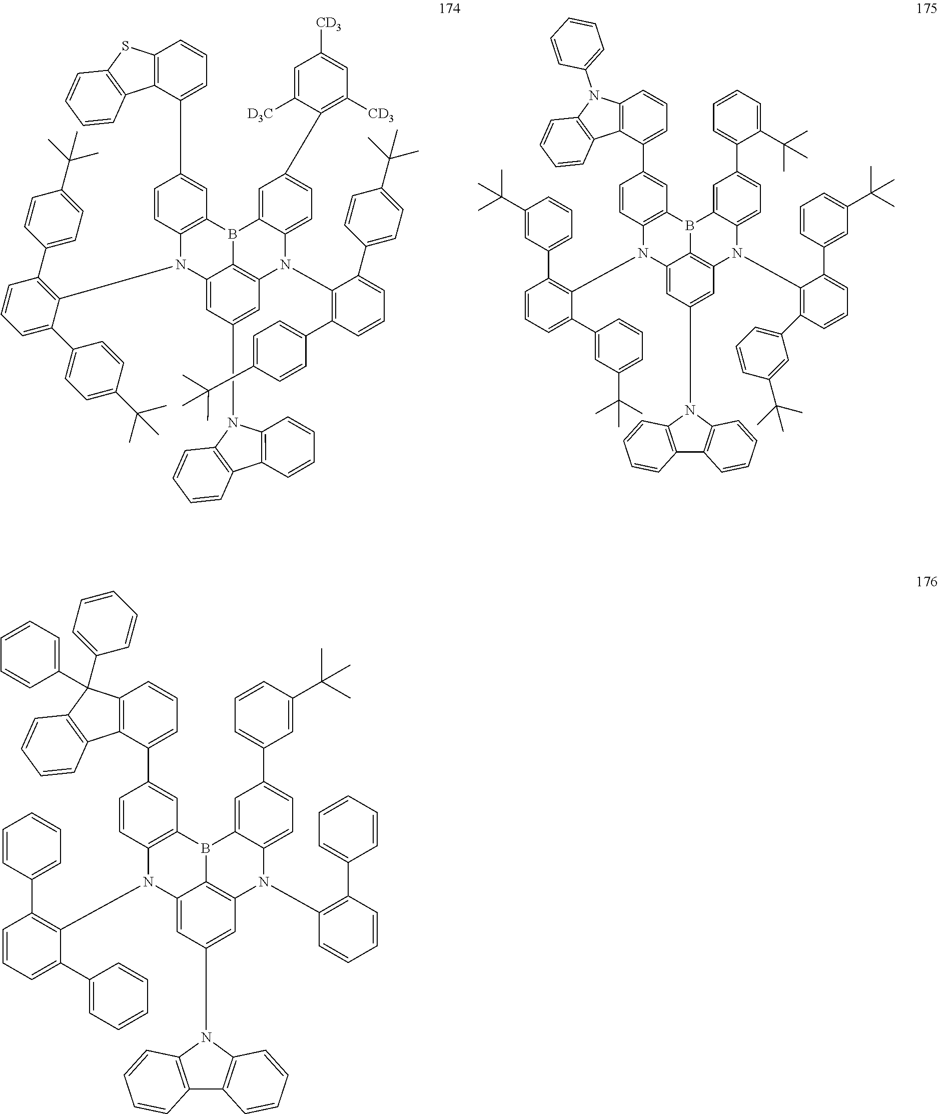 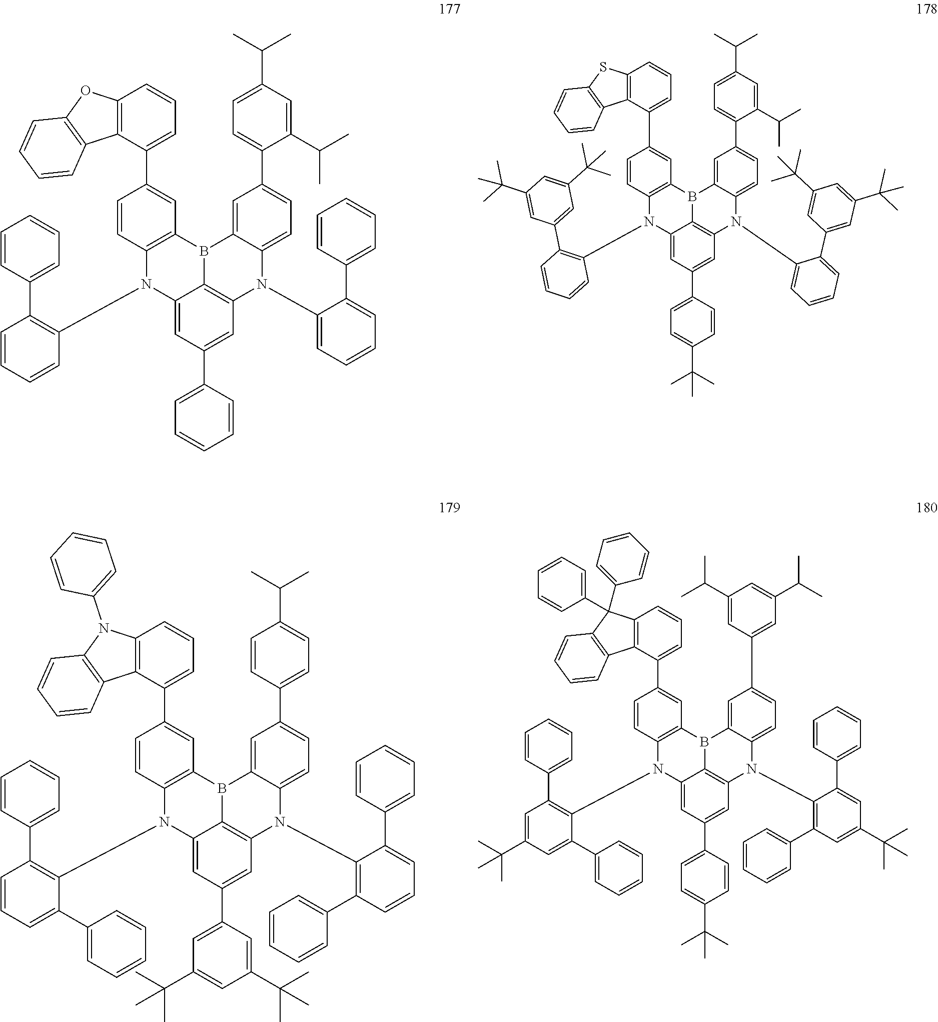 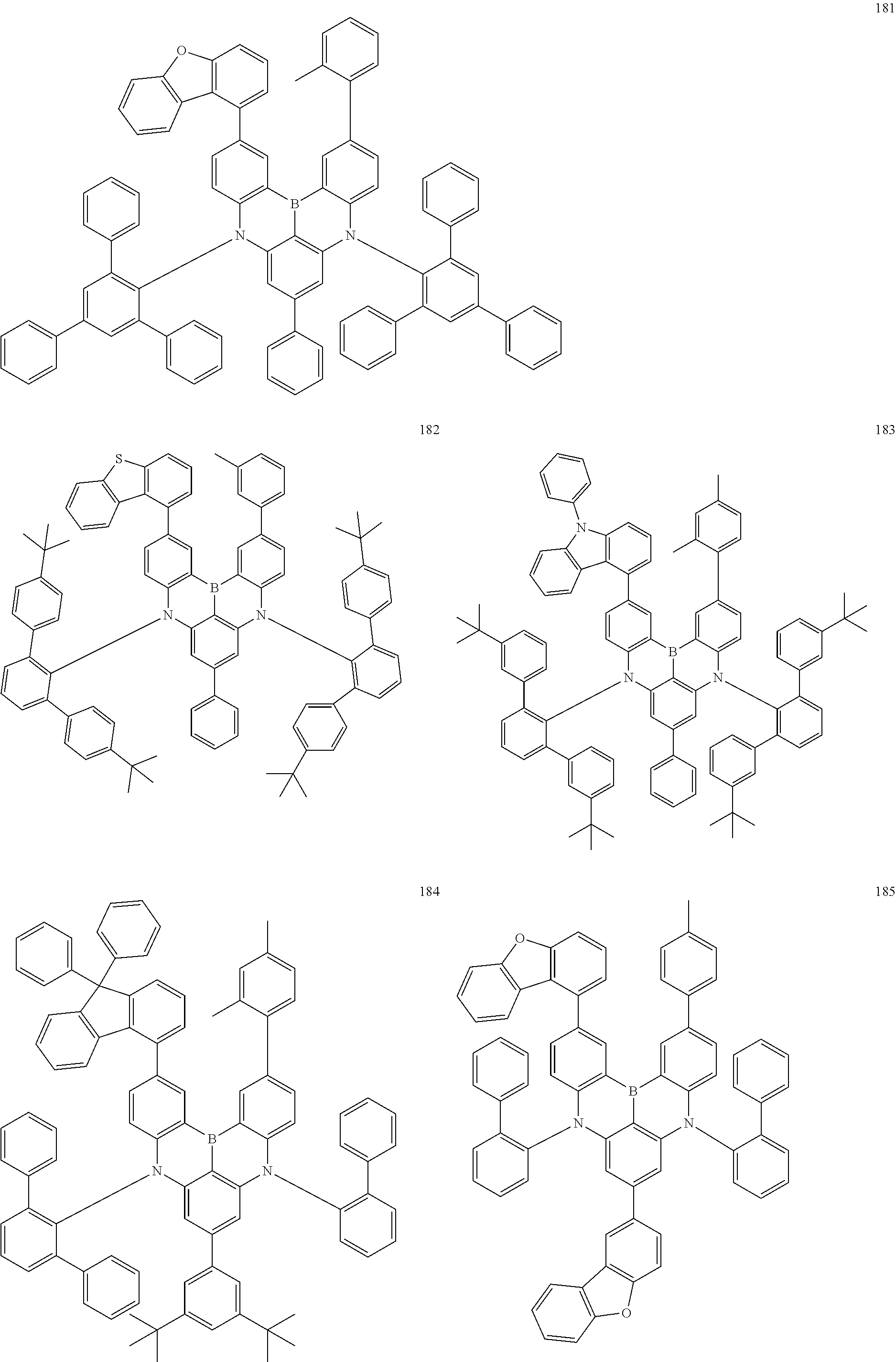 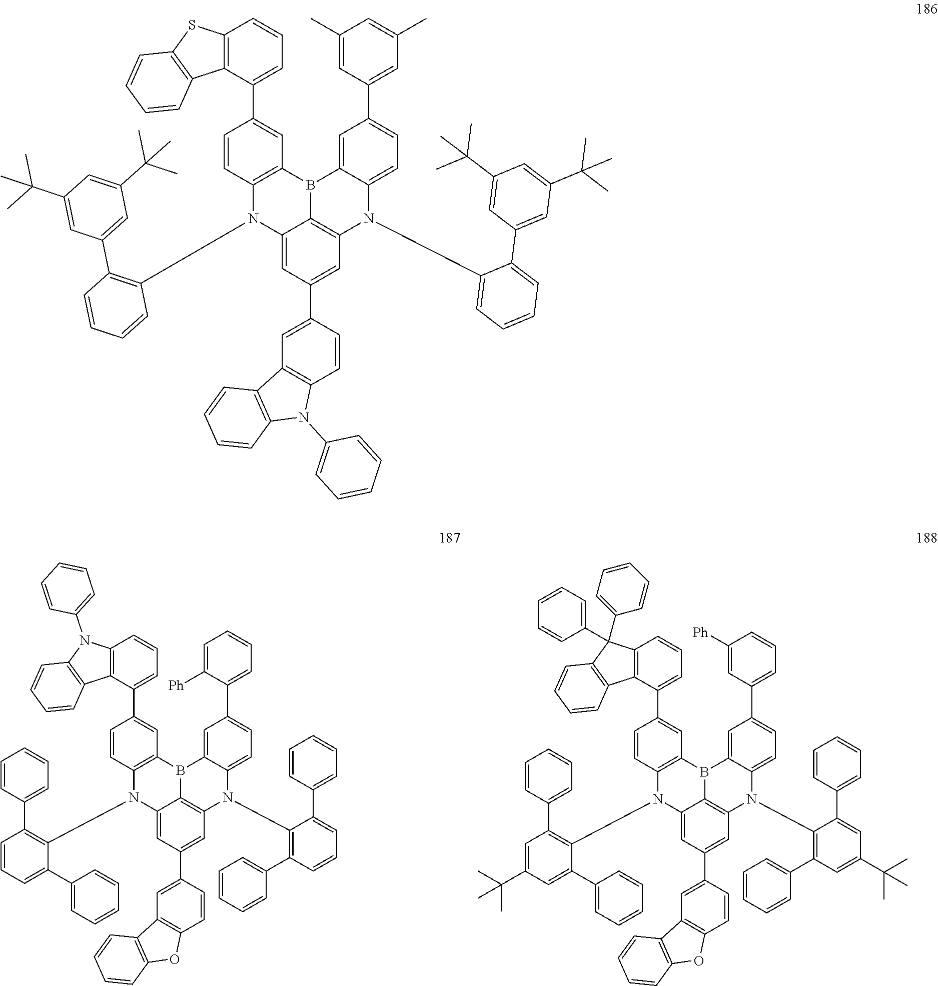 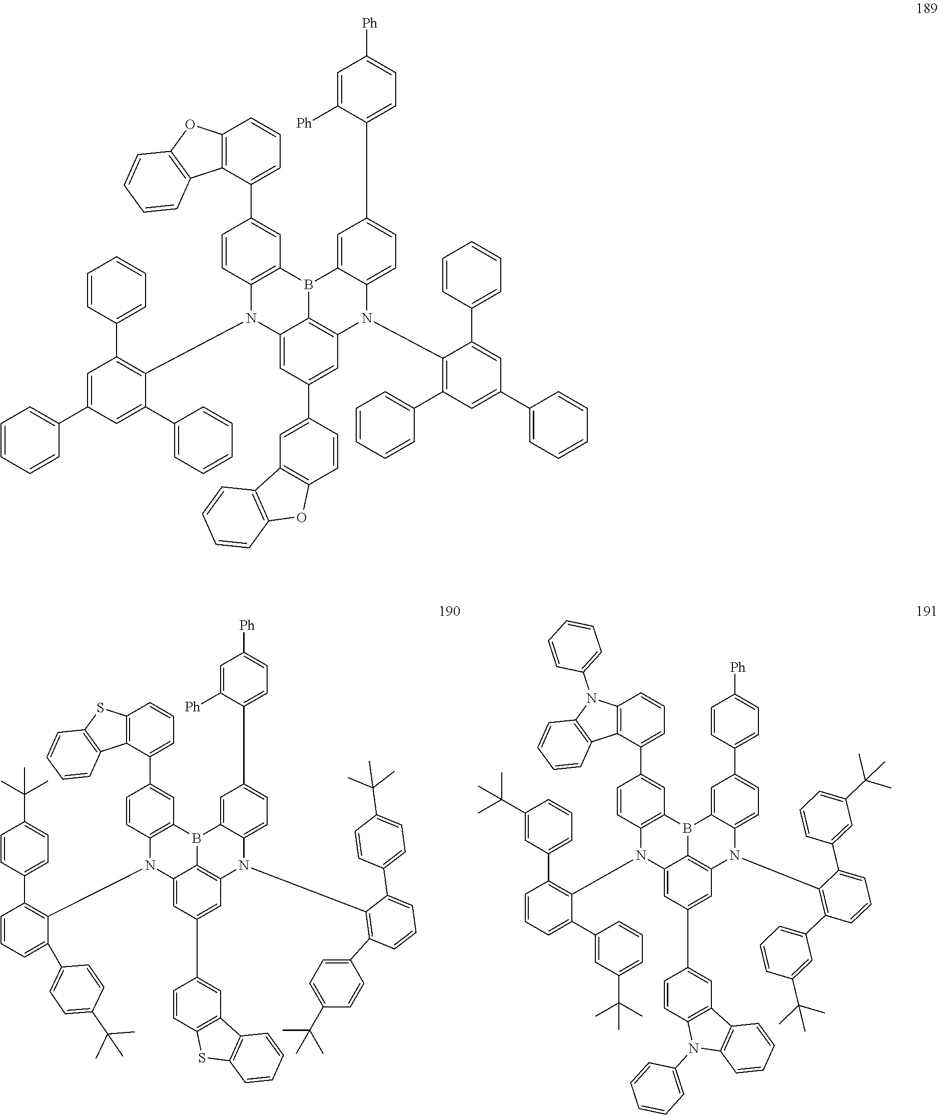 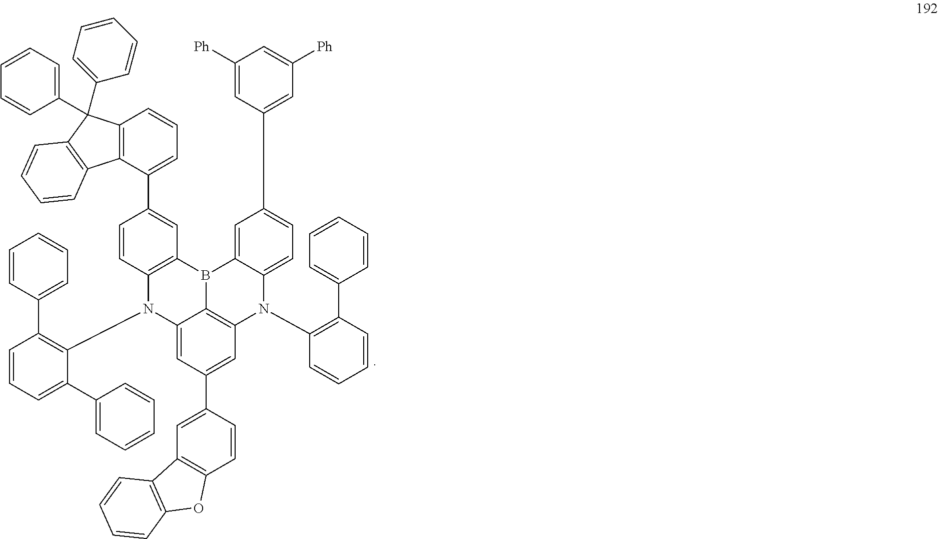 [SMILES: c1ccc(-c2cc(-c3ccccc3)cc(-c3ccc4c(c3)B3c5cc(-c6cccc7c6-c6ccccc6C7(c6ccccc6)c6ccccc6)ccc5N(c5c(-c6ccccc6)cccc5-c5ccccc5)c5cc(-c6ccc7oc8ccccc8c7c6)cc(c53)N4c3ccccc3-c3ccccc3)c2)cc1]
